(19) United States
(12) Patent Application Publication
(10) Pub. No.: US 2026/0047266 A1
(43) Pub. Date: Feb. 12, 2026

(54) ORGANIC ELECTROLUMINESCENT ELEMENT

(71) Applicant: NIPPON STEEL Chemical & Material Co., Ltd., Tokyo (JP)

(72) Inventors: Yuji IKENAGA, Tokyo (JP); Mitsuru SAKAI, Tokyo (JP); Junya OGAWA, Tokyo (JP); Yuya SHIMAMOTO, Tokyo (JP); Koyo TAKAKI, Tokyo (JP)

(73) Assignee: NIPPON STEEL Chemical & Material Co., Ltd., Tokyo (JP)

(21) Appl. No.: 19/101,365

(22) PCT Filed: Aug. 28, 2023
(86) PCT No.: PCT/JP2023/031043

§ 371 Date: Feb. 5, 2025

(30) Foreign Application Priority Data
Aug. 31, 2022 (JP) 2022-138435

(51) Int. Cl. H10K 50/12; C09K 11/06; H10K 85/30; H10K 85/60; H10K 101/00; H10K 101/20

(52) U.S. Cl. CPC H10K 50/12; C09K 11/06; H10K 85/342; H10K 85/346; H10K 85/622; H10K 85/626; H10K 85/654; H10K 85/6572; H10K 85/6574; H10K 85/658; C09K 2211/1029; H10K 2101/20; H10K 2101/90

(57) ABSTRACT

To provide an organic EL device having a low voltage, high efficiency and extended lifetime. Provided are an organic EL device comprising a first host represented by the following general formula (1), a second host represented by the following general formula (2), and a light emitting dopant material; a premixture; and a method for producing the organic EL device:

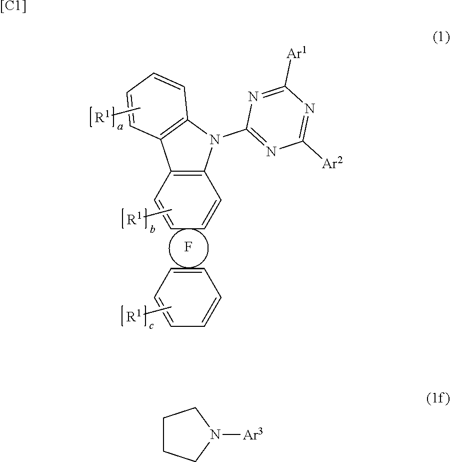

wherein ring F is represented by a formula (1f), Ar¹ and Ar² each independently represent a phenyl group or the like, Ar³ represents an aromatic hydrocarbon group having 6 to 30 carbon atoms or the like, an average rate of deuteration of Ar³ is 50% or more, each R¹ independently represents deuterium or the like, and an average rate of deuteration of the total hydrogen contained in the indolocarbazole backbone and R¹ is 50% or more,

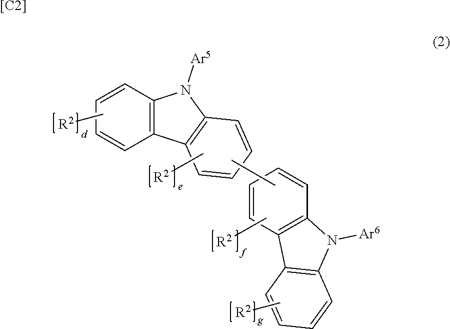

wherein Ar⁵ and Ar⁶ each independently represent an aromatic hydrocarbon group having 6 to 30 carbon atoms or the like, an average rate of deuteration thereof is 30% or more, each R² independently represents deuterium or the like, and an average rate of deuteration of the total hydrogen contained in biscarbazole and R² is 50% or more.

### TECHNICAL FIELD

The present invention relates to an organic electroluminescent element or device (hereinafter, referred to as an organic EL device), and specifically relates to an organic EL device comprising a specific mixed host material.

### BACKGROUND ART

Application of a voltage to an organic EL device allows injection of holes and electrons from an anode and a cathode, respectively, into a light-emitting layer. Then, in the light-emitting layer, injected holes and electrons recombine to generate excitons. At this time, according to statistical rules of electron spins, singlet excitons and triplet excitons are generated at a ratio of 1:3. Regarding a fluorescence-emitting organic EL device using light emission from singlet excitons, it is said that the internal quantum efficiency thereof has a limit of 25%. Meanwhile, regarding a phosphorescent organic EL device using light emission from triplet excitons, it is known that intersystem crossing is efficiently performed from singlet excitons, the internal quantum efficiency is enhanced to 100%.

Highly efficient organic EL devices utilizing delayed fluorescence have been developed recently. For example, Patent Literature 1 discloses an organic EL device utilizing a TTF (Triplet-Triplet Fusion) mechanism, which is one of delayed fluorescence mechanisms. The TTF mechanism utilizes a phenomenon in which singlet excitons are generated due to collision of two triplet excitons, and it is thought that the internal quantum efficiency can be theoretically raised to 40%. However, since the efficiency is lower compared to phosphorescent organic EL devices, further improvement in efficiency and low voltage characteristics are required.

In addition, patent Literature 2 discloses an organic EL device utilizing a TADF (Thermally Activated Delayed Fluorescence) mechanism. The TADF mechanism utilizes a phenomenon in which reverse intersystem crossing from triplet excitons to singlet excitons is generated in a material having a small energy difference between a singlet level and a triplet level, and it is thought that the internal quantum efficiency can be theoretically raised to 100%.

However, all the mechanisms have room for advancement in terms of both efficiency and lifetime, and are additionally required to be improved also in terms of reduction in driving voltage.

### CITATION LIST

### Patent Literature

Patent Literature 1: WO2010/134350 A
Patent Literature 2: WO2011/070963 A
Patent Literature 3: WO2008/056746 A
Patent Literature 4: WO2018/198844 A
Patent Literature 5: U.S. Pat. No. 10,333,077B2 A
Patent Literature 6: JP5784621 B2
Patent Literature 7: KR102054806 B1
Patent Literature 8: KR102283849 B1
Patent Literature 9: KR20220013910 A
Patent Literature 10: KR102193015 B1
Patent Literature 3 discloses use of an indolocarbazole compound as a host material of a light-emitting layer.
Patent Literatures 4 and 5 disclose use of an indolocarbazole compound and a biscarbazole compound in a mixed host material of a light-emitting layer.
Patent Literatures 6 and 7 disclose use of a deuterium-substituted indolocarbazole compound in a host material of a light-emitting layer.
Patent Literatures 8 and 9 disclose use of a deuterated biscarbazole compound in a host material of a light-emitting layer.
Patent Literatures 7 and 10 disclose use of a deuterium-substituted indolocarbazole compound and a biscarbazole compound in a mixed host material of a light emitting layer.

However, none of these can be said to be sufficient, and further improvement is desired.

### SUMMARY OF INVENTION

### Technical Problem

Organic EL displays, when compared with liquid crystal displays, are not only characterized by being thin-and-light, high in contrast, and capable of displaying a high-speed moving picture, but also highly valued in terms of designability such as curving and flexibility, and are widely applied in display apparatuses including mobiles and TV. However, organic EL displays are needed to be further reduced in voltage in order to suppress battery consumption in the case of use thereof for mobile terminals, and are inferior as light sources in terms of luminance and lifetime as compared with inorganic LEDs and thus are demanded to be improved in efficiency and enhanced in device lifetime. In view of the above circumstances, an object of the present invention is to provide a practically useful organic EL device having a low voltage, high efficiency and lifetime characteristics.

### Solution to Problem

As a result of intensive studies, the present inventors have found that the above problems can be solved by an organic electroluminescent device in which a specific mixed host material is used in a light emitting layer, and have completed the present invention.

The present invention relates to an organic electroluminescent device comprising one or more light emitting layers between an anode and a cathode opposed to each other, wherein at least one of the light emitting layers contains a first host selected from the compound represented by the following general formula (1), a second host selected from the compound represented by the following general formula (2), and a light emitting dopant material.

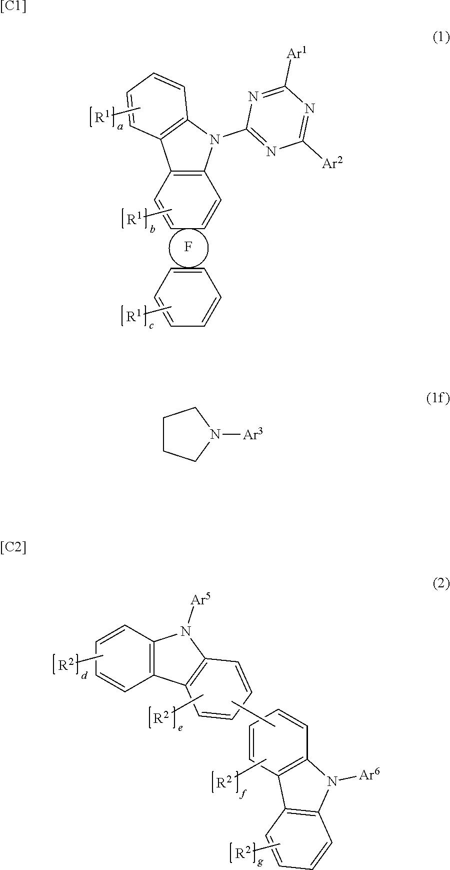

In the general formula (1), ring F represents a heterocyclic ring represented by a formula (1f) fused with two adjacent benzene rings at any positions. Ar¹ and Ar² each independently represent a deuterium-containing substituted or unsubstituted phenyl group or a deuterium-containing substituted or unsubstituted biphenyl group.

Ar³ represents a deuterium-containing substituted or unsubstituted aromatic hydrocarbon group having 6 to 30 carbon atoms, a deuterium-containing substituted or unsubstituted aromatic heterocyclic group having 3 to 17 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. Each R¹ independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. a to c represent the number of substitutions, a and c represent an integer of 0 to 4, and b represents an integer of 0 to 2.

To be noted, at least one R¹ represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and the average rate of deuteration of the total hydrogen contained in the indolocarbazole backbone and R¹ as the substituent thereof is 50% or more. Some or all of hydrogen contained in Ar³ are replaced by deuterium, and the average rate of deuteration of the total hydrogen contained in Ar³ is 50% or more.

In the general formula (2), Ar⁵ and Ar⁶ each independently represent a deuterium-containing substituted or unsubstituted aromatic hydrocarbon group having 6 to 30 carbon atoms or a deuterium-containing substituted or unsubstituted linked aromatic group in which two to five of these aromatic groups are linked to each other, and the aromatic hydrocarbon groups when being linked are the same or different from each other.

Each R² independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. d to g represent the number of substitutions, d and g represent an integer of 0 to 4, and e and f represent an integer of 0 to 3.

To be noted, at least one R² represents deuterium, or a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and the average rate of deuteration of the total hydrogen contained in the biscarbazole backbone and R² as the substituent thereof is 50% or more. Some of hydrogen contained in Ar⁵ and Ar⁶ in the general formula (2) are replaced by deuterium, and the average rate of deuteration of the total hydrogen contained in Ar⁵ and Ar⁶ is 30% or more.

In the general formula (1), Ar³ preferably represents a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted quaterphenyl group, a deuterium-containing substituted or unsubstituted dibenzofuranyl group, or a deuterium-containing substituted or unsubstituted dibenzothiophenyl group, and more preferably a deuterium-containing substituted or unsubstituted phenyl group, a deuterium-containing substituted or unsubstituted biphenyl group, a deuterium-containing substituted or unsubstituted terphenyl group, or a deuterium-containing substituted or unsubstituted quaterphenyl group. In the general formula (1), R¹ preferably represents deuterium.

Further, in the general formula (1), the average rate of deuteration of the total hydrogen contained in Ar³ is preferably 70% or more, and the average rate of deuteration of the total hydrogen contained in the indolocarbazole backbone and R¹ as the substituent thereof is preferably 70% or more.

In the general formula (2), Ar⁵ and Ar⁶ preferably represent a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted dibenzofuranyl group, or a deuterium-containing substituted or unsubstituted dibenzothiophenyl group, and more preferably a deuterium-containing substituted or unsubstituted phenyl group or a deuterium-containing substituted or unsubstituted biphenyl group. In the general formula (2), R² preferably represents deuterium.

Further, in the general formula (2), the average rate of deuteration of the total hydrogen contained in Ar⁵ and Ar⁶ is preferably 50% or more.

The organic electroluminescent device of the present invention comprises a light-emitting layer having a mixed host containing two compounds and having a dopant (light-emitting dopant material). In the organic electroluminescent device, the ratio of the compound represented by the general formula (1) to the total of the compound represented by the general formula (1) and the compound represented by the general formula (2) in the mixed host is preferably 10 wt % or more and less than 80 wt %, and more preferably 30 wt % or more and less than 80 wt %. It is more preferable that the light-emitting dopant material be an organic metal complex containing at least one metal selected from the group consisting of ruthenium, rhodium, palladium, silver, rhenium, osmium, iridium, platinum and gold, or a thermally activated delayed fluorescence-emitting dopant.

The present invention relates to a premixture comprising a first host and a second host to be used for forming, in an organic electroluminescent device comprising a light-emitting layer containing hosts and a light-emitting dopant material between an anode and a cathode opposed to each other, the light-emitting layer, wherein the first host is selected from a compound represented by the general formula (1) and the second host is selected from a compound represented by the general formula (2). Also in the premixture, preferred aspects of the compound represented by the general formula (1) and the compound represented by the general formula (2) and a preferred mixed ratio of those compounds are the same as those described in the above organic electroluminescent device. When the above organic electroluminescent device is produced, a step of mixing the first host represented by the general formula (1) and the second host represented by the general formula (2) to give a premixture and then vapor-depositing a host material containing the premixture to form a light emitting layer.

In a method for producing the organic electroluminescent device, a difference in temperature at 50% weight loss of the first host and the second host is preferably within 20° C.

### Advantageous Effect of Invention

According to the present invention, a first host that has indolocarbazole, a nitrogen-containing six-membered ring, and a phenyl group or a biphenyl group and is further substituted with deuterium, and a biscarbazole compound substituted with deuterium as a second host can be mixed and used to thereby obtain an organic EL device having a low voltage, high efficiency and extended lifetime. In addition, the first host and the second host are mixed to give a premixture, and then a host material containing the premixture is used to thereby obtain an organic EL device having high luminance, high efficiency, and extended lifetime.

### BRIEF DESCRIPTION OF DRAWING

FIG. 1 is a schematic cross-sectional view showing one example of an organic EL device.

### DESCRIPTION OF EMBODIMENTS

The first host material contained in the light emitting layer of the organic EL device of the present invention is represented by the general formula (1).

In the general formula (1), ring F represents a heterocyclic ring represented by the formula (1f) fused with two adjacent benzene rings at any positions. Ar¹ and Ar² each independently represent a deuterium-containing substituted or unsubstituted phenyl group or a deuterium-containing substituted or unsubstituted biphenyl group, and is preferably an unsubstituted phenyl group or an unsubstituted biphenyl group. Here, the term “deuterium-containing substituted” encompasses both the case where the basic backbone simply has a substituent and the case where the hydrogen contained in the basic backbone and the substituent thereof is replaced by deuterium. For example, a deuterium-containing substituted phenyl group encompasses both the case where the phenyl group as the basic backbone has a substituent and the case where the hydrogen contained in the phenyl group and the substituent in the phenyl group is replaced by deuterium.

Ar³ represents a deuterium-containing substituted or unsubstituted aromatic hydrocarbon group having 6 to 30 carbon atoms, a deuterium-containing substituted or unsubstituted aromatic heterocyclic group having 3 to 17 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. Ar³ preferably represents a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted quaterphenyl group, a deuterium-containing substituted or unsubstituted dibenzofuranyl group, or a deuterium-containing substituted or unsubstituted dibenzothiophenyl group, and more preferably a deuterium-containing substituted or unsubstituted phenyl group, a deuterium-containing substituted or unsubstituted biphenyl group, a deuterium-containing substituted or unsubstituted terphenyl group, or a deuterium-containing substituted or unsubstituted quaterphenyl group.

Specific examples of the unsubstituted aromatic hydrocarbon group having 6 to 30 carbon atoms, the unsubstituted aromatic heterocyclic group having 3 to 17 carbon atoms, or the linked aromatic group in which two to five of these aromatic groups are linked to each other for Ar³ include a group generated by removing one hydrogen atom from benzene, naphthalene, acenaphthene, acenaphthylene, azulene, anthracene, chrysene, pyrene, phenanthrene, fluorene, triphenylene, benzo[a]anthracene, tetracene, pentacene, hexacene, coronene, heptacene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzoisothiazole, benzothiadiazole, purine, pyranone, coumarin, isocoumarin, chromone, dibenzofuran, dibenzothiophene, dibenzoselenophene, carbazole, or compounds in which two to five of these are linked to each other. Preferred is a group generated by removing one hydrogen atom from benzene, dibenzofuran, dibenzothiophene, carbazole, or compounds in which two to five of these are linked to each other, more preferred is a phenyl group, a biphenyl group, a terphenyl group, a quaterphenyl group, a dibenzofuranyl group, or a dibenzothiophenyl group, and further preferred is a quaterphenyl group. The terphenyl group and the quaterphenyl group may be linked linearly or branched.

Each R¹ independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. R¹ is preferably deuterium, and at least one or more R¹ is preferably the aromatic hydrocarbon group, the aromatic heterocyclic group, or the linked aromatic group.

Specific examples of the unsubstituted aromatic hydrocarbon group having 6 to 10 carbon atoms, the unsubstituted aromatic heterocyclic group having 3 to 12 carbon atoms, or the linked aromatic group in which two to five of these aromatic group are linked to each other for R¹ include a group generated by removing one hydrogen atom from benzene, naphthalene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzoisothiazole, benzothiadiazole, dibenzofuran, dibenzothiophene, dibenzoselenophene, carbazole, or compounds in which two to five of these are linked to each other. Preferred is a group generated by removing one hydrogen atom from benzene, dibenzofuran, dibenzothiophene, carbazole, or compounds in which two to five of these are linked to each other, more preferred is a group generated by removing one hydrogen atom from benzene, dibenzofuran, dibenzothiophene, carbazole, or compounds in which two to three of these are linked to each other, and further preferred is a group generated by removing one hydrogen atom from benzene, carbazole, or compounds in which two to three of these are linked to each other.

In the general formula (1), Ar¹ and Ar² may be partially or entirely deuterated. The average rate of deuteration of Ar¹ and Ar² is preferably 0%. In the general formula (1), at least one of R¹ represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic group are linked to each other, and the average rate of deuteration of the total hydrogen contained in the indolocarbazole backbone and R¹ as the substituent thereof is 50% or more, preferably 70% or more, more preferably 80% or more, and further preferably 90% or more. In the general formula (1), some or all of hydrogen contained in Ar³ are replaced by deuterium, and the average rate of deuteration of the total hydrogen contained in Ar³ is 50% or more, preferably 70% or more, and further preferably 80% or more. Further, the average rate of deuteration of the total hydrogen contained in the whole compound represented by the general formula (1) is preferably 30% or more, more preferably 40% or more, and further preferably 50% or more. A deuterated product represented by the general formula (1) encompasses both the case of a single compound represented by the general formula (1) and the case of a mixture of two or more compounds represented by the general formula (1). In other words, when the average rate of deuteration is specifically described by way of Ar³ as an example, the average rate of deuteration of hydrogen on Ar³ of 50% means that, among N hydrogen atoms on Ar³, N/2 hydrogen atoms are replaced by deuterium on average, in which the deuterated product represented by the general formula (1) may be a single compound or a mixture of those different in the rate of deuteration.

The average rate of deuteration can be determined by mass analysis or proton nuclear magnetic resonance spectroscopy. For example, when the average rate of deuteration is determined by proton nuclear magnetic resonance spectroscopy, first, a measurement sample is prepared by adding and dissolving a compound and an internal standard material to and in a deuterated solvent, and the proton concentration [mol/g] in the compound included in the measurement sample is calculated from the ratio between the respective integral intensities derived from the internal standard material and the compound. Next, the ratio between the proton concentration in a deuterium compound and the proton concentration in the corresponding non-deuterated compound is calculated, and subtracted from 1, thereby enabling calculation of the average rate of deuteration of the deuterium compound. The average rate of deuteration of a partial structure can be calculated from the integral intensity of the chemical shift derived from an objective partial structure, according to the same procedure.

The second host material contained in the light emitting layer of the organic EL device of the present invention is represented by the general formula (2).

In the general formula (2), Ar⁵ and Ar⁶ each independently represent a deuterium-containing substituted or unsubstituted aromatic hydrocarbon group having 6 to 30 carbon atoms or a deuterium-containing substituted or unsubstituted linked aromatic group in which two to five of these aromatic groups are linked to each other, and the aromatic hydrocarbon groups when being linked are the same or different from each other. Ar⁵ and Ar⁶ preferably each independently represent a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted dibenzofuranyl group, or a deuterium-containing substituted or unsubstituted dibenzothiophenyl group, and further preferably a deuterium-containing substituted or unsubstituted phenyl group or a deuterium-containing substituted or unsubstituted biphenyl group.

Specific examples of the unsubstituted aromatic hydrocarbon group having 6 to 30 carbon atoms and the unsubstituted aromatic heterocyclic group having 3 to 17 carbon atoms for Ar⁵ and Ar⁶ are the same as those for Ar³.

Each R² independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked may be the same as or different from each other. R² preferably represents deuterium.

Specific examples of the unsubstituted aromatic hydrocarbon group having 6 to 10 carbon atoms, the unsubstituted aromatic heterocyclic group having 3 to 12 carbon atoms, or the linked aromatic group in which two to five of these aromatic groups are linked to each other for R² are the same as those for R¹. Preferred is a group generated by removing one hydrogen atom from benzene, dibenzofuran, dibenzothiophene, carbazole, or compounds in which two to five of these are linked to each other, and more preferred is a group generated by removing one hydrogen atom from benzene, dibenzofuran, dibenzothiophene, carbazole, or compounds in which two to three of these are linked to each other.

In the general formula (2), at least one R² represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and the average rate of deuteration of the total hydrogen contained in the biscarbazole backbone and R² as the substituent thereof is 50% or more, and preferably 70% or more. Some or all of hydrogen contained in Ar⁵ and Ar⁶ are replaced by deuterium, and the average rate of deuteration of the total hydrogen contained in Ar⁵ and Ar⁶ is 30% or more, and preferably 50% or more. Further, the average rate of deuteration of the total hydrogen contained in the whole compound represented by the general formula (2) is preferably 30% or more, and more preferably 50% or more. Here, the average rate of deuteration and the calculation method thereof are the same as those for the general formula (1).

In the present specification, the linked aromatic group refers to an aromatic group in which the aromatic groups in two or more aromatic groups are linked to each other by a single bond. The linked aromatic group may be linear or branched. The linkage position in linking of benzene rings may be any of the ortho-, meta-, and para-positions. The aromatic group may be an aromatic hydrocarbon group or an aromatic heterocyclic group, and the plurality of aromatic groups may be the same or different.

In the present specification, the aromatic hydrocarbon group, the aromatic heterocyclic group, or the linked aromatic group may have a substituent. In the case that a substituent is contained, the substituent is preferably deuterium, a halogen, a cyano group, a triarylsilyl group, an aliphatic hydrocarbon group having 1 to 10 carbon atoms, an alkenyl group having two to five carbon atoms, an alkoxy group having one to five carbon atoms, or a diarylamino group having 12 to 44 carbon atoms. When the substituent is an aliphatic hydrocarbon group having 1 to 10 carbon atoms, the substituent may be linear, branched, or cyclic. When the triarylsilyl group or the diarylamino group is substituted with the aromatic hydrocarbon group, the aromatic heterocyclic group, or the linked aromatic group, silicon and carbon or nitrogen and carbon are bonded together by a single bond.

Specific examples of the substituent include deuterium, cyano, methyl, ethyl, propyl, i-propyl, butyl, t-butyl, pentyl, neopentyl, cyclopentyl, hexyl, cyclohexyl, heptyl, octyl, nonyl, decyl, vinyl, propenyl, butenyl, pentenyl, methoxy, ethoxy, propoxy, butoxy, pentoxy, diphenylamino, naphthylphenylamino, dinaphthylamino, dinthranylamino, diphenanthrenylamino, and dipyrenylamino. Preferred examples thereof include deuterium, cyano, methyl, ethyl, t-butyl, propyl, butyl, pentyl, neopentyl, hexyl, heptyl, or octyl, diphenylamino, naphthylphenylamino, or dinaphthylamino.

Specific examples of the compound represented by the general formula (1) are shown below, but are not limited to these exemplified compounds. In the following structural formulas, the number of substitutions such as l, m, n, o, p, q, r, s, or t of the substituted deuterium (D) means the average number, and varies depending on the rate of deuteration (D-rate).

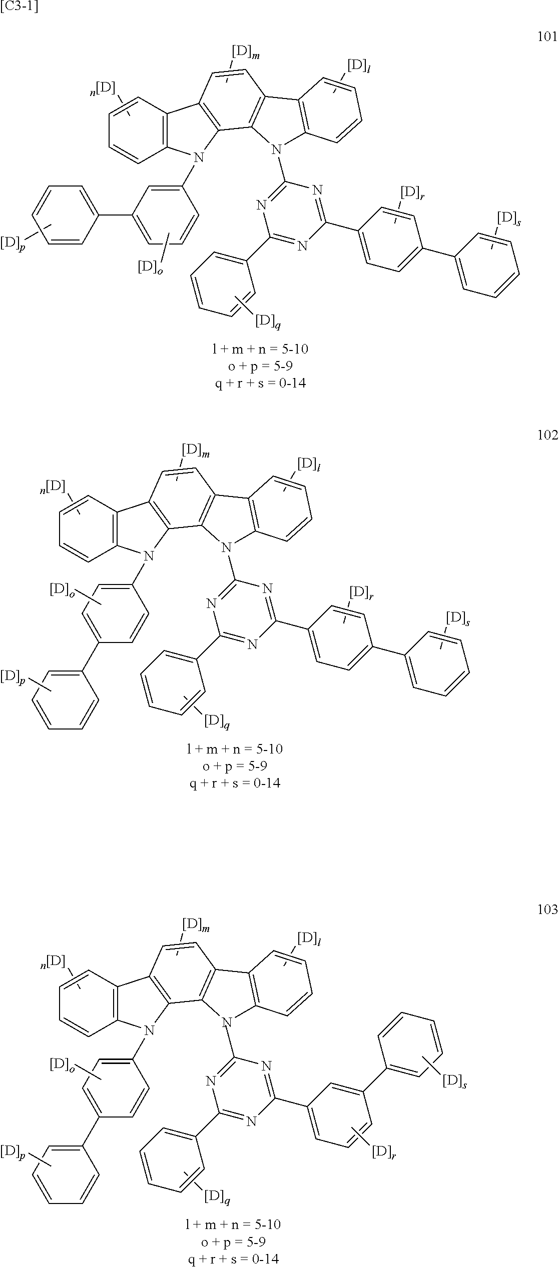

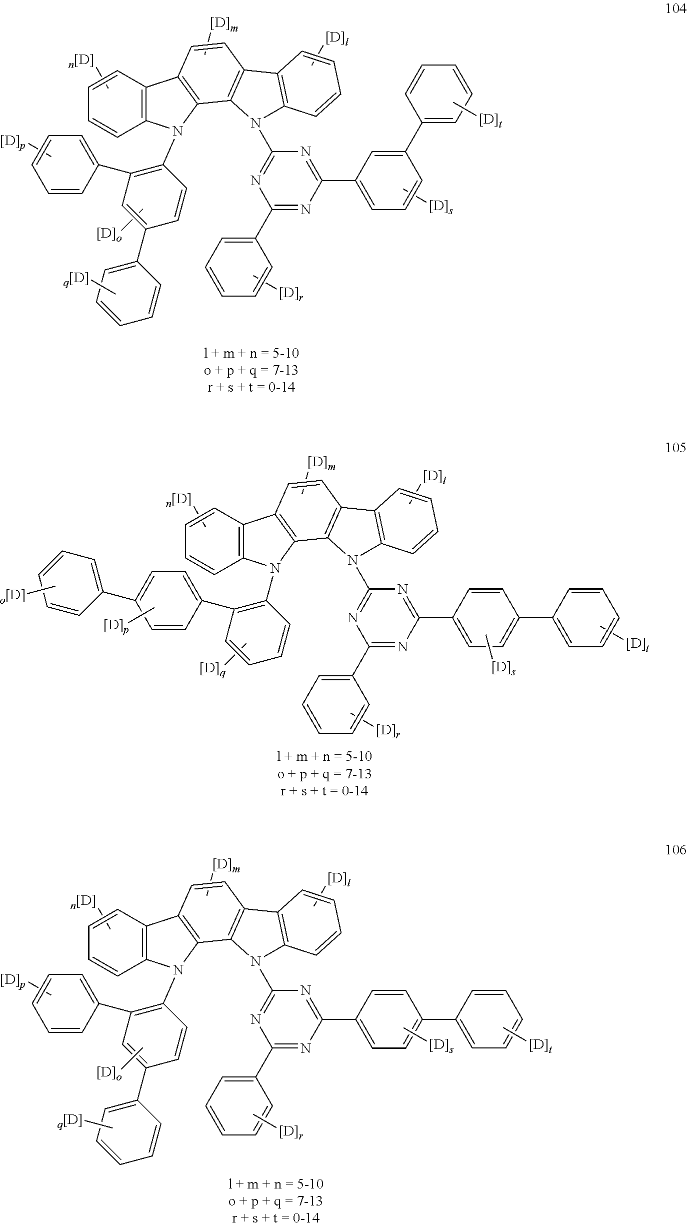

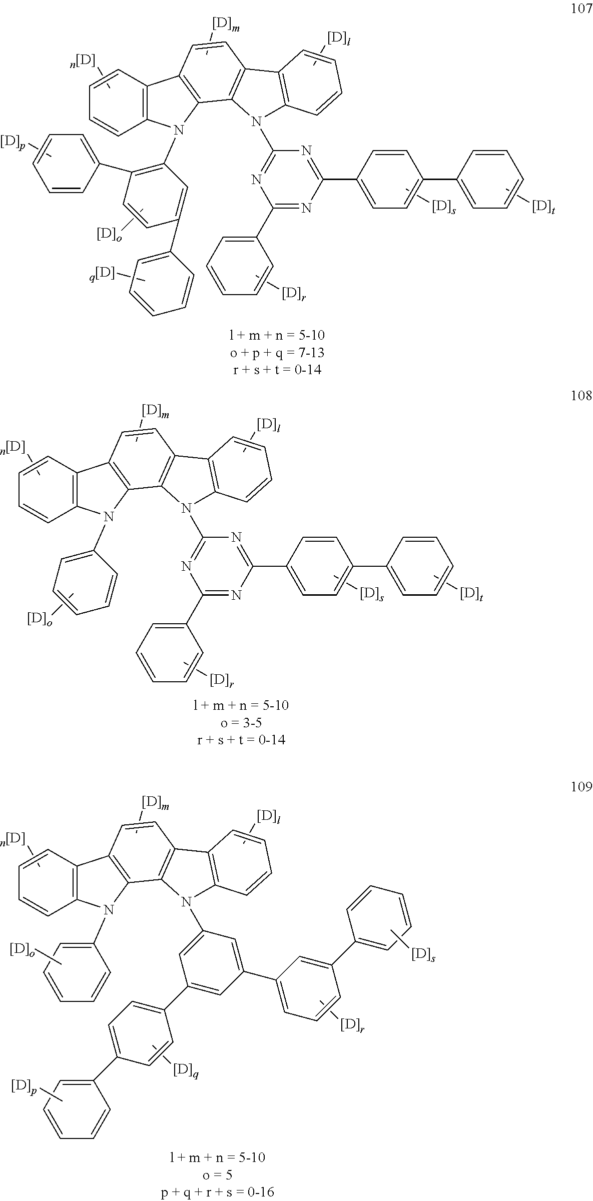

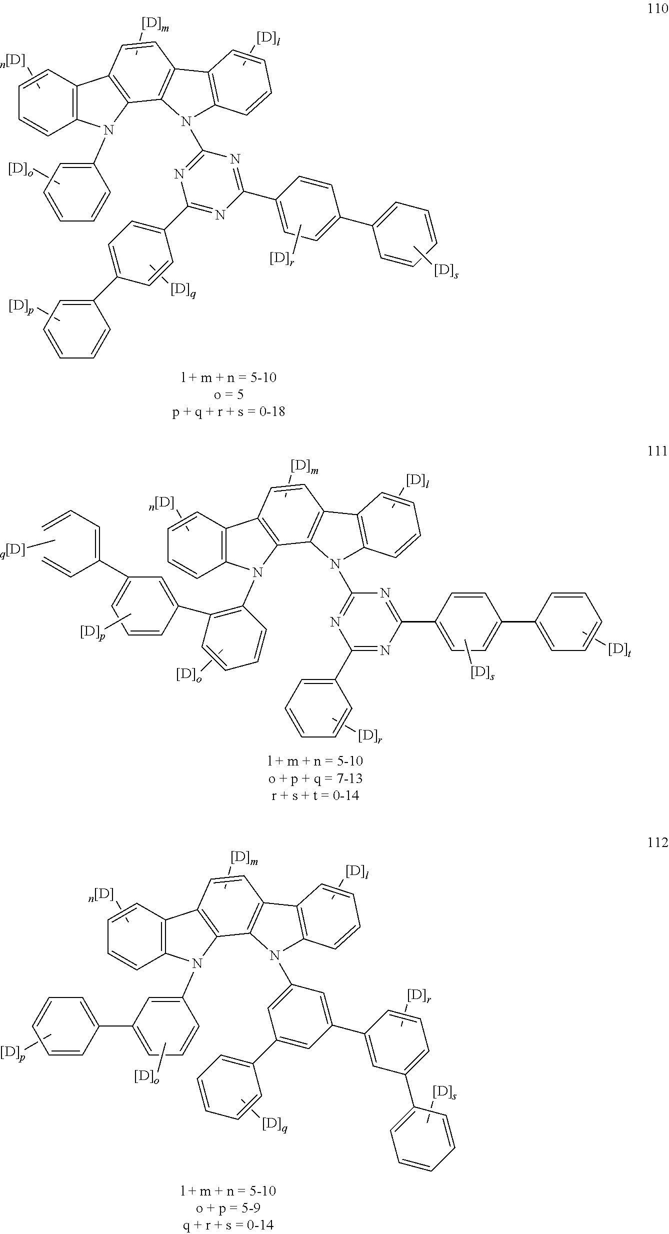

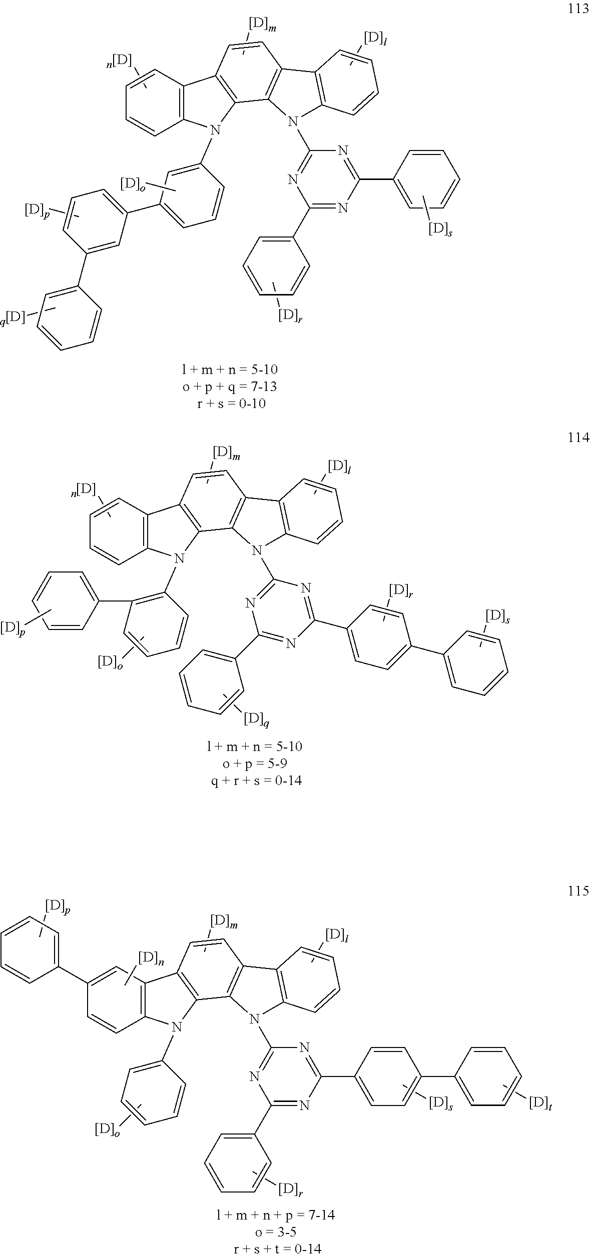

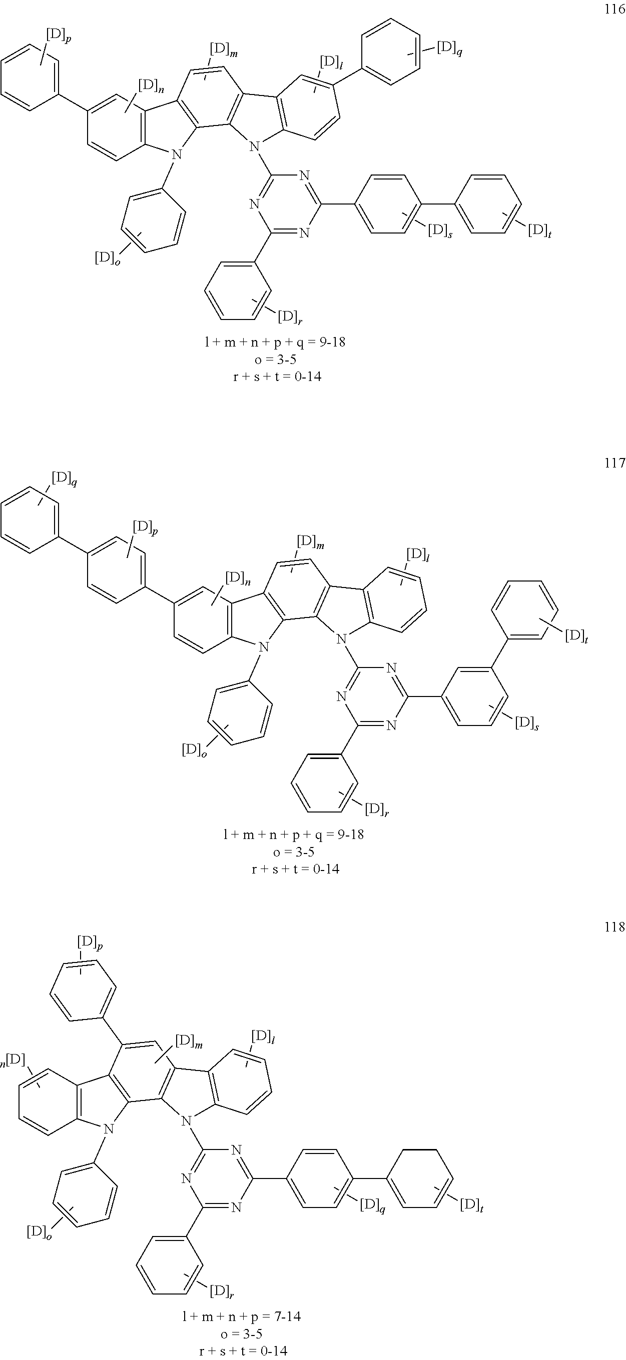

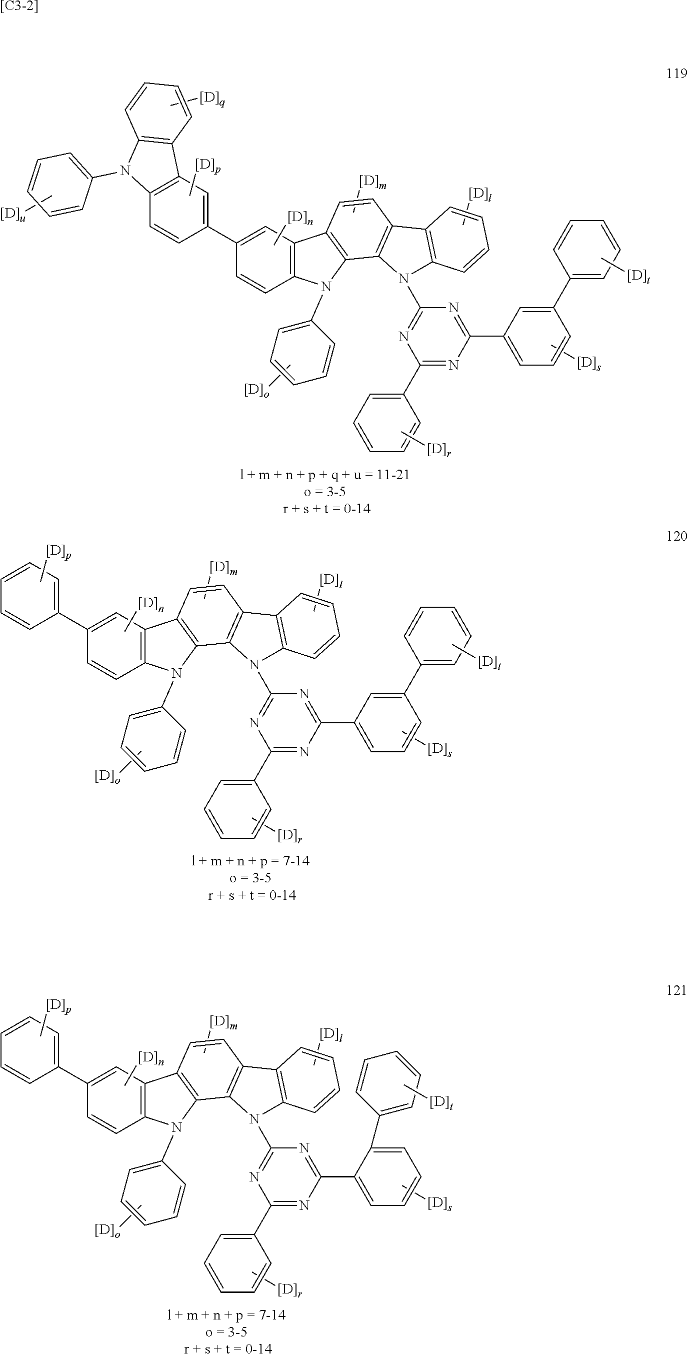

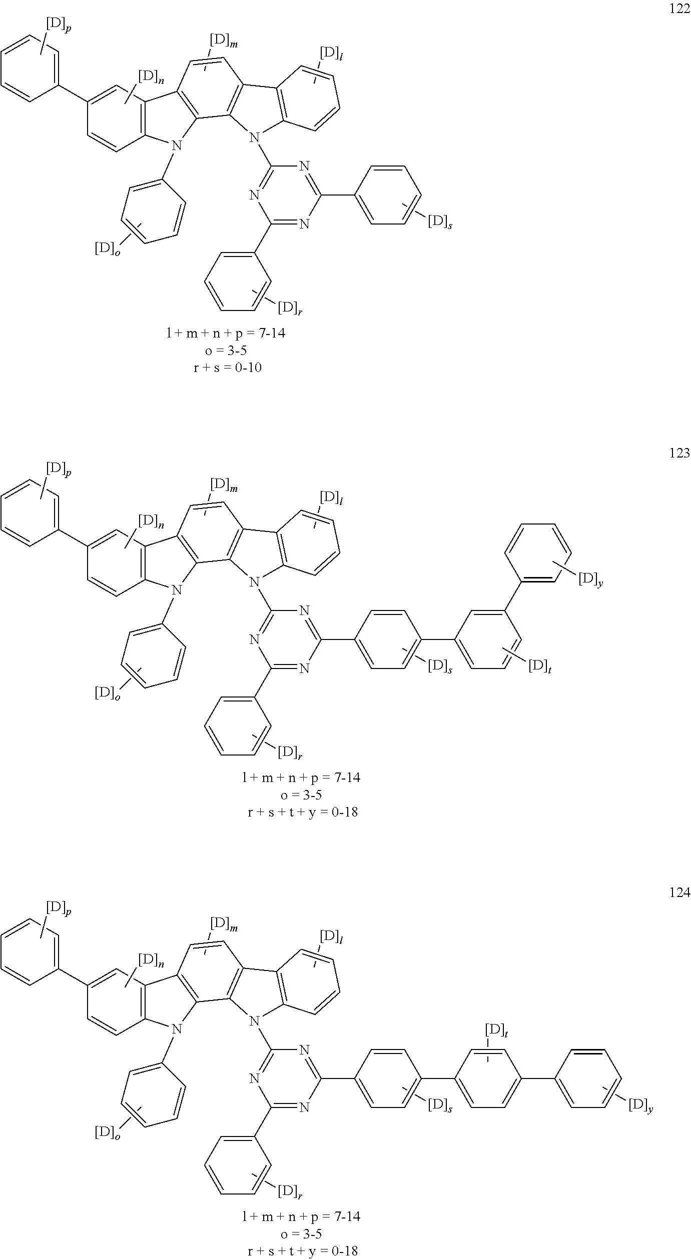

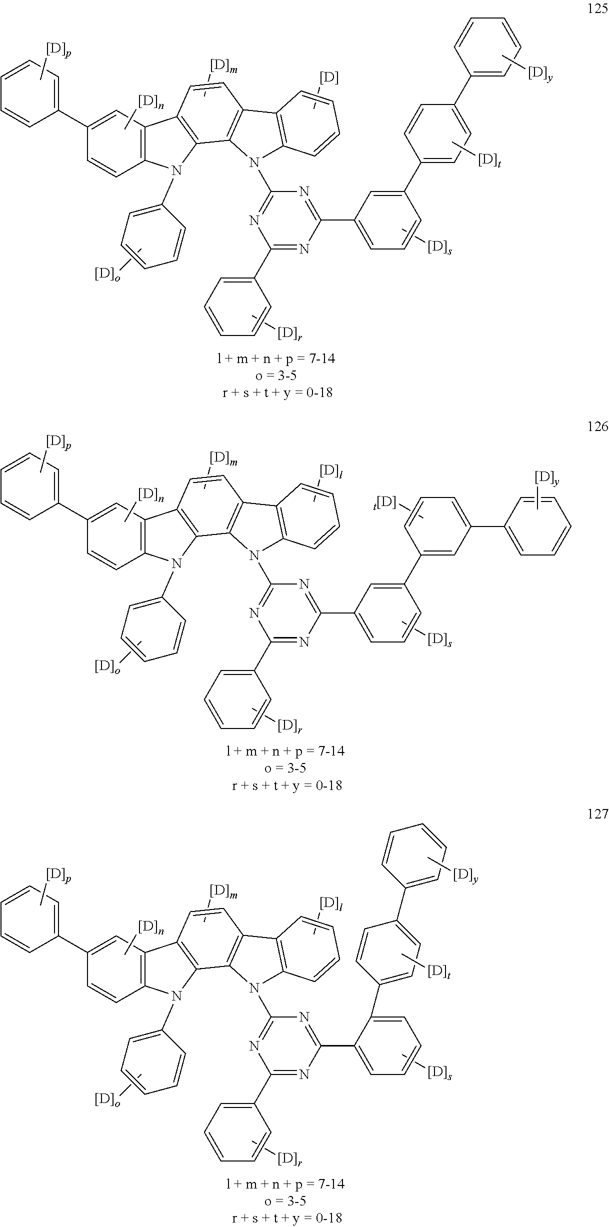

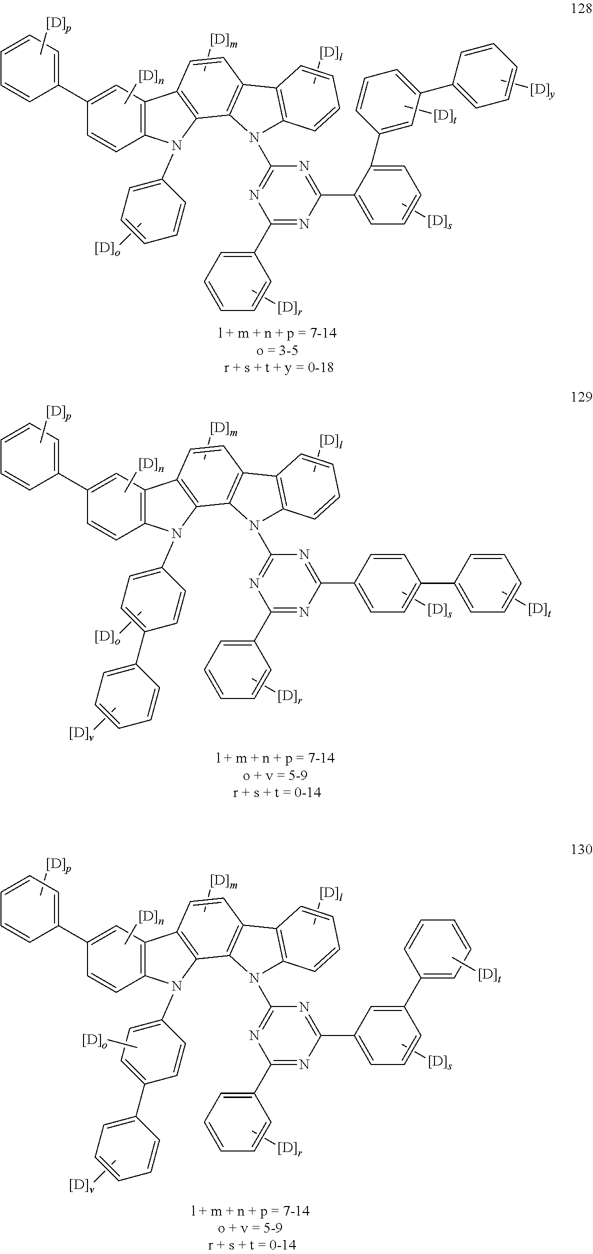

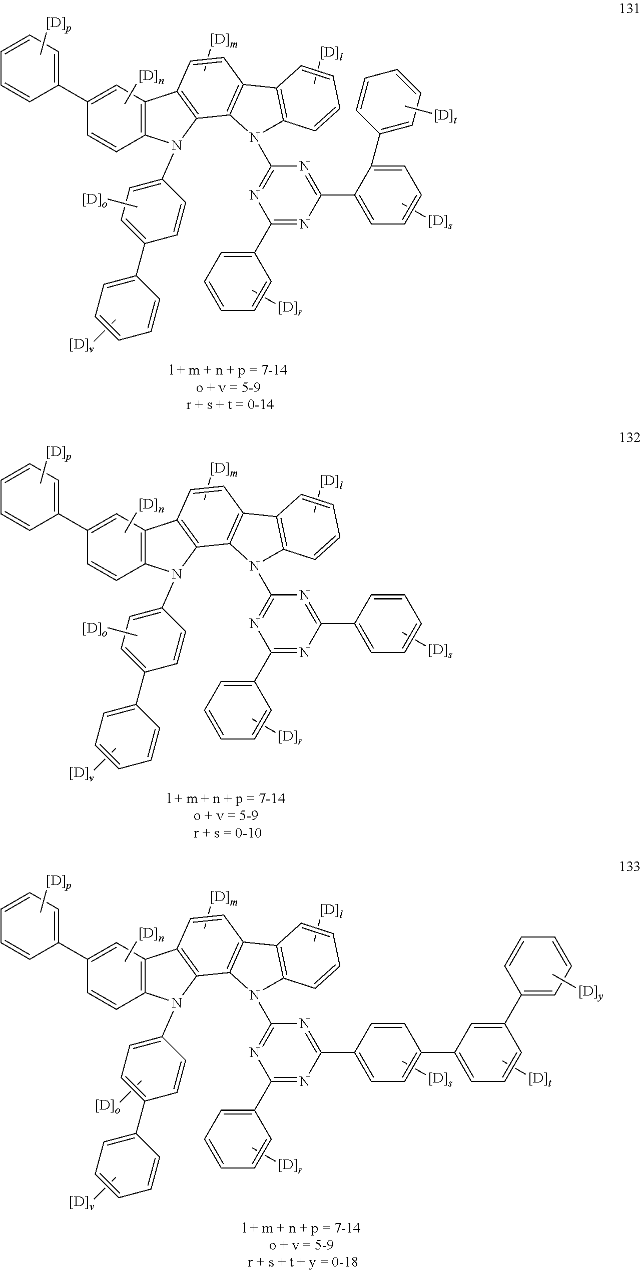

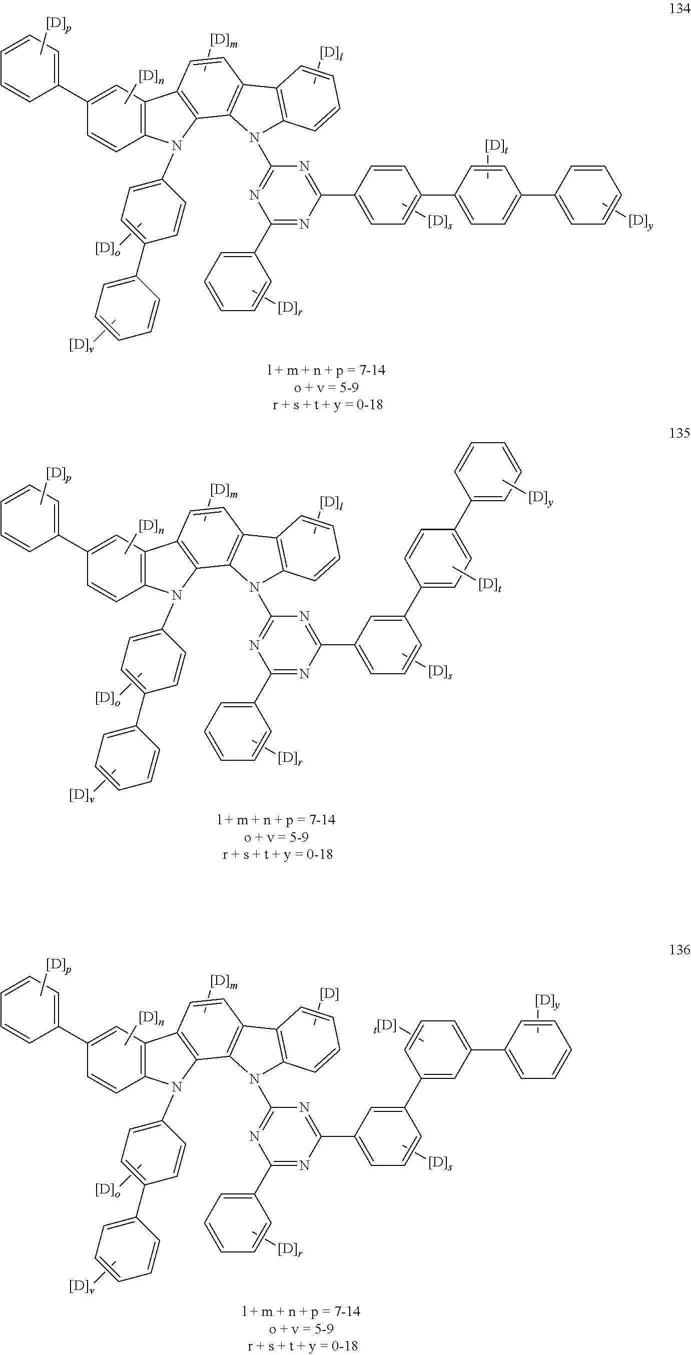

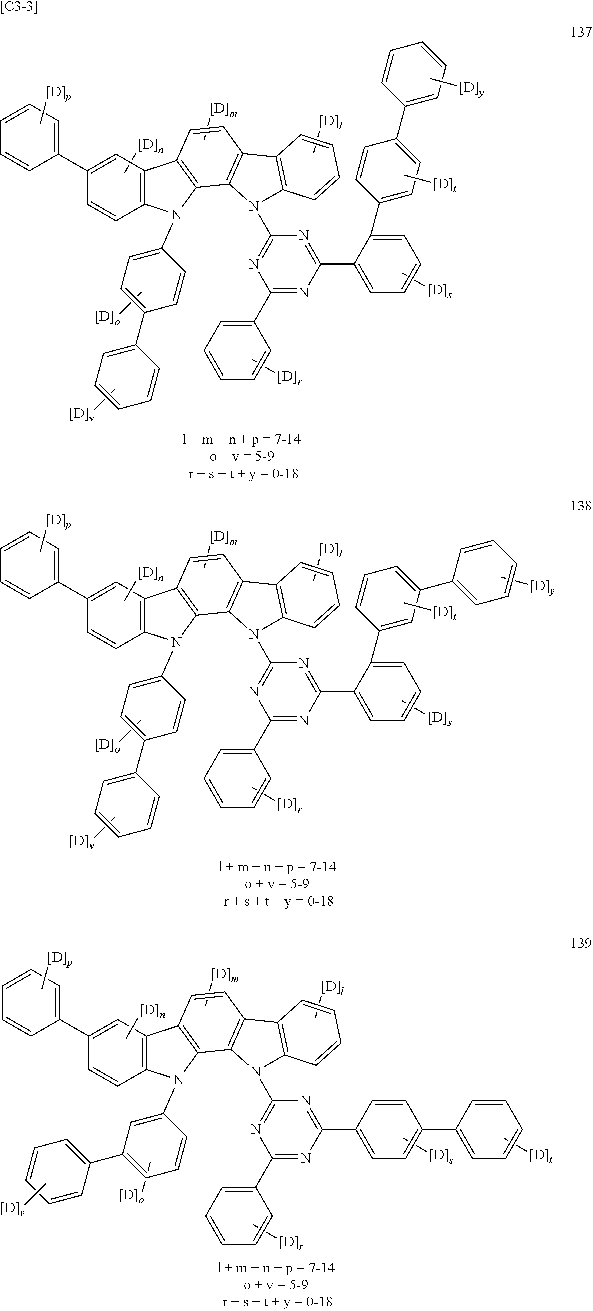

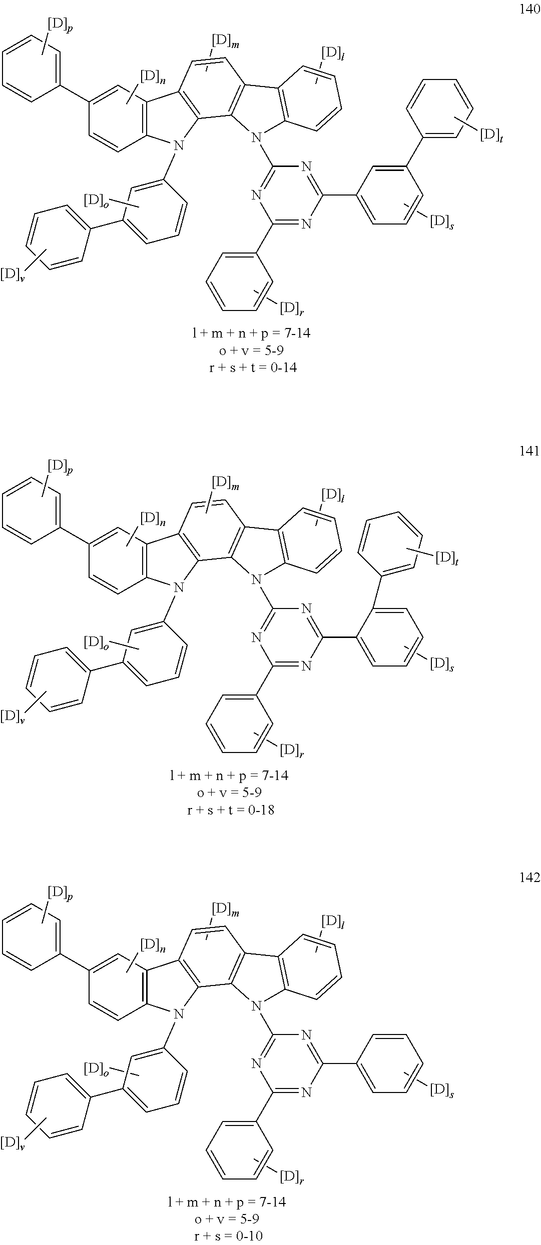

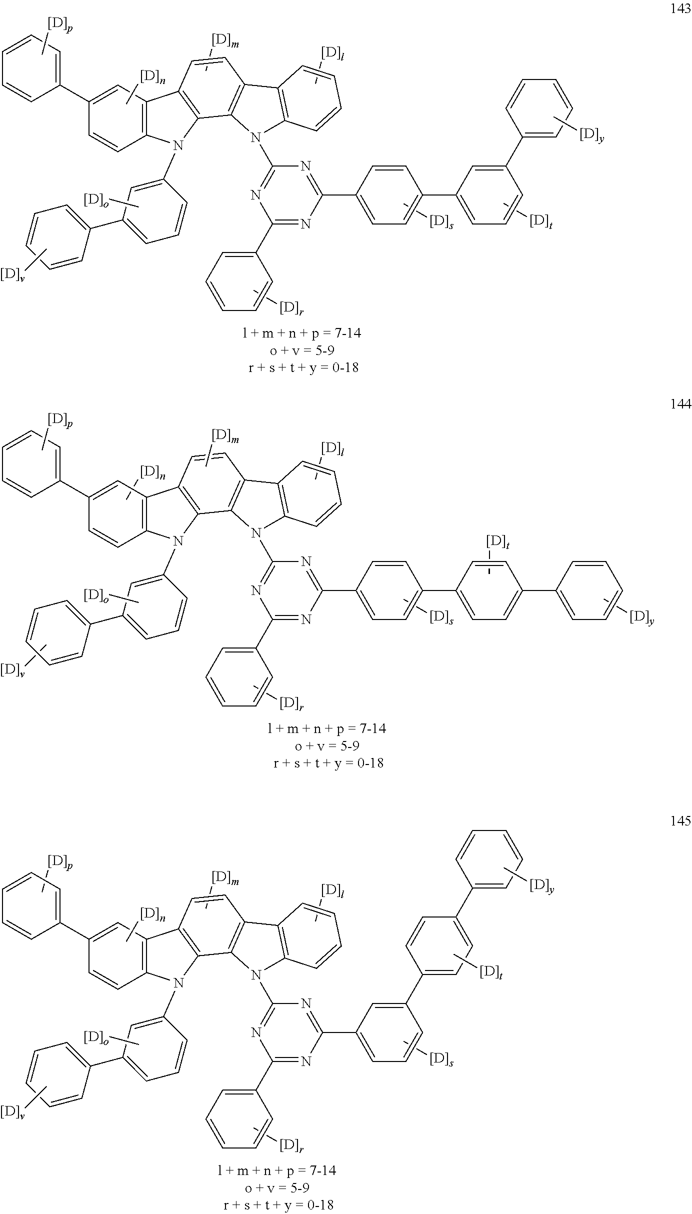

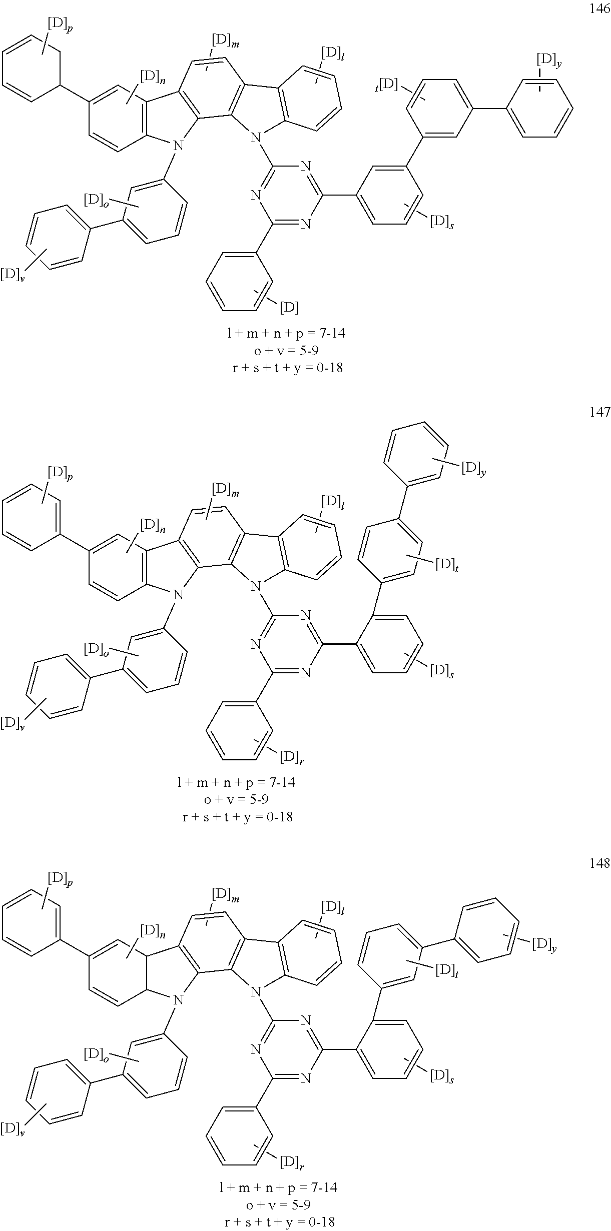

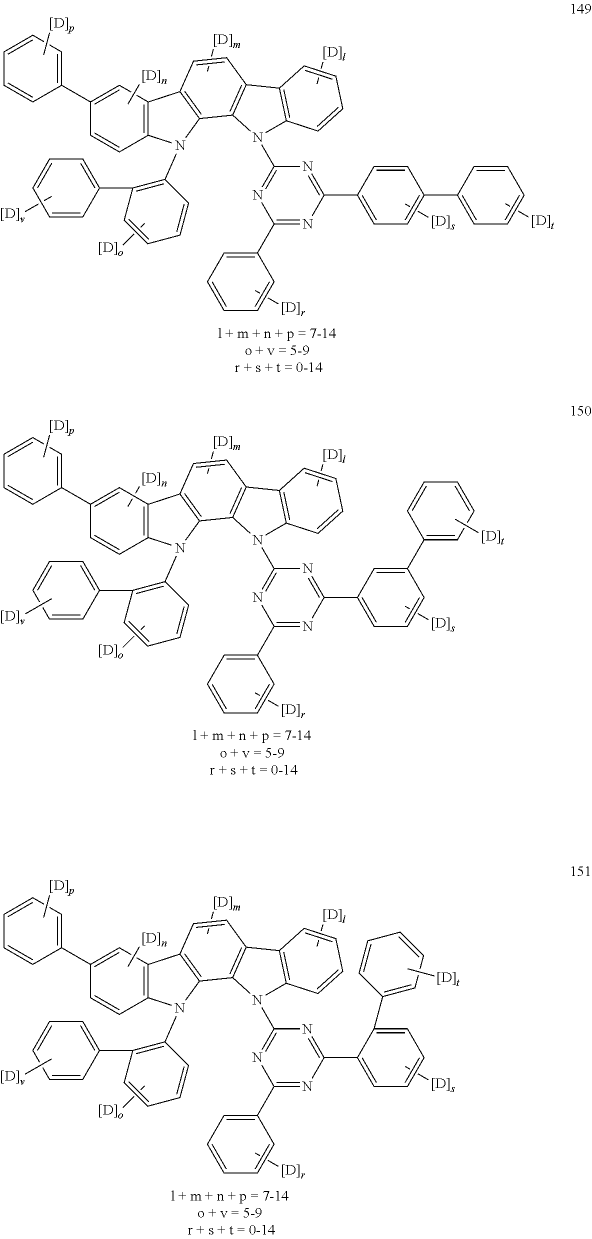

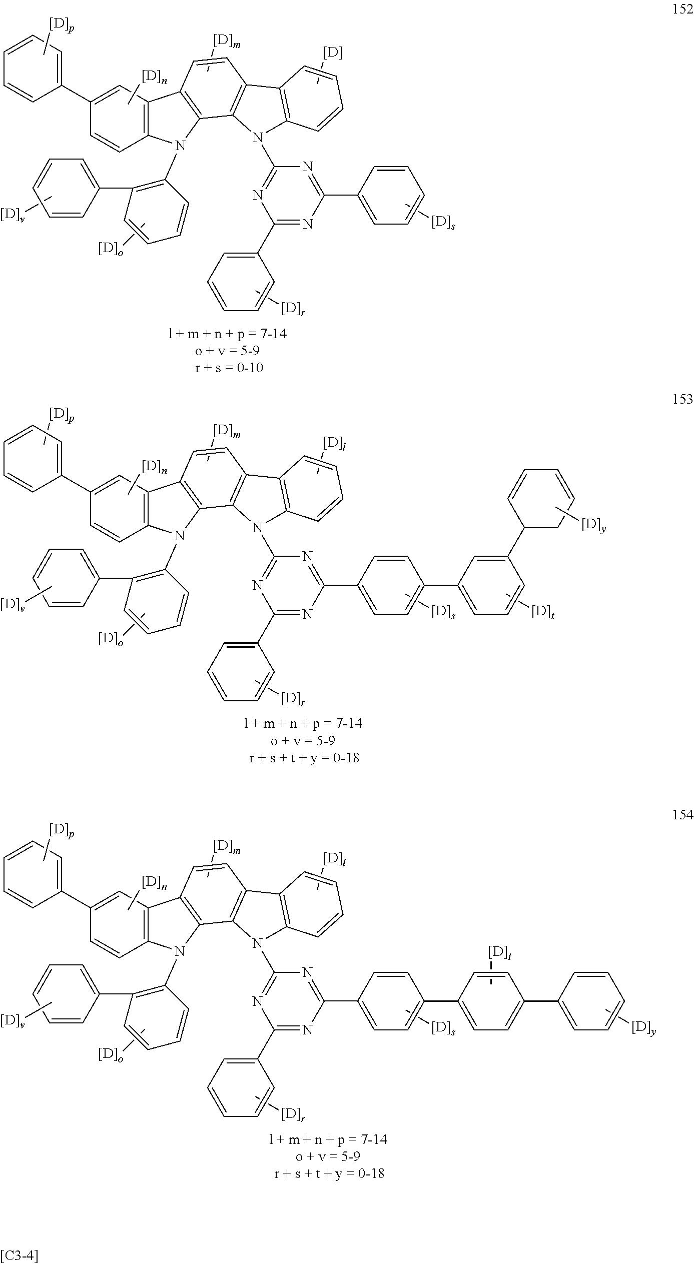

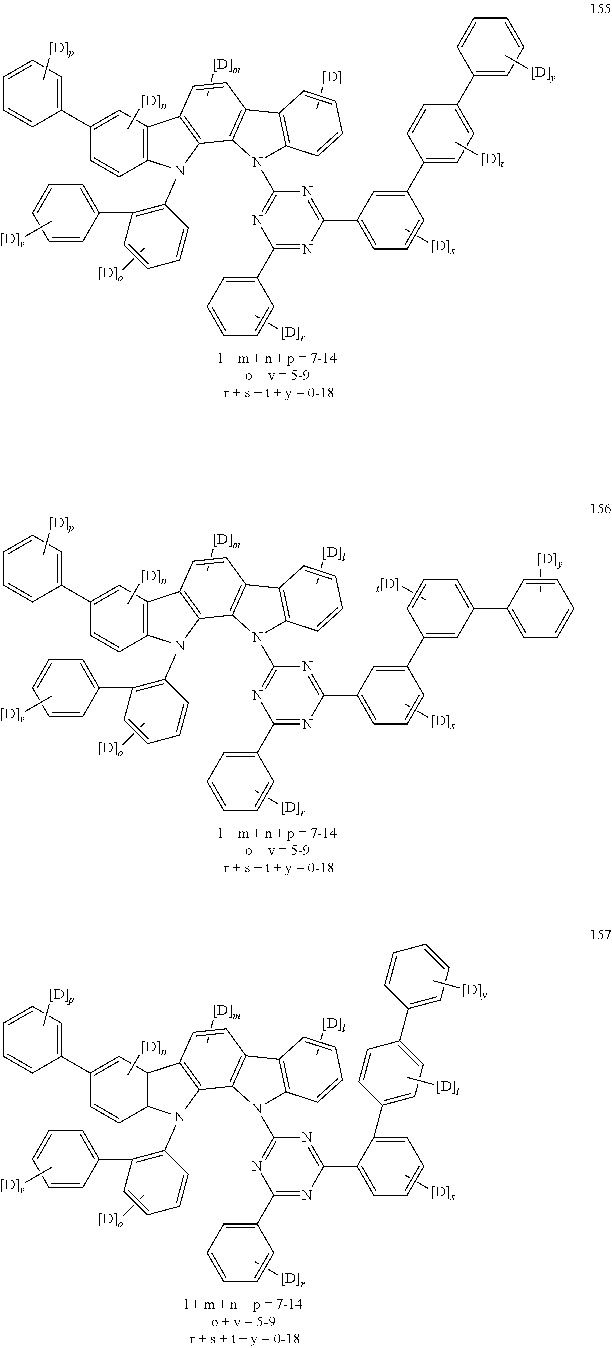

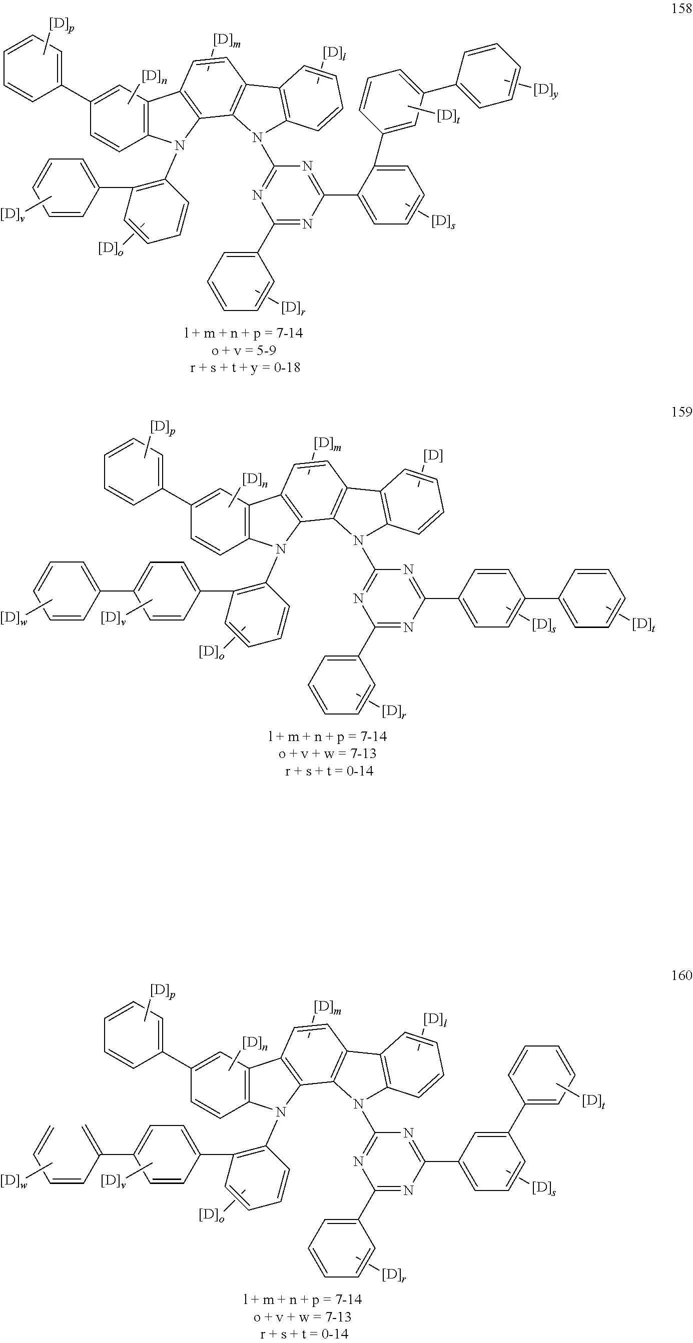

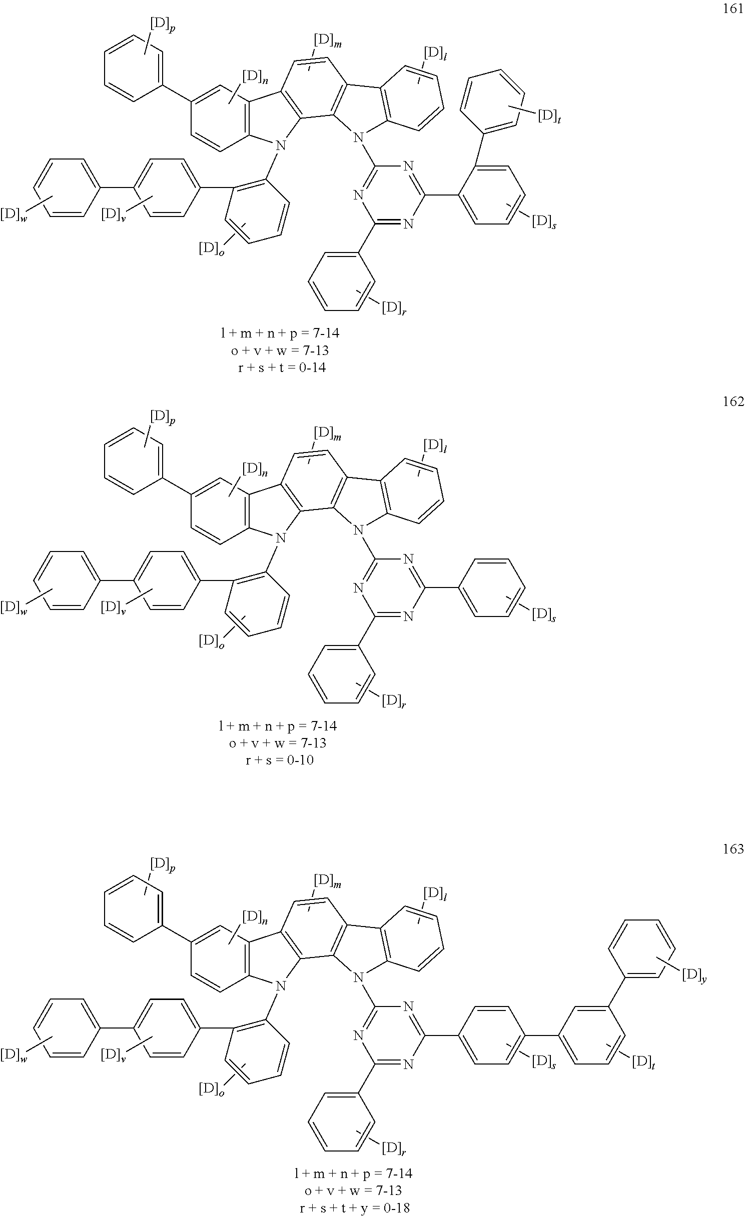

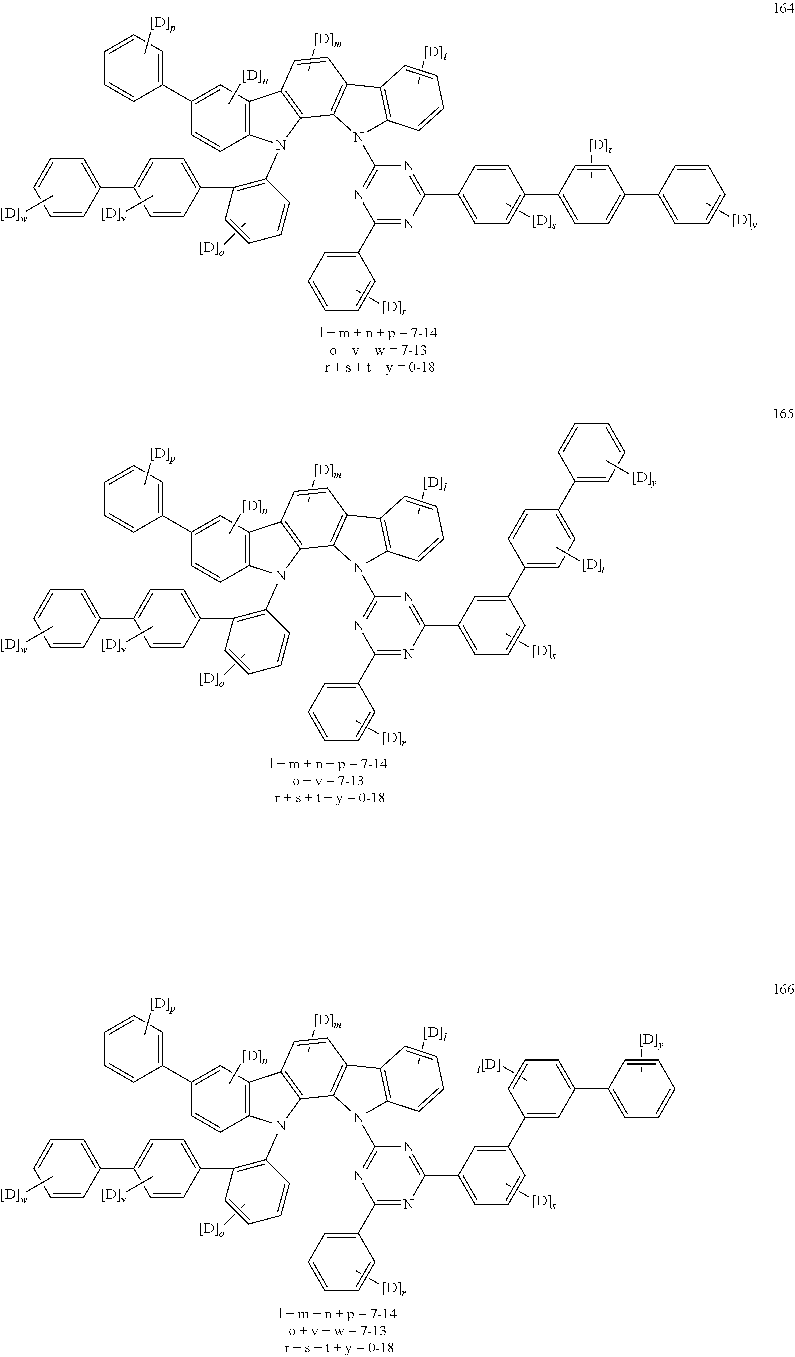

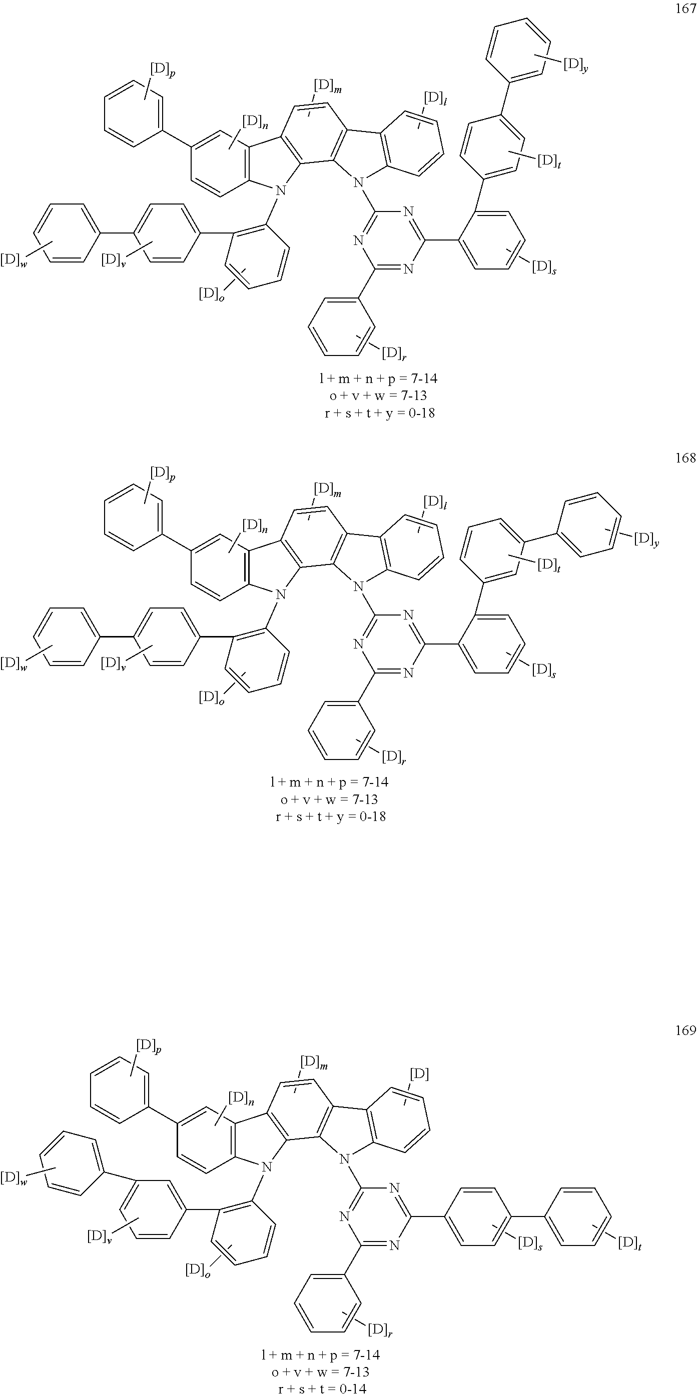

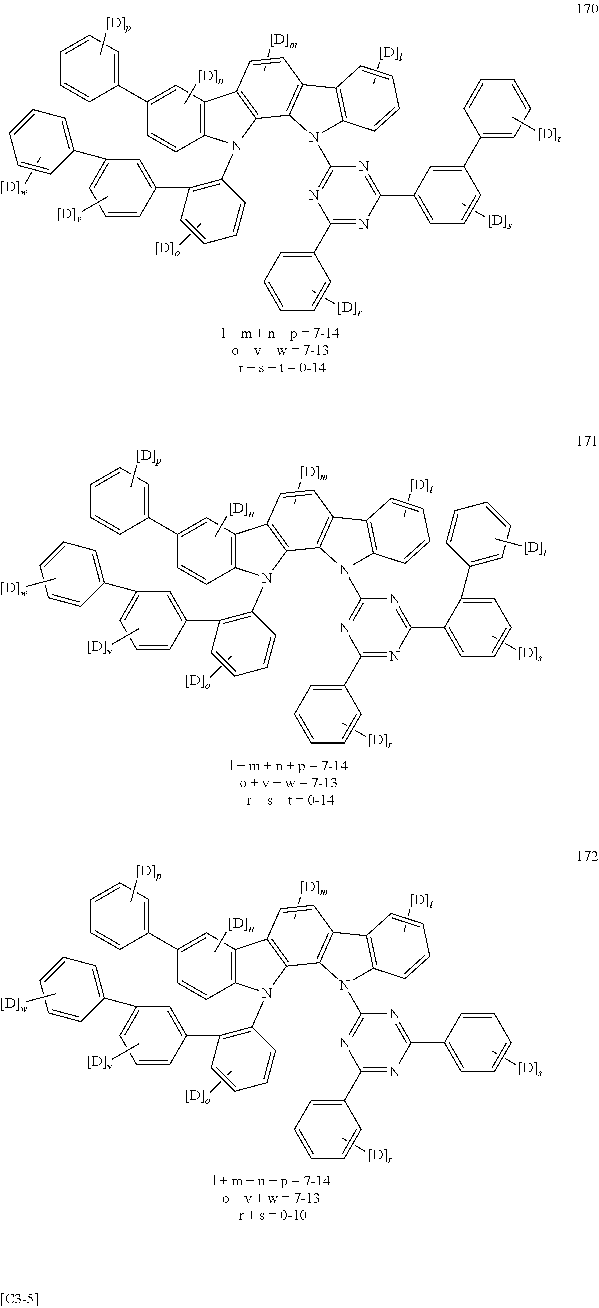

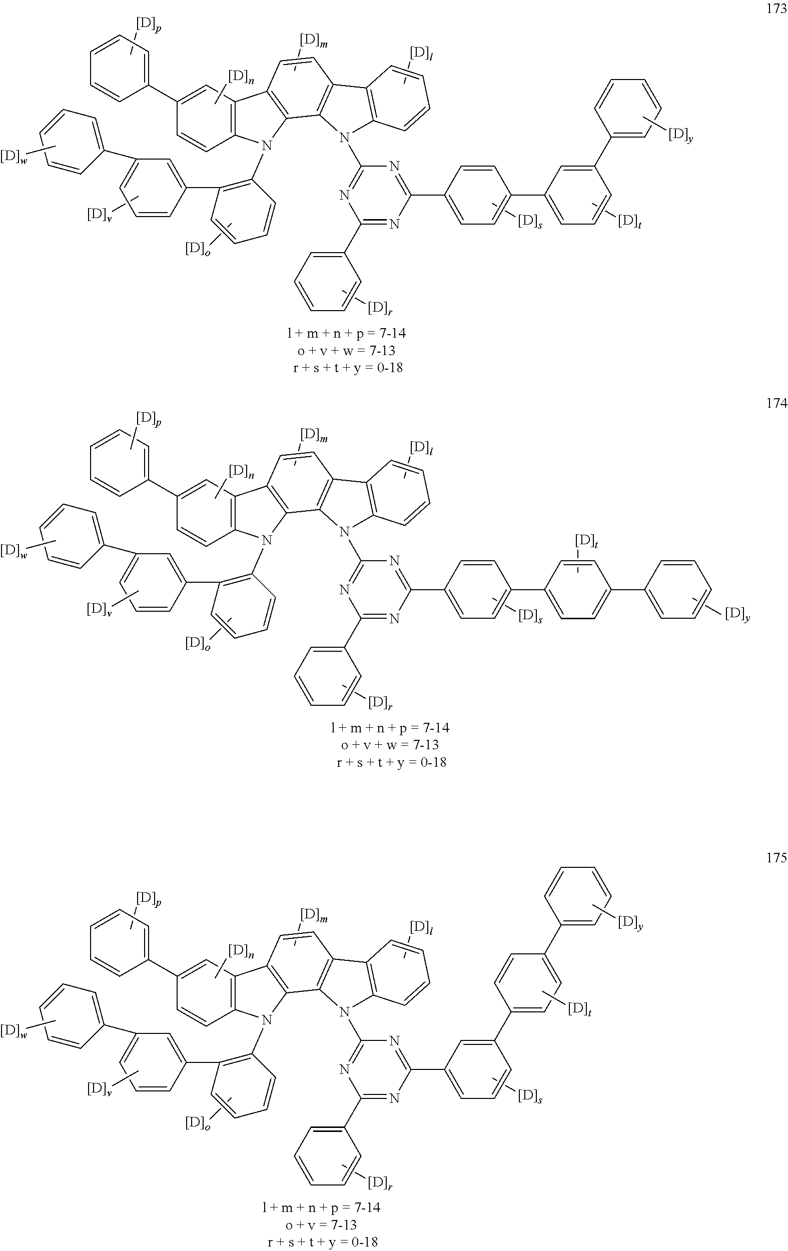

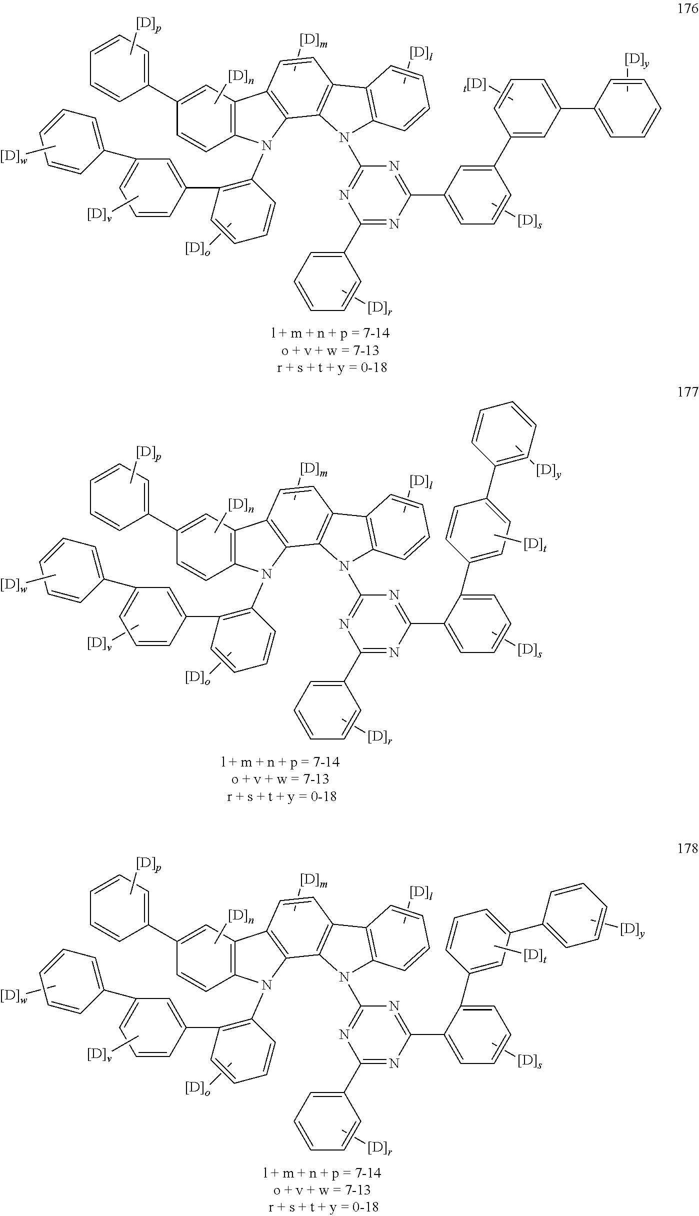

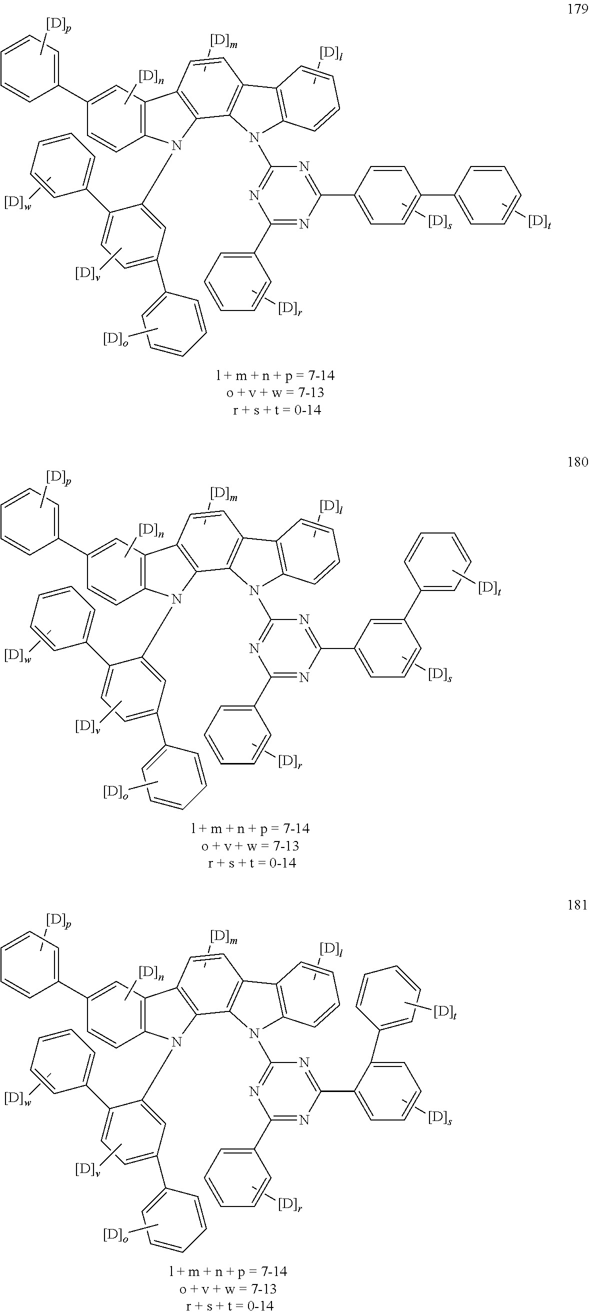

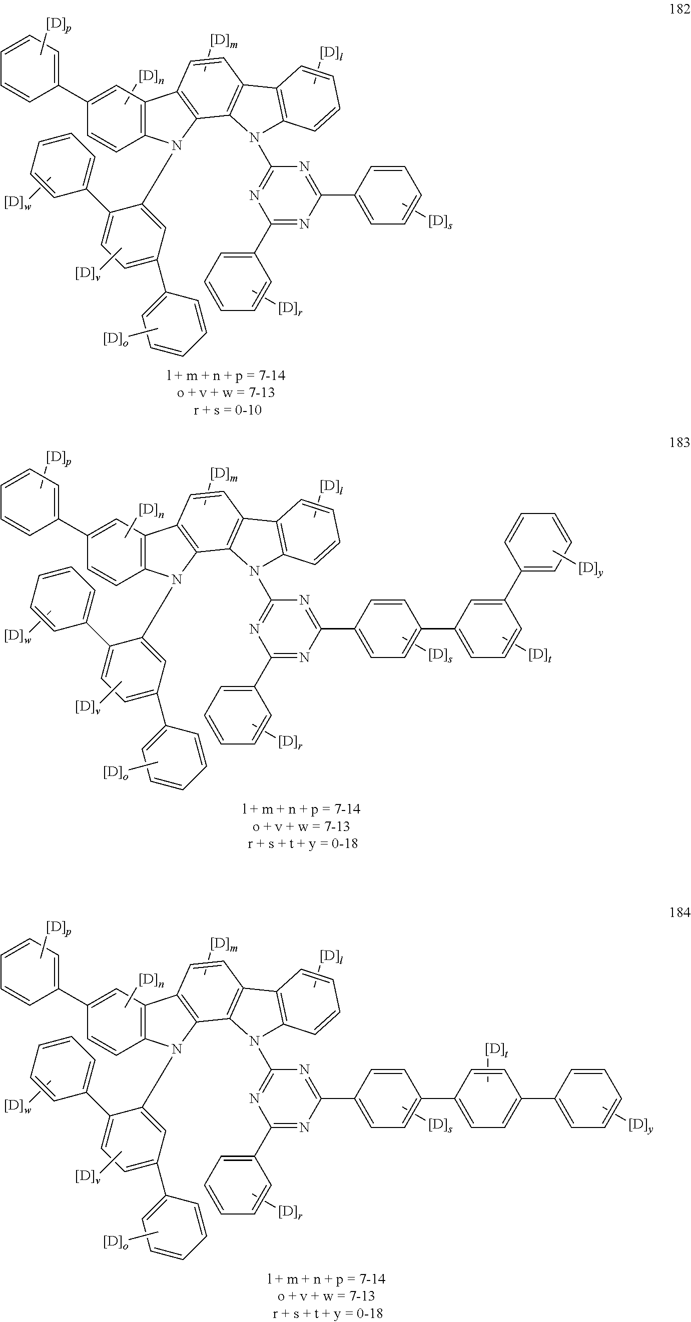

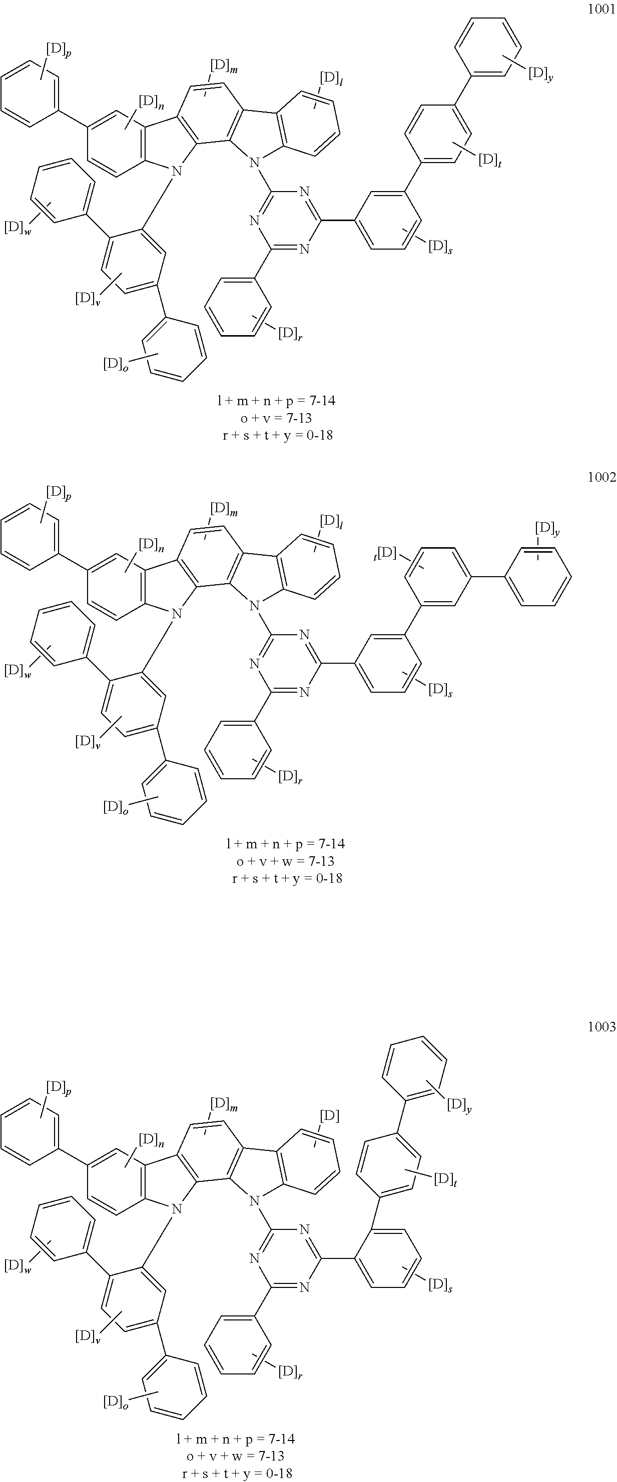

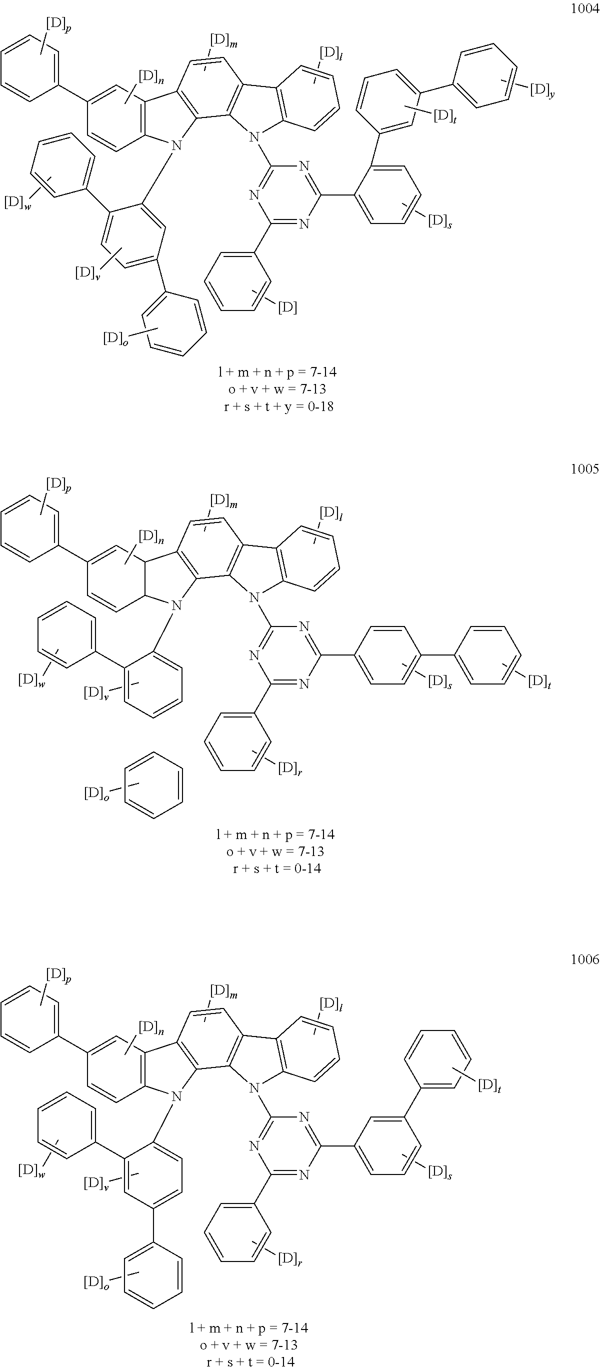

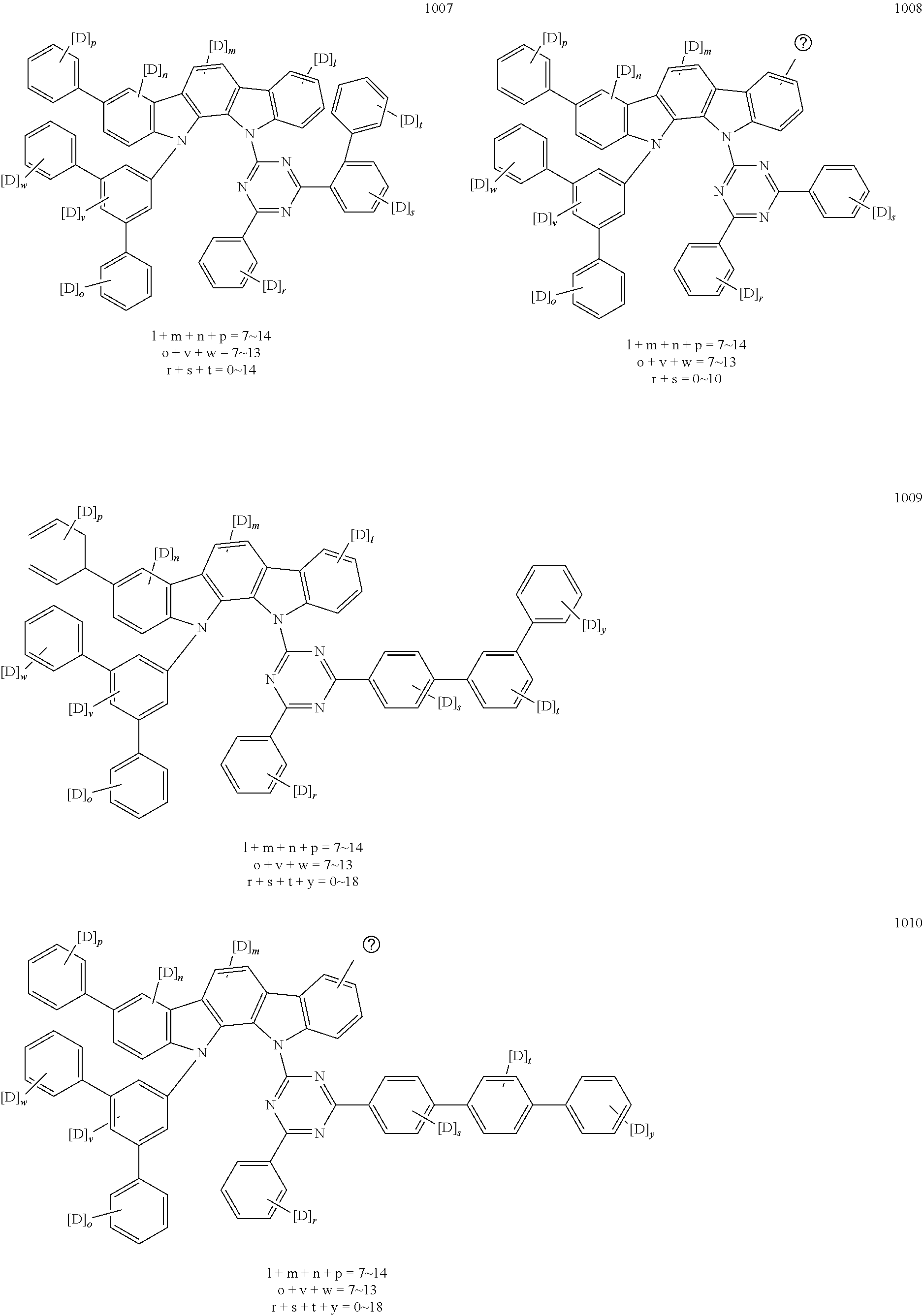

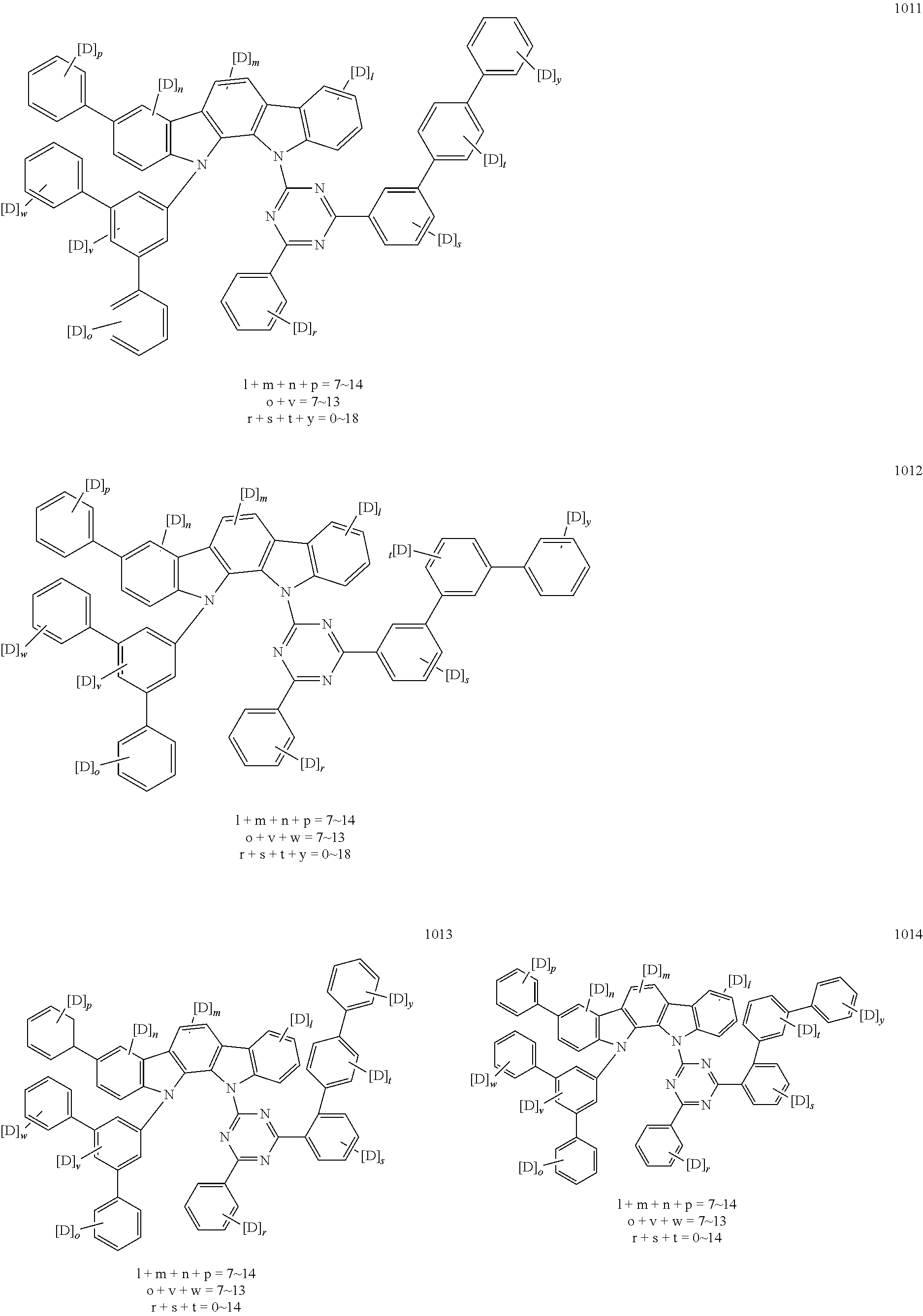

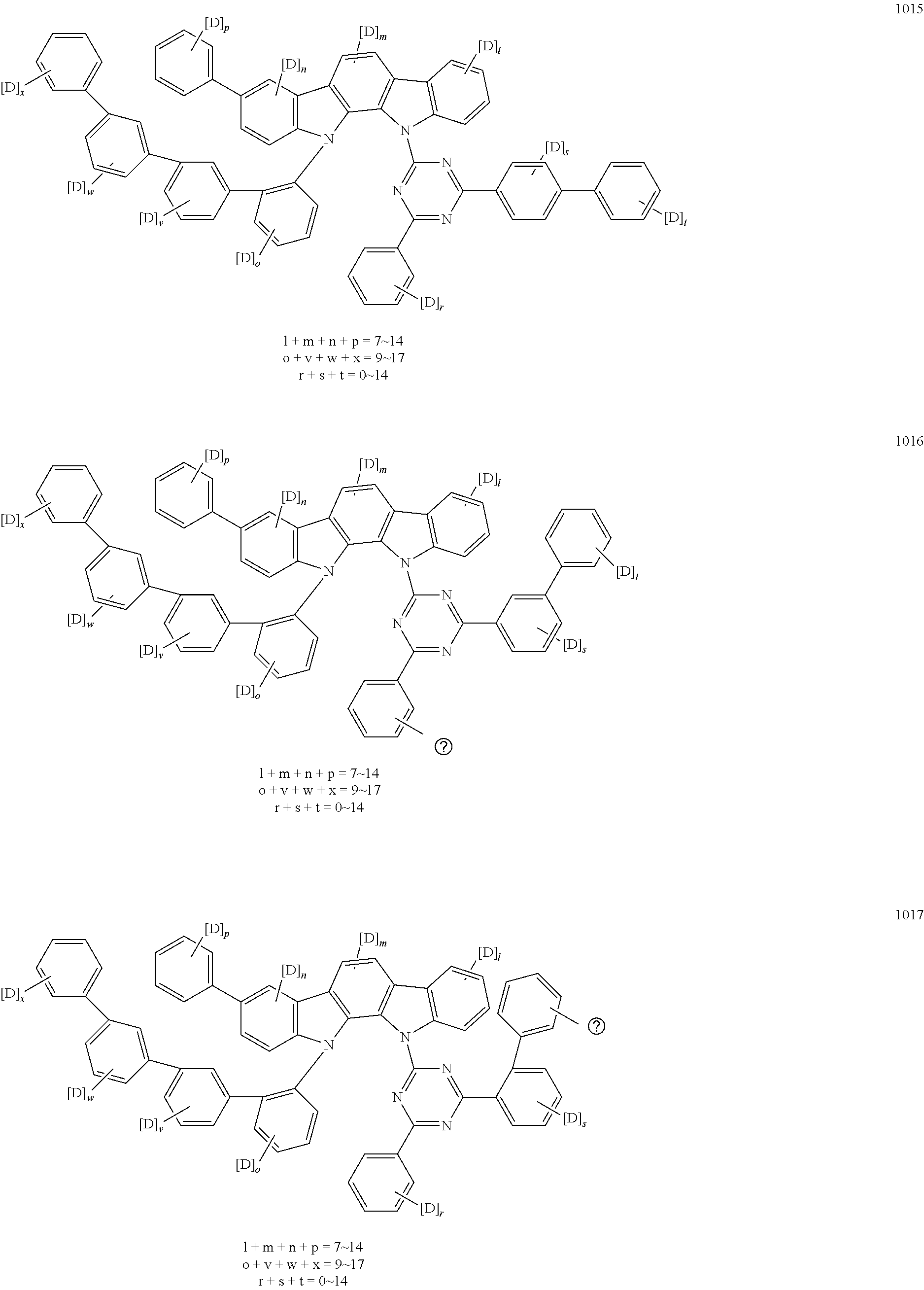

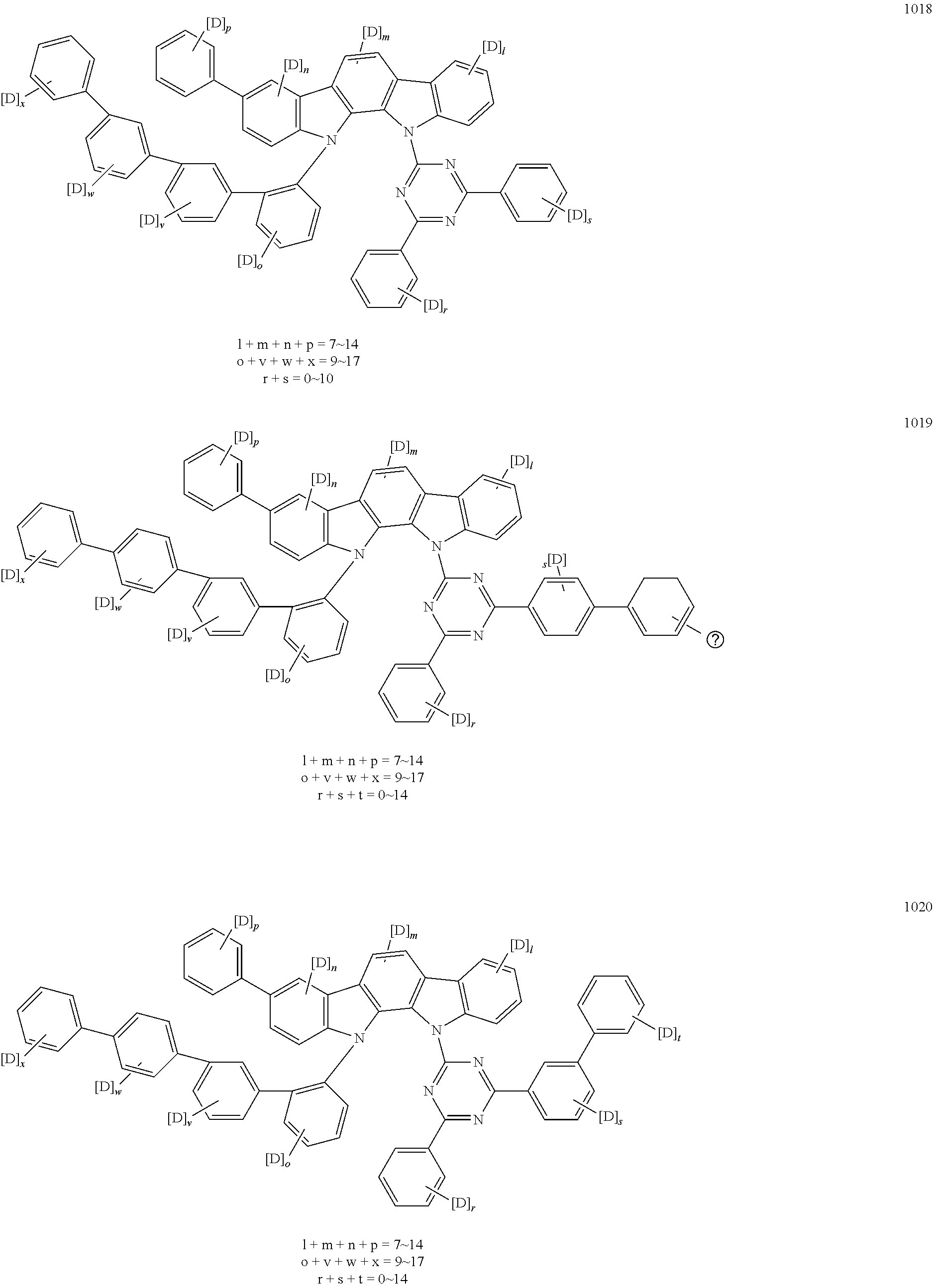

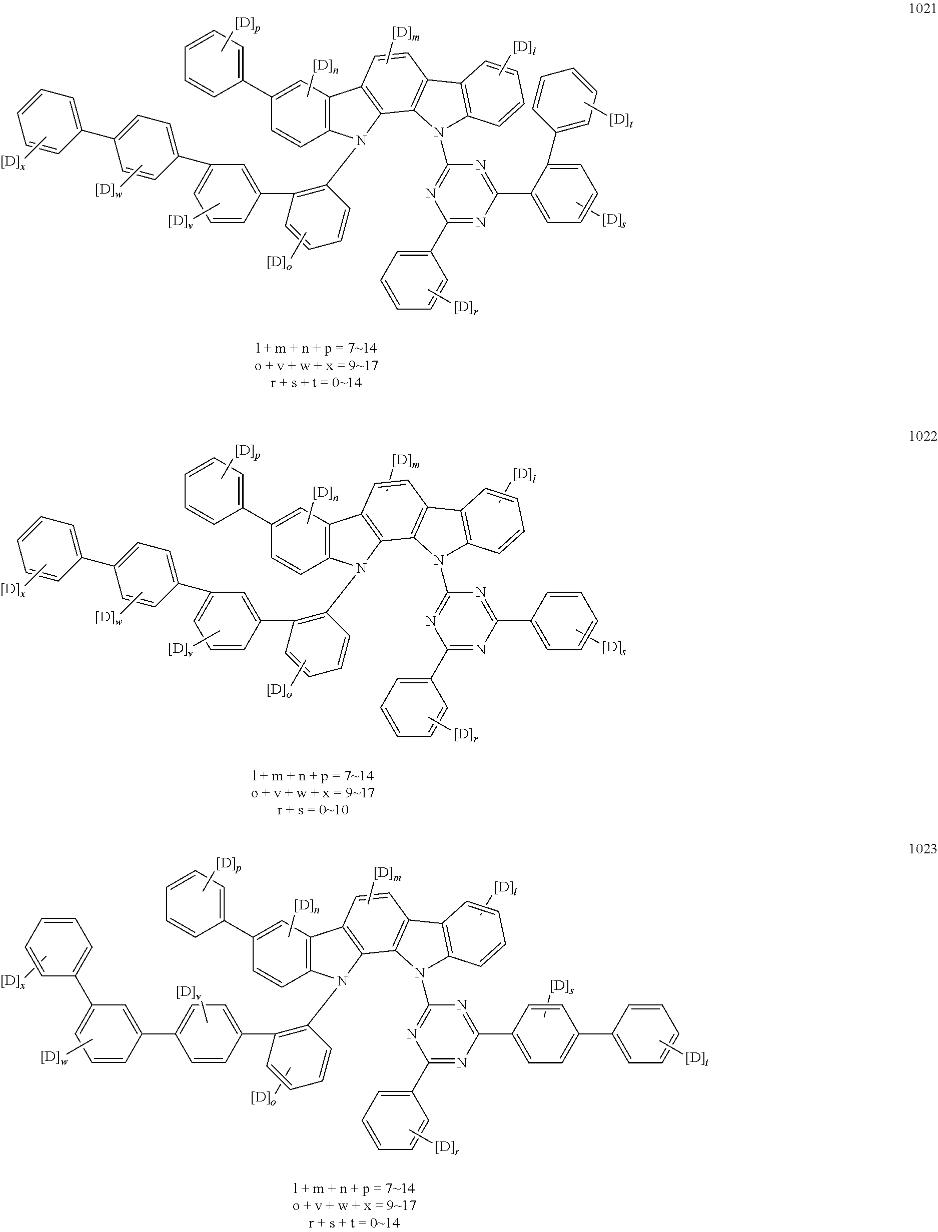

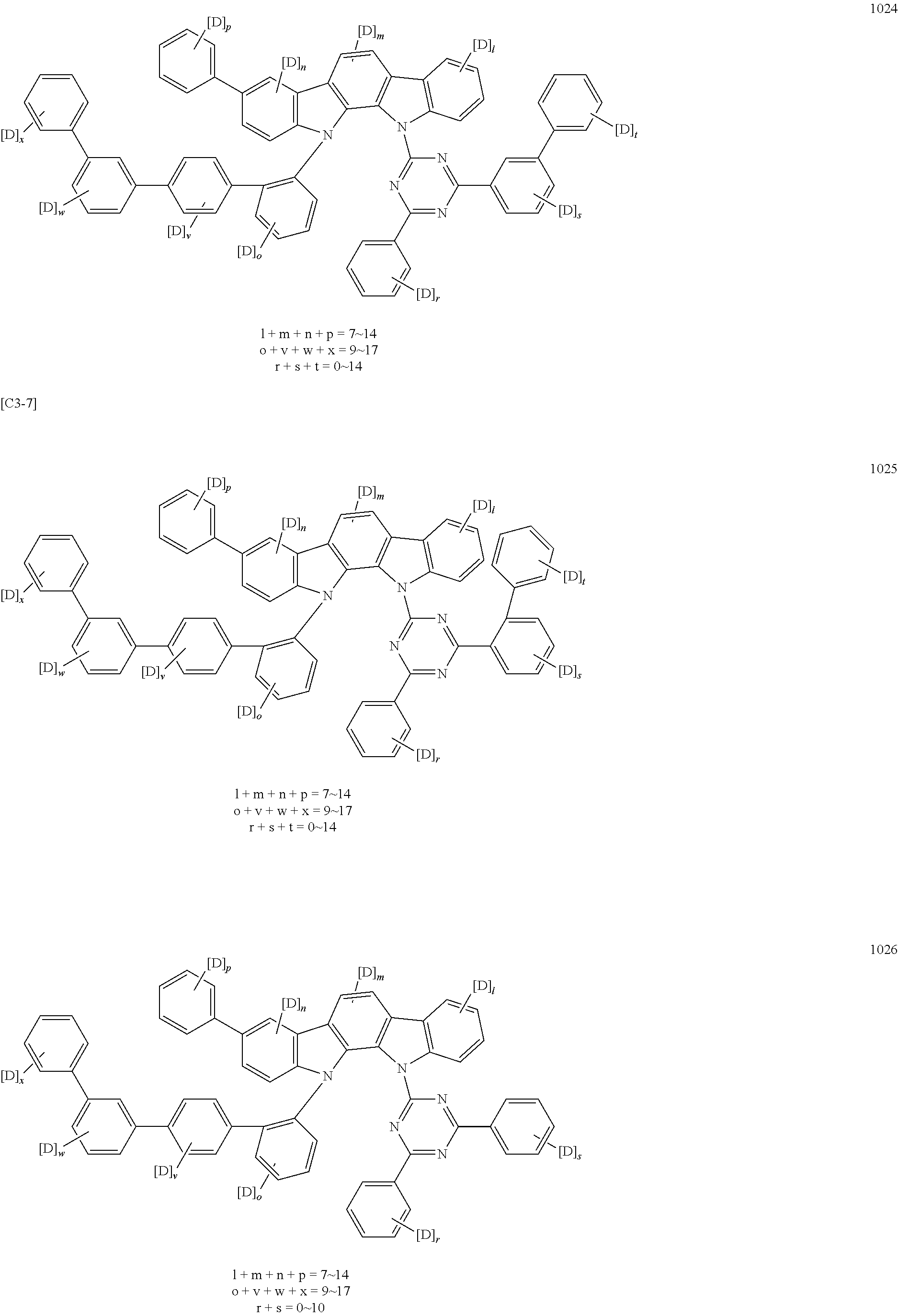

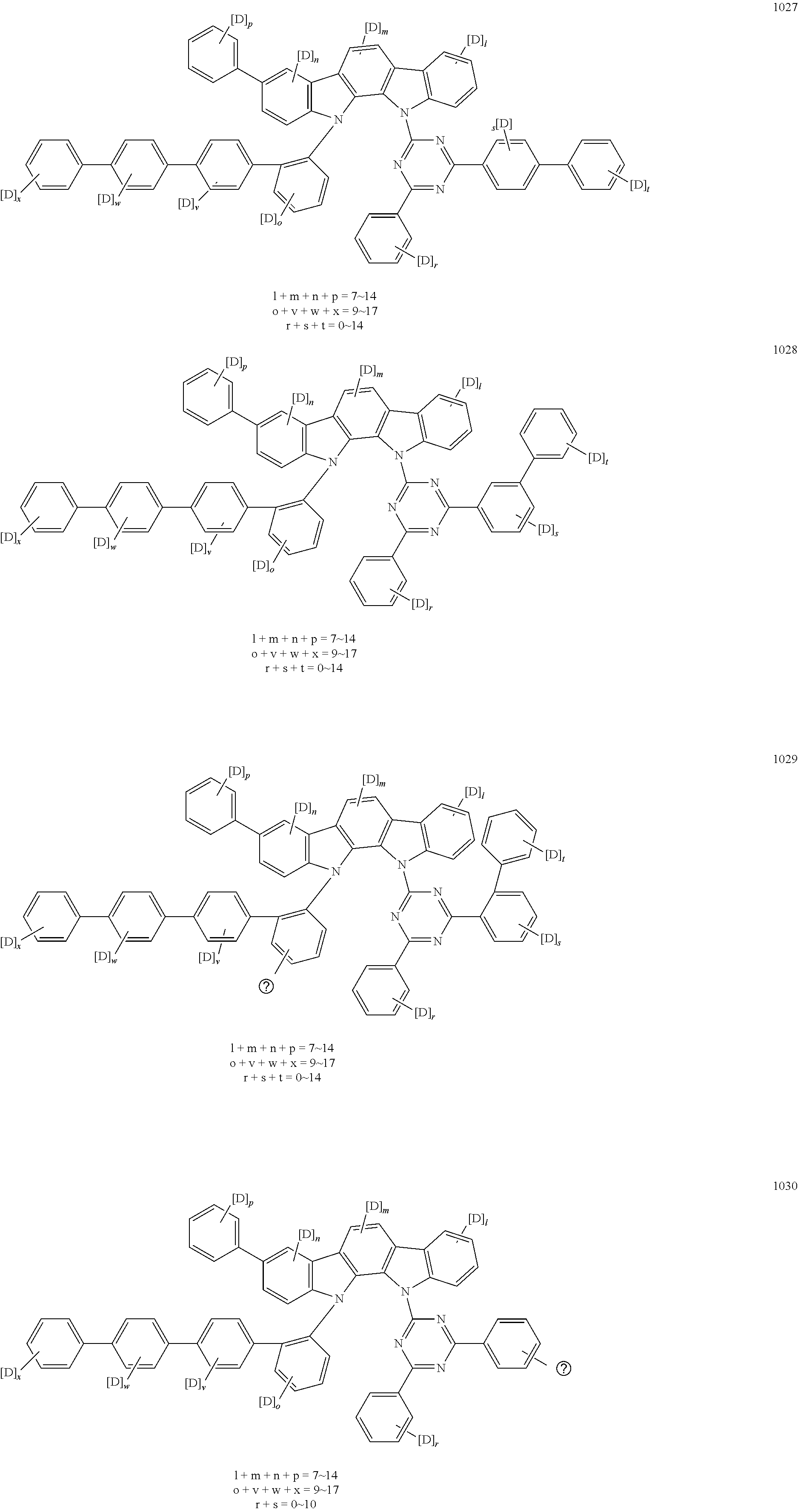

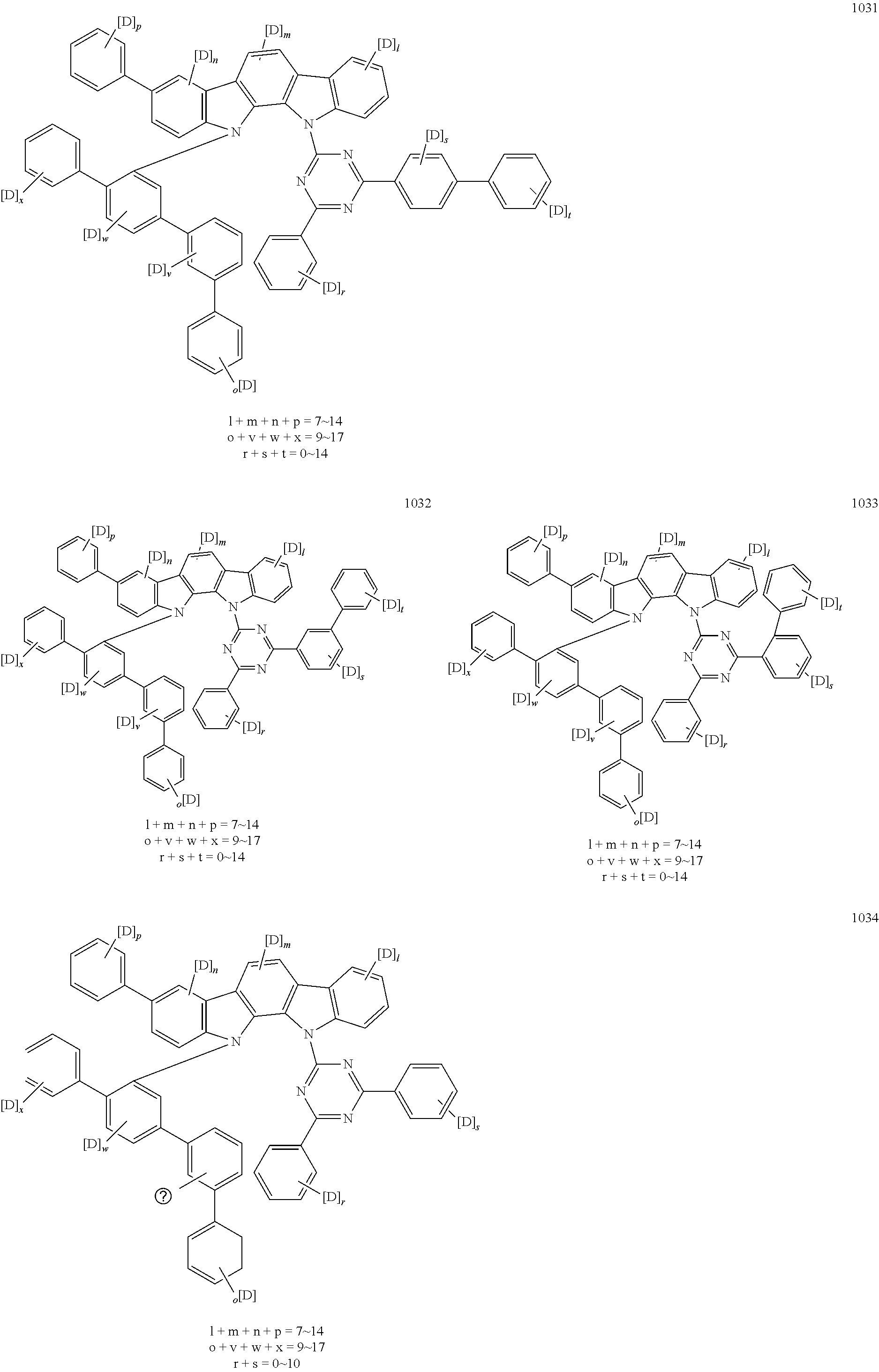

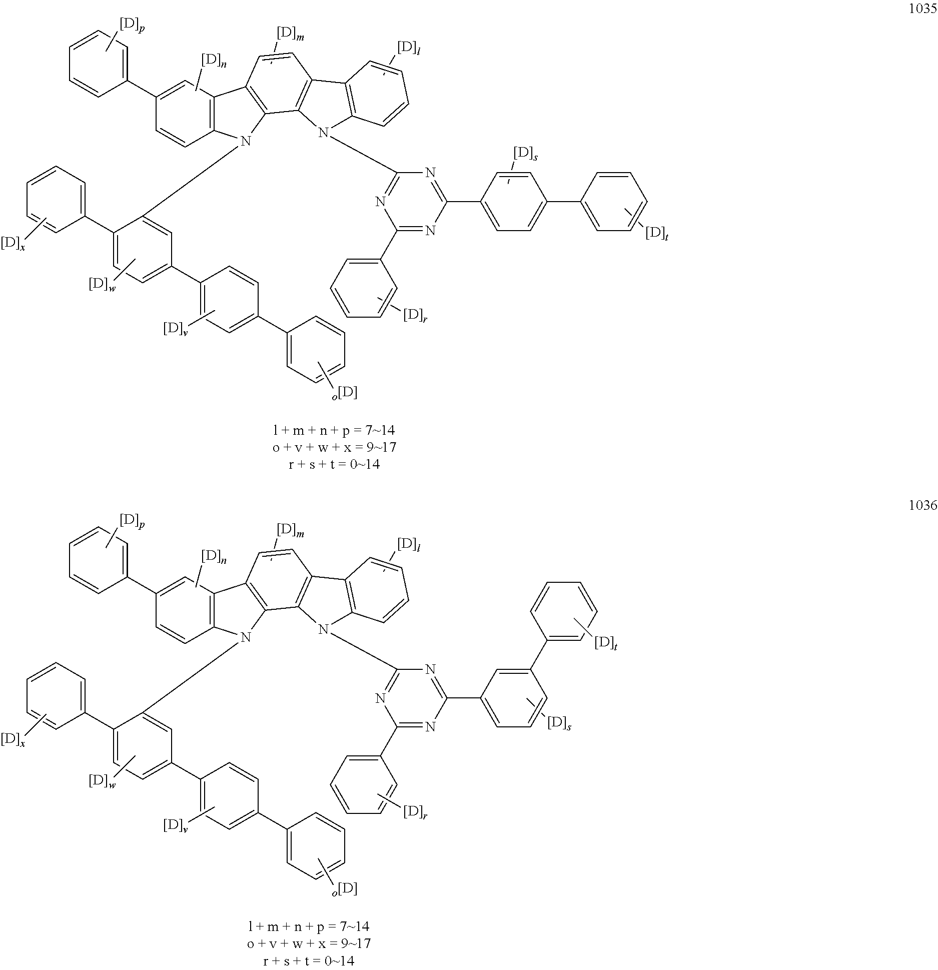

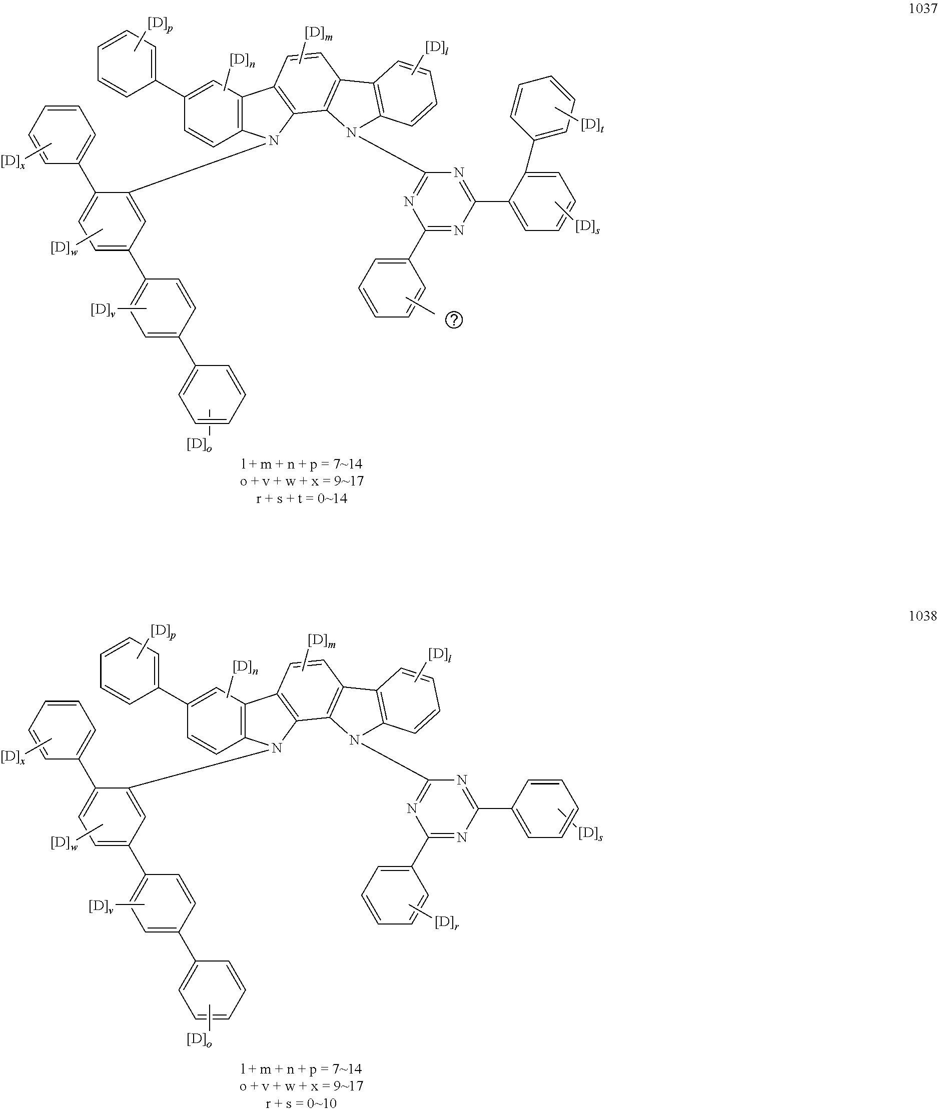

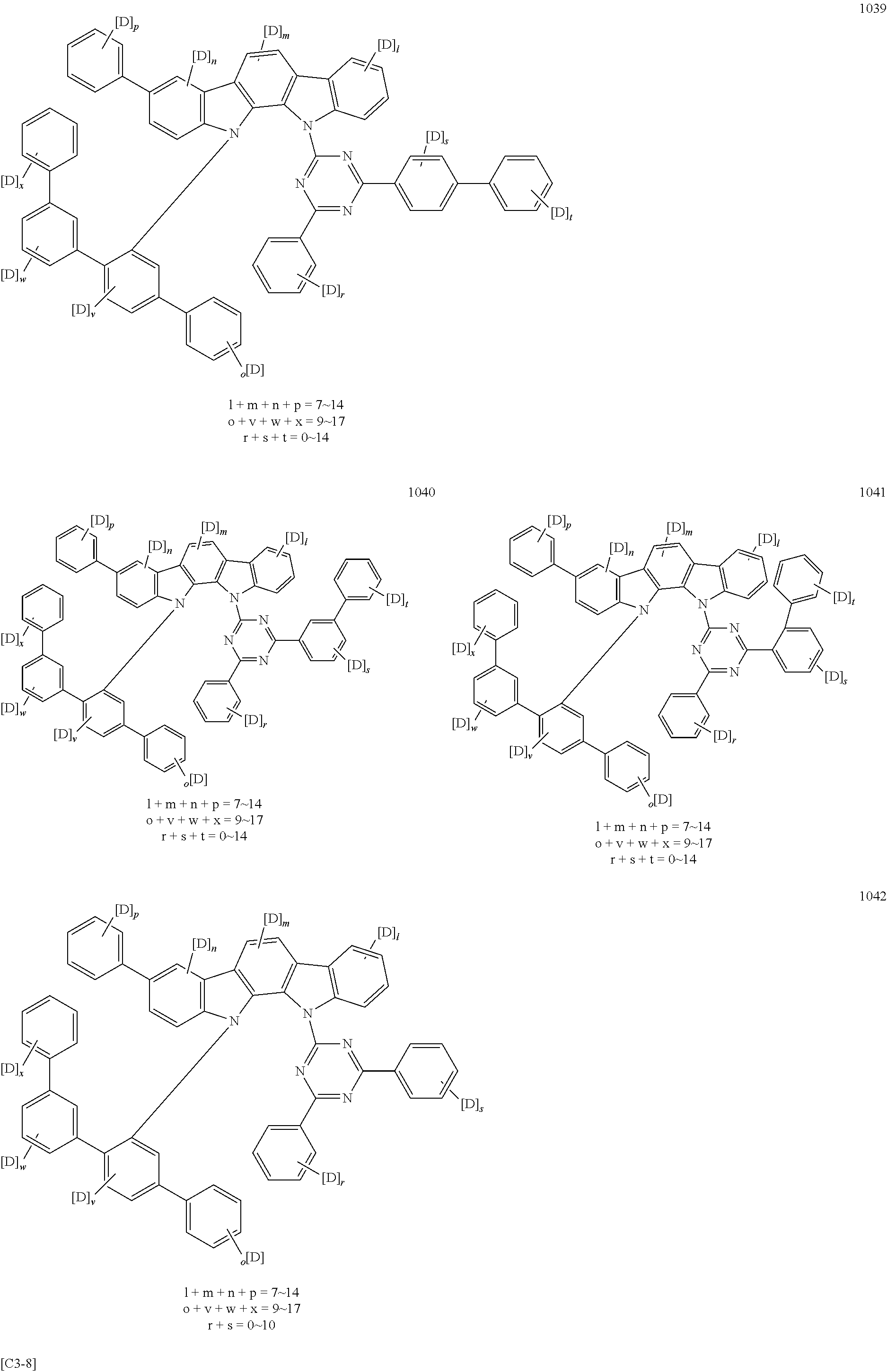

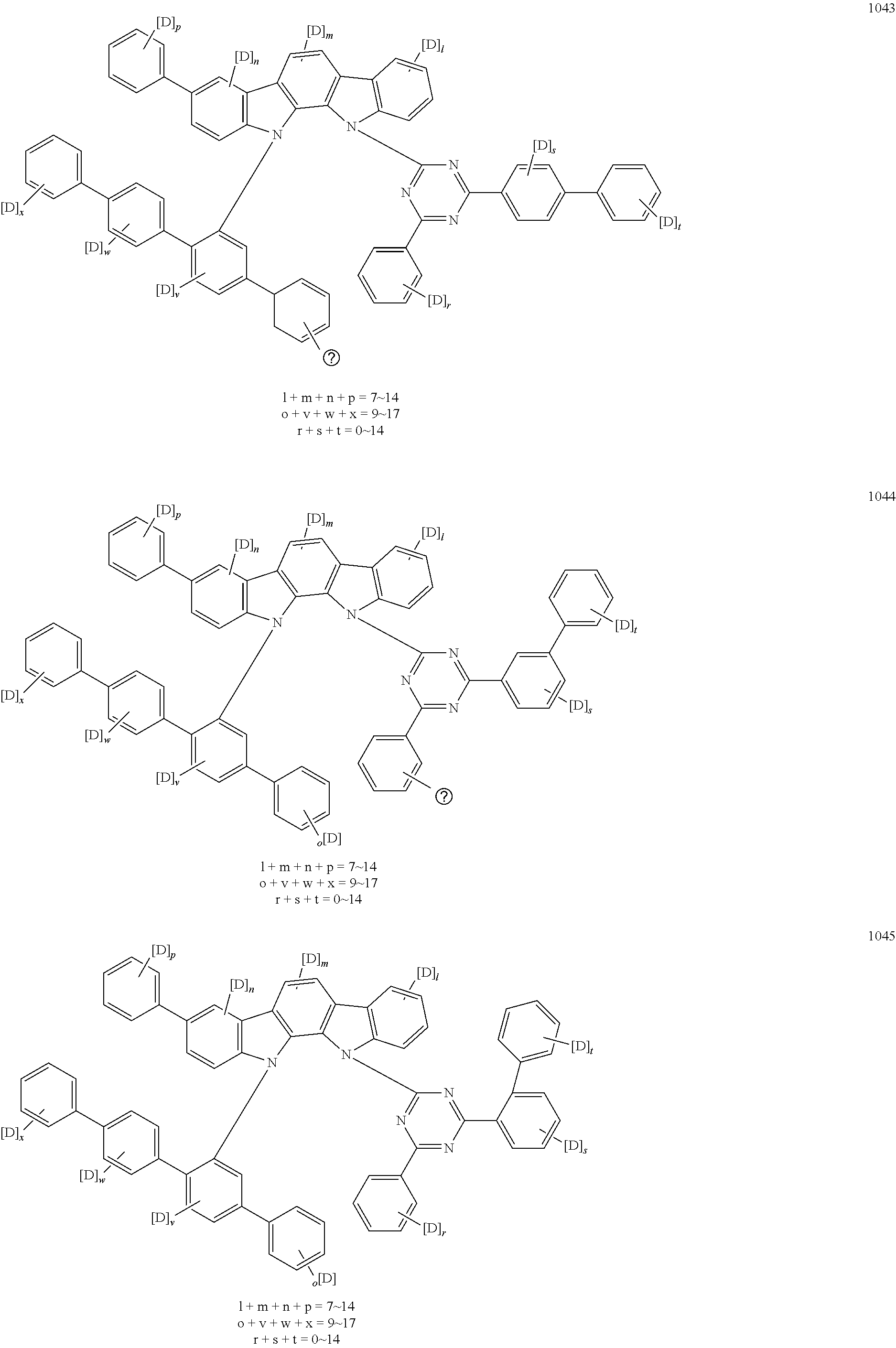

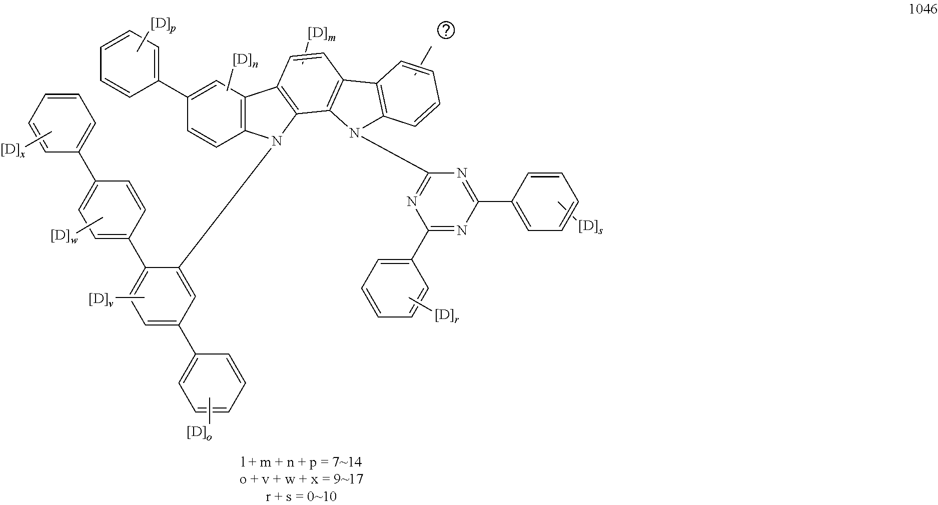

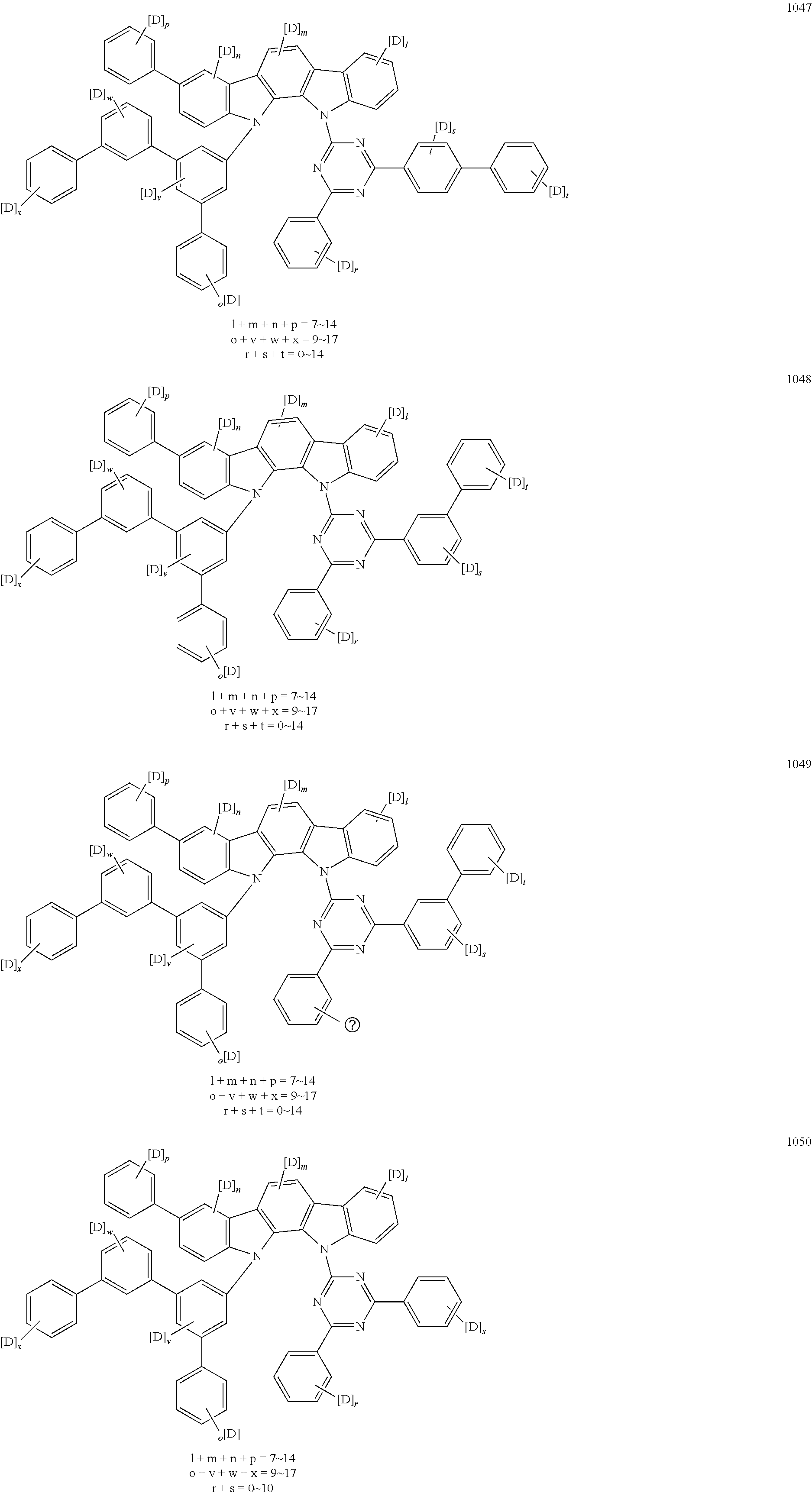

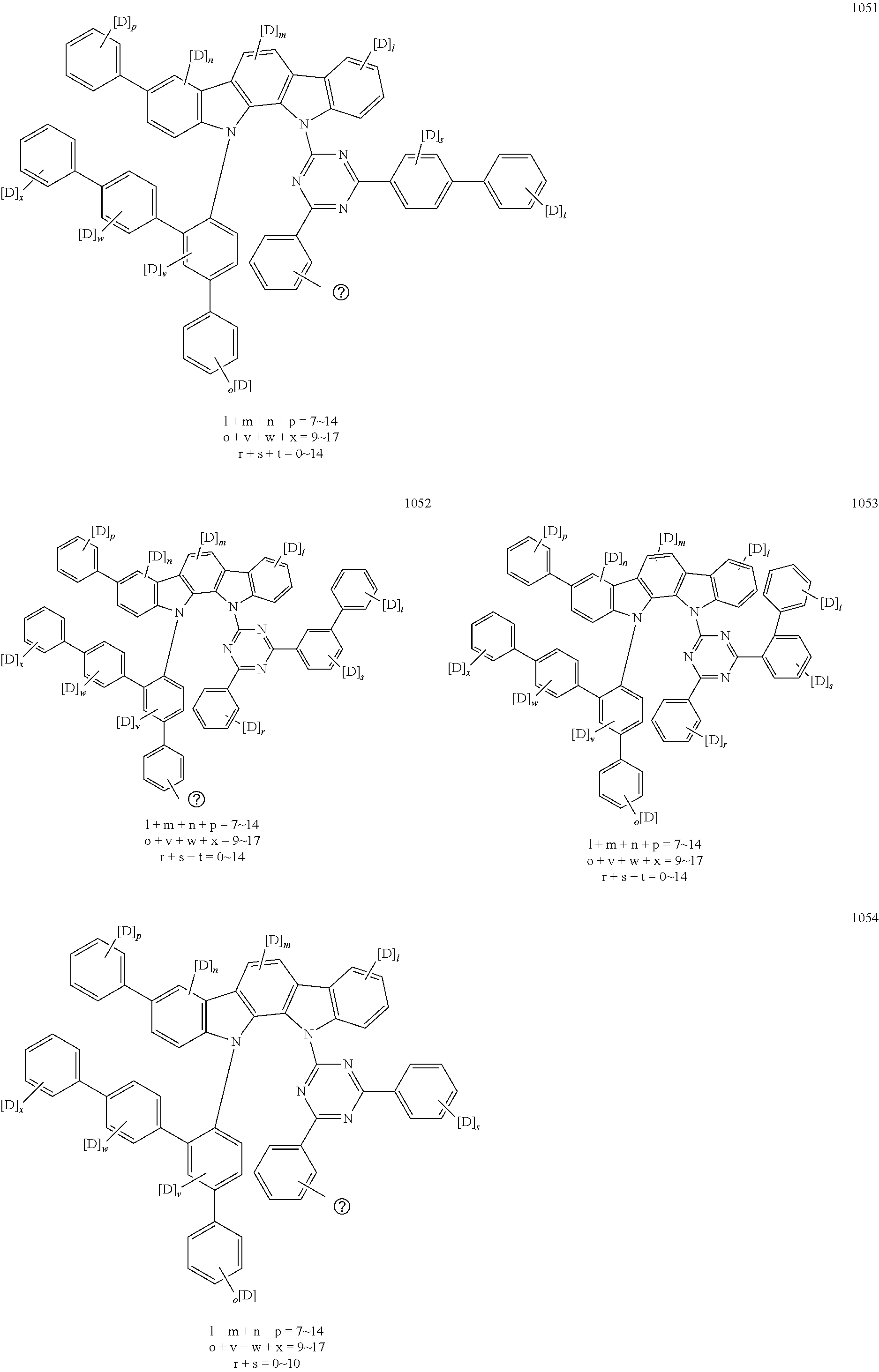

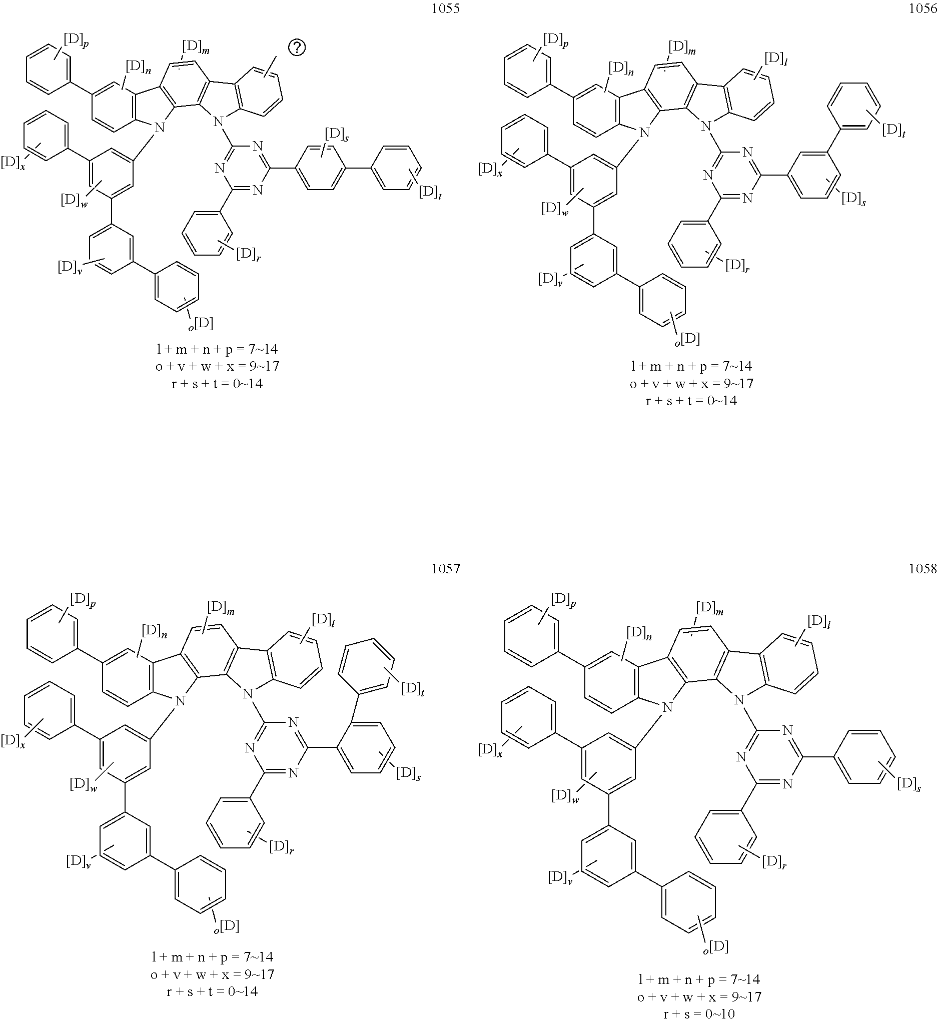

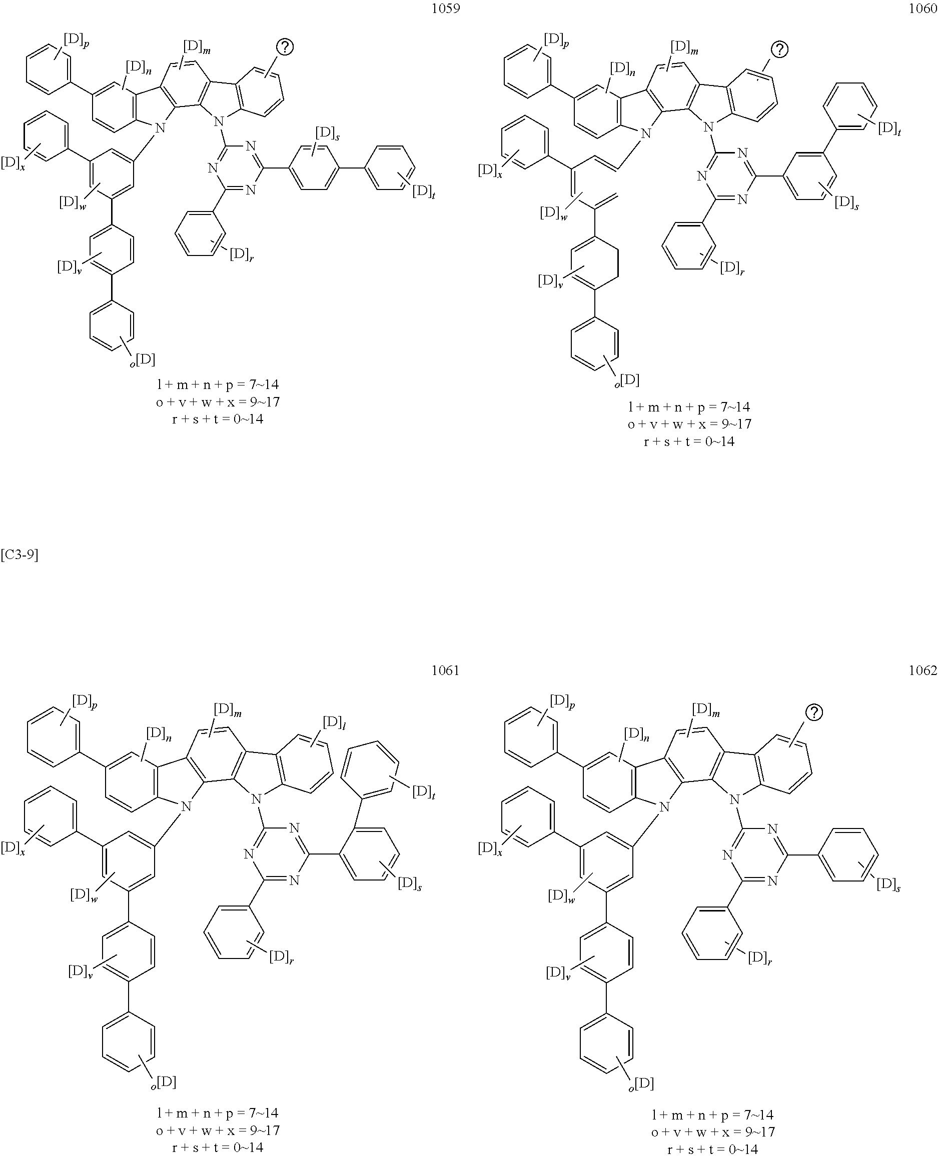

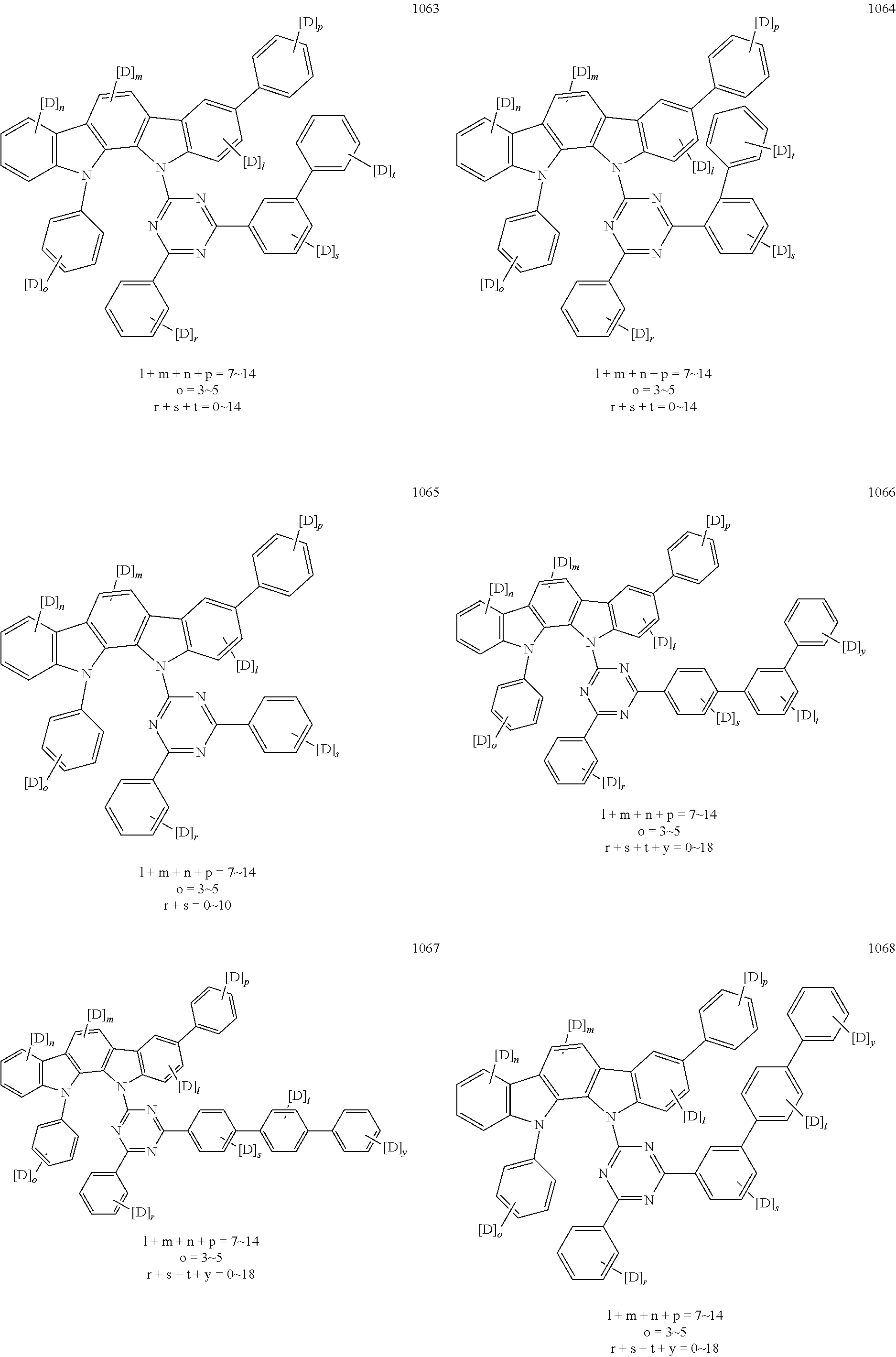

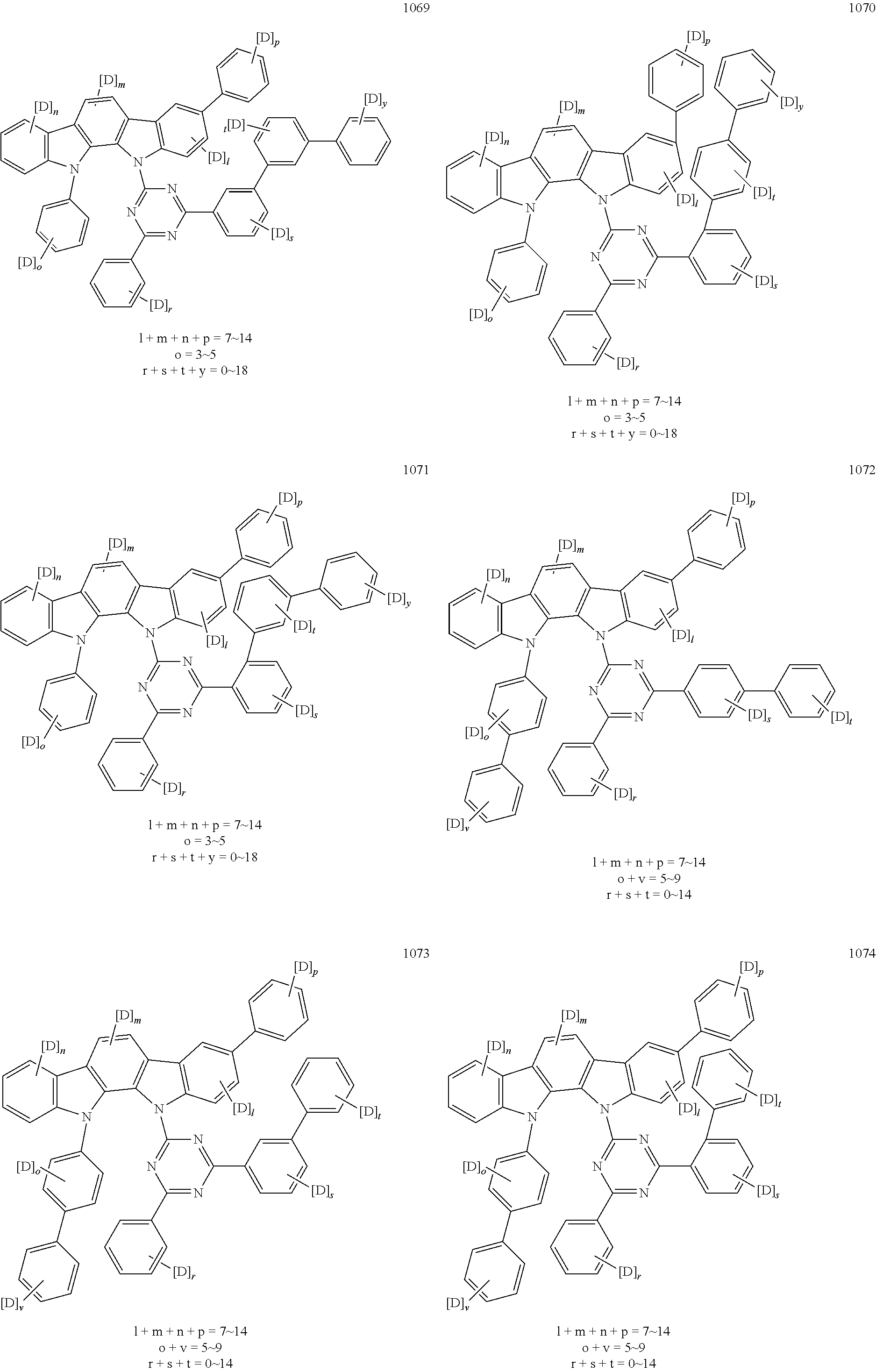

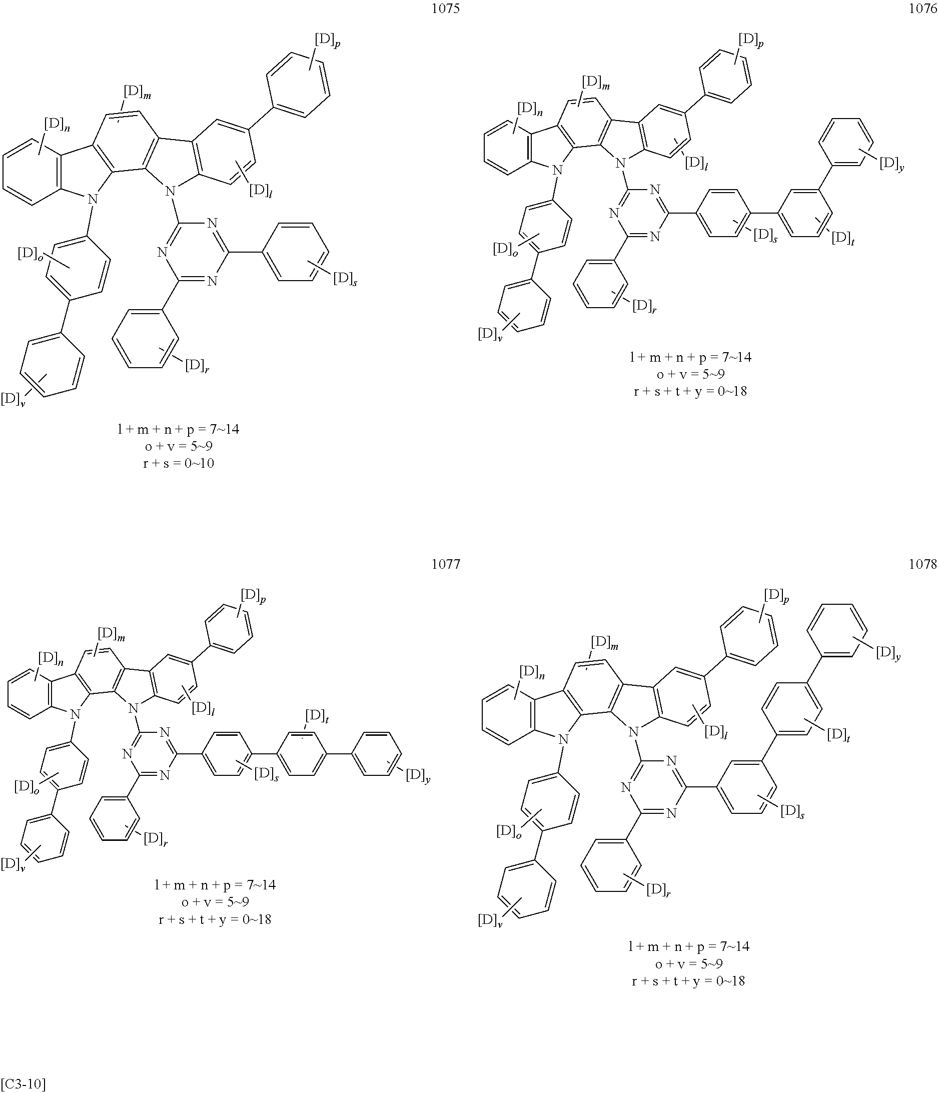

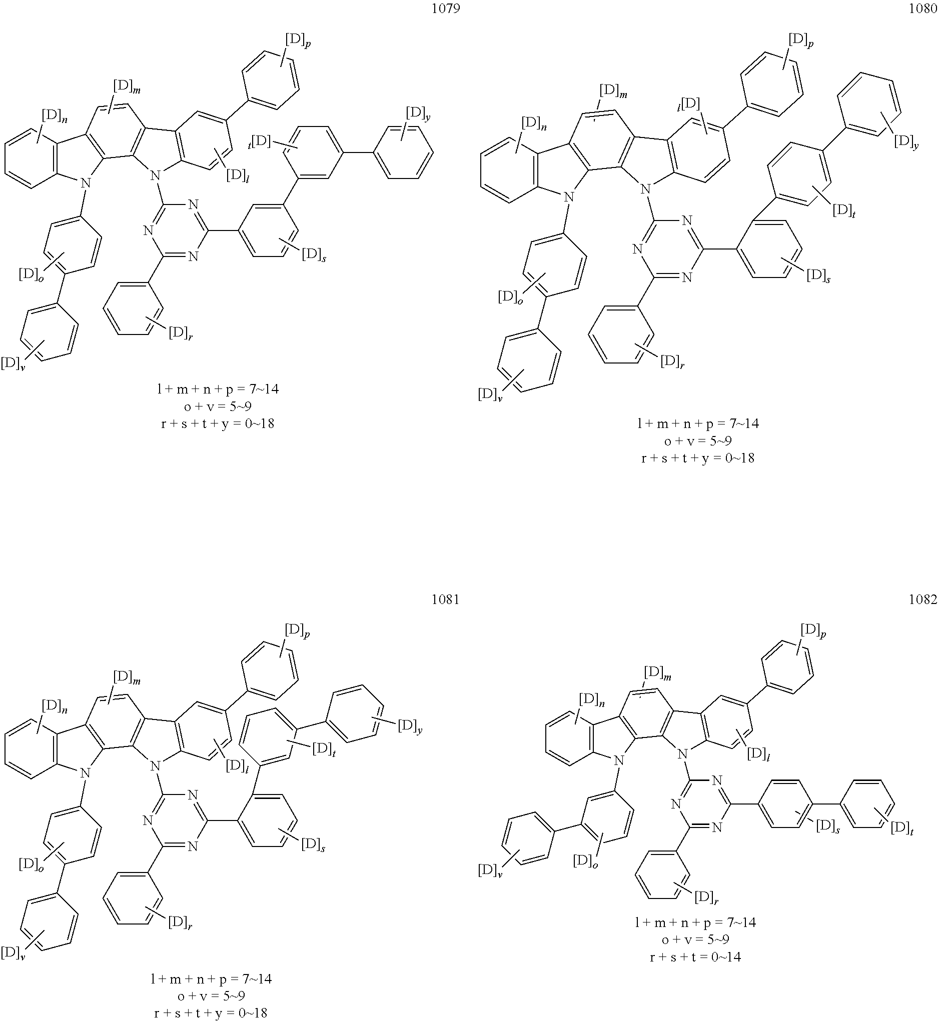

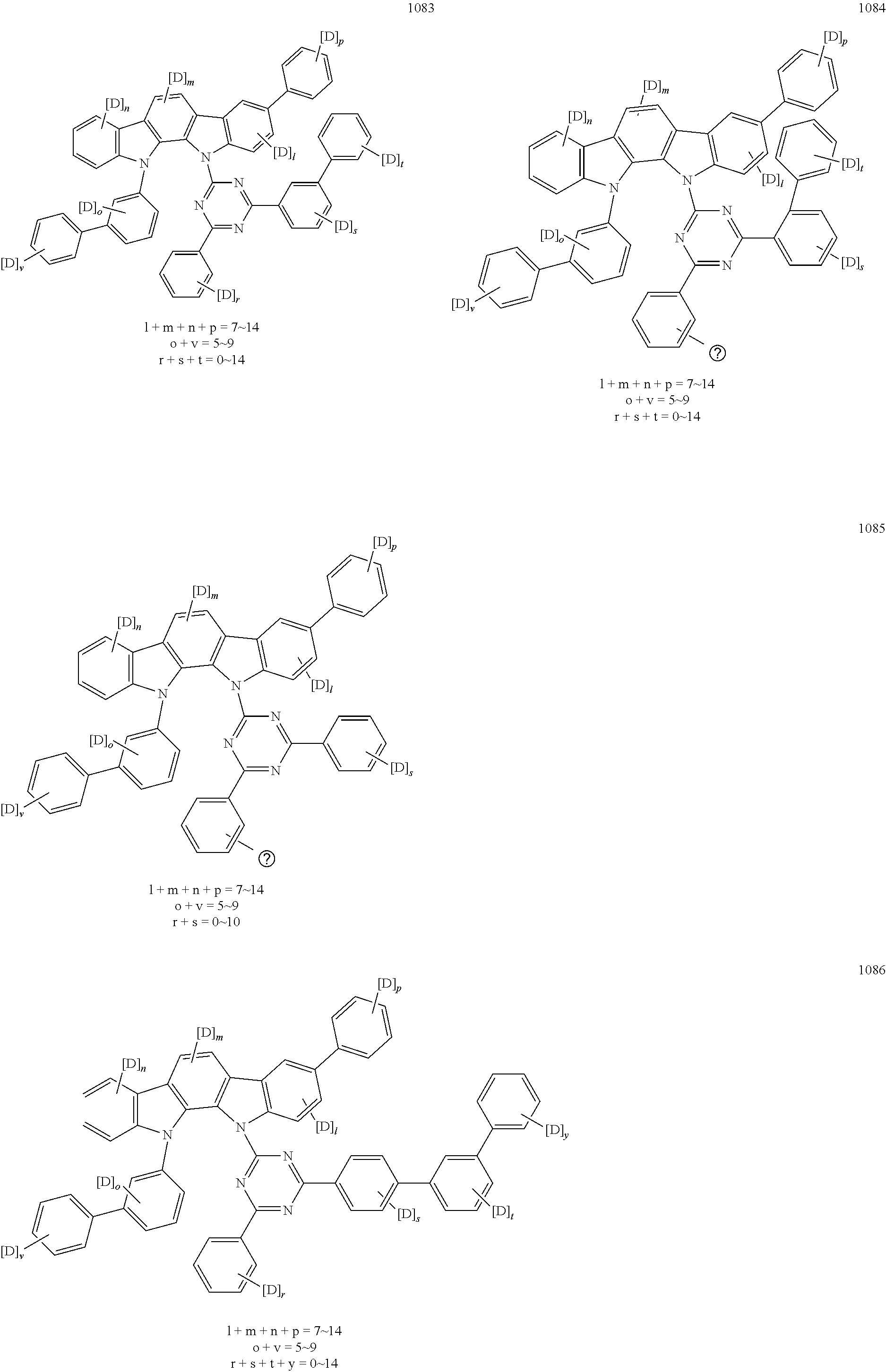

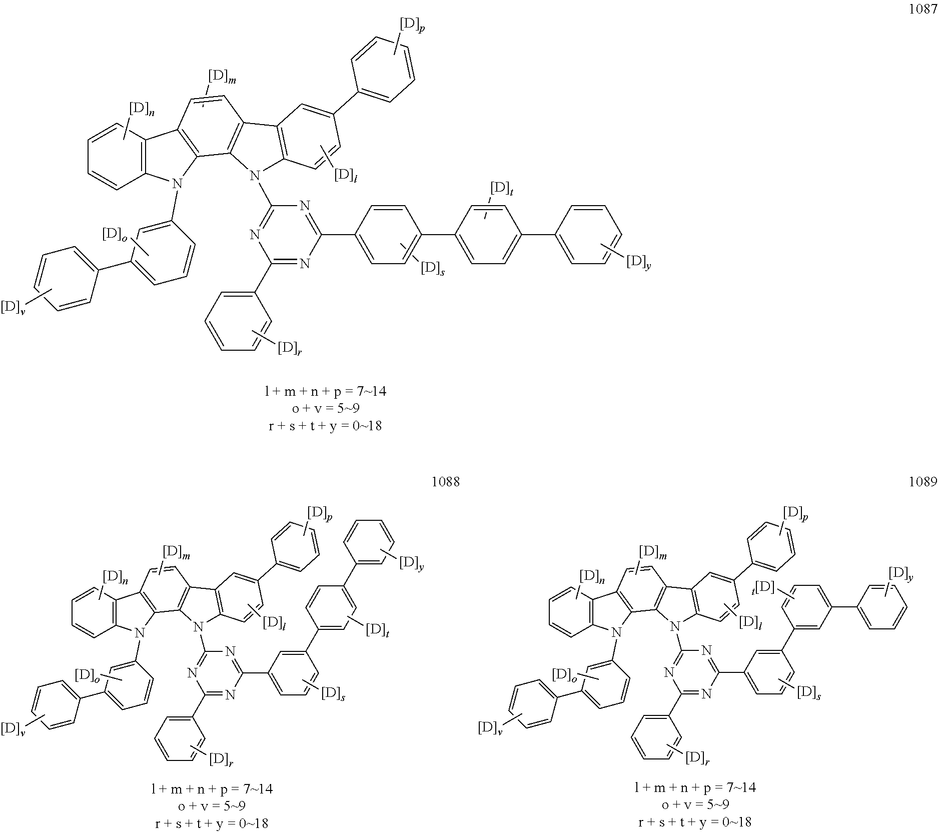

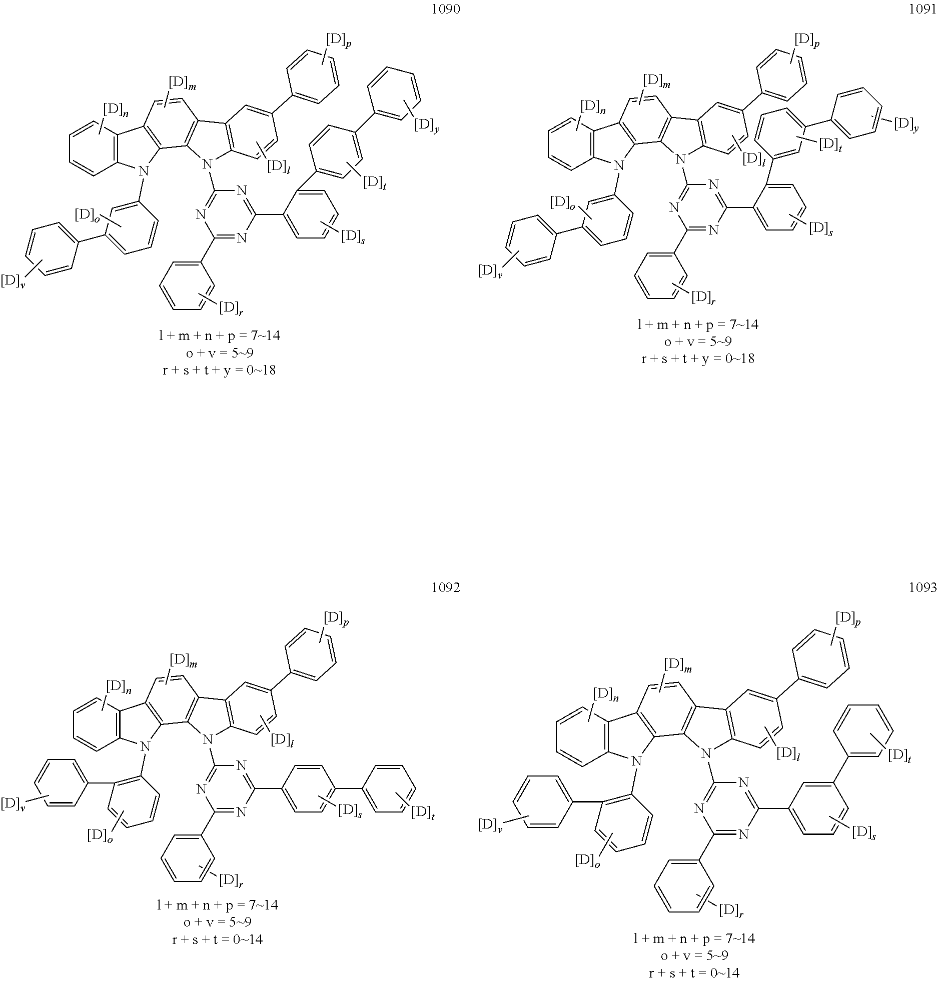

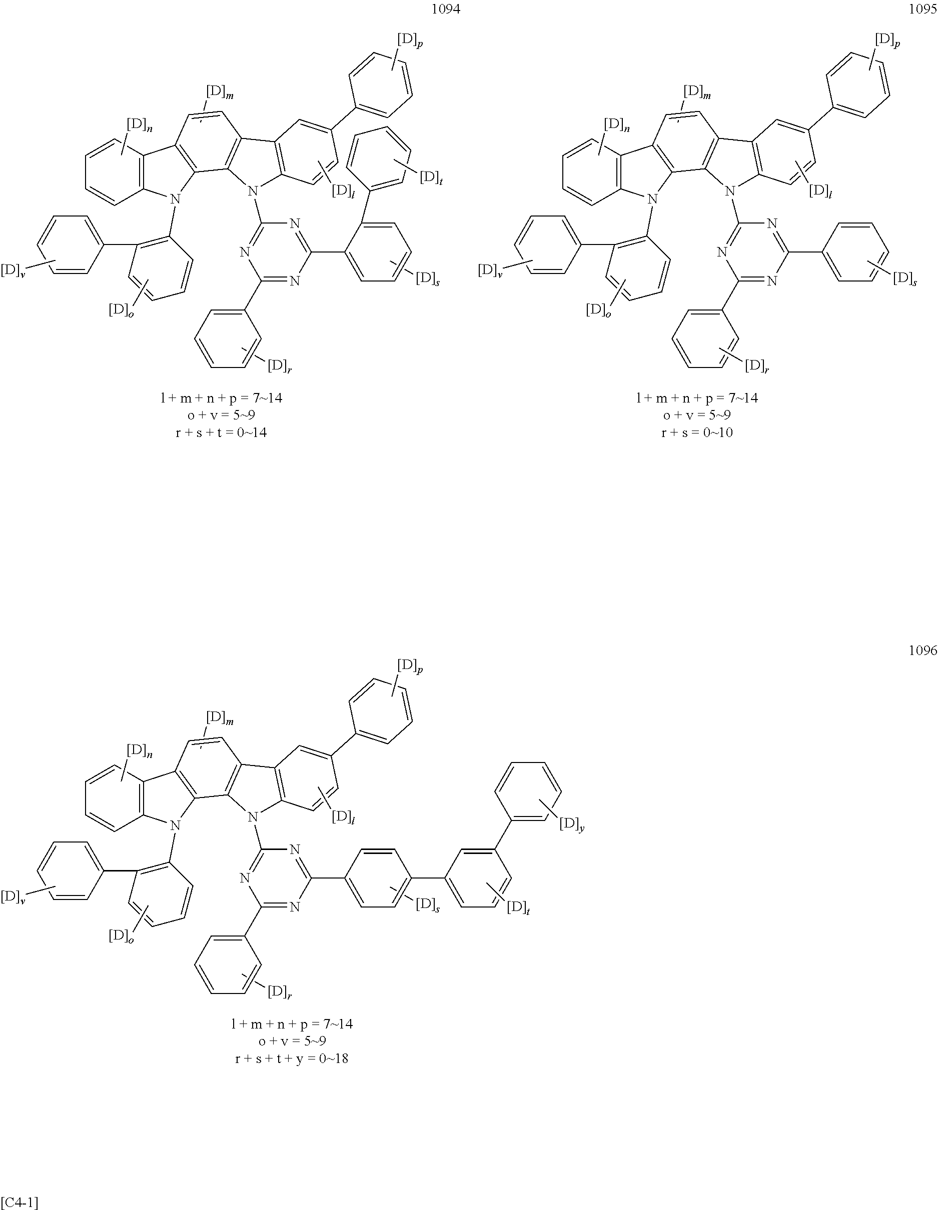

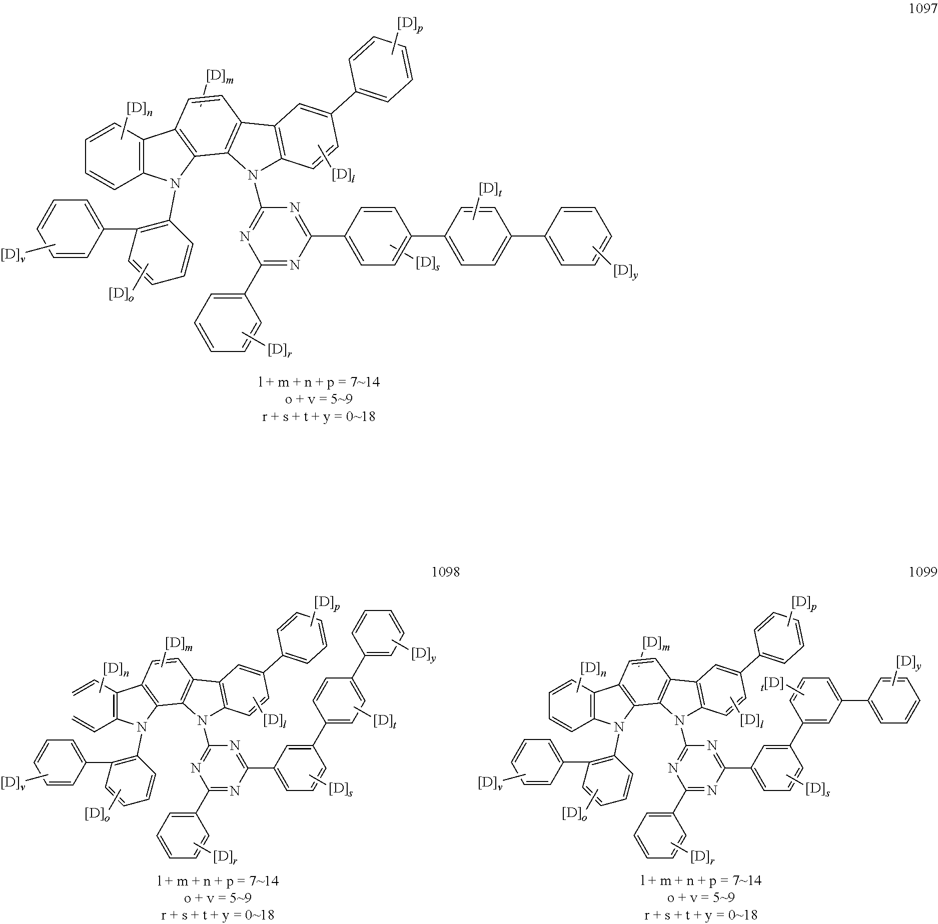

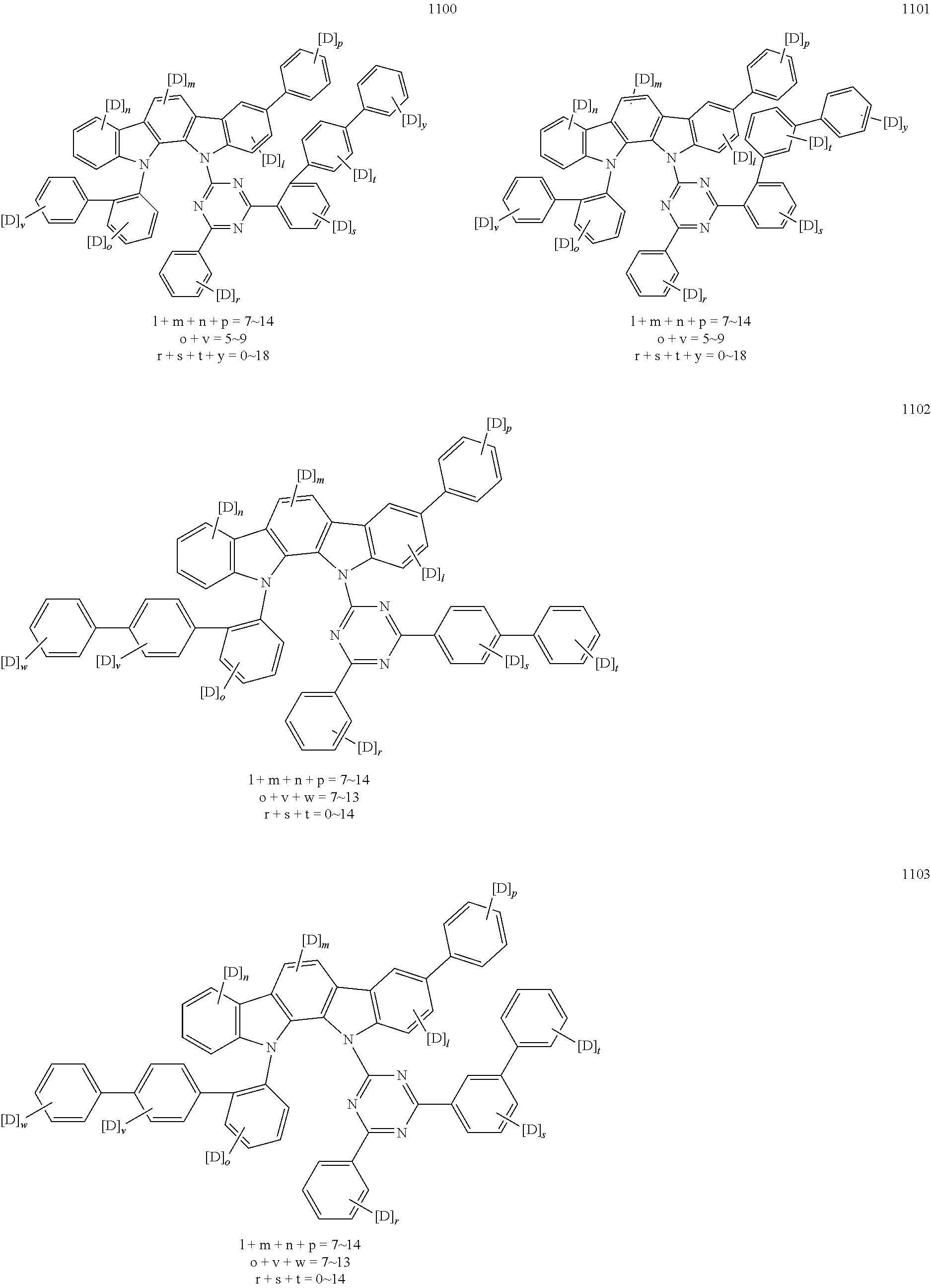

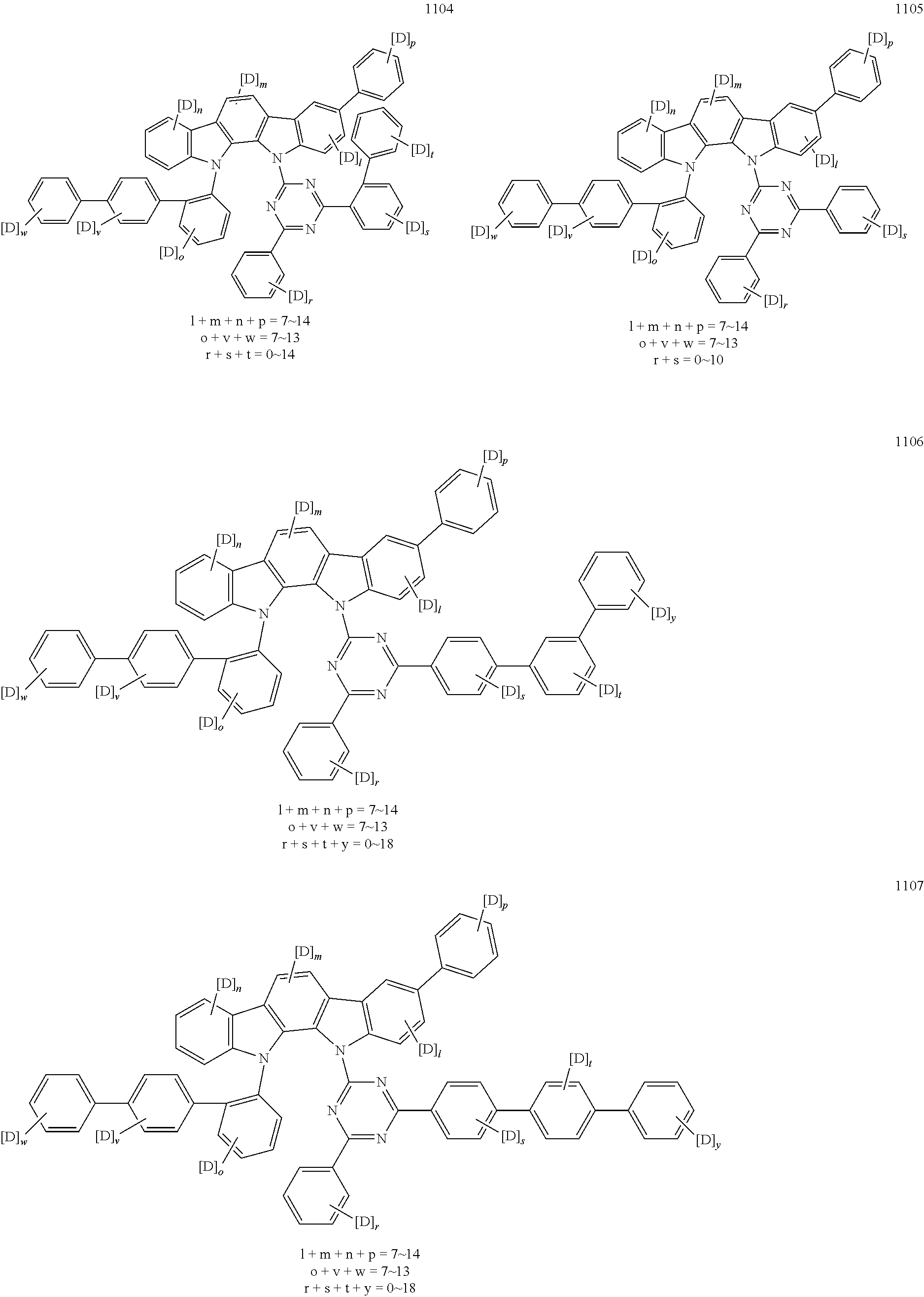

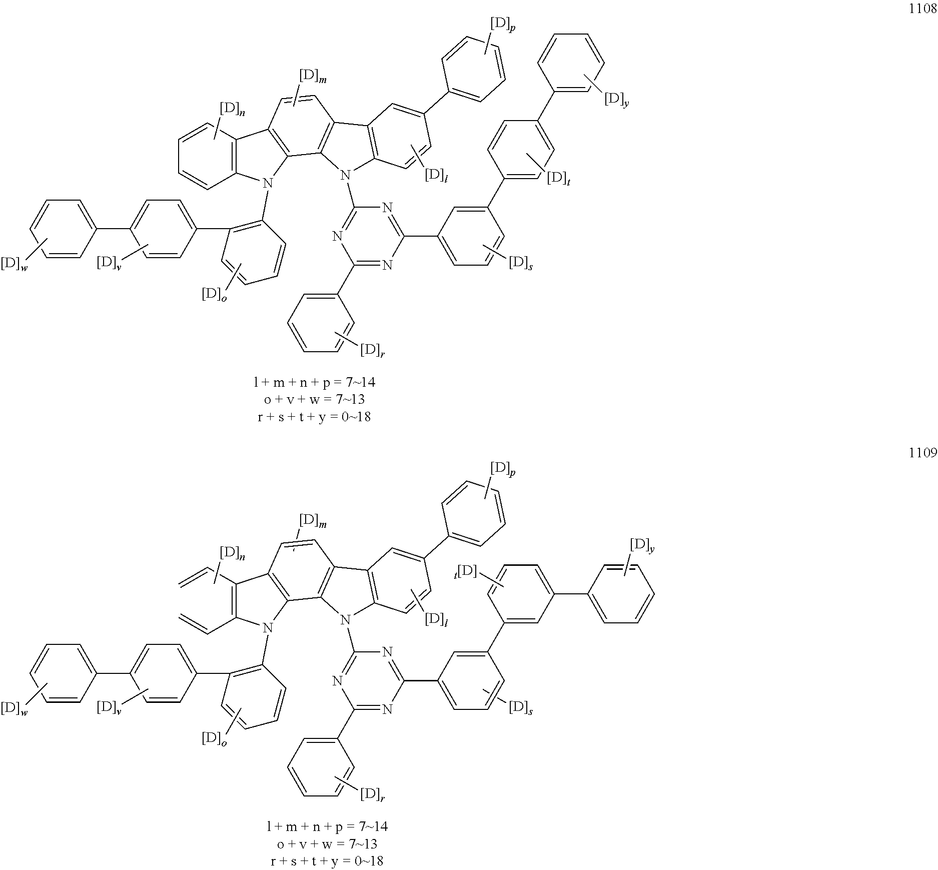

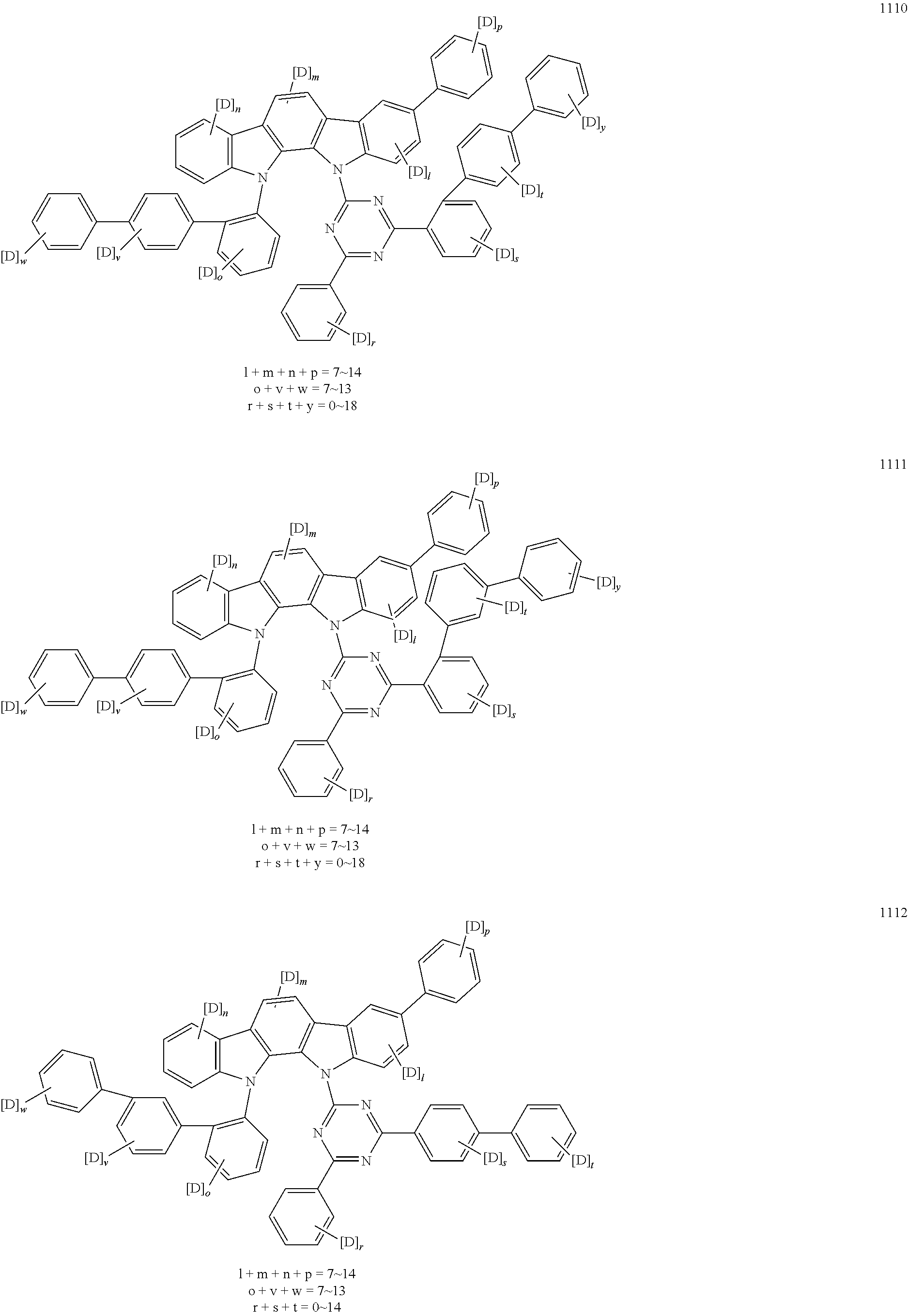

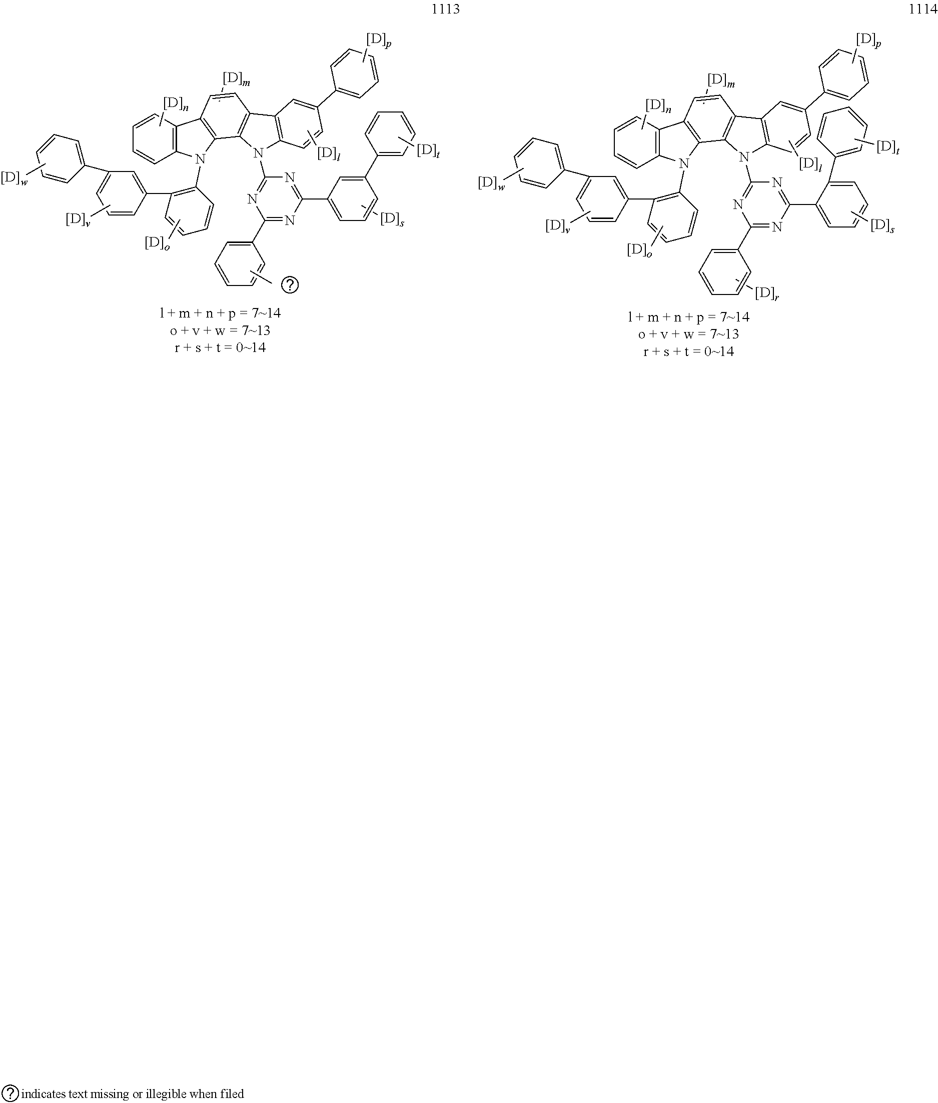

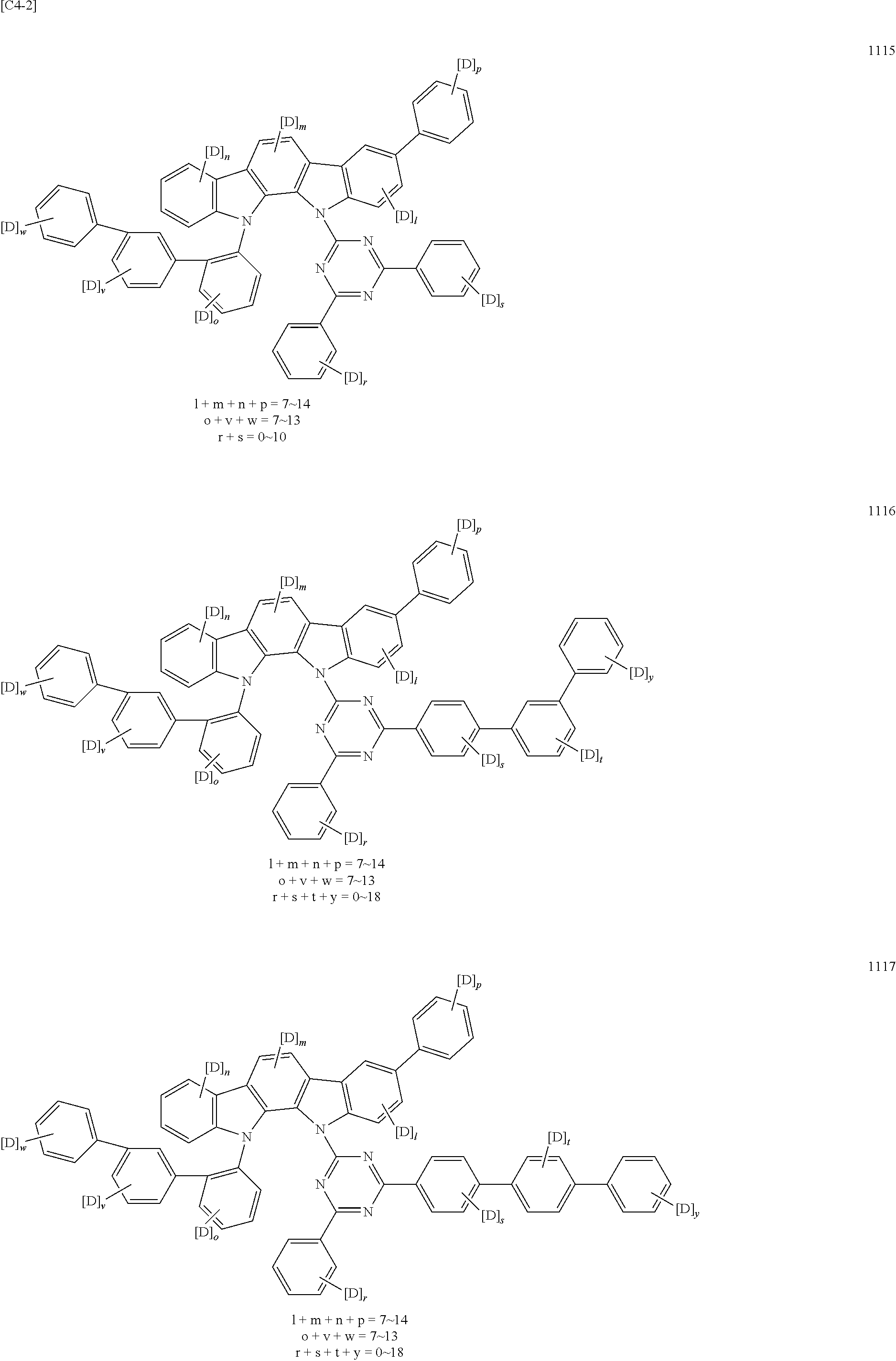

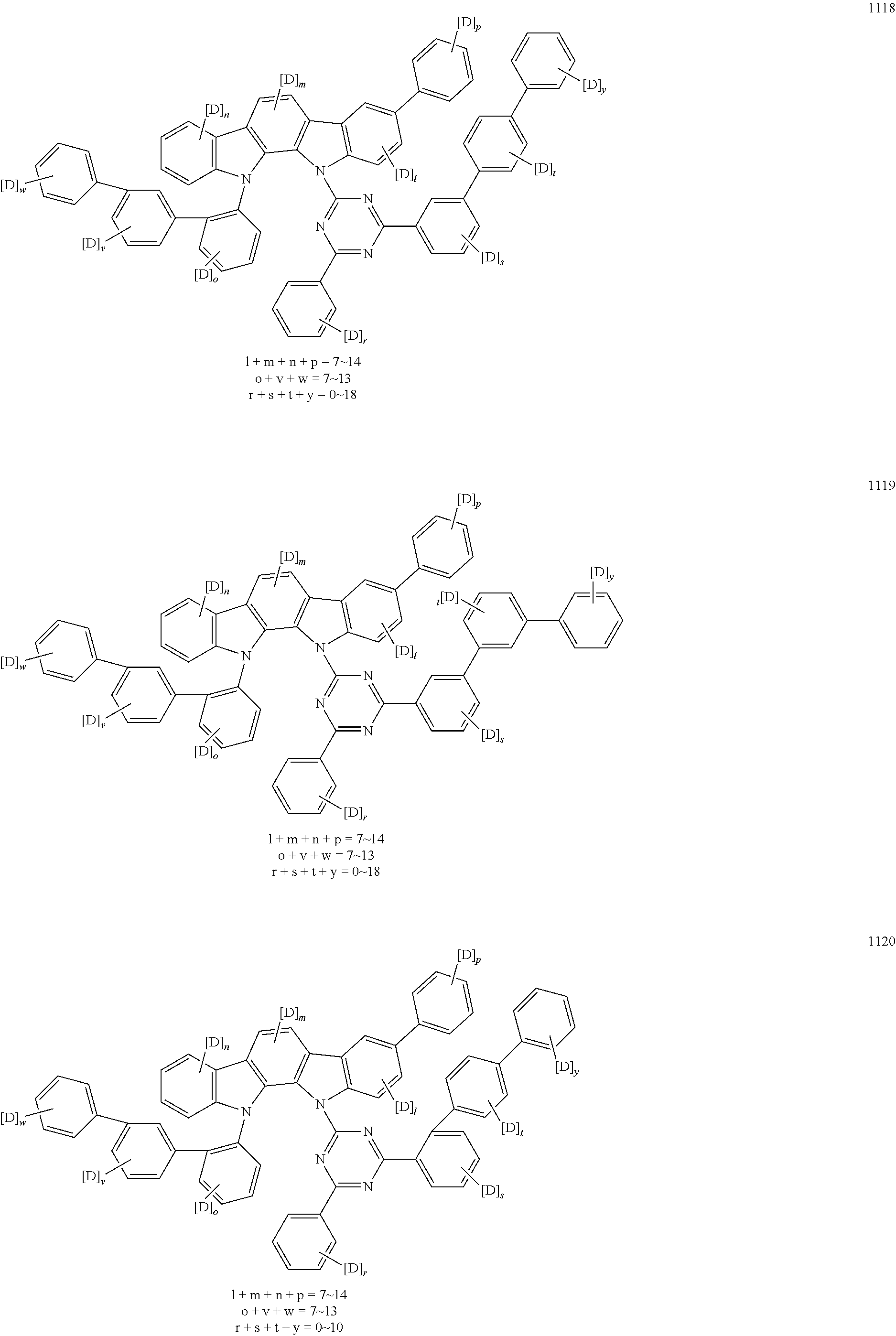

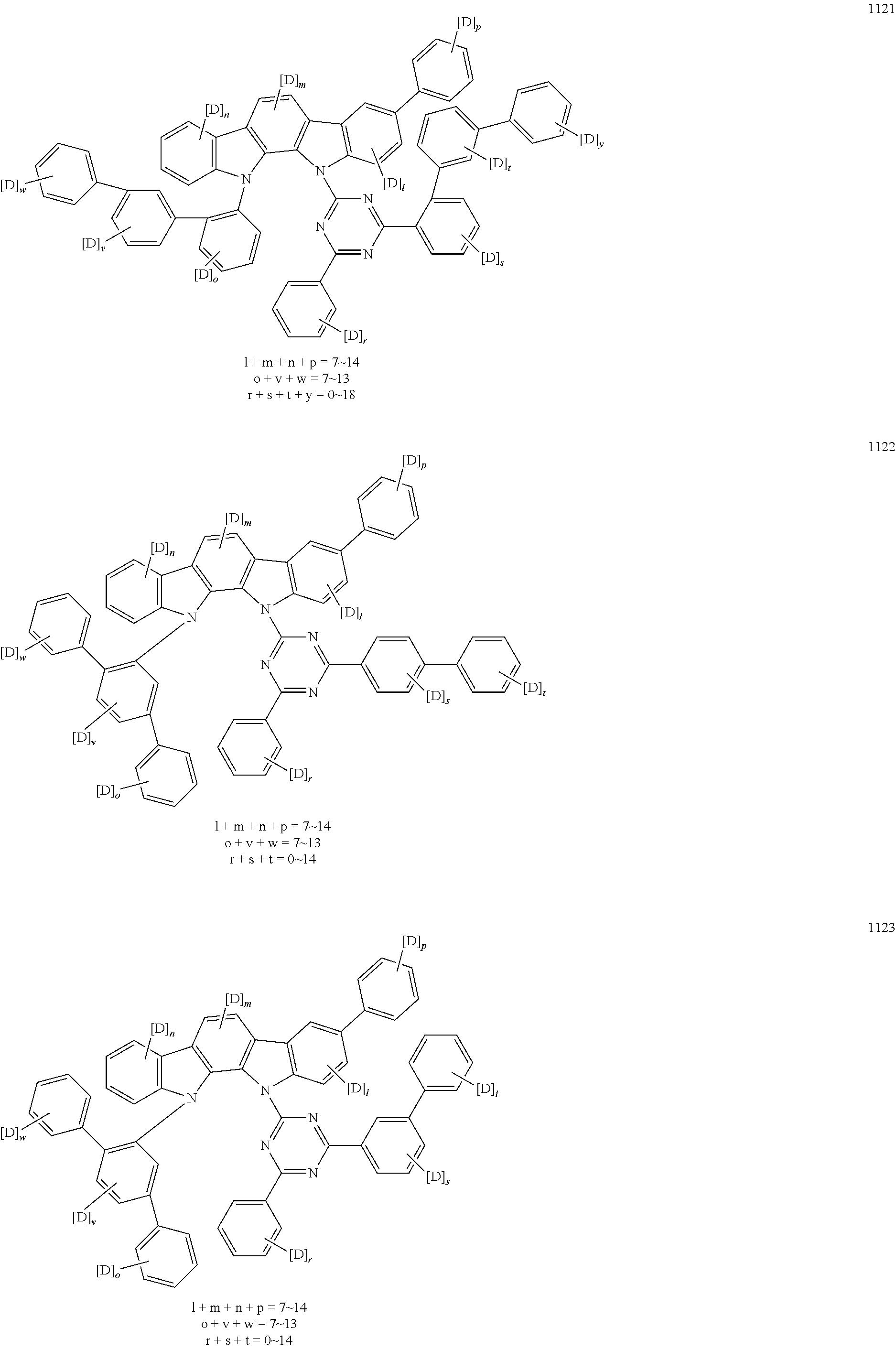

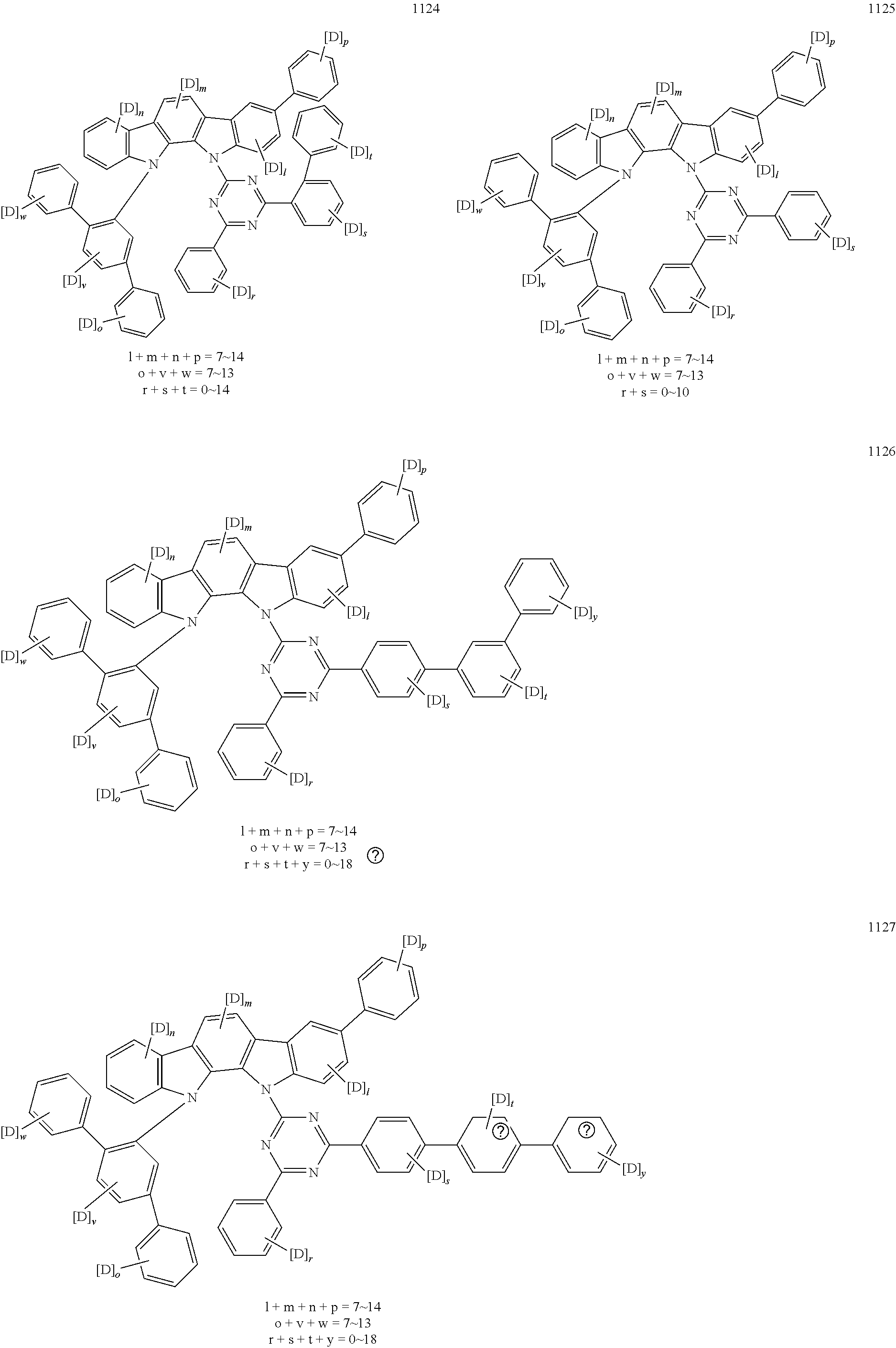

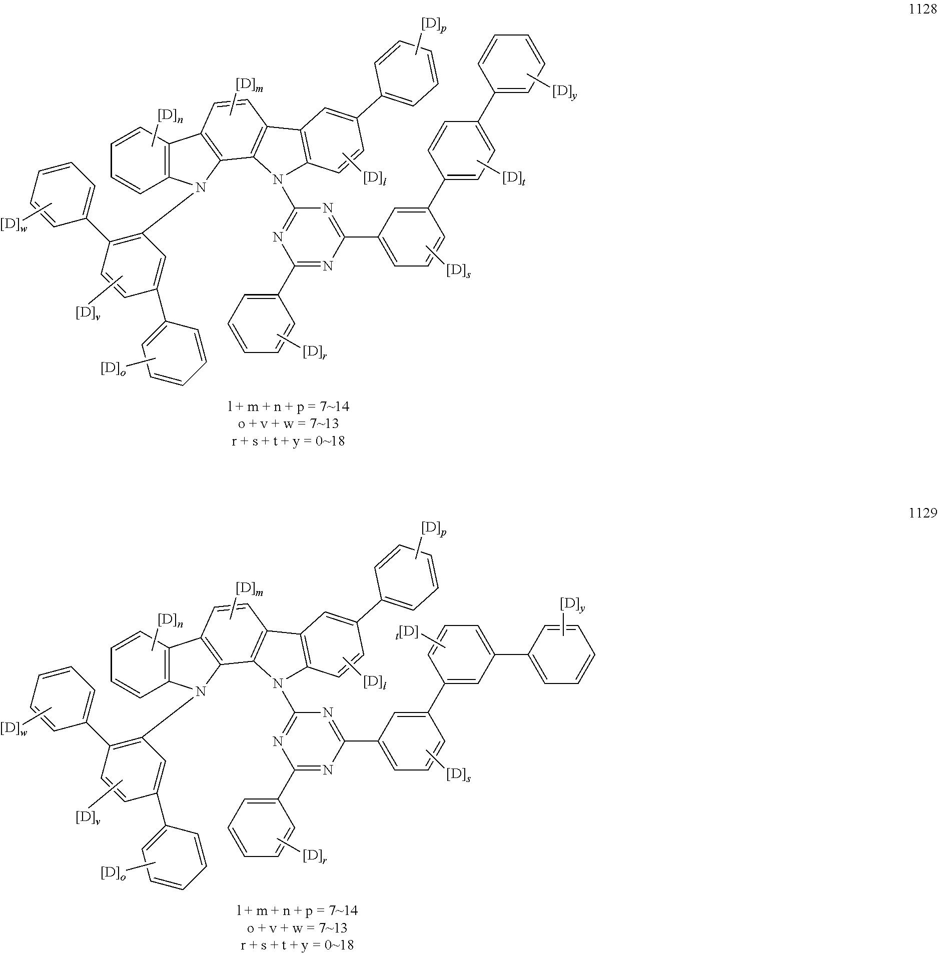

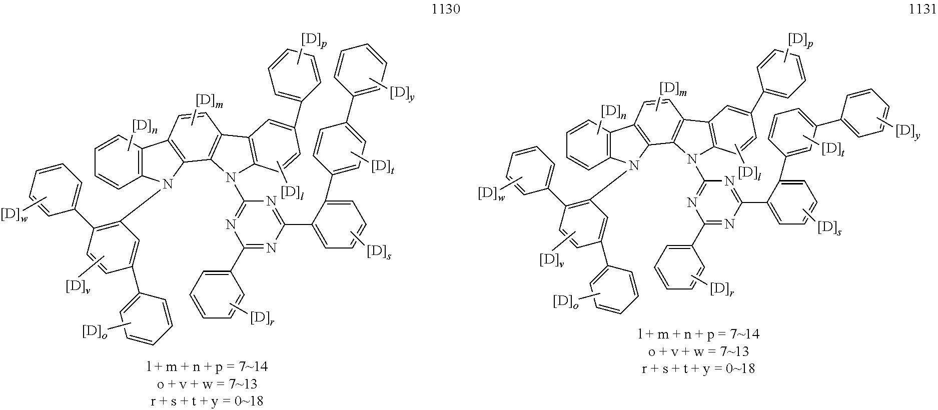

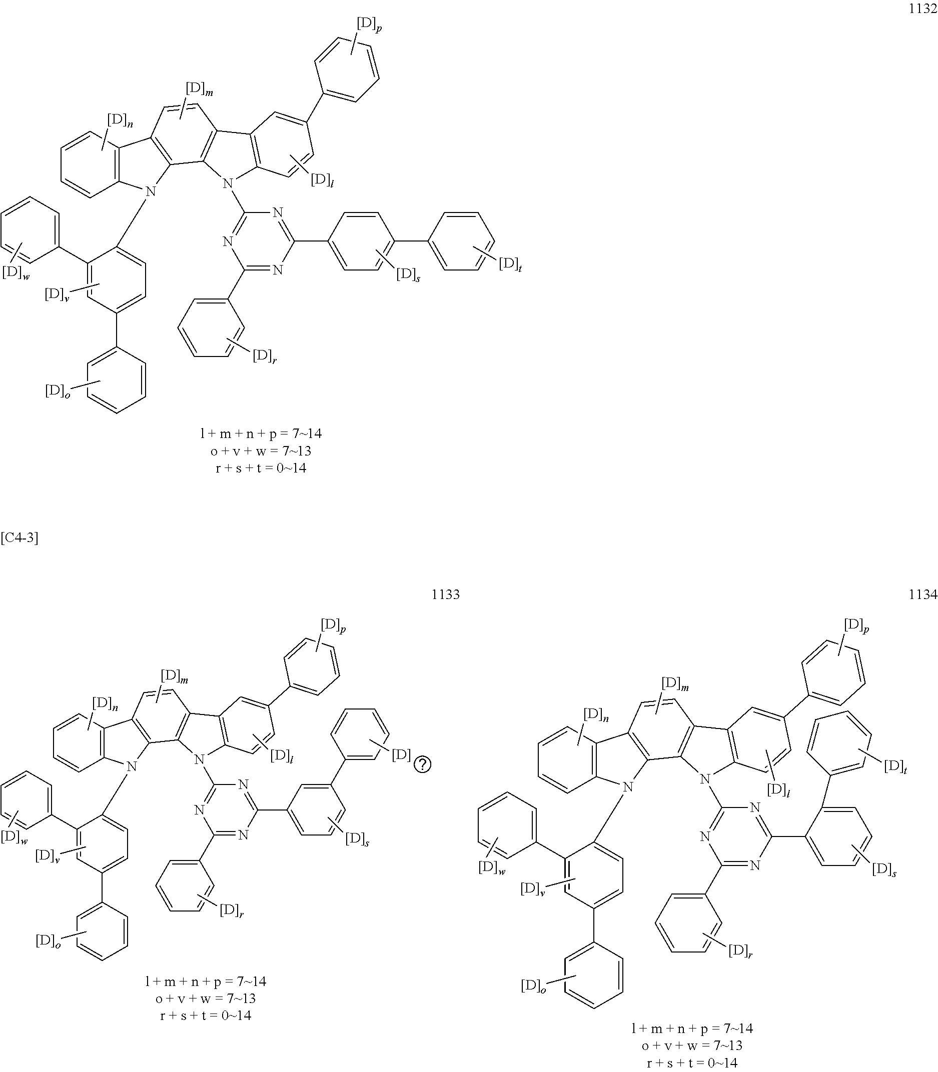

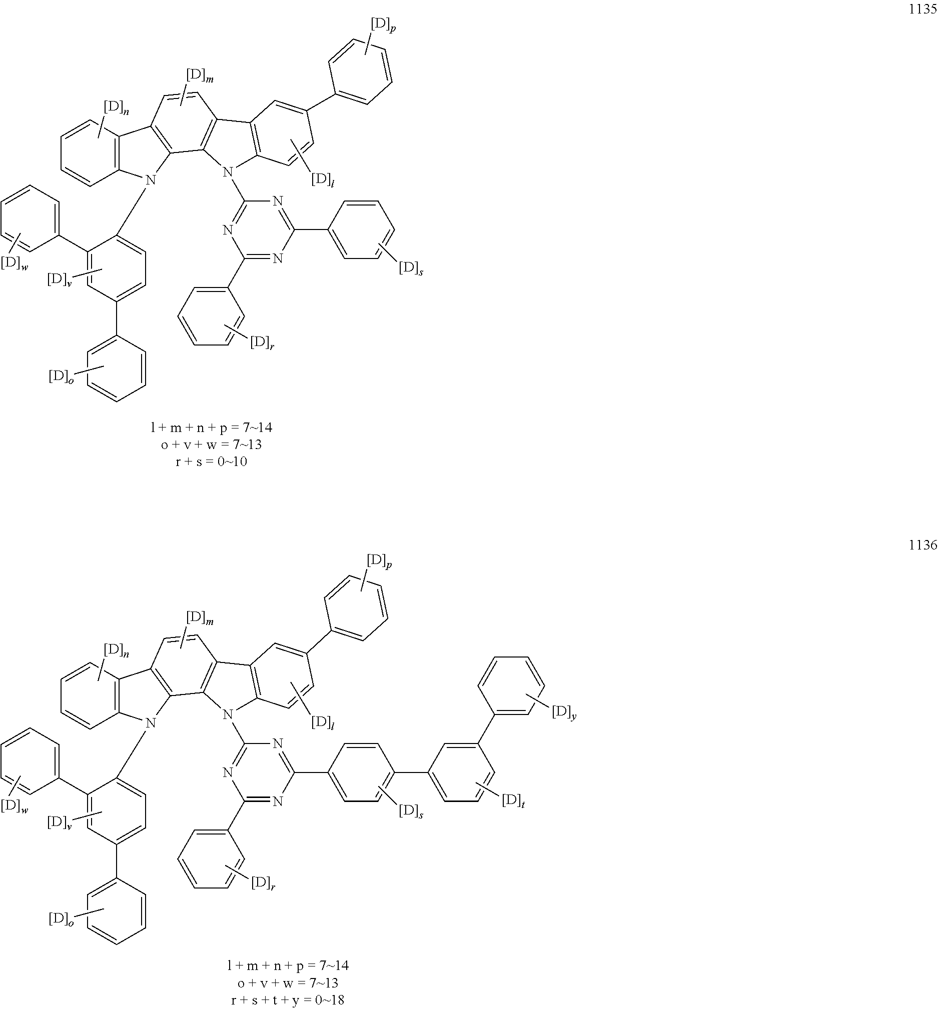

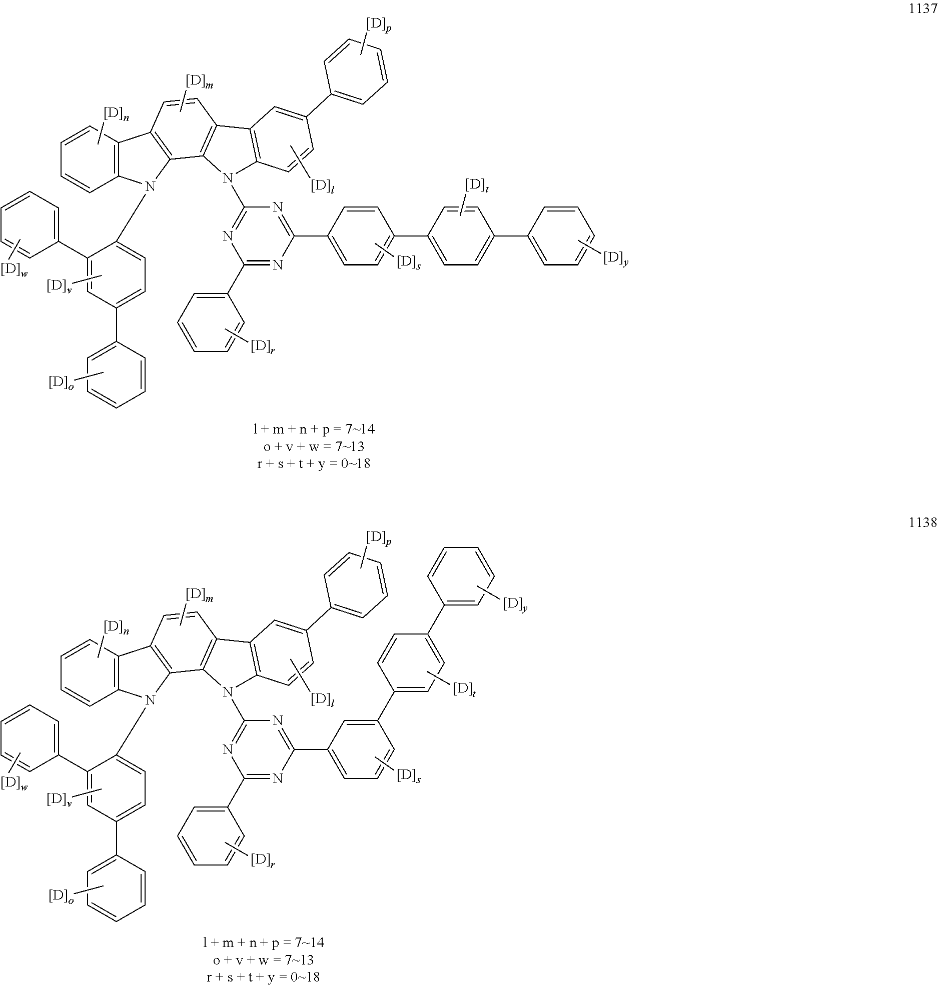

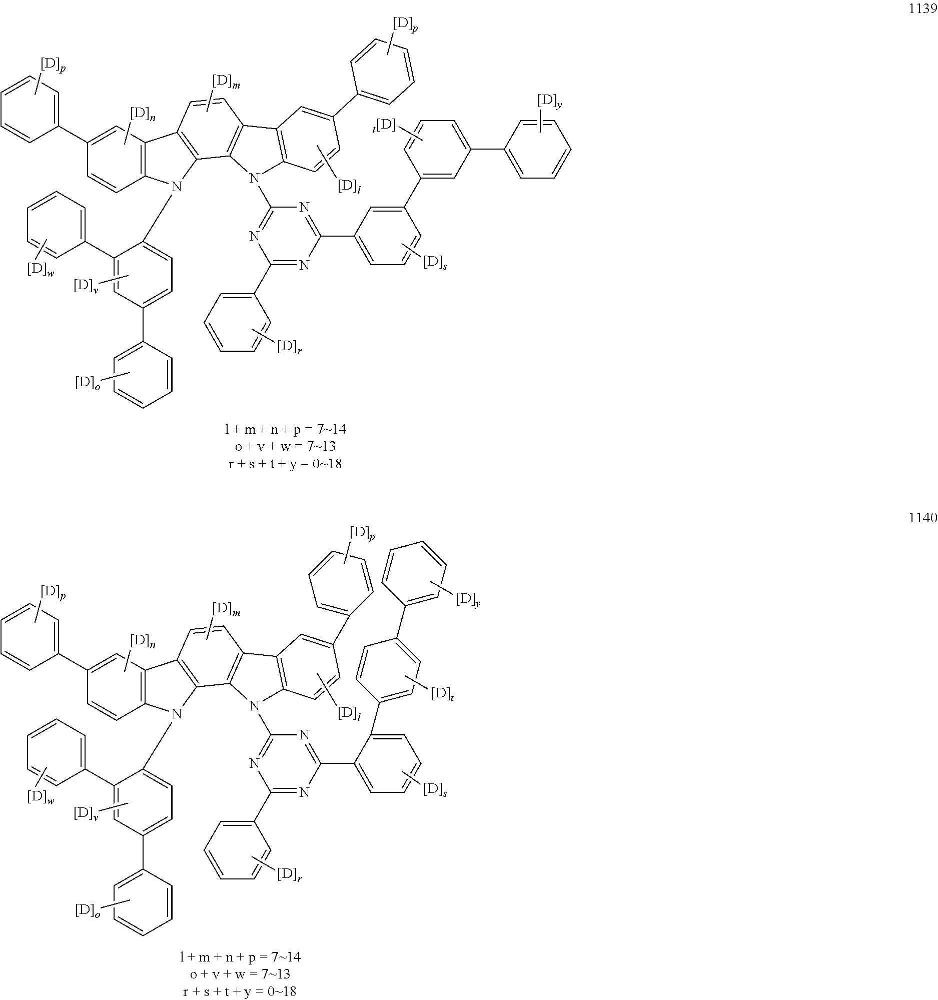

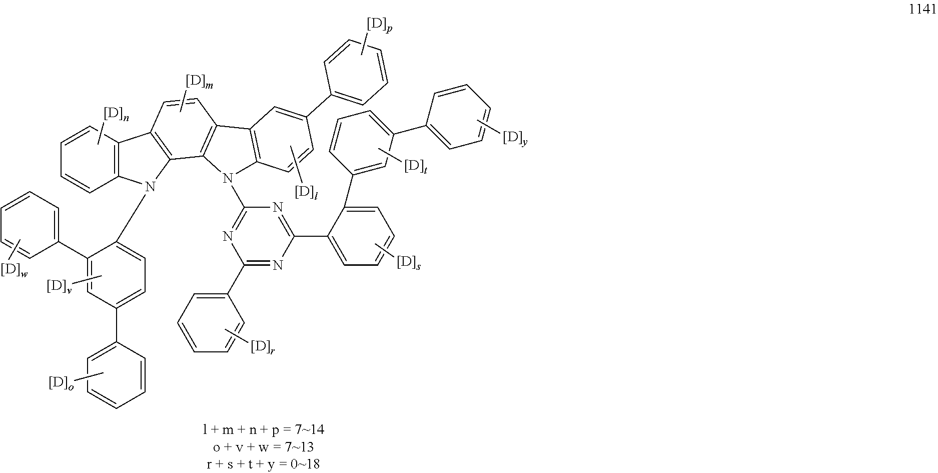

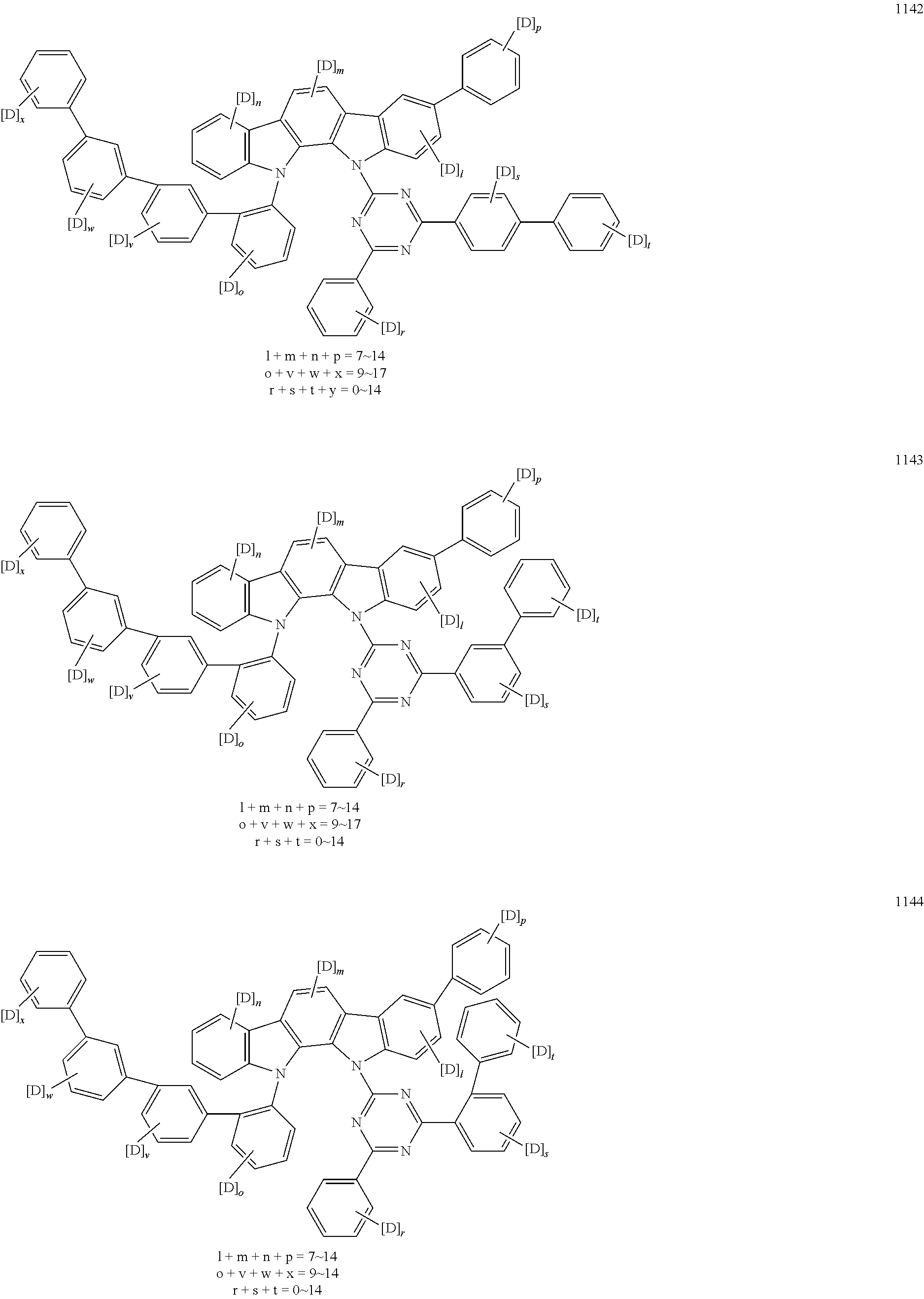

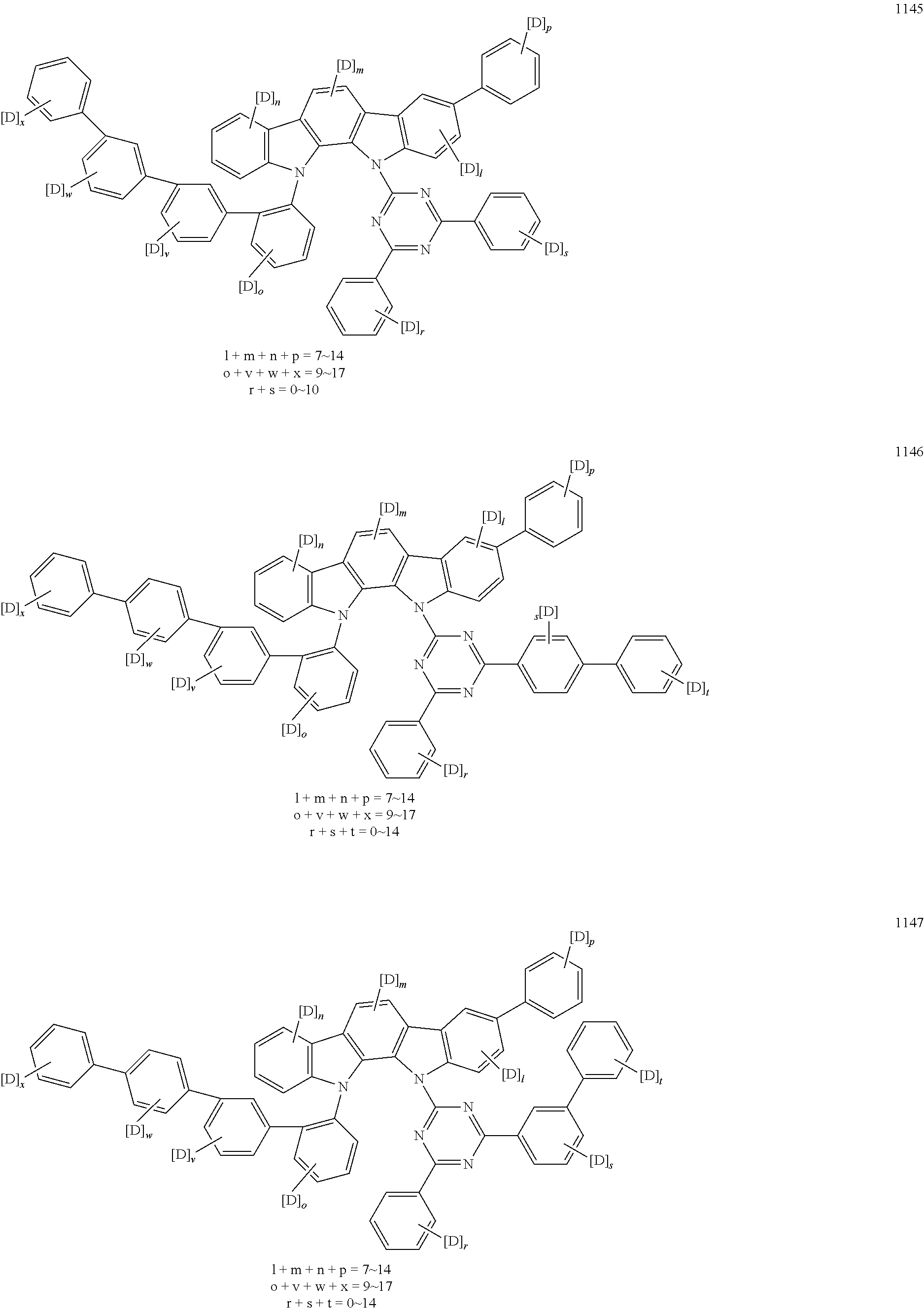

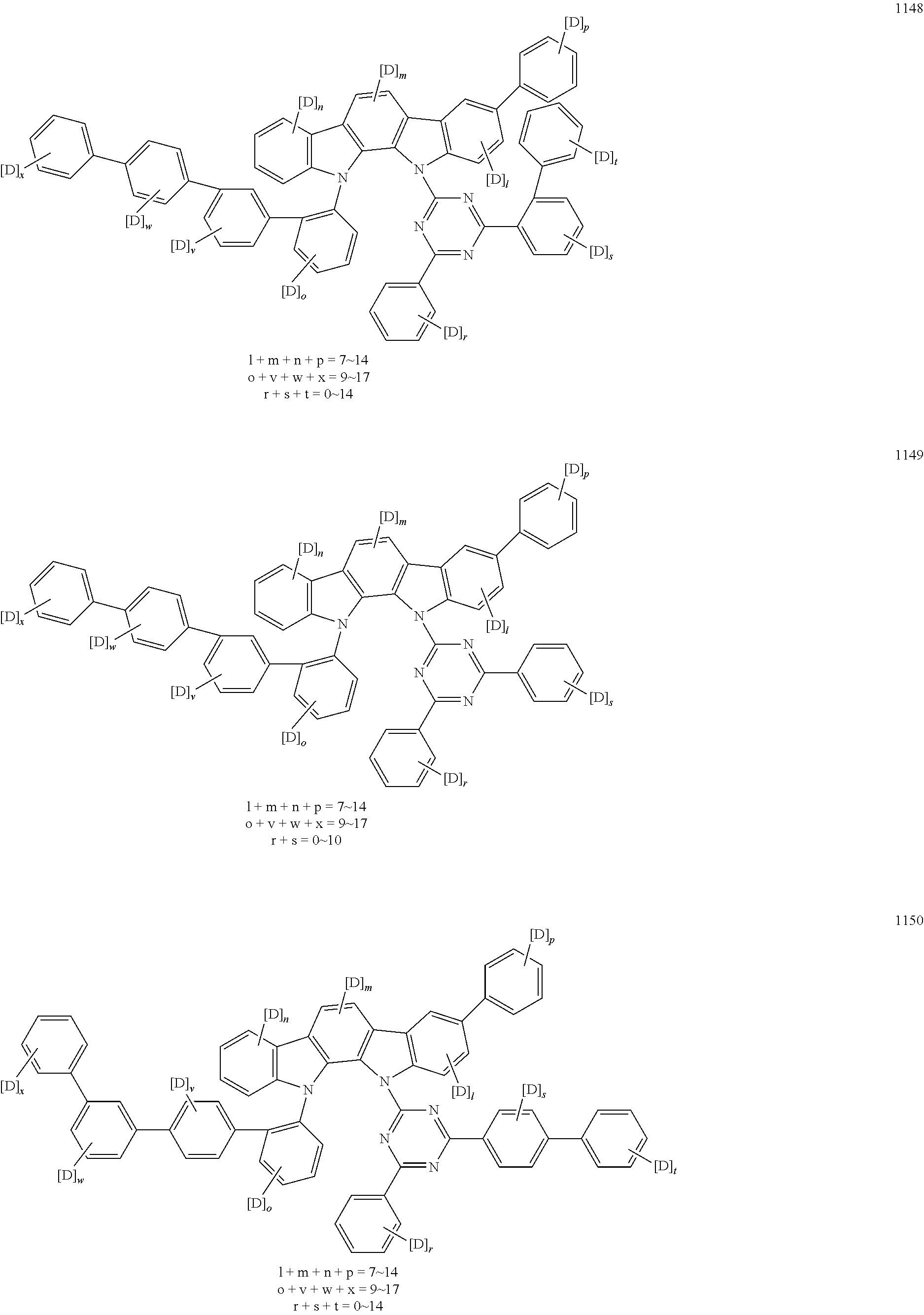

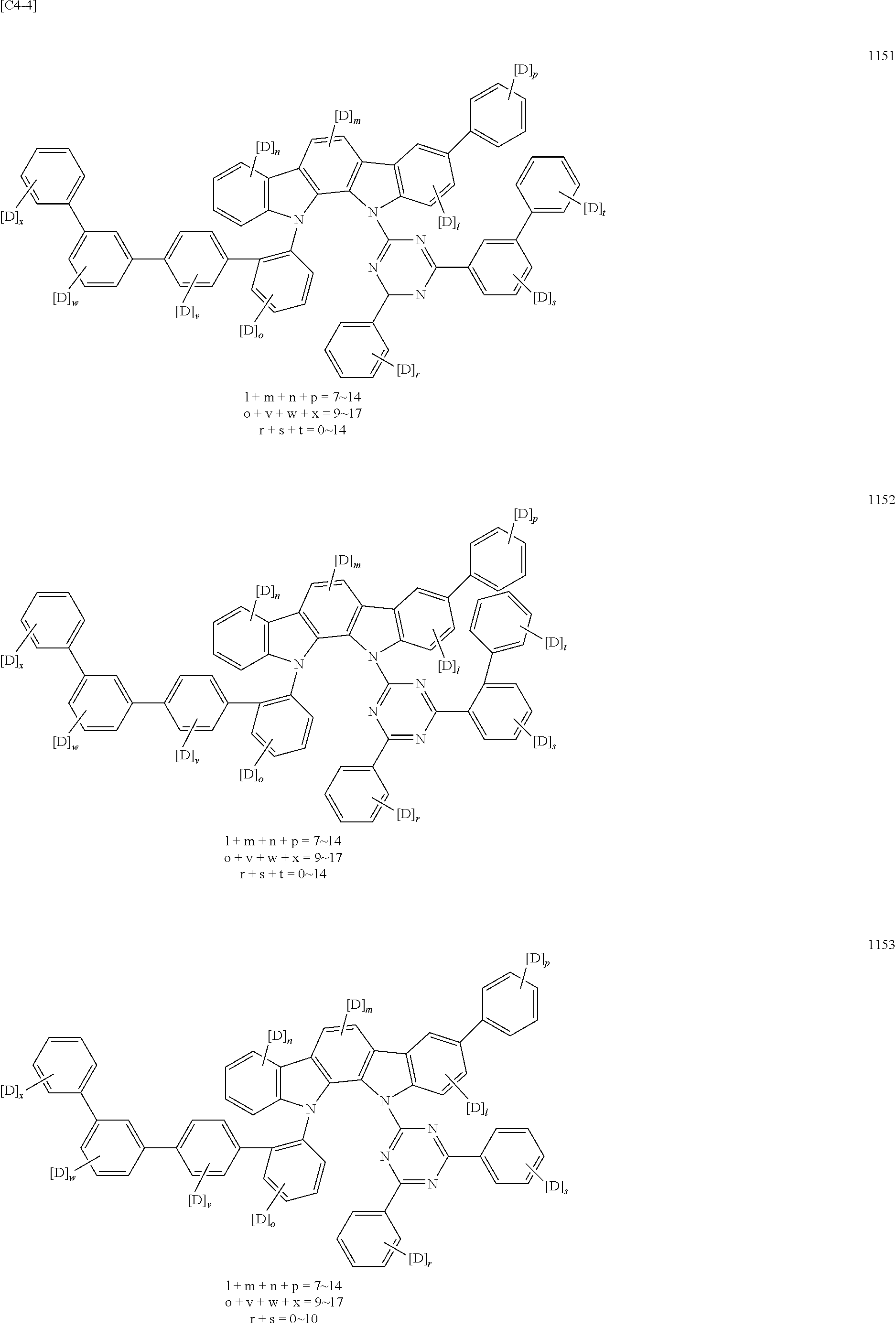

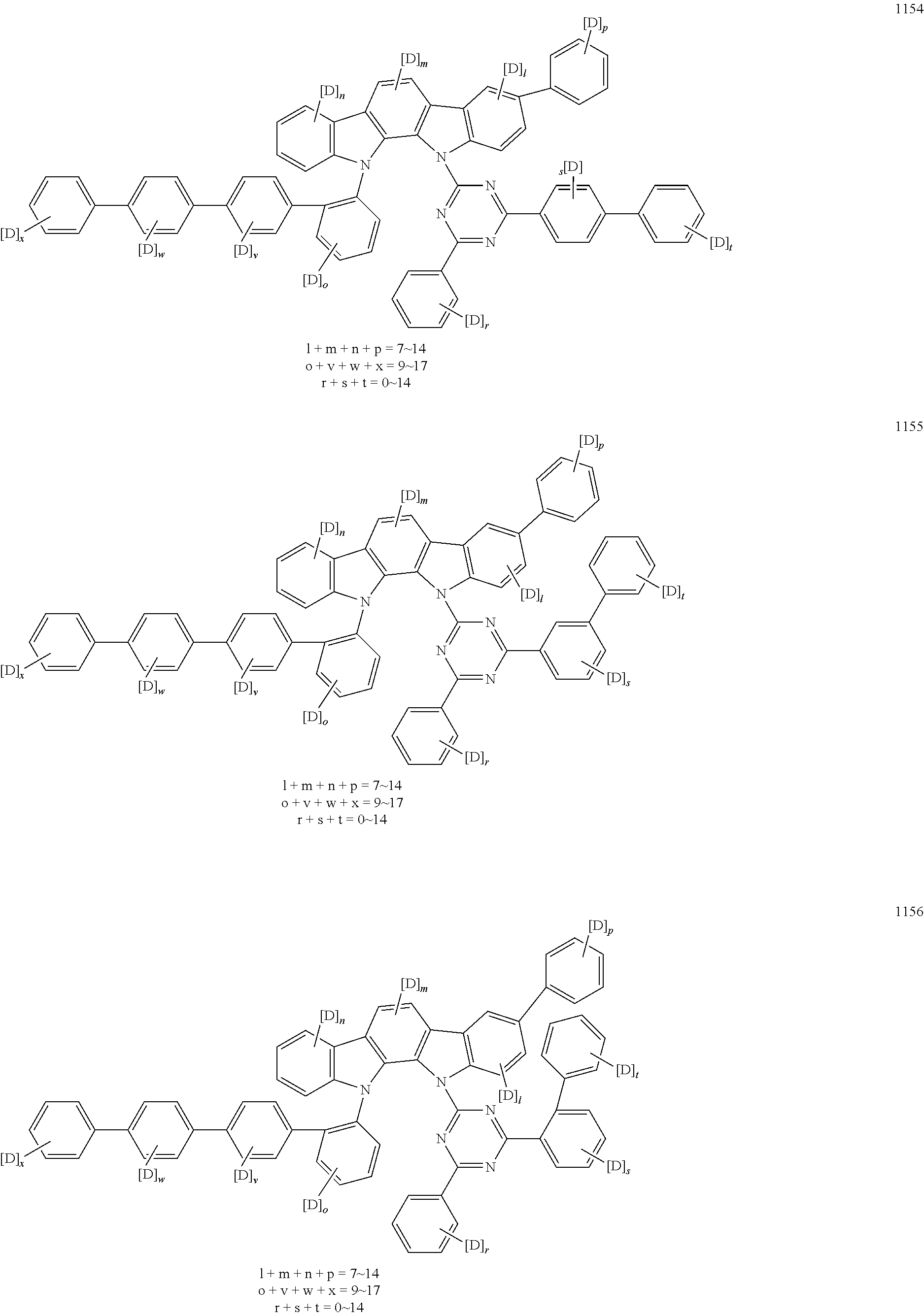

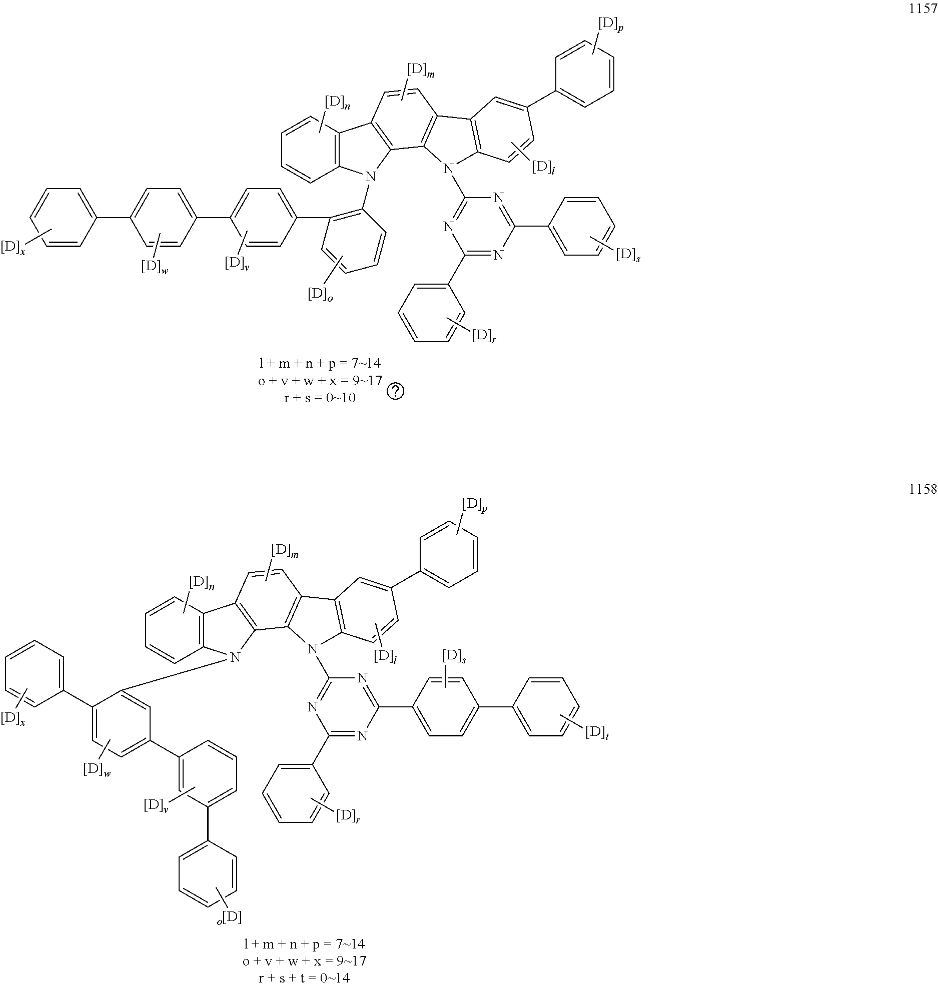

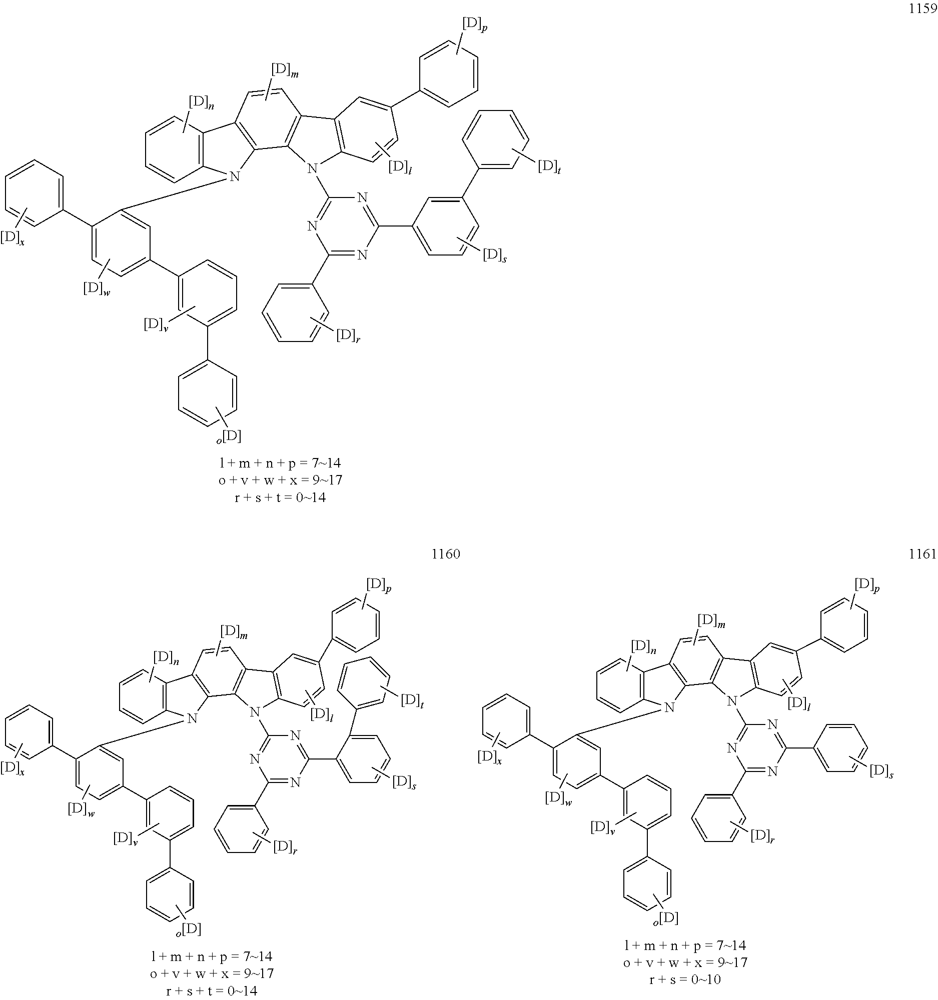

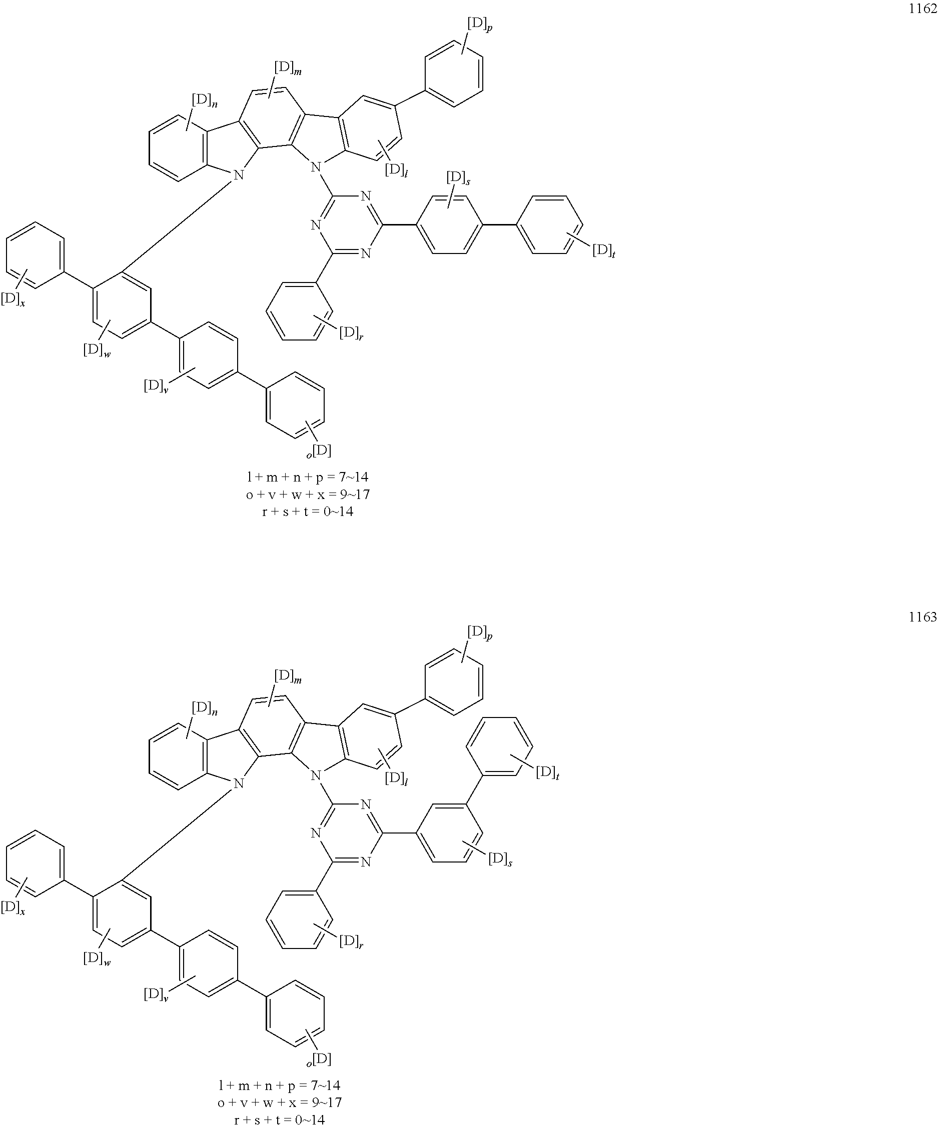

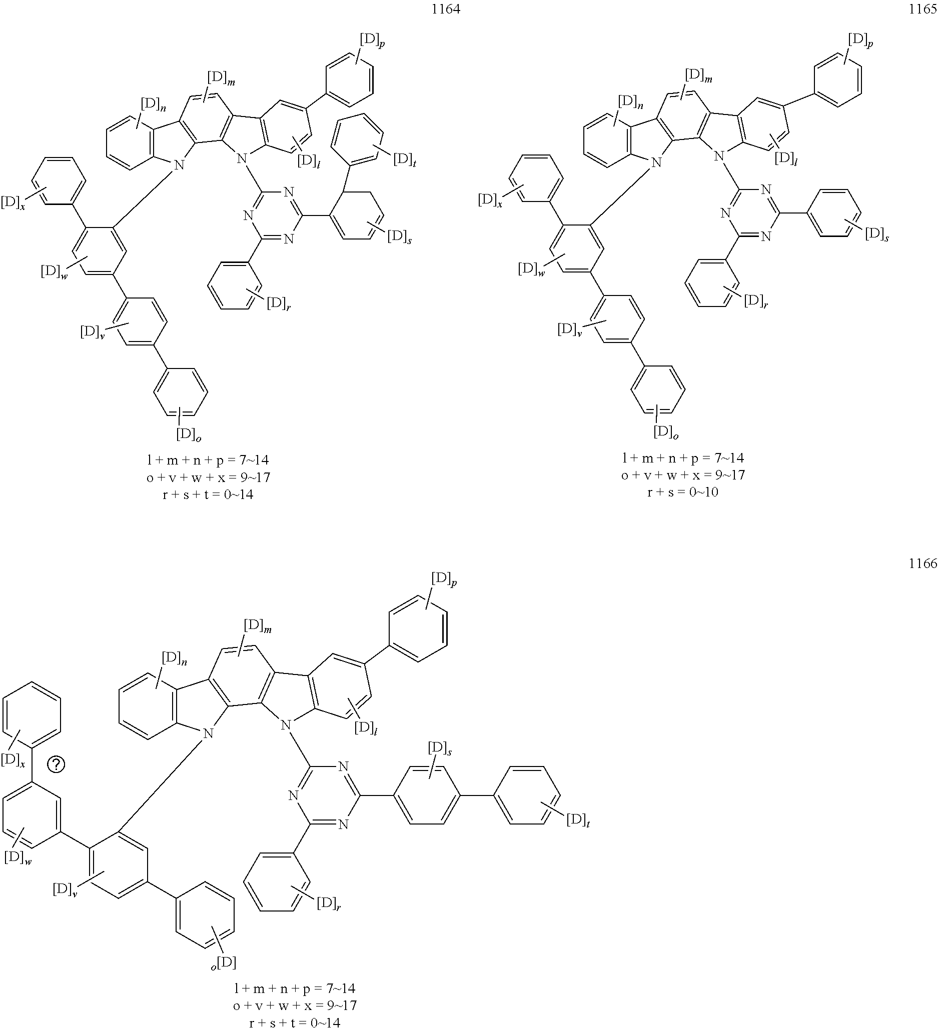

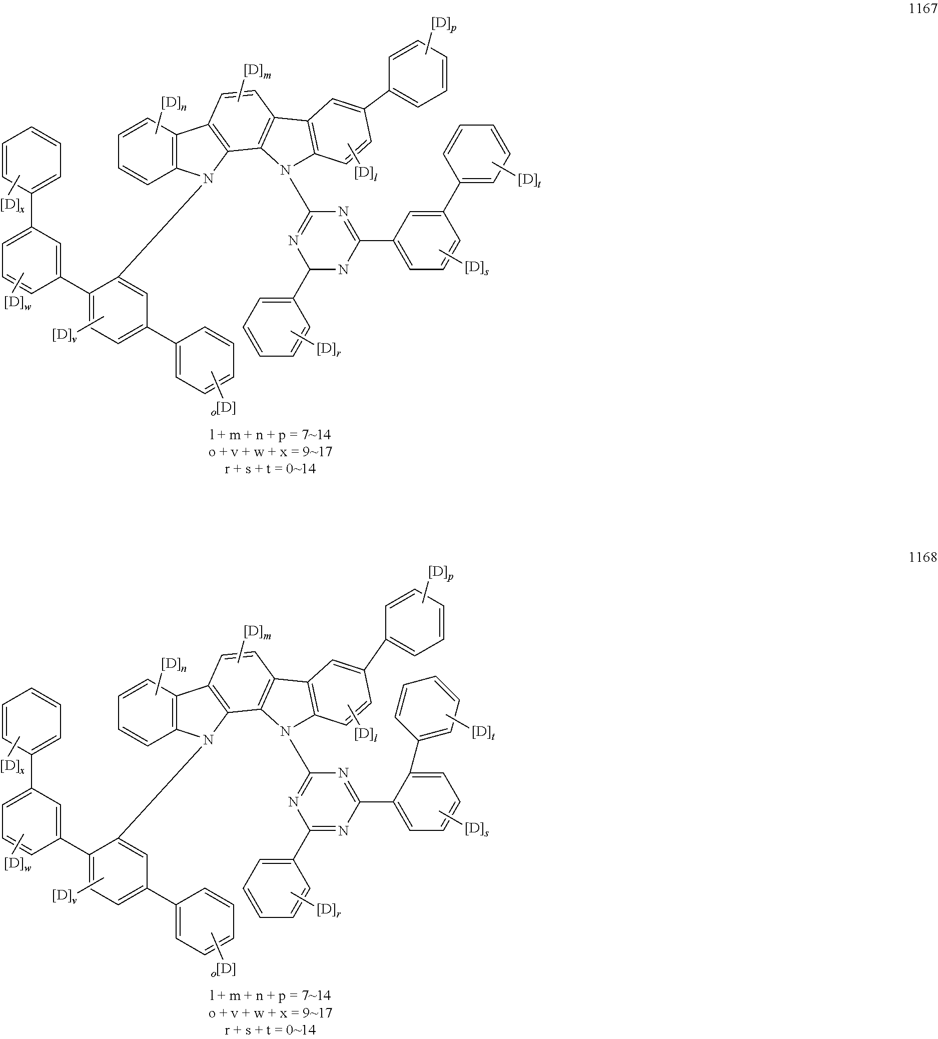

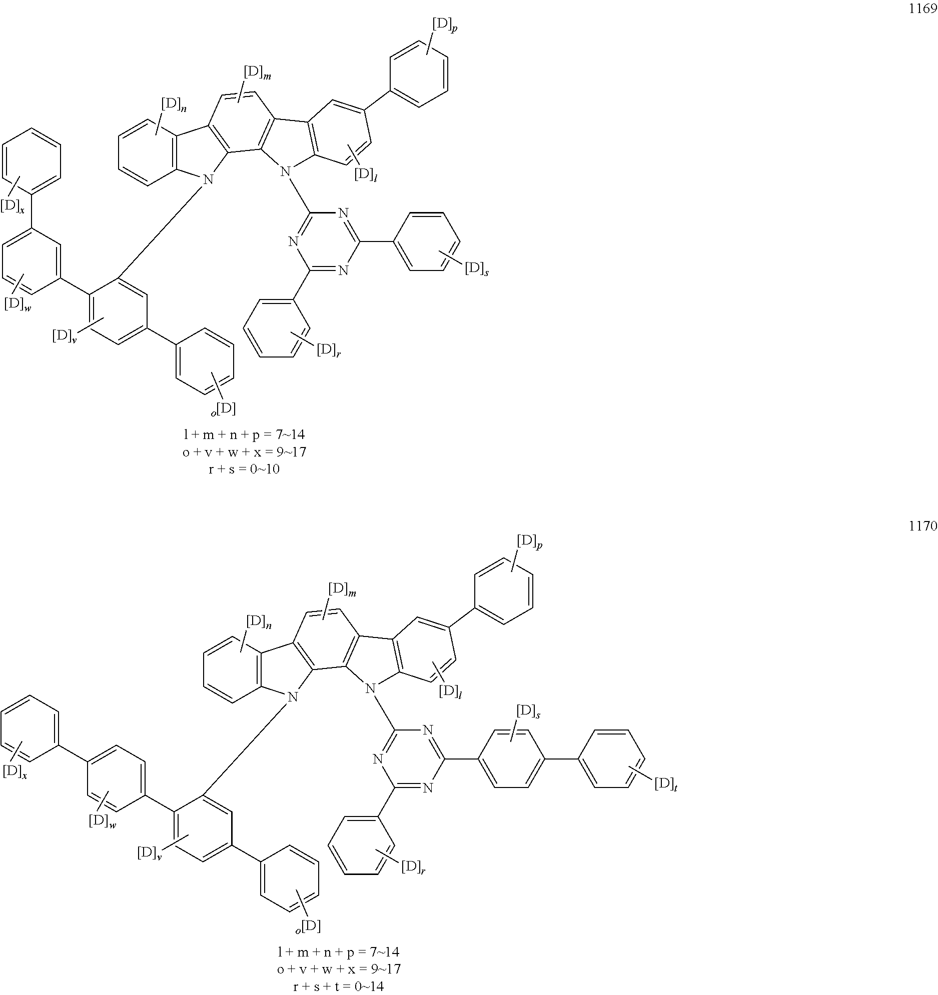

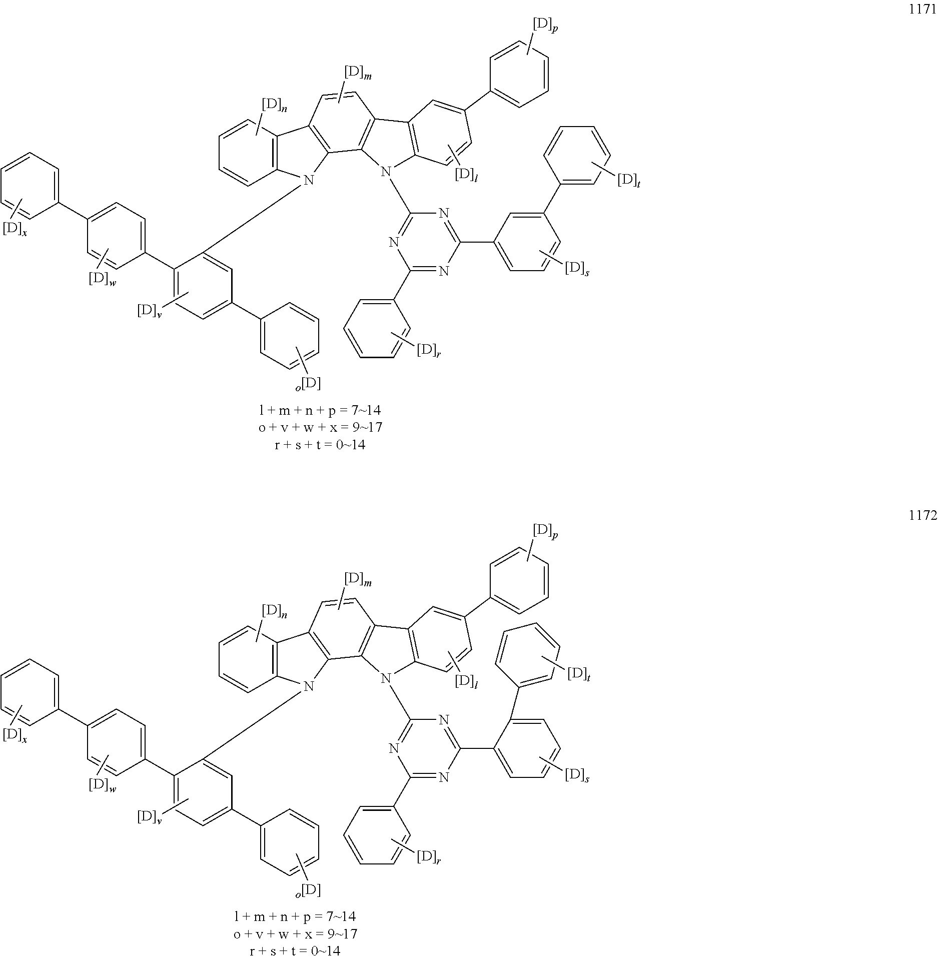

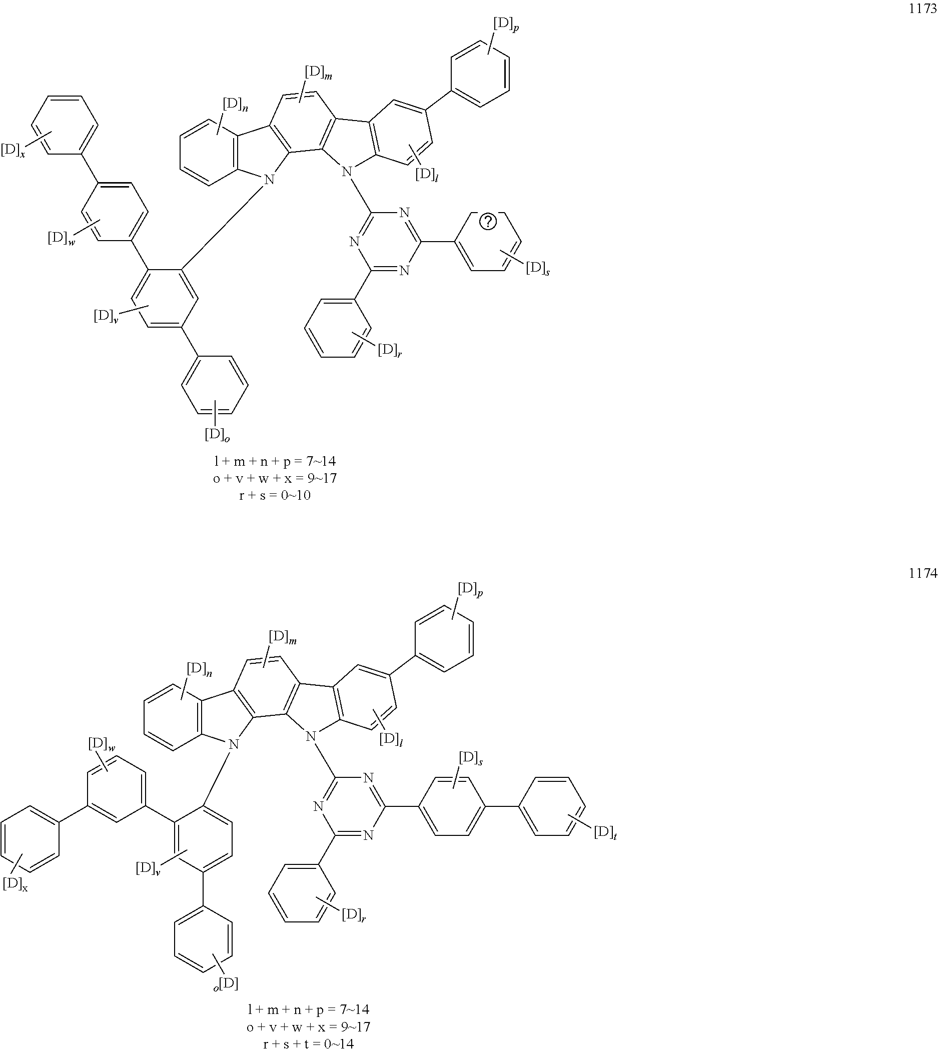

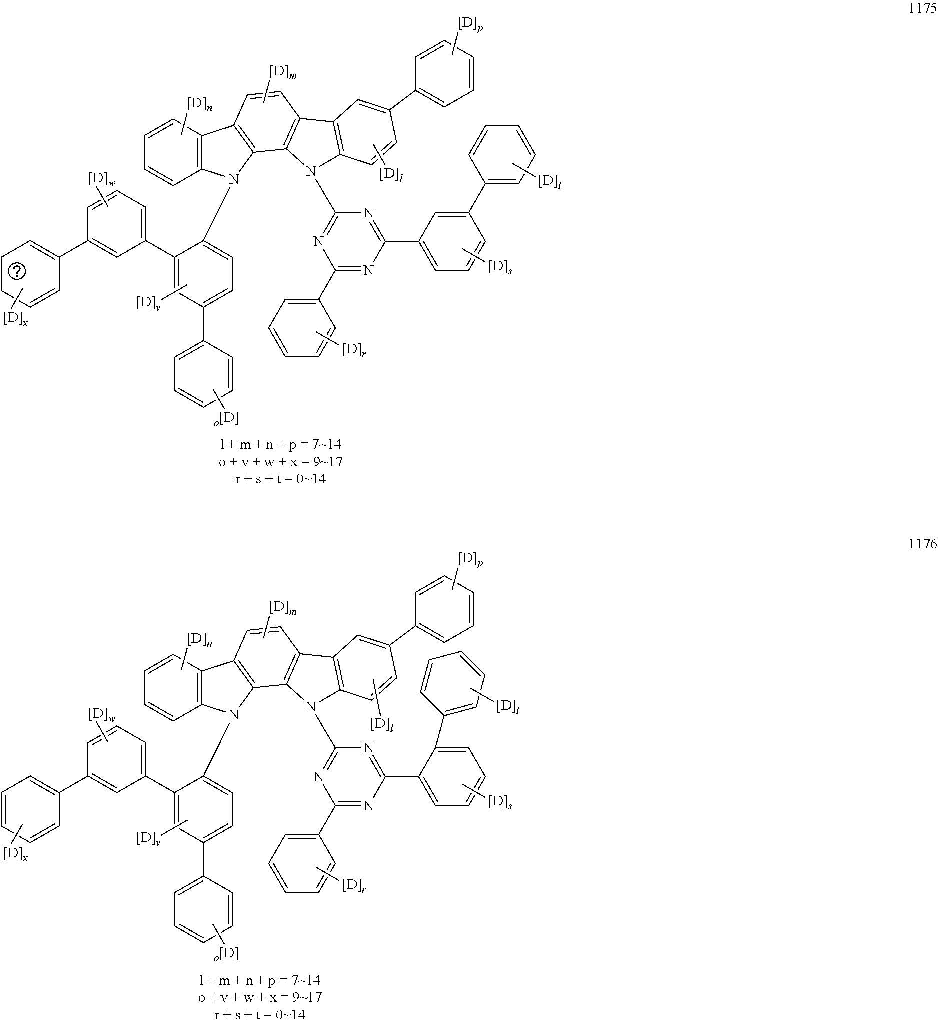

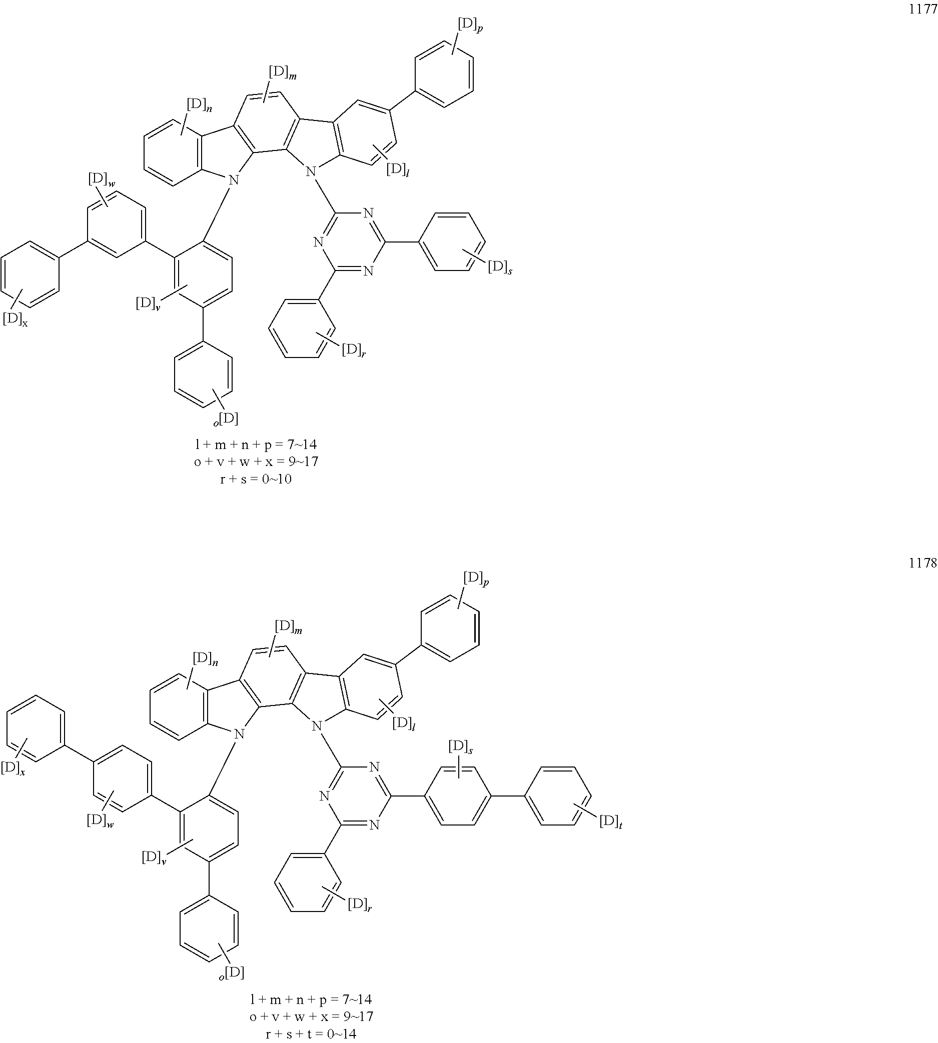

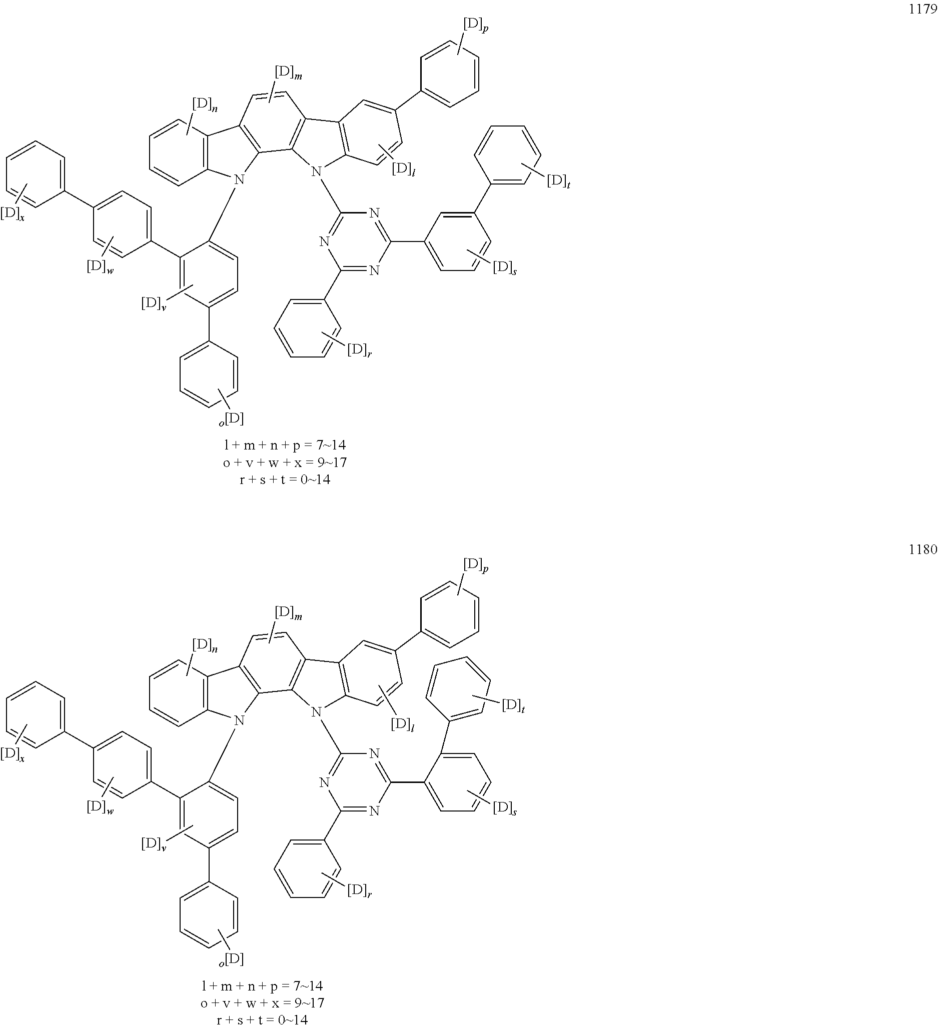

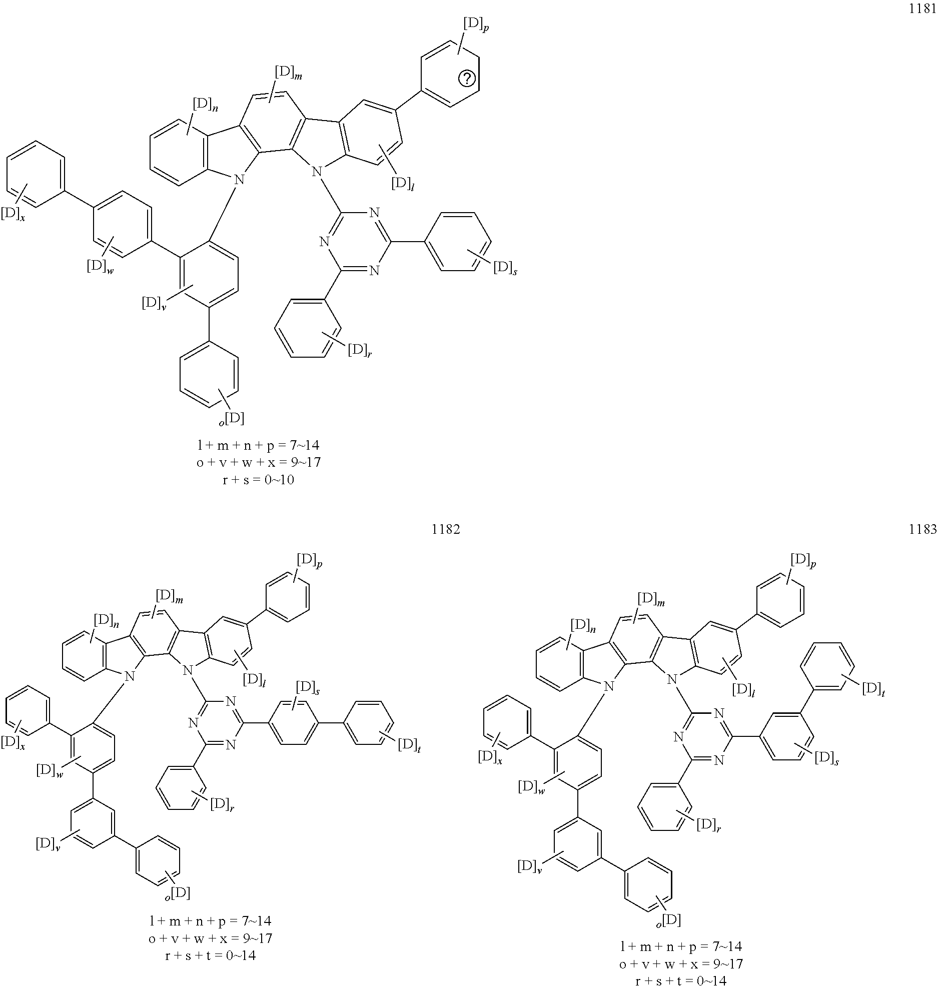

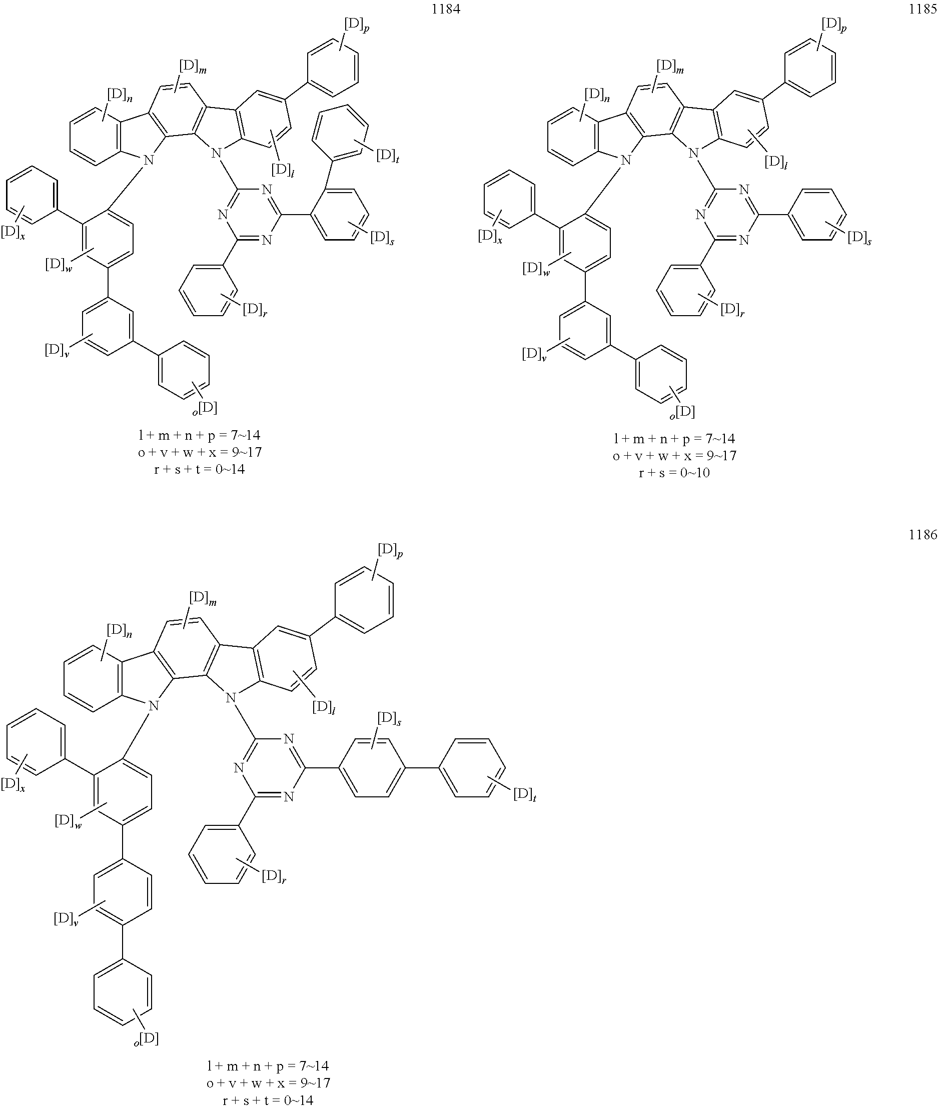

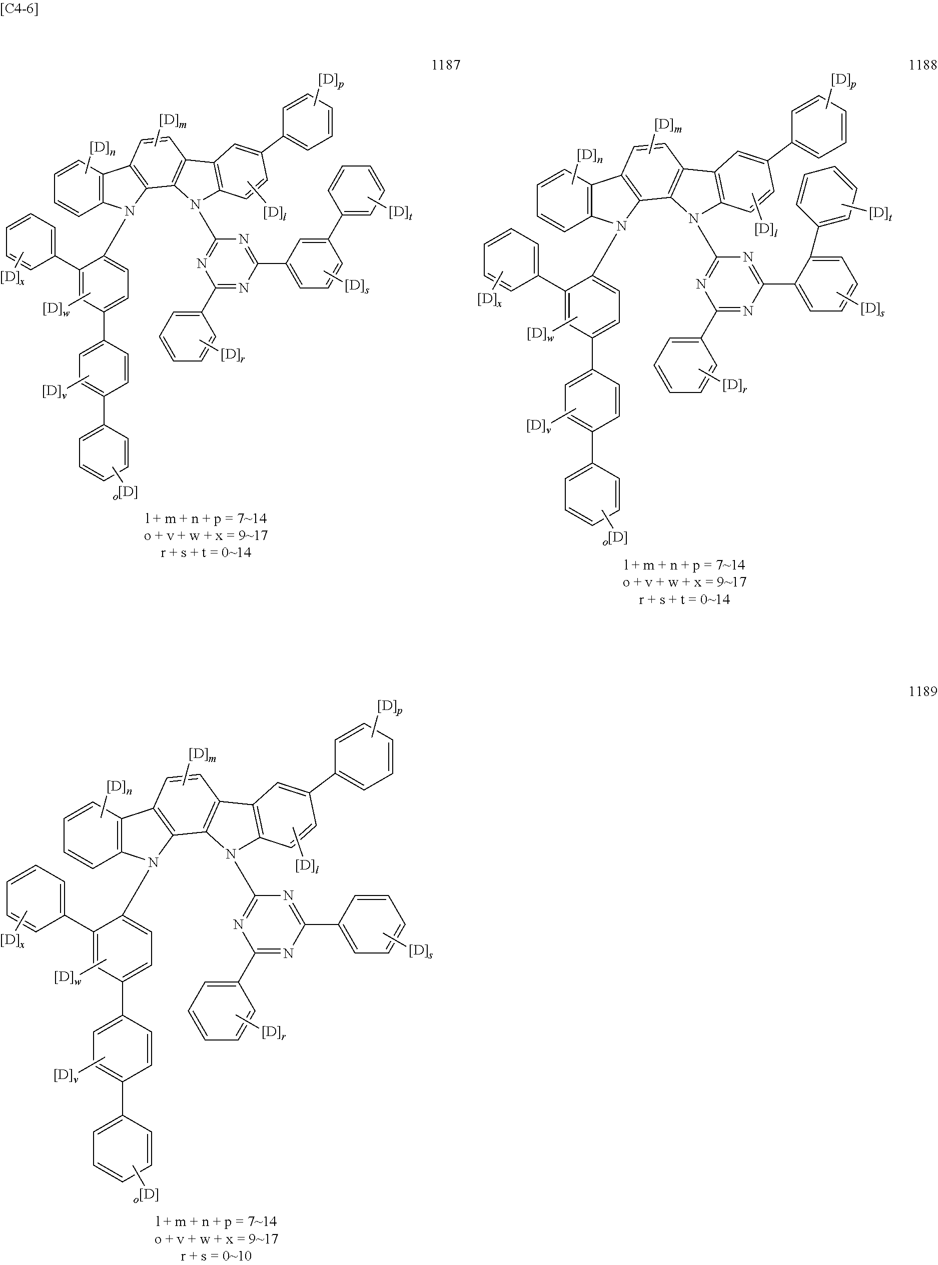

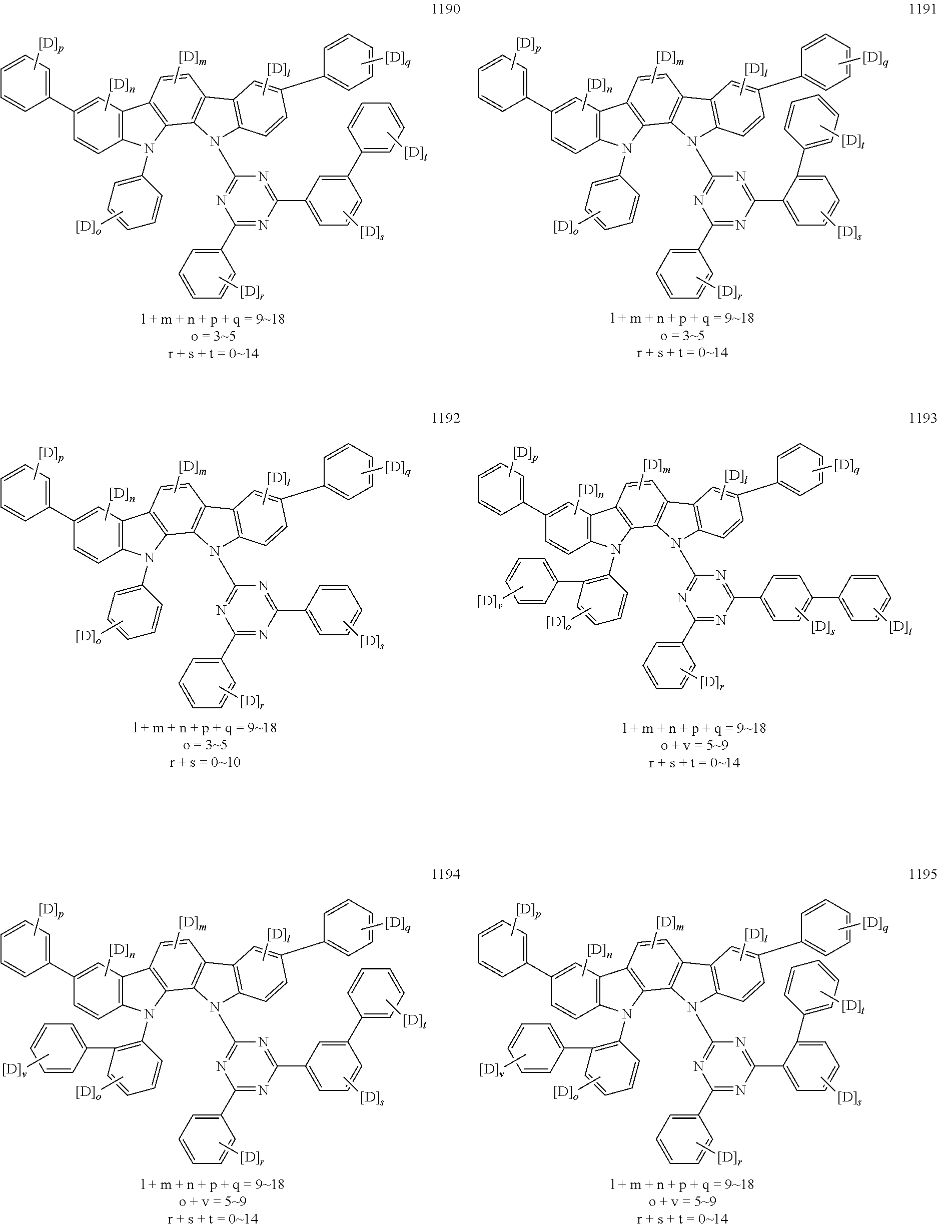

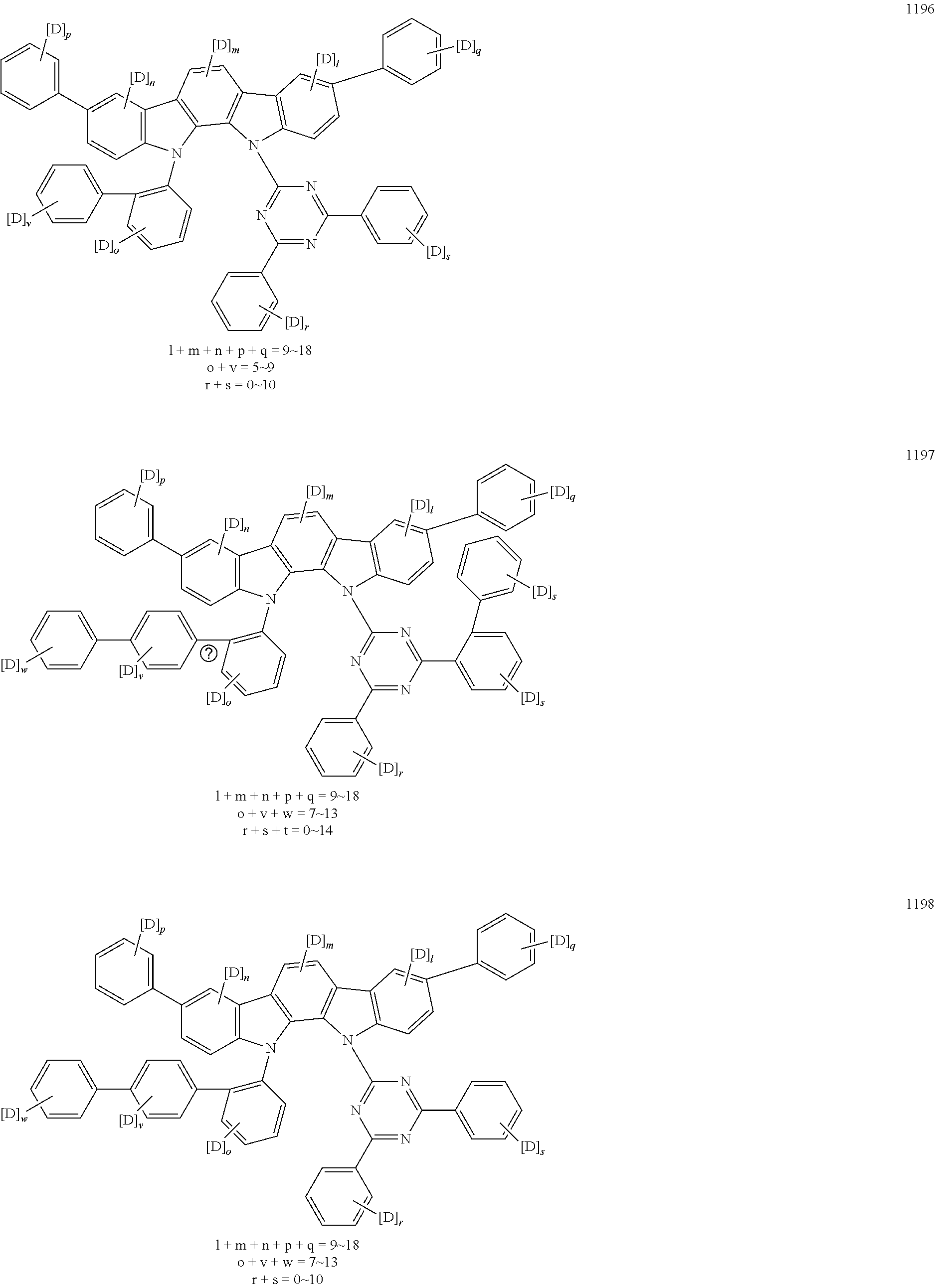

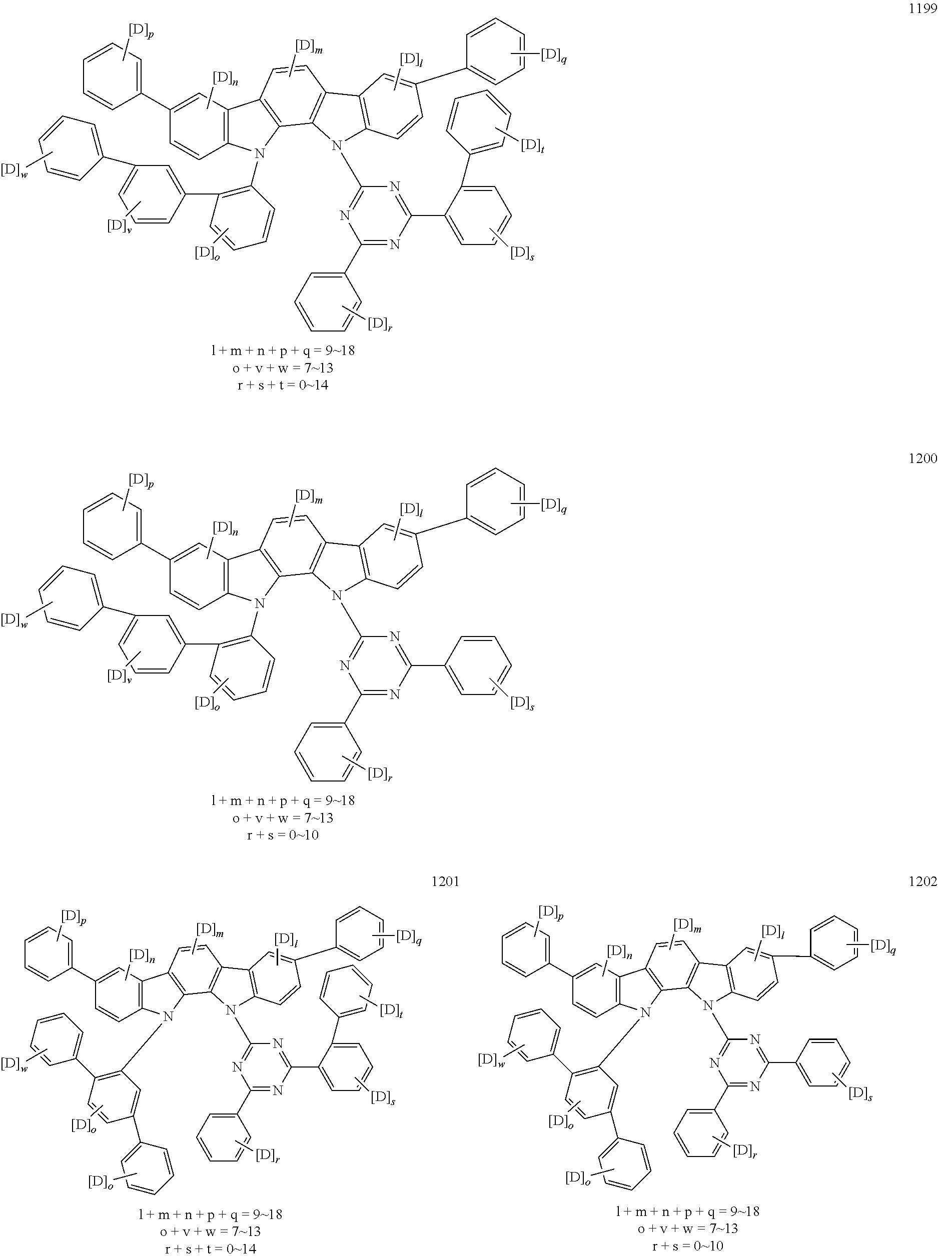

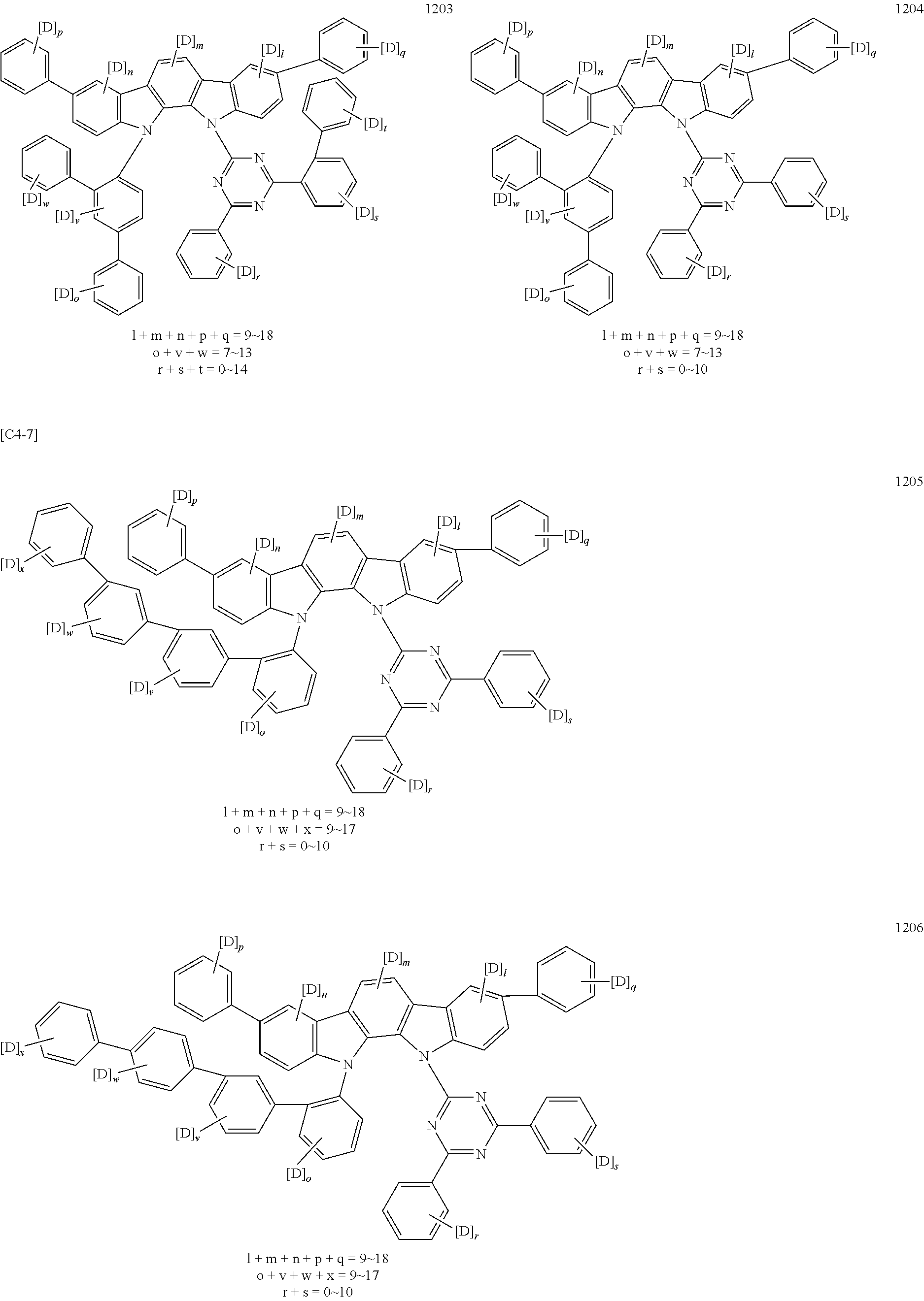

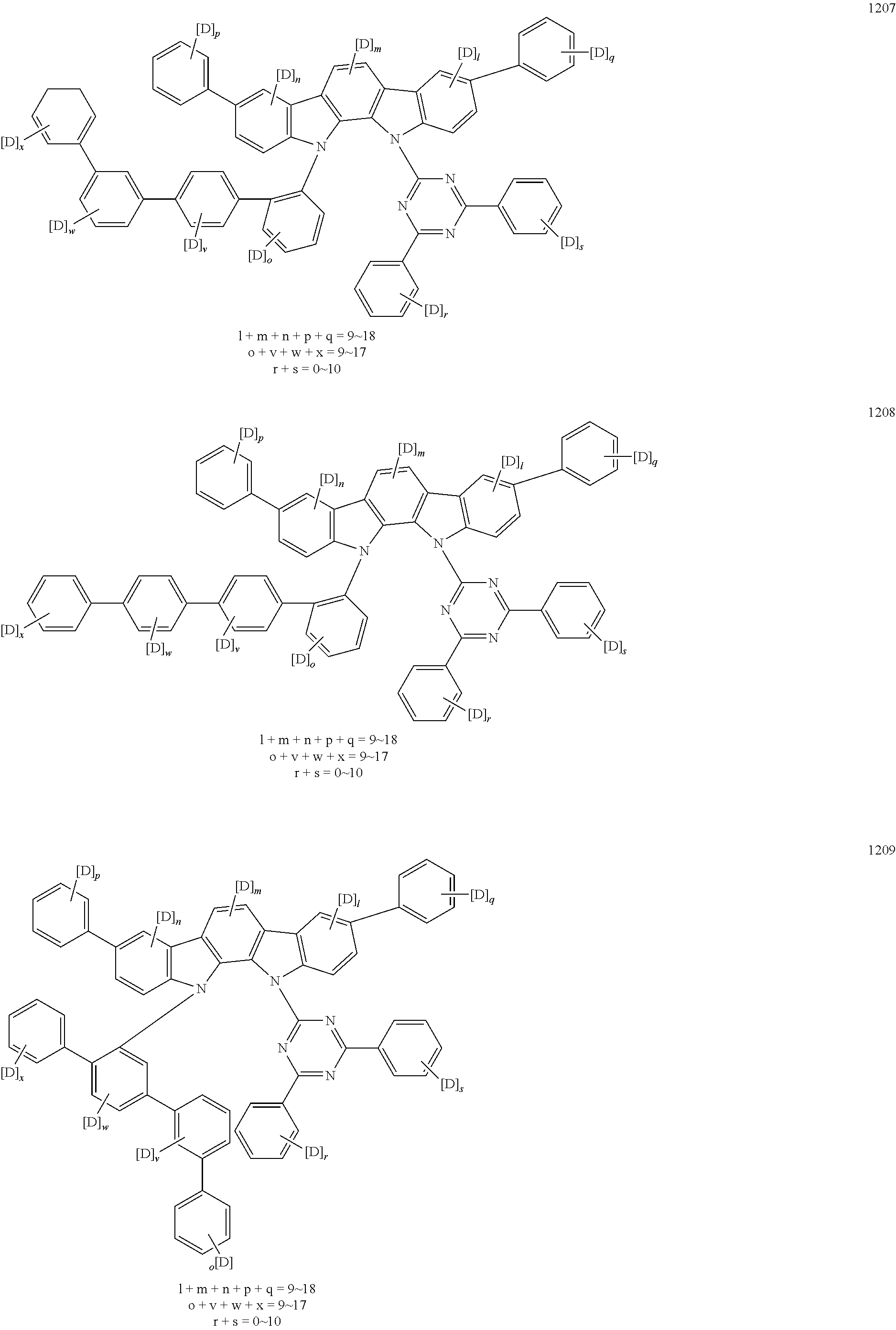

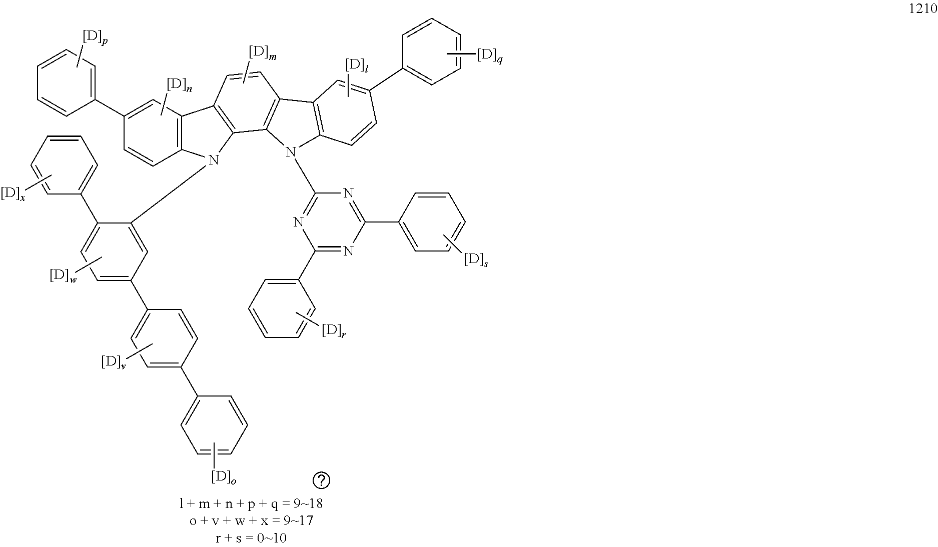

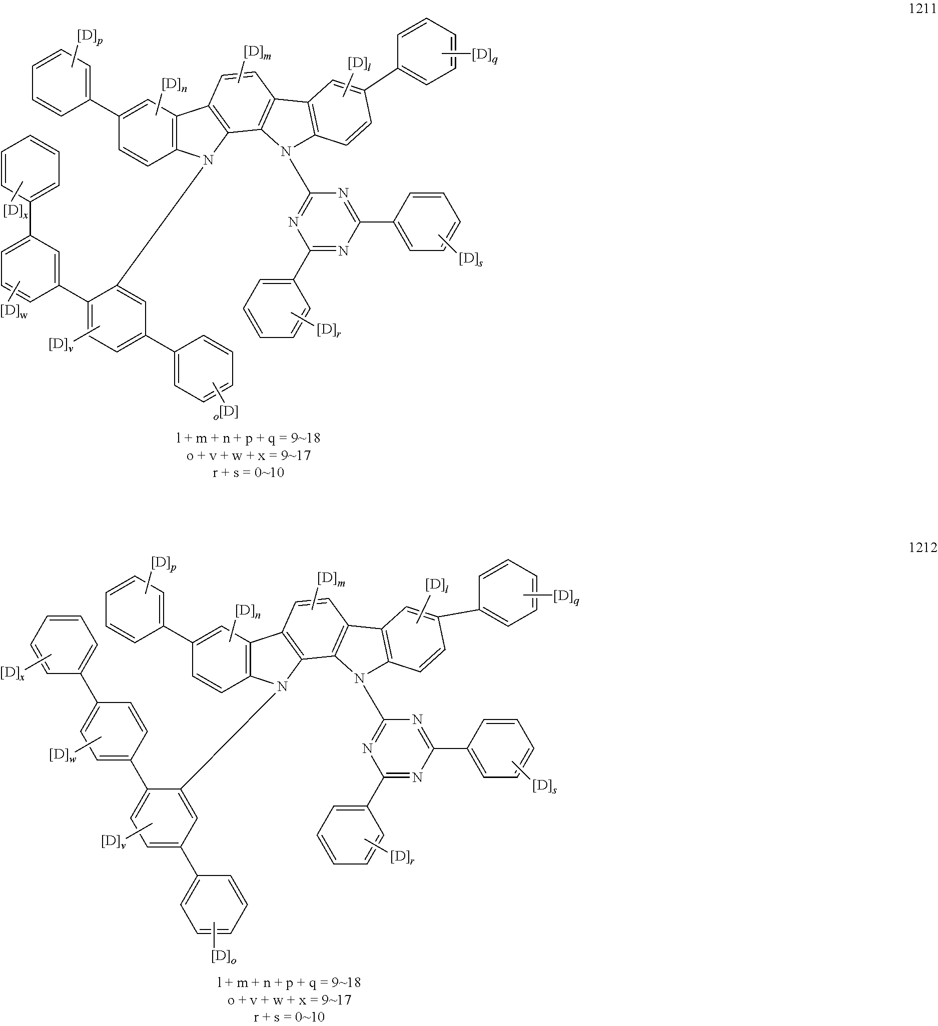

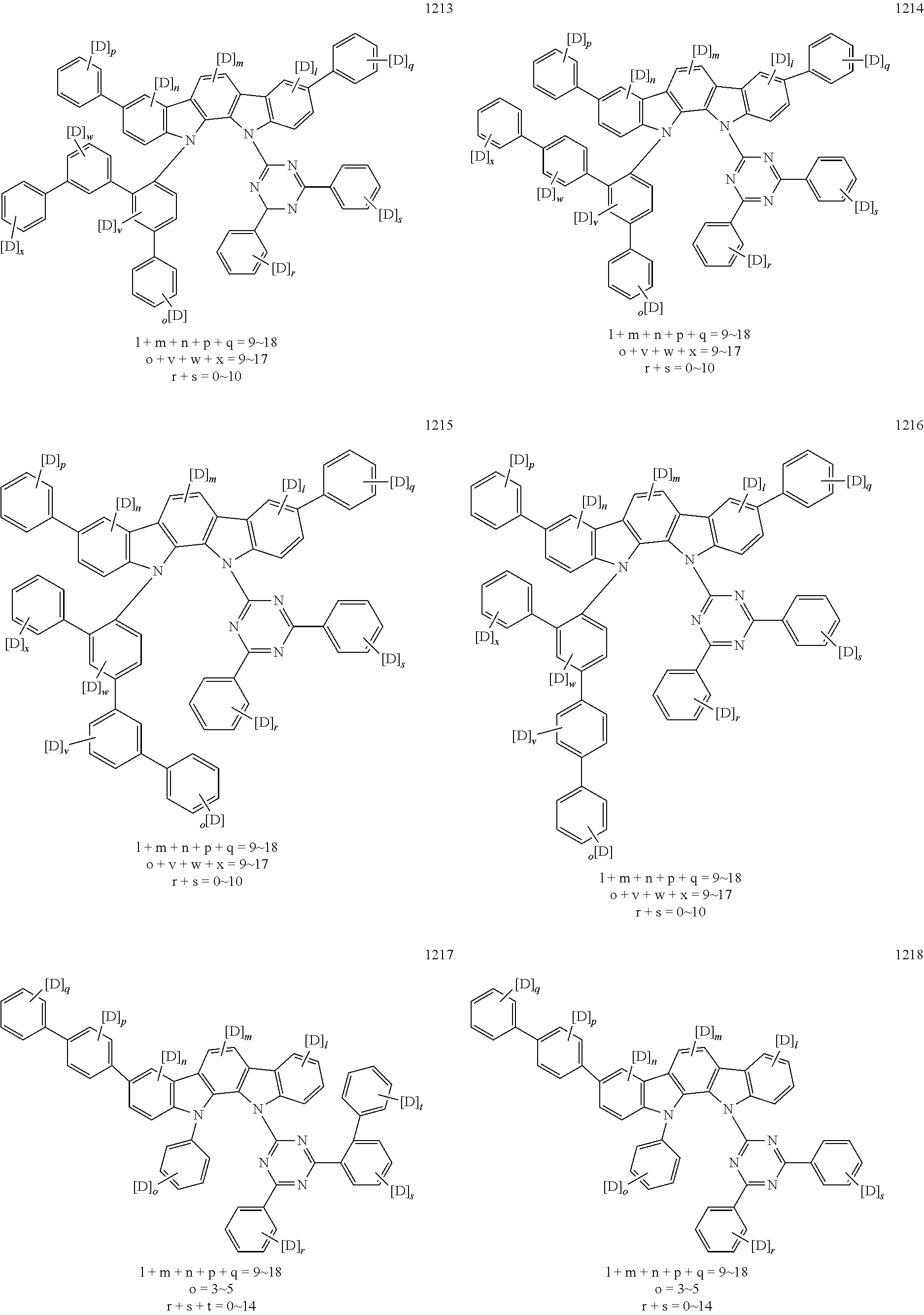

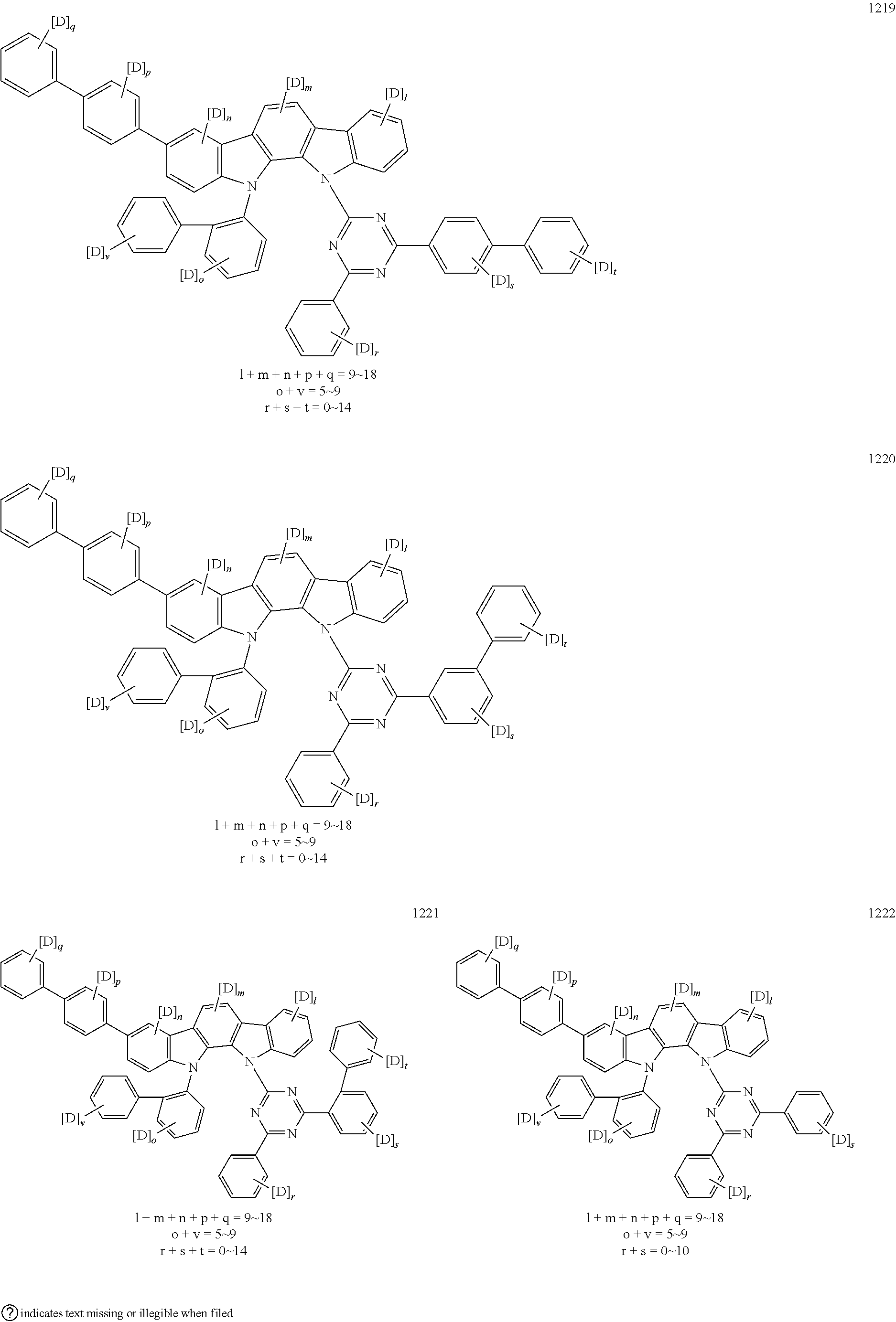

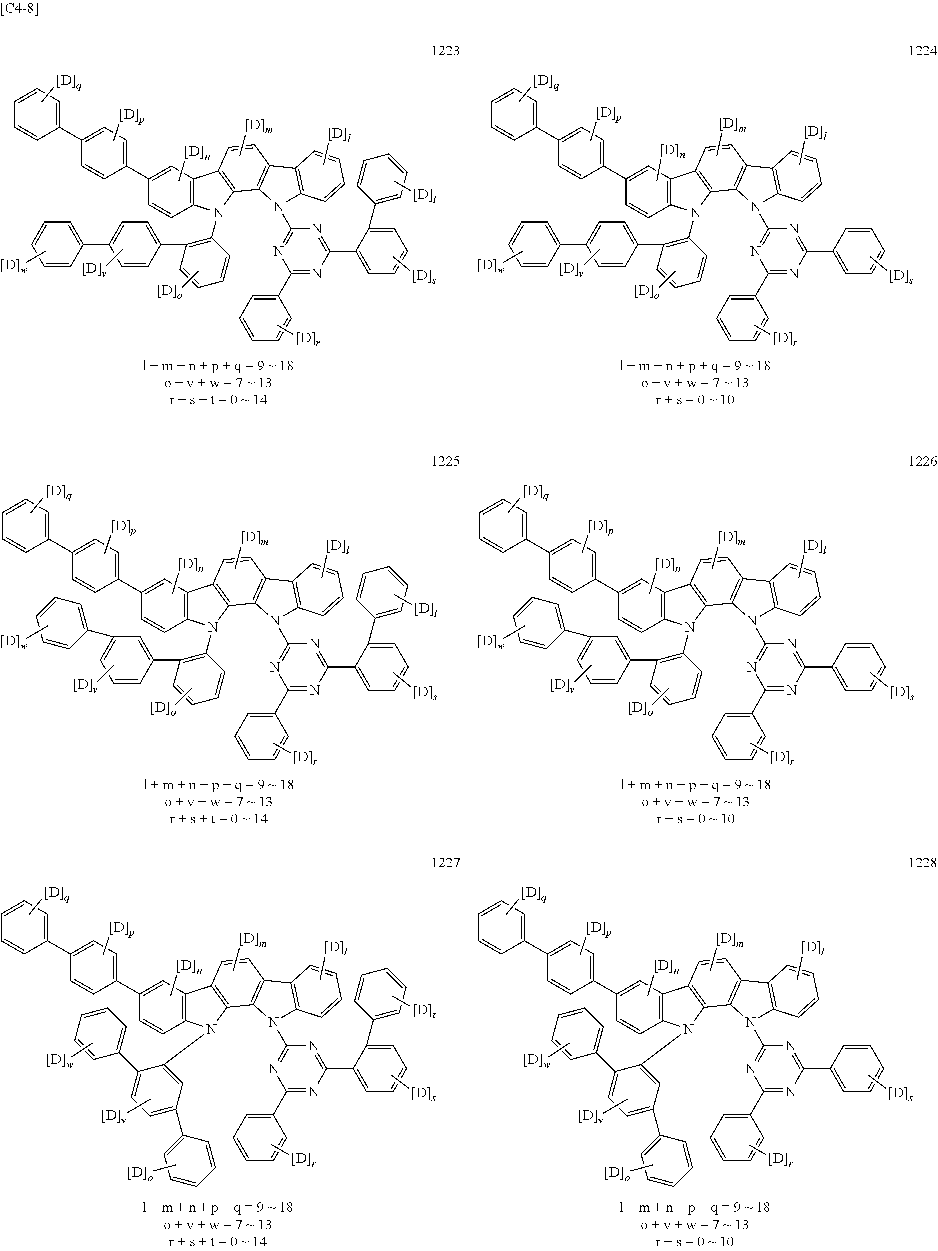

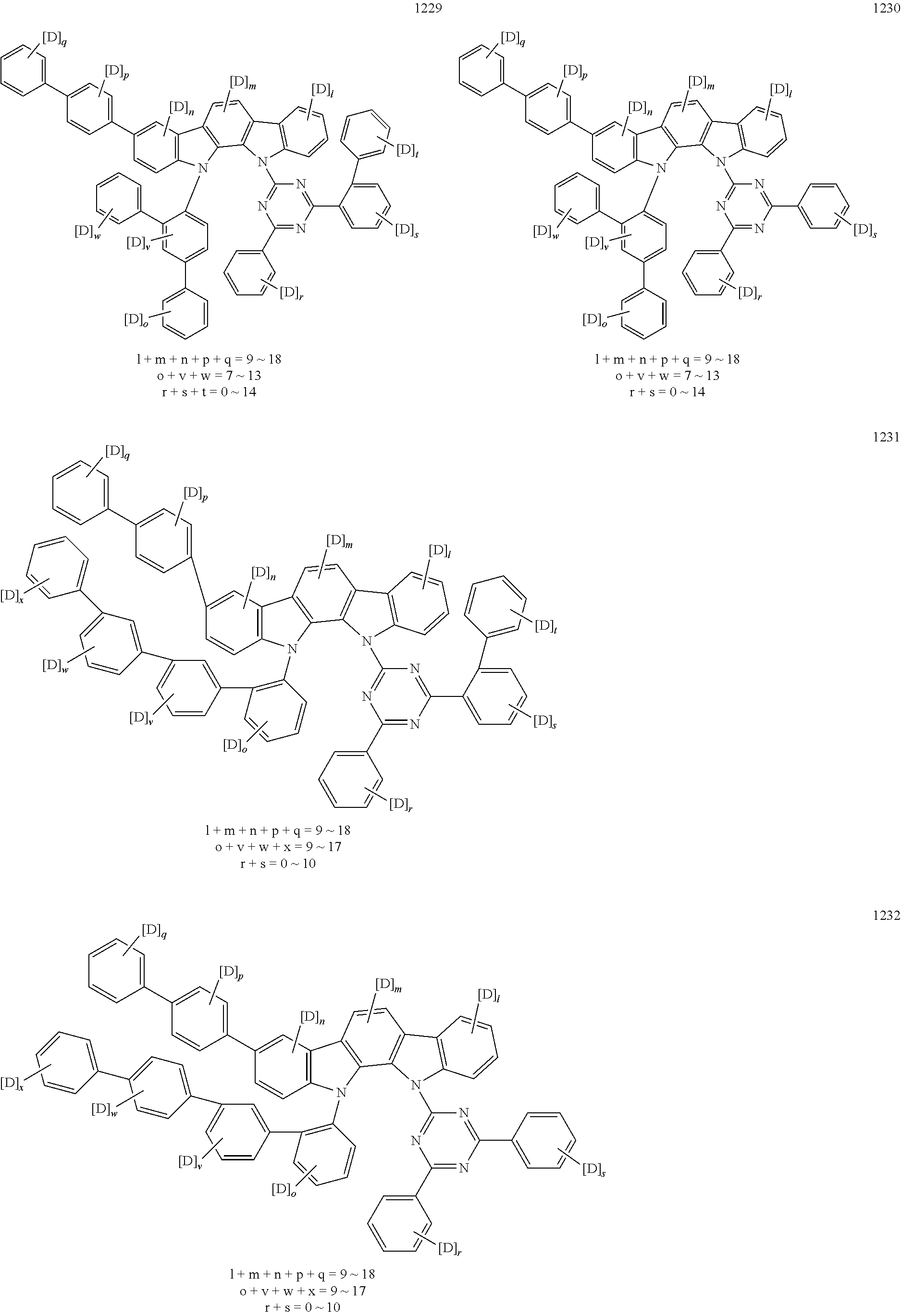

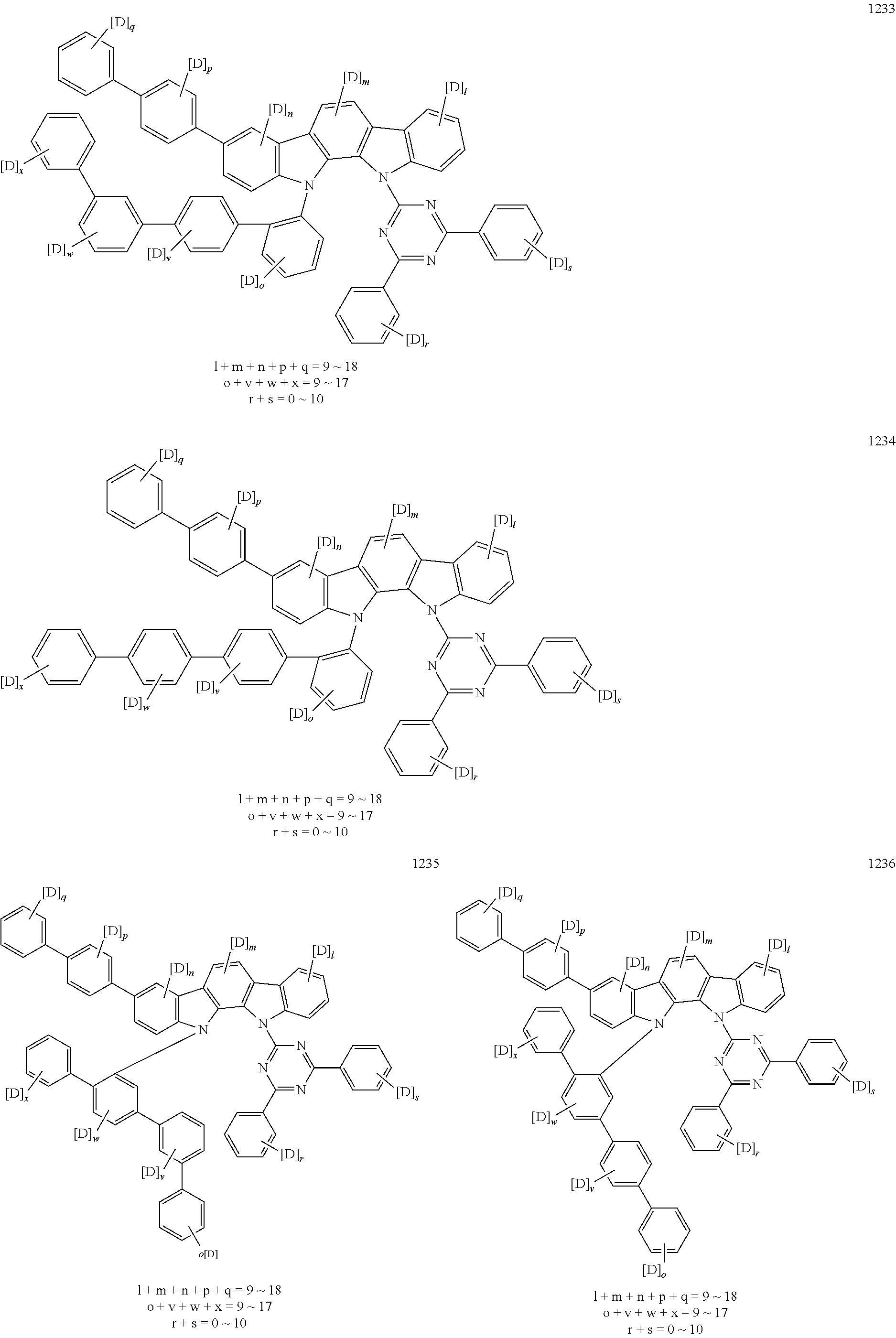

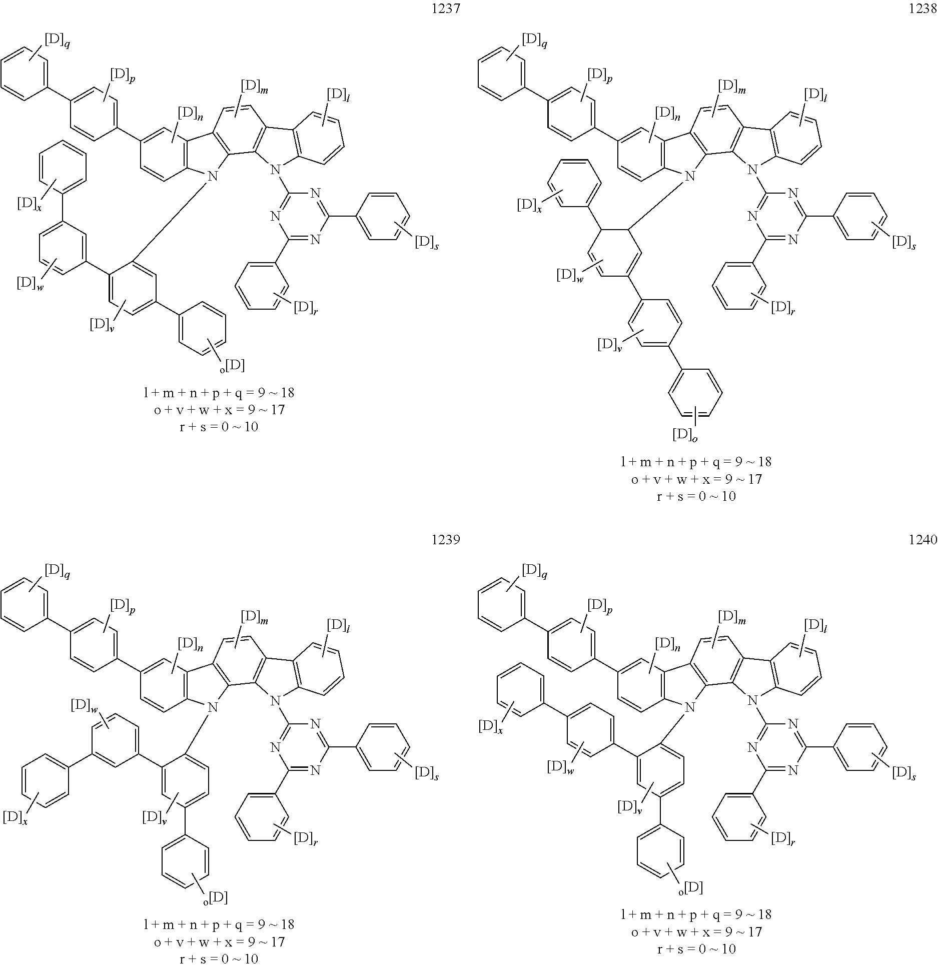

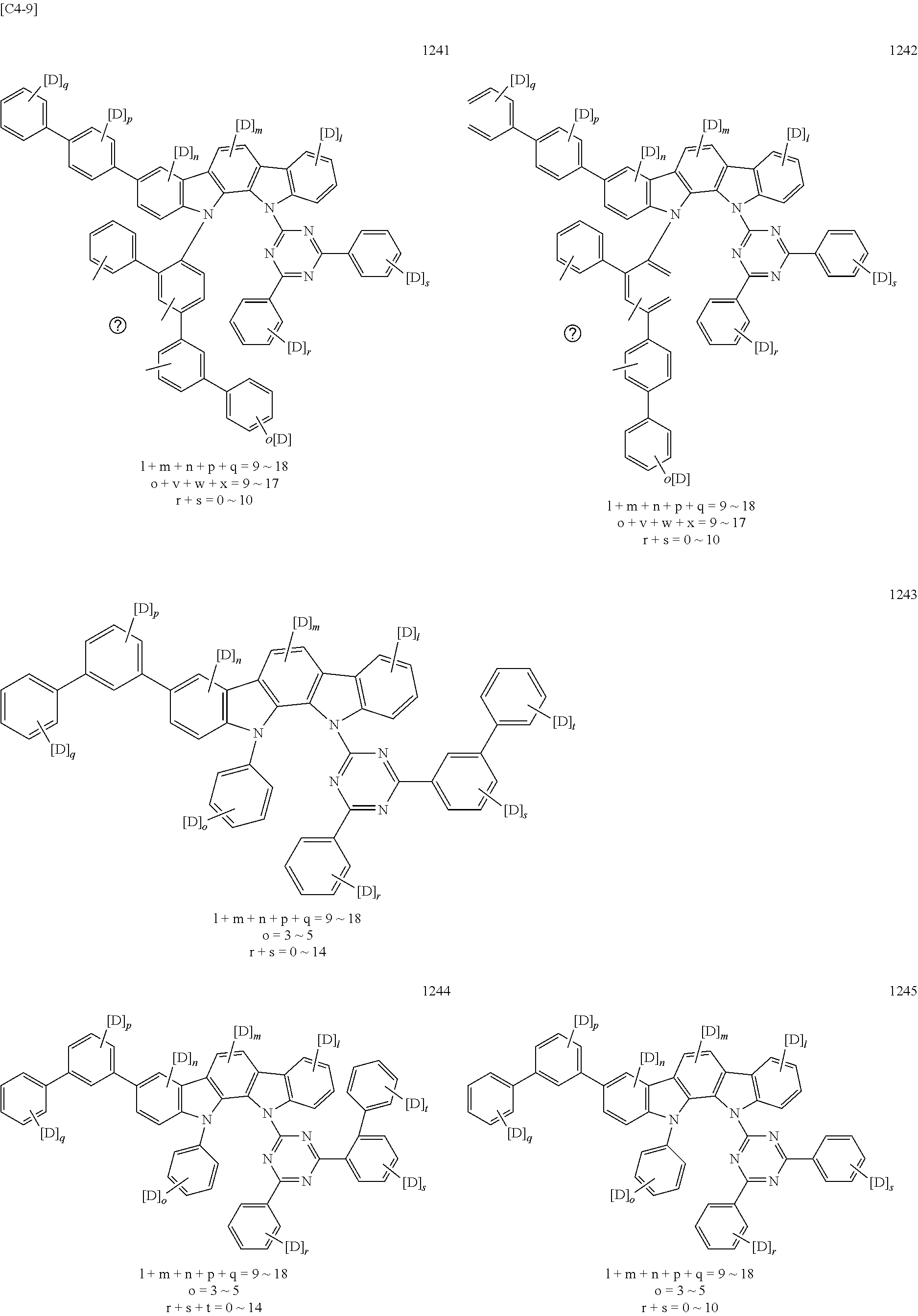

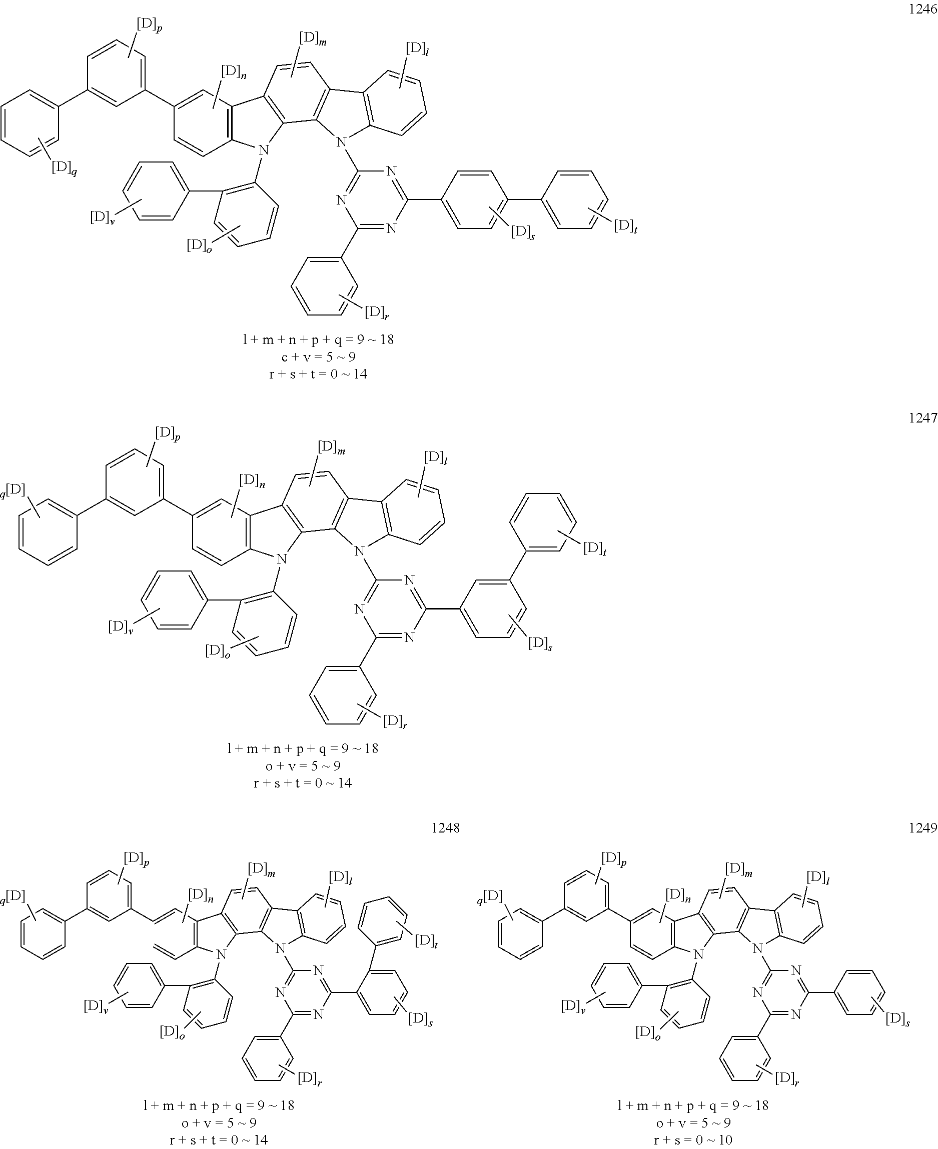

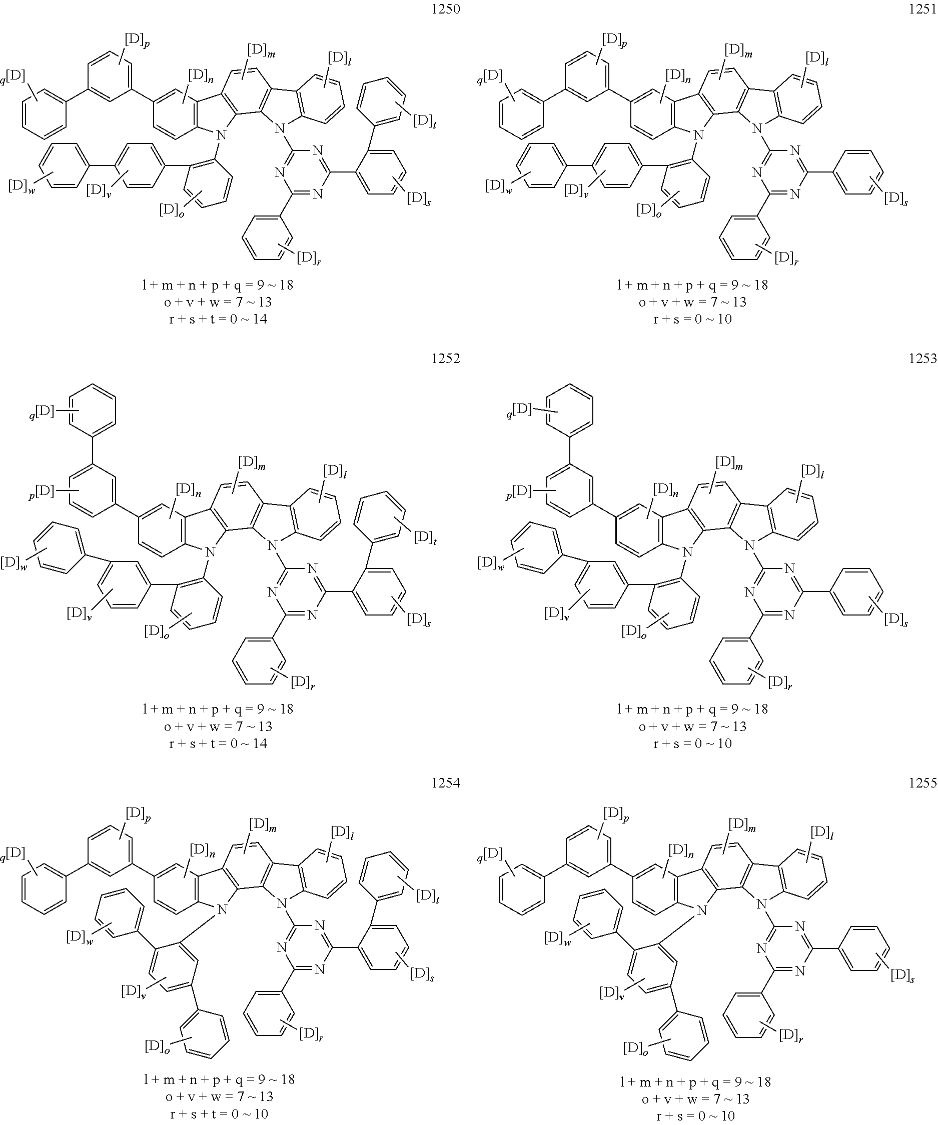

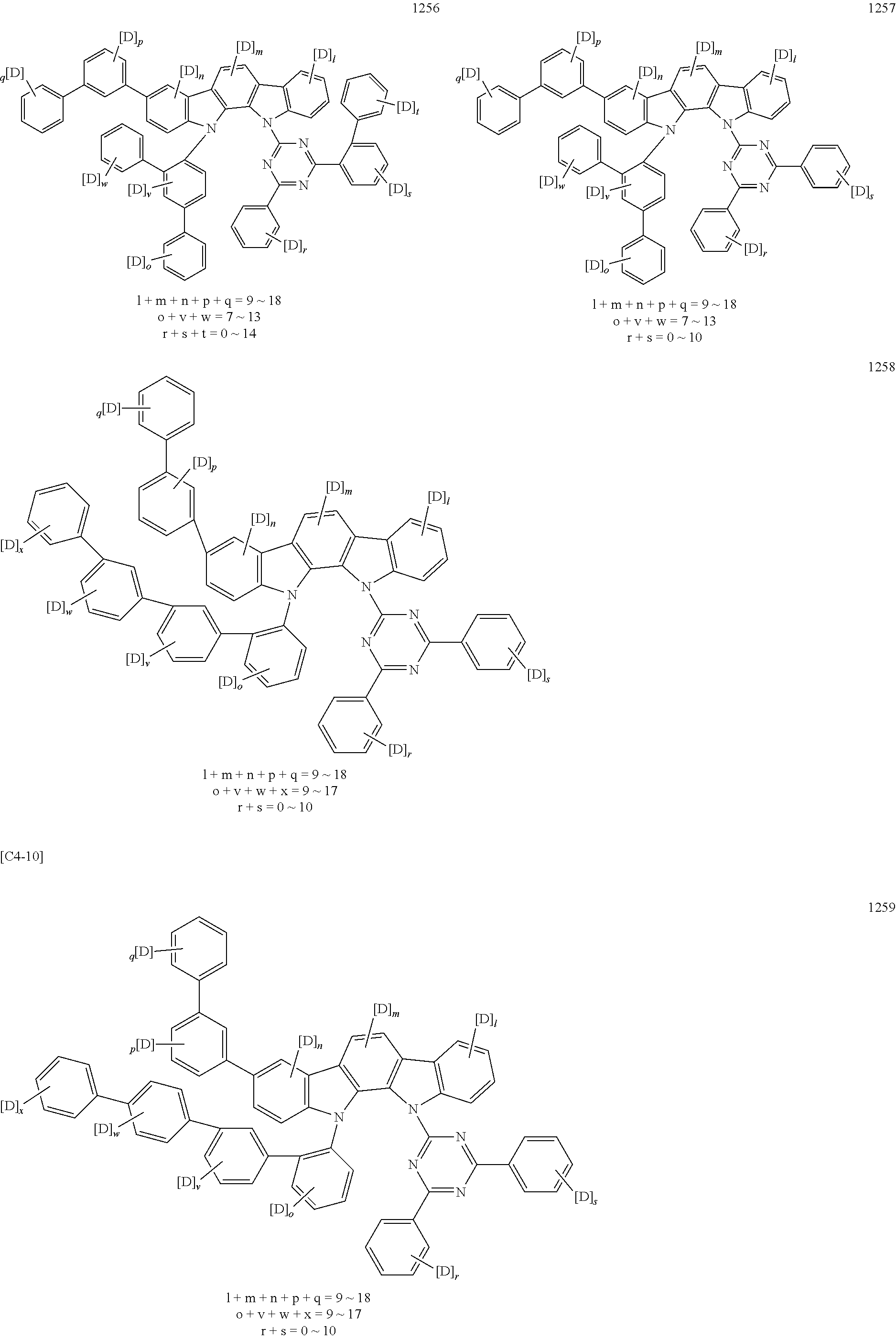

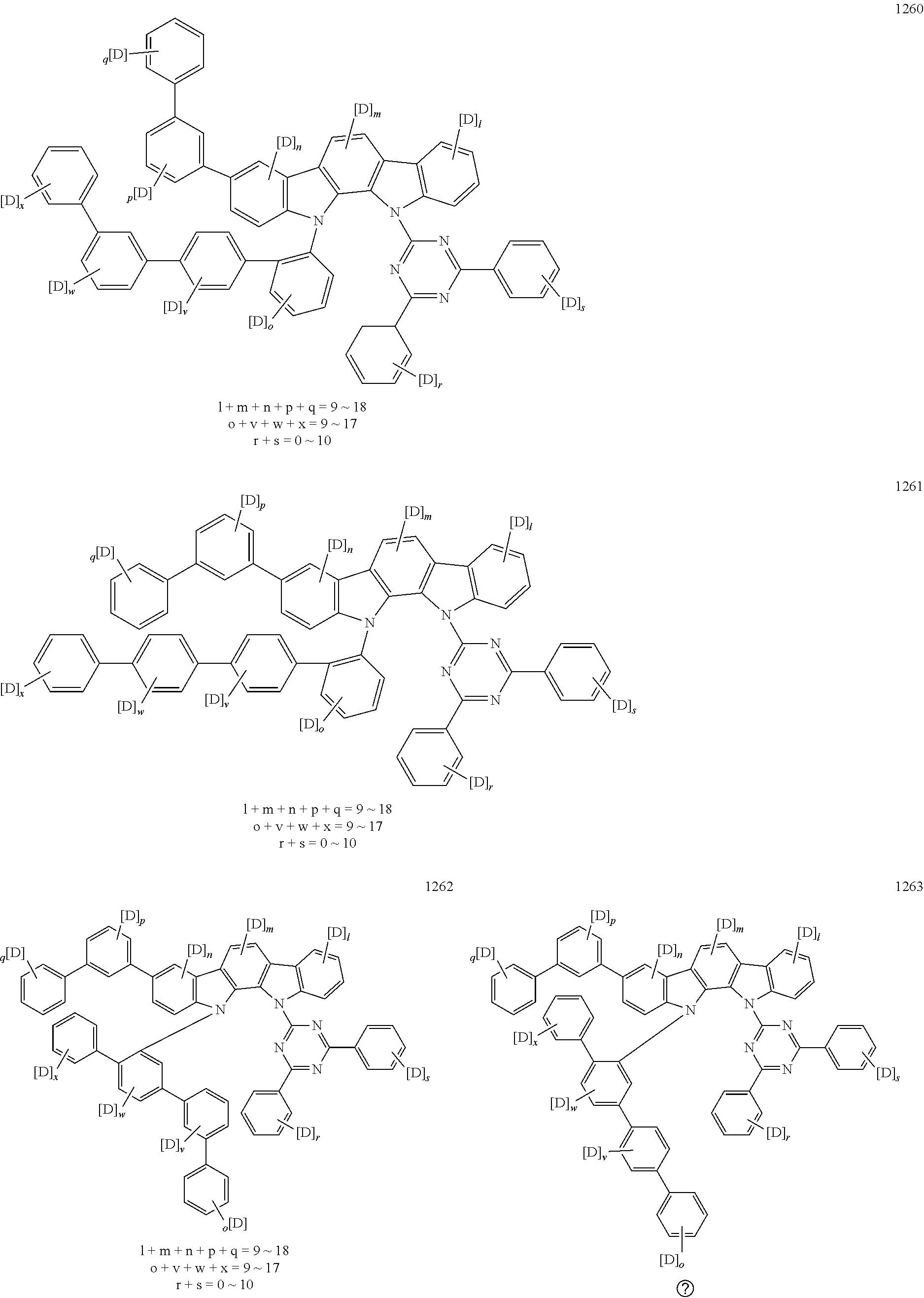

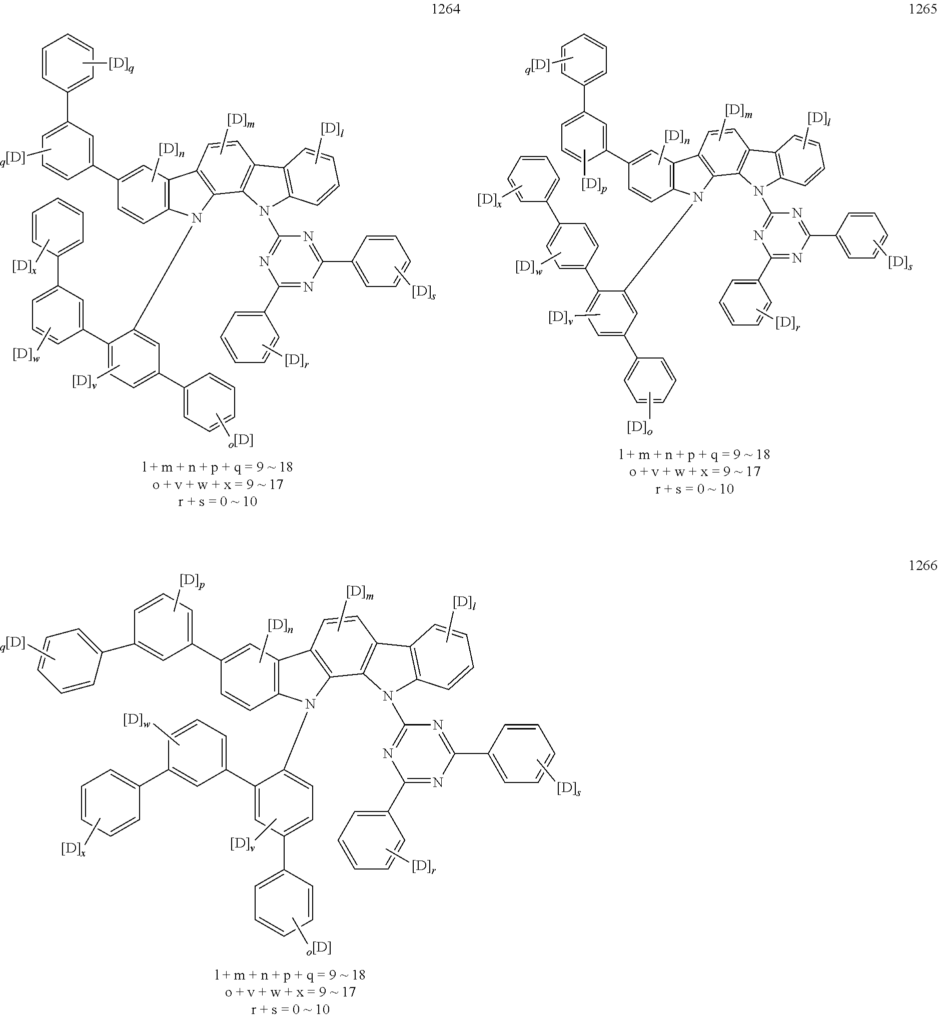

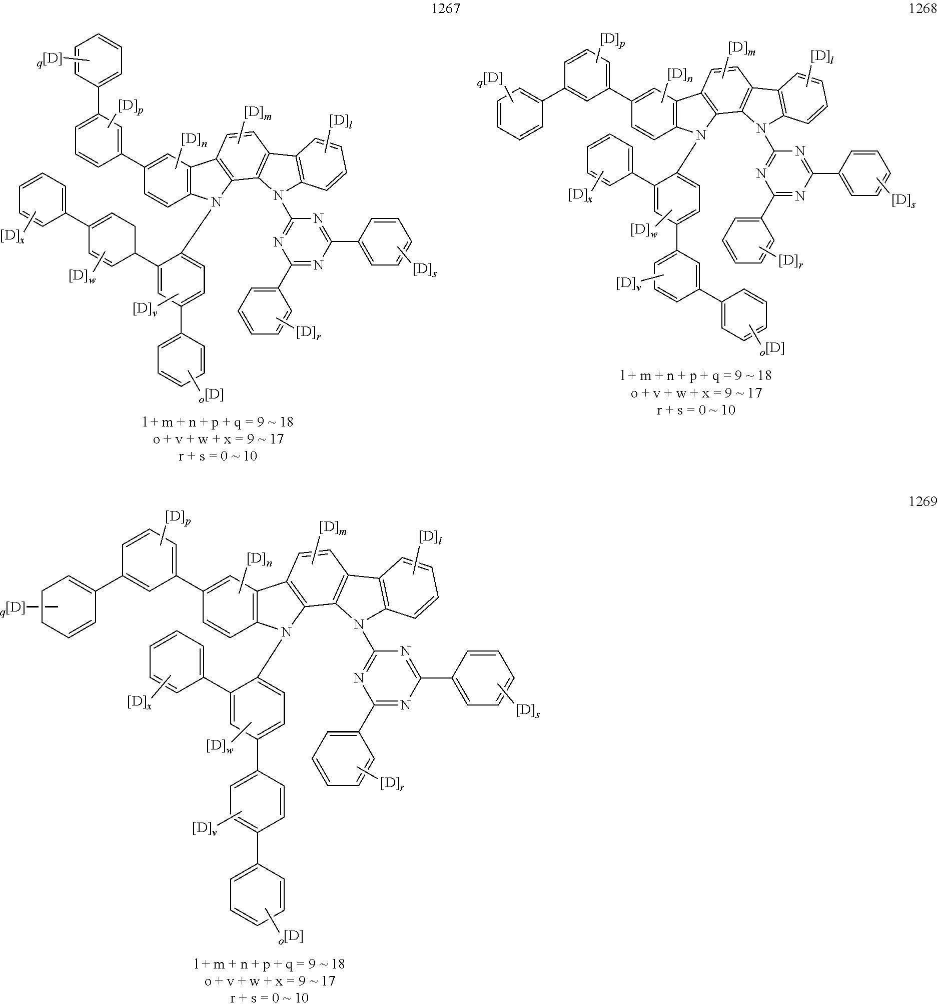

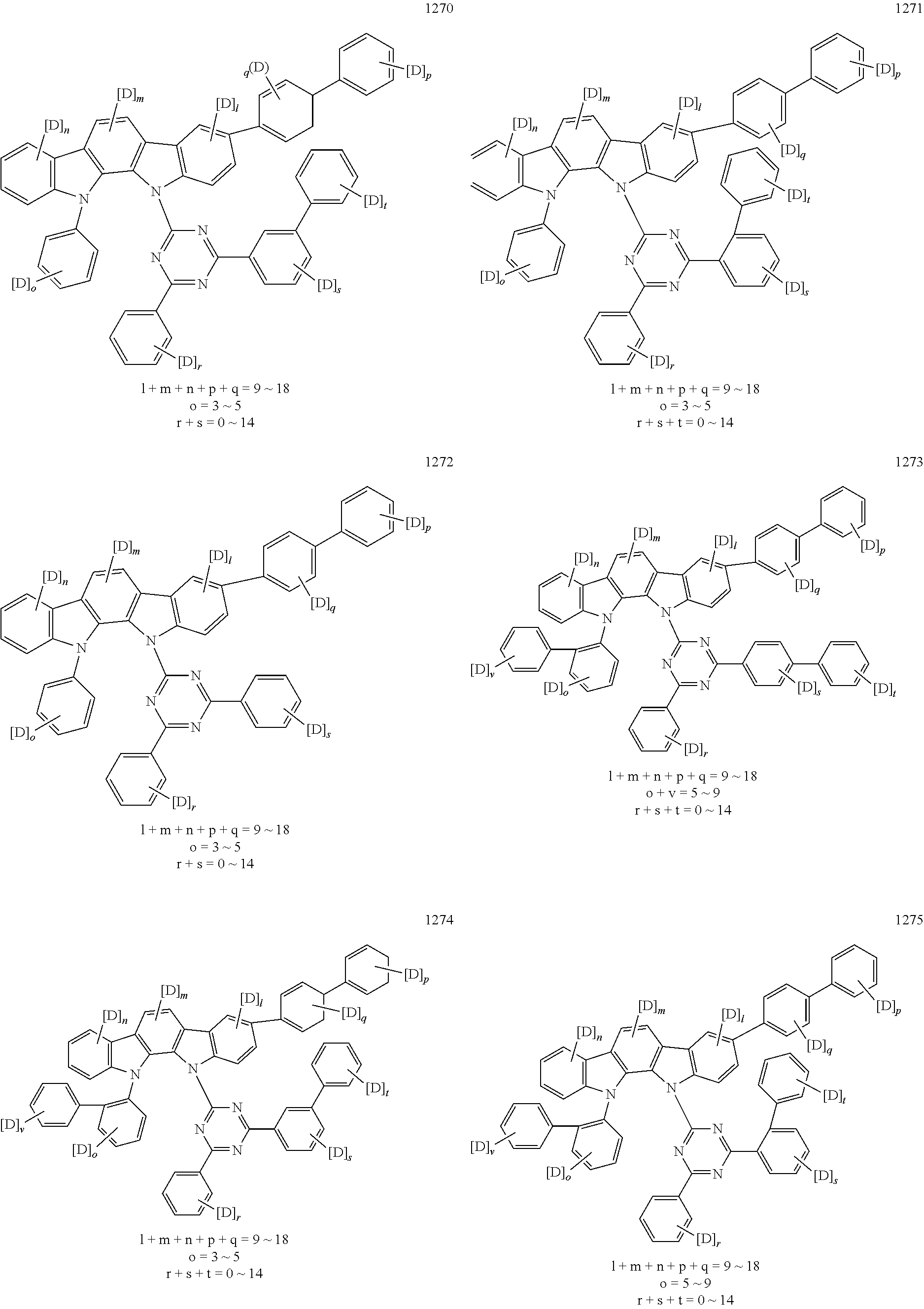

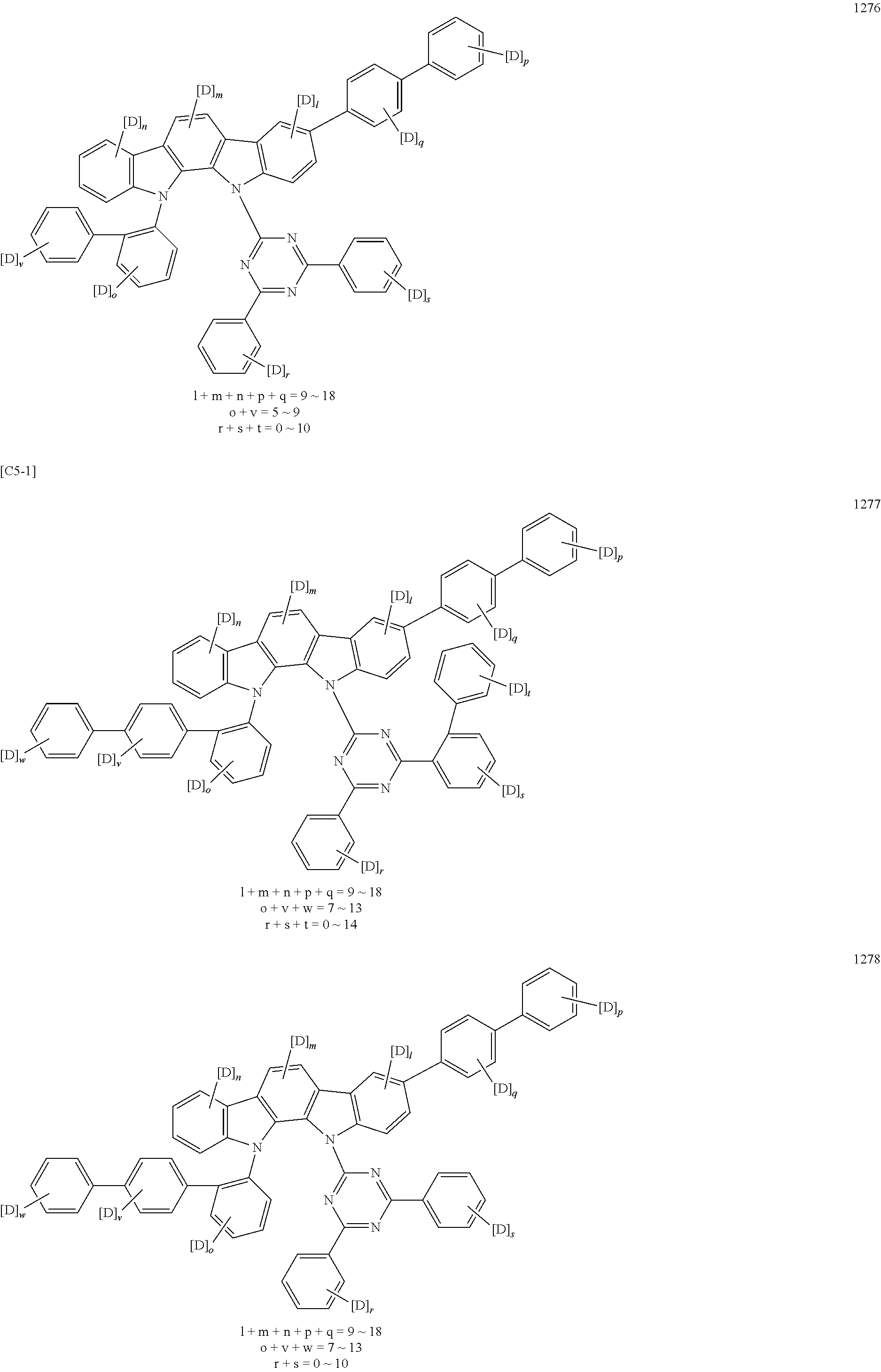

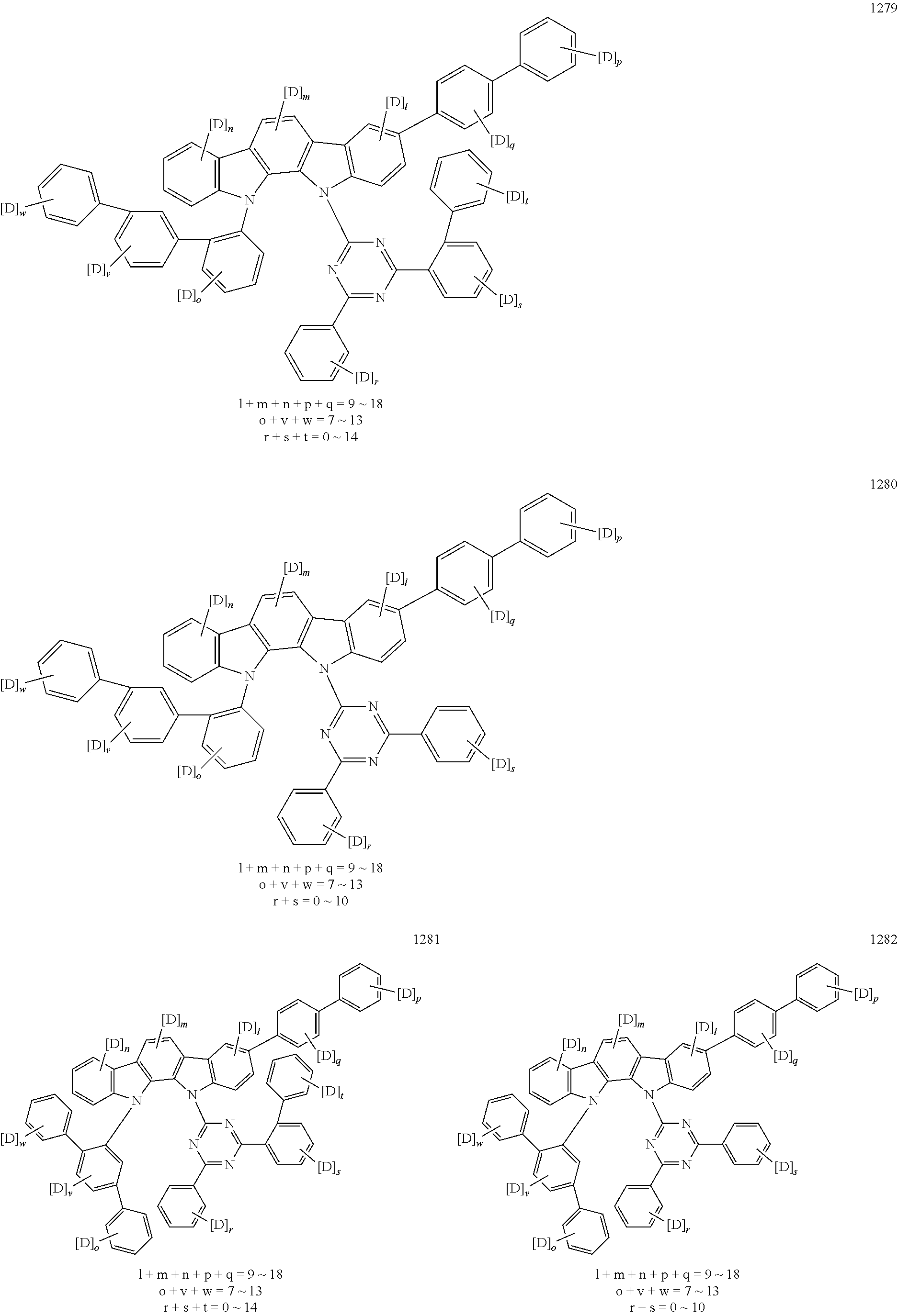

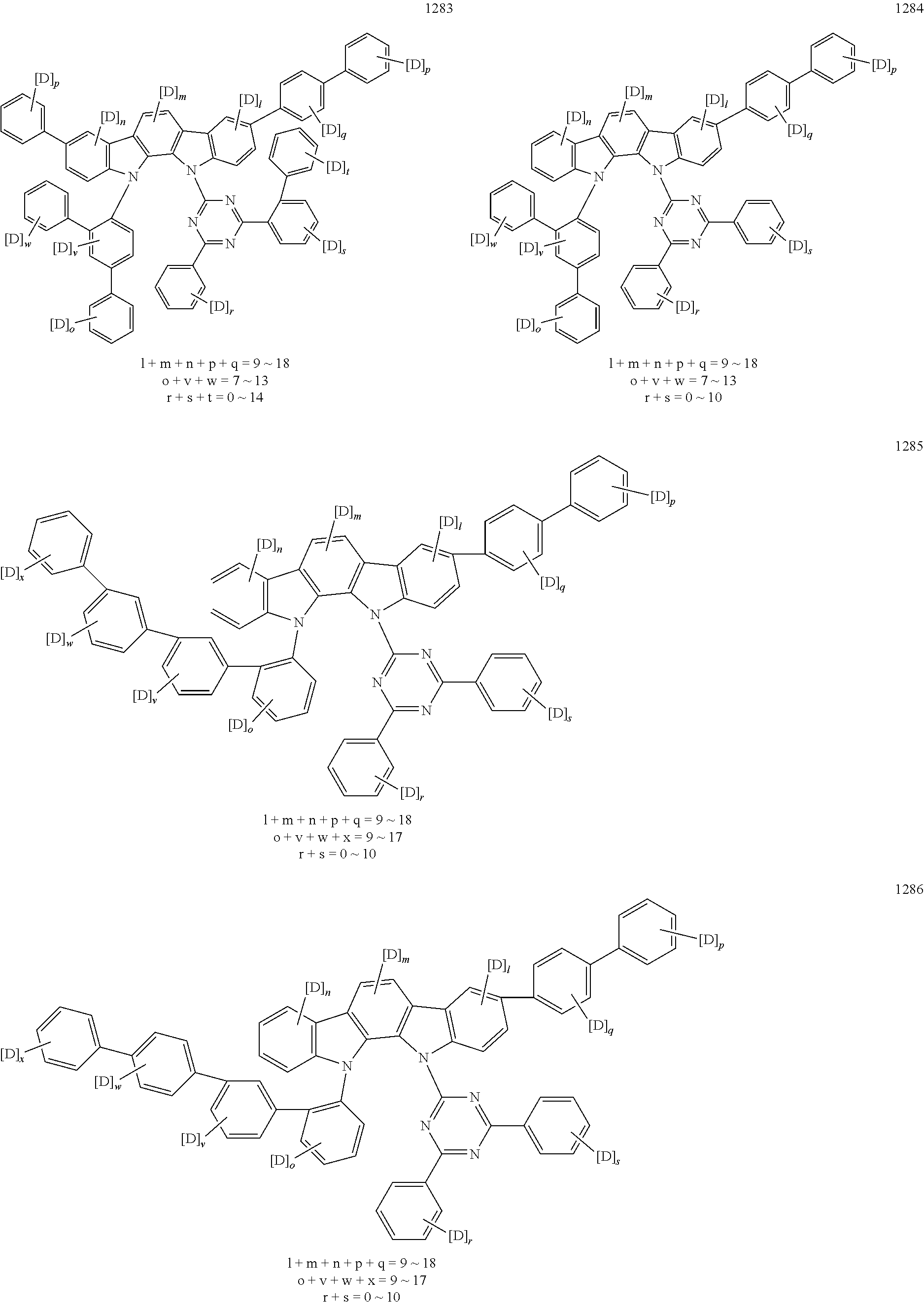

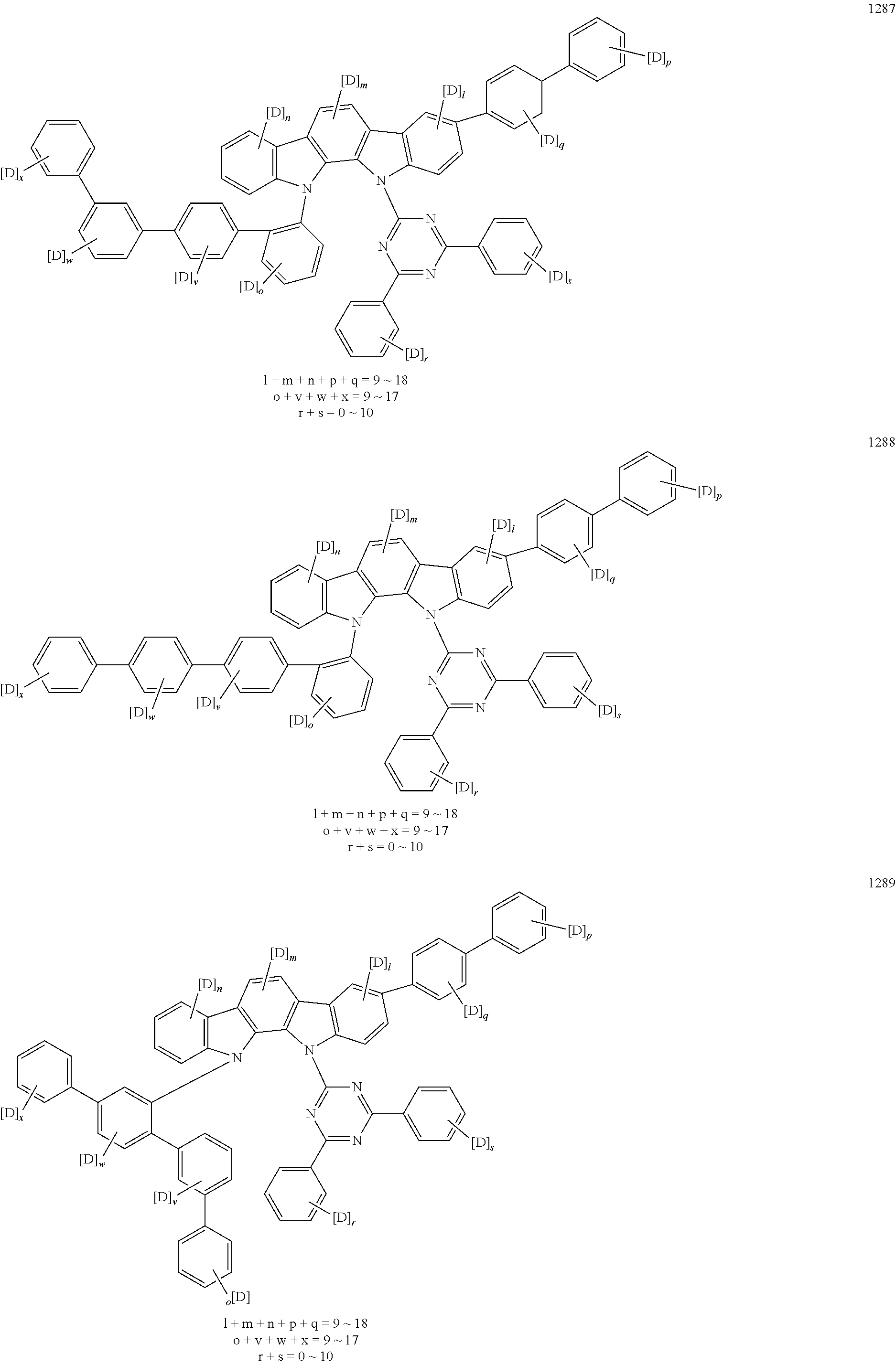

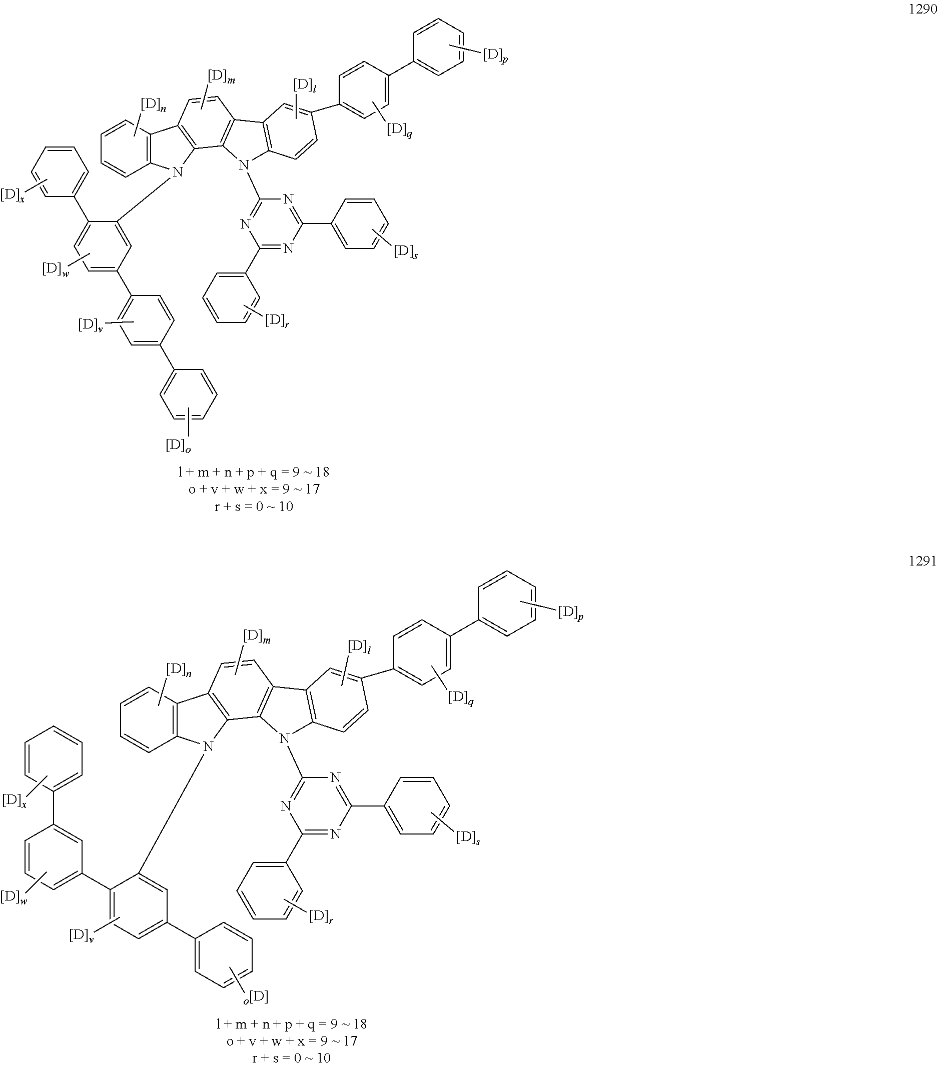

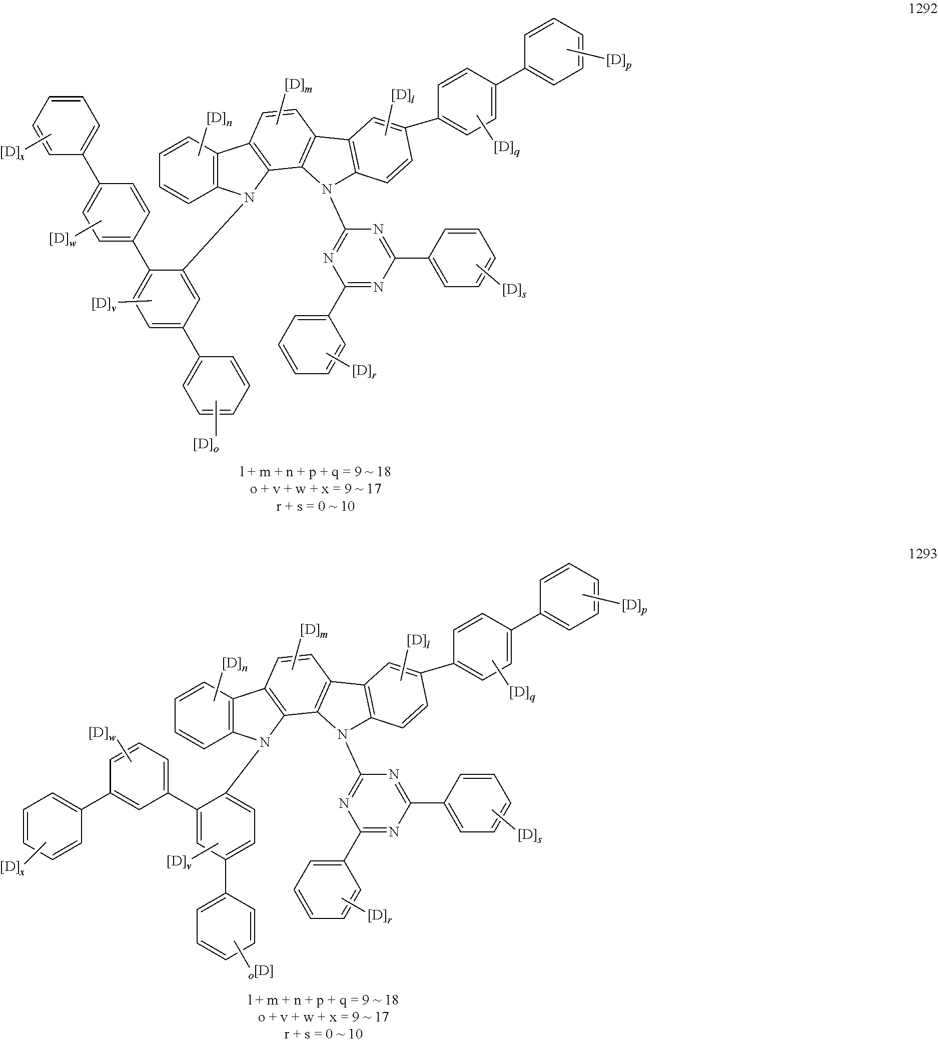

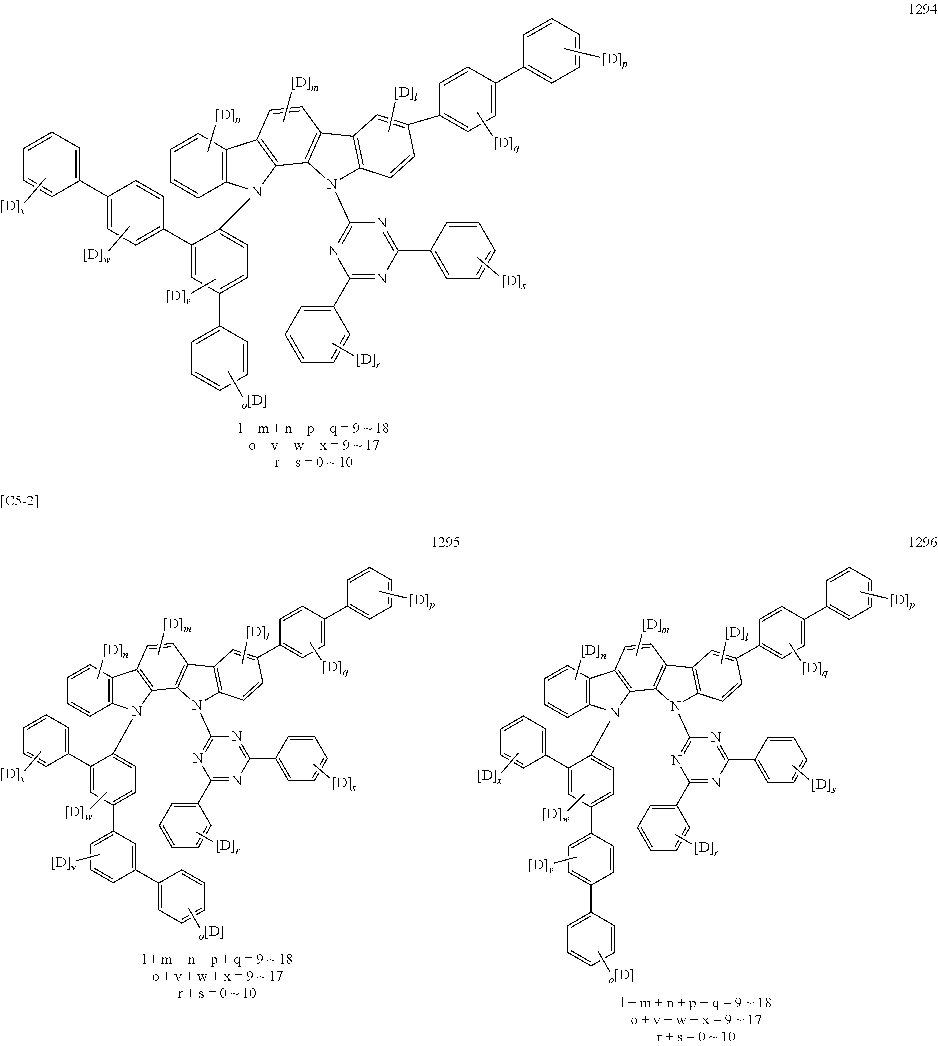

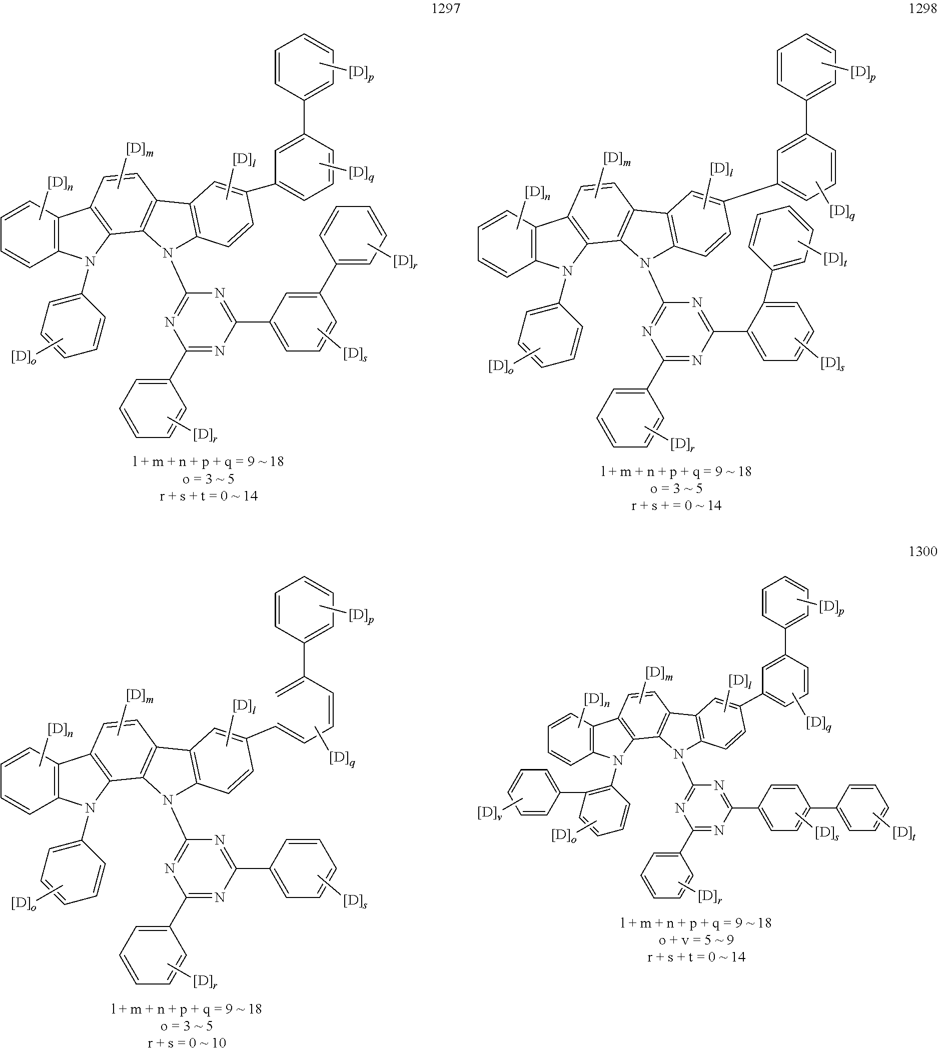

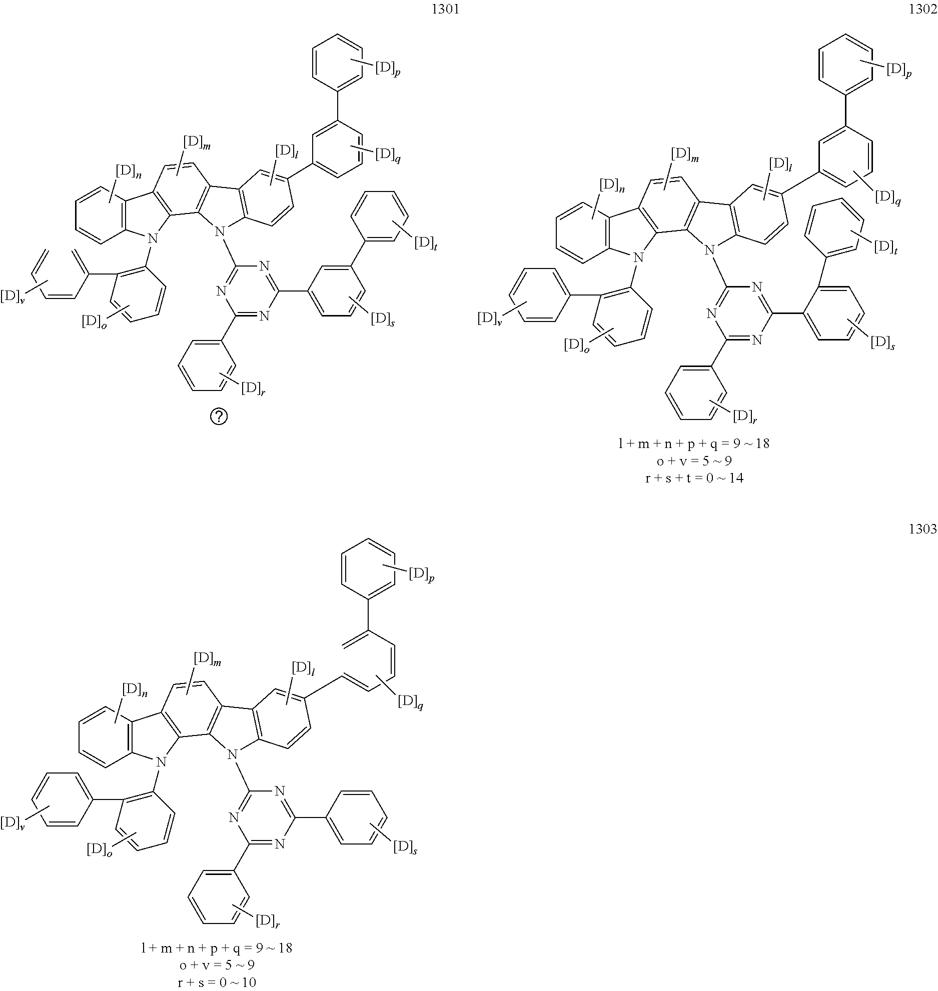

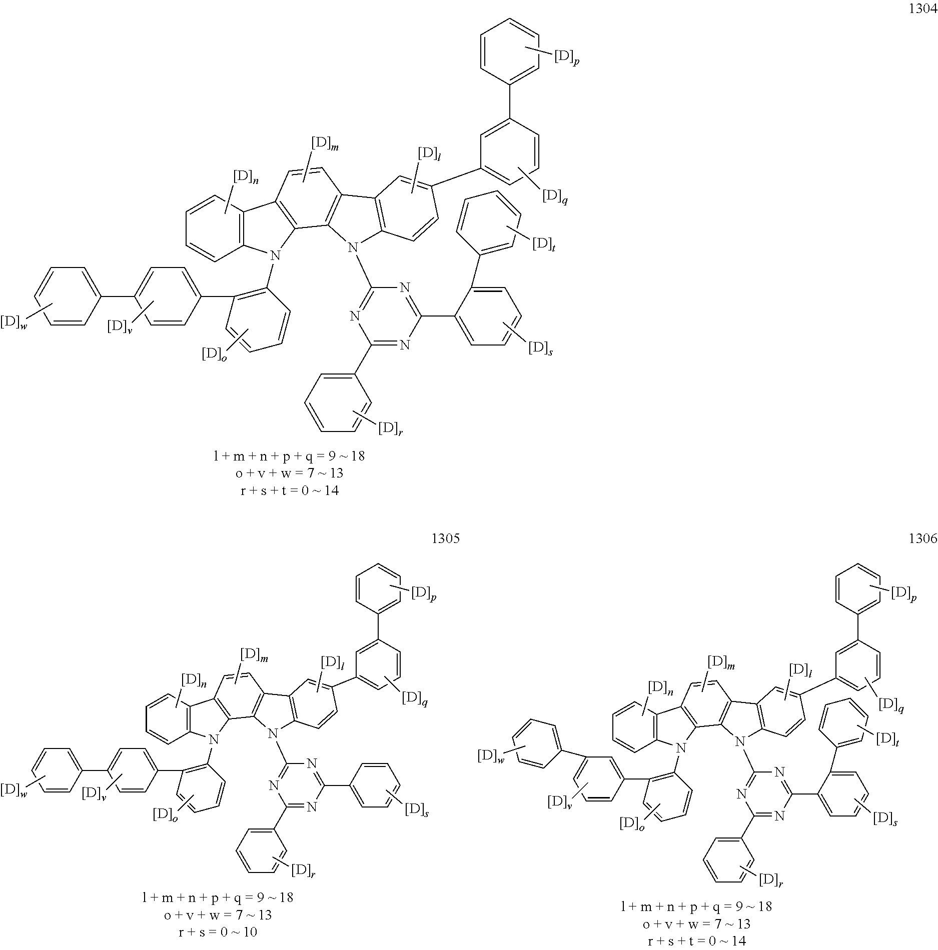

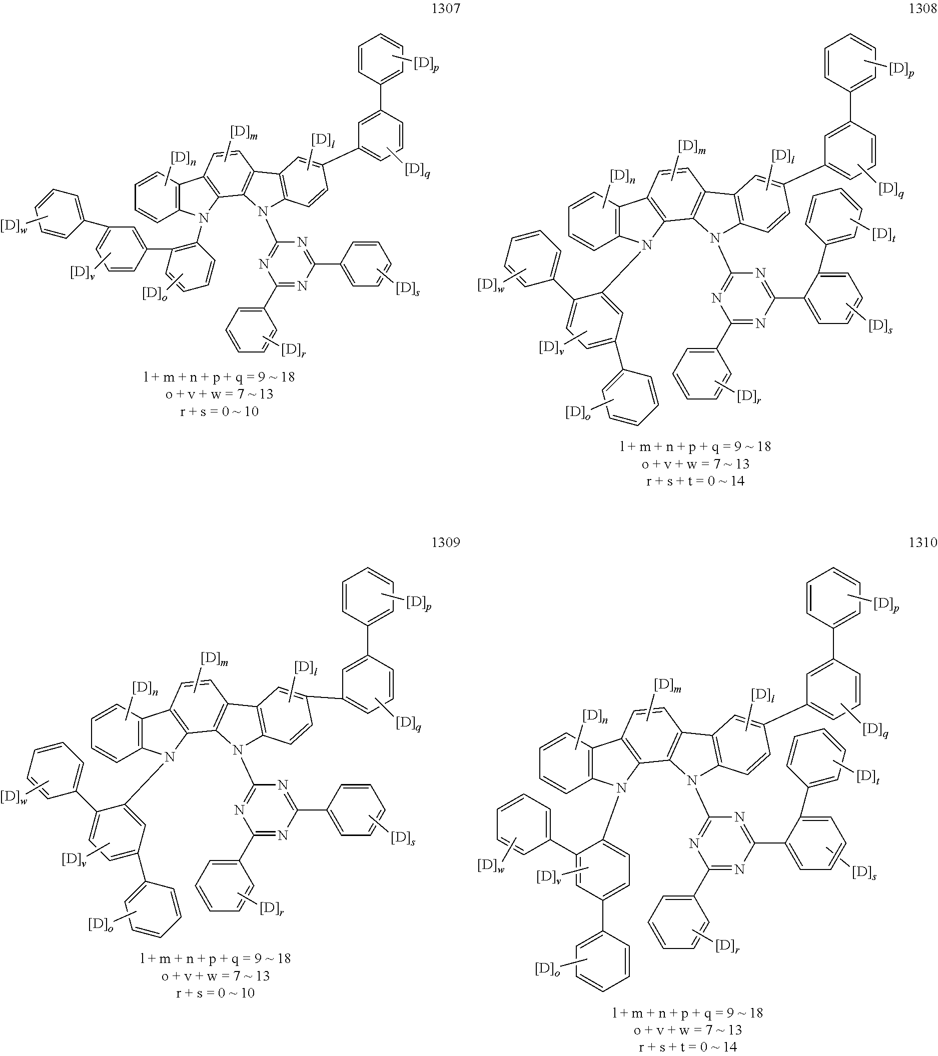

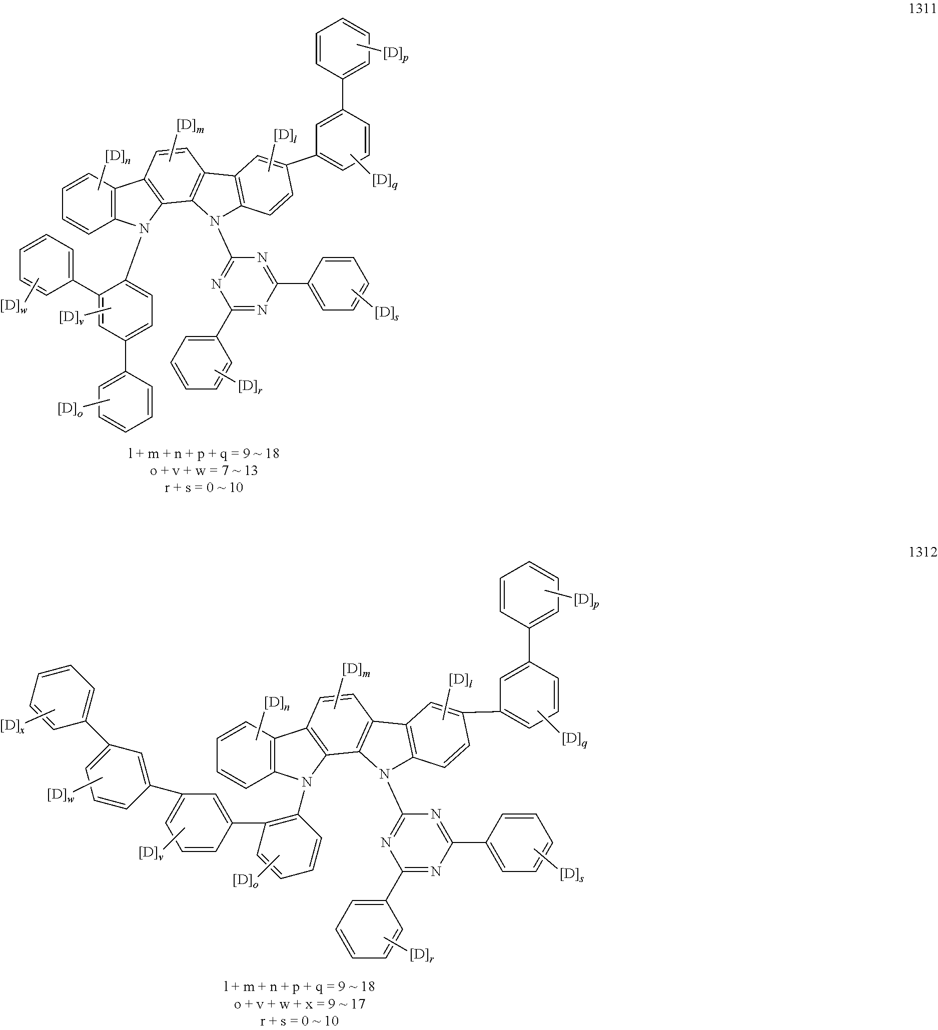

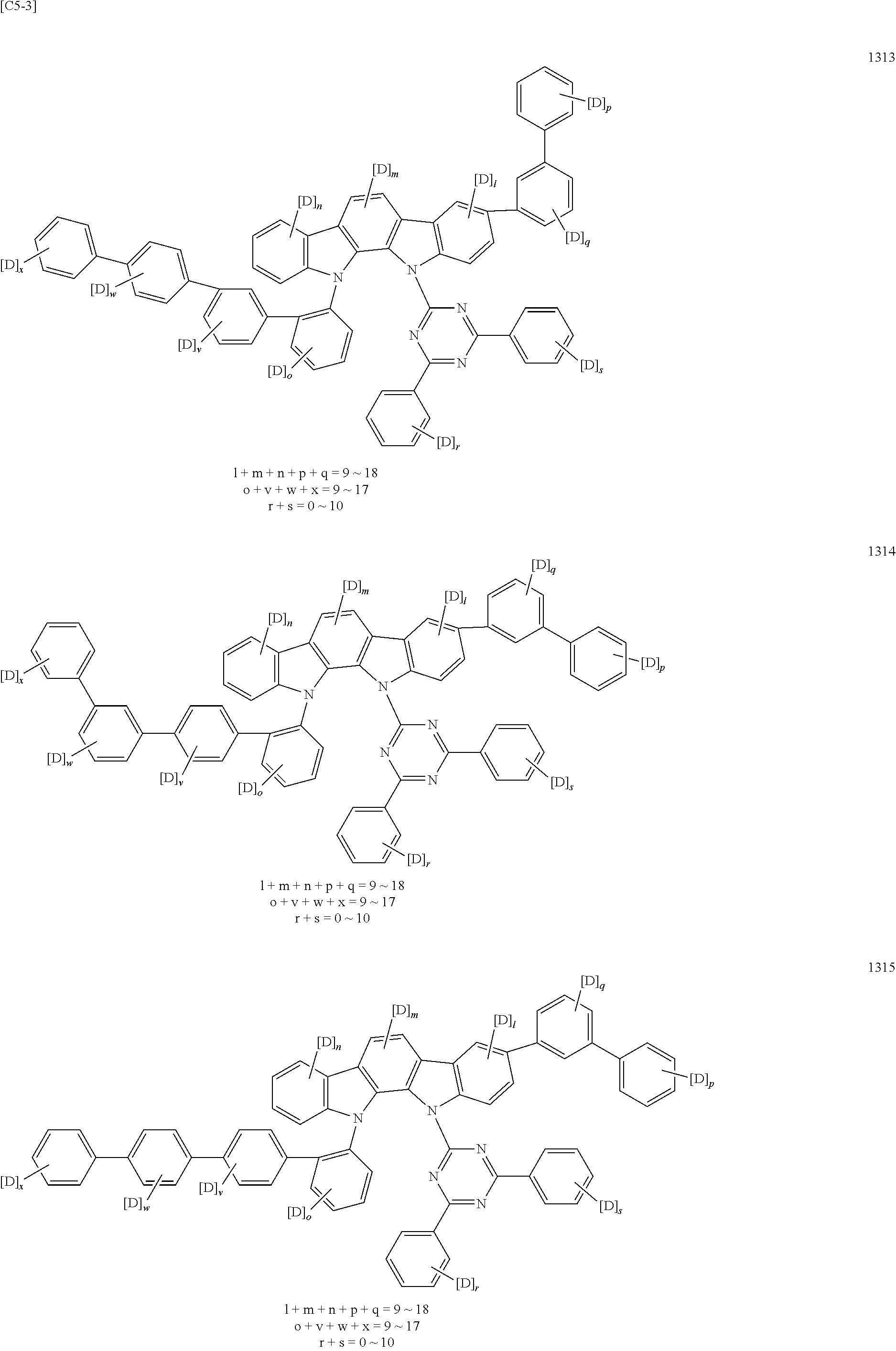

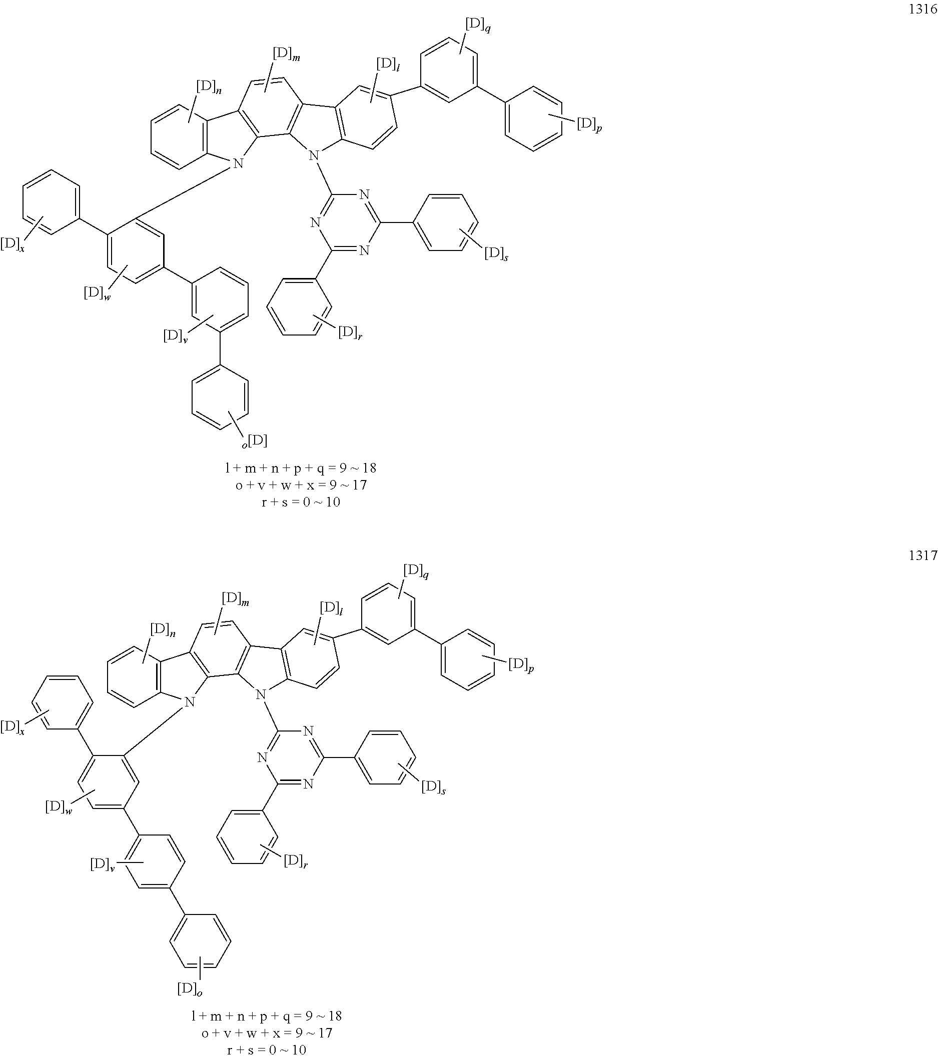

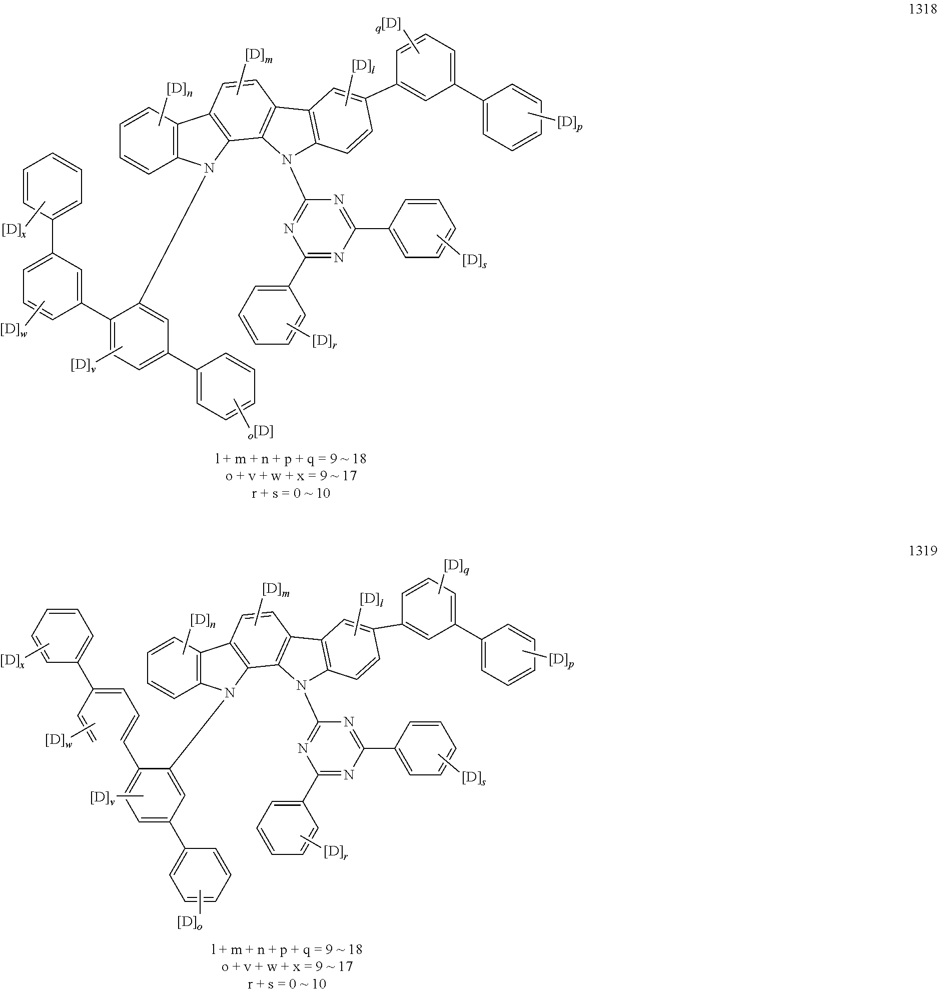

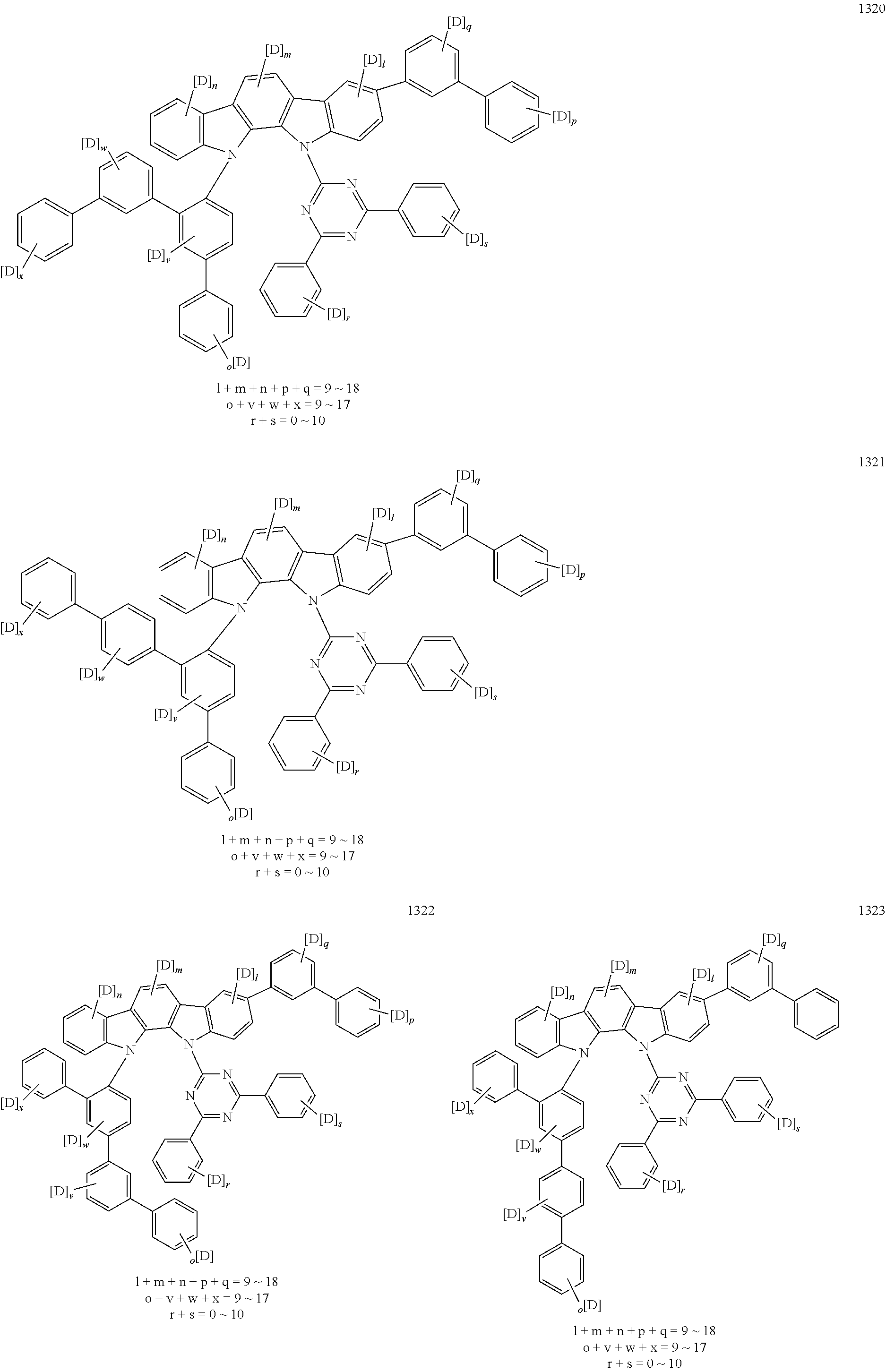

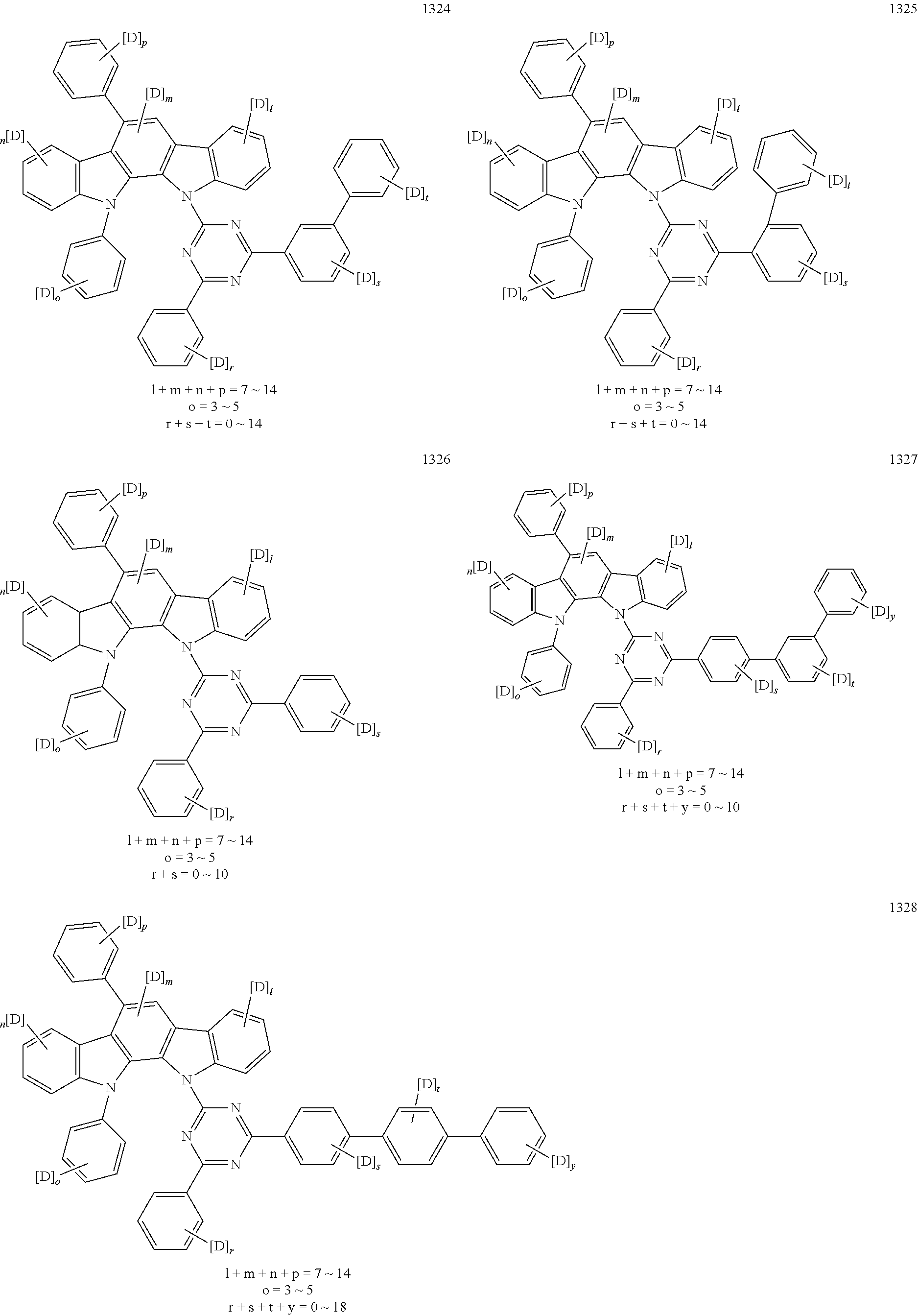

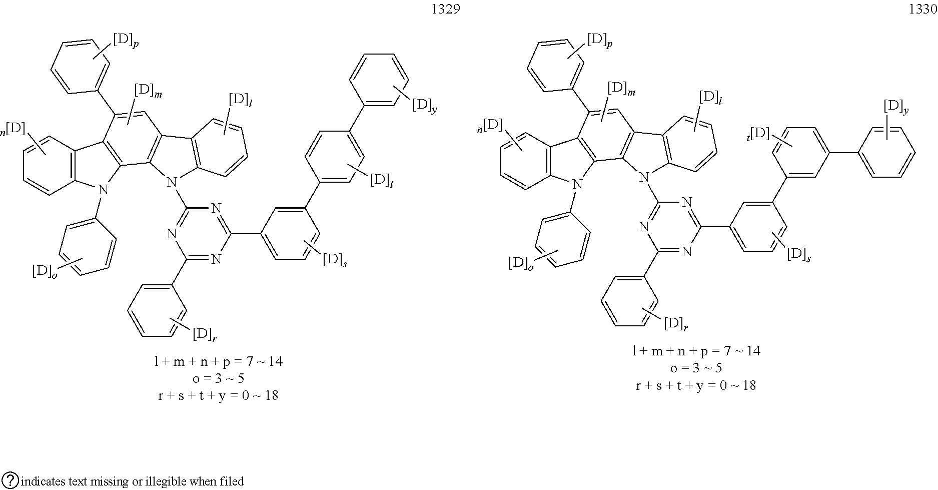

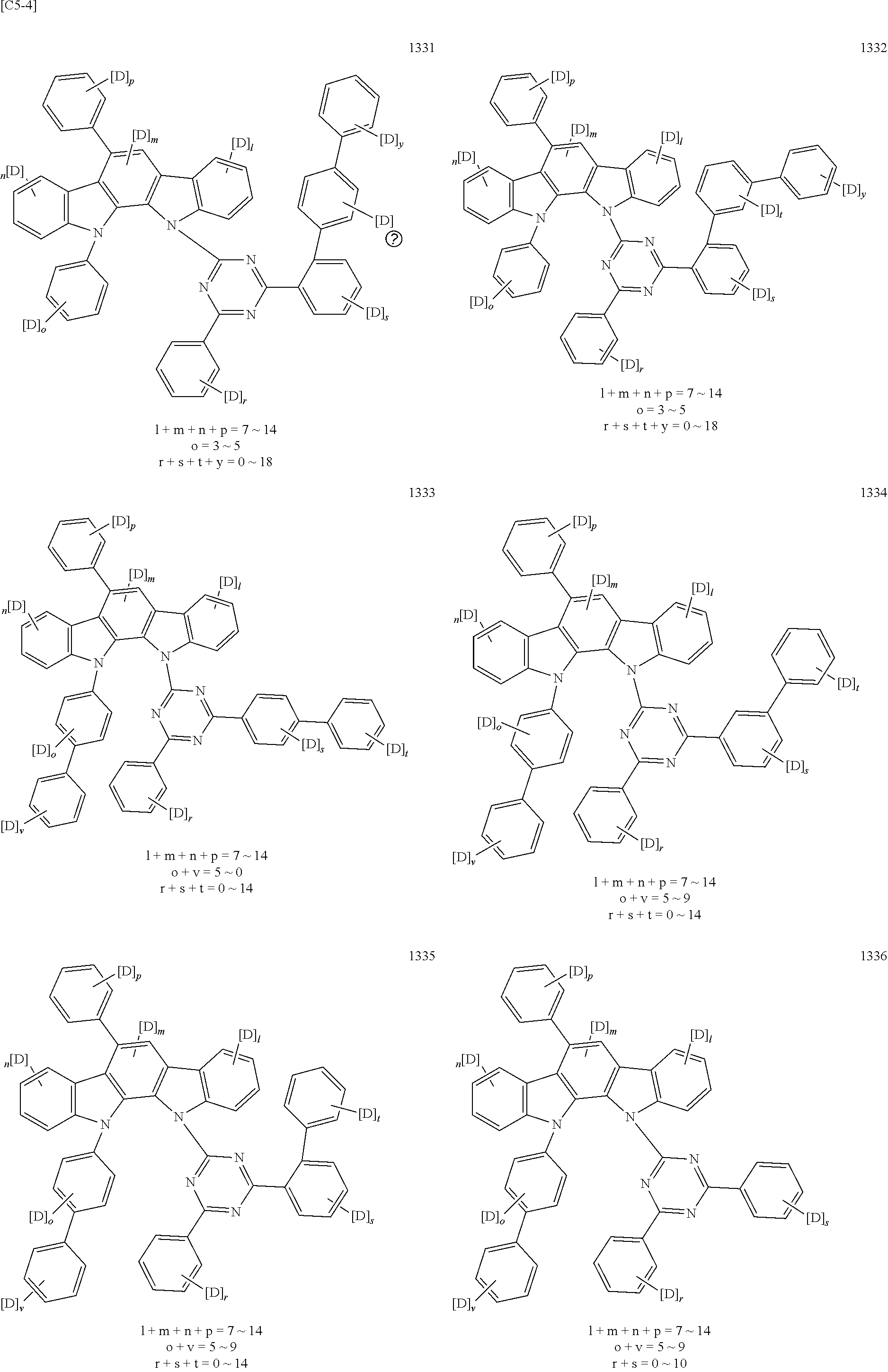

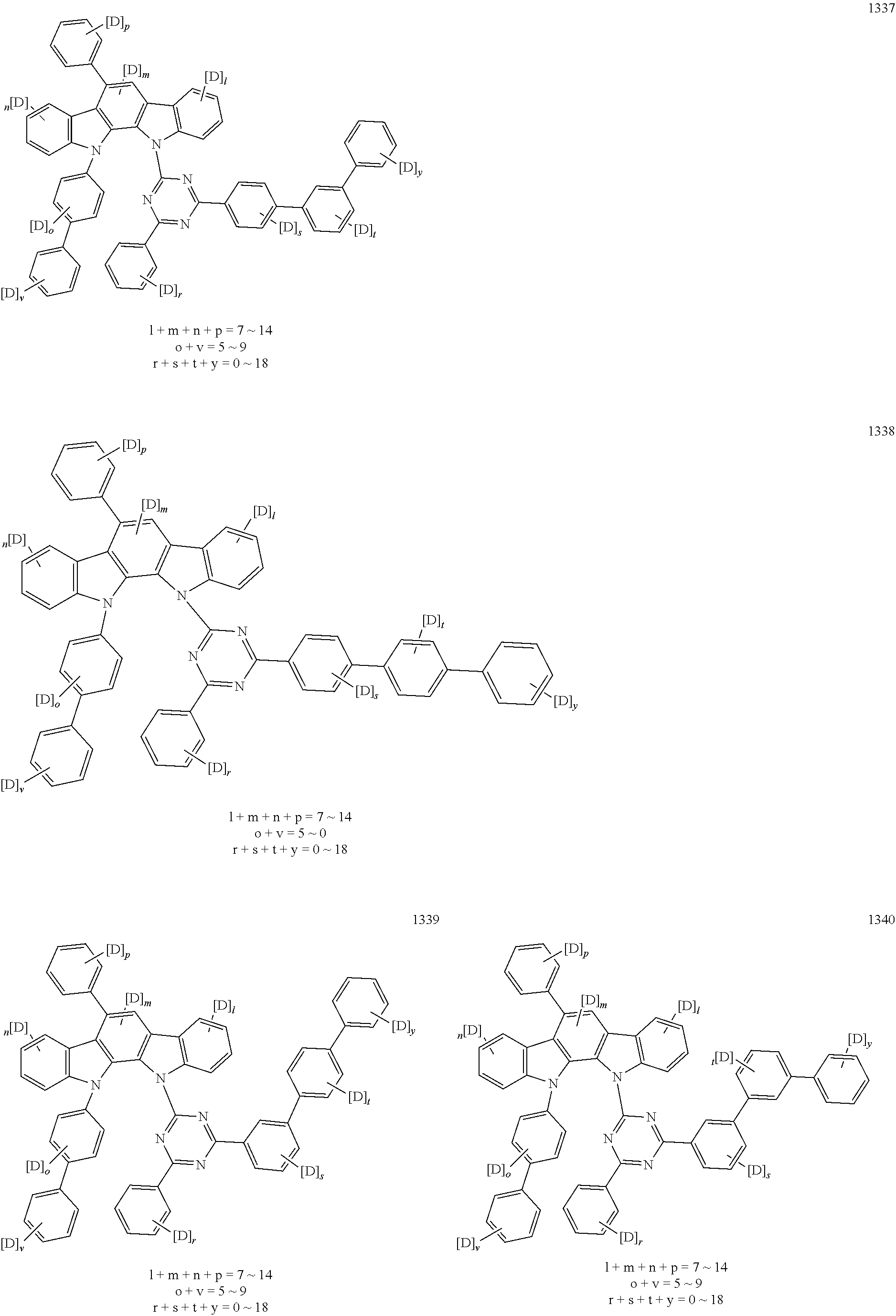

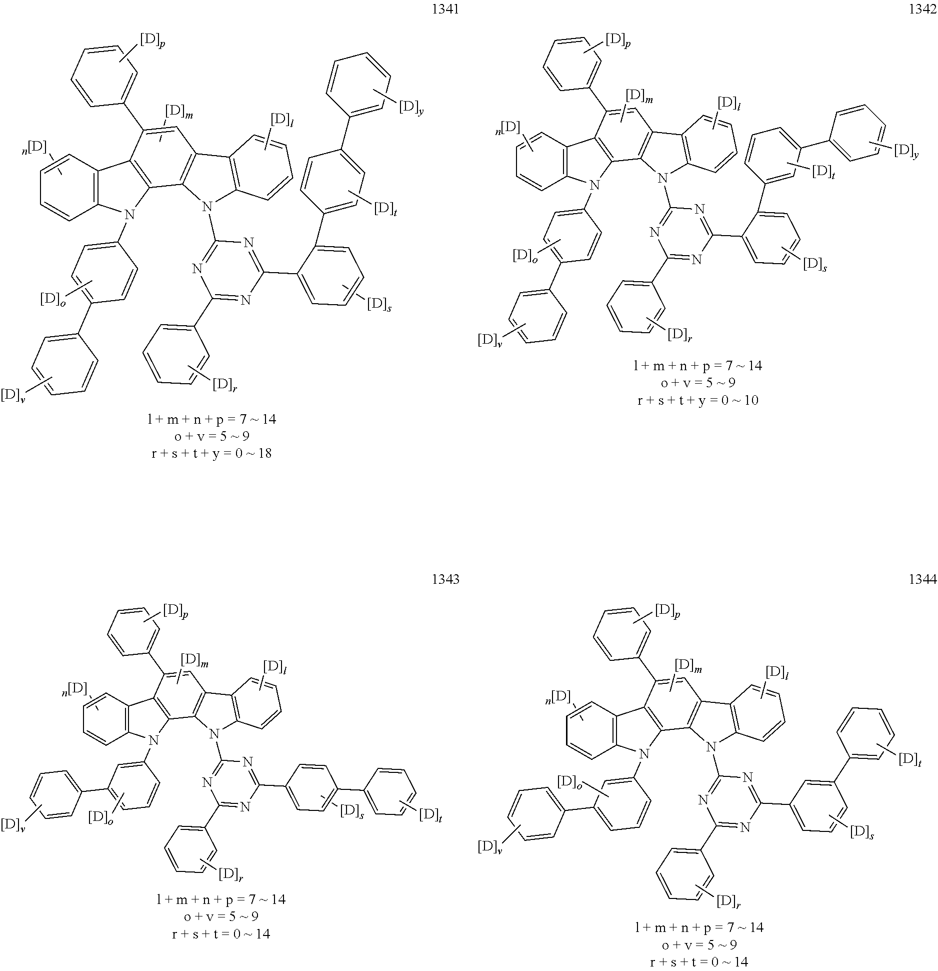

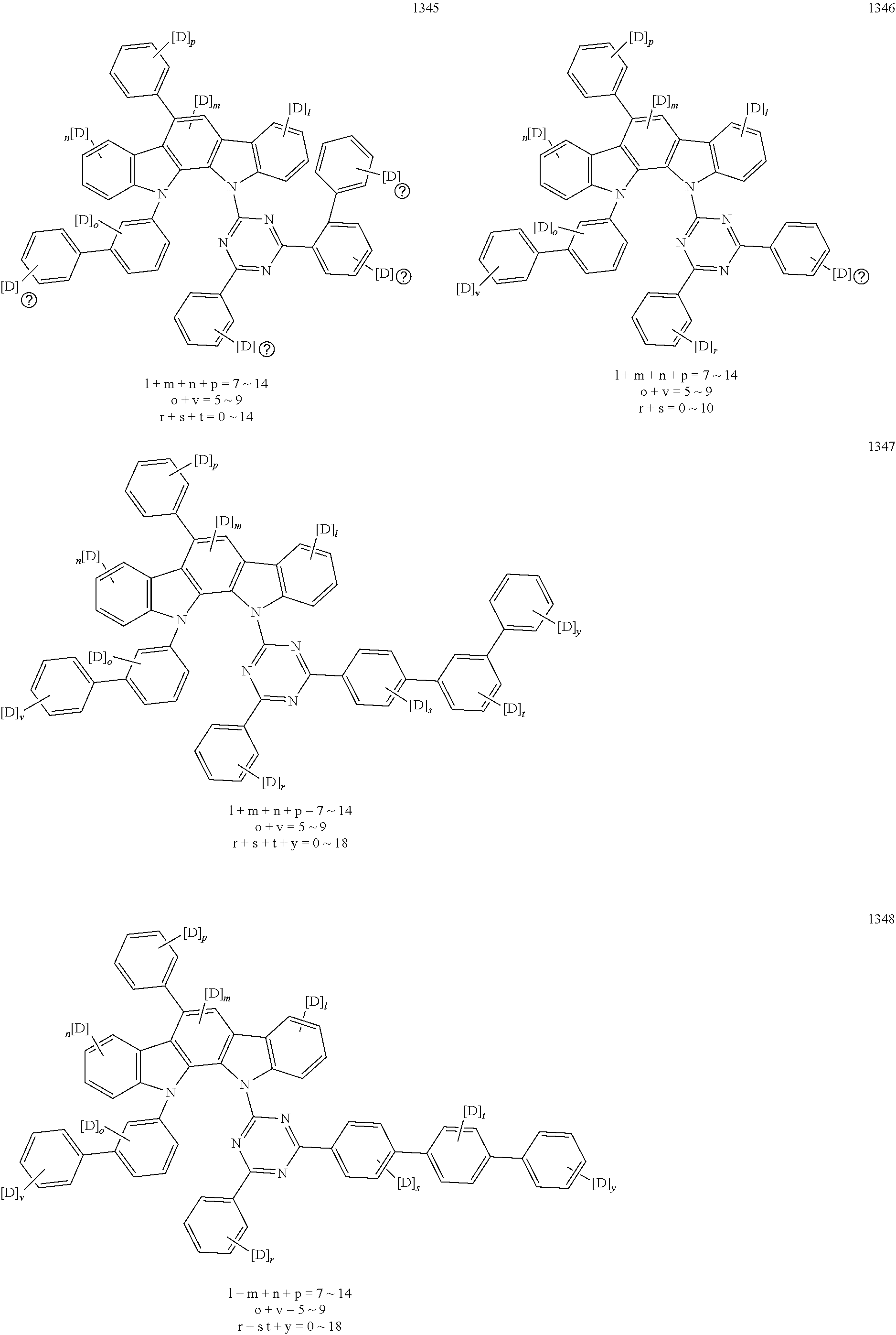

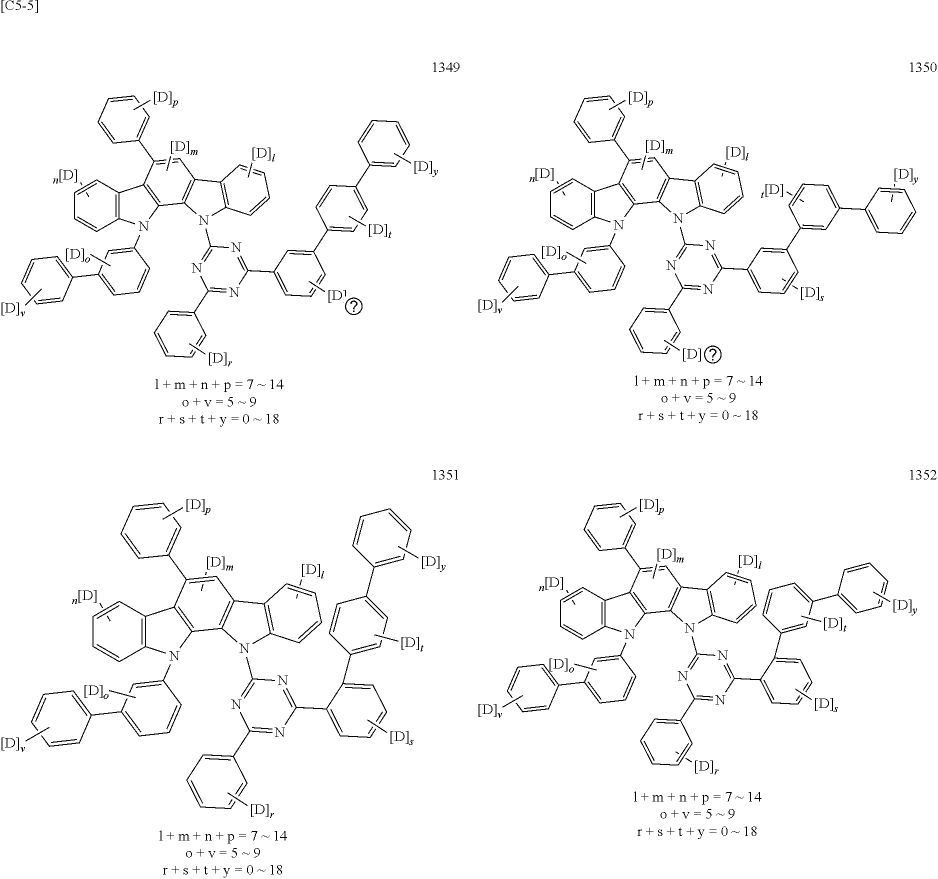

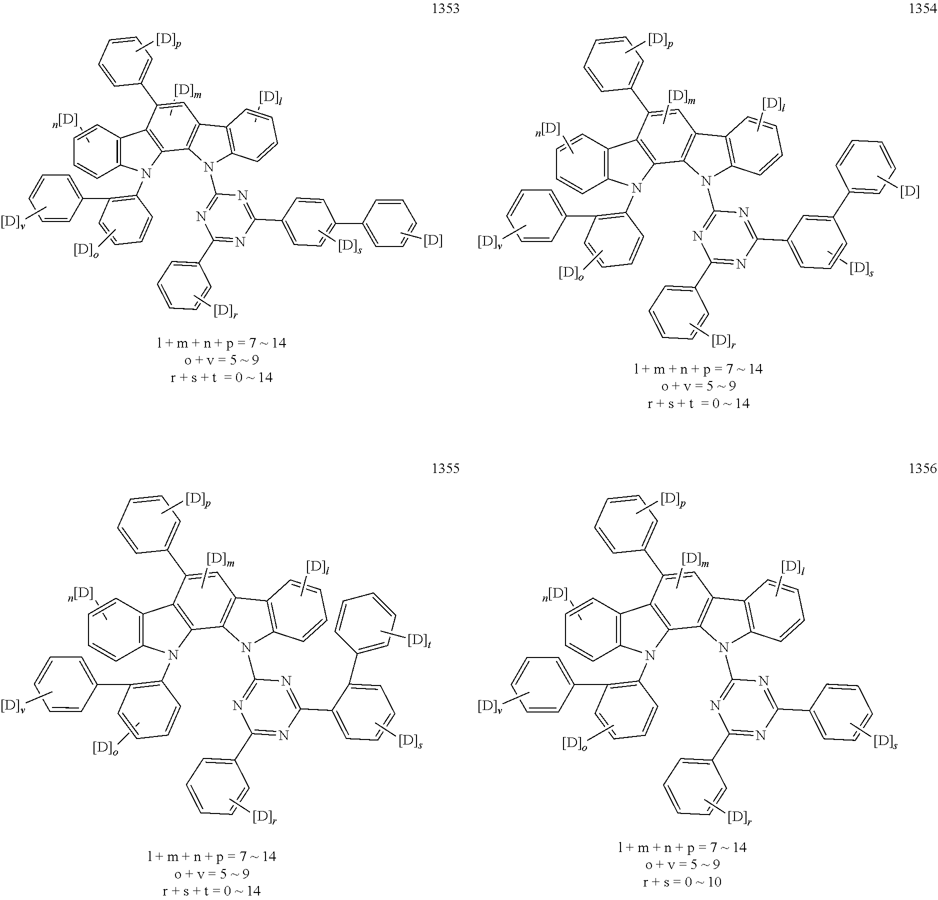

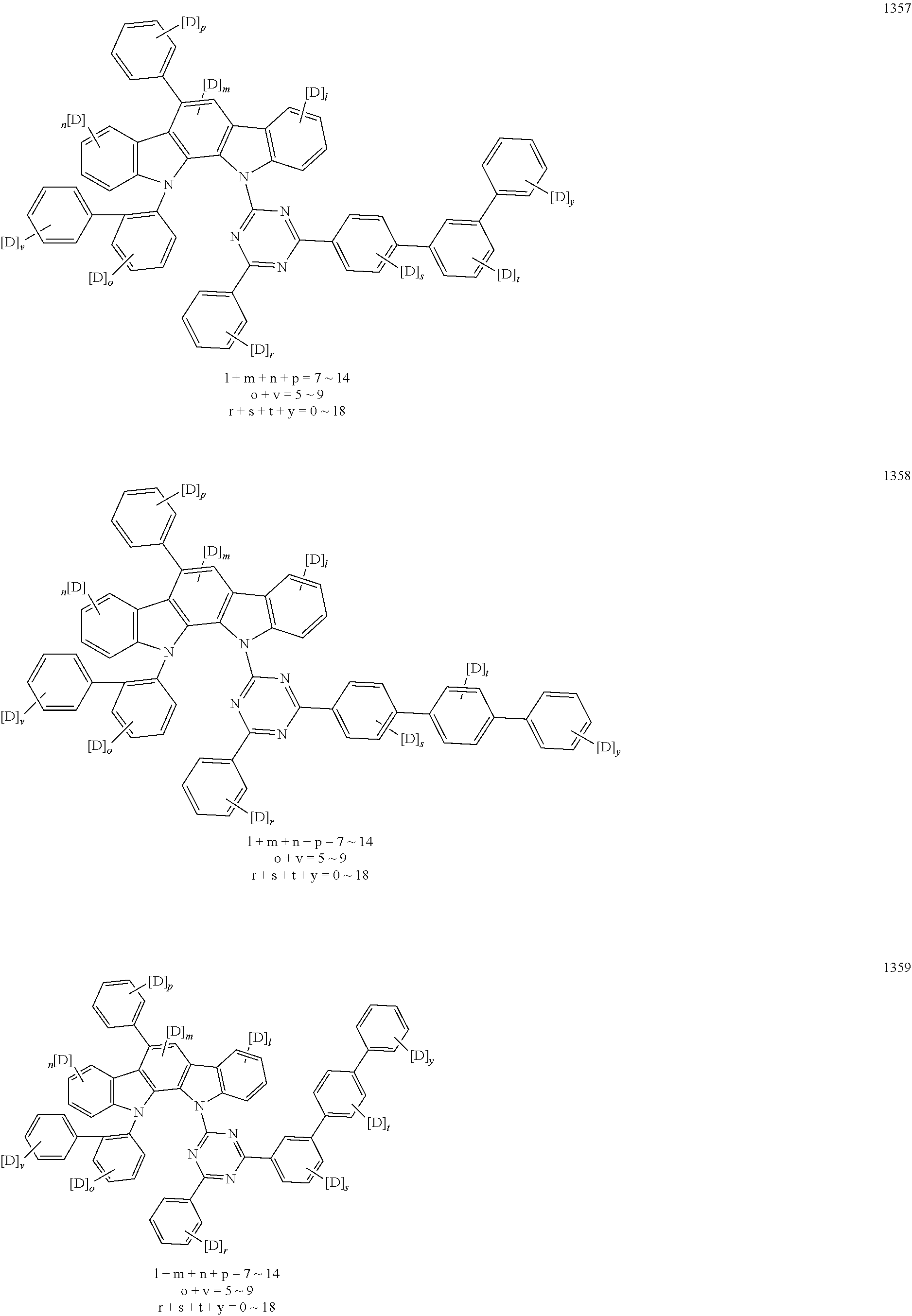

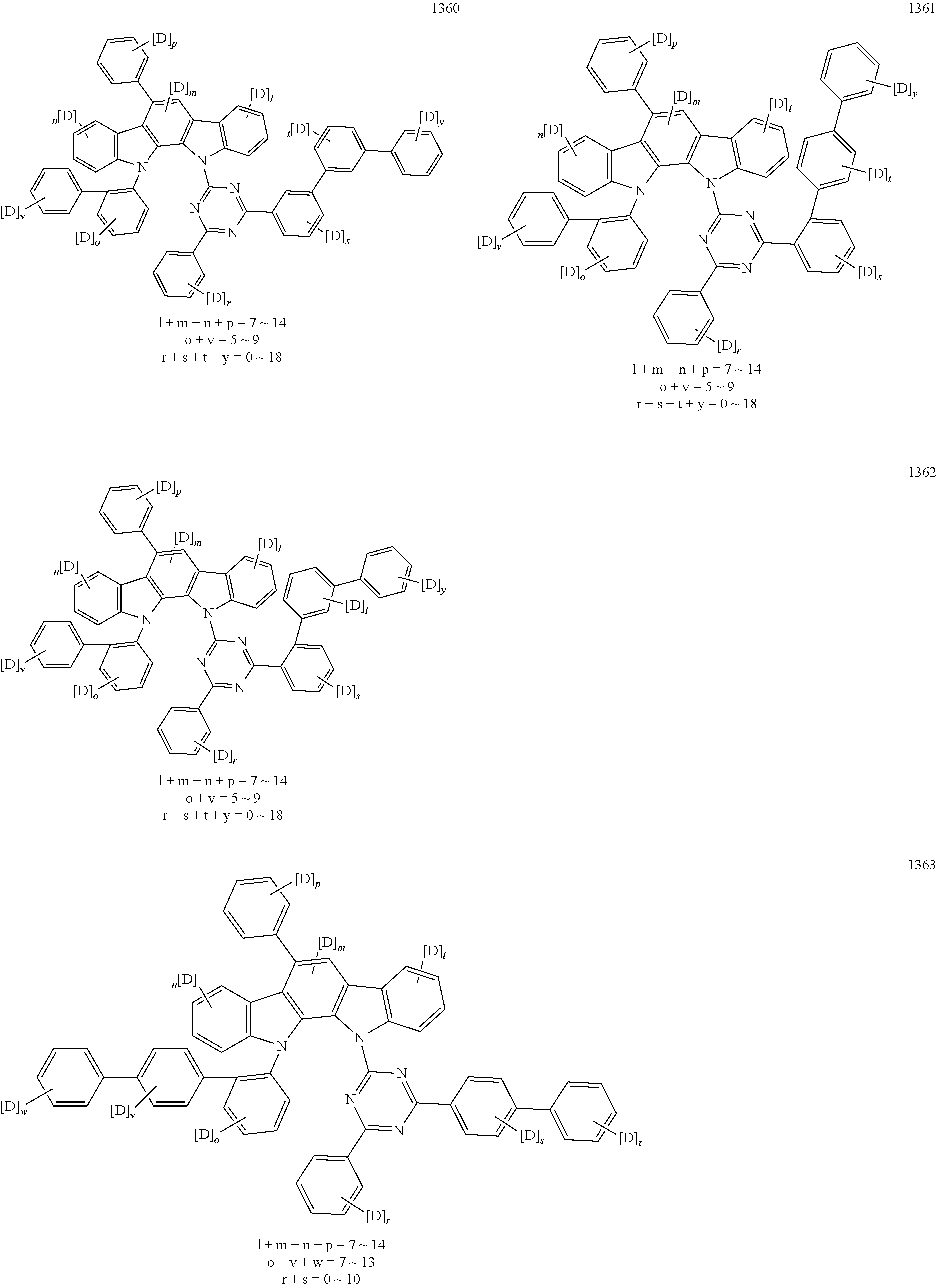

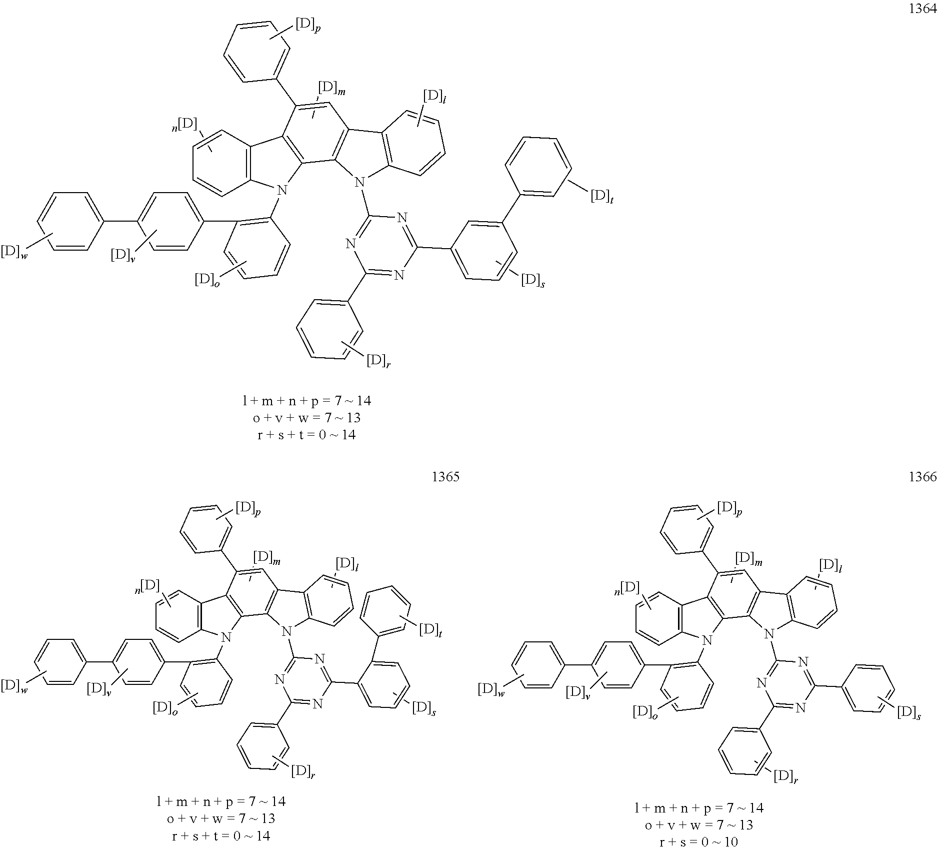

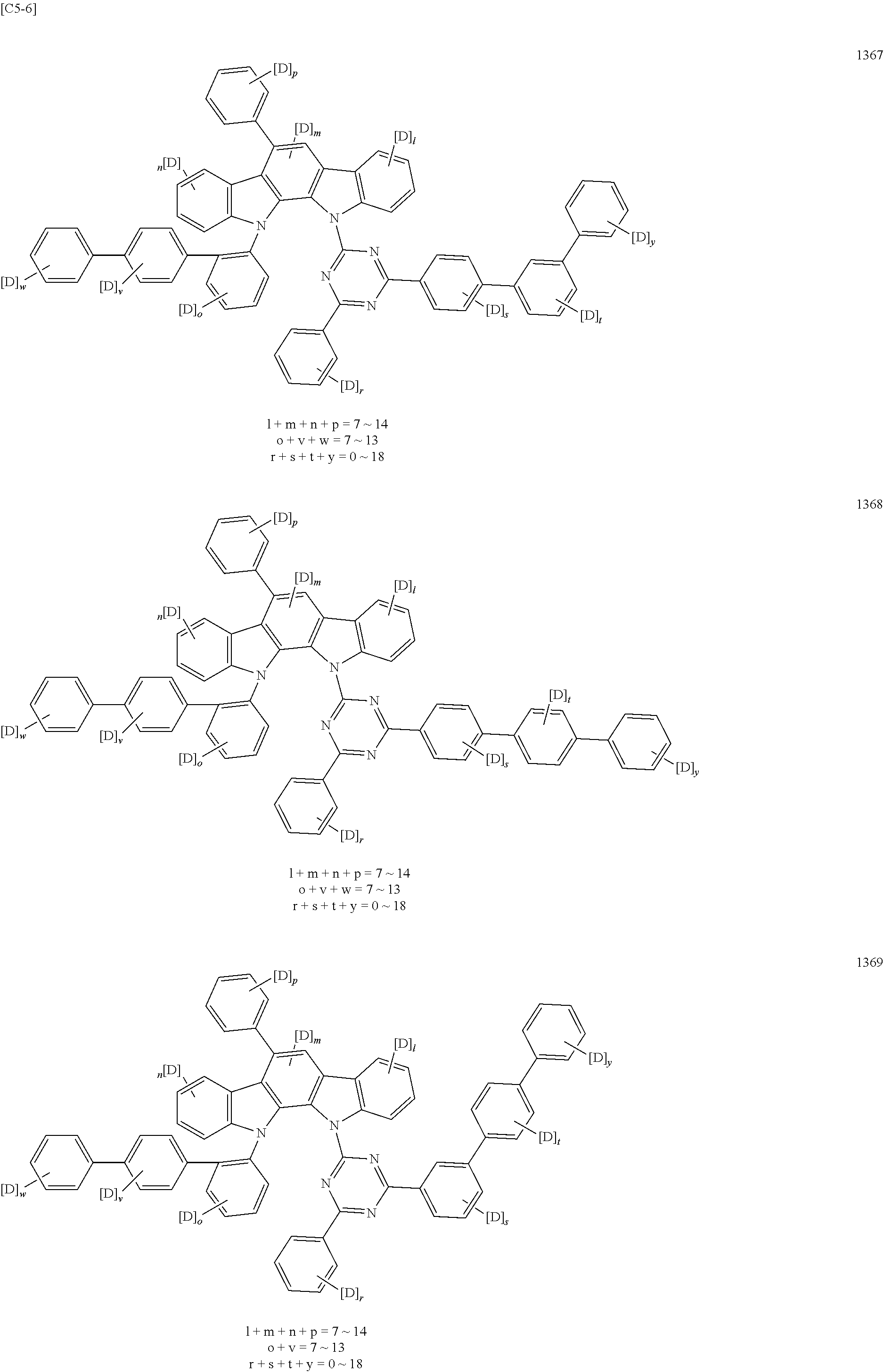

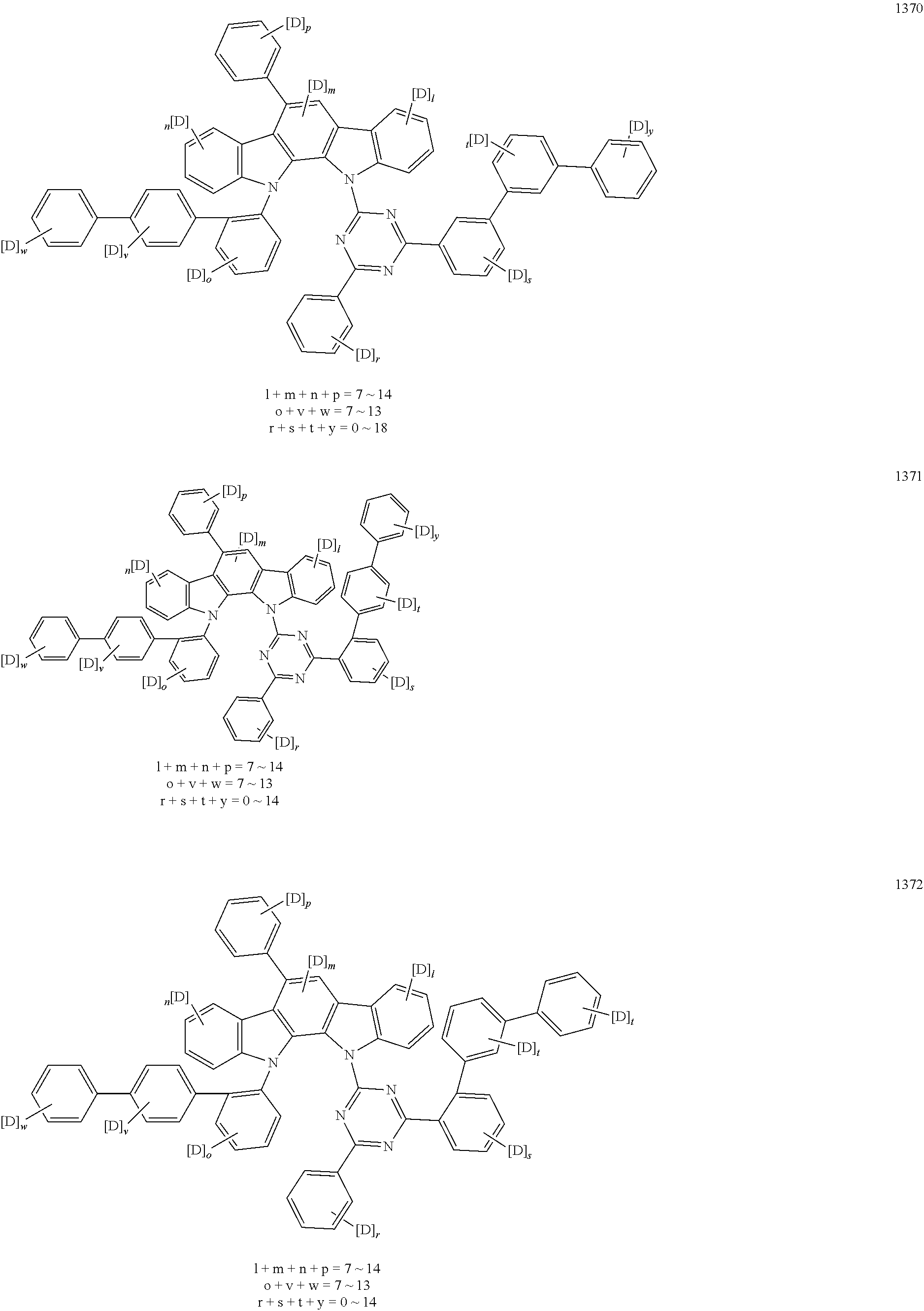

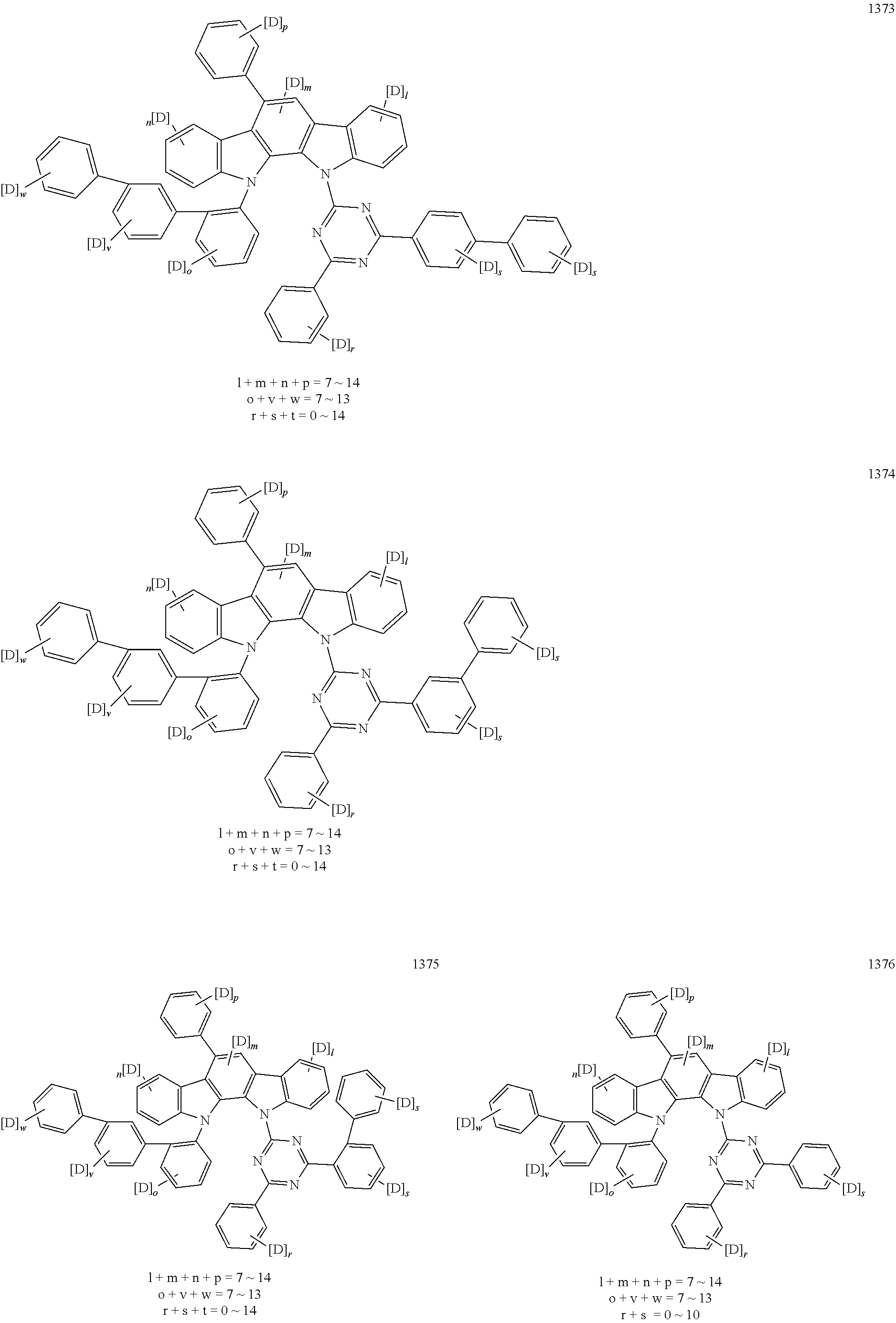

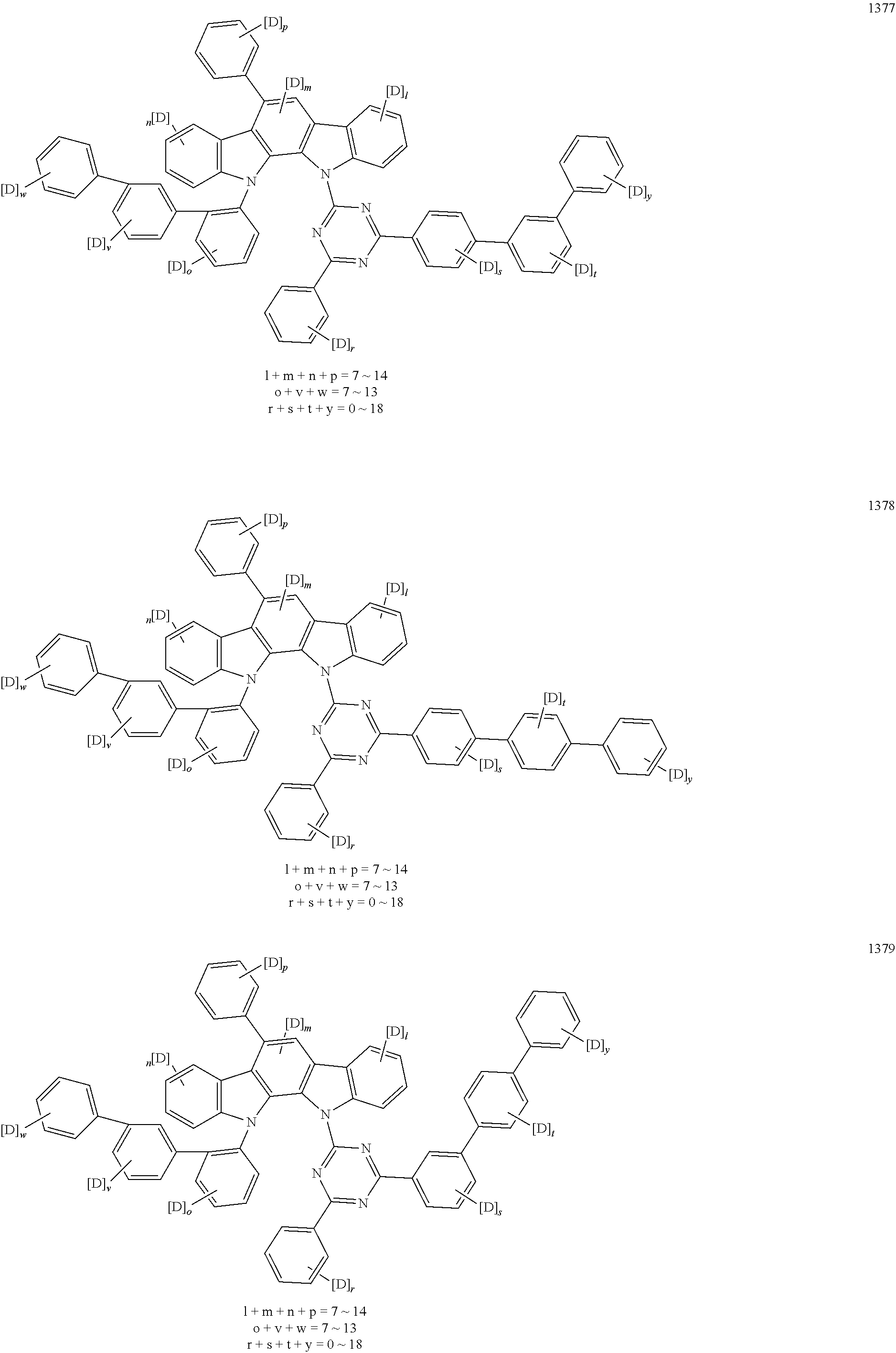

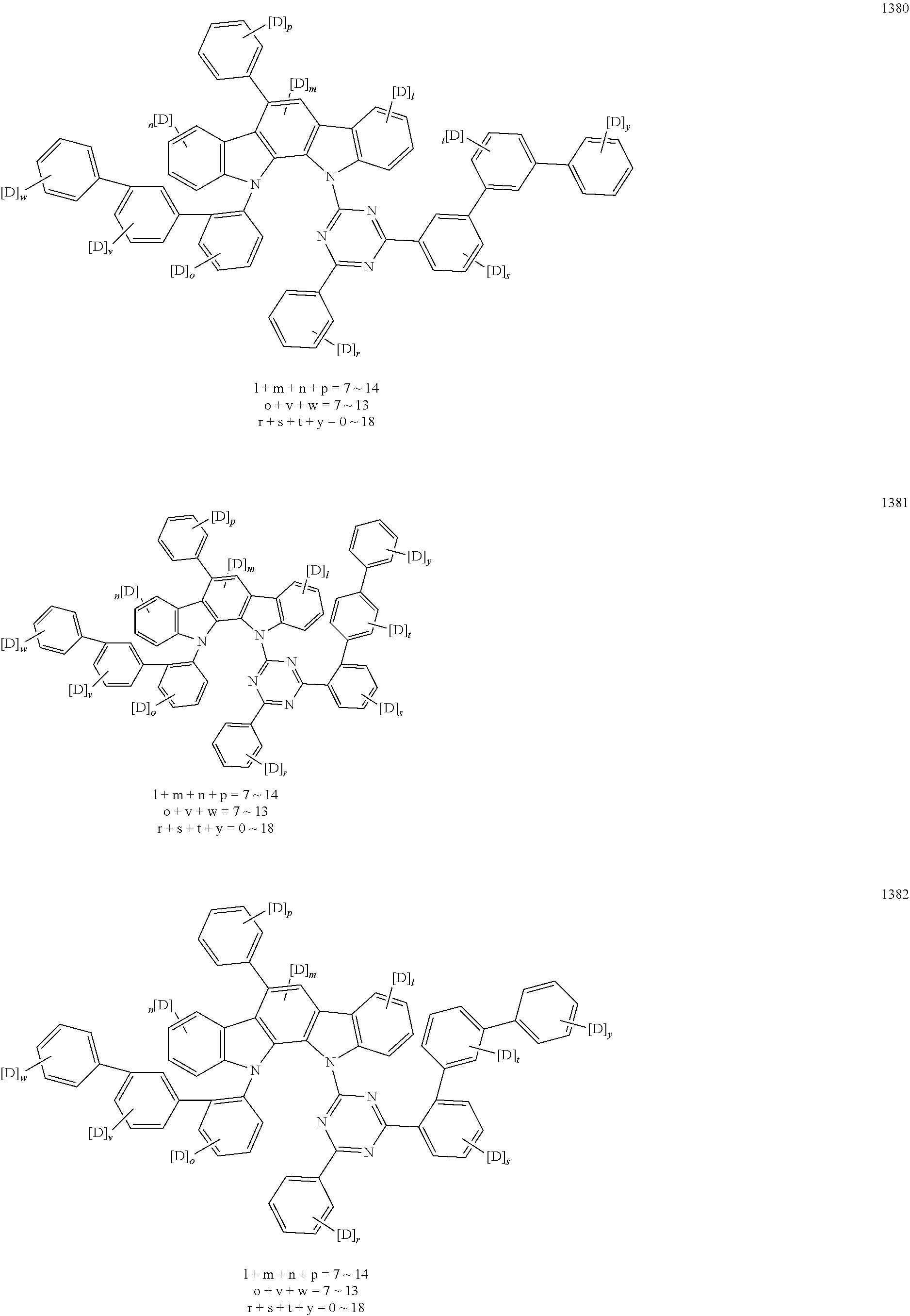

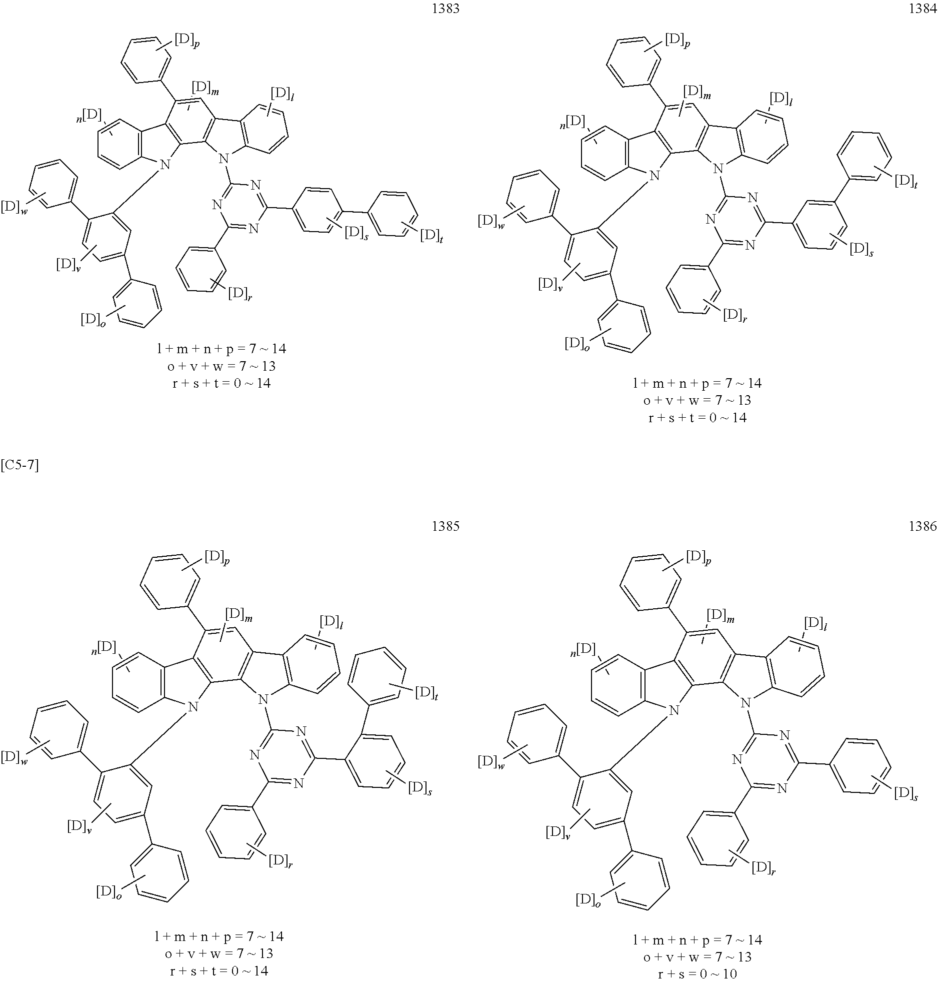

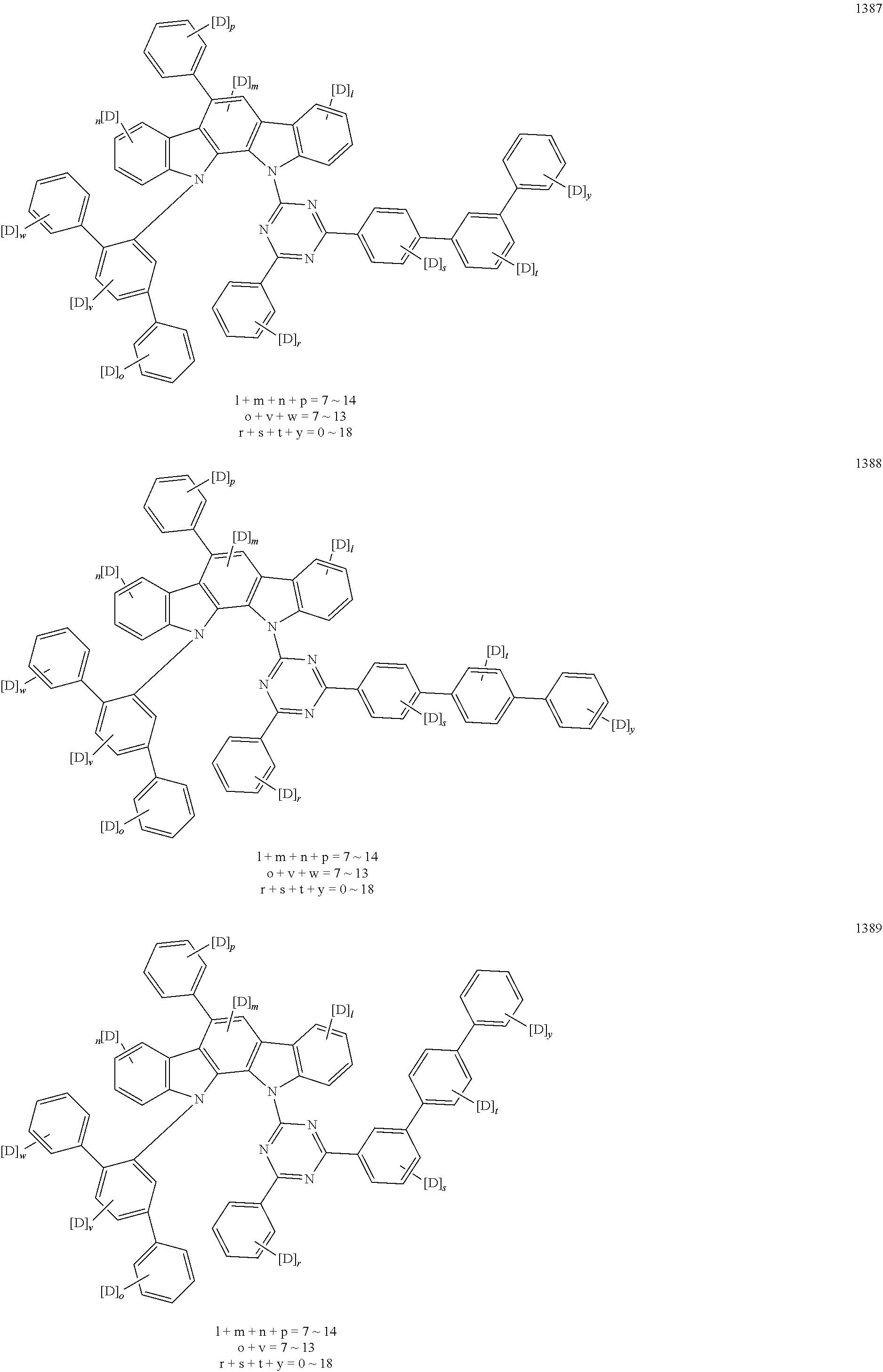

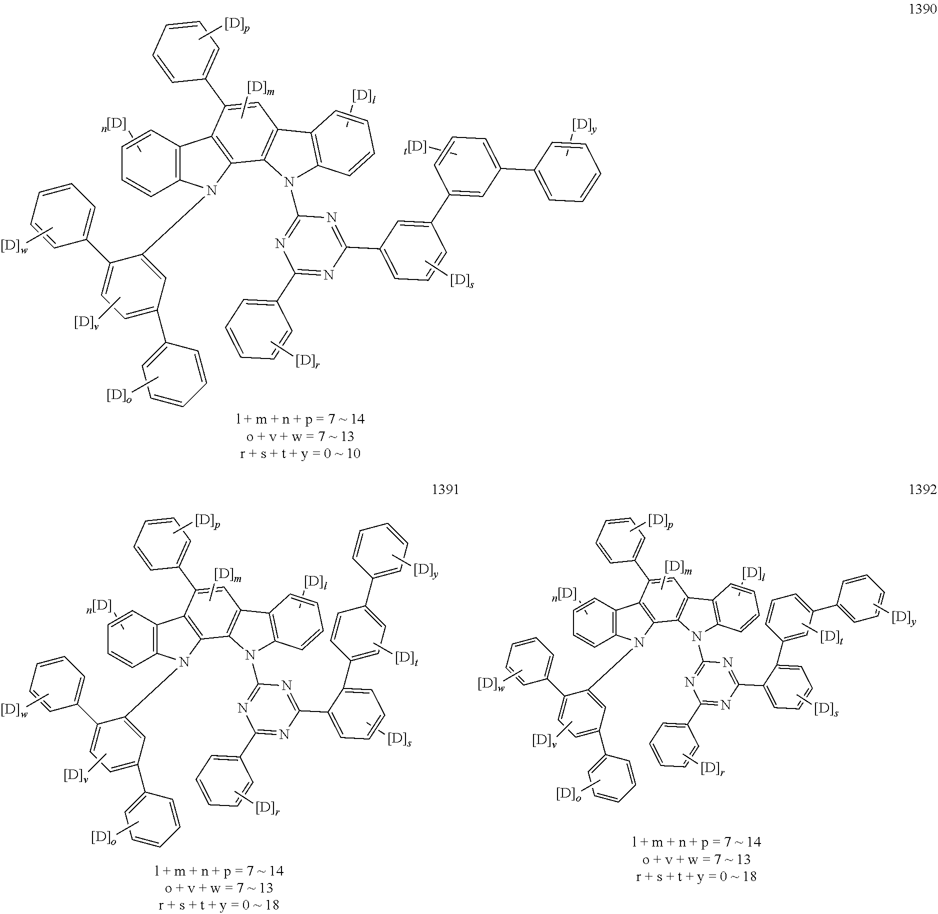

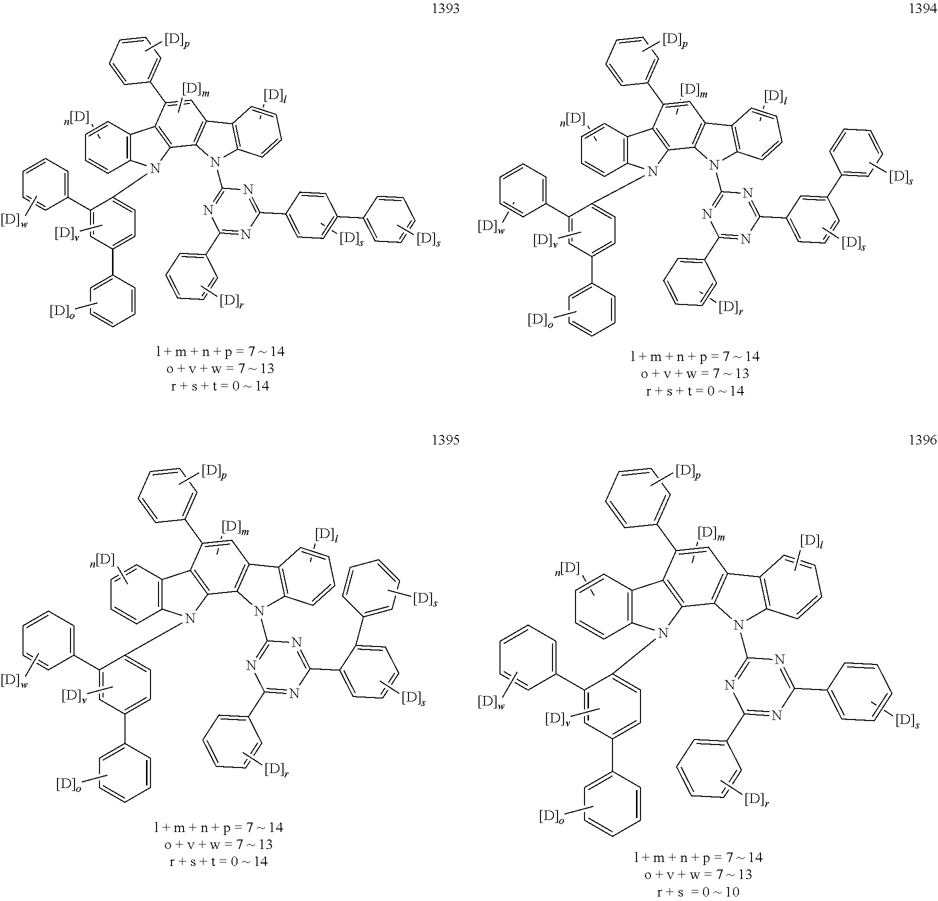

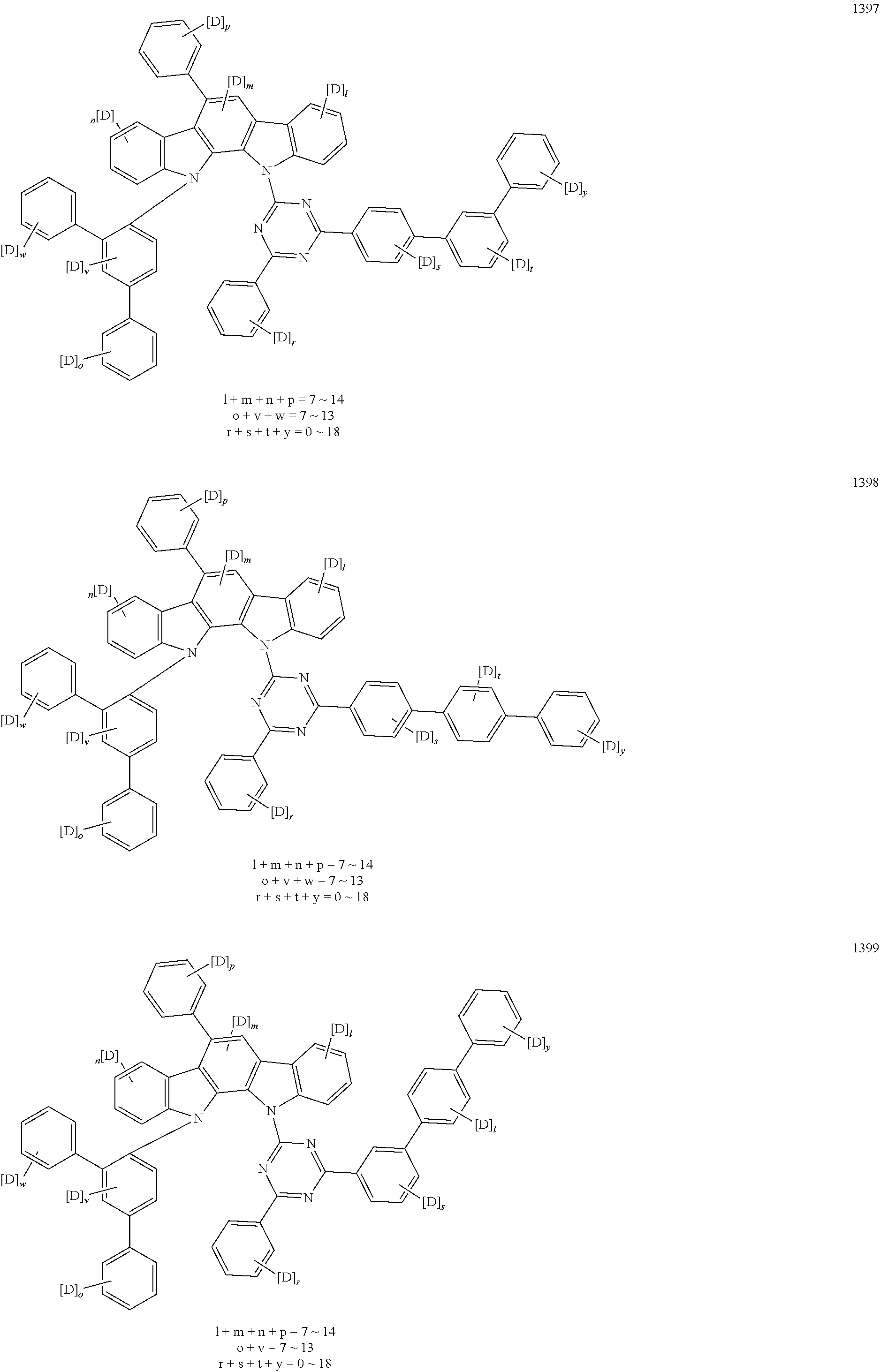

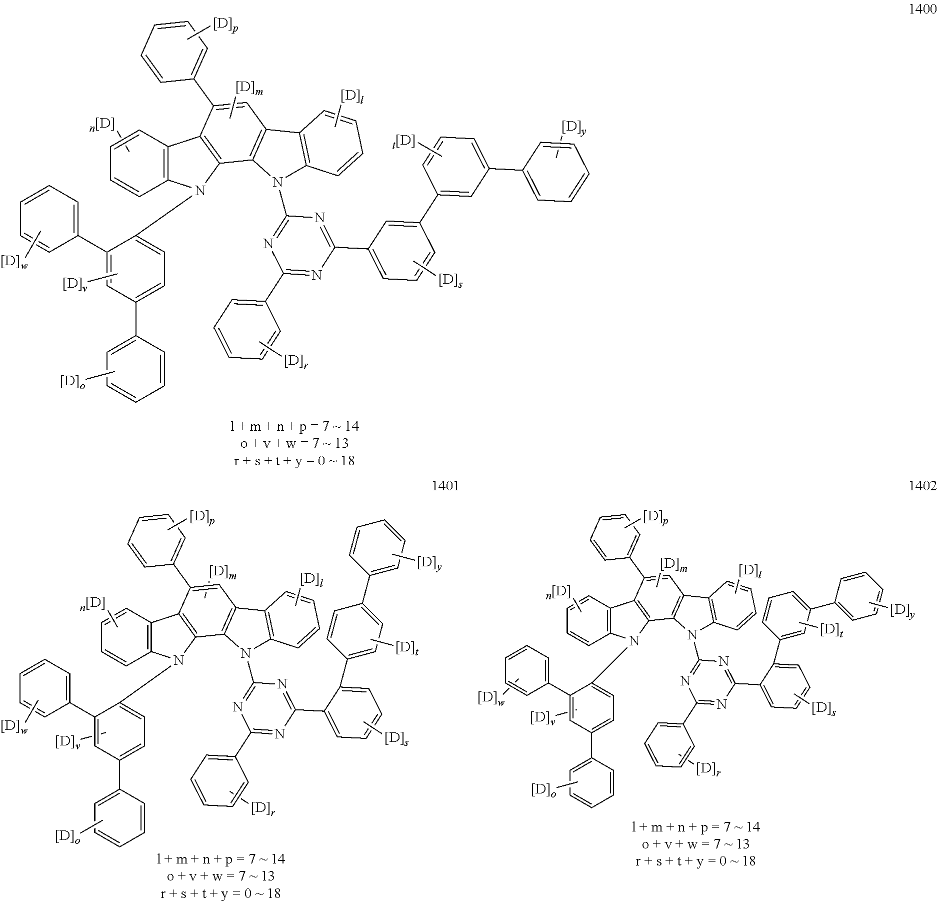

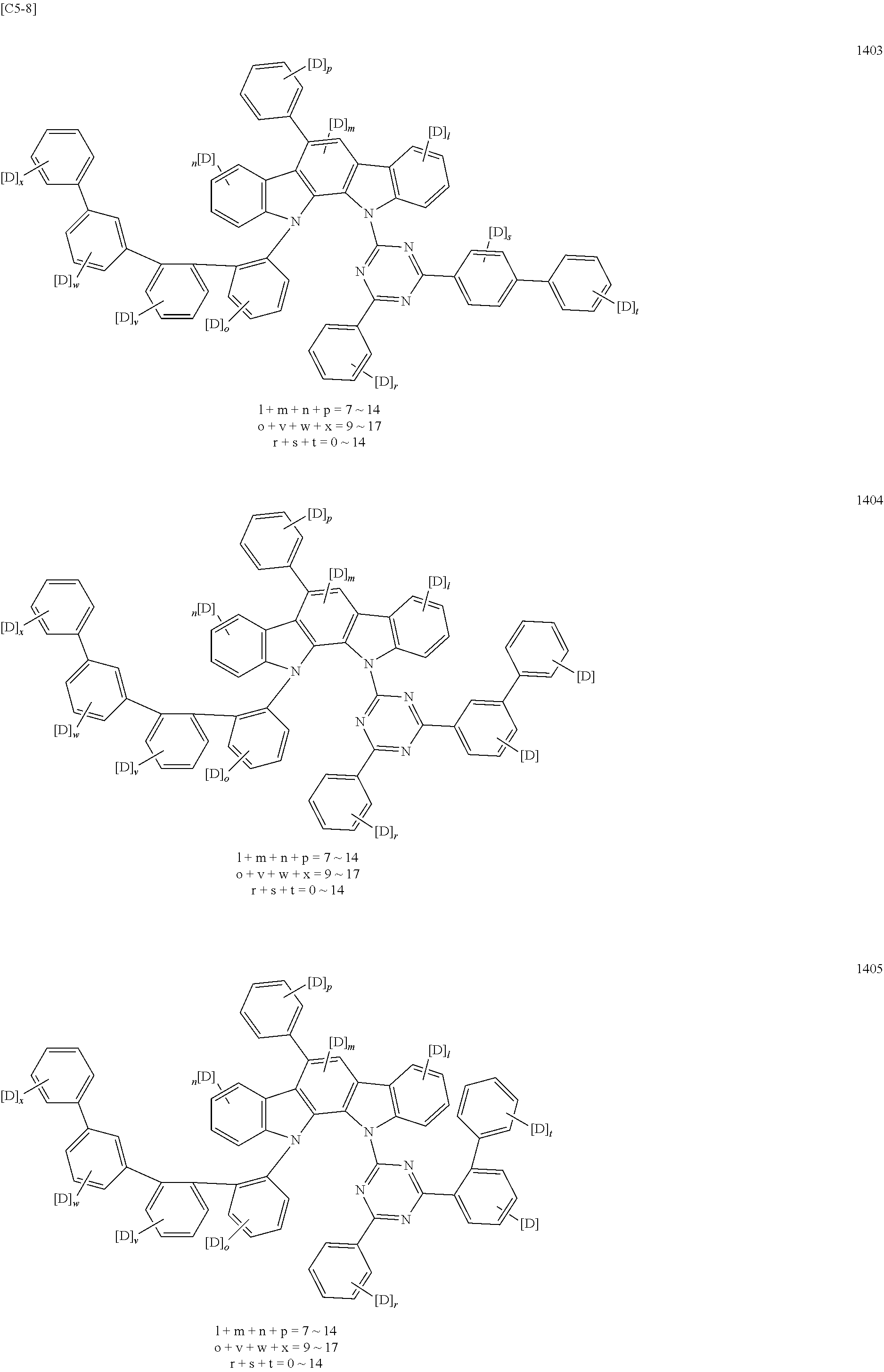

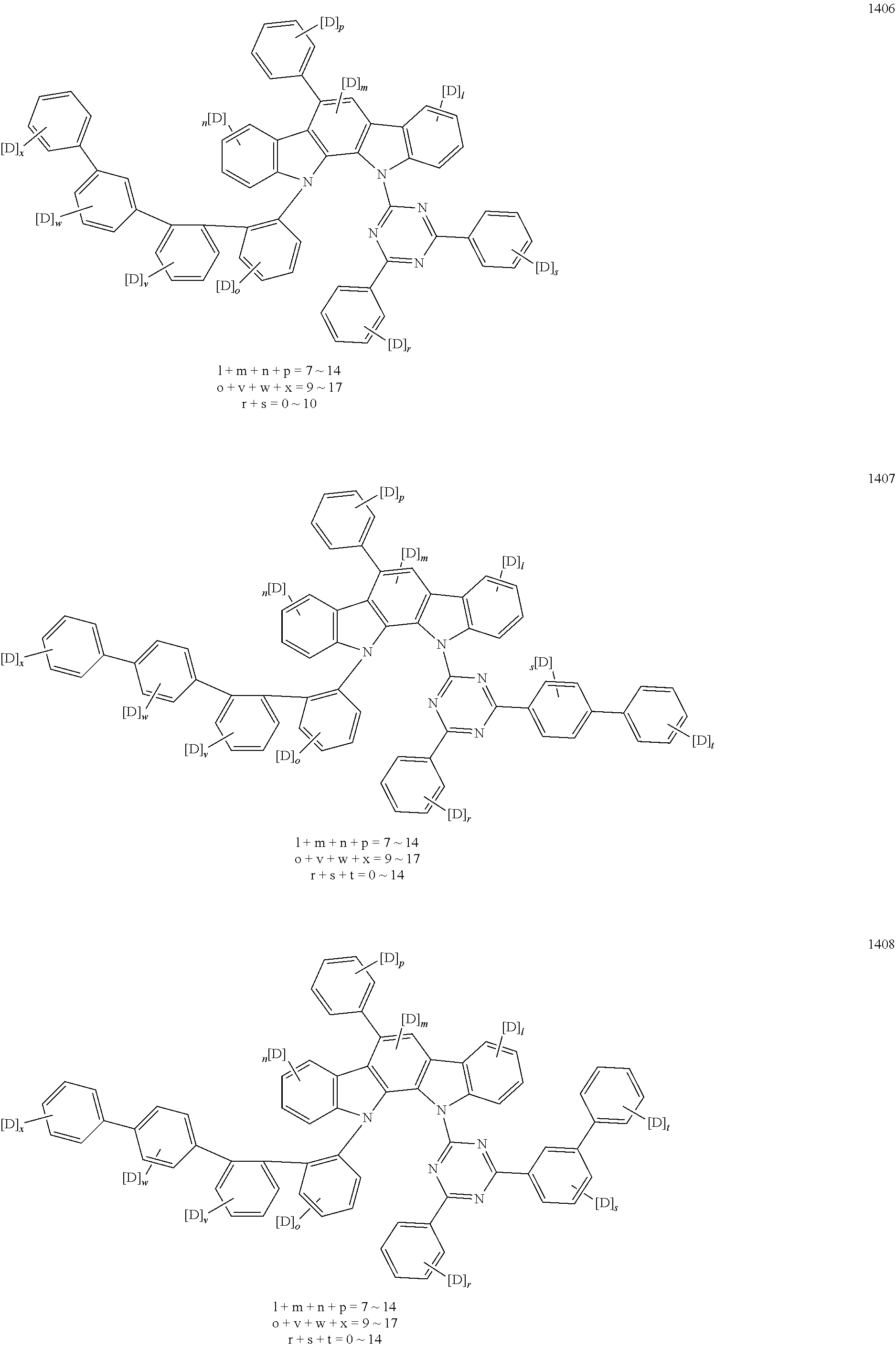

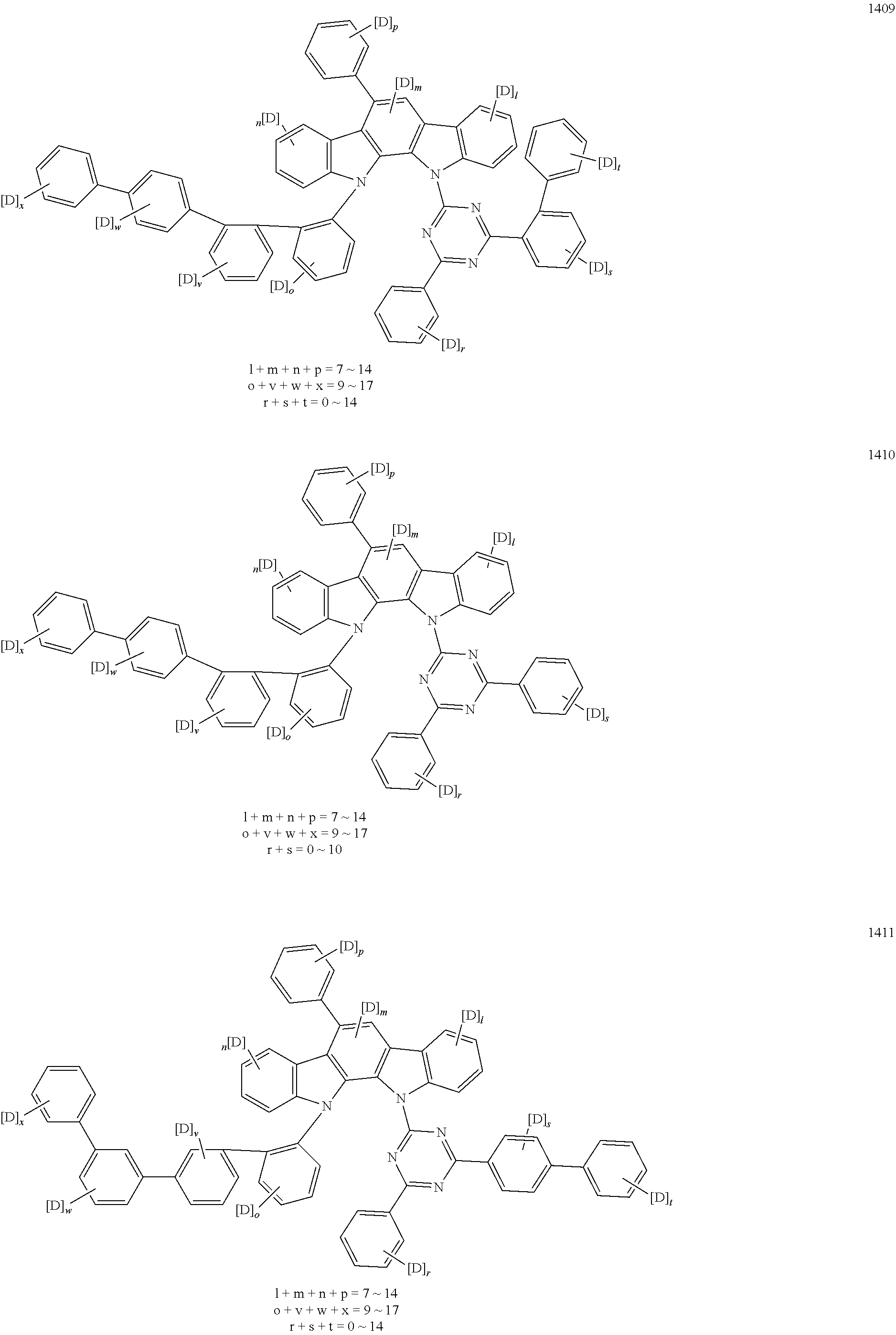

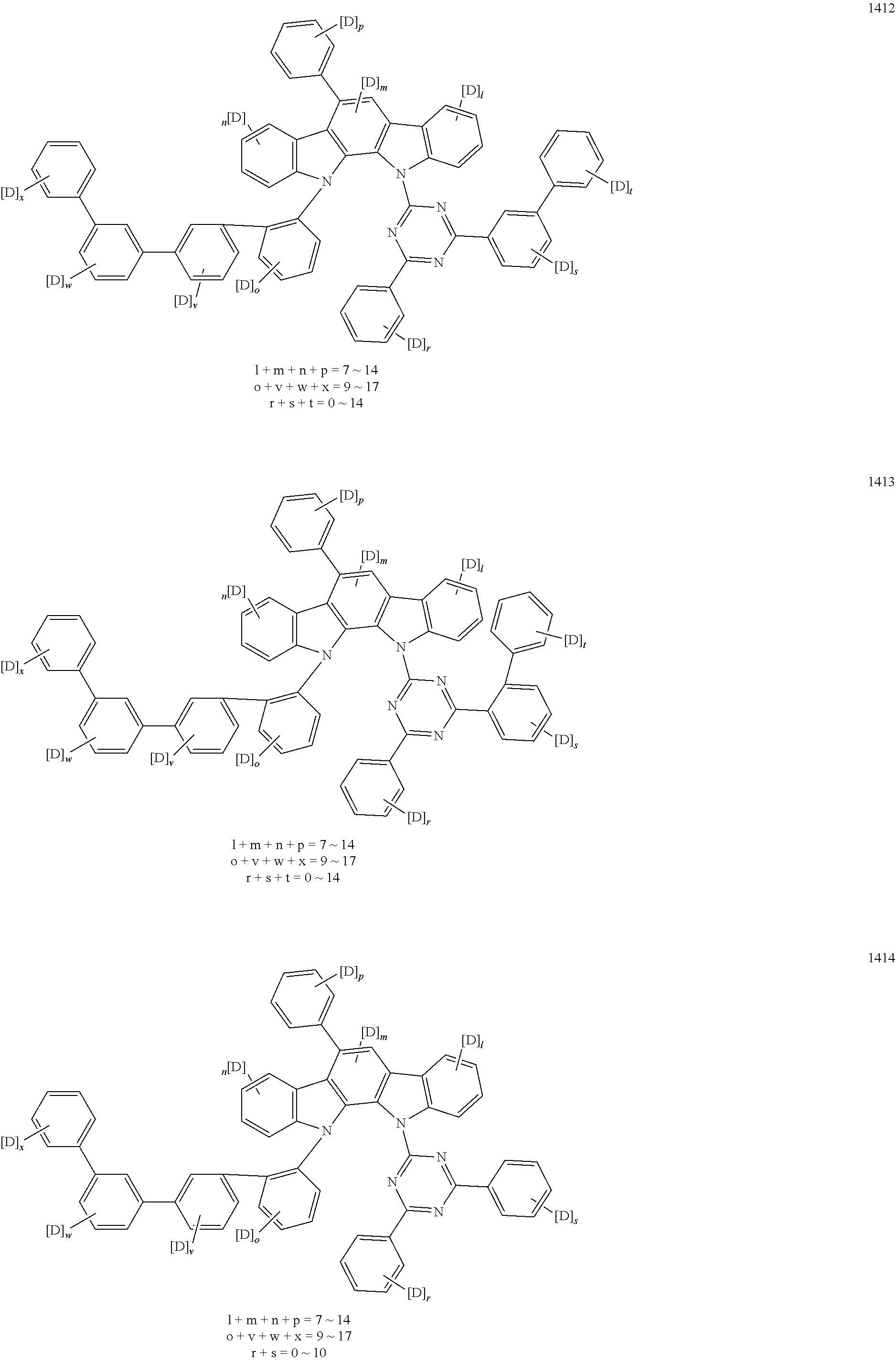

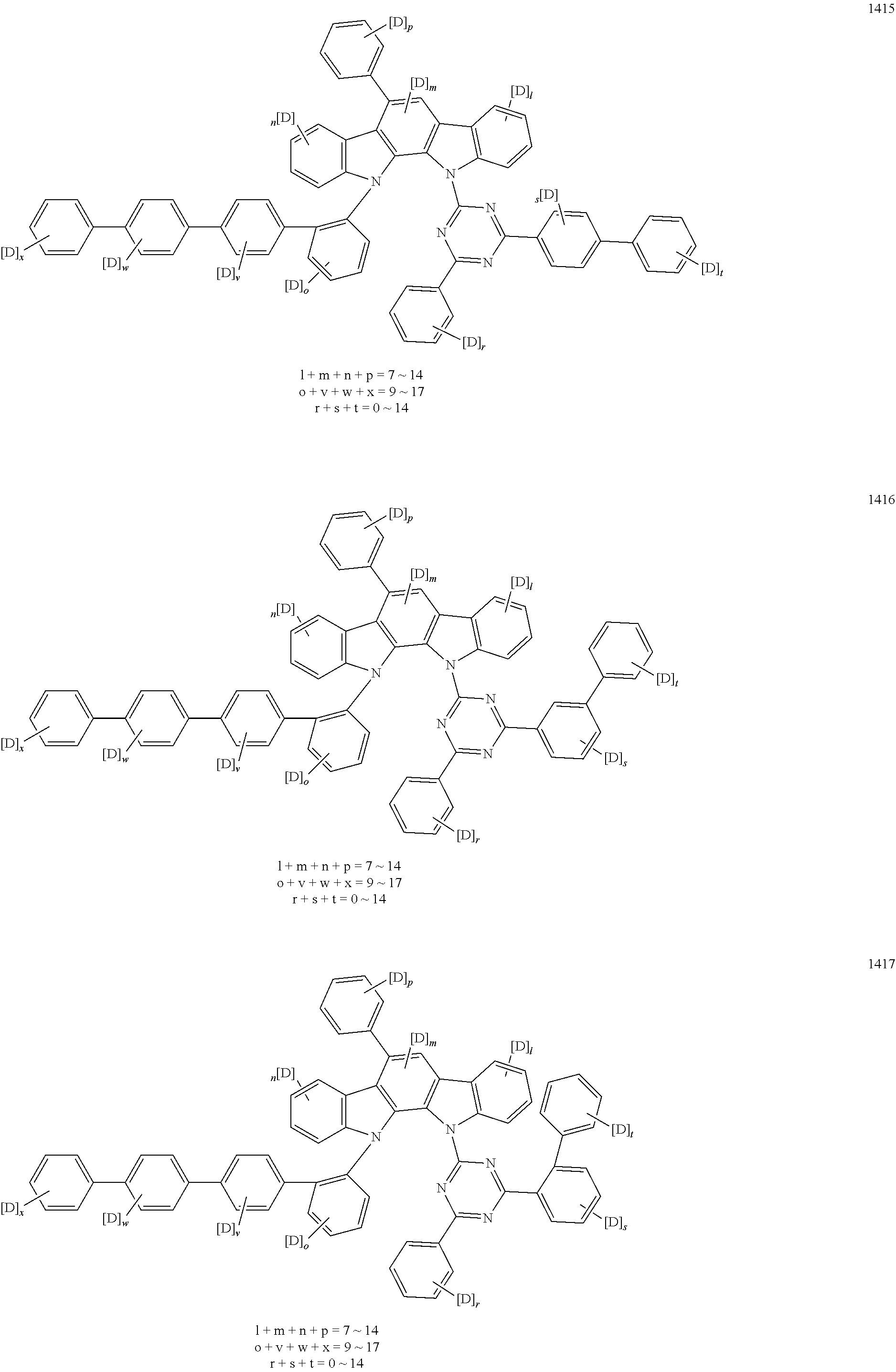

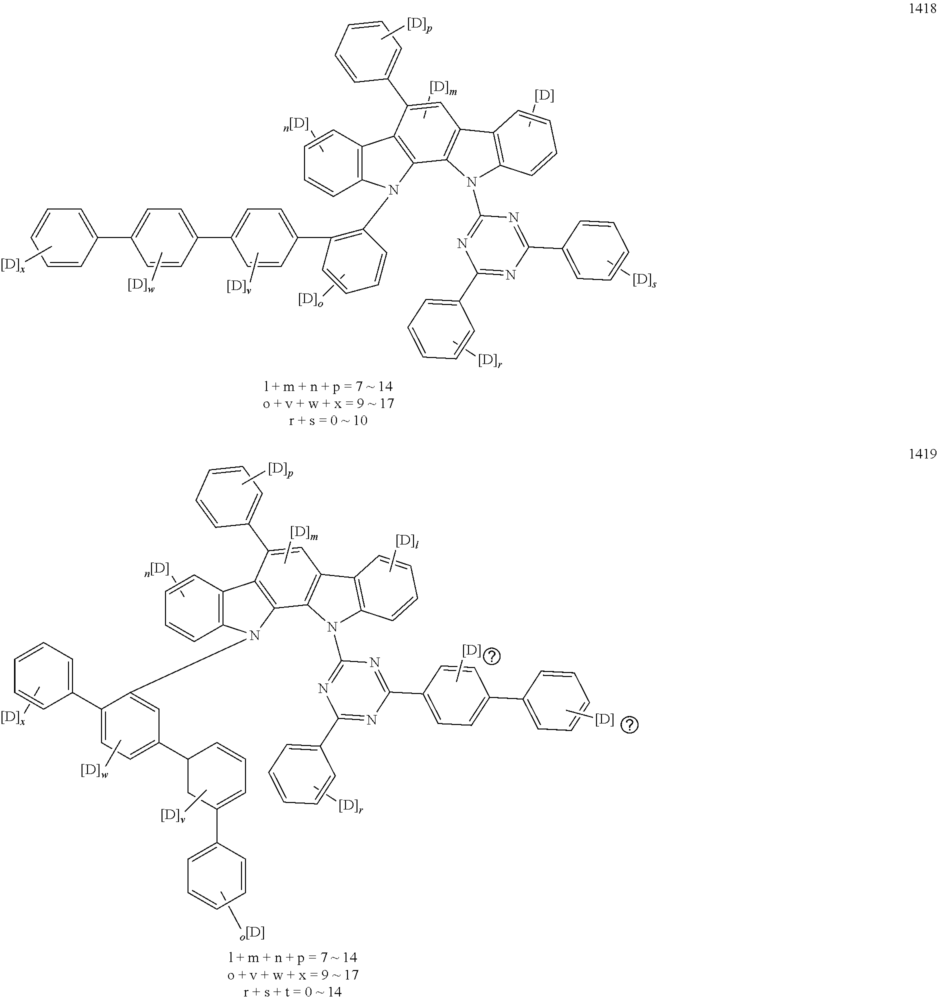

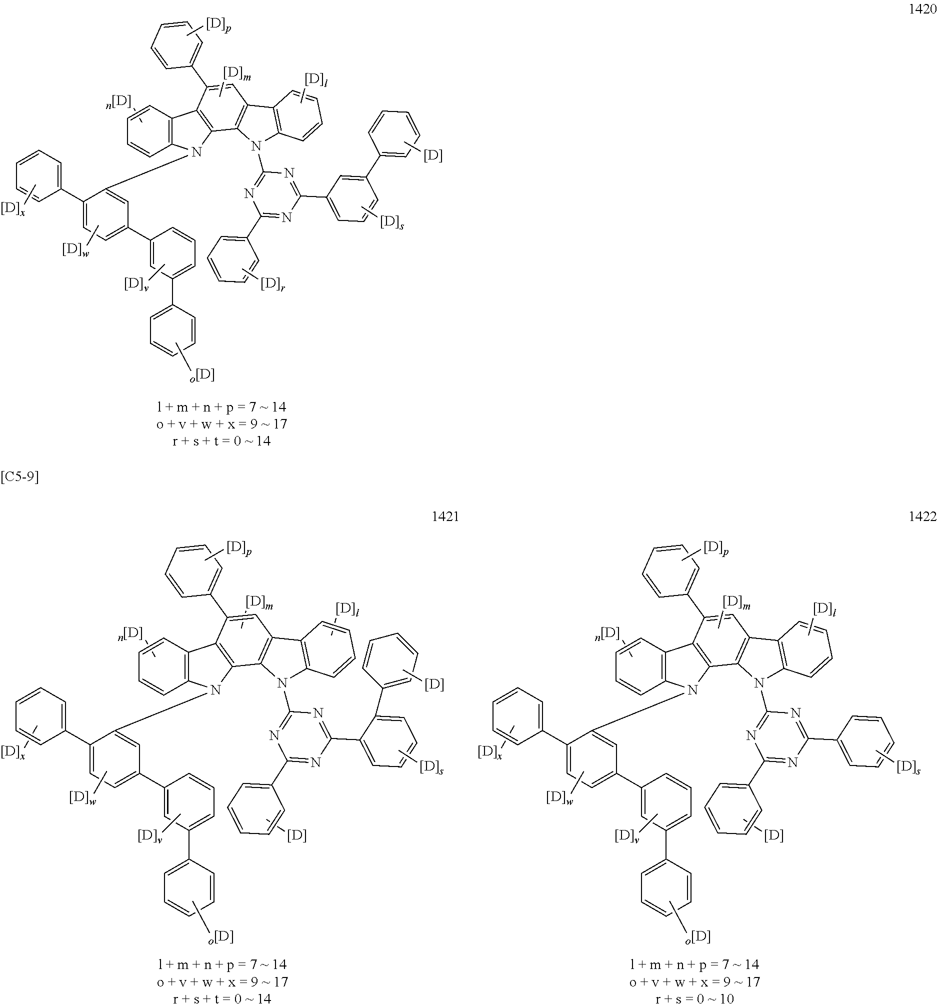

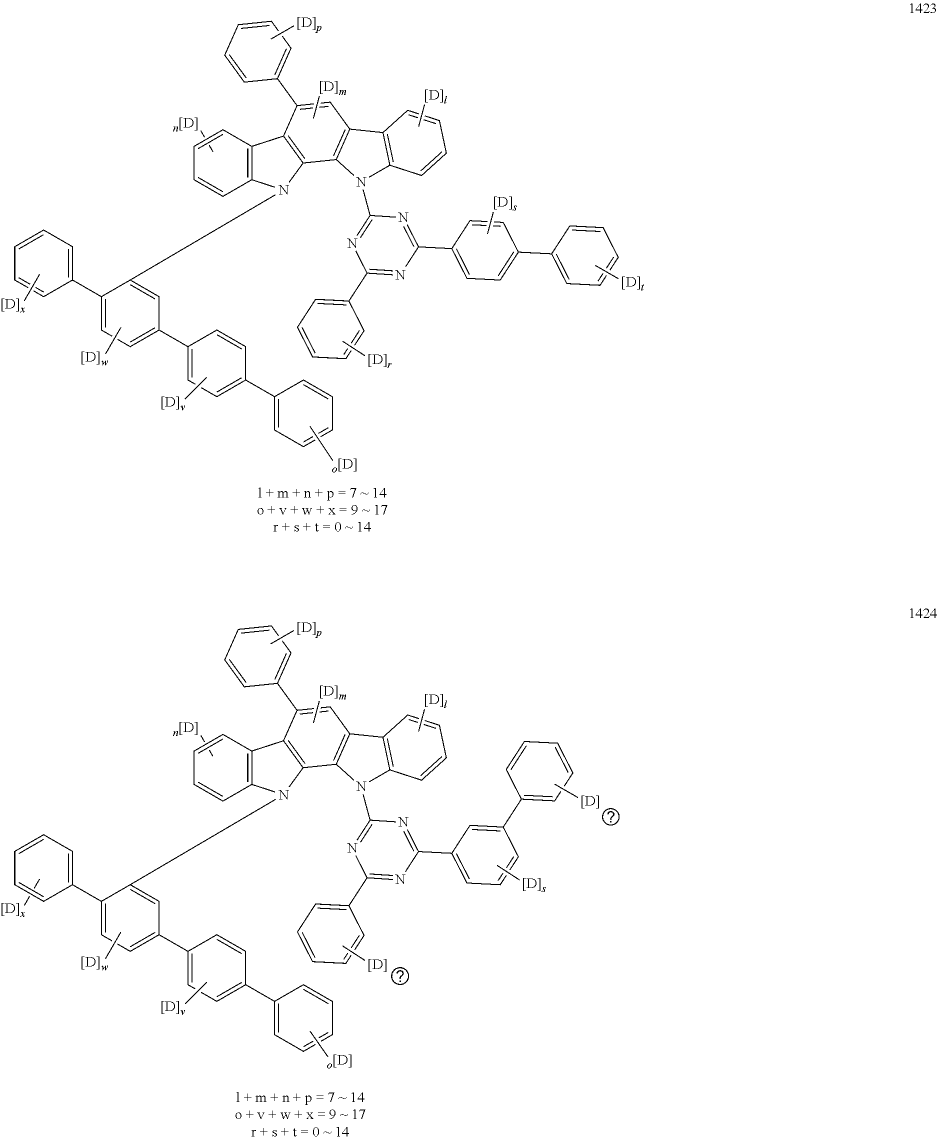

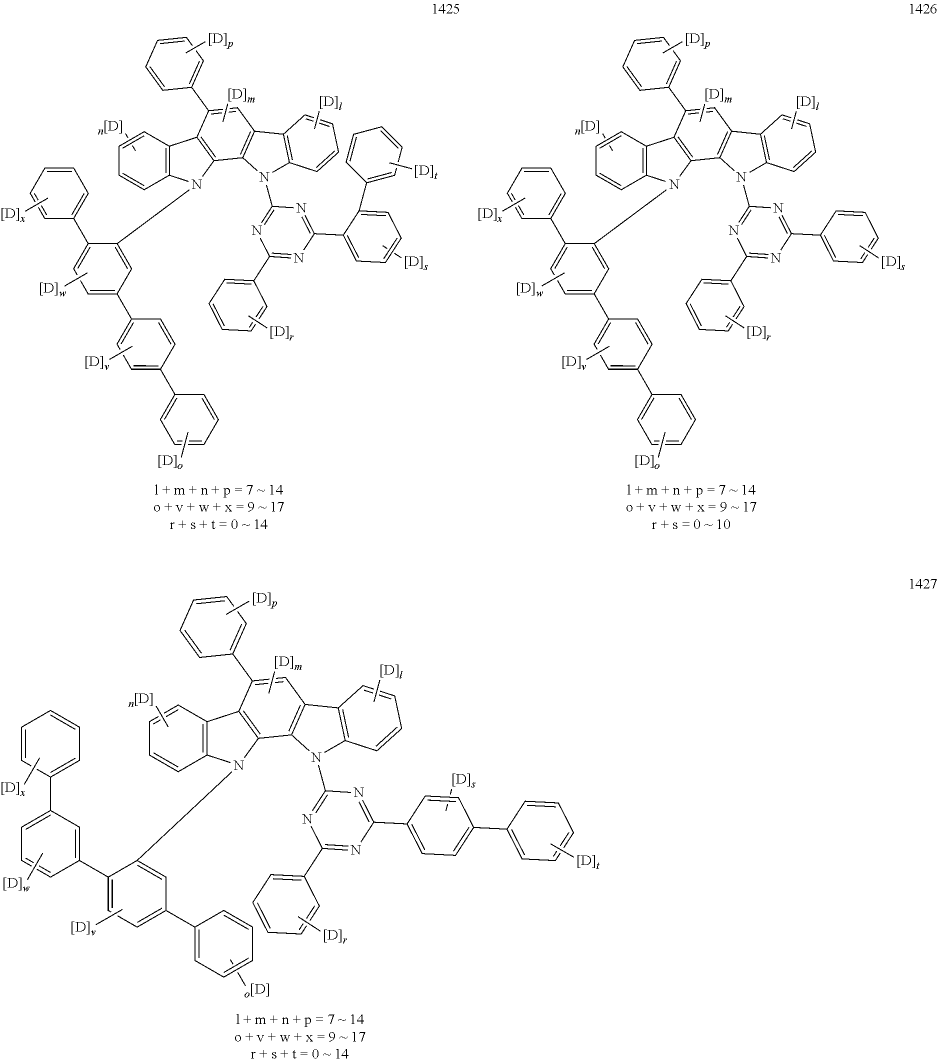

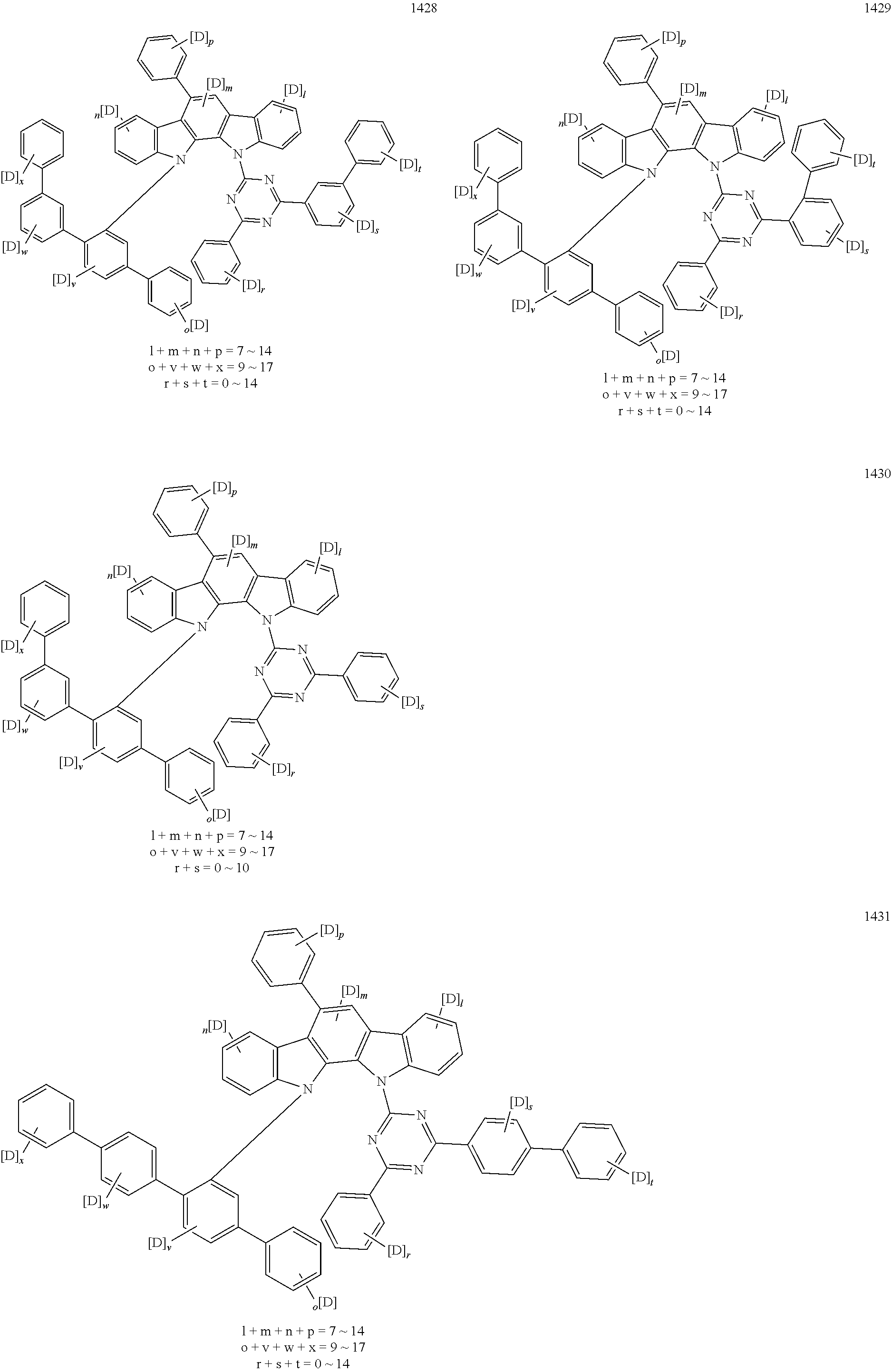

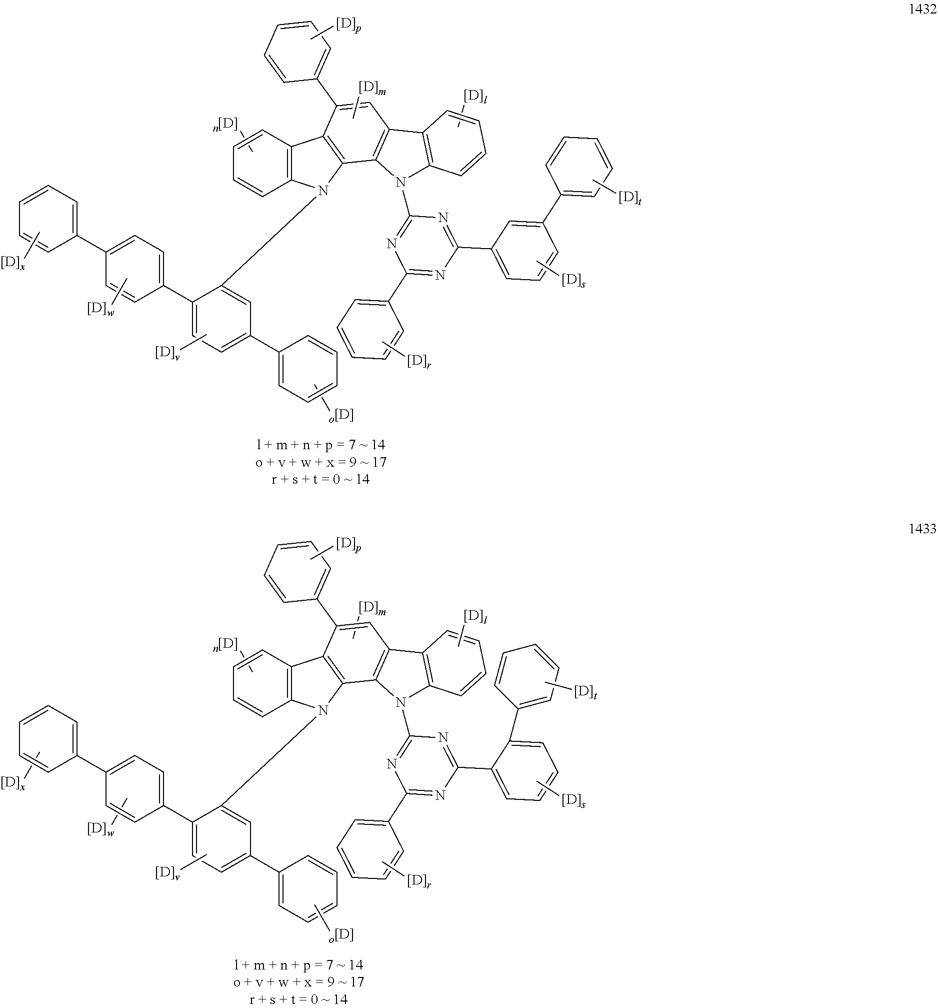

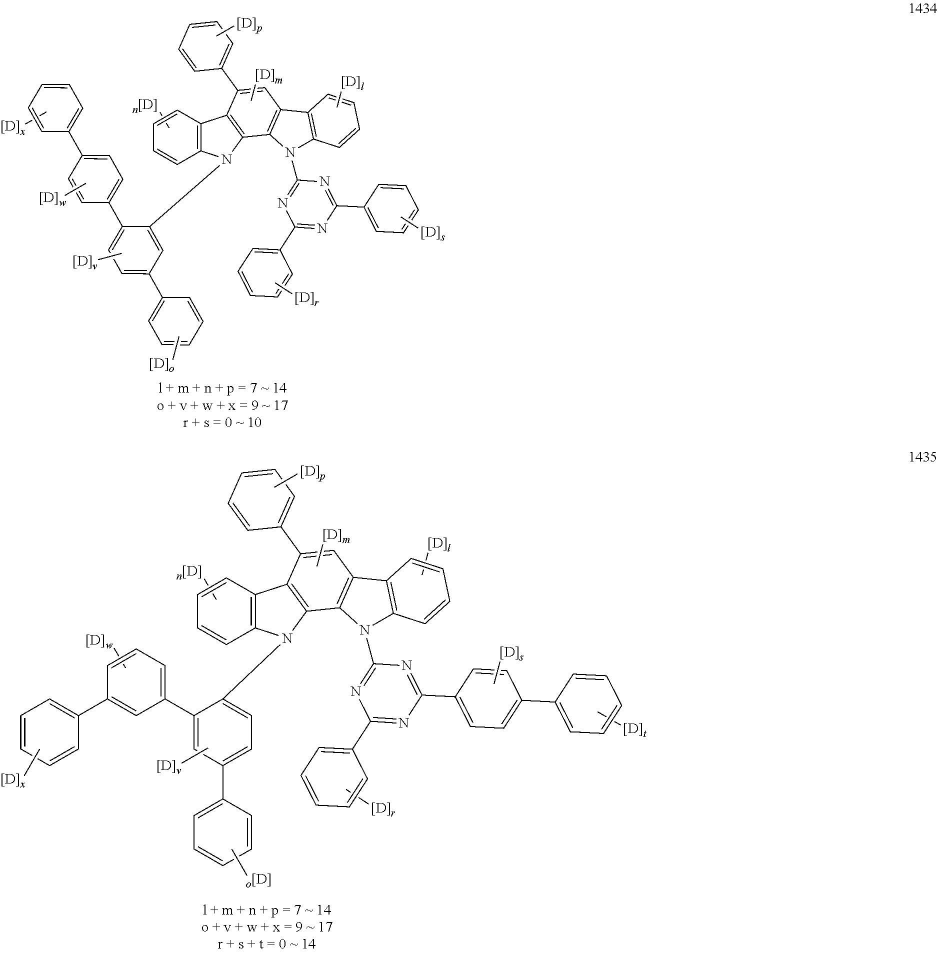

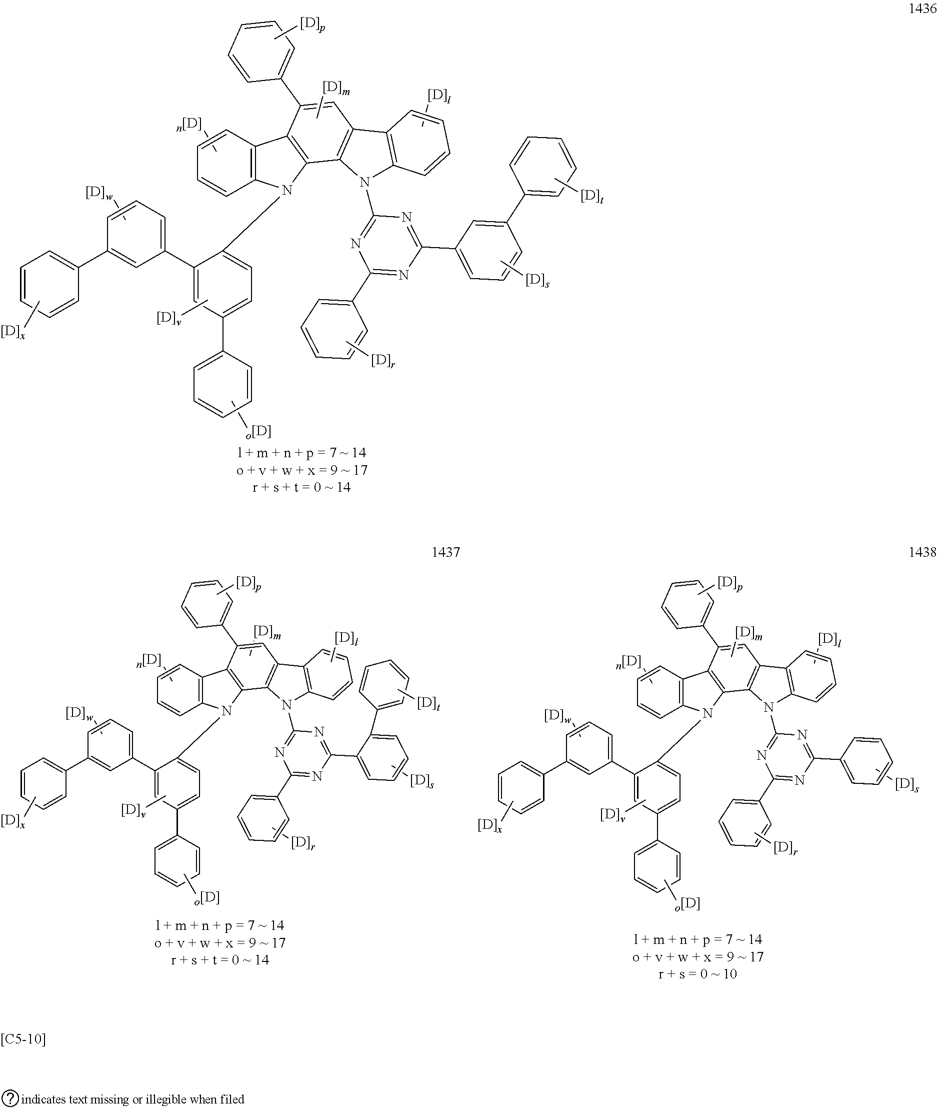

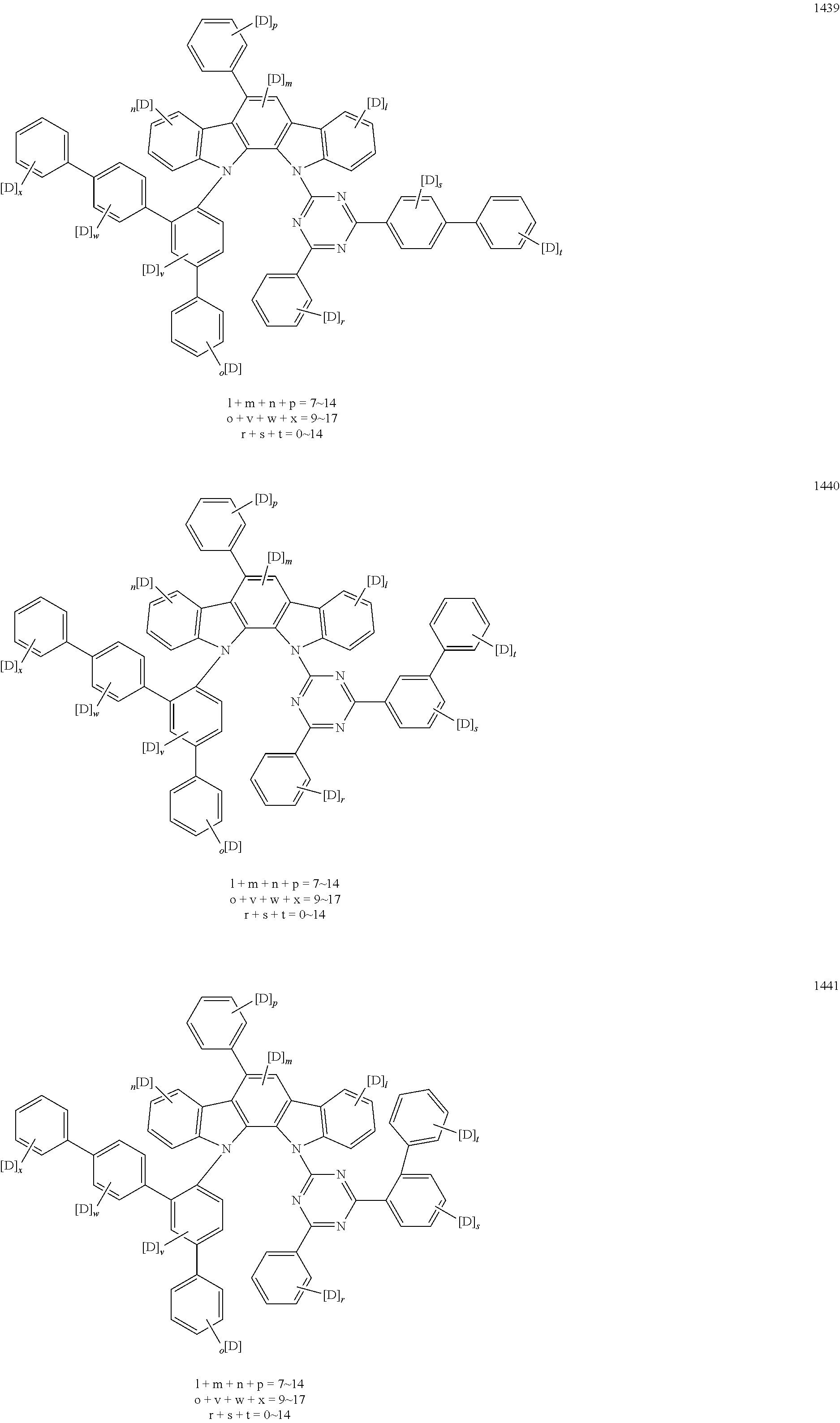

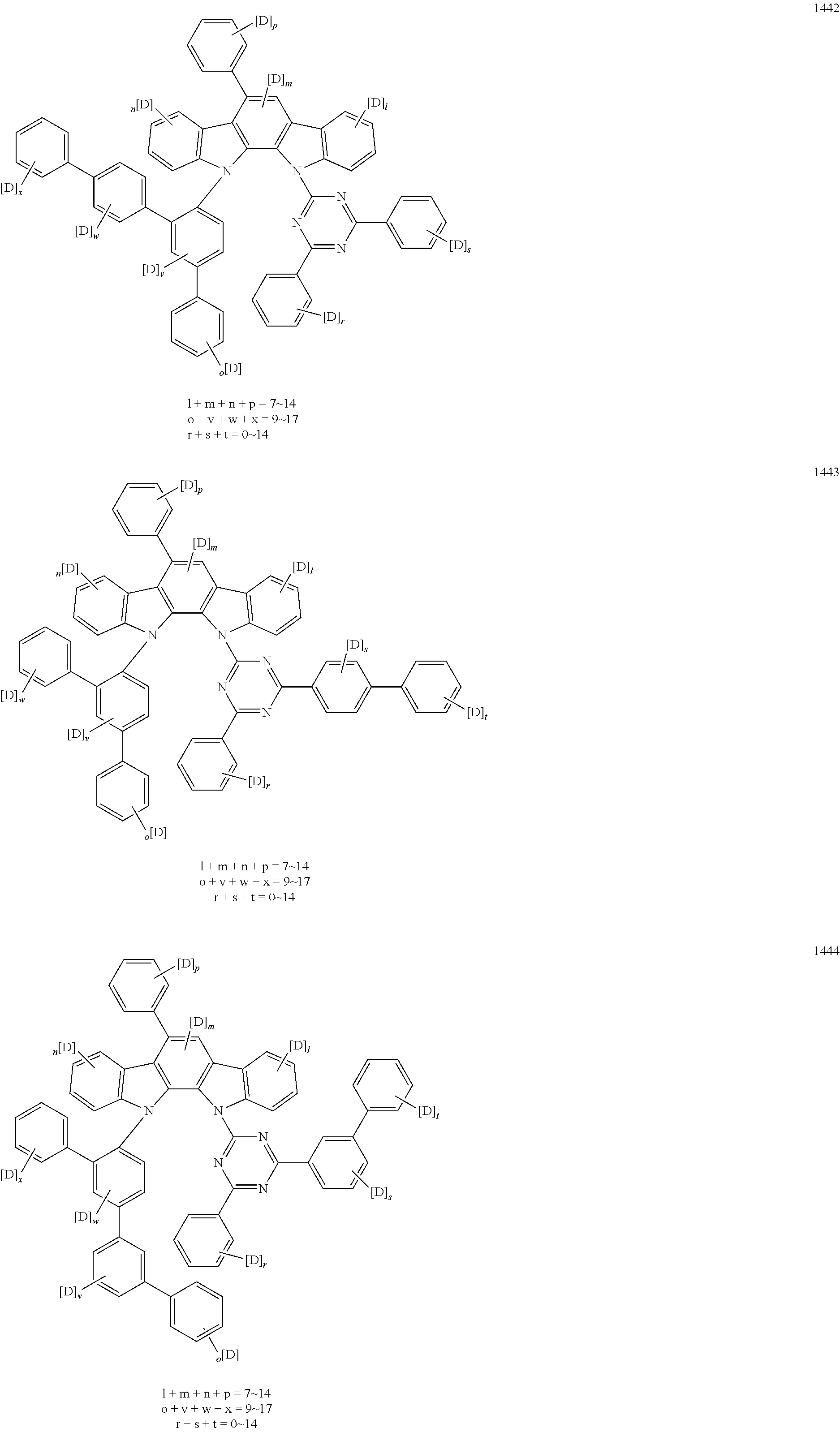

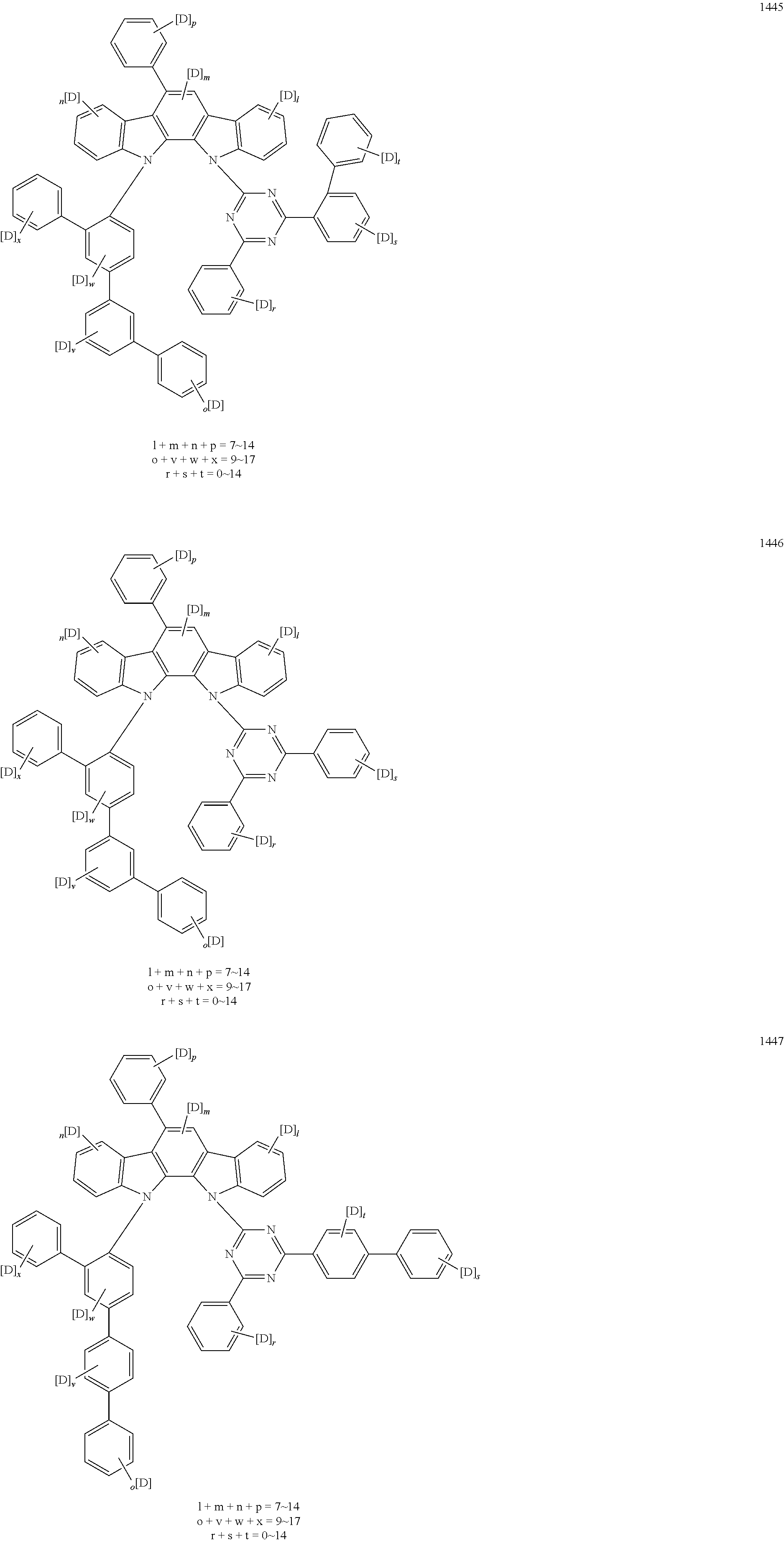

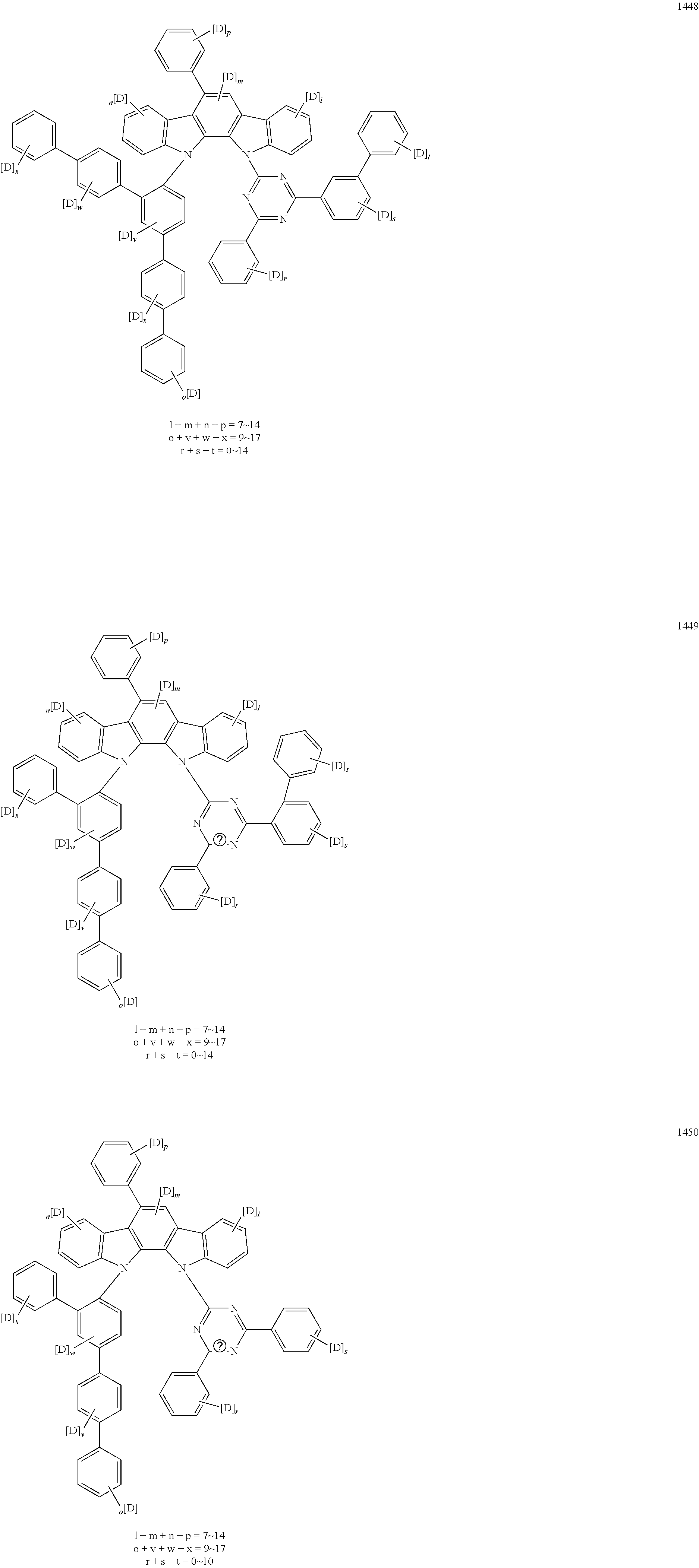

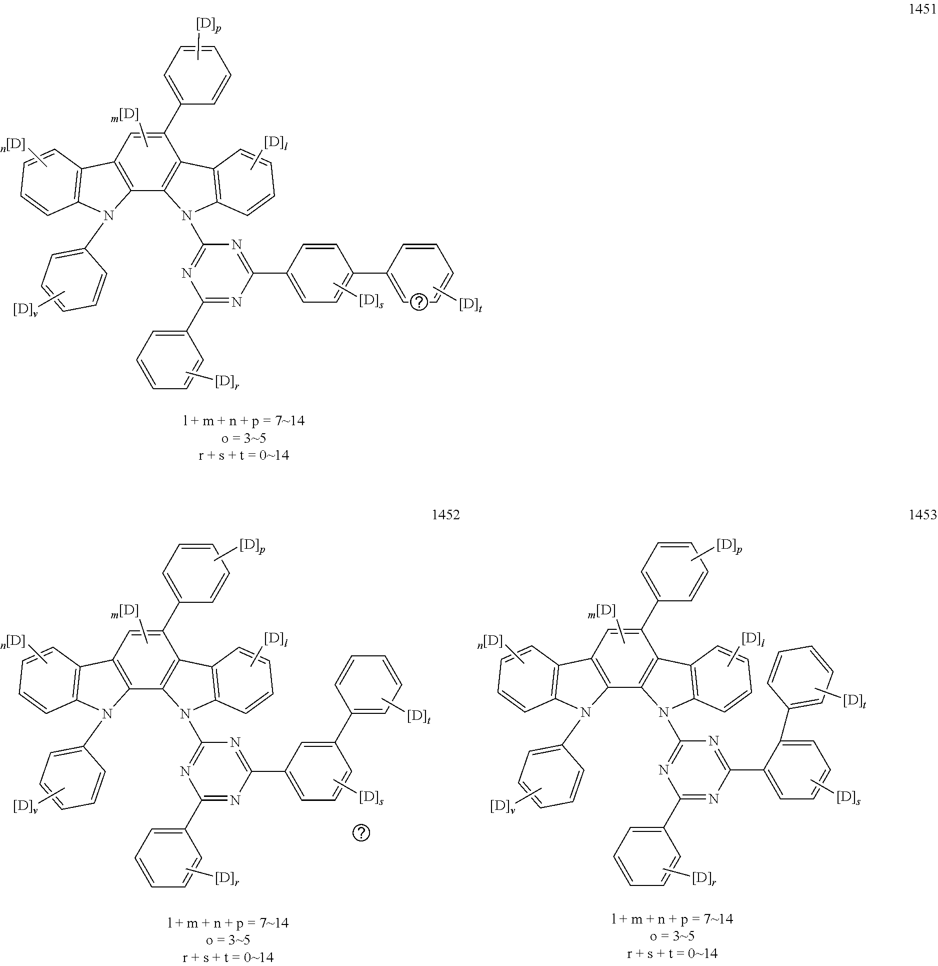

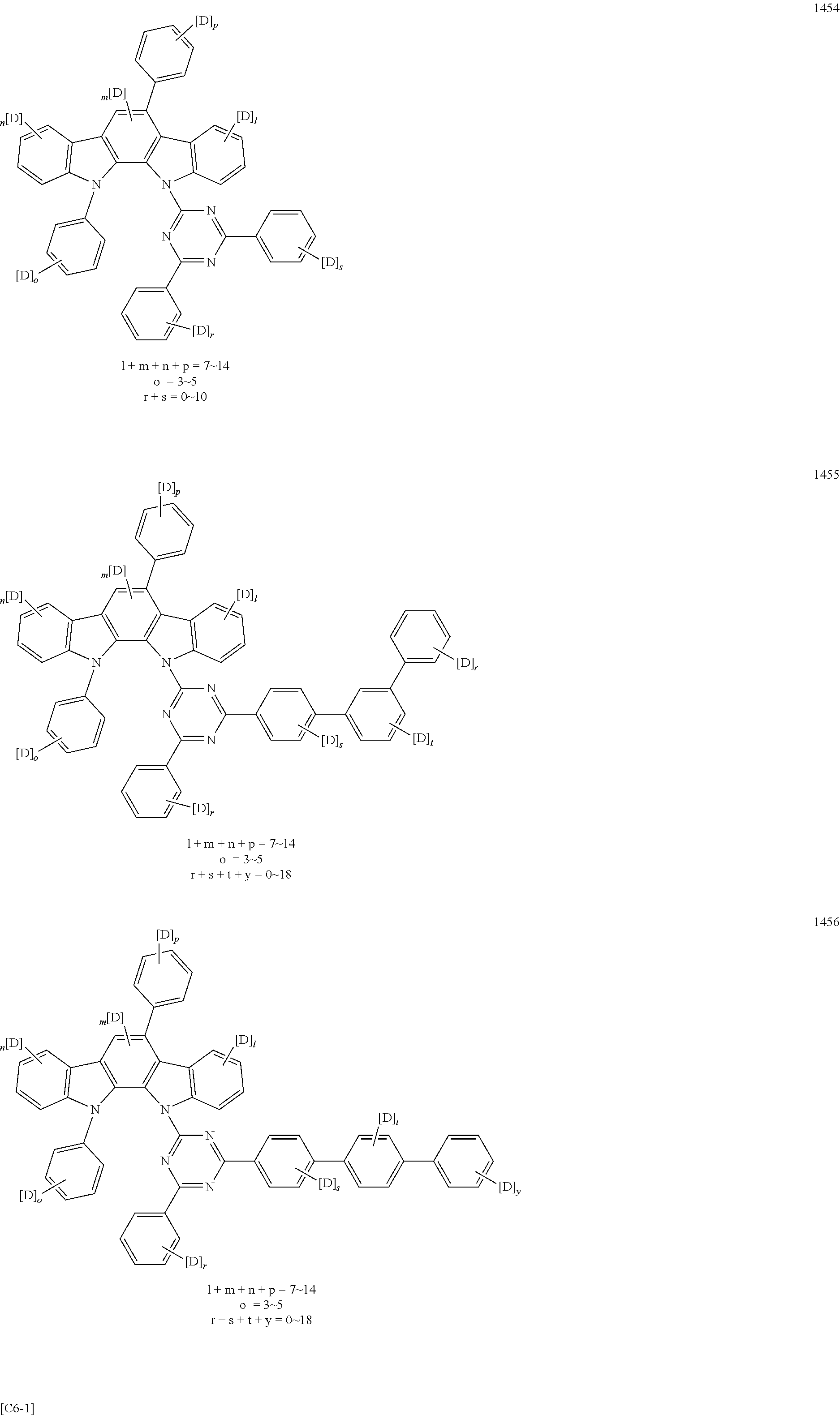

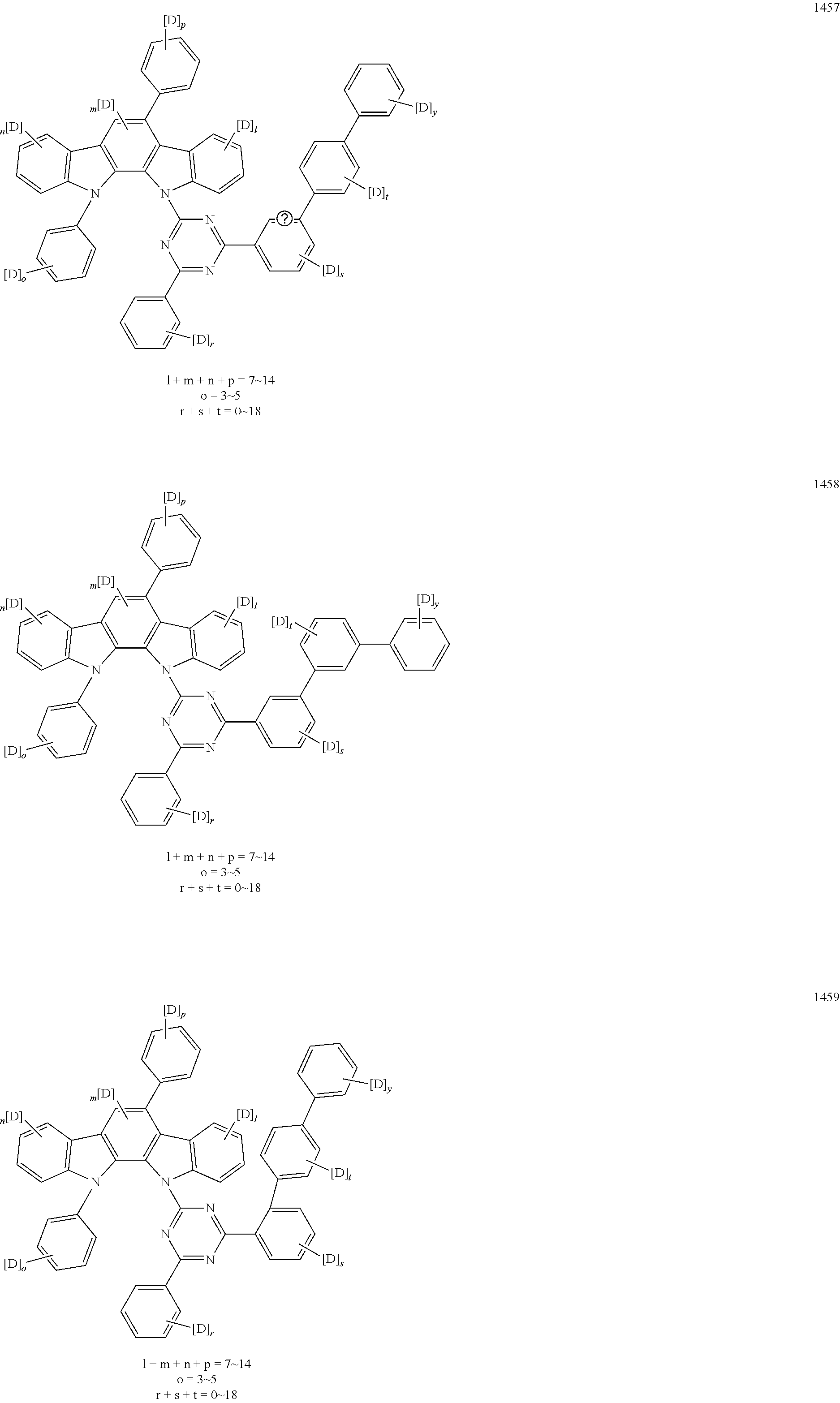

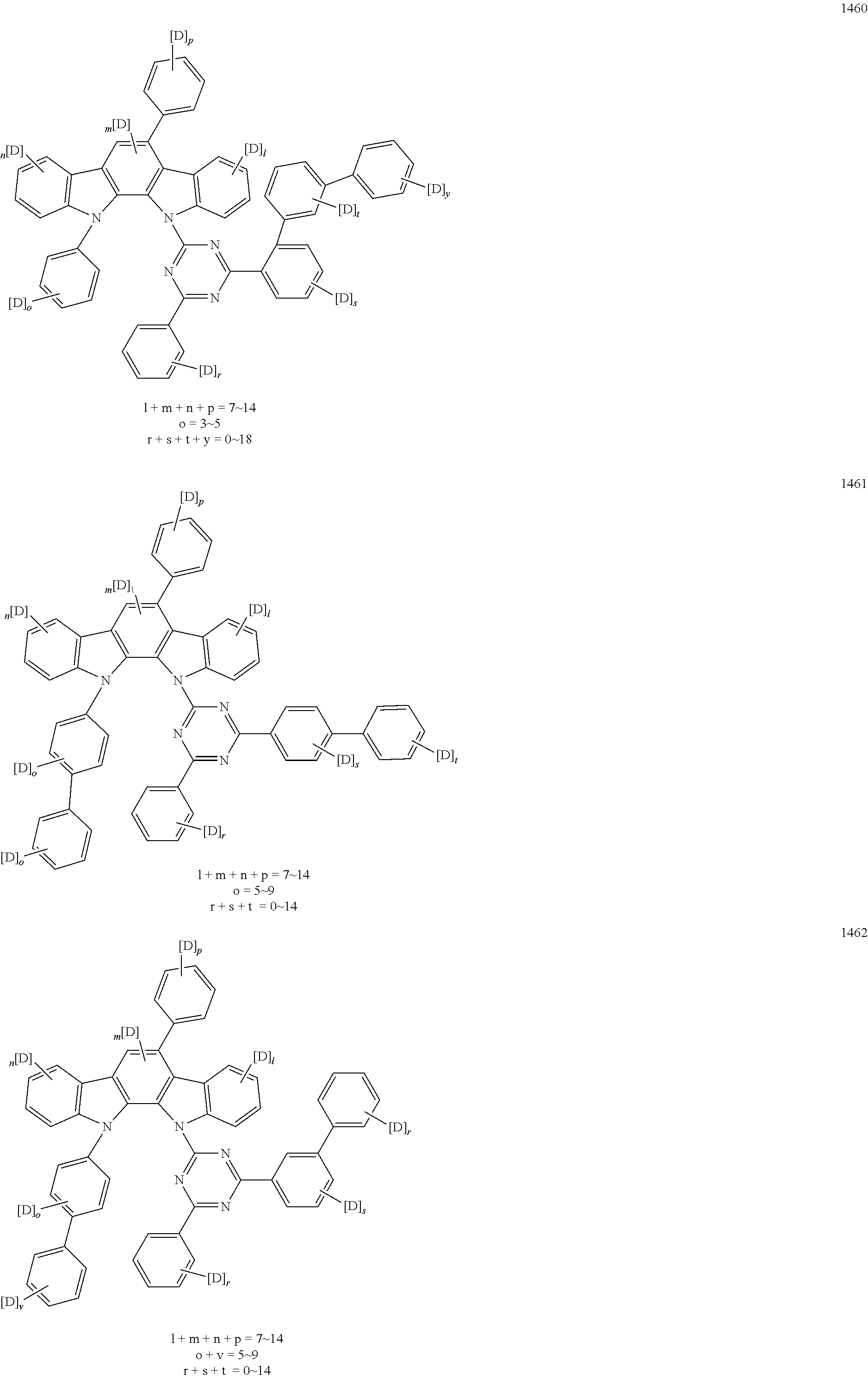

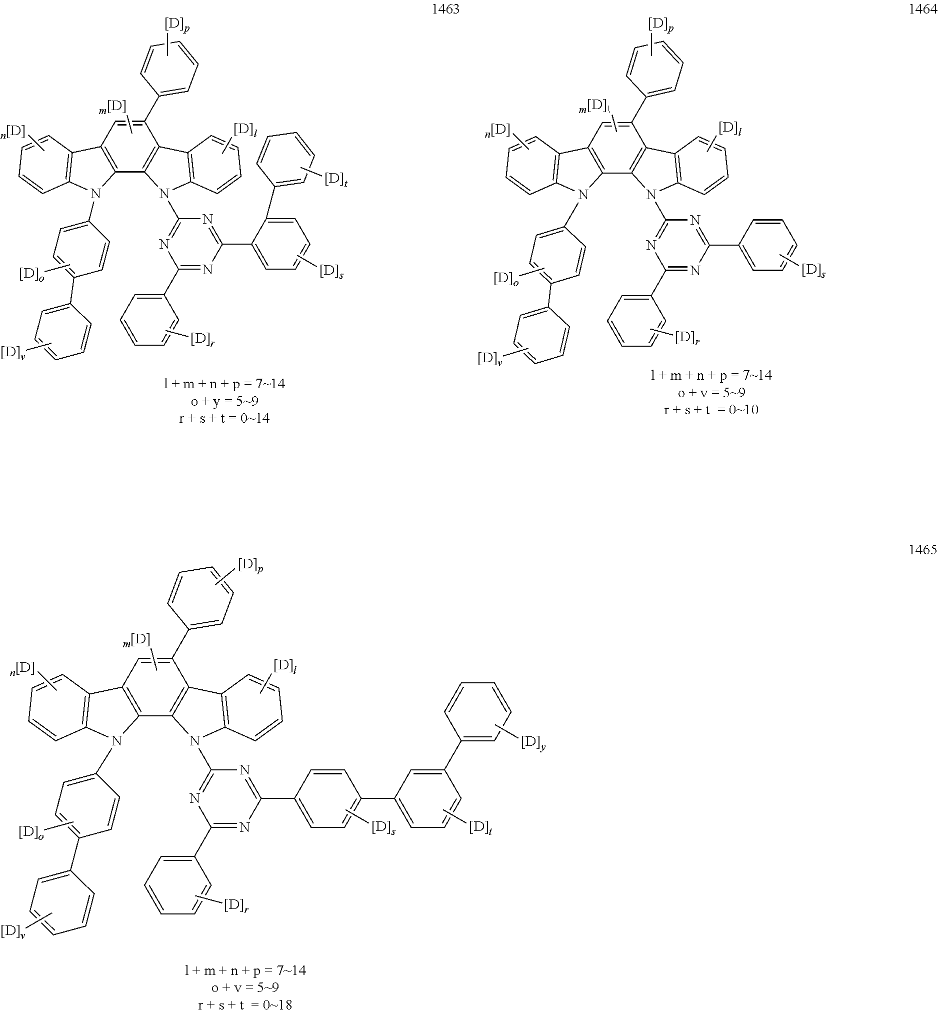

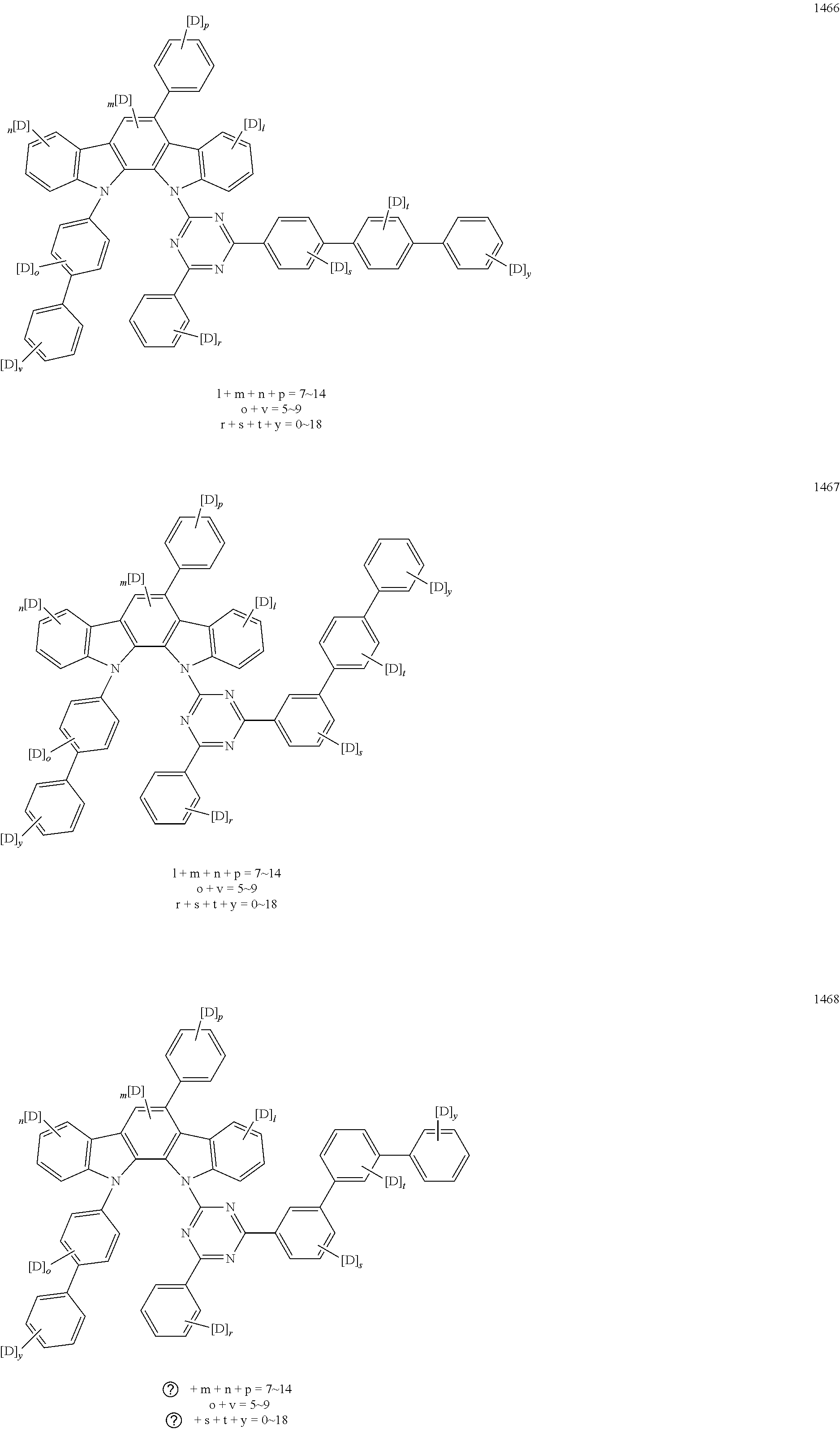

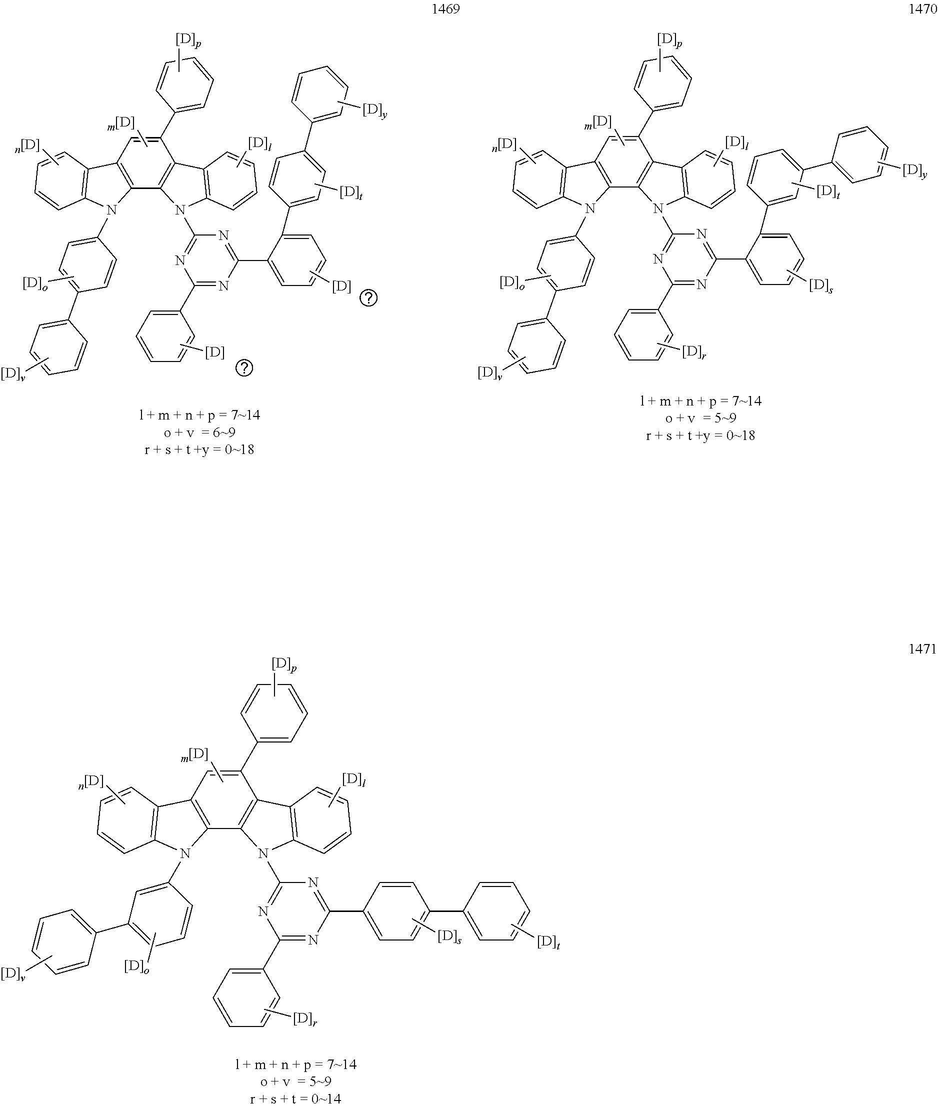

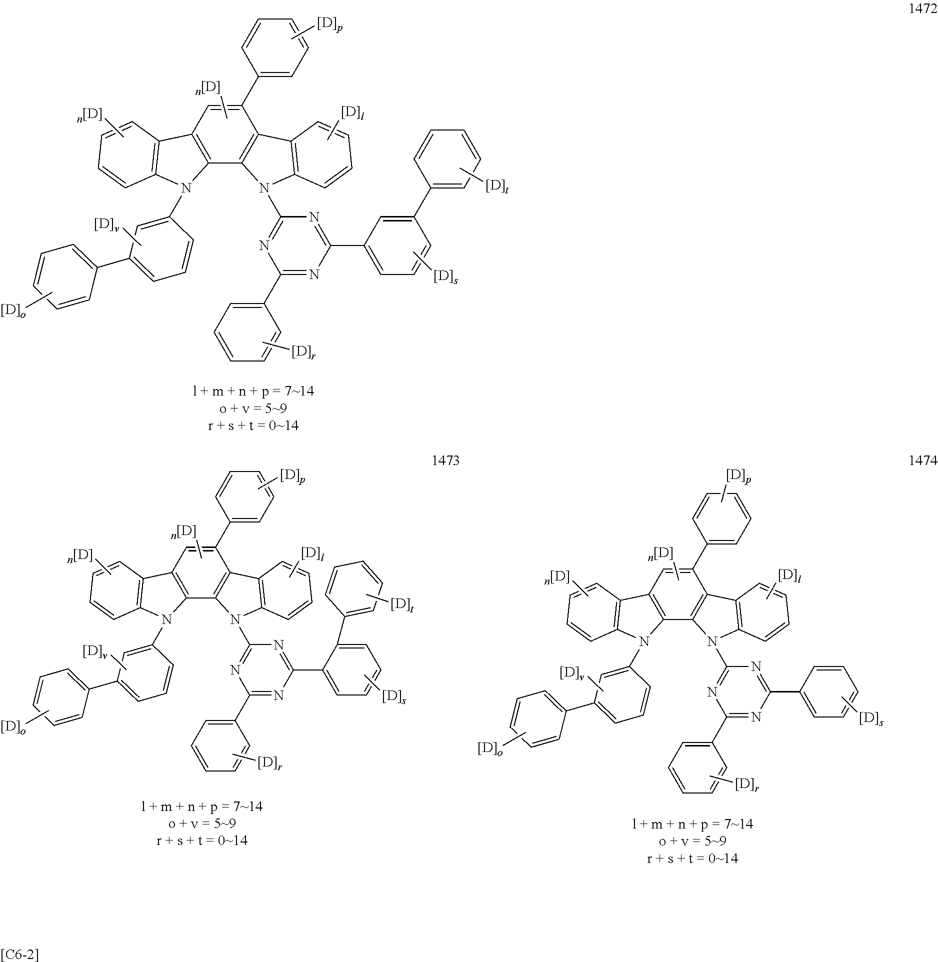

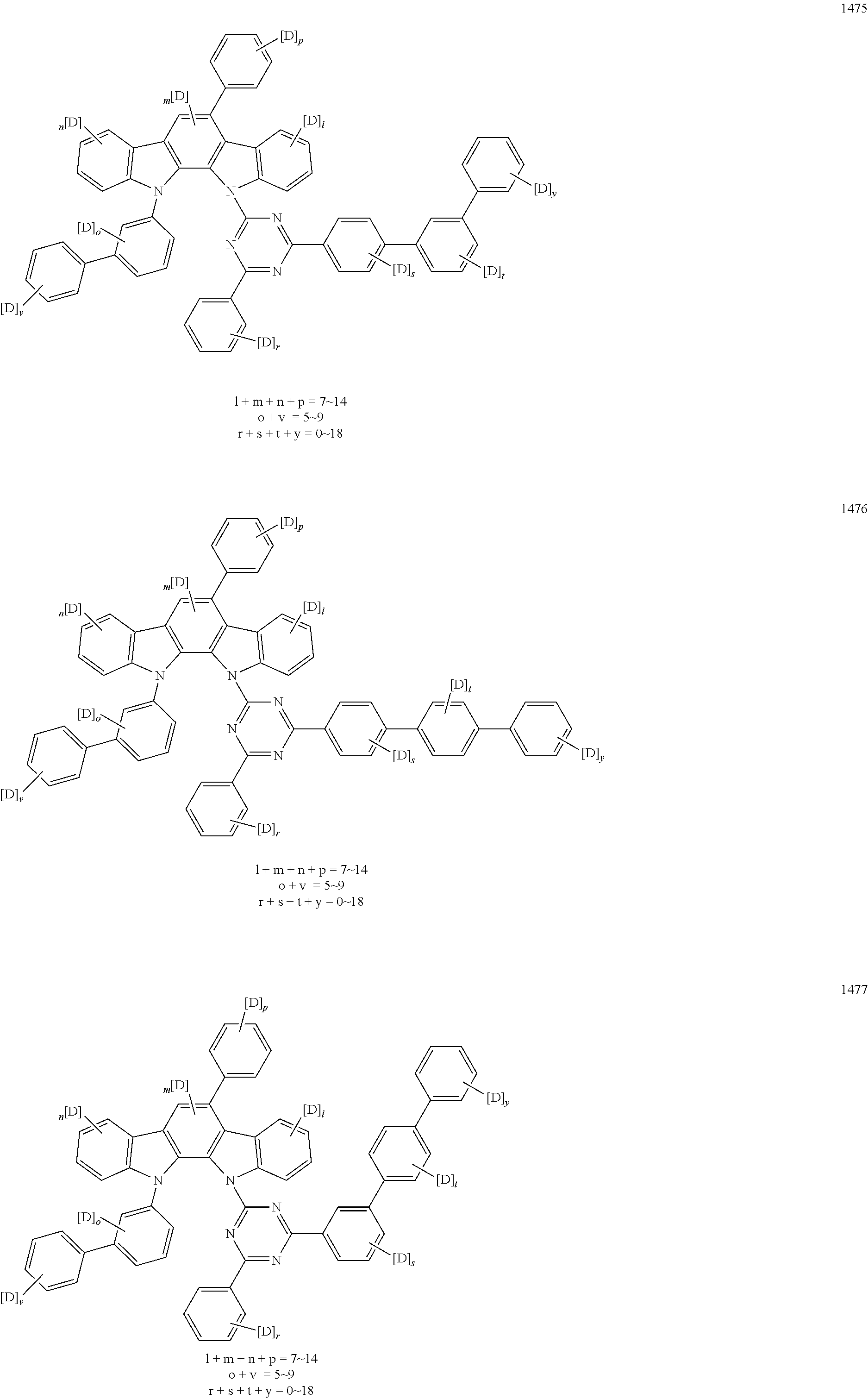

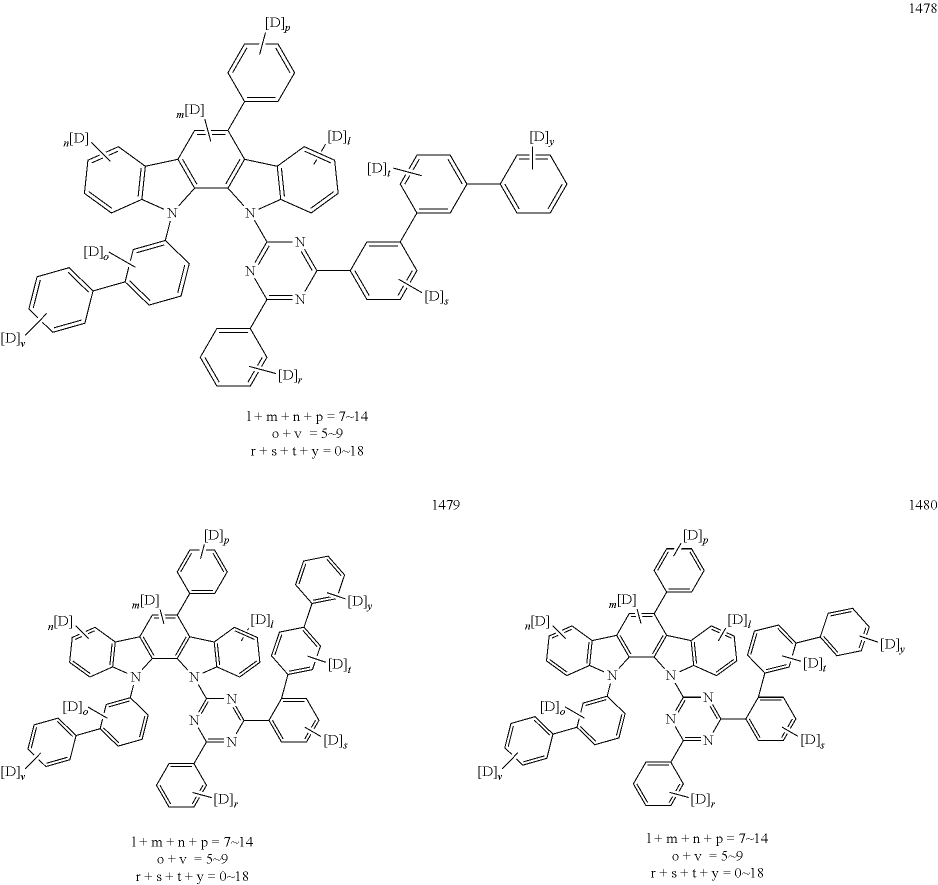

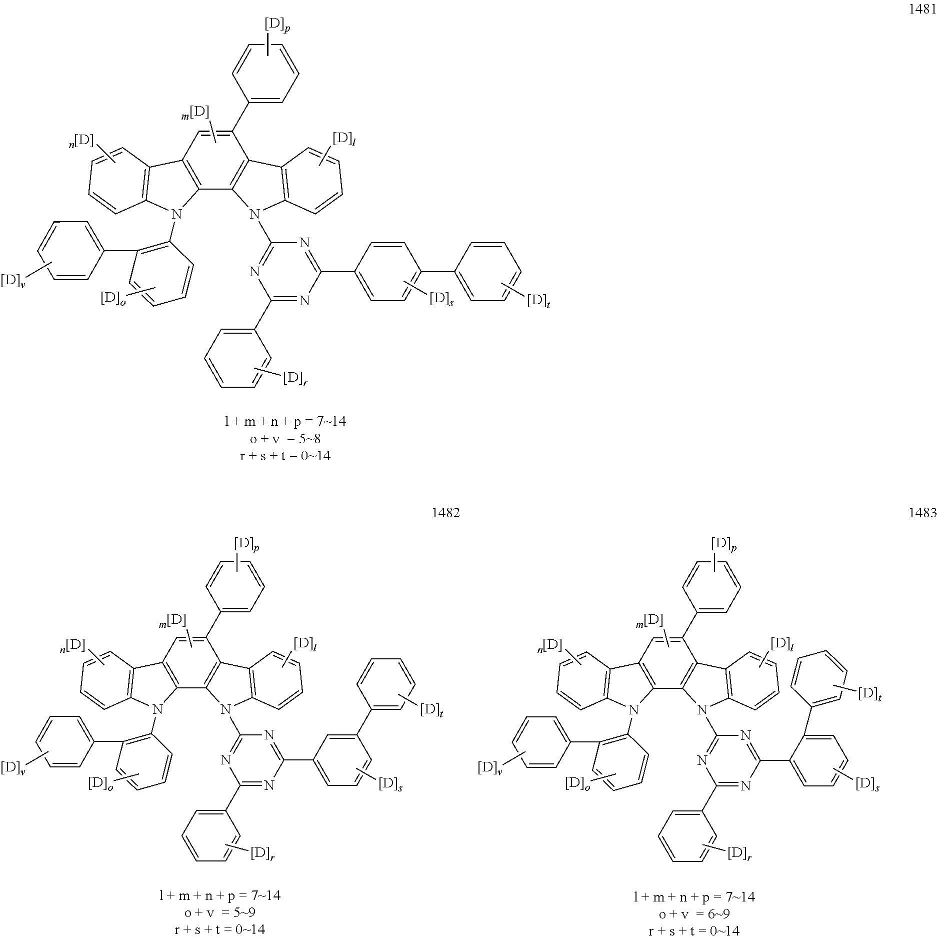

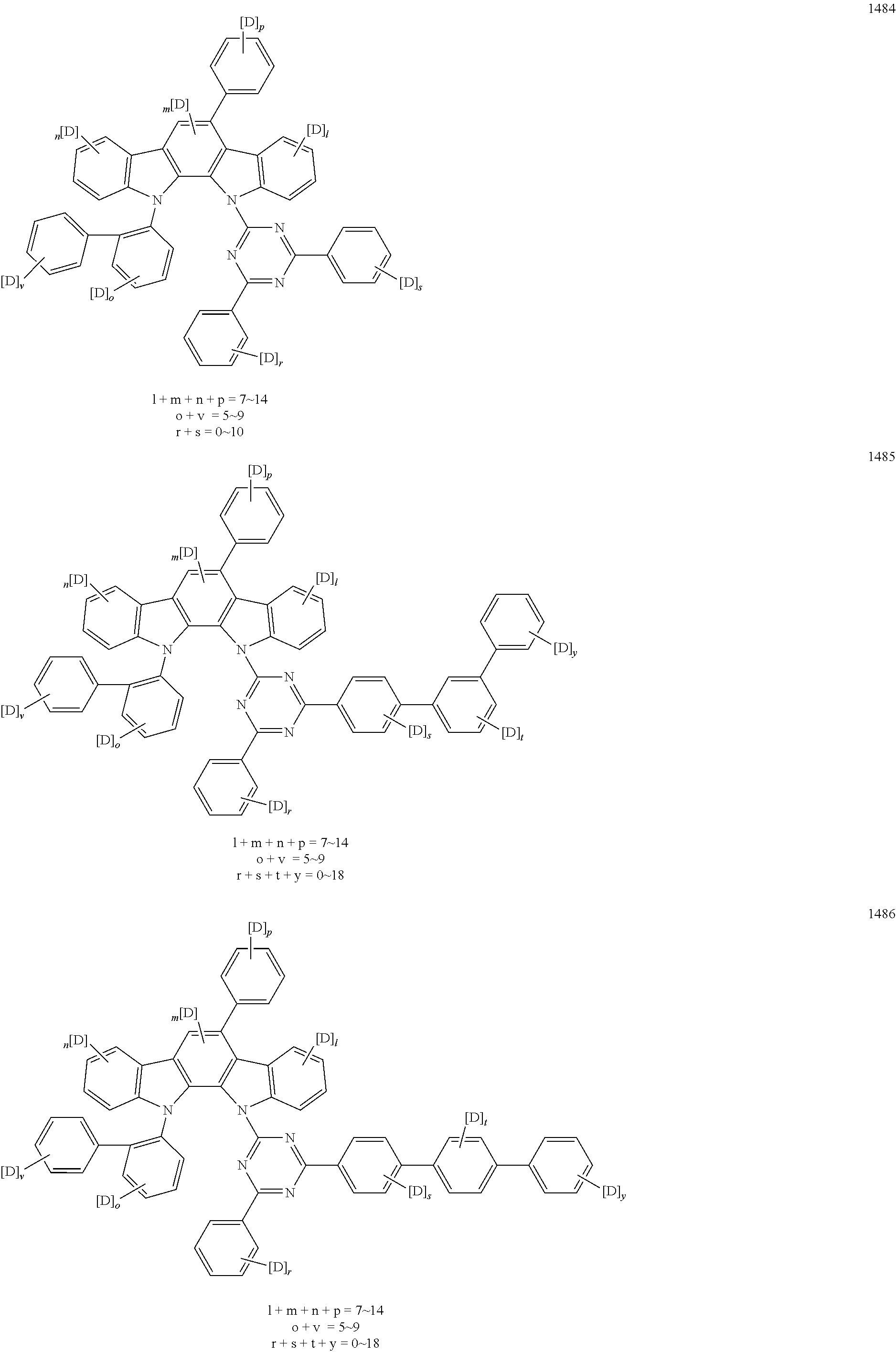

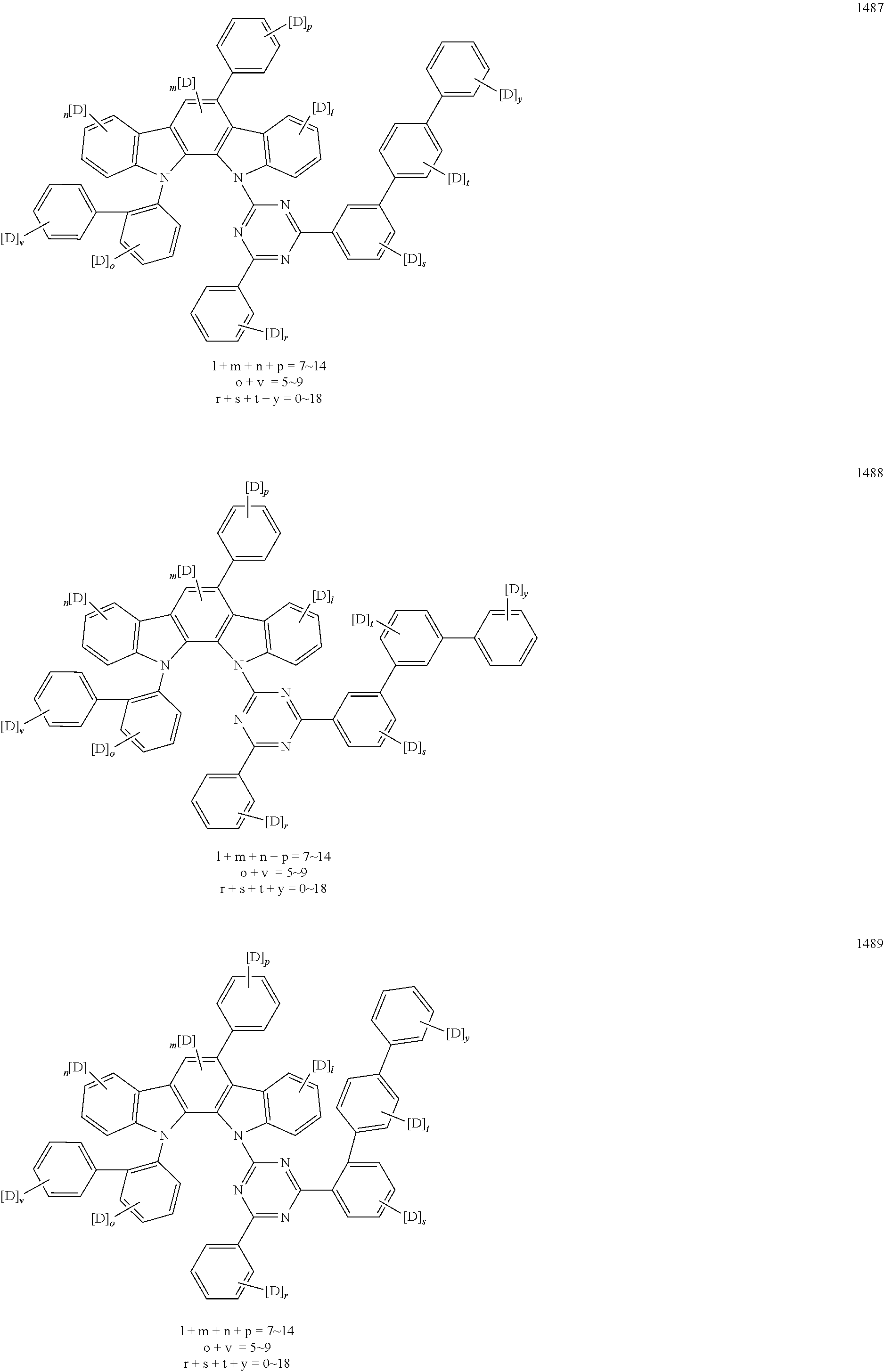

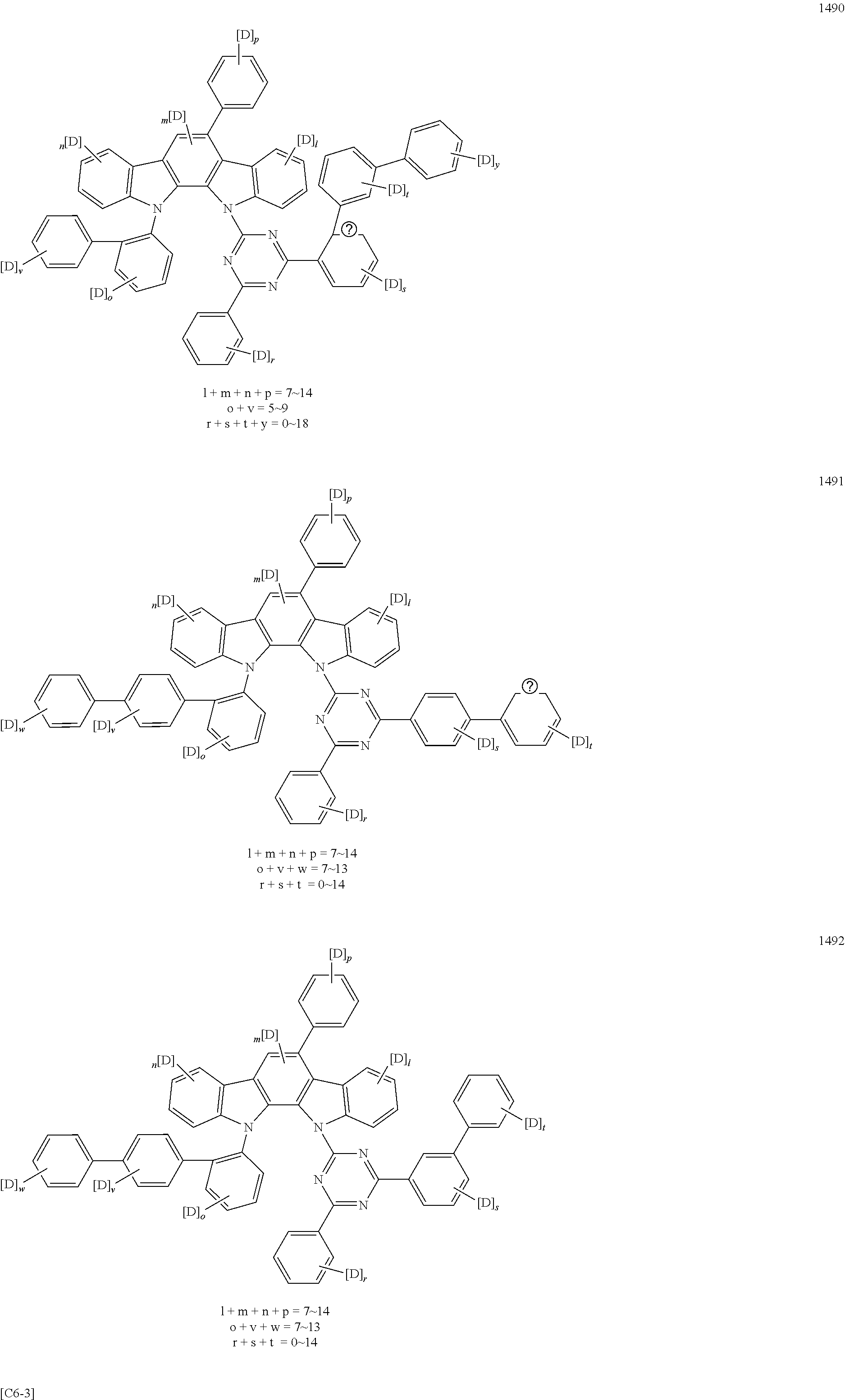

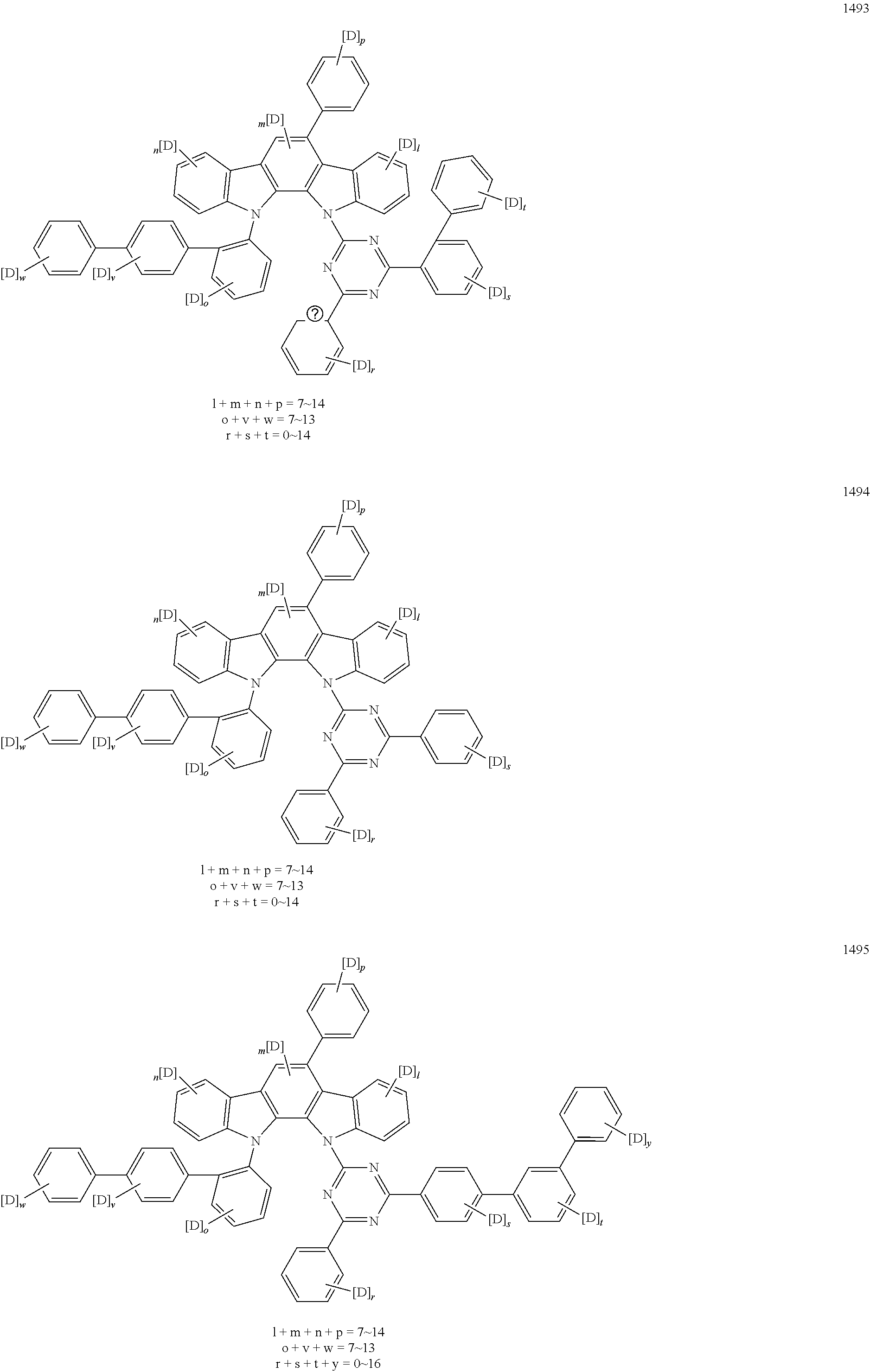

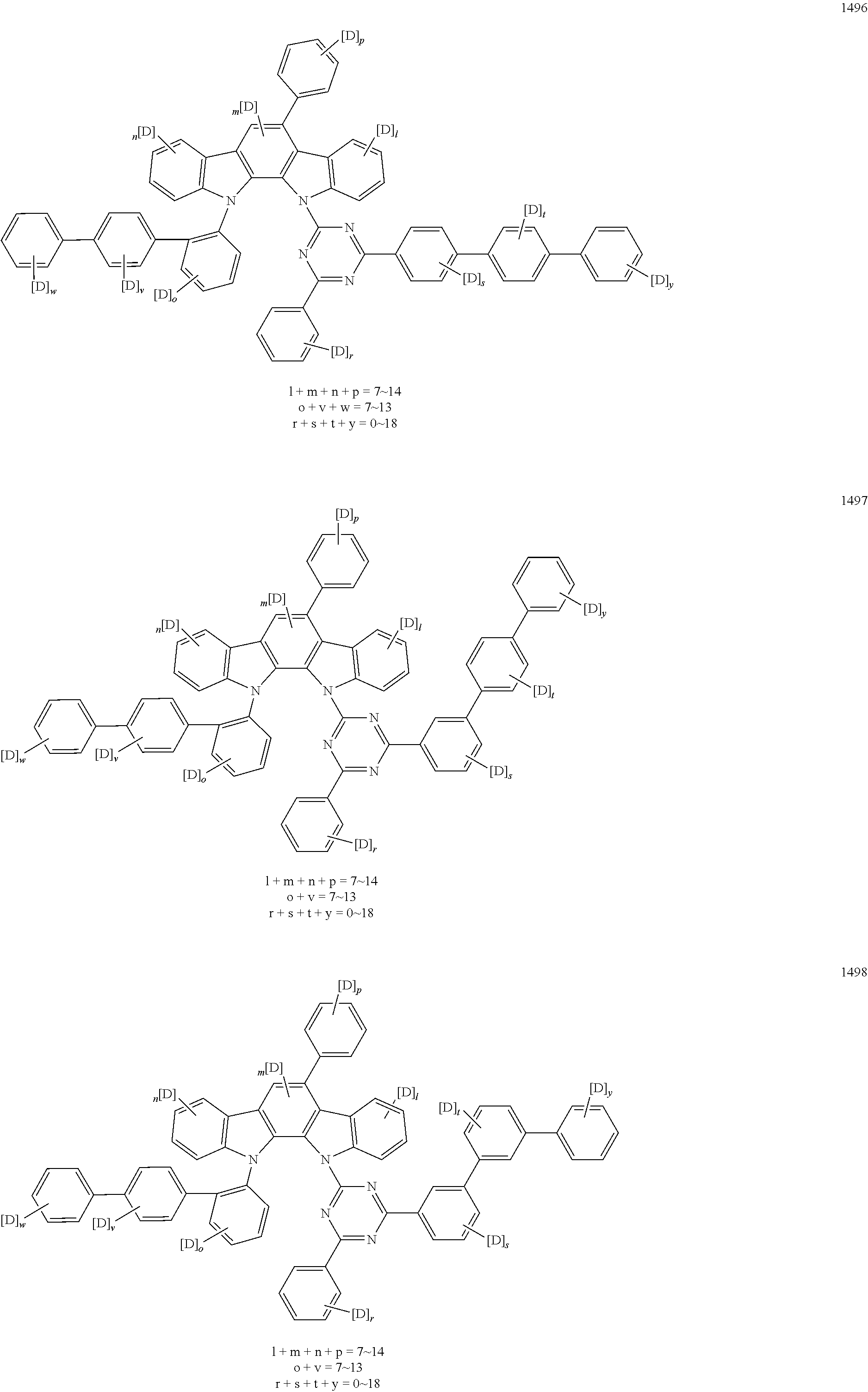

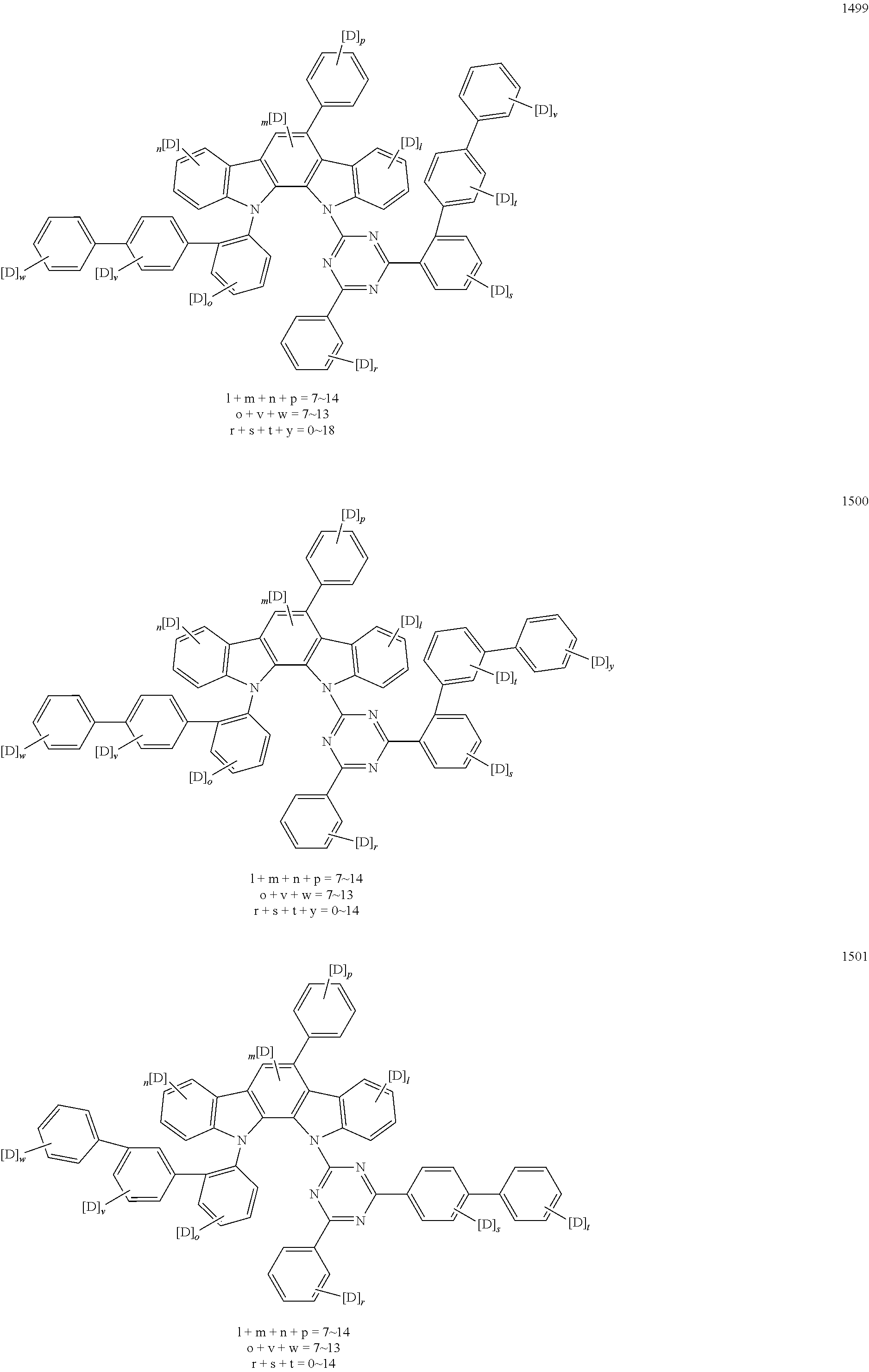

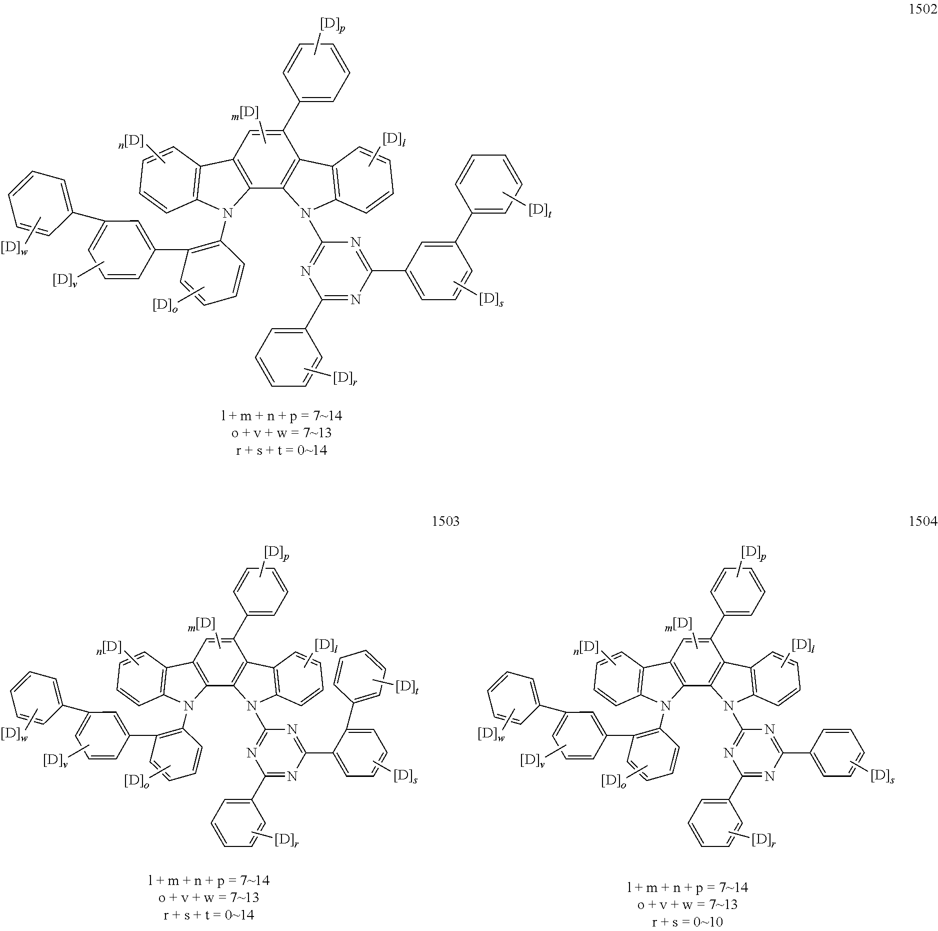

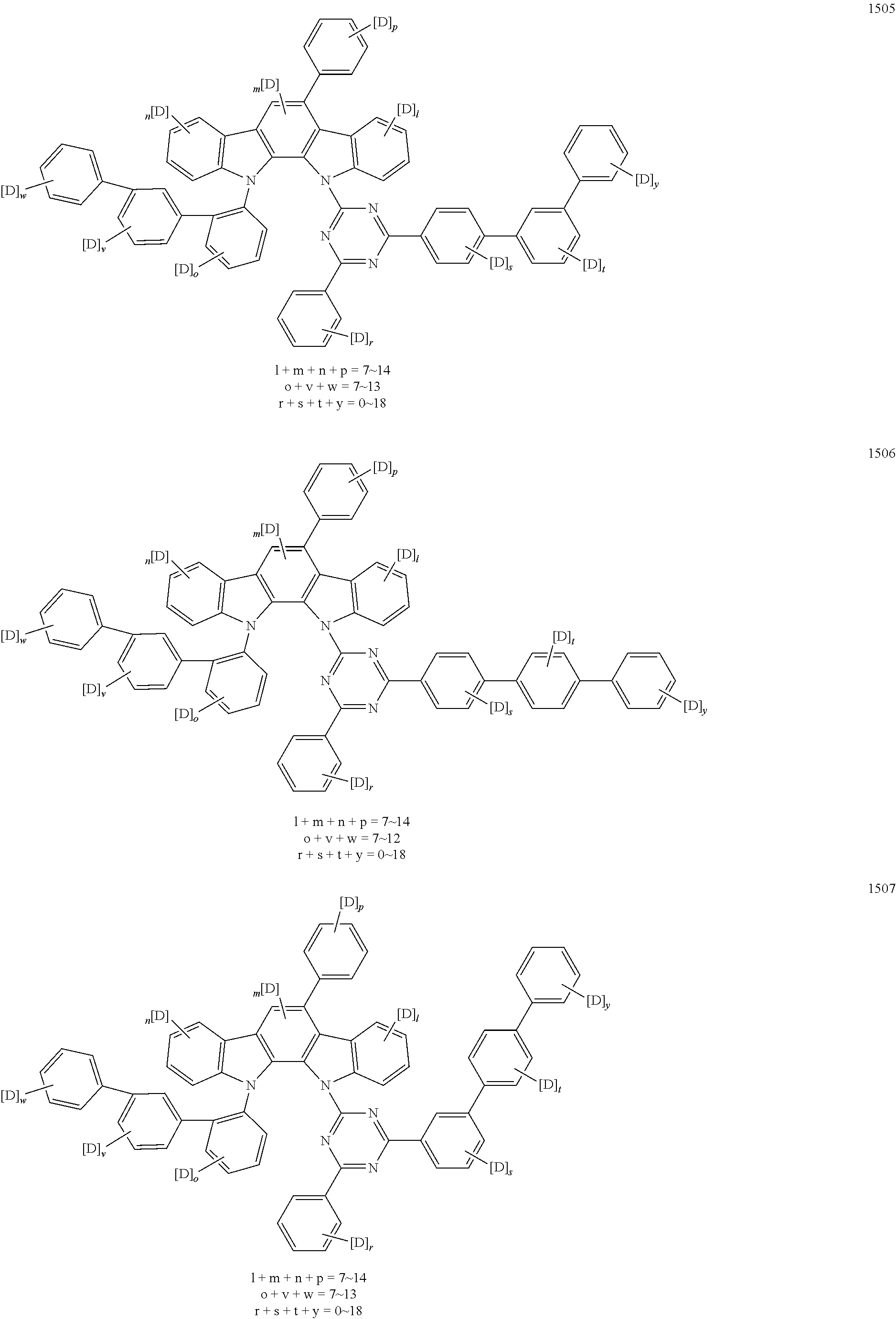

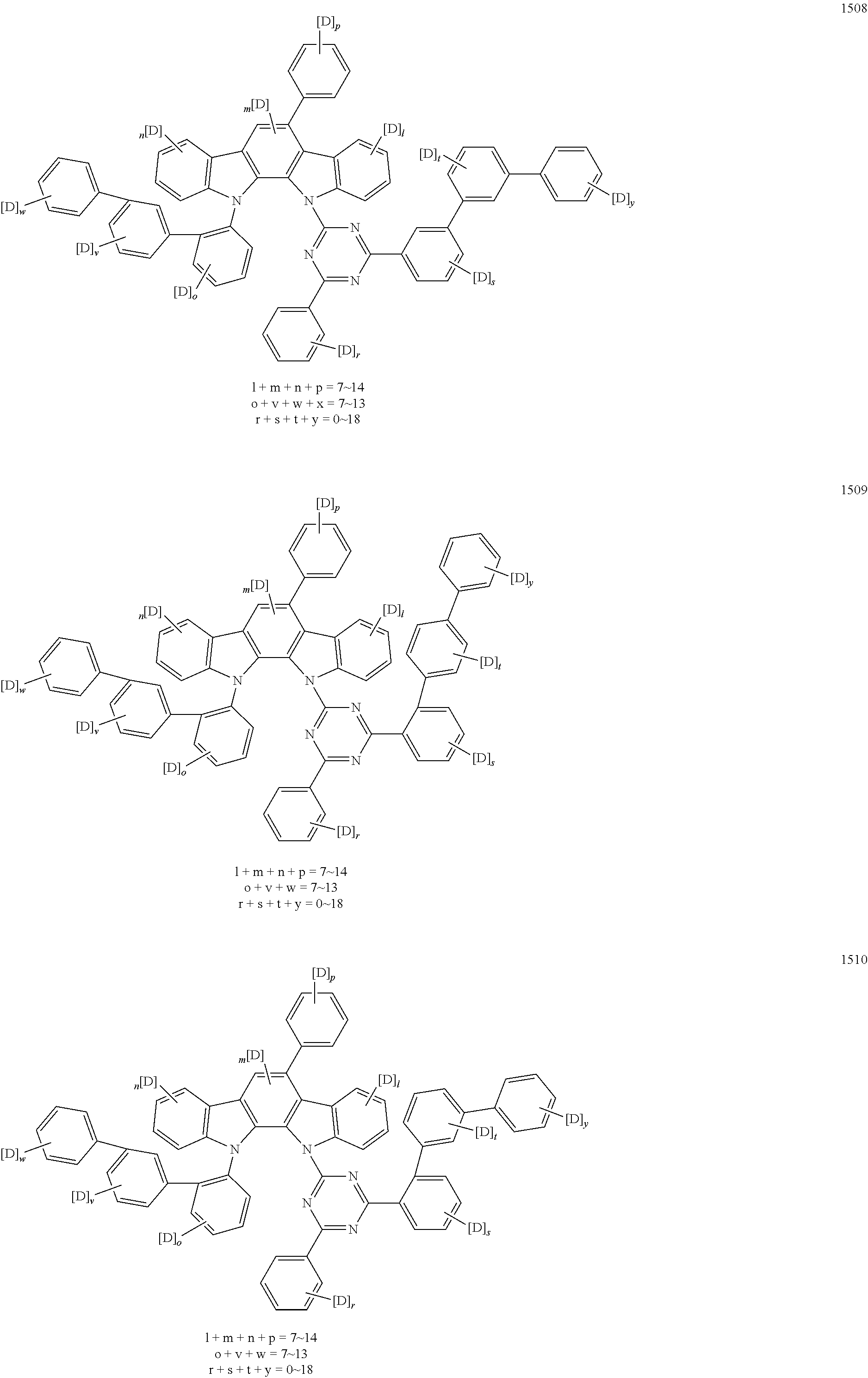

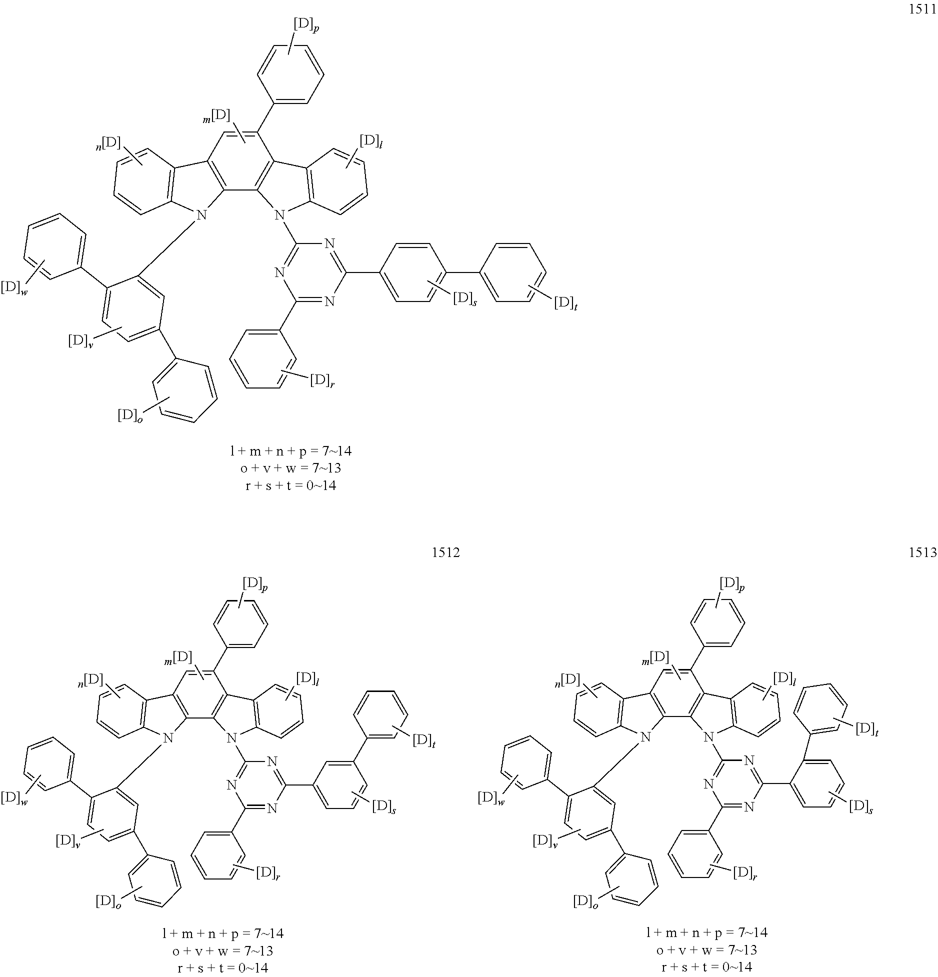

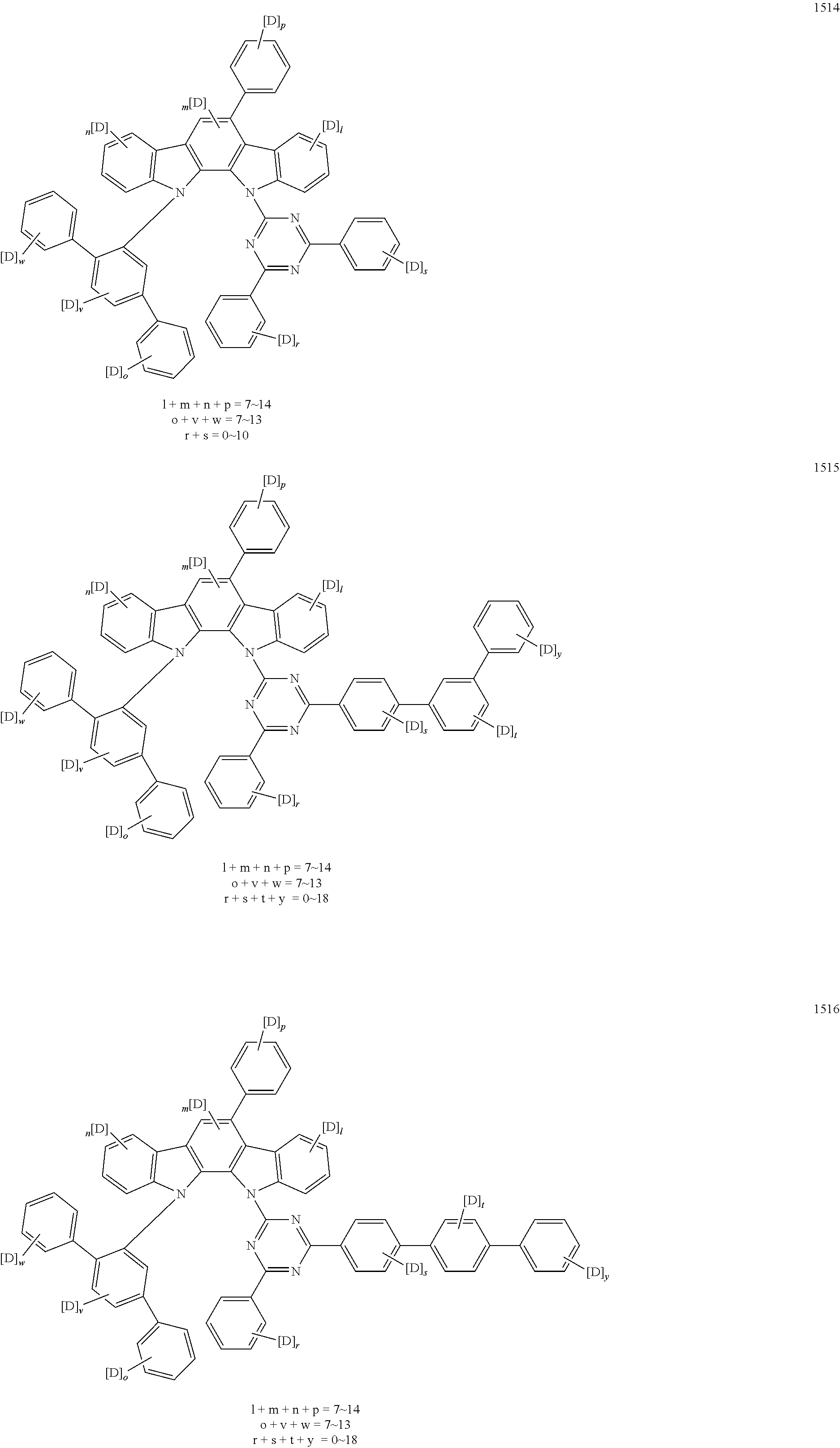

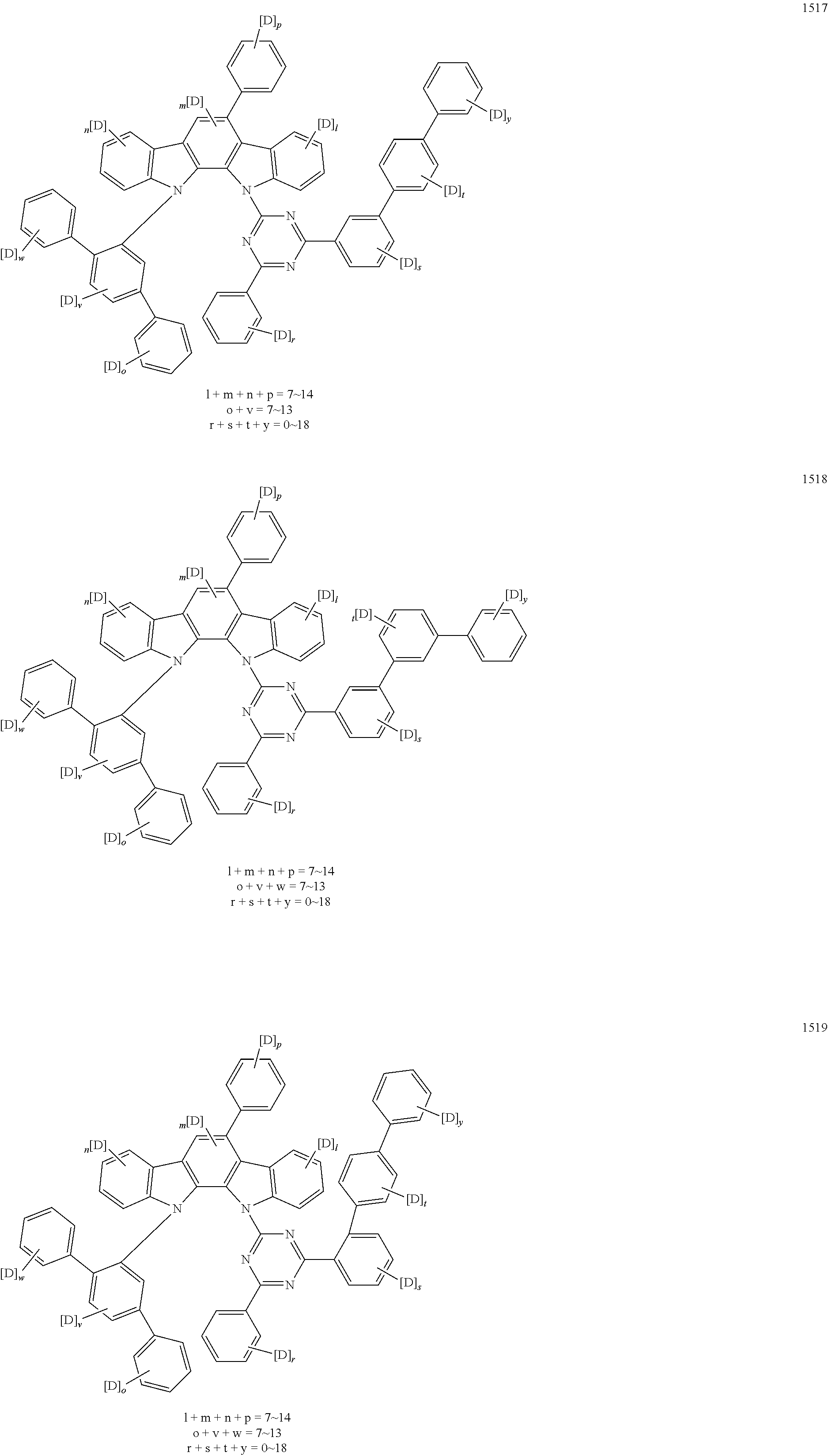

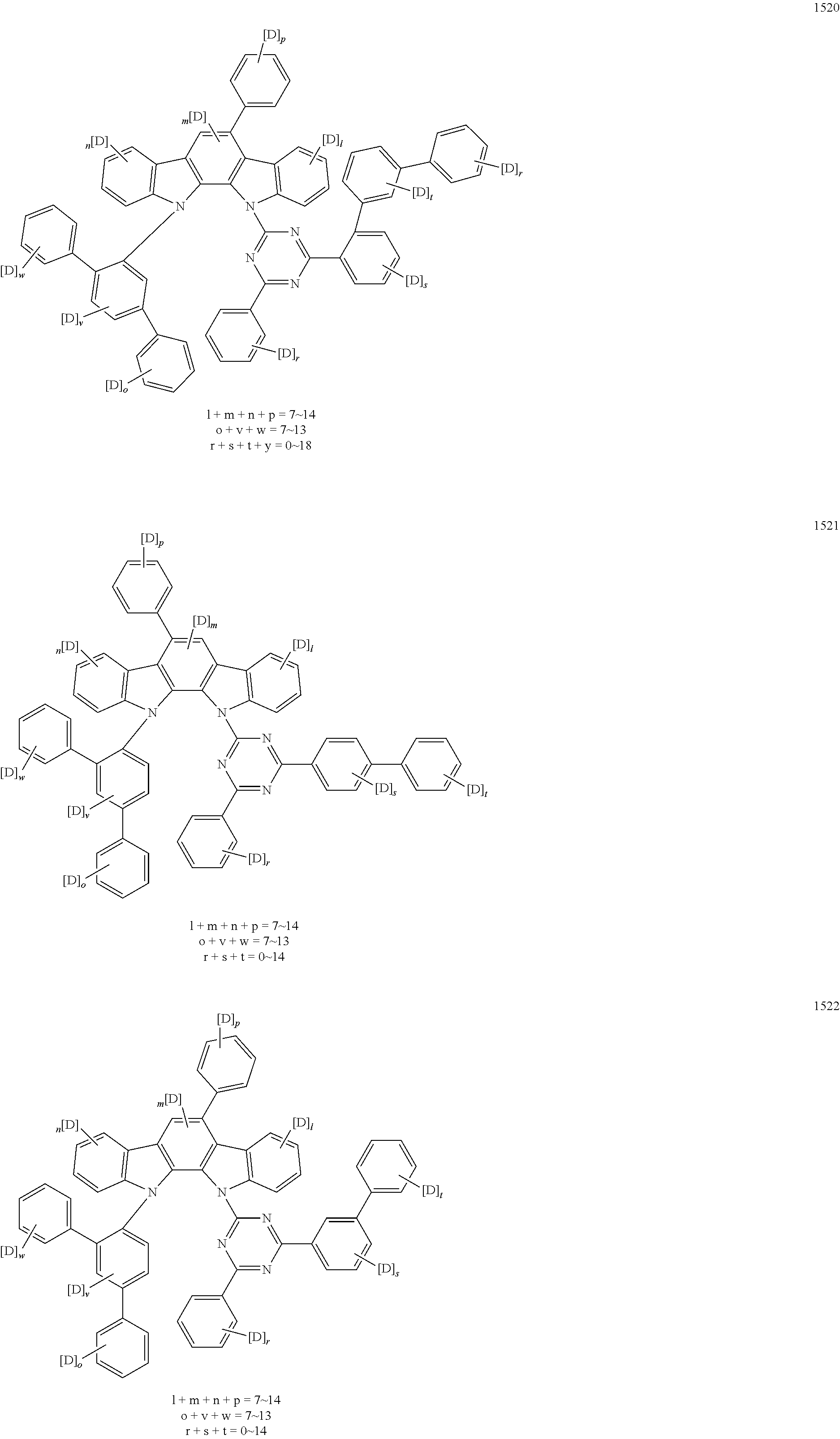

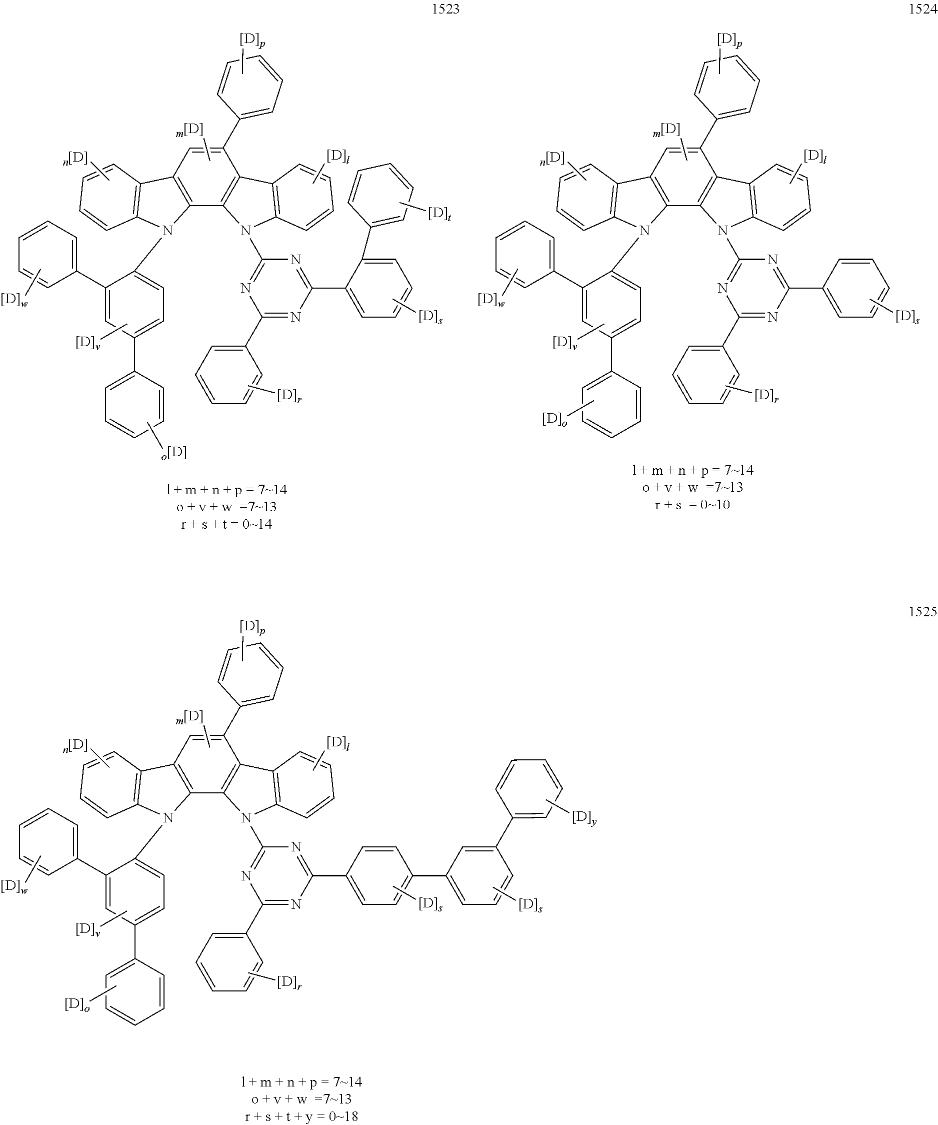

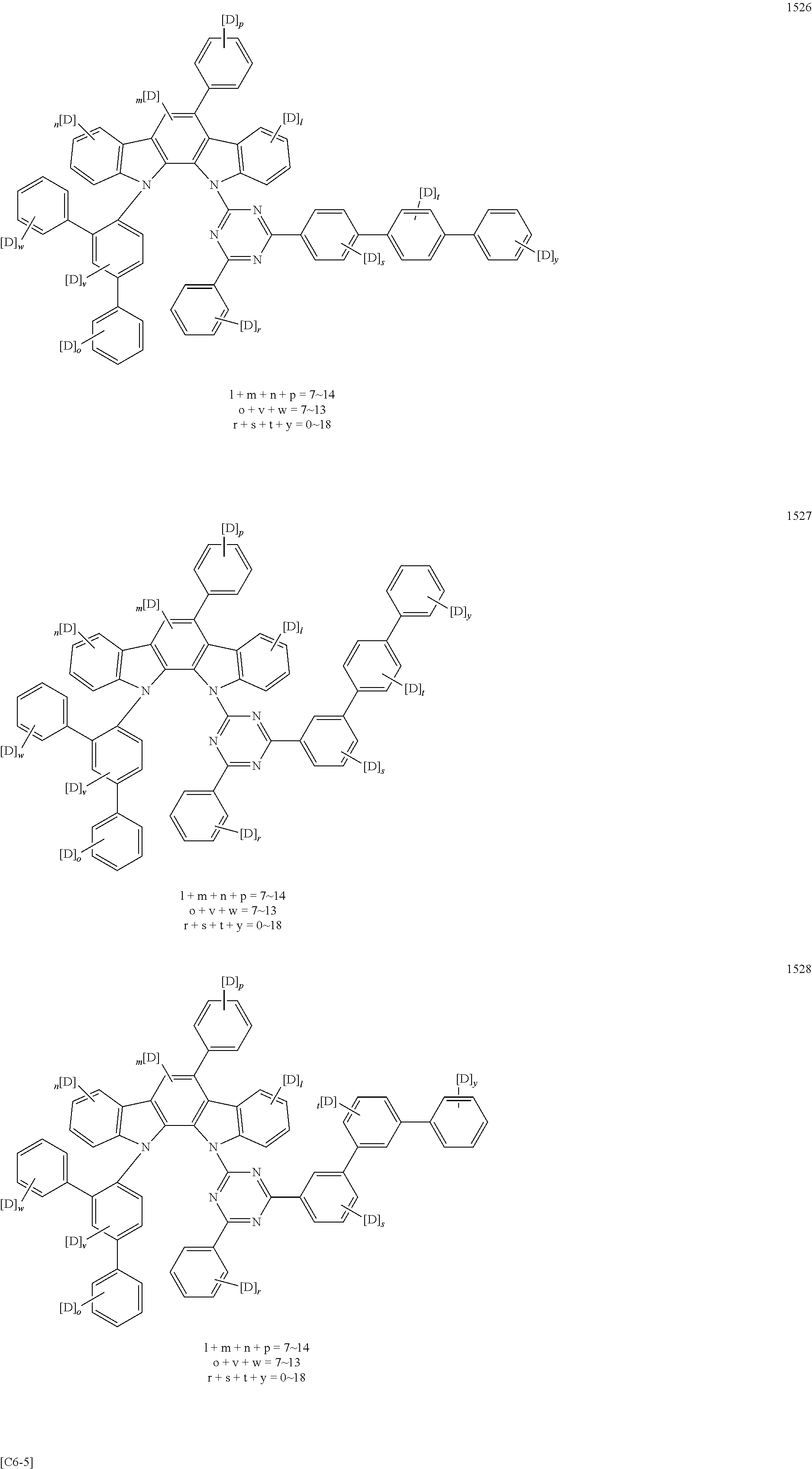

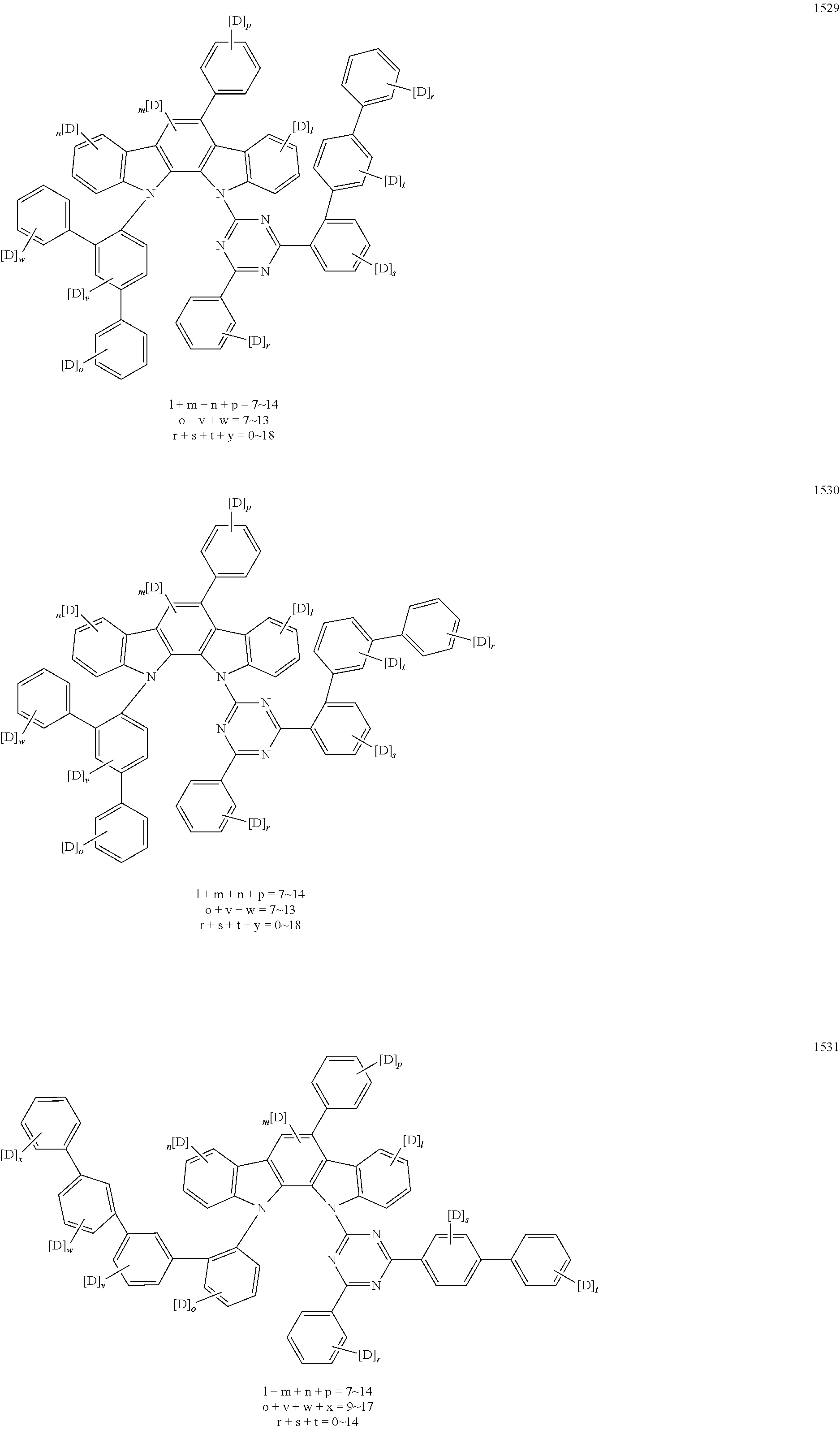

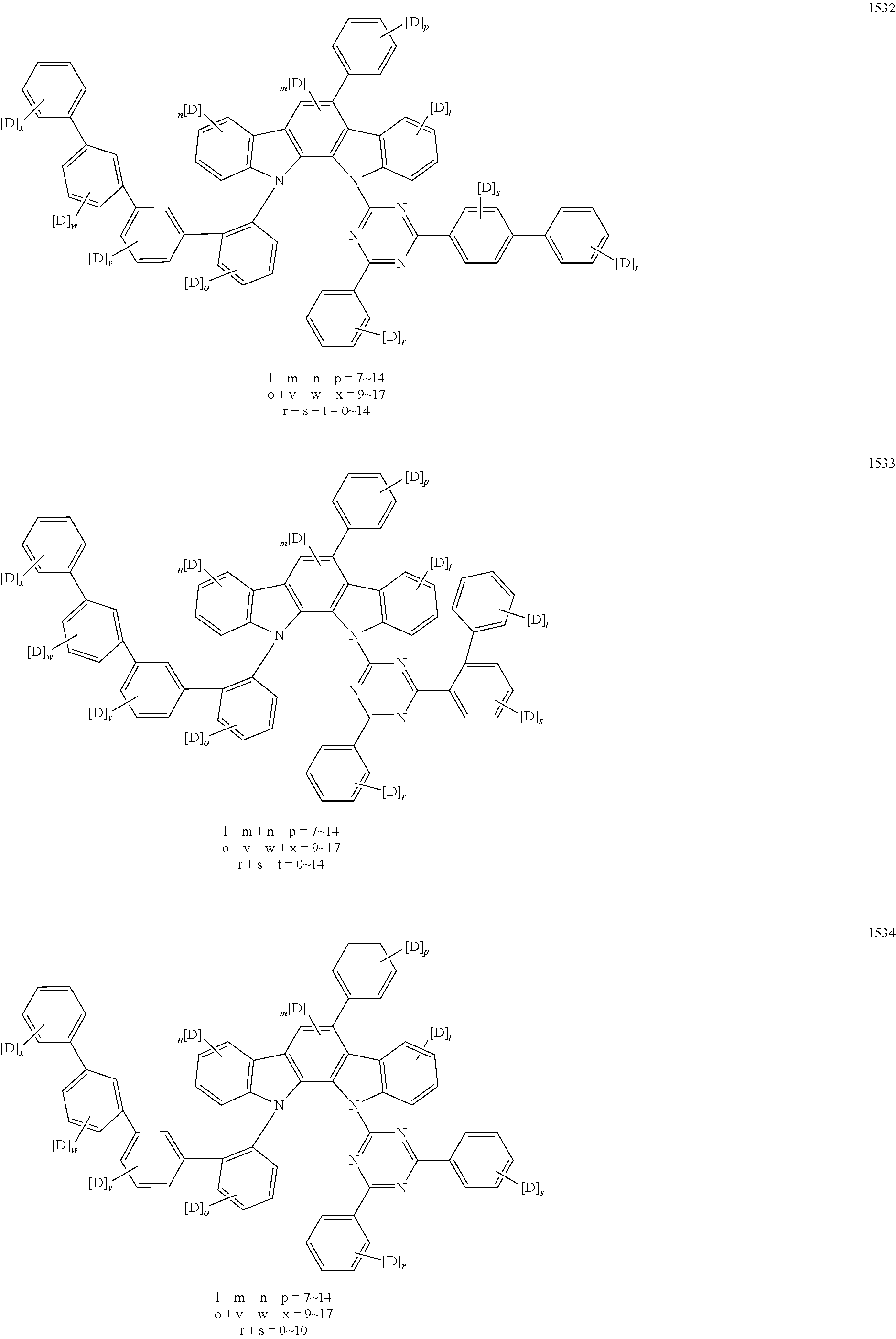

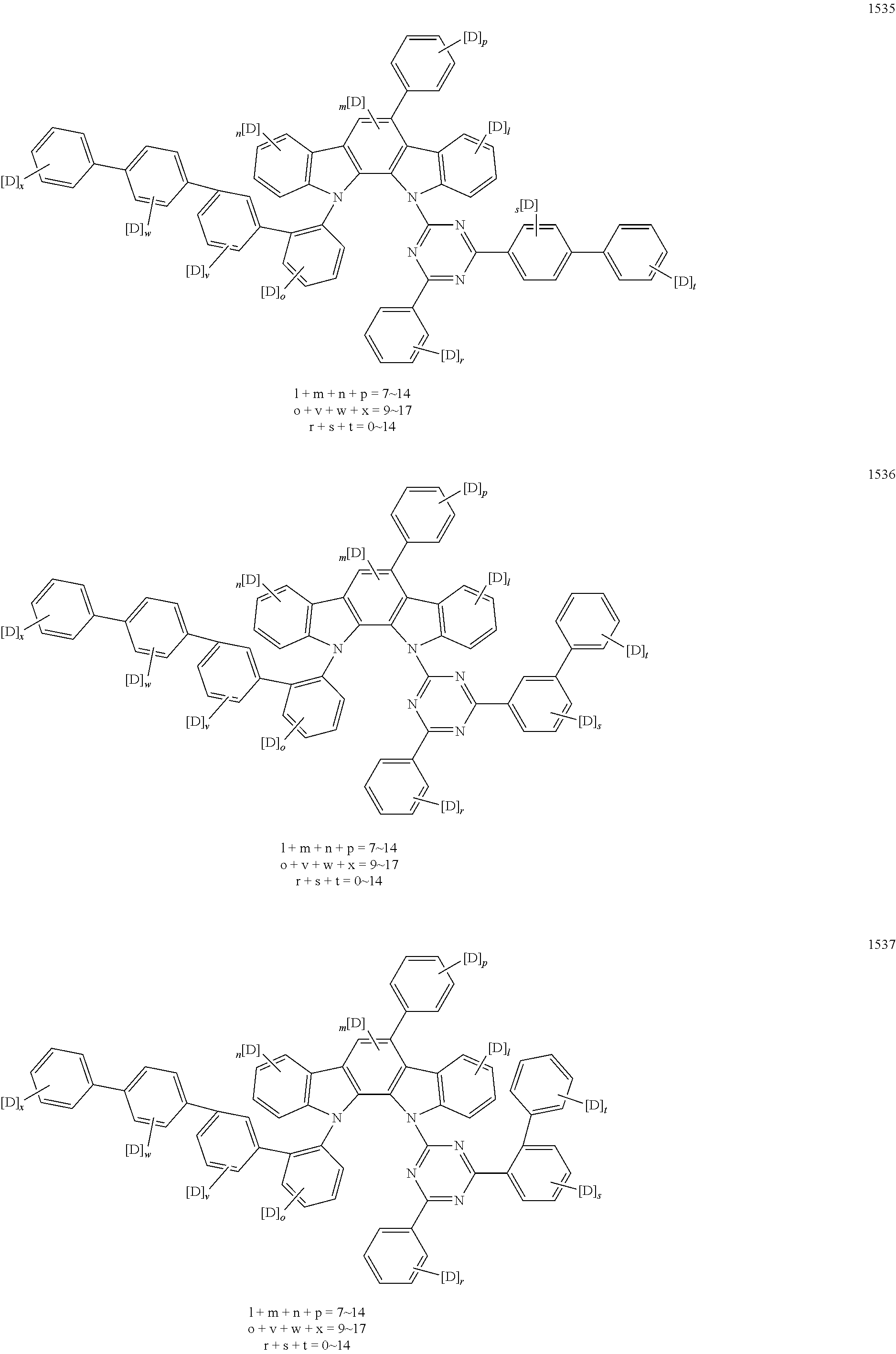

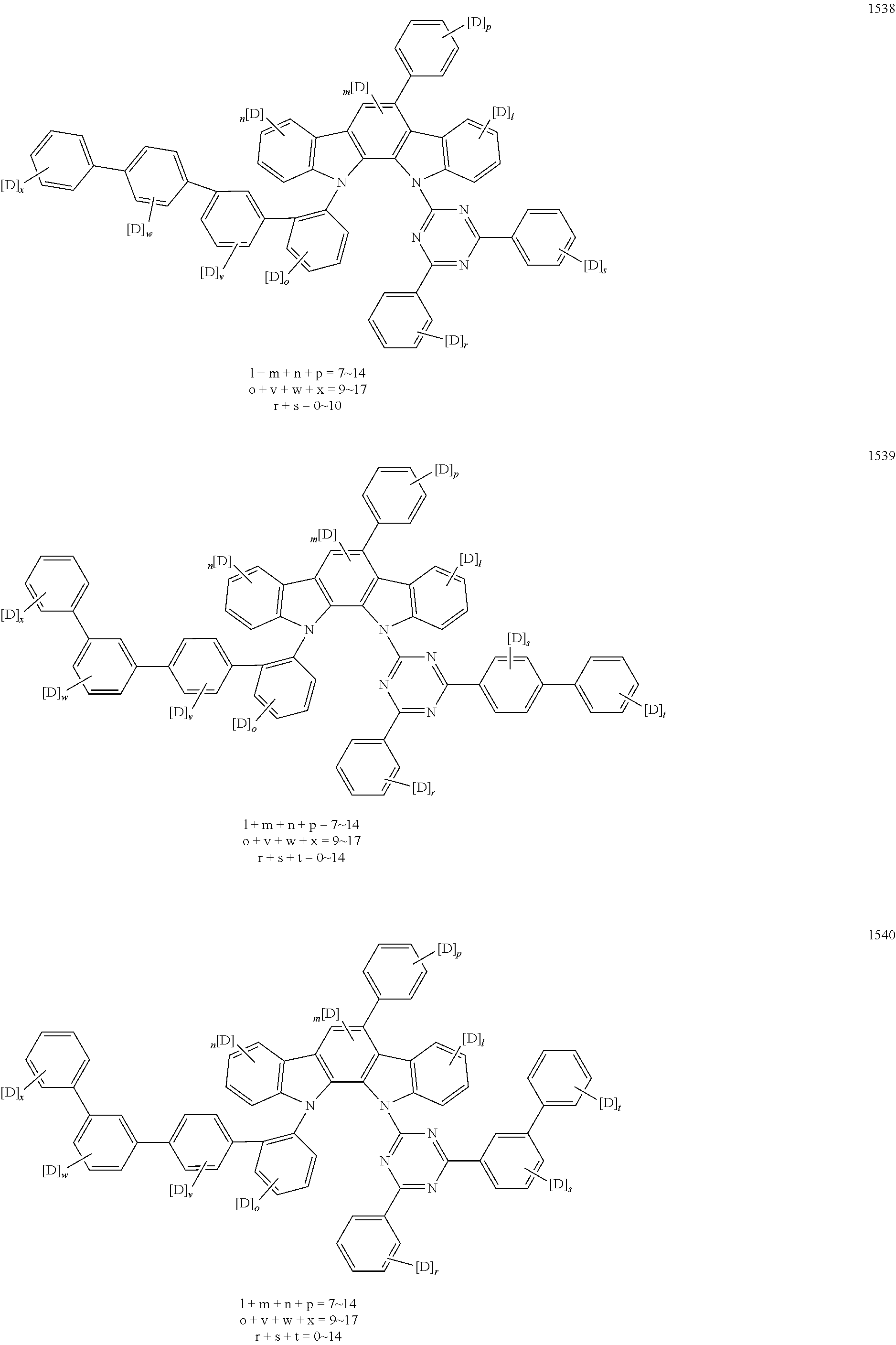

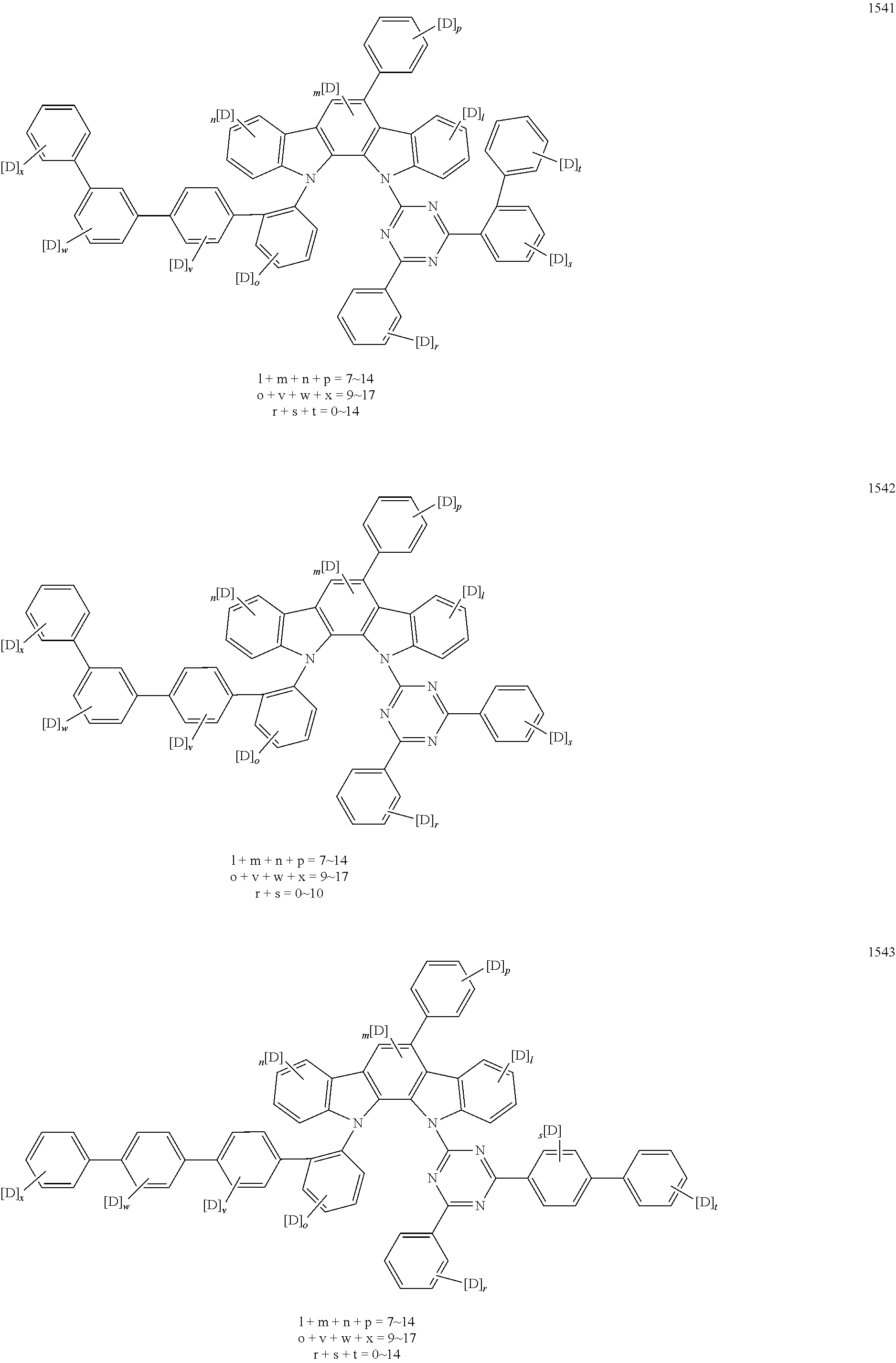

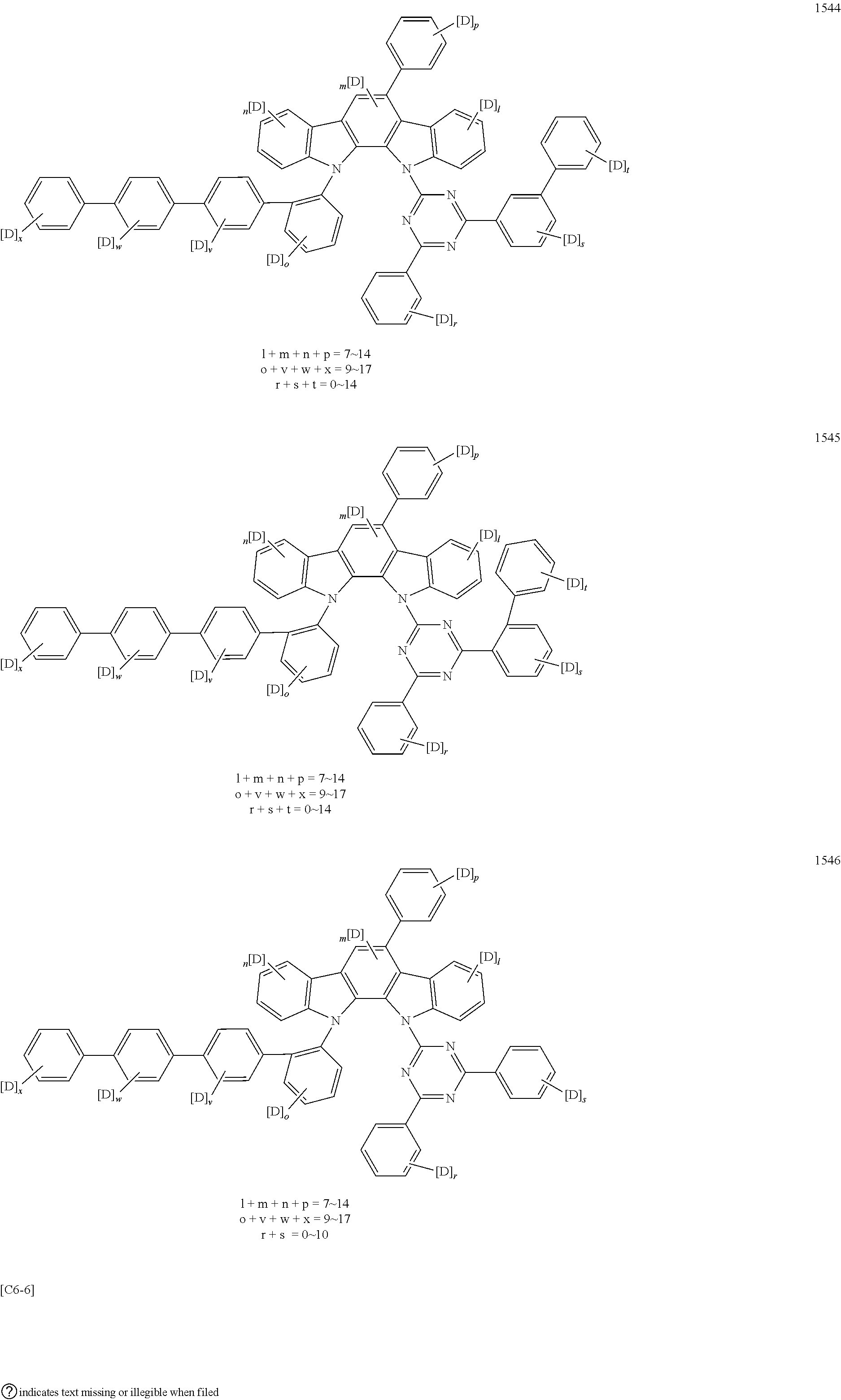

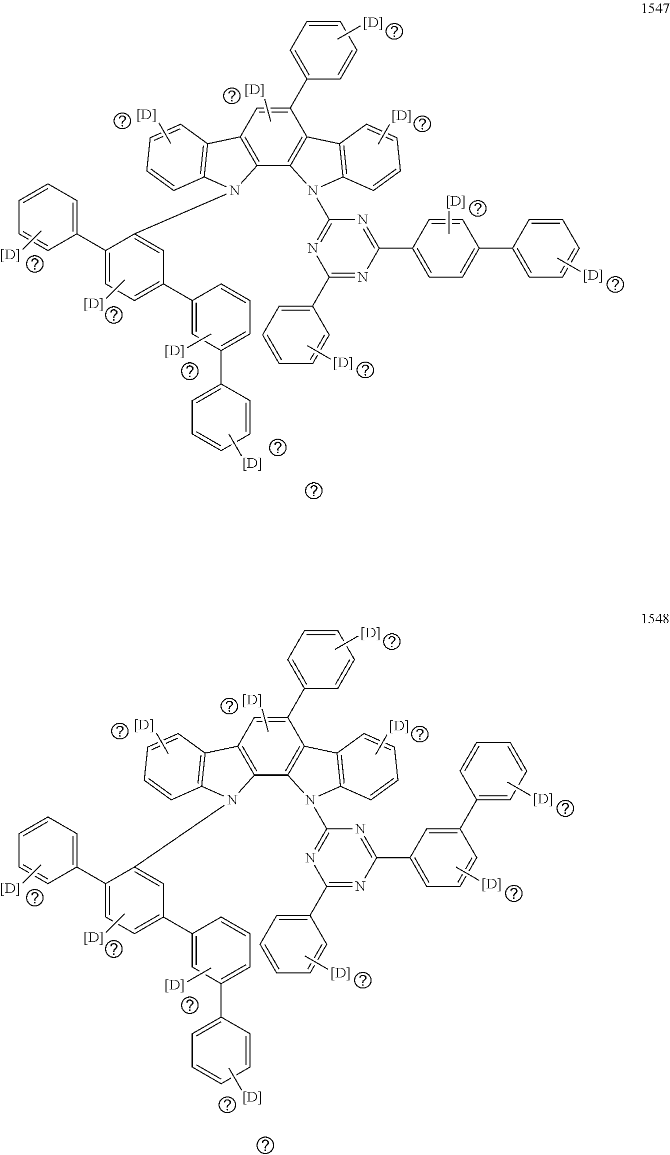

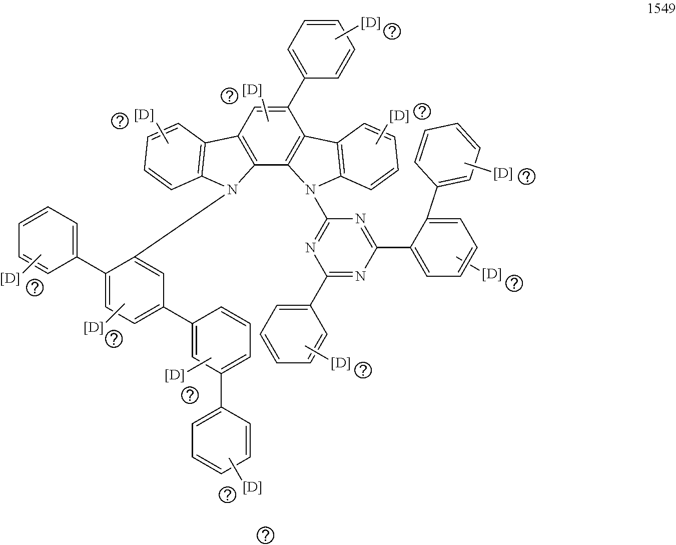

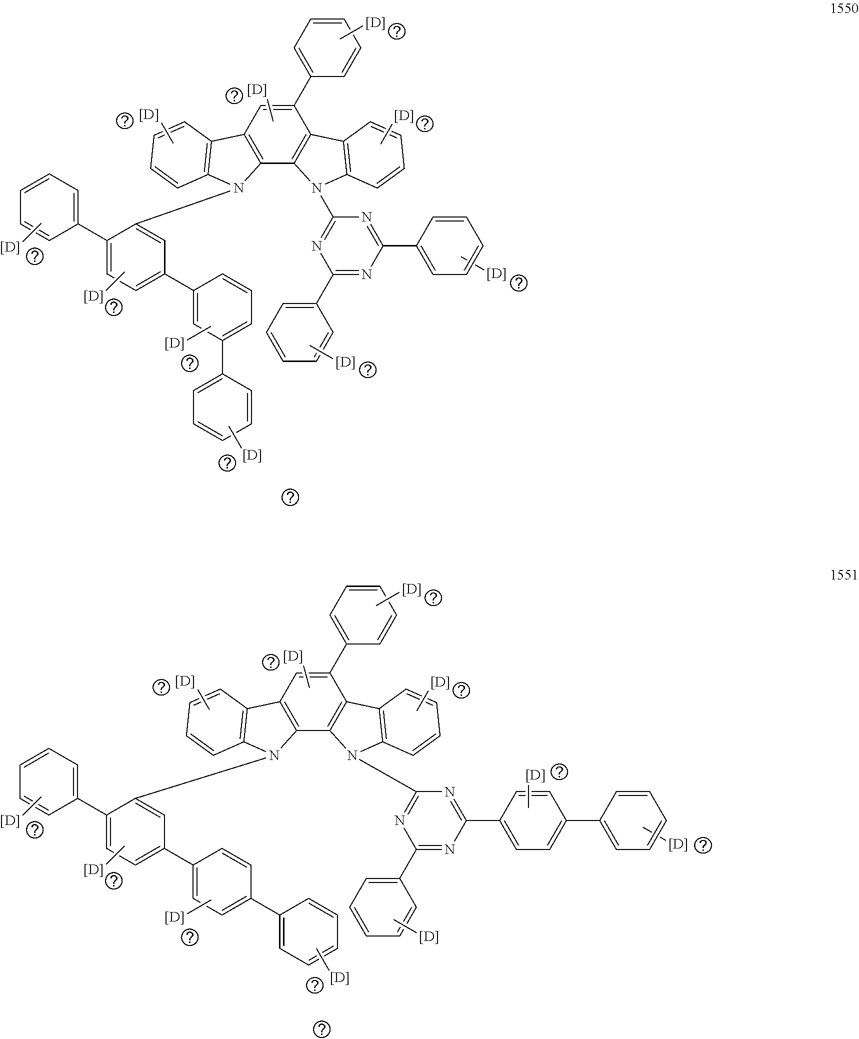

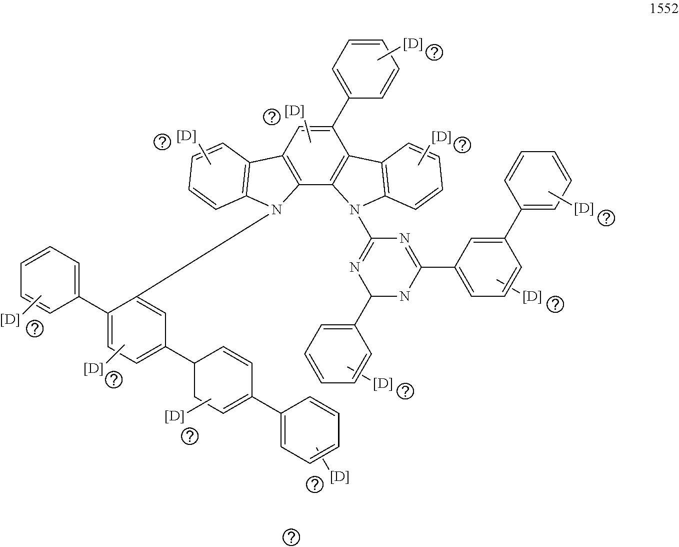

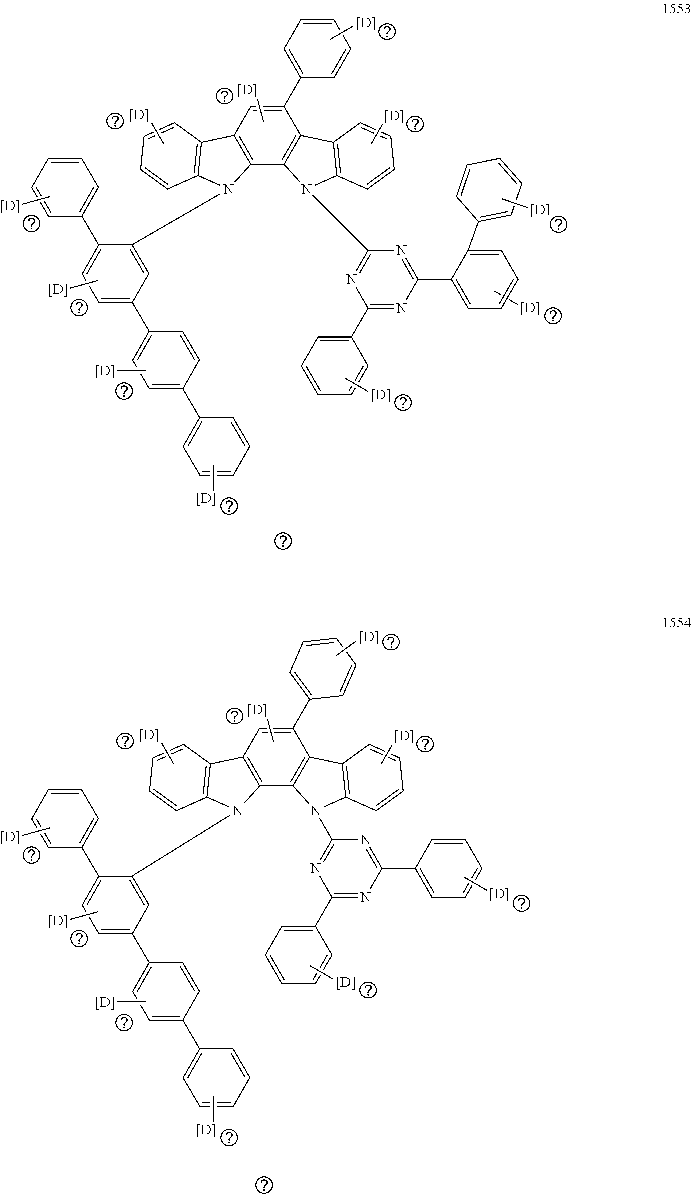

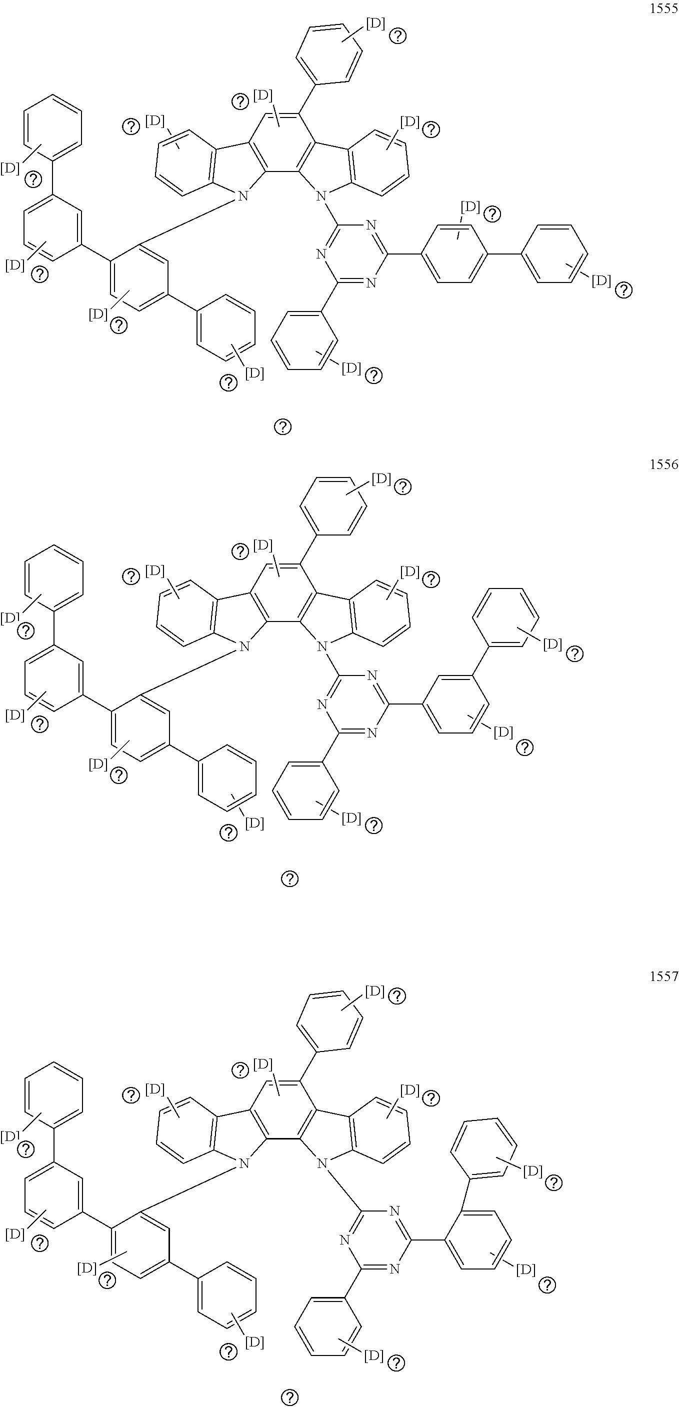

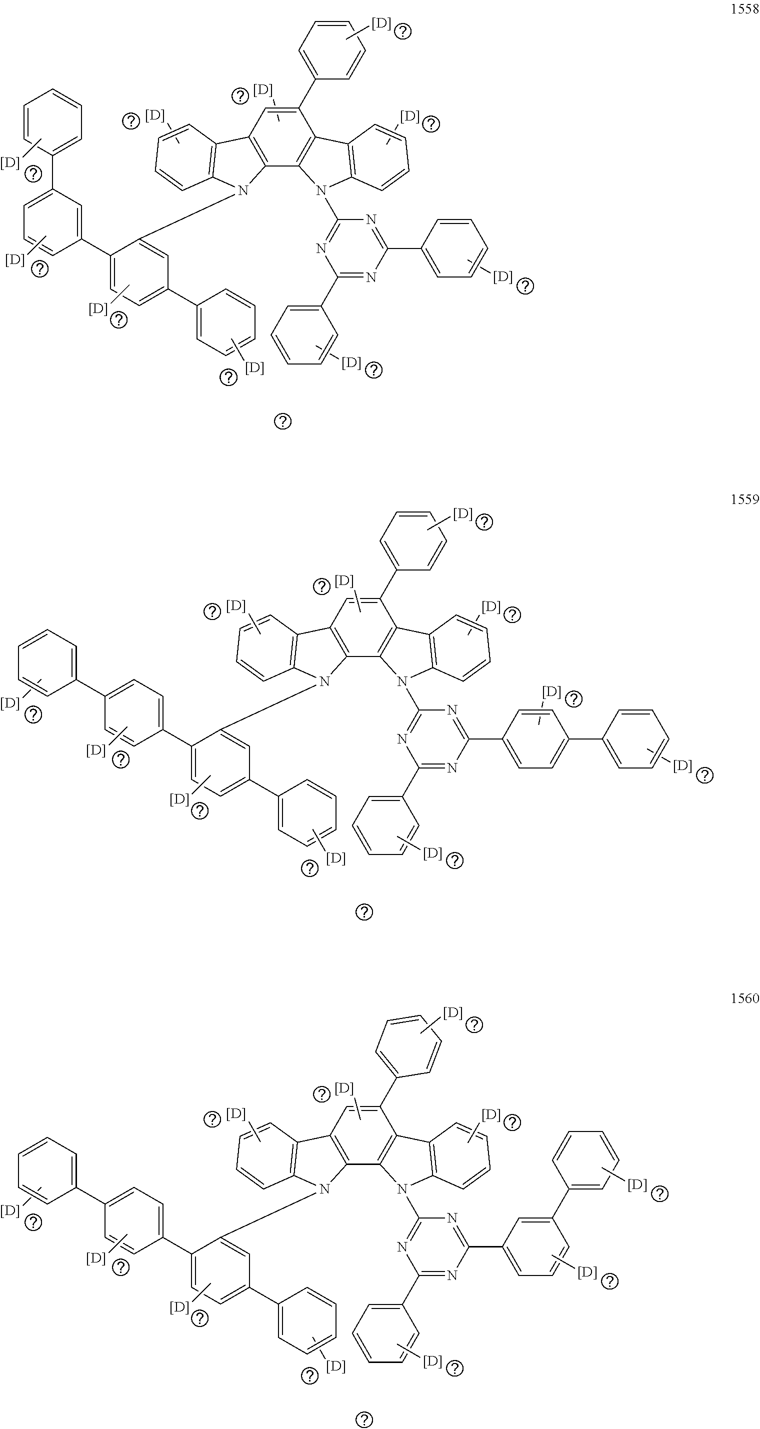

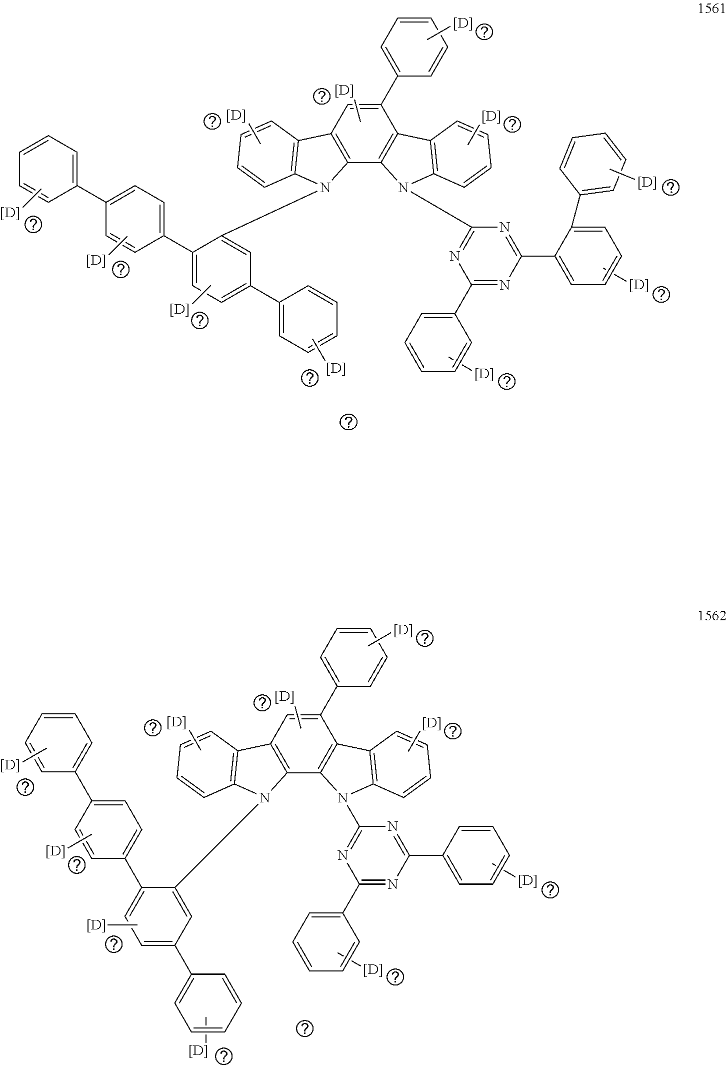

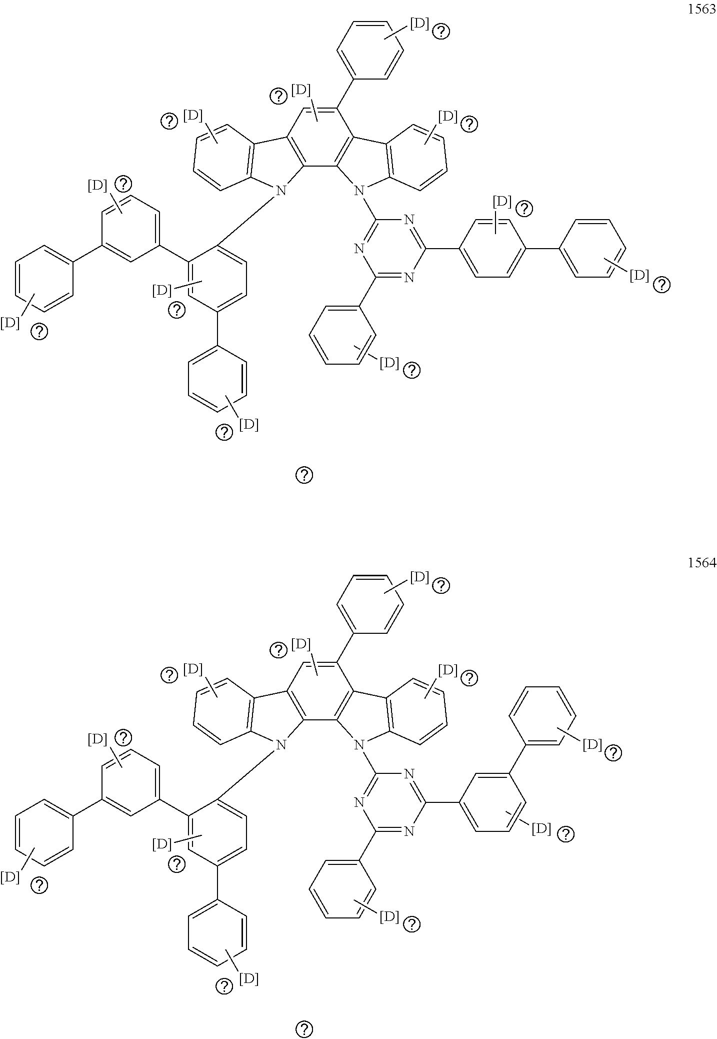

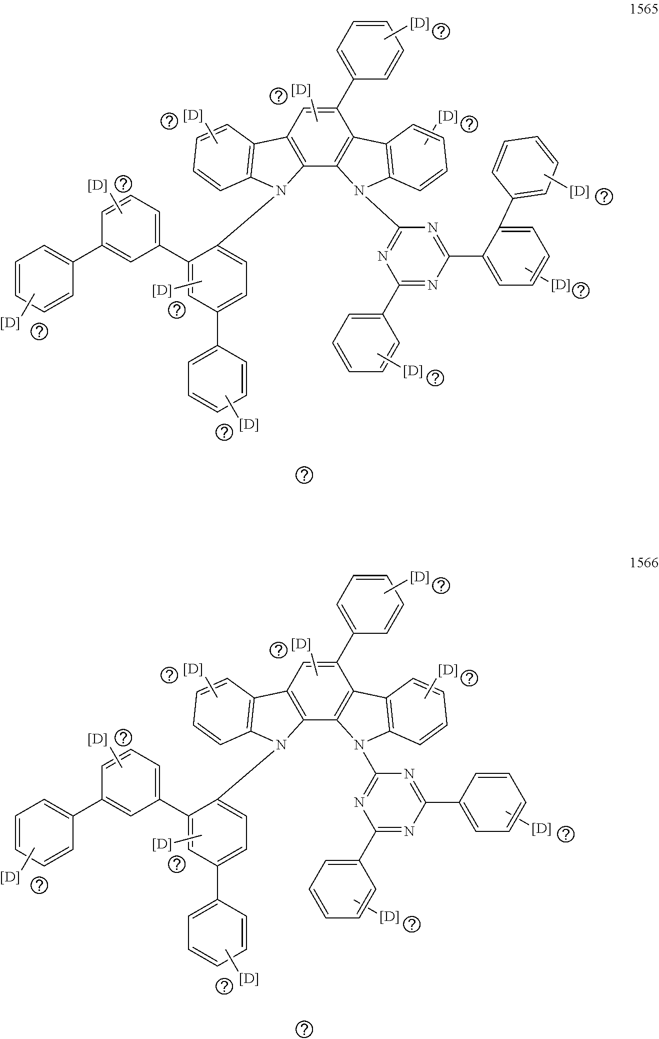

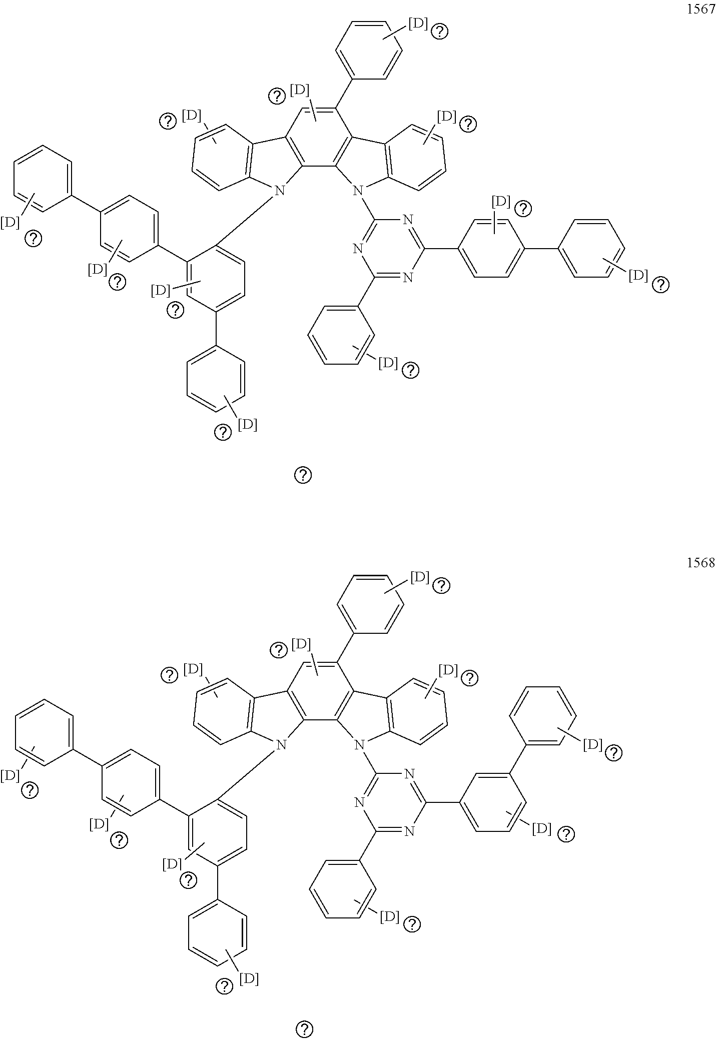

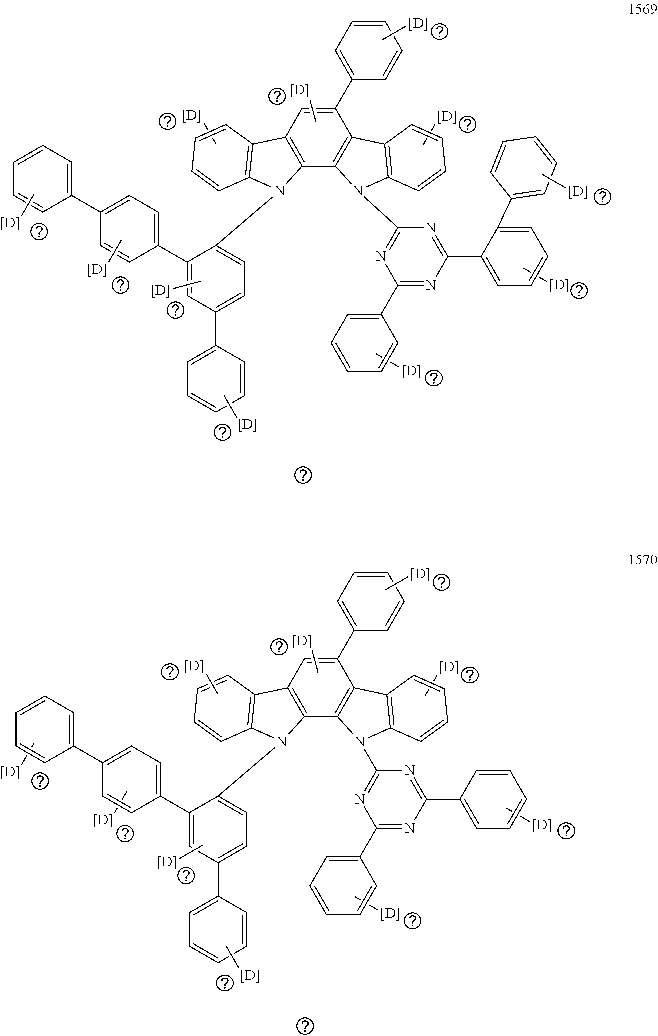

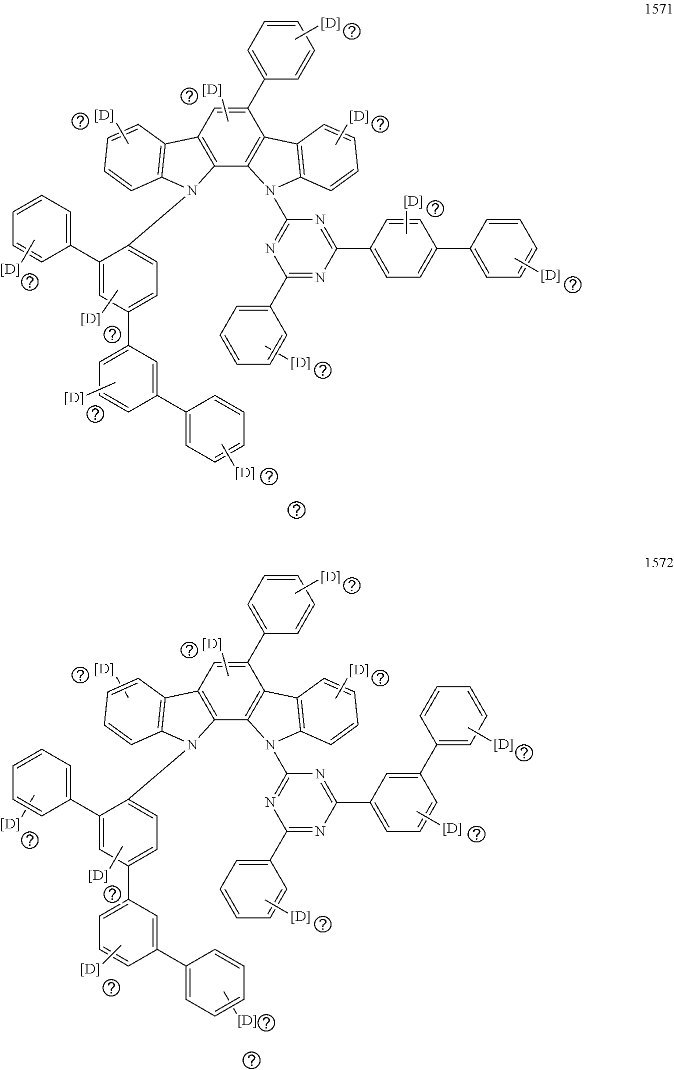

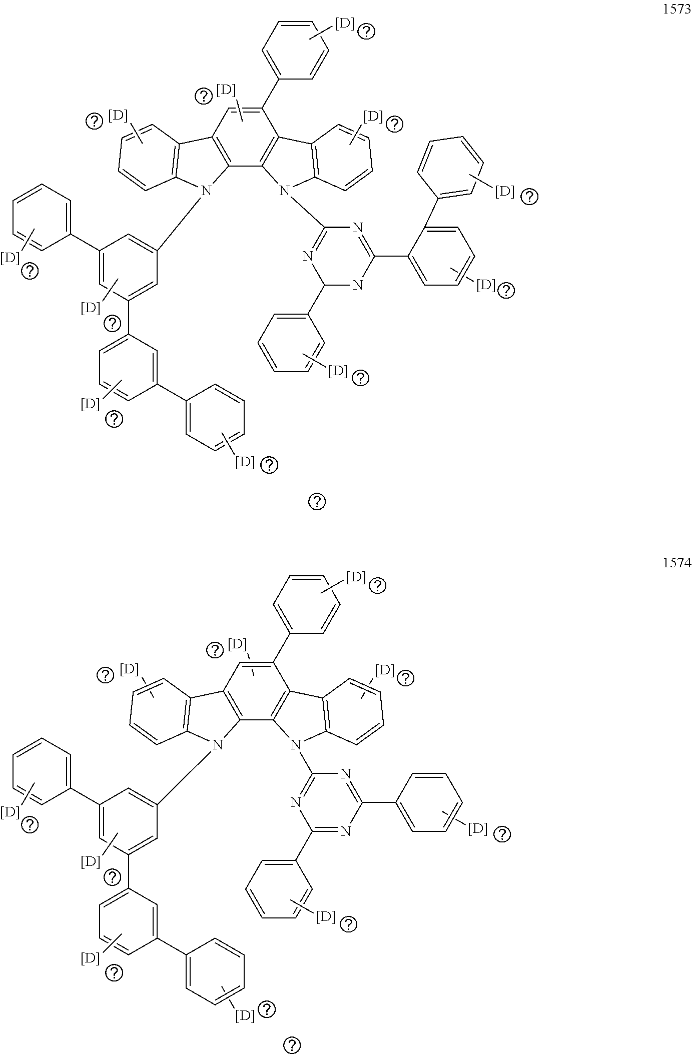

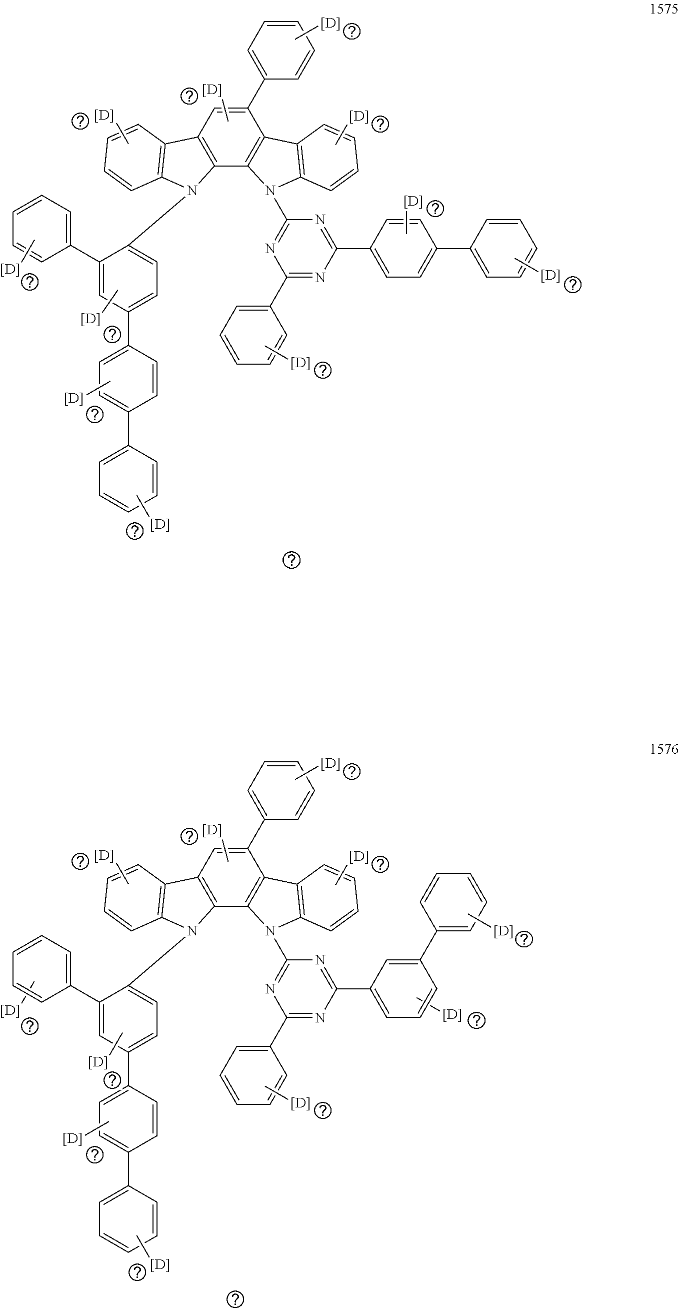

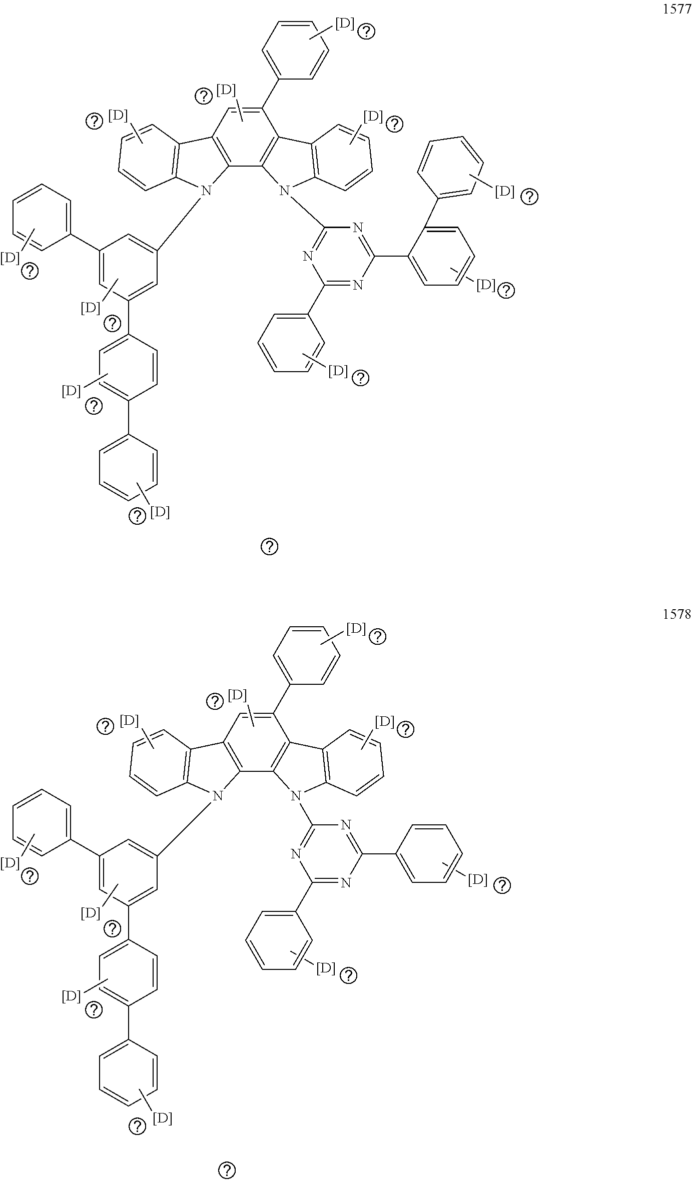

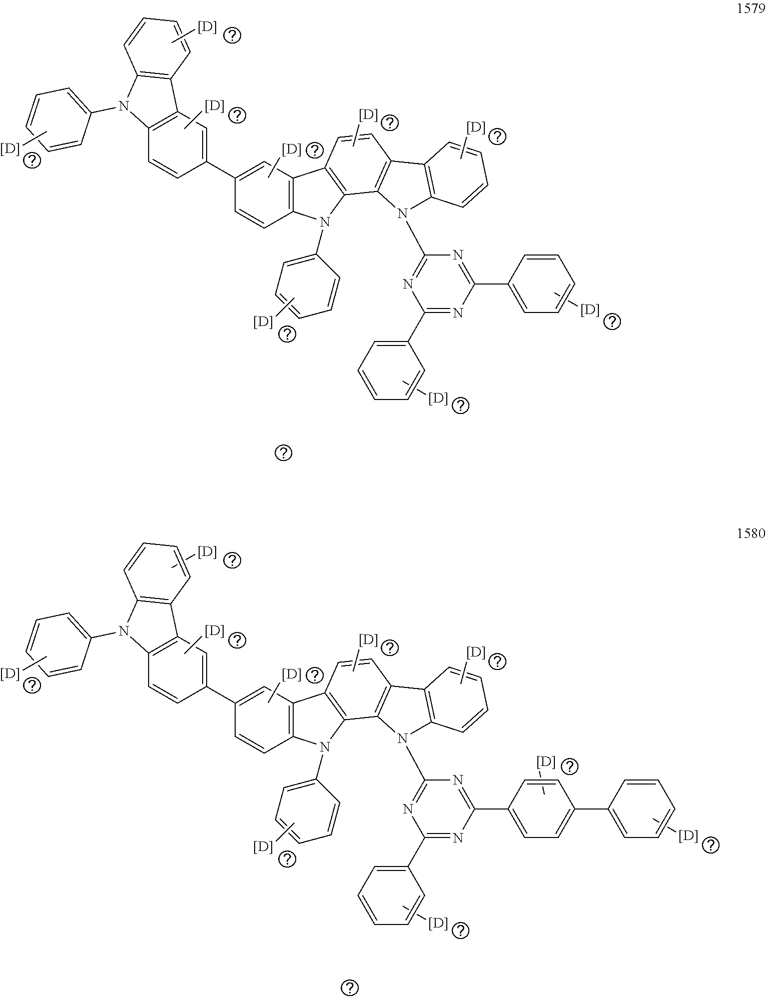

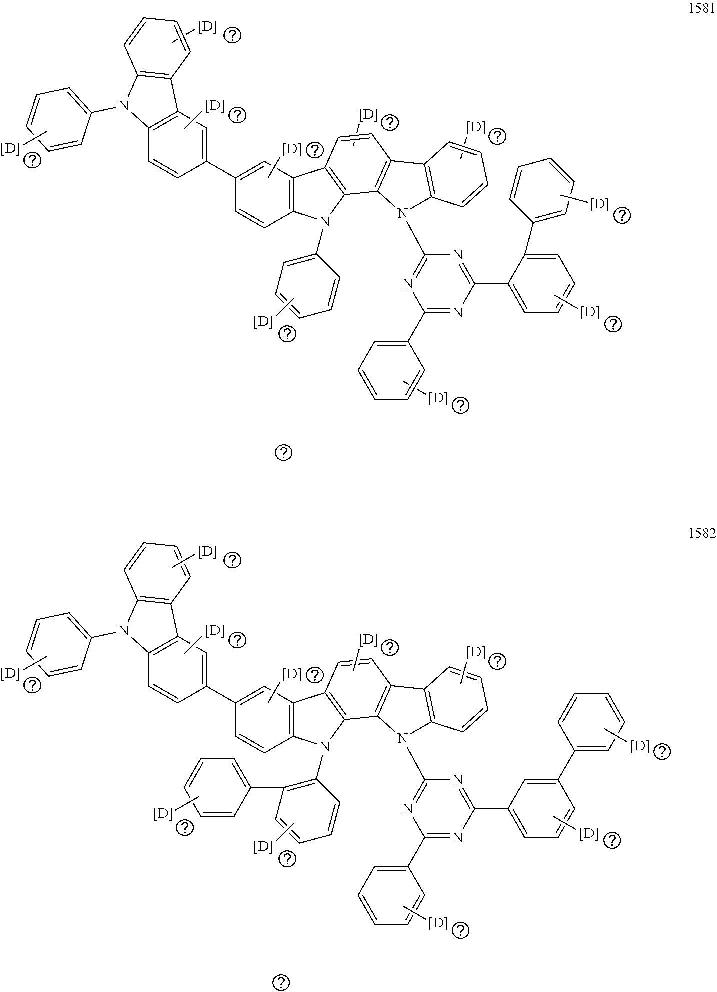

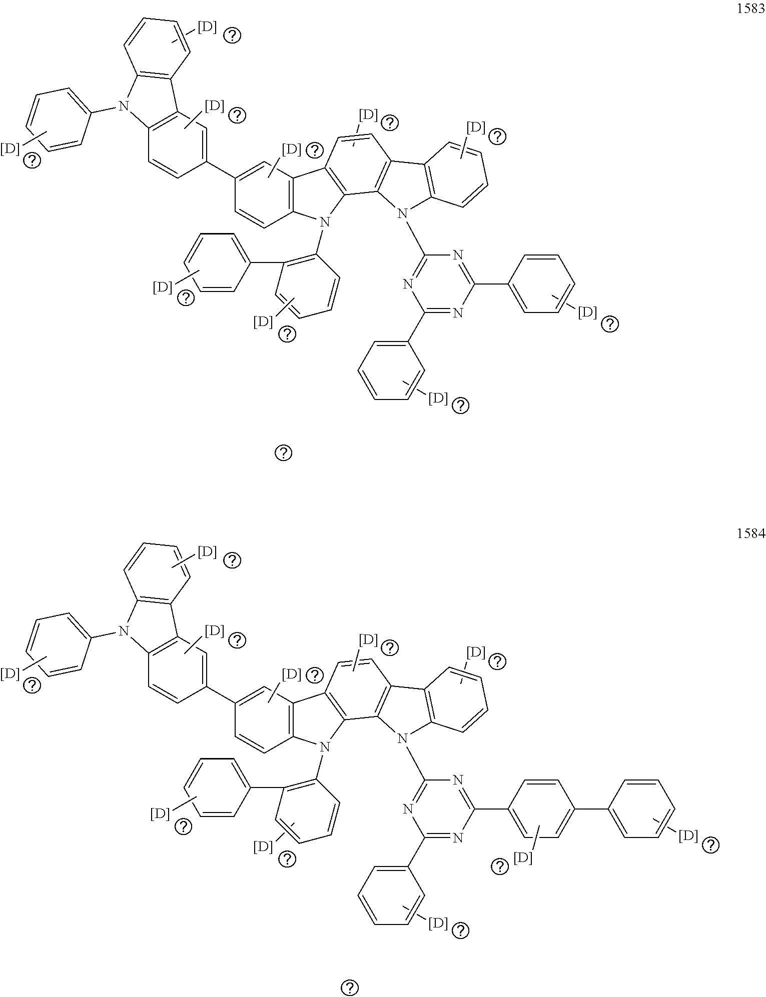

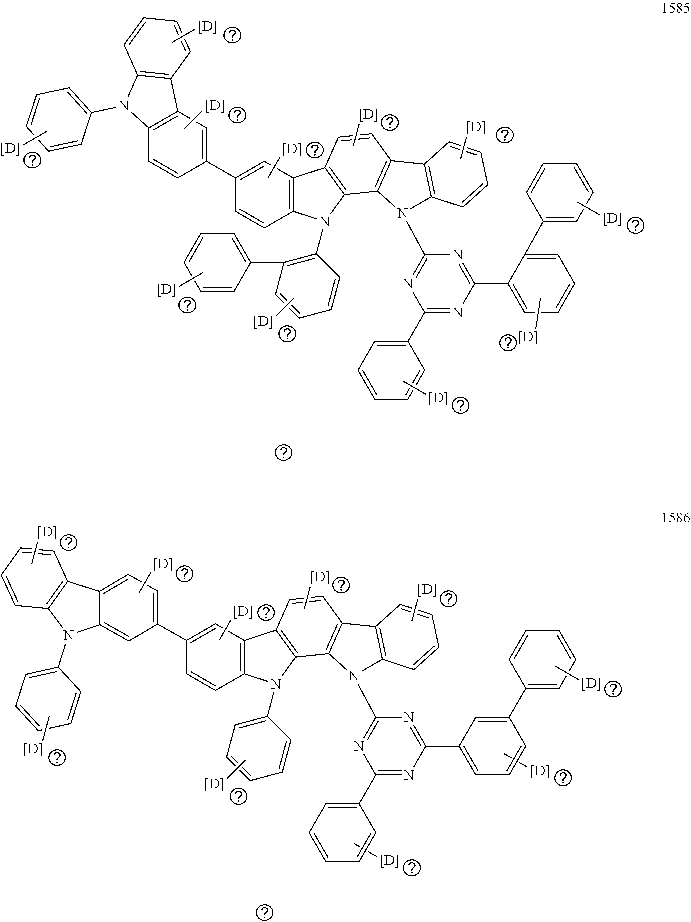

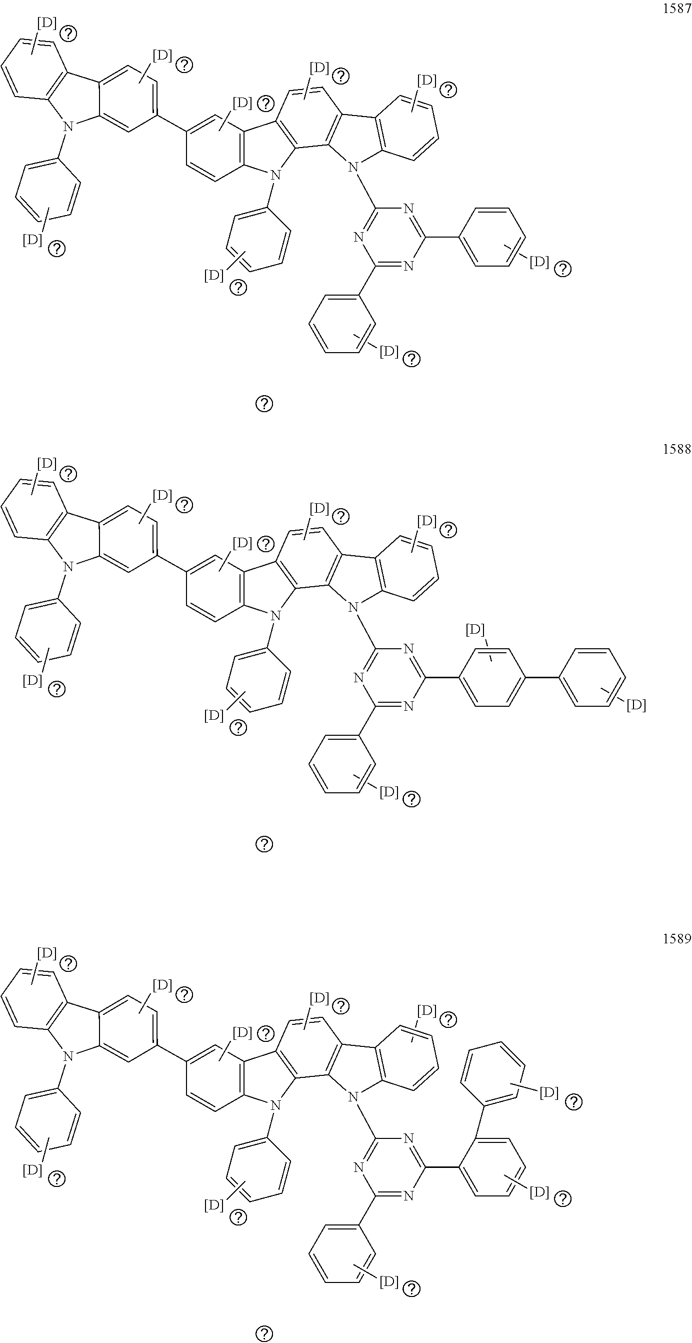

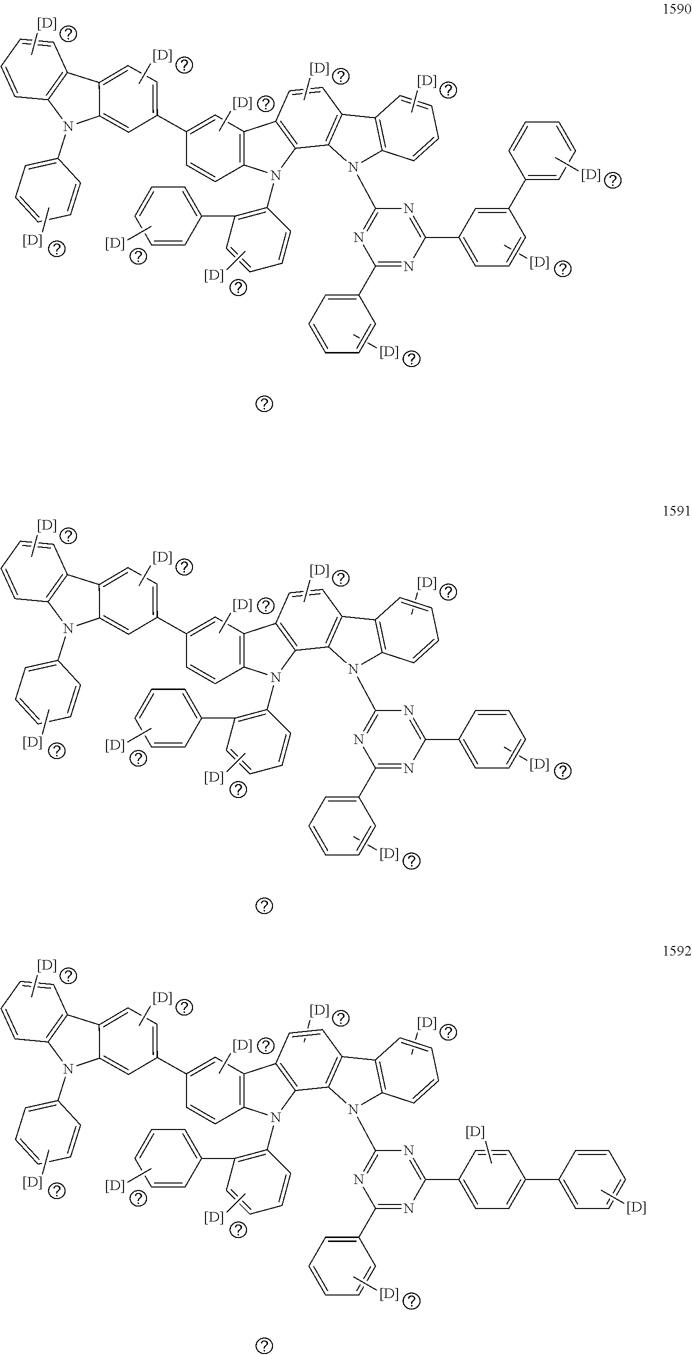

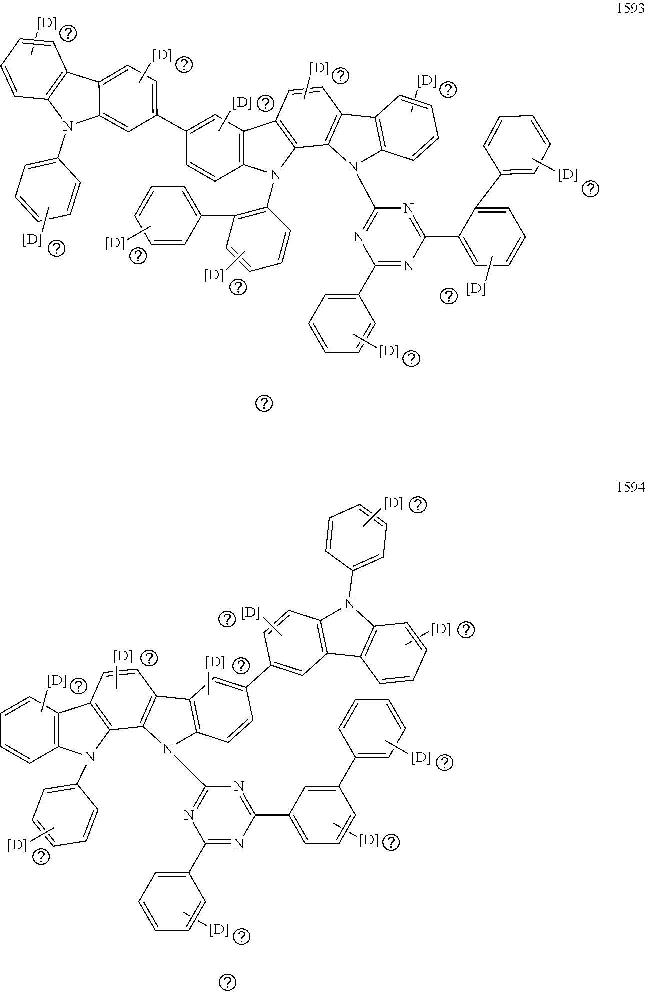

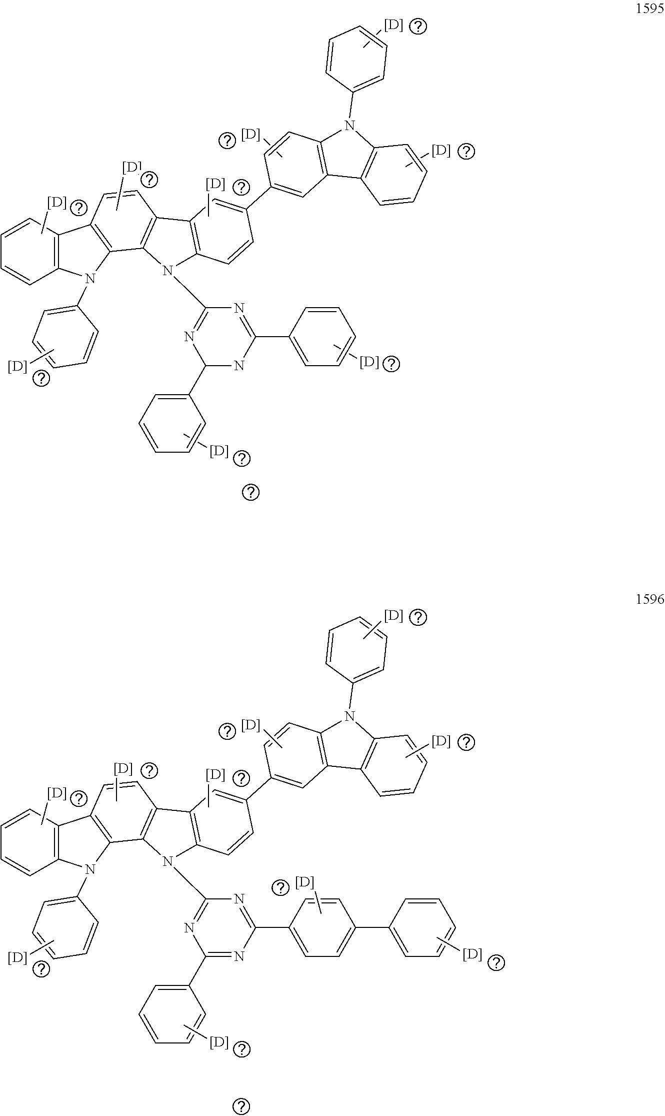

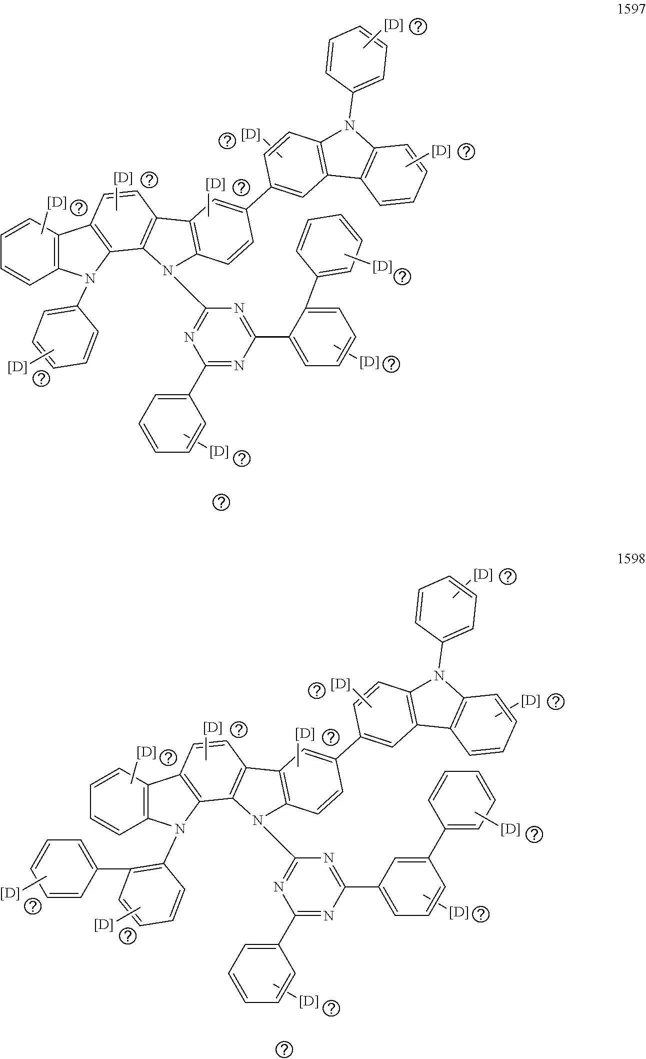

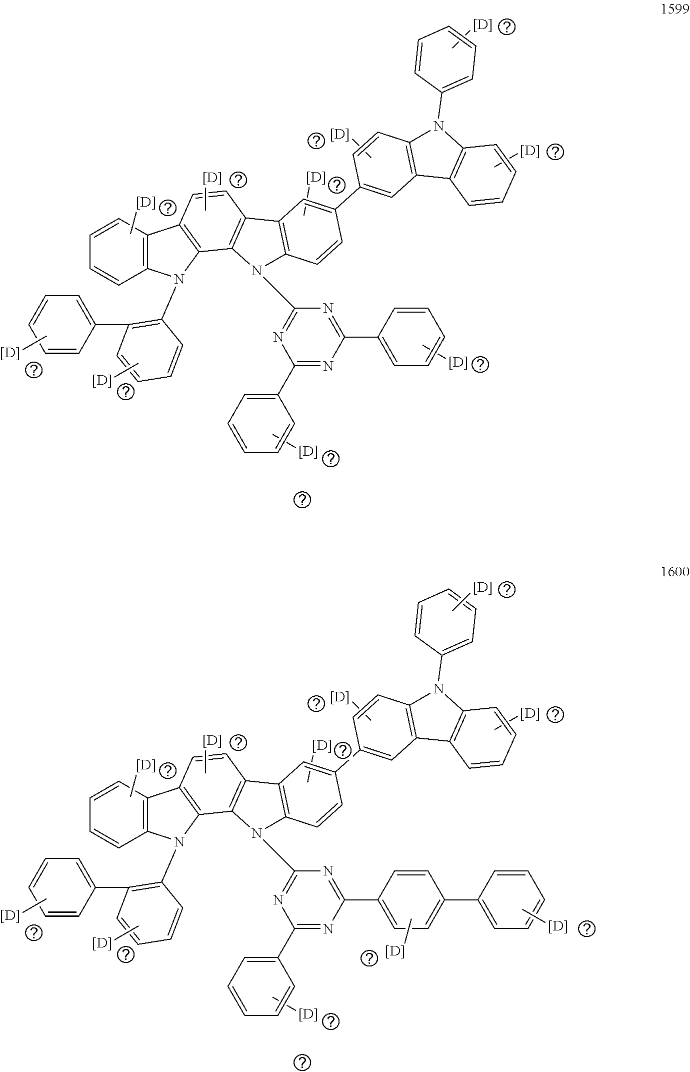

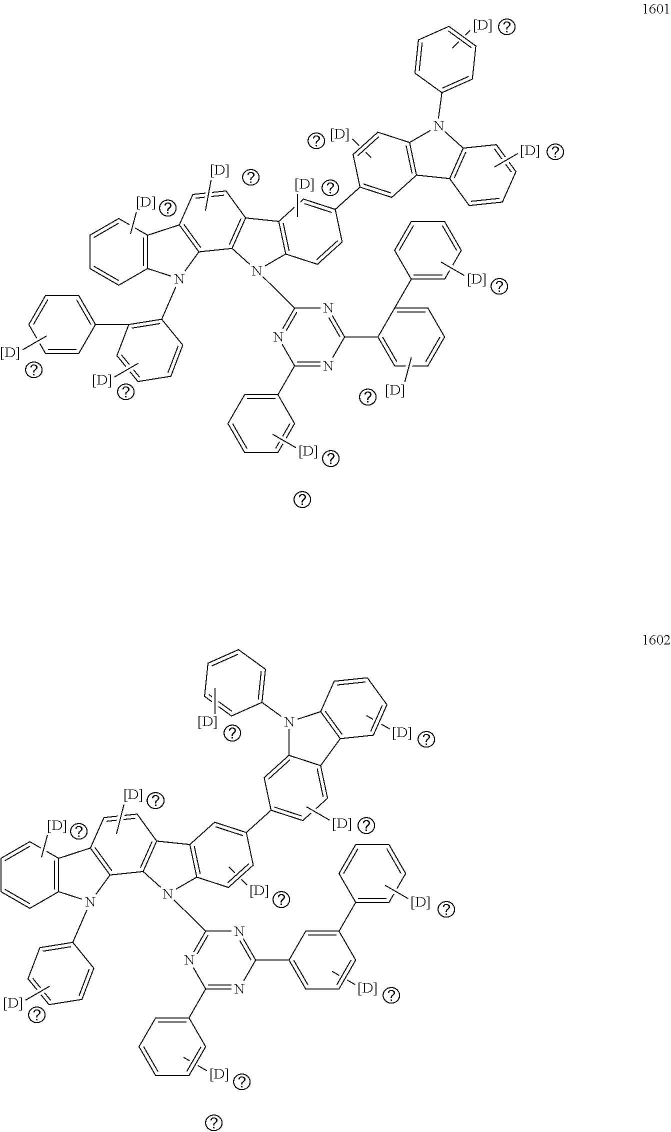

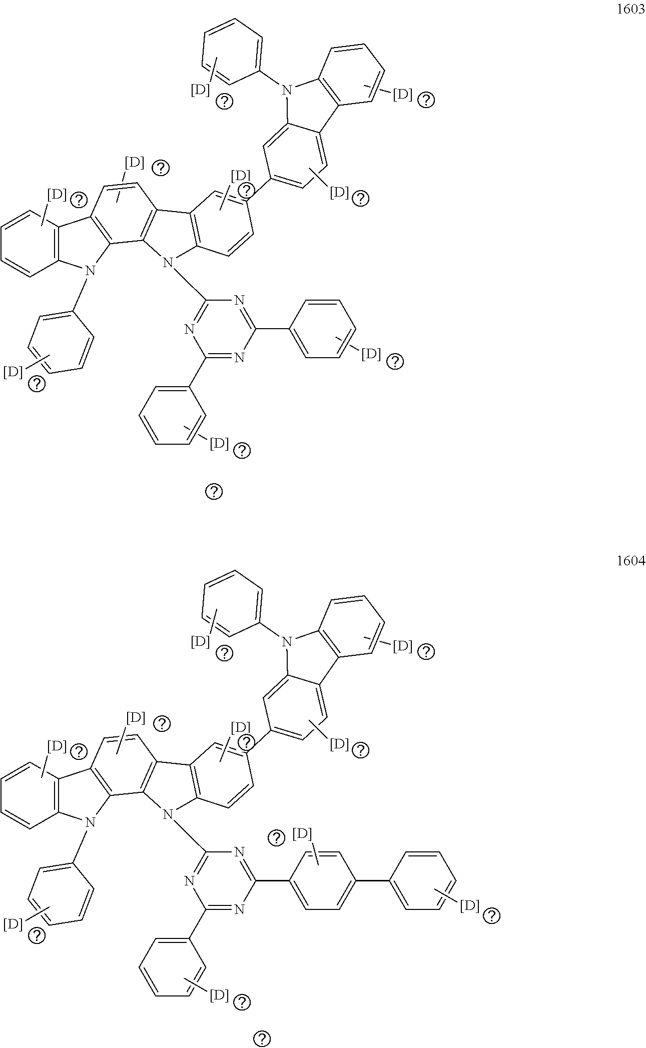

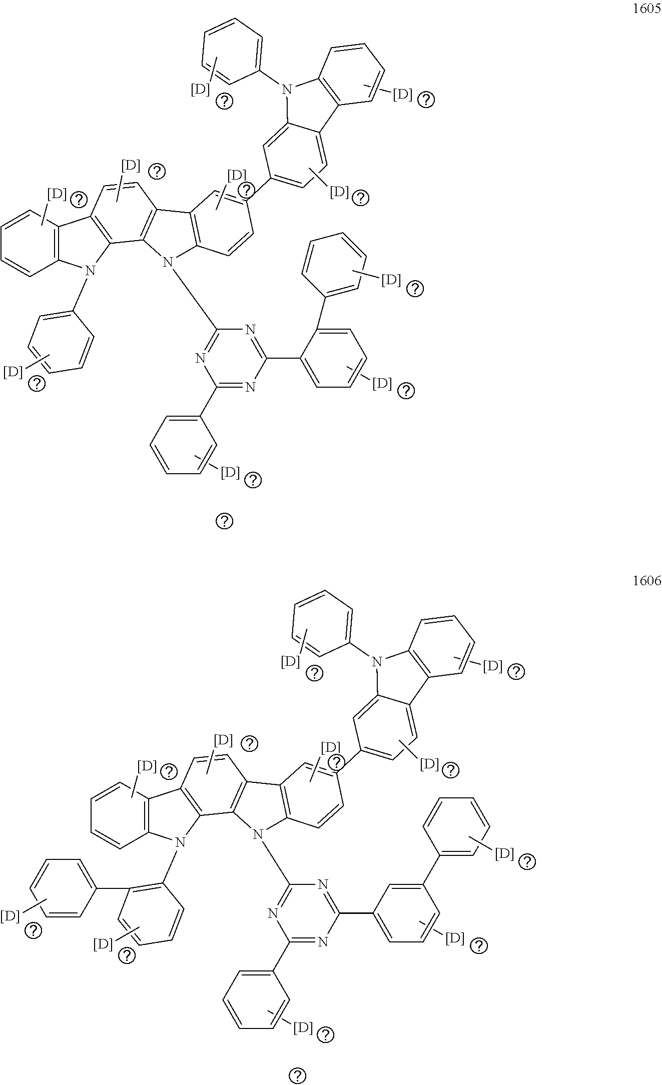

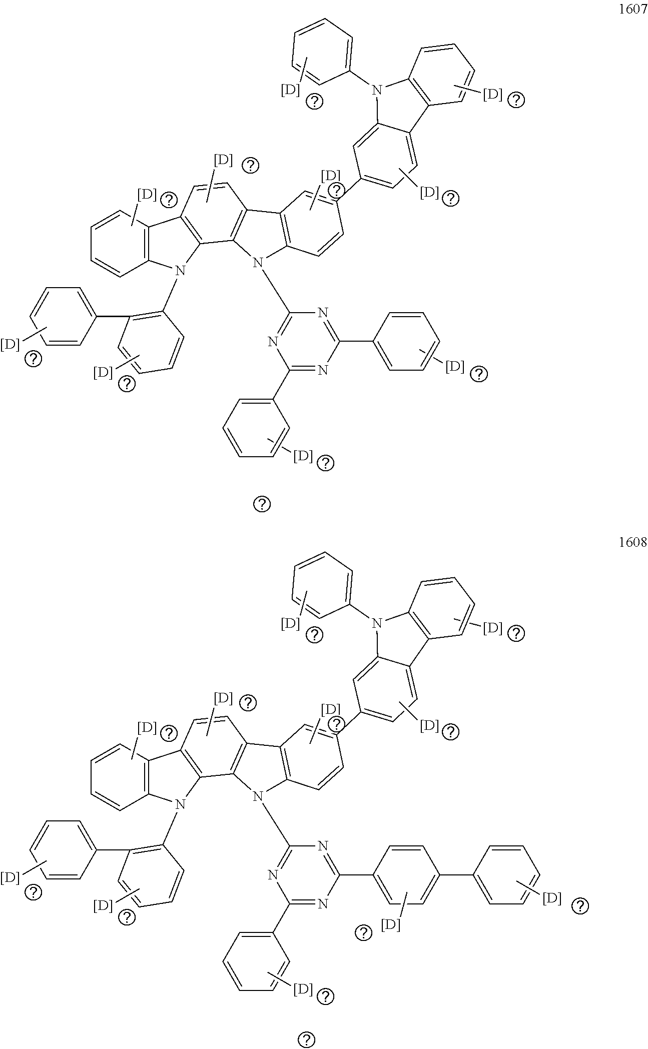

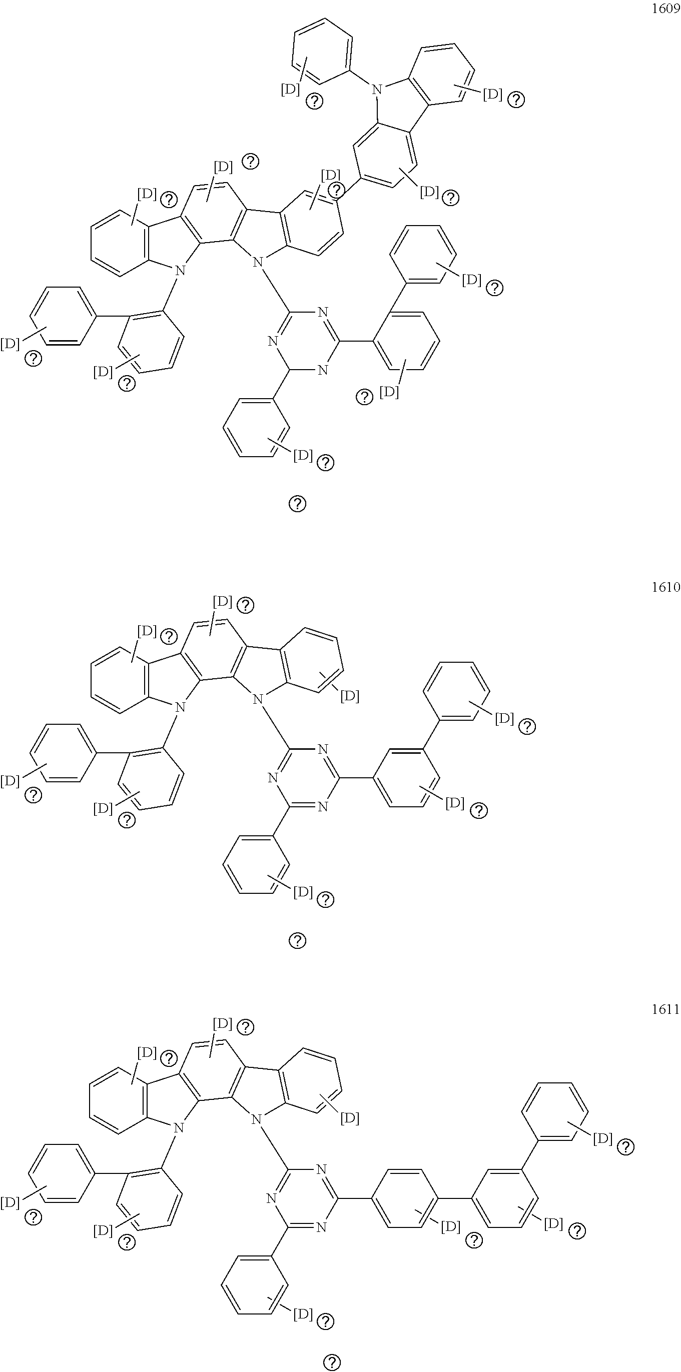

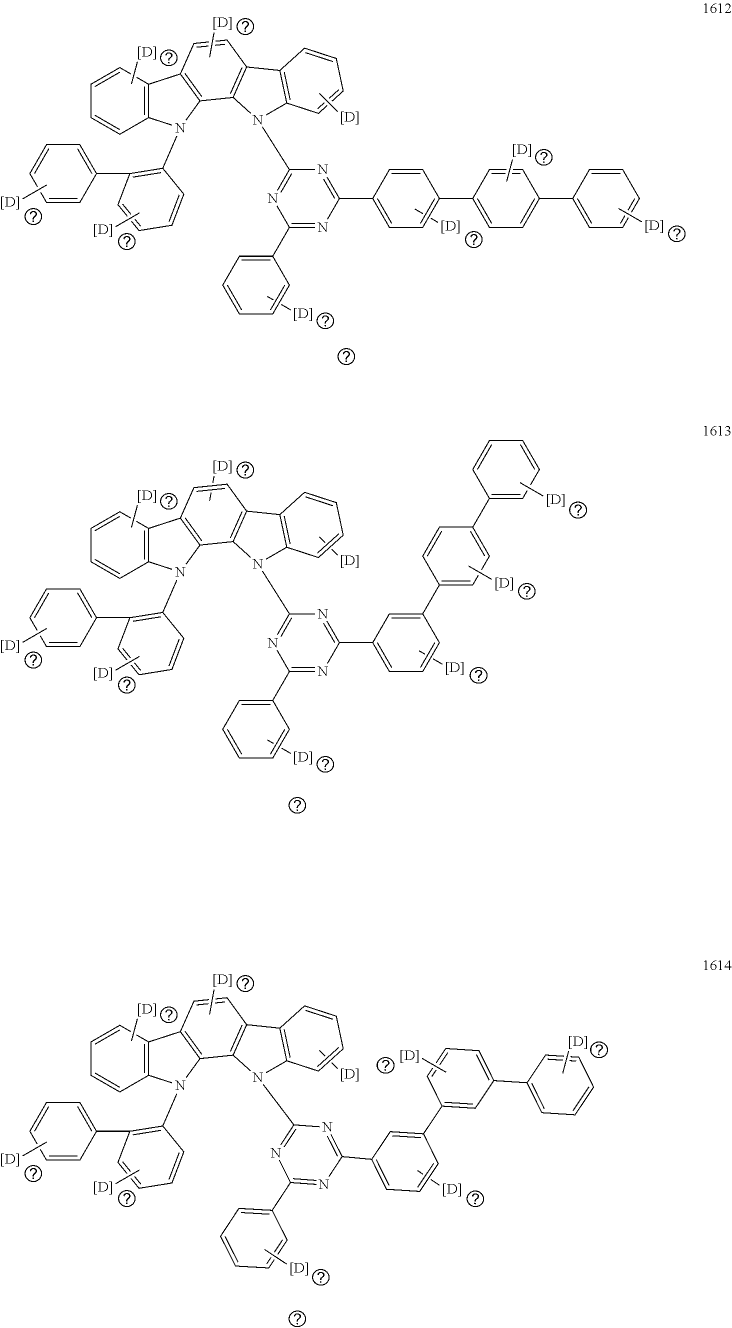

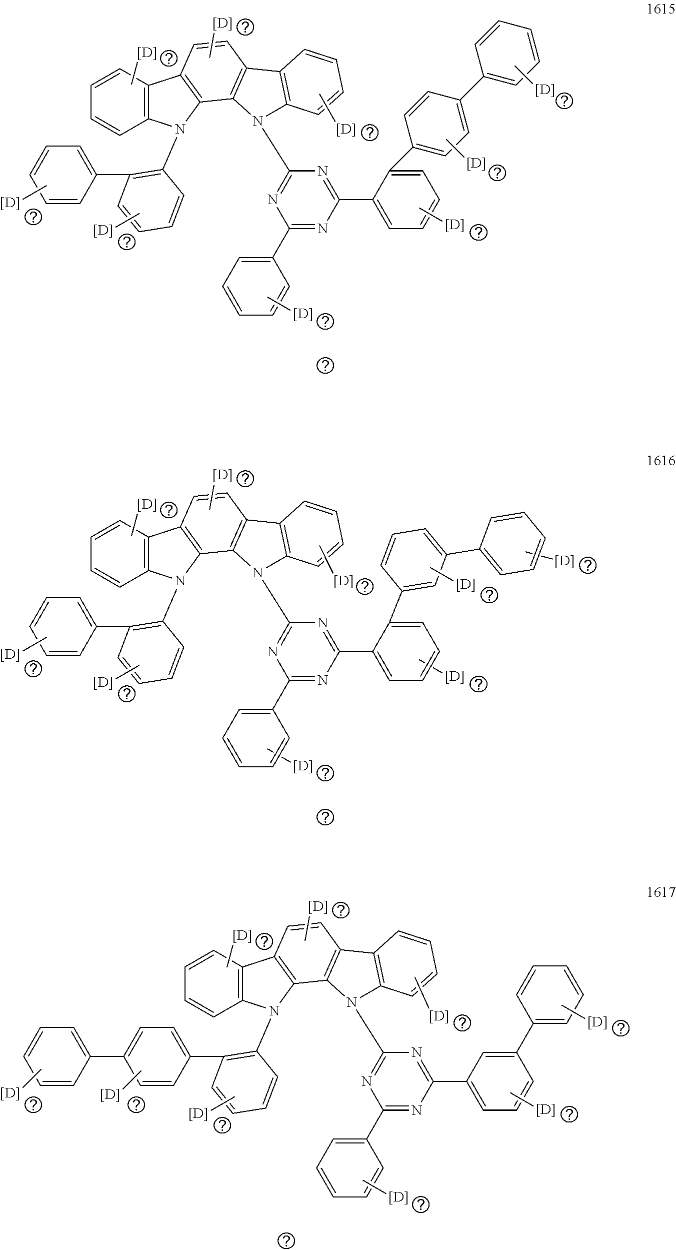

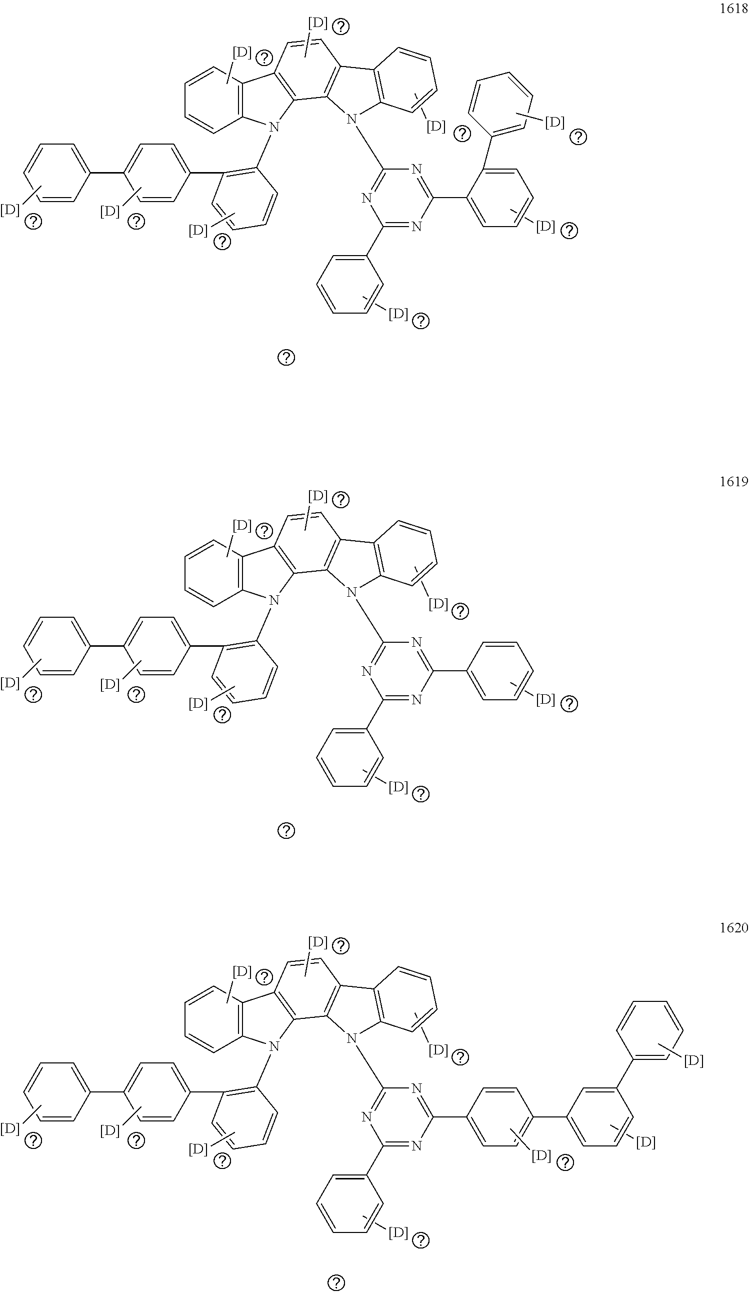

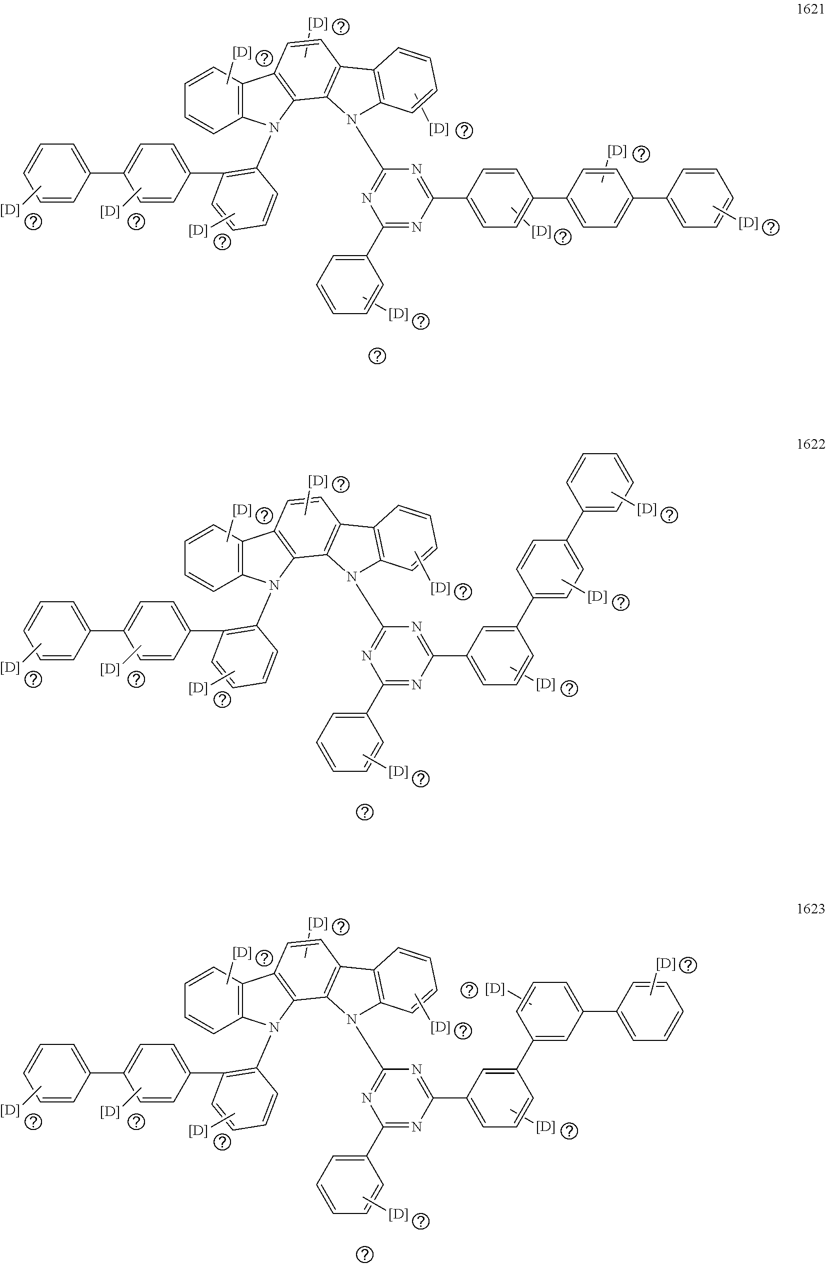

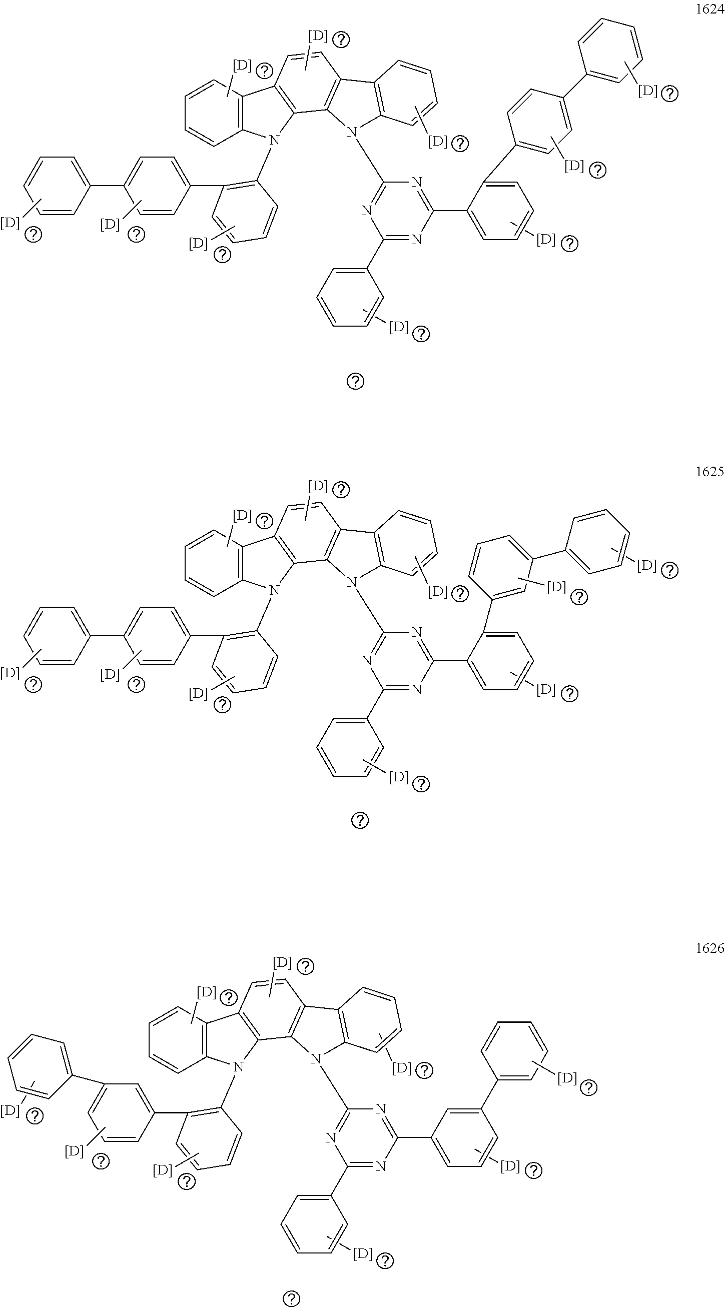

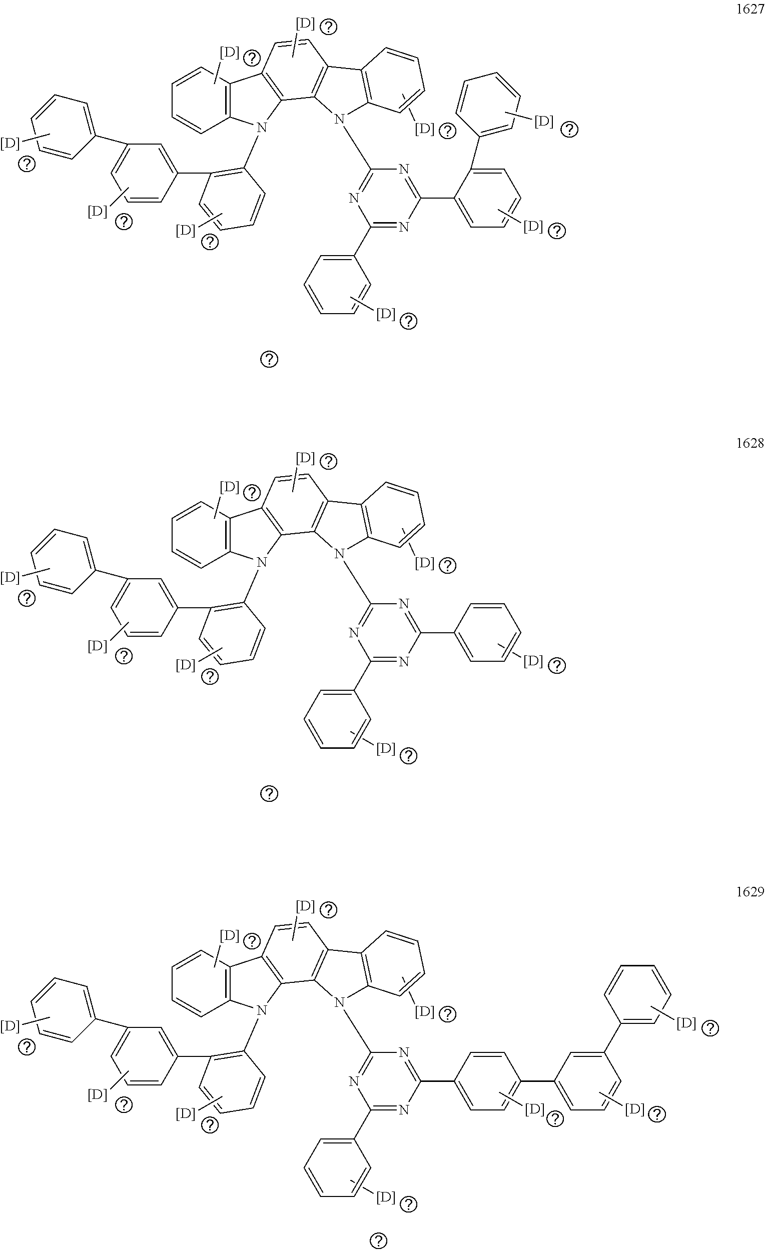

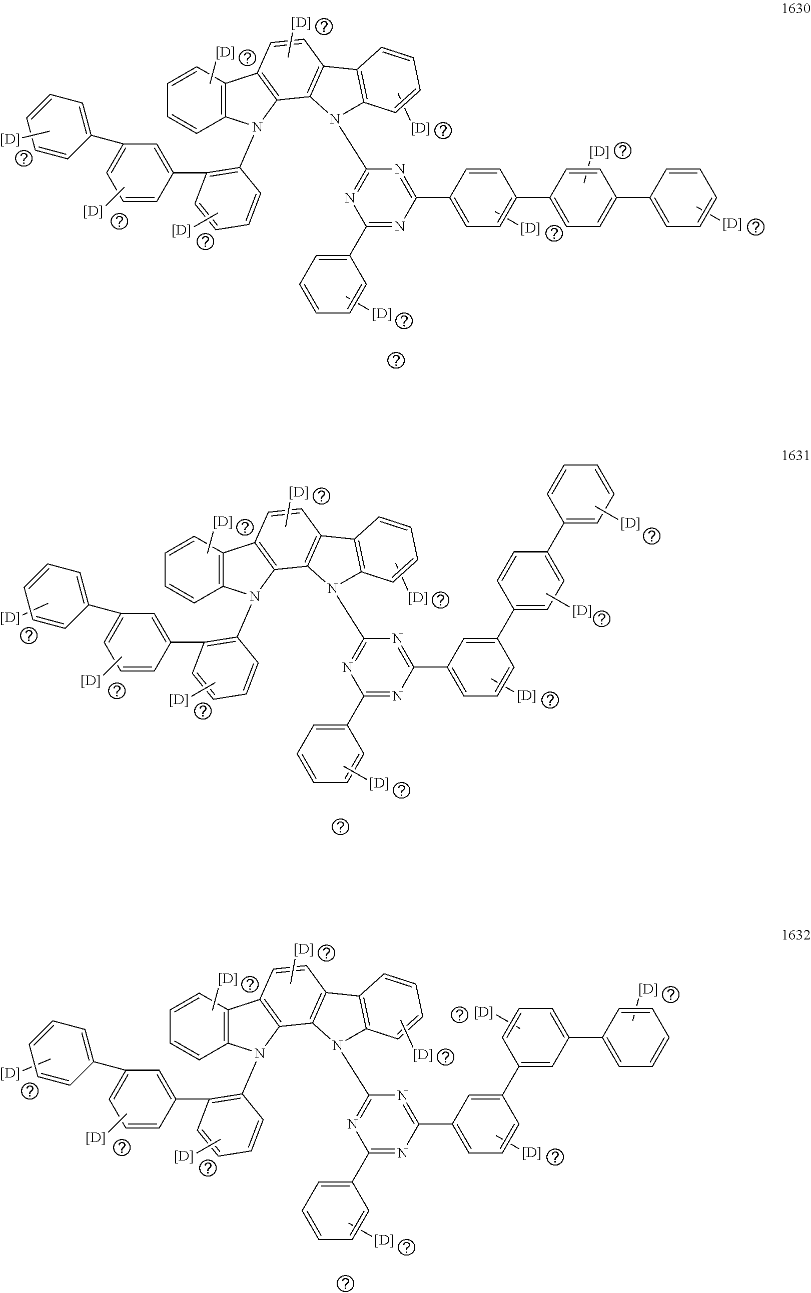

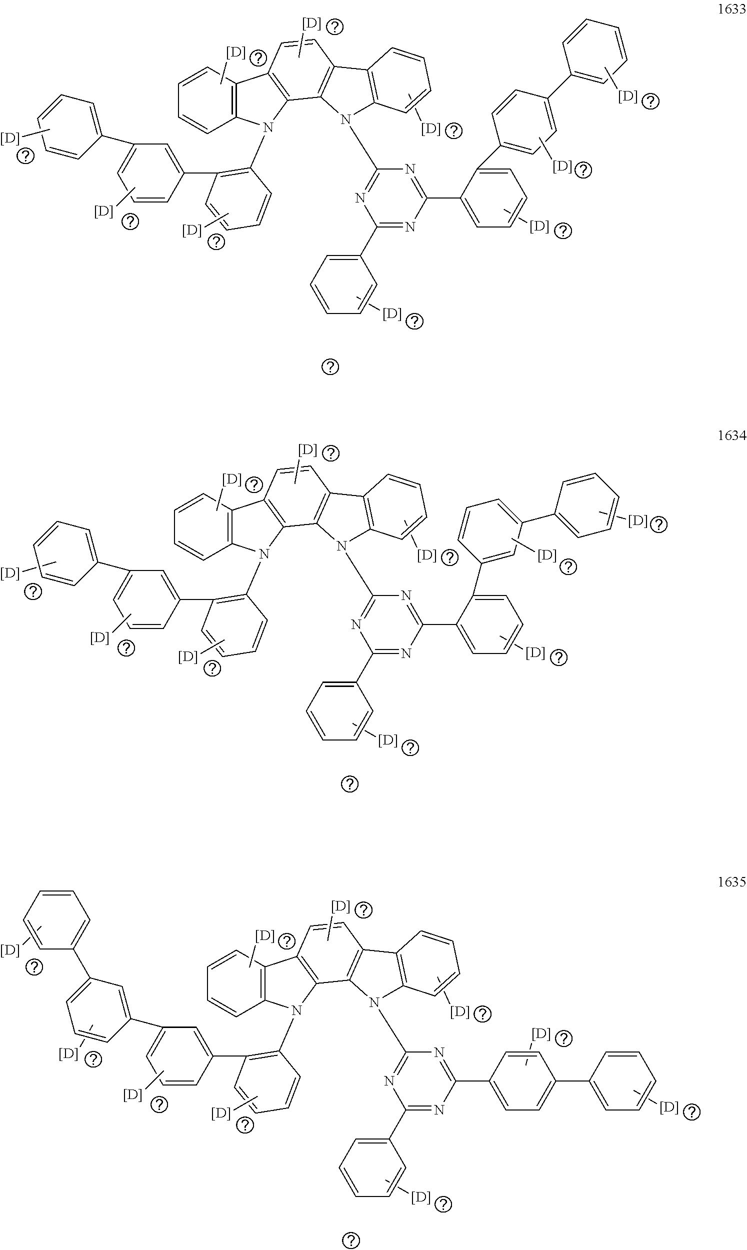

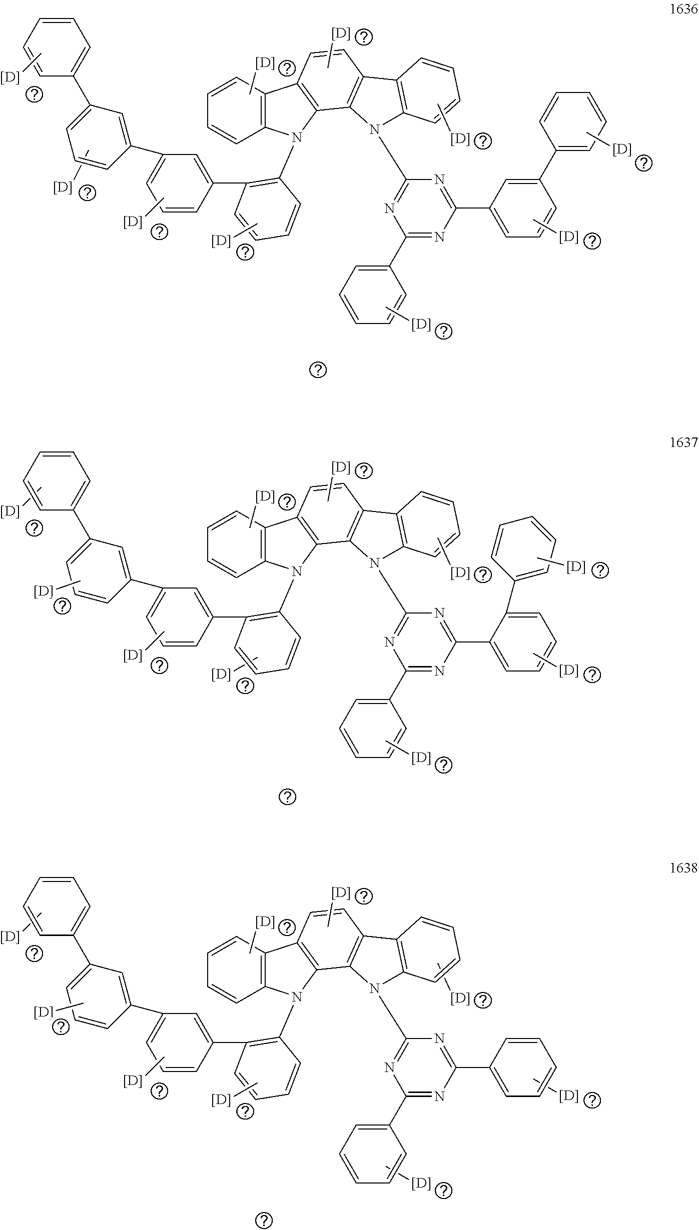

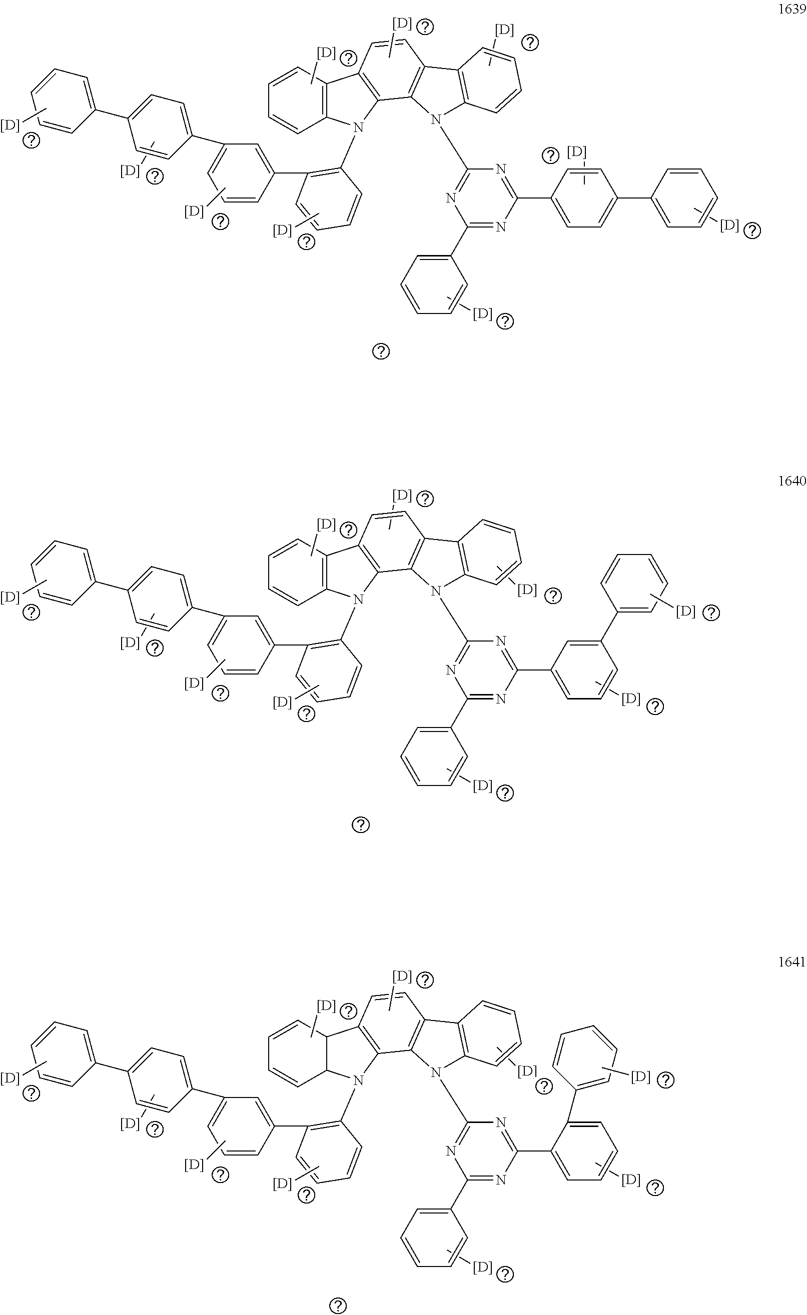

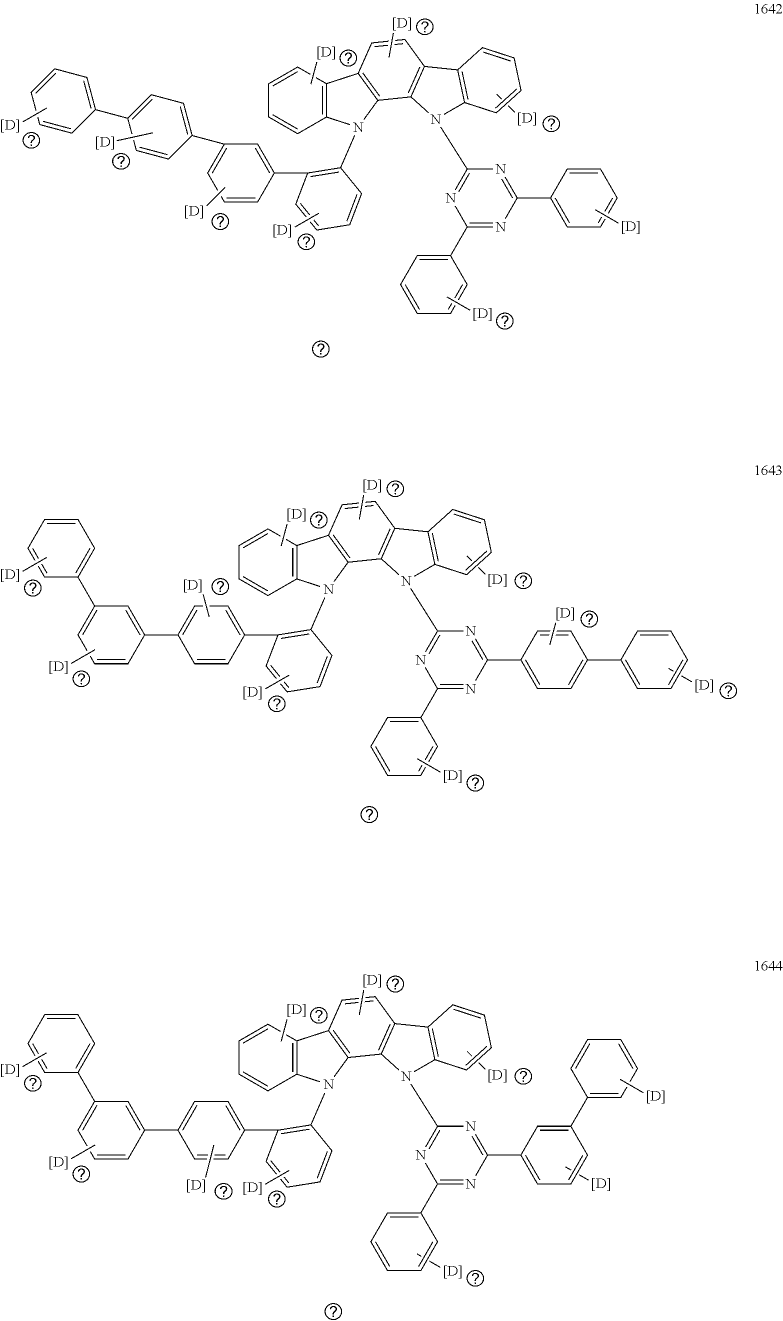

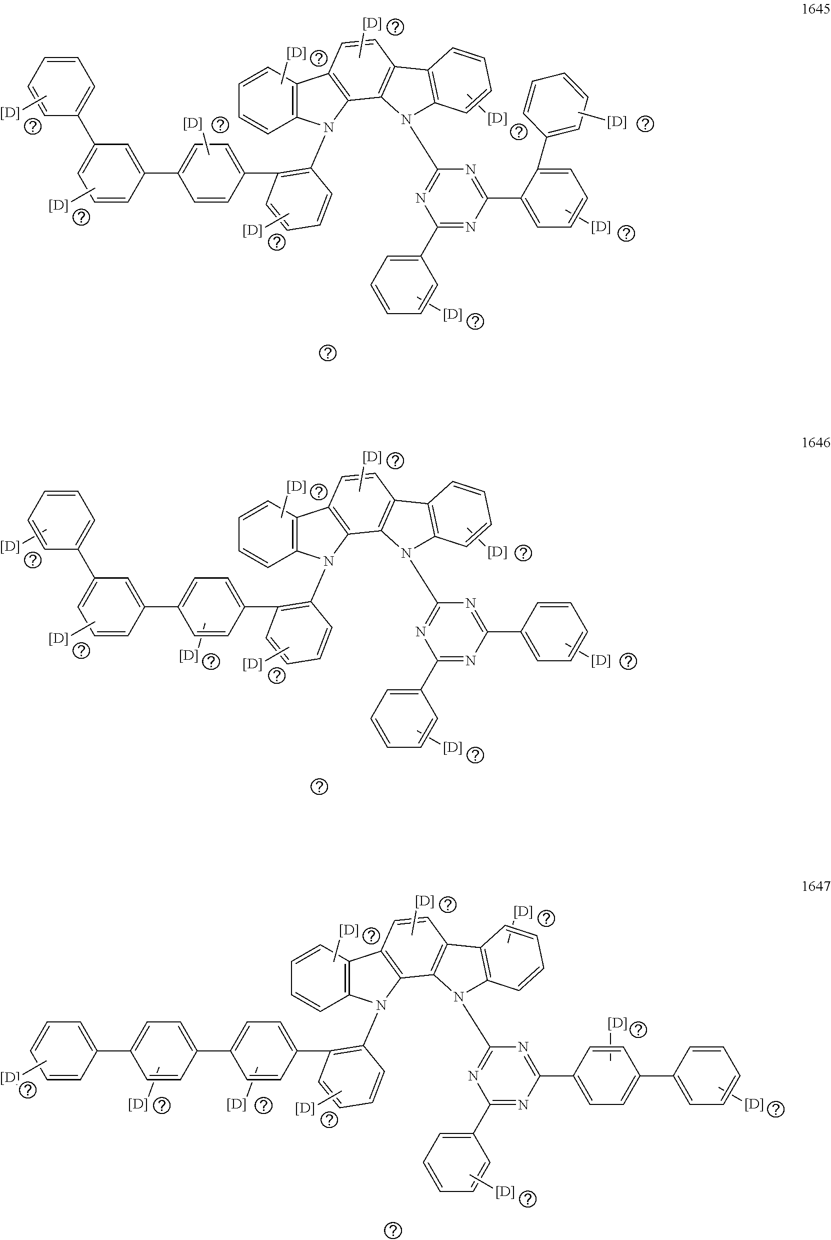

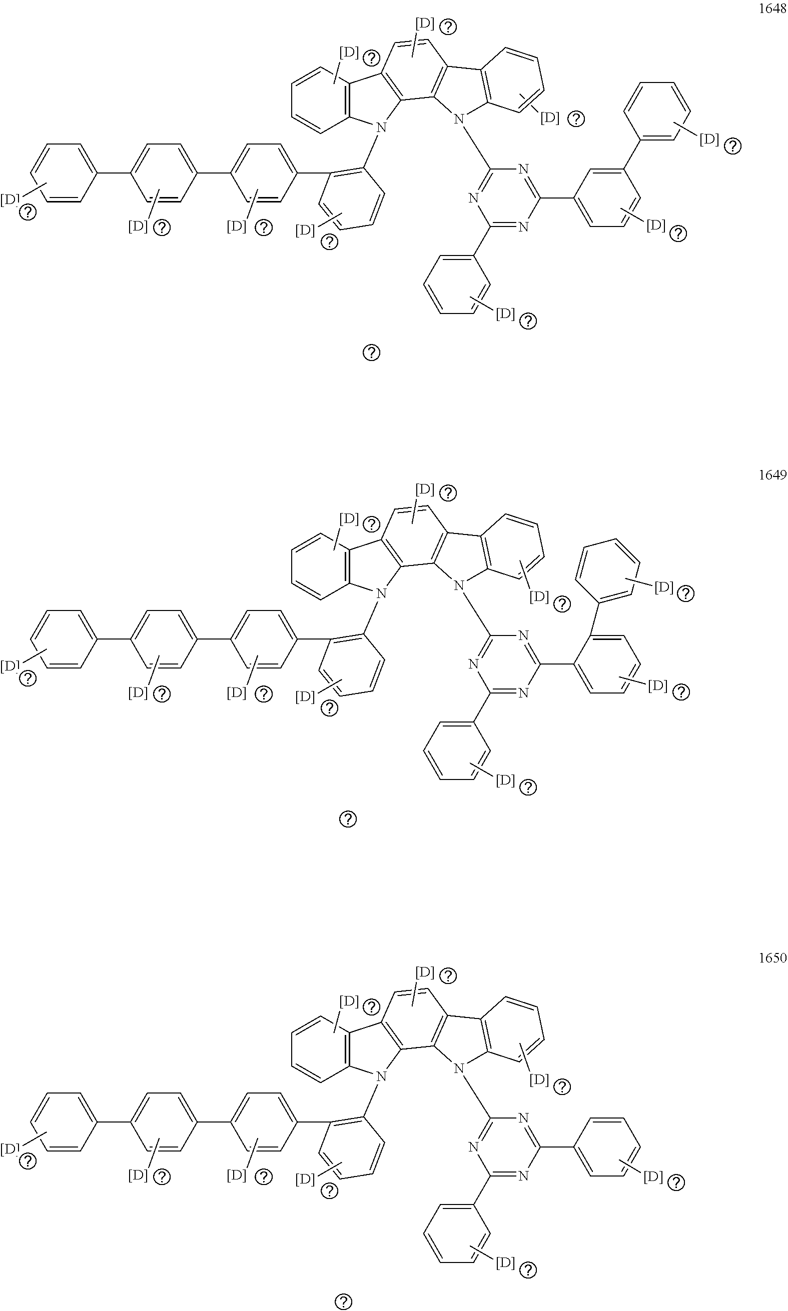

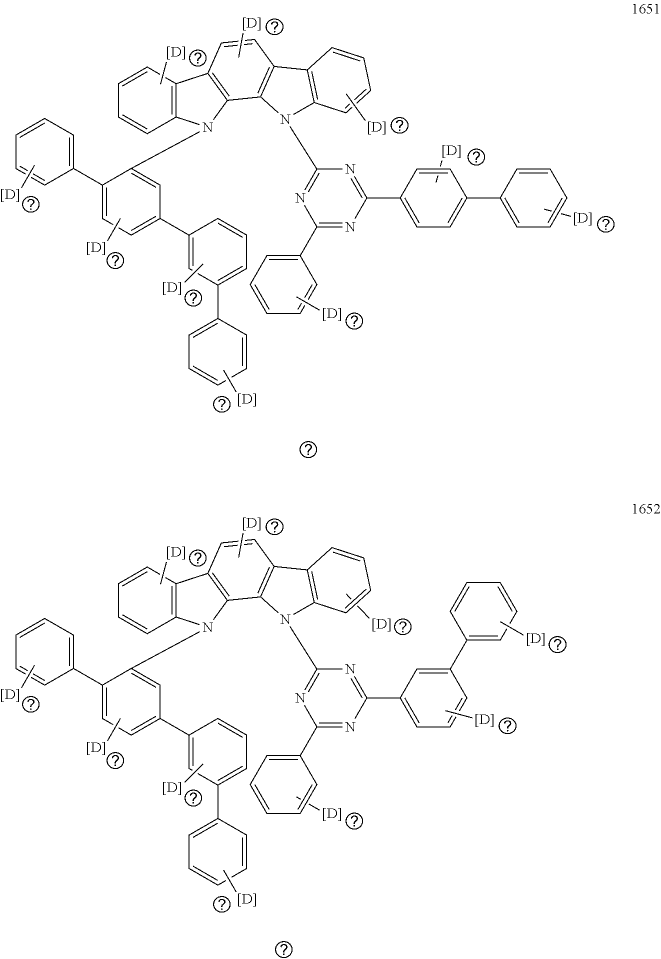

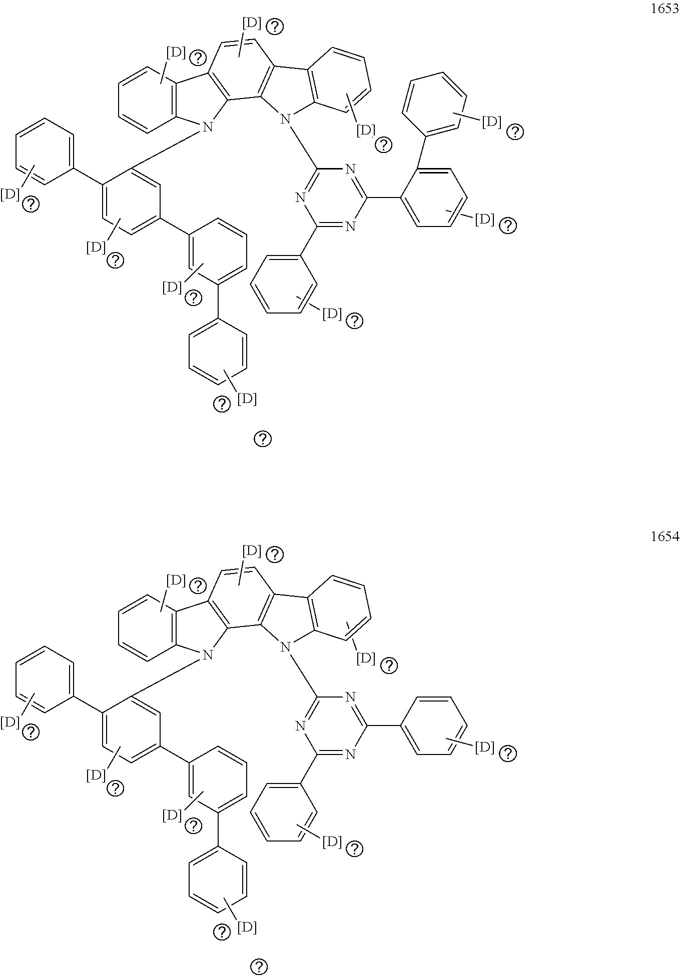

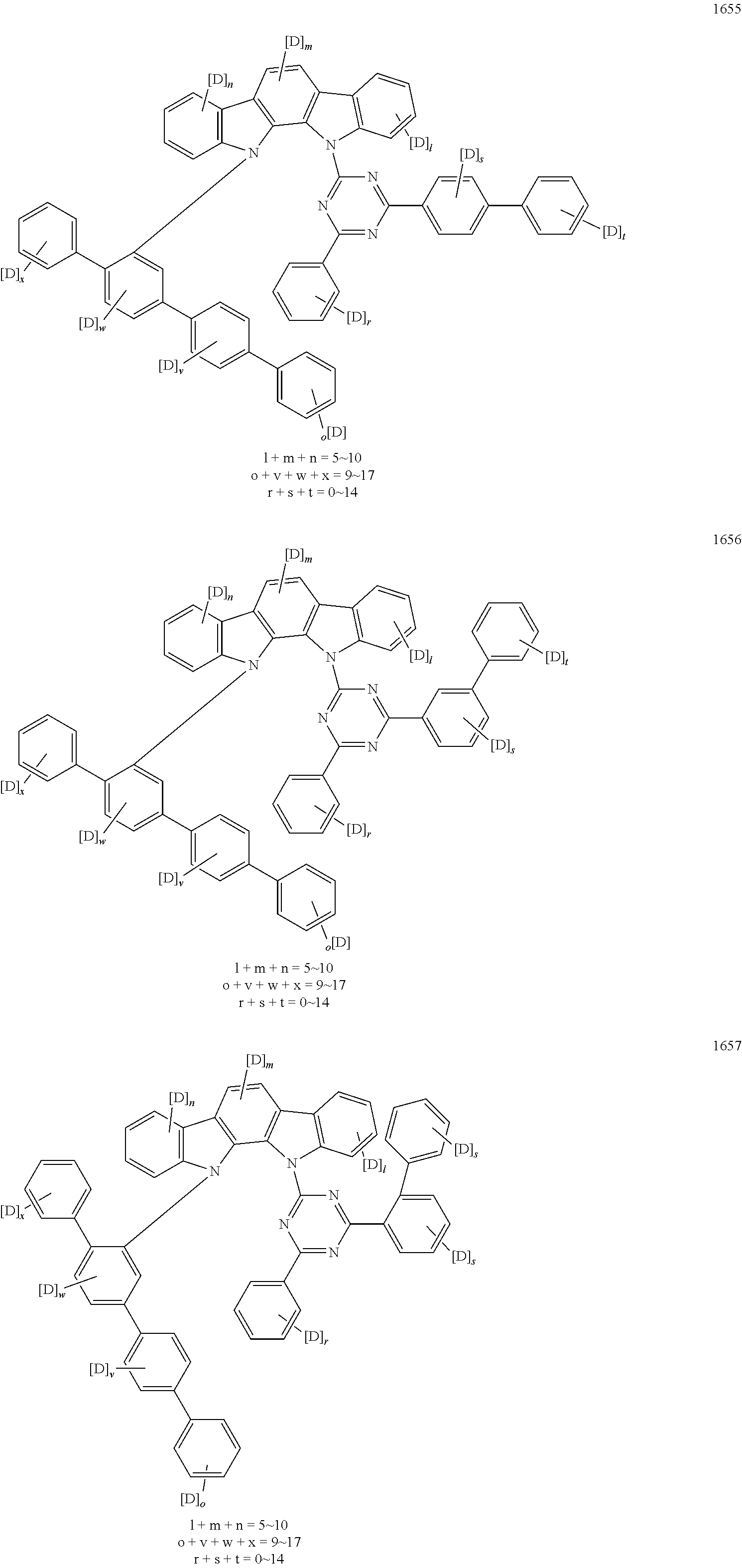

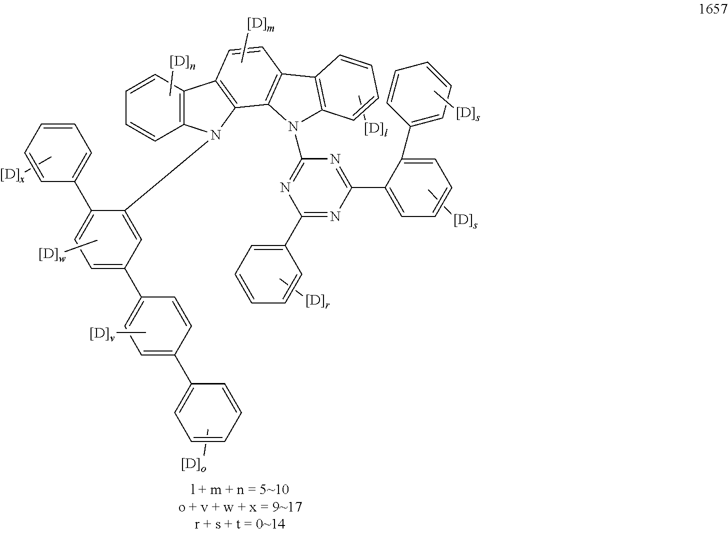

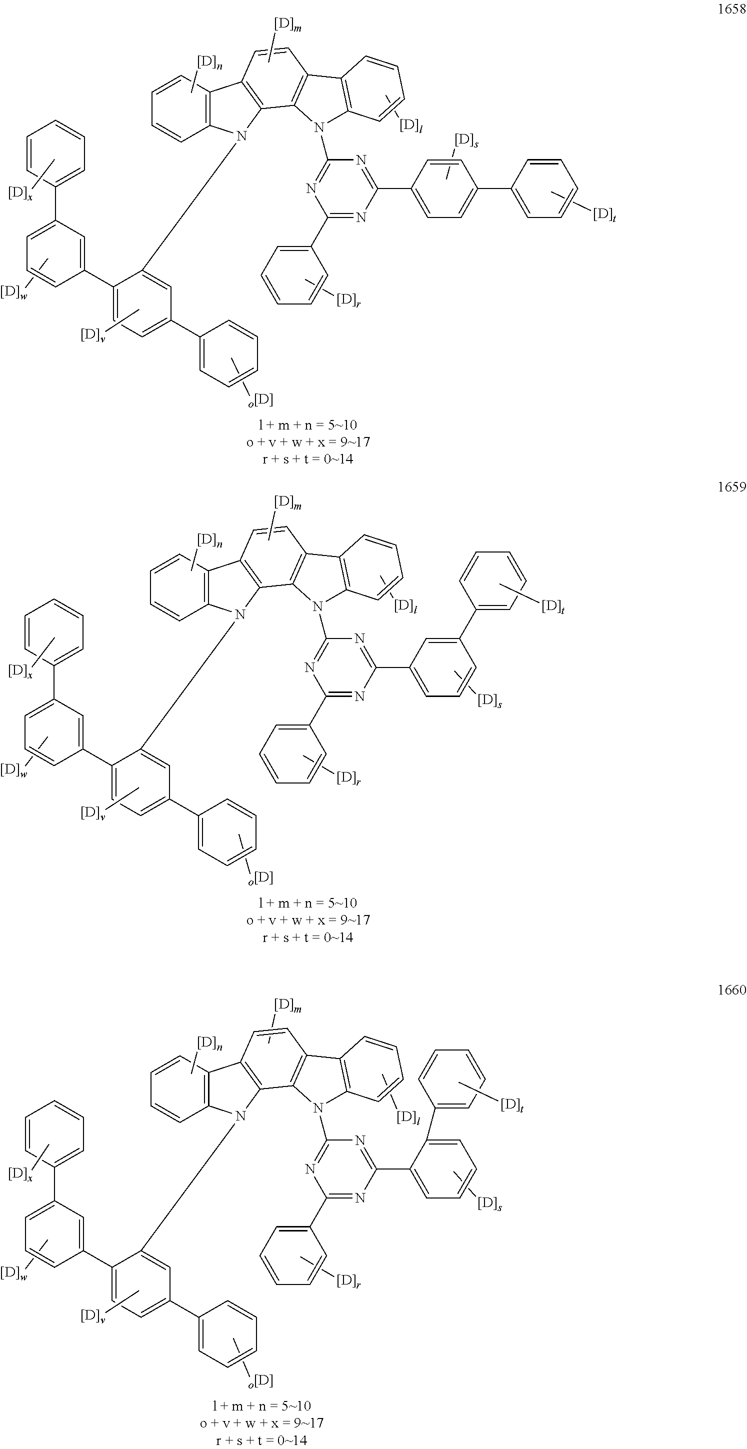

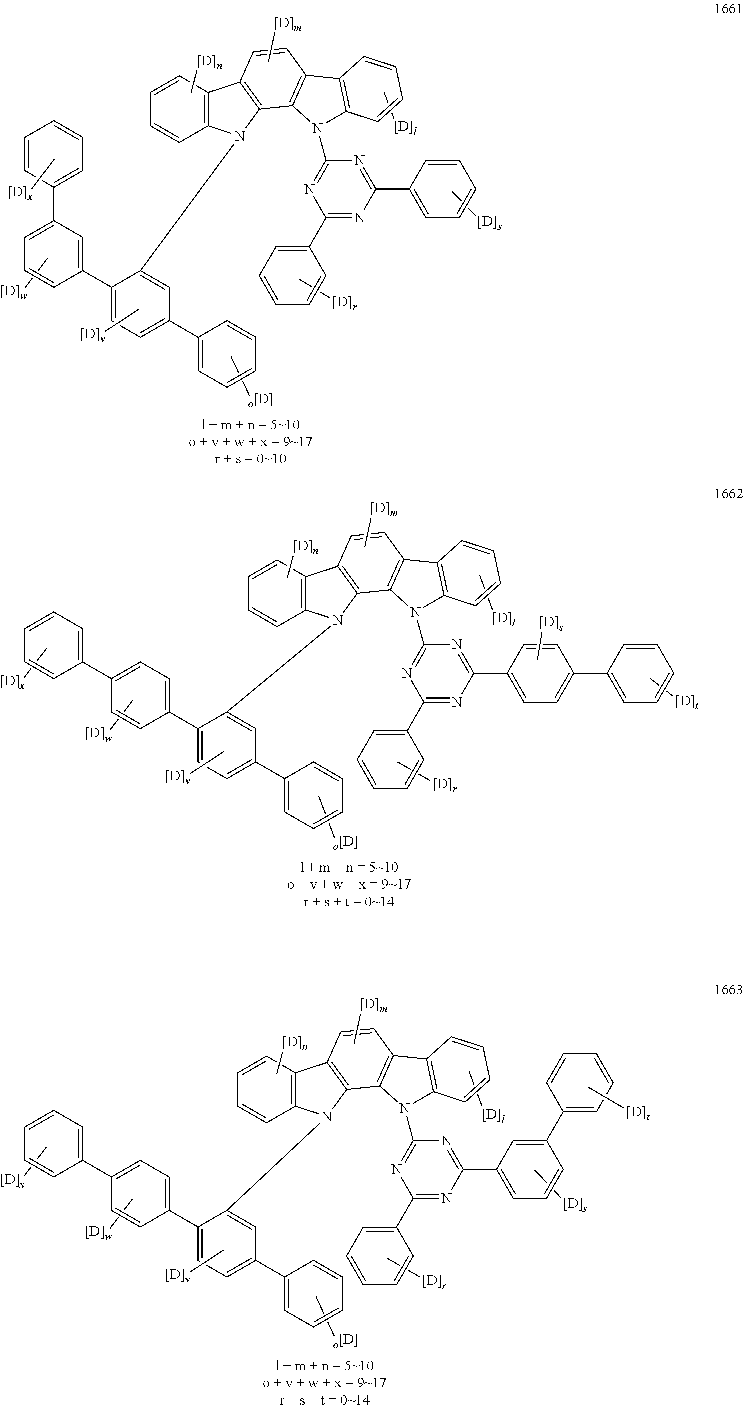

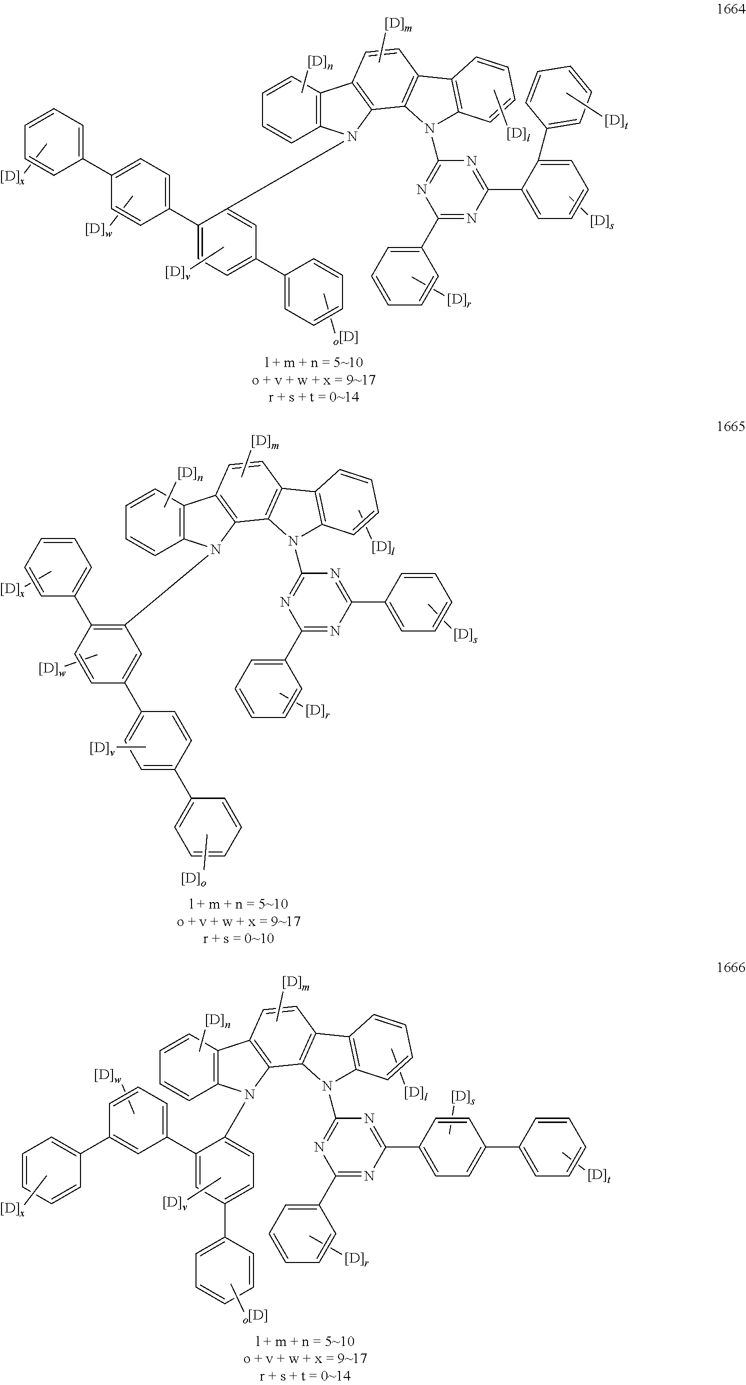

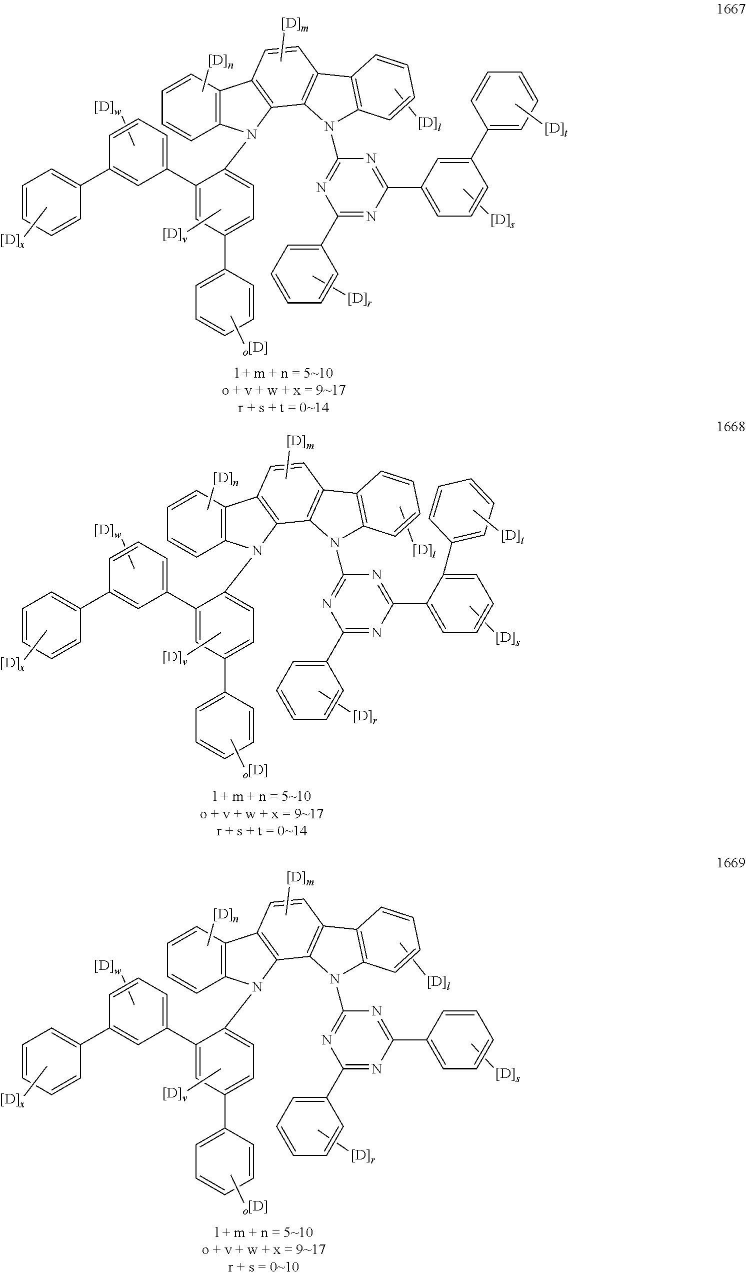

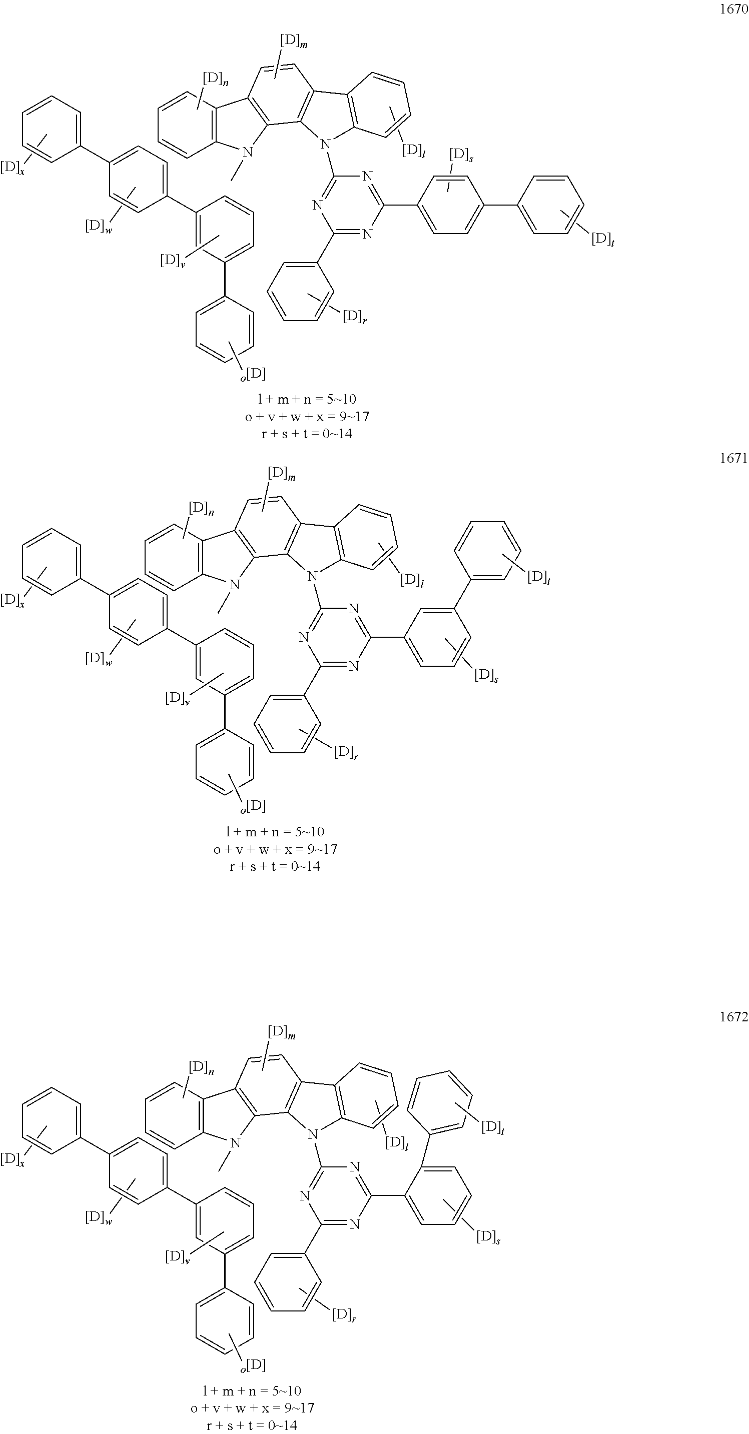

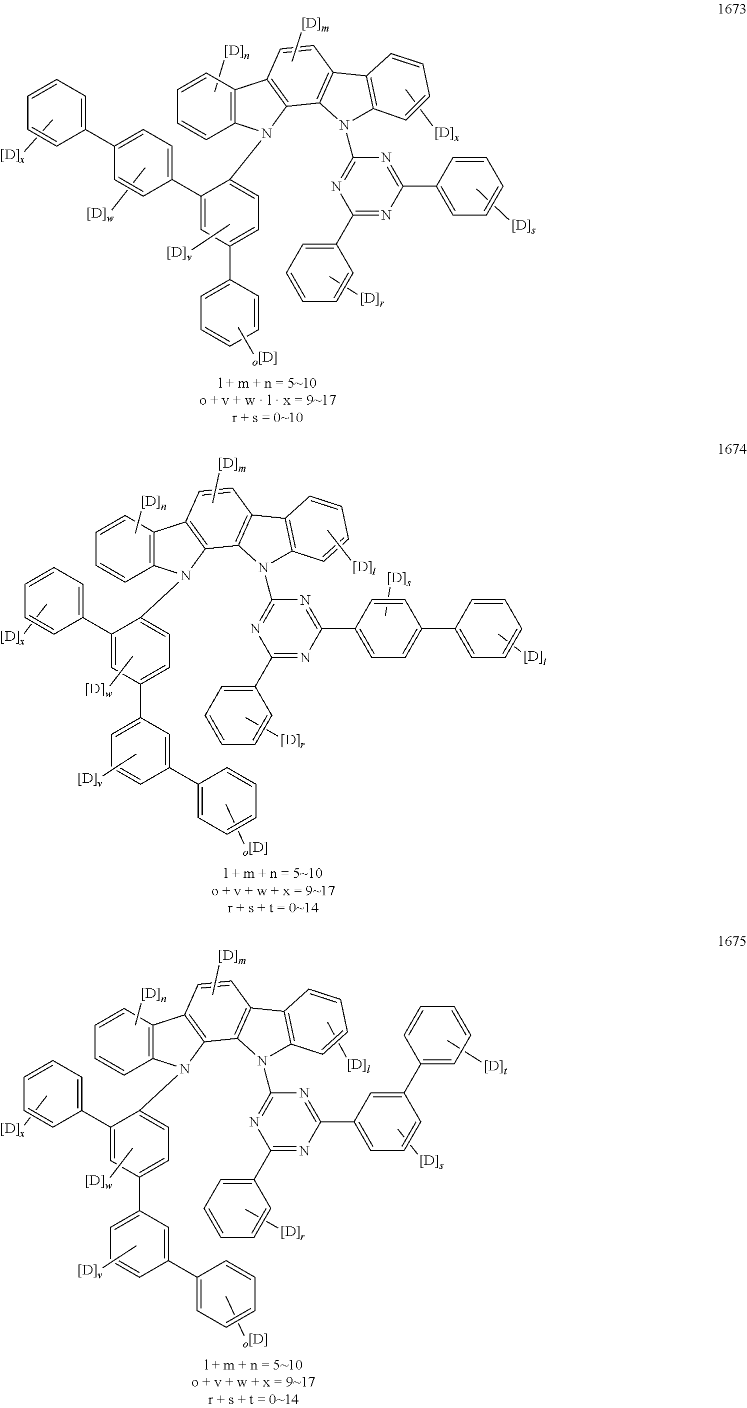

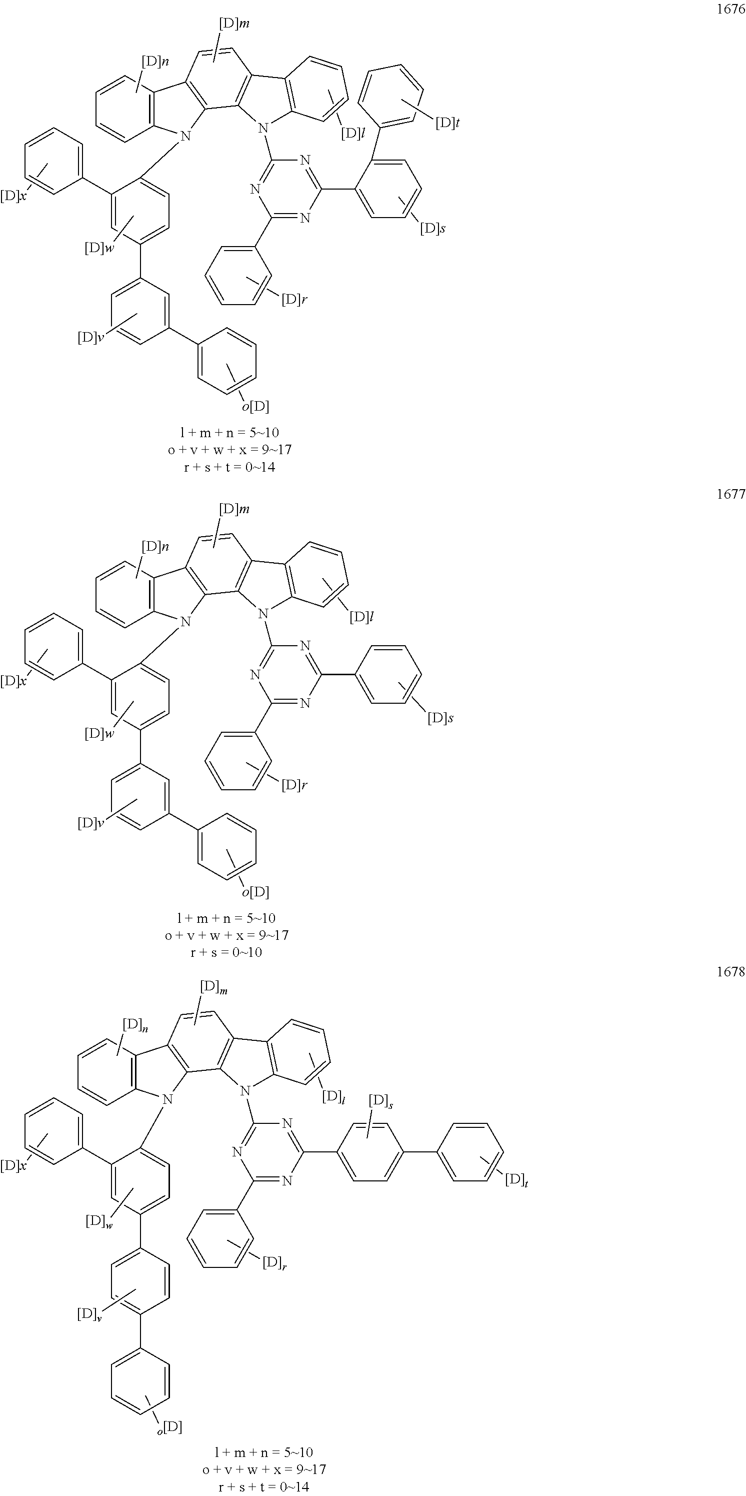

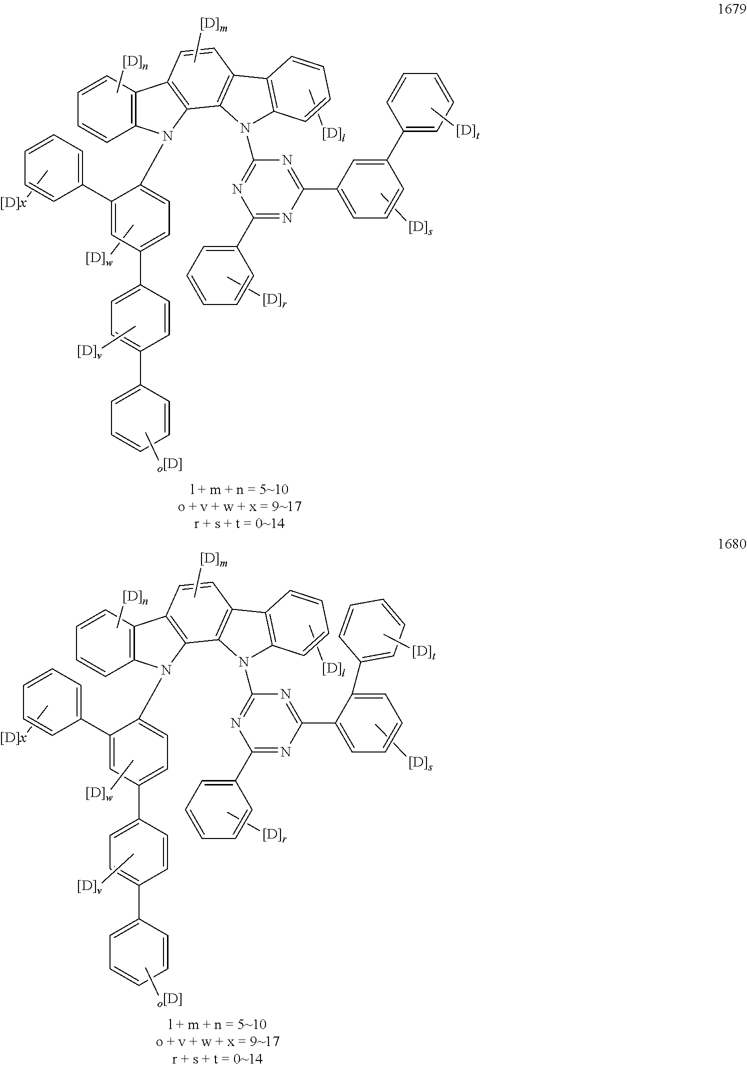

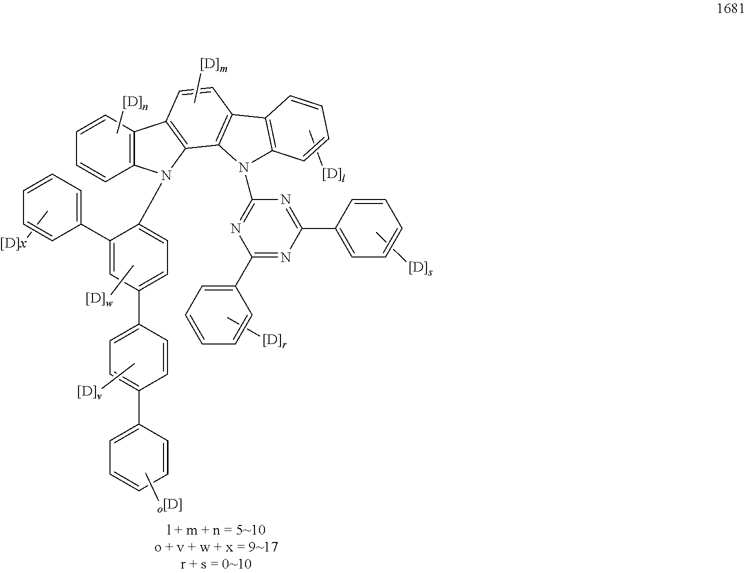

Specific examples of the compound represented by the general formula (2) are shown below, but are not limited to these exemplified compounds. In the following structural formulas, the number of substitutions such as l′, m′, n′, o′, p′, q′, r′, s′, or t′ of the substituted deuterium (D) means the average number, and varies depending on the rate of deuteration (D-rate).

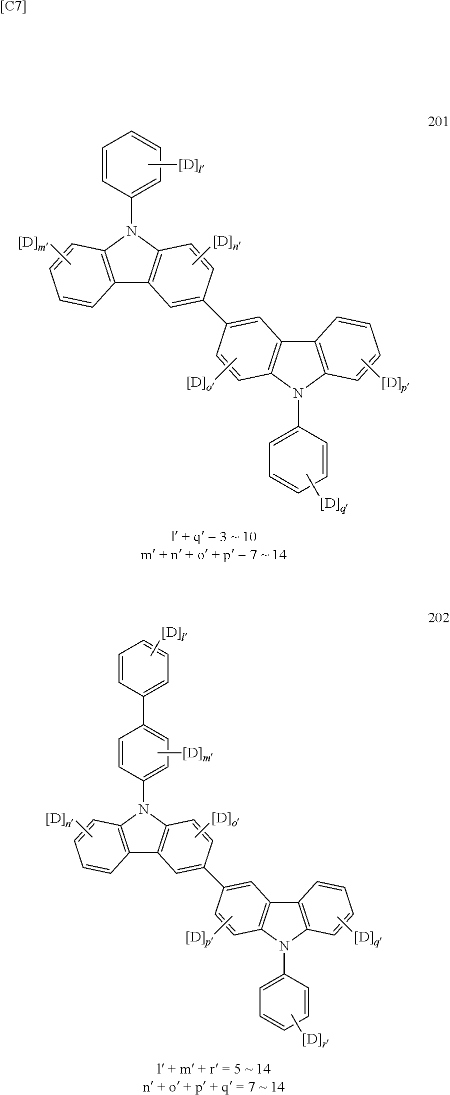

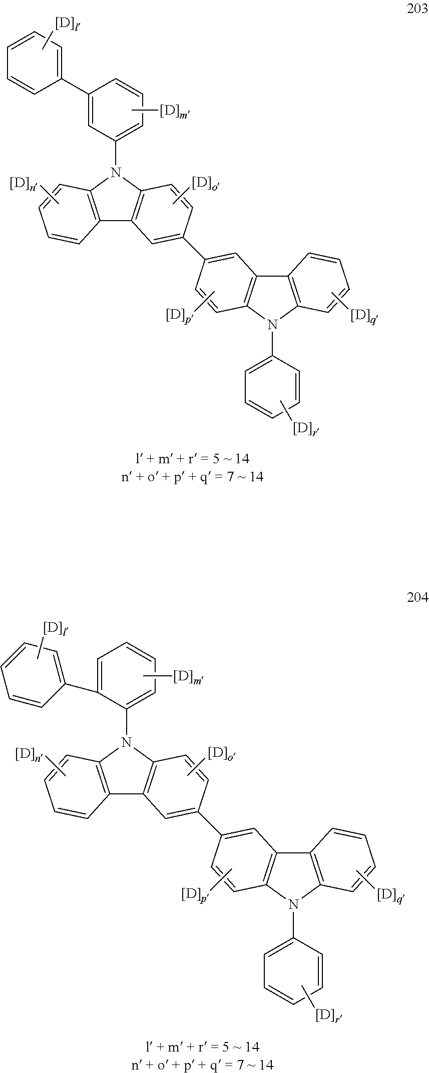

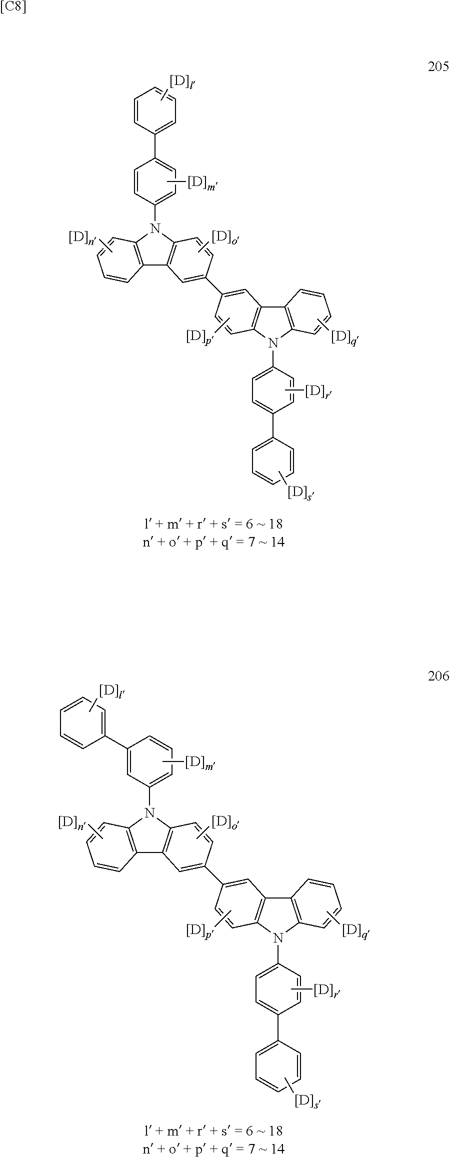

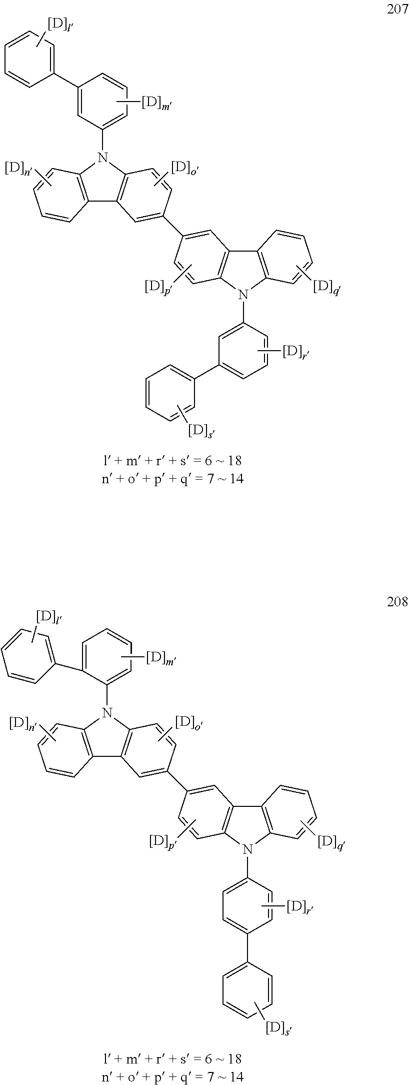

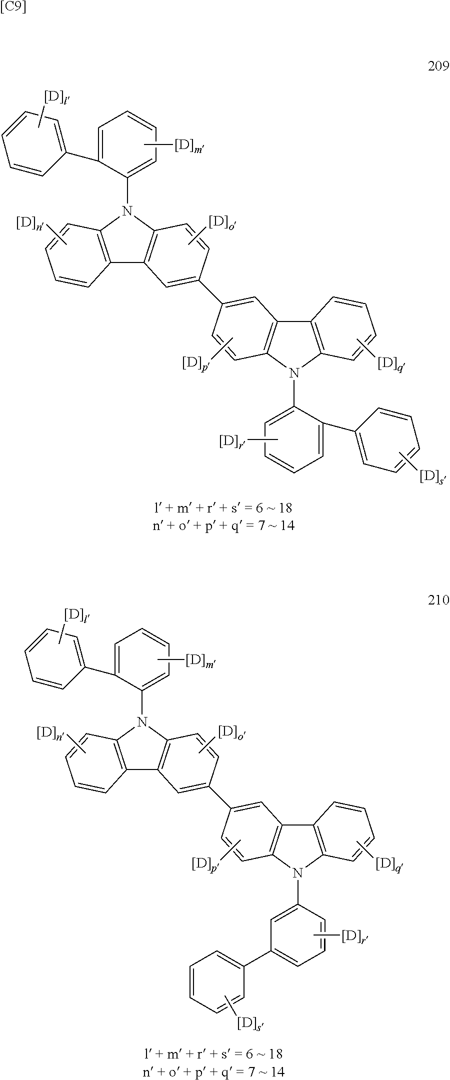

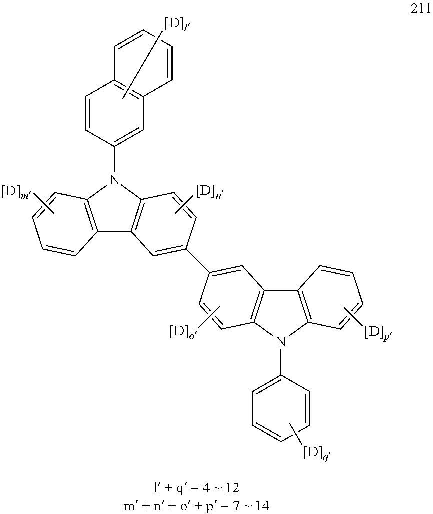

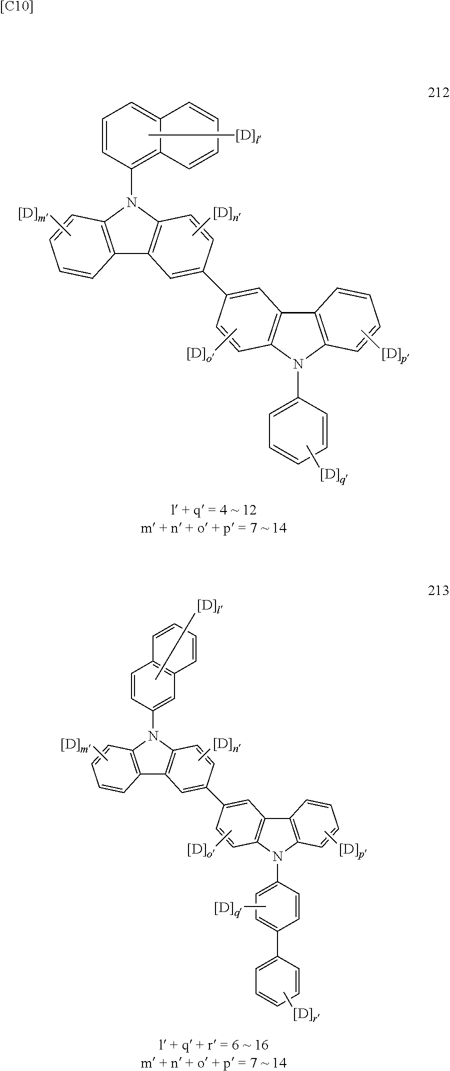

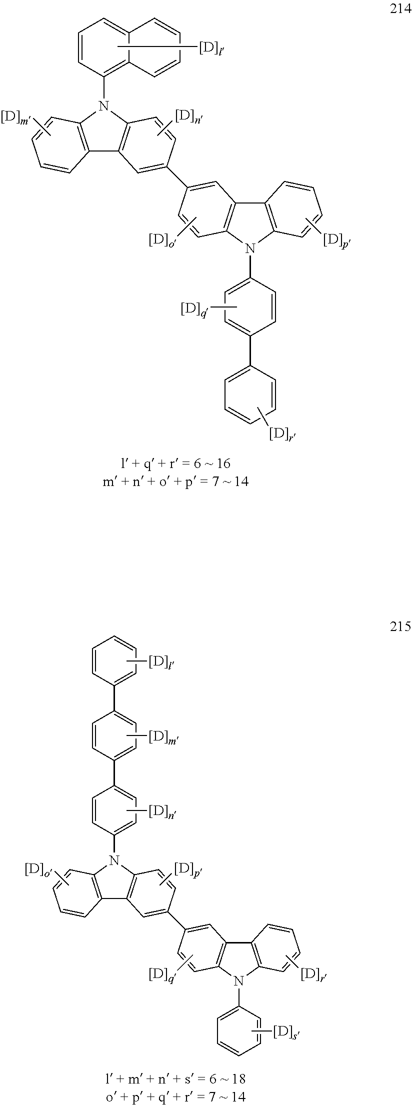

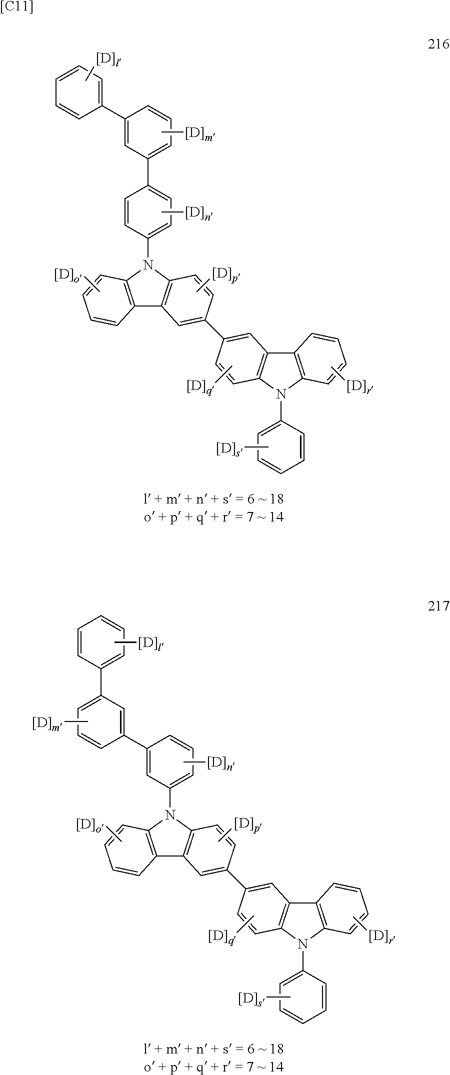

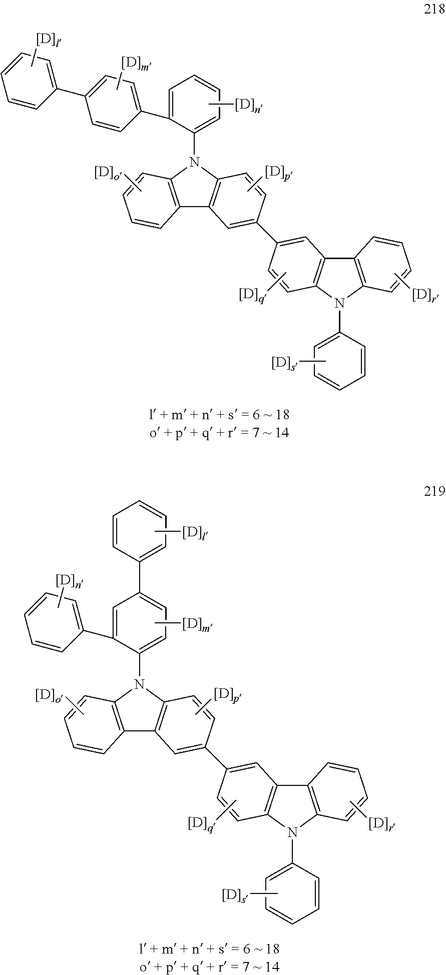

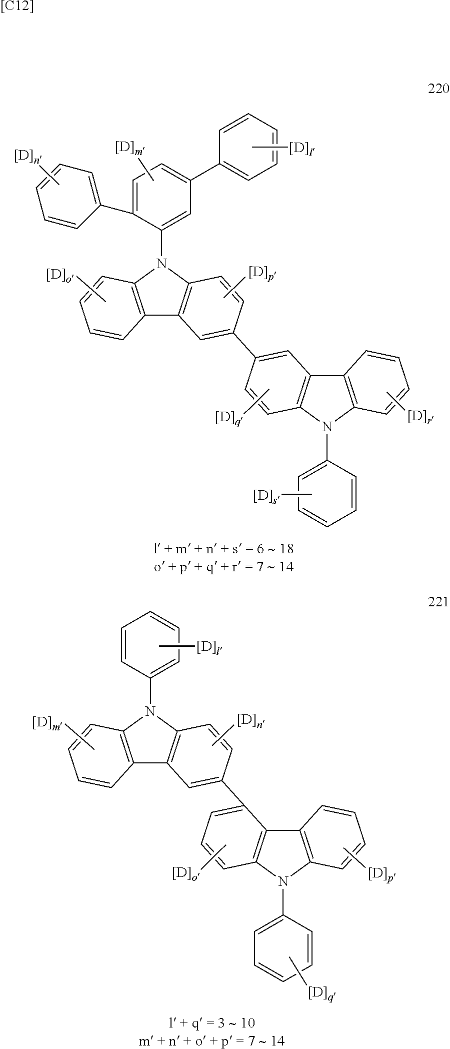

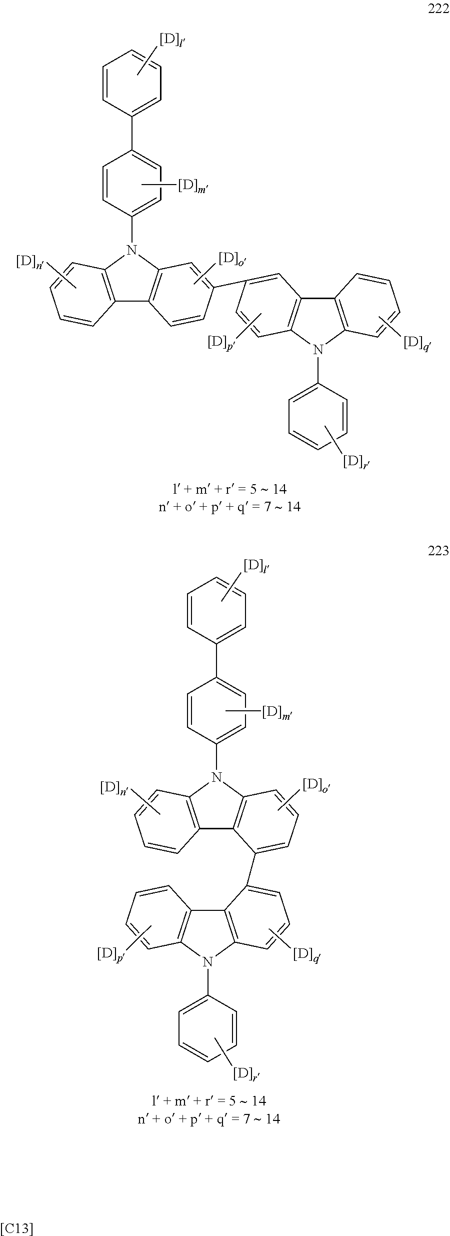

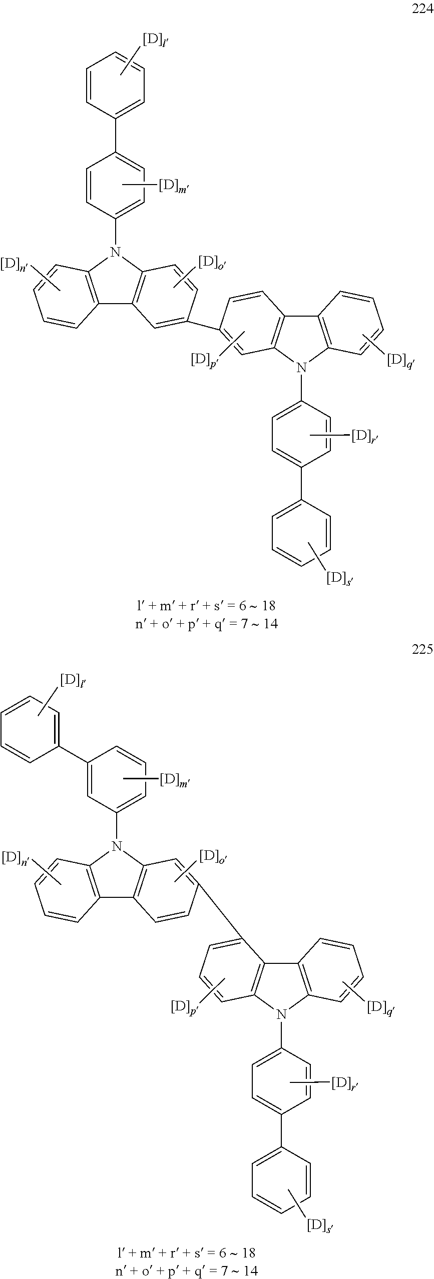

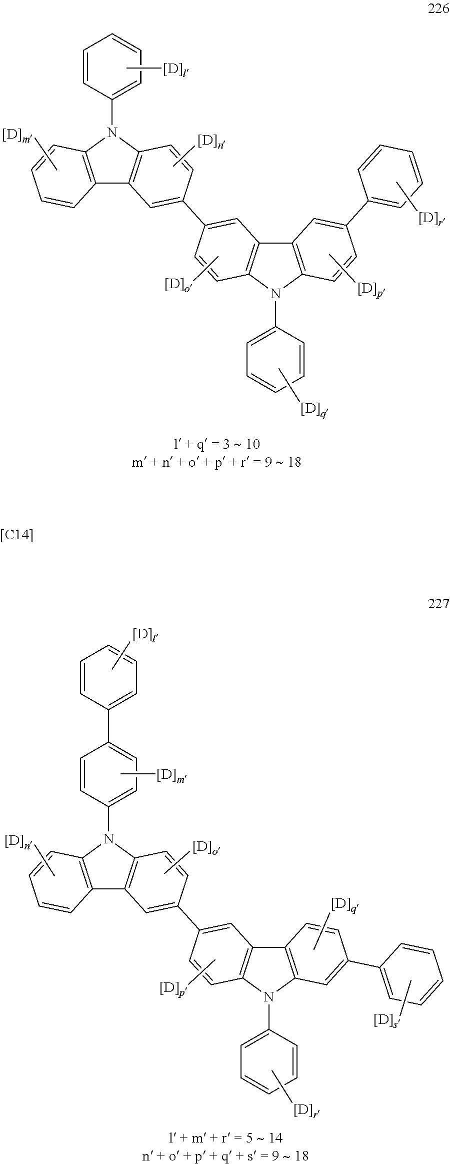

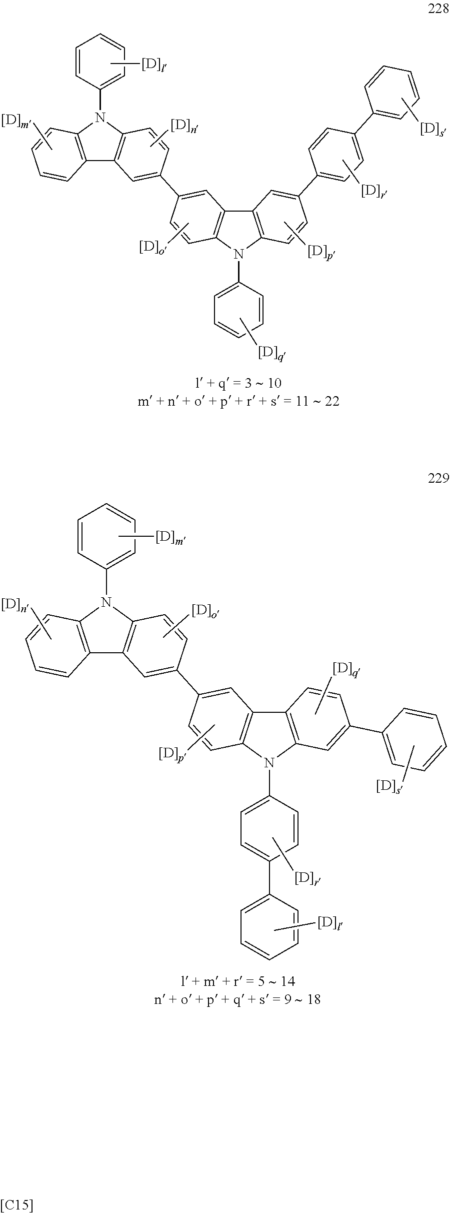

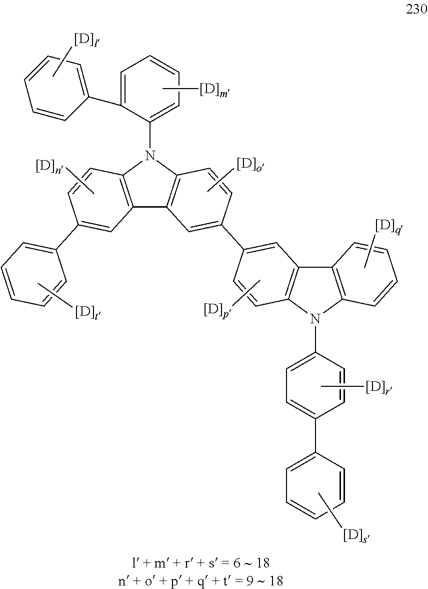

The host material for an organic EL device of the present invention is suitably used as a host material of a light-emitting layer.

Next, the structure of the organic EL device of the present invention will be described by referring to the drawing, but the structure of the organic EL device of the present invention is not limited thereto.

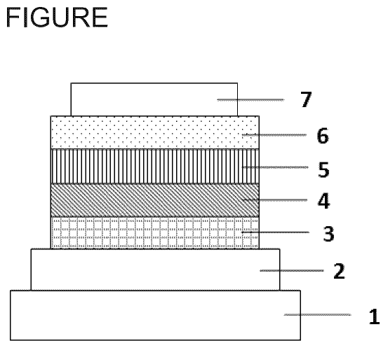

FIG. 1 is a cross-sectional view showing a structure example of an organic EL device generally used for the present invention, in which there are indicated a substrate 1, an anode 2, a hole injection layer 3, a hole transport layer 4, a light-emitting layer 5, an electron transport layer 6, and a cathode 7. The organic EL device of the present invention may have an exciton blocking layer adjacent to the light-emitting layer and may have an electron blocking layer between the light-emitting layer and the hole injection layer. The exciton blocking layer can be inserted into either of the anode side, and the cathode side of the light-emitting layer and inserted into both sides at the same time. The organic EL device of the present invention has the anode, the light-emitting layer, and the cathode as essential layers, and preferably has a hole injection transport layer and an electron injection transport layer in addition to the essential layers, and further preferably has a hole blocking layer between the light-emitting layer and the electron injection transport layer. Note that the hole injection transport layer refers to either or both of a hole injection layer and a hole transport layer, and the electron injection transport layer refers to either or both of an electron injection layer and an electron transport layer.

A structure reverse to that of FIG. 1 is applicable, in which a cathode 7, an electron transport layer 6, a light-emitting layer 5, a hole transport layer 4, a hole injection layer 3, and an anode 2 are laminated on a substrate 1 in this order. In this case, layers may be added or omitted as necessary.

### —Substrate—

The organic EL device of the present invention is preferably supported on a substrate. The substrate is not particularly limited, and those conventionally used in organic EL devices may be used, and substrates made of, for example, glass, a transparent plastic, or quartz may be used.

### —Anode—

Regarding an anode material for an organic EL device, it is preferable to use a material of a metal, an alloy, an electrically conductive compound, and a mixture thereof, each having a large work function (4 eV or more). Specific examples of such an electrode material include a metal such as Au, and a conductive transparent material such as CuI, indium tin oxide (ITO), SnO₂, and ZnO. In addition, an amorphous material such as IDIXO (In₂O₃—ZnO), which is capable of forming a transparent conductive film, may be used. Regarding the anode, such an electrode material is used to form a thin film by, for example, a vapor-deposition or sputtering method, and a desired shape pattern may be formed by a photolithographic method; or if the pattern accuracy is not particularly required (about 100 μm or more), a pattern may be formed via a desired shape mask when the electrode material is vapor-deposited or sputtered. Alternatively, when a coatable substance such as an organic conductive compound is used, a wet film formation method such as a printing method or a coating method may be used. For taking emitted light from the anode, it is desired to have a transmittance of more than 10%, and the sheet resistance for the anode is preferably several hundreds Ω/□ or less. The film thickness is selected usually within 10 to 1000 nm, preferably within 10 to 200 nm though depending on the material.

### —Cathode—

Meanwhile, regarding a cathode material, a material of a metal (an electron injection metal), an alloy, an electrically conductive compound, or a mixture thereof, each having a small work function (4 eV or less) is used. Specific examples of such an electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and a rare earth metal. Among these, from the viewpoint of the electron injectability and the durability against oxidation and the like, a mixture of an electron injection metal and a second metal which is a stable metal having a larger work function value is suitable, and examples thereof include a magnesium/silver mixture, a magnesium/aluminum mixture, a magnesium/indium mixture, an aluminum/aluminum oxide mixture, a lithium/aluminum mixture and aluminum. The cathode can be produced by forming a thin film by a method such as vapor-depositing or sputtering of such a cathode material. In addition, the sheet resistance of cathode is preferably several hundreds Ω/□ or less. The film thickness is selected usually within 10 nm to 5 μm, preferably within 50 to 200 nm. Note that for transmission of emitted light, if either one of the anode and cathode of the organic EL device is transparent or translucent, emission luminance is improved, which is convenient.

In addition, formation of a film of the above metal with a thickness of 1 to 20 nm, on the cathode, followed by formation of a conductive transparent material described in the description on the anode thereon, enables production of a transparent or translucent cathode, and application of this enables production of a device wherein an anode and a cathode both have transmittance.

### —Light-Emitting Layer—

The light-emitting layer is a layer that emits light after excitons are generated when holes and electrons injected from the anode and the cathode, respectively, are recombined. As a light-emitting layer, an organic light-emitting dopant material and a host material may be contained.

It is preferable for the host that a compound represented by the general formula (1) be used as the first host and a compound represented by the general formula (2) be used as the second host. As the first host material of the compound represented by the general formula (1), one kind may be used, or two or more kinds of different compounds may be used. Also, as the second host material of the compound represented by the general formula (2), one kind may be used, or two or more kinds of different compounds may be used. With respect to the mixing ratio (weight ratio) of the first host and the second host, the proportion of the first host to the first host and the second host in total is 10 wt % or more and less than 80 wt %, and preferably 30 wt % or more and less than 80 wt %. One or a plurality of other known host materials may be further used in combination as necessary, and the amount thereof used is 50 wt % or less, and preferably 25 wt % or less to the first host and the second host in total. As other known host material, a compound is preferable, which has hole transport ability and electron transport ability, which prevents elongation of the wavelength of light emitted, and which also has a high glass transition temperature.

Such other known host material is one known in many Patent Literatures and the like, and can be selected therefrom. Specific examples of the host material include, but not particularly limited thereto, indolocarbazole derivatives described in WO2008/056746A1 or WO2008/146839A1, carbazole derivatives described in WO2009/086028A1 or WO2012/077520A1, CBP (N,N-biscarbazolylbiphenyl) derivatives, triazine derivatives described in WO2014/185595A1 or WO2018/021663A1, indenocarbazole derivatives described in WO2010/136109A1 or WO2011/000455A1, dibenzofuran derivatives described in WO2015/169412A1, triazole derivatives, indole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tert-amine compounds, styrylamine compounds, aromatic dimethylidene-based compounds, porphyrin-based compounds, anthraquinodimethane derivatives, anthrone derivatives, diphenylquinone derivatives, thiopyran dioxide derivatives, heterocyclic tetracarboxylic anhydrides of naphthalene, perylene, or the like, various metal complexes typified by phthalocyanine derivatives, metal complexes of 8-quinolinol derivatives, metal phthalocyanine, and metal complexes of benzoxazole or benzothiazole derivatives, and polymer compounds such as polysilane-based compounds, poly(N-vinylcarbazole) derivatives, aniline-based copolymers, thiophene oligomers, polythiophene derivatives, polyphenylene derivatives, polyphenylene vinylene derivatives, and polyfluorene derivatives.

Specific examples of other known host material described above are shown below, but are not limited thereto. With respect to other known host materials, some or all of hydrogen may be deuterium.

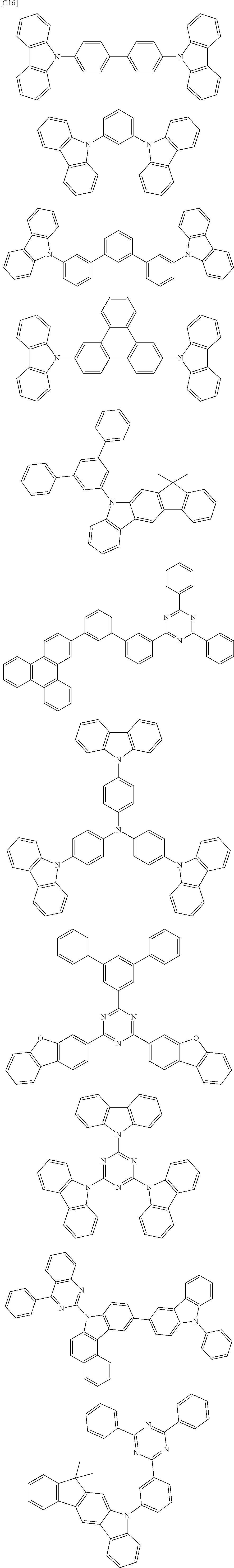

Preferred examples of the organic light-emitting dopant material include a phosphorescent dopant, a fluorescence-emitting dopant or a thermally activated delayed fluorescence-emitting dopant.

Preferred is a phosphorescent dopant including an organic metal complex containing at least one metal selected from ruthenium, rhodium, palladium, silver, rhenium, osmium, iridium, platinum and gold. Specifically, iridium complexes described in J. Am. Chem. Soc. 2001, 123, 4304, JP2013-530515A, US2016/0049599A1, US2017/0069848A1, US2018/0282356A1, US2019/0036043A1, and the like, or platinum complexes described in US2018/0013078A1, KR2018/094482A, and the like are preferably used, but the phosphorescent dopant material is not limited thereto.

Regarding the phosphorescent dopant material, only one kind thereof may be contained in the light-emitting layer, or two or more kinds thereof may be contained. A content of the phosphorescent dopant material is preferably 0.1 to 30 wt % and more preferably 1 to 20 wt % with respect to the host material.

The phosphorescent dopant material is not particularly limited, and specific examples thereof include the following.

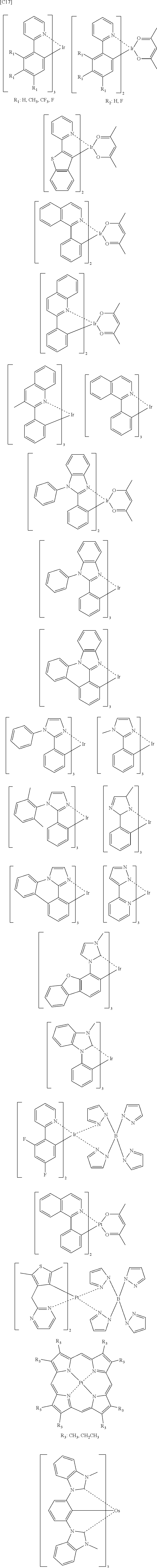

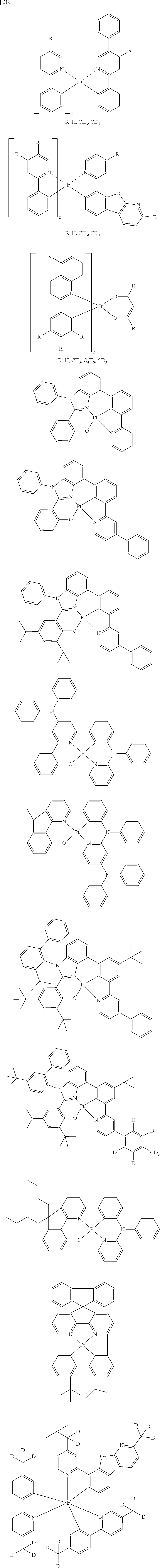

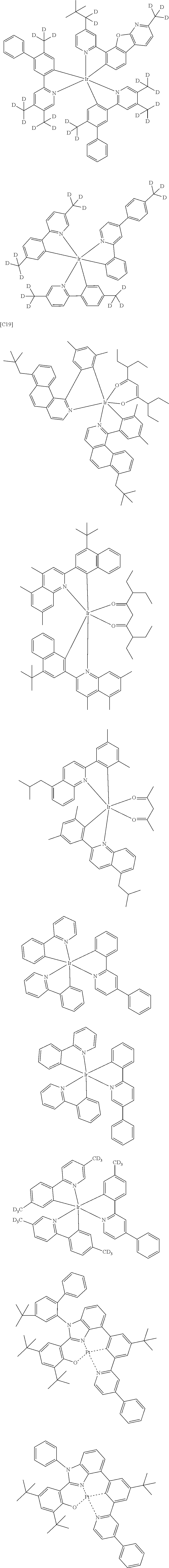

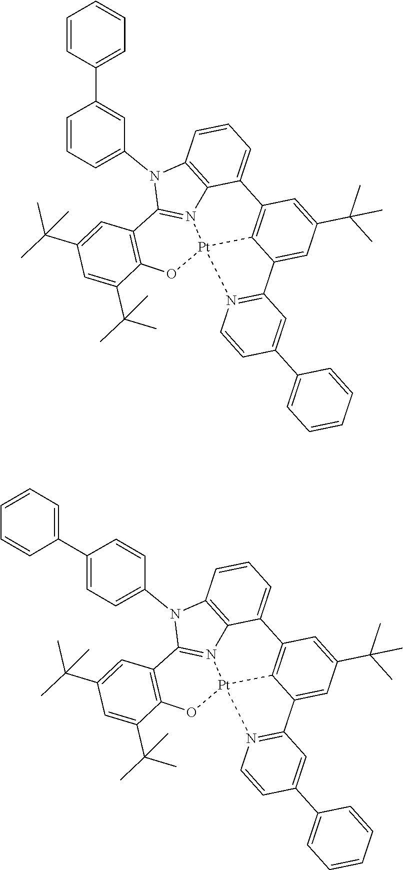

The fluorescence-emitting dopant is not particularly limited. Examples thereof include benzoxazole derivatives, benzothiazole derivatives, benzimidazole derivatives, styrylbenzene derivatives, polyphenyl derivatives, diphenylbutadiene derivatives, tetraphenyl butadiene derivatives, naphthalimido derivatives, coumarin derivatives, fused aromatic compounds, perinone derivatives, oxadiazole derivatives, oxazine derivatives, aldazine derivatives, pyrrolidine derivatives, cyclopentadiene derivatives, bisstyryl anthracene derivatives, quinacridone derivatives, pyrrolopyridine derivatives, thiadiazolopyridine derivatives, styrylamine derivatives, diketopyrrolopyrrole derivatives, aromatic dimethylidine compounds, metal complexes of 8-quinolinol derivatives or metal complexes of pyromethene derivatives, rare earth complexes, various metal complexes represented by transition metal complexes, polymer compounds such as polythiophene, polyphenylene, and polyphenylene vinylene, and organosilane derivatives. Preferred examples thereof include fused aromatic derivatives, styryl derivatives, diketopyrrolopyrrole derivatives, oxazine derivatives, pyromethene metal complexes, transition metal complexes, and lanthanoid complexes. More preferable examples thereof include naphthalene, pyrene, chrysene, triphenylene, benzo[c]phenanthrene, benzo[a]anthracene, pentacene, perylene, fluoranthene, acenaphthofluoranthene, dibenzo[a,j]anthracene, dibenzo[a,h]anthracene, benzo[a]naphthalene, hexacene, naphtho[2,1-f]isoquinoline, α-naphthaphenanthridine, phenanthrooxazole, quinolino[6,5-f]quinoline, and benzothiophanthrene. These may have an alkyl group, an aryl group, an aromatic heterocyclic group, or a diarylamino group as a substituent.

Regarding the fluorescence-emitting dopant material, only one kind thereof may be contained in the light-emitting layer, or two or more kinds thereof may be contained. A content of the fluorescence-emitting dopant material is preferably 0.1 to 20 wt % and more preferably 1 to 10 wt % with respect to the host material.

The thermally activated delayed fluorescence-emitting dopant is not particularly limited. Examples thereof include: metal complexes such as a tin complex and a copper complex; indolocarbazole derivatives described in WO2011/070963A1; cyanobenzene derivatives and carbazole derivatives described in Nature 2012, 492, 234; and phenazine derivatives, oxadiazole derivatives, triazole derivatives, sulfone derivatives, phenoxazine derivatives, and acridine derivatives described in Nature Photonics 2014, 8,326.

The thermally activated delayed fluorescence-emitting dopant material is not particularly limited, and specific examples thereof include the following.

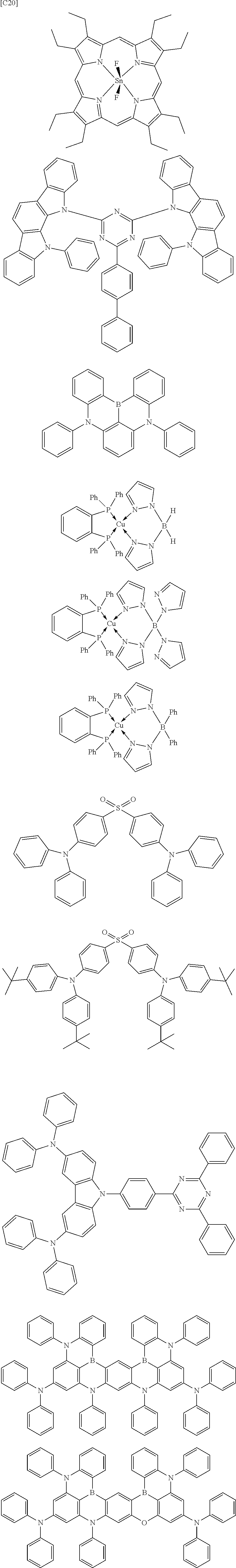

Regarding the thermally activated delayed fluorescence-emitting dopant material, only one kind thereof may be contained in the light-emitting layer, or two or more kinds thereof may be contained. In addition, the thermally activated delayed fluorescence-emitting dopant may be used by mixing with a phosphorescent dopant and a fluorescence-emitting dopant. A content of the thermally activated delayed fluorescence-emitting dopant material is preferably 0.1% to 50 wt& and more preferably 1% to 30 wt % with respect to the host material.

### —Injection Layer—

The injection layer is a layer that is provided between an electrode and an organic layer in order to lower a driving voltage and improve emission luminance, and includes a hole injection layer and an electron injection layer, and may be present between the anode and the light-emitting layer or the hole transport layer, and between the cathode and the light-emitting layer or the electron transport layer. The injection layer can be provided as necessary.

### —Hole Blocking Layer—

The hole blocking layer has a function of the electron transport layer in a broad sense, and is made of a hole blocking material having a function of transporting electrons and a significantly low ability to transport holes, and can block holes while transporting electrons, thereby improving a probability of recombining electrons and holes in the light-emitting layer.

### —Electron Blocking Layer—

The electron blocking layer has a function of a hole transport layer in a broad sense and blocks electrons while transporting holes, thereby enabling a probability of recombining electrons and holes in the light-emitting layer to be improved.

Regarding the material of the electron blocking layer, a known electron blocking layer material can be used and a material of the hole transport layer to be described below can be used as necessary. A film thickness of the electron blocking layer is preferably 3 to 100 nm, and more preferably 5 to 30 nm.

### —Exciton Blocking Layer—

The exciton blocking layer is a layer for preventing excitons generated by recombination of holes and electrons in the light-emitting layer from being diffused in a charge transport layer, and insertion of this layer allows excitons to be efficiently confined in the light-emitting layer, enabling the luminous efficiency of the device to be improved. The exciton blocking layer can be inserted, in a device having two or more light-emitting layers adjacent to each other, between two adjacent light-emitting layers.

Regarding the material of the exciton blocking layer, a known exciton blocking layer material can be used. Examples thereof include 1,3-dicarbazolyl benzene (mCP) and bis(2-methyl-8-quinolinolato)-4-phenylphenolato aluminum (III) (BAlq).

### —Hole Transport Layer—

The hole transport layer is made of a hole transport material having a function of transporting holes, and the hole transport layer can be provided as a single layer or a plurality of layers.

The hole transport material has either hole injection, transport properties or electron barrier properties, and may be an organic material or an inorganic material. For the hole transport layer, any one selected from conventionally known compounds can be used. Examples of such a hole transport material include porphyrin derivatives, arylamine derivatives, triazole derivatives, oxadiazole derivatives, imidazole derivatives, polyarylalkane derivatives, pyrazoline derivatives and pyrazolone derivatives, phenylenediamine derivatives, arylamine derivatives, amino-substituted chalcone derivatives, oxazole derivatives, styryl anthracene derivatives, fluorenone derivatives, hydrazone derivatives, stilbene derivatives, silazane derivatives, an aniline copolymer, and a conductive polymer oligomer, and particularly a thiophene oligomer. Use of porphyrin derivatives, arylamine derivatives, or styrylamine derivatives is preferred. Use of arylamine derivatives is more preferred.

### —Electron Transport Layer—

The electron transport layer is made of a material having a function of transporting electrons, and the electron transport layer can be provided as a single layer or a plurality of layers.

The electron transport material (which may also serve as a hole blocking material) may have a function of transferring electrons injected from the cathode to the light-emitting layer. For the electron transport layer, any one selected from conventionally known compounds can be used, and examples thereof include polycyclic aromatic derivatives such as naphthalene, anthracene, and phenanthroline, tris(8-quinolinolato)aluminum(III) derivatives, phosphine oxide derivatives, nitro-substituted fluorene derivatives, diphenylquinone derivatives, thiopyran dioxide derivatives, carbodiimide, fluorenylidene methane derivatives, anthraquinodimethane derivatives and anthrone derivatives, bipyridine derivatives, quinoline derivatives, oxadiazole derivatives, benzimidazole derivatives, benzothiazole derivatives, and indolocarbazole derivatives. In addition, a polymer material in which the above material is introduced into a polymer chain or the above material is used for a main chain of a polymer can be used.

The method for producing the organic EL device of the present invention comprises a step of mixing the first host material represented by the general formula (1) and the second host material represented by the general formula (2) in advance, and a step of vapor-depositing the resulting mixture from one vapor deposition source to form a light-emitting layer. Thus, two host materials can be mixed in advance, resulting in an enhancement in performance of an organic EL device.

As the method for premixing, a method by which hosts can be mixed as uniformly as possible is desirable, and examples thereof include, but are not limited to, milling, a method for heating and melting hosts under reduced pressure or under an inert gas atmosphere such as nitrogen, and sublimation. The form of the host and the premixture thereof may be powder, sticks, or granules.

Since the host materials are co-vapor-deposited from one vapor deposition source, the difference in temperature at 50% weight loss of the first host material represented by the general formula (1) and the second host material represented by the general formula (2) in the composition obtained by the above mixing in advance is preferably within 20° C.

The 50% weight reduction temperature is a temperature at which the weight is reduced by 50% when the temperature is raised from room temperature to 550° C. at a rate of 10° C./min in TG-DTA measurement under a nitrogen stream reduced pressure (1 Pa). It is considered that vaporization due to evaporation or sublimation the most vigorously occurs around this temperature.

When a plurality of hosts is used, each host can be deposited from different deposition sources, or a plurality of hosts can be premixed before vapor deposition to form a premixture to thereby simultaneously deposit a plurality of hosts from one deposition source.

As the method for producing the deuterated product represented by the general formula (1) or (2), a production method using a partially or entirely deuterated starting material and a production method by a hydrogen/deuterium exchange reaction are known. The partially or entirely deuterated raw material can be purchased from a commercial supply source or can be produced by a known hydrogen/deuterium exchange reaction. Examples of the known hydrogen/deuterium exchange reaction include a method in which deuterium gas or an equivalent thereof is acted on a non-deuterated product in the presence of a transition metal catalyst, and a method in which a non-deuterated product is treated with a deuteration solvent (such as deuterated benzene) in the presence of an acid catalyst.

### EXAMPLES

Hereafter, the present invention will be described in more detail by referring to Examples, but the present invention is not limited to these Examples and can be implemented in various forms without departing from the gist thereof.

Da in the formula indicates that some or all of hydrogen in the compound are deuterium, for each compound independently.

### Synthesis Example 1

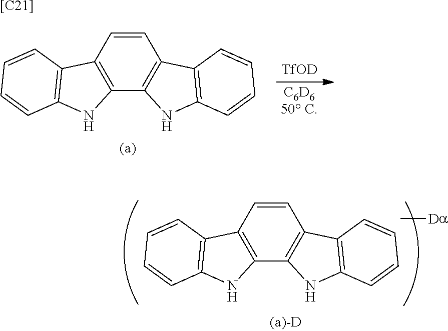

To 6.8 g of compound (a) were added 160 ml of deuterated benzene (C6D6) and 20.0 g of deuterated trifluoromethanesulfonic acid (TfOD), and the mixture was heated and stirred under a nitrogen atmosphere at 50° C. for 4 hours. The reaction liquid was added to a solution of sodium carbonate (14.8 g) in deuterated water (400 ml), and the mixture was rapidly cooled, and subjected to separation and purification to give 6.0 g of compound (a)-D as a deuterated product.

### Synthesis Example 2

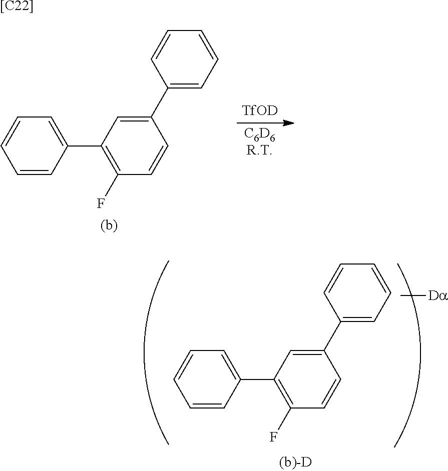

To 15.0 g of compound (b) were added 160 ml of deuterated benzene (C6D6) and 50.0 g of deuterated trifluoromethanesulfonic acid (TfOD), and the mixture was heated and stirred under a nitrogen atmosphere at room temperature (R.T.) for 2 hours. The reaction liquid was added to a solution of sodium carbonate (36.8 g) in deuterated water (800 ml), and the mixture was rapidly cooled, and subjected to separation and purification to give 14.0 g of compound (b)-D as a deuterated product.

### Synthesis Example 3

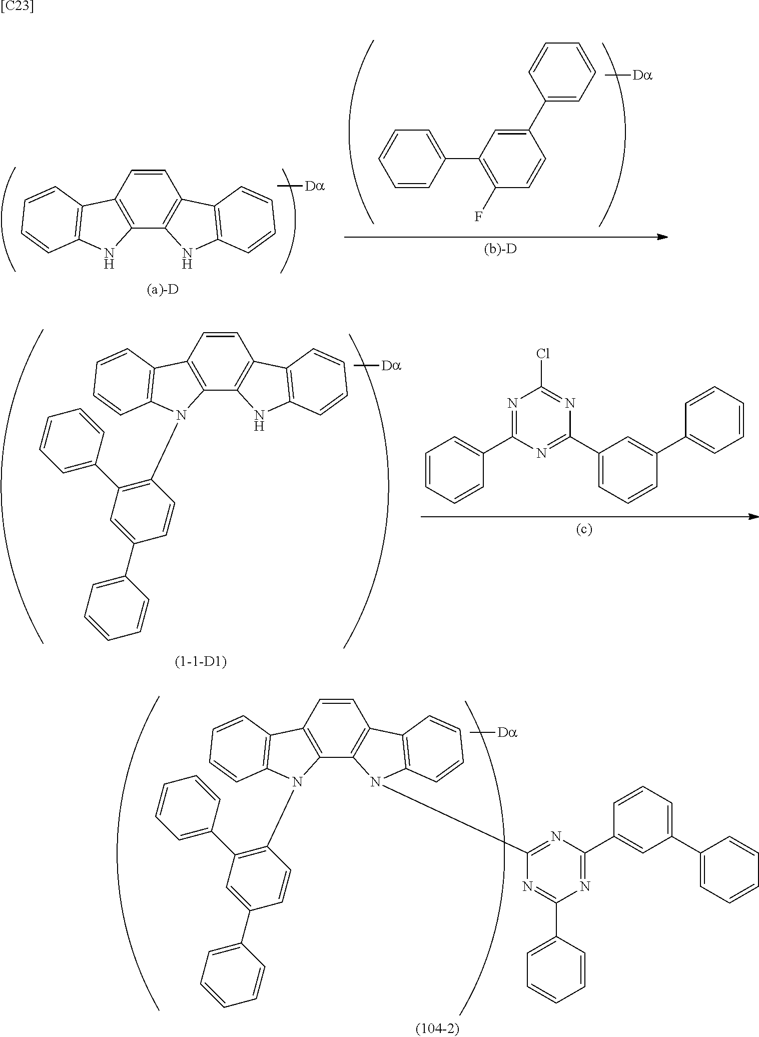

To 5 g of compound (a)-D were added 5.6 g of compound (b)-D, 8.6 g of tripotassium phosphate, and 60 ml of 1,3-dimethyl-2-imidazolidinone, and the mixture was stirred under a nitrogen atmosphere at 200° C. for 48 hours. The mixture was cooled to room temperature, then purified by silica gel column chromatography and crystallization to give 6.6 g (yield 70%) of intermediate (1-1-D1) as a white solid.

Under a nitrogen atmosphere, 1.3 g of 60 wt % sodium hydride was added to 30 ml of N,N′-dimethylacetamide to prepare a suspension. To this was added 6 g of intermediate (1-1-D1) dissolved in 170 mL of N,N′-dimethylacetamide, and the mixture was stirred for 30 minutes. To this was added 5.1 g of compound (c), and the mixture was then stirred for 6 hours. The reaction solution was added to a mixed solution of methanol (300 ml) and distilled water (100 ml) while stirring, and the resulting precipitated solid was collected by filtration. The resulting solid was purified by silica gel column chromatography and crystallization to give 6.5 g (yield 66%) of compound 104-2 as a yellow solid.

The rate of deuteration of compound 104-2 was determined by proton nuclear magnetic resonance spectroscopy. A measurement sample was prepared by dissolving compound 104-2 (5.0 mg) and dimethylsulfone (2.0 mg) as an internal standard material in deuterated tetrahydrofuran (1.0 ml). The average proton concentration [mol/g] in compound 104-2 included in the measurement sample was calculated from the ratio between the respective integral intensities derived from the internal standard material and compound 104-2. The average proton concentration [mol/g] in a non-deuterated product (corresponding to comparative example compound C) of compound 104-2 was also calculated in the same manner. Next, the ratio between the proton concentration in compound 104-2 and the proton concentration in comparative example compound C was calculated, and subtracted from 1, and thus the average rate of deuteration of compound 104-2 was calculated.

### Synthesis Example 4

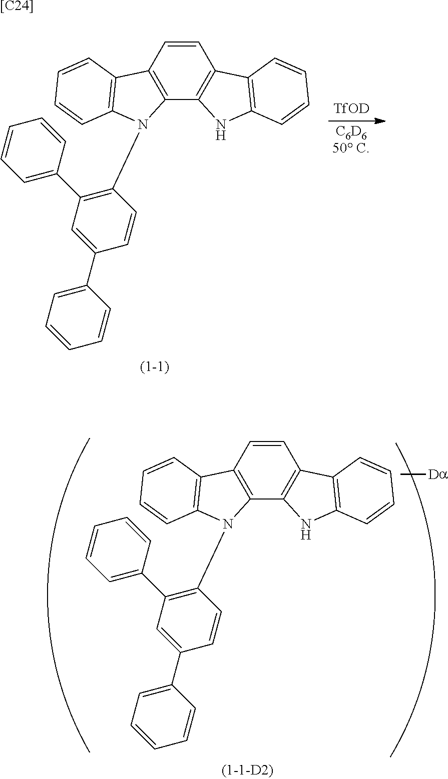

To 6.6 g of compound (1-1) were added 160 ml of deuterated benzene (C6D6) and 10.0 g of deuterated trifluoromethanesulfonic acid (TEOD), and the mixture was heated and stirred under a nitrogen atmosphere at 50° C. for 4 hours. The reaction liquid was added to a solution of sodium carbonate (8.0 g) in deuterated water (100 ml), and the mixture was rapidly cooled, and subjected to separation and purification to give 5.4 g of compound (1-1-D2) as a deuterated product.

### Synthesis Example 5

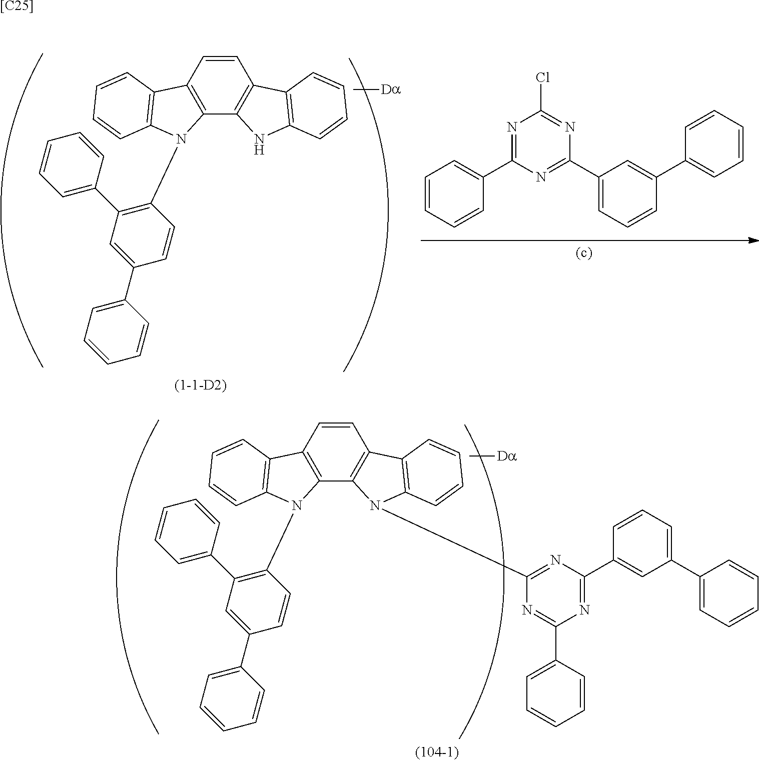

Under a nitrogen atmosphere, 1.3 g of 60 wt % sodium hydride was added to 30 ml of N,N′-dimethylacetamide to prepare a suspension. To this was added 5.0 g of intermediate (1-1-D2) dissolved in 170 mL of N,N′-dimethylacetamide, and the mixture was stirred for 30 minutes. To this was added 4.3 g of compound (c), and the mixture was then stirred for 6 hours. The reaction solution was added to a mixed solution of methanol (300 ml) and distilled water (100 ml) while stirring, and the resulting precipitated solid was collected by filtration. The resulting solid was purified by silica gel column chromatography and crystallization to give 5.8 g (yield 71%) of compound 104-1 as a yellow solid.

Reaction was performed in the same manner as in Synthesis Examples 1 to 5 to synthesize compounds 101-2, 102-2, 101-3, 107-2, 108-1, 108-2, 115-2, 116-2, 117-2, 1451-2, 119-2, 106-2, 106-3, 1642-2, 1642-3, 1665-2, 1665-3, 1639-2, 1673-2, 120-2, 149-2, 172-2, and 1524-2 being deuterated products. The rates of deuteration of 101-2, 102-2, 101-3, 104-1, 107-2, 108-1, 108-2, 115-2, 116-2, 117-2, 1451-2, 119-2, 106-2, 106-3, 1642-2, 1642-3, 1665-2, 1665-3, 1639-2, 1673-2, 120-2, 149-2, 172-2, and 1524-2 were calculated in the same manner as 104-2. The rates of deuteration of the partial structure of the indolocarbazole (ICZ) backbone and R¹ as the substituent thereof as well as the partial structure of Ar¹ and Ar² in the general formula (1), and the partial structure of Ar³ can be calculated from the integral intensity of the chemical shift derived from an objective partial structure, according to the same procedure. In the following Table 1, the number of hydrogen before deuteration represents the number of total hydrogen contained in each partial structure or the whole compound, in each compound, and the average rate of deuteration represents the proportion of deuterated hydrogen. For example, compound 101-2 and 101-3 represent compounds having the same structure with each other but a different rate of deuteration.

TABLE 1

| | | | Partial structure | | | | | |
|---|---|---|---|---|---|---|---|---|
| | | | of ICZ backbone | | | | | |
| | | | and R¹ as substituent | | Partial structure | | Partial structure | |
| | Whole | | thereof | | of Ar³ | | of Ar¹ + Ar² | |
| | | Number of | | Number of | | Number of | | deuteration |
| | Average | hydrogen | Average | hydrogen | Average | hydrogen | rate of | Number of |
| | rate of | before | rate of | before | rate of | before | Average | hydrogen |
| Compound | deuteration | deuteration | deuteration | deuteration | deuteration | deuteration | deuteration | before |
| 101-2 | 52% | 33 | 93% | 10 | 87% | 9 | 0% | 14 |
| 102-2 | 53% | 33 | 93% | 10 | 90% | 9 | 0% | 14 |
| 101-3 | 91% | 33 | 93% | 10 | 87% | 9 | 91% | 14 |
| 104-1 | 49% | 37 | 83% | 10 | 77% | 13 | 0% | 14 |
| 104-2 | 54% | 37 | 93% | 10 | 83% | 13 | 0% | 14 |
| 107-2 | 54% | 37 | 93% | 10 | 82% | 13 | 0% | 14 |
| 108-1 | 40% | 29 | 81% | 10 | 72% | 5 | 0% | 14 |
| 108-2 | 48% | 29 | 93% | 10 | 95% | 5 | 0% | 14 |
| 115-2 | 53% | 33 | 91% | 14 | 95% | 5 | 0% | 14 |
| 116-2 | 57% | 37 | 91% | 18 | 95% | 5 | 0% | 14 |
| 117-2 | 58% | 37 | 92% | 18 | 95% | 5 | 0% | 14 |
| 1451-2 | 53% | 33 | 90% | 14 | 95% | 5 | 0% | 14 |
| 119-2 | 58% | 40 | 88% | 21 | 95% | 5 | 0% | 14 |
| 106-2 | 54% | 37 | 93% | 10 | 83% | 13 | 0% | 14 |
| 106-3 | 89% | 37 | 93% | 10 | 83% | 13 | 91% | 14 |
| 1642-2 | 64% | 37 | 93% | 10 | 85% | 17 | 0% | 10 |
| 1642-3 | 90% | 37 | 93% | 10 | 85% | 17 | 95% | 10 |
| 1665-2 | 63% | 37 | 93% | 10 | 82% | 17 | 0% | 10 |
| 1665-3 | 89% | 37 | 93% | 10 | 82% | 17 | 95% | 10 |
| 1639-2 | 58% | 41 | 93% | 10 | 85% | 17 | 0% | 14 |
| 1673-2 | 63% | 37 | 93% | 10 | 83% | 17 | 0% | 10 |
| 120-2 | 53% | 33 | 91% | 14 | 95% | 5 | 0% | 14 |
| 149-2 | 56% | 37 | 91% | 14 | 87% | 9 | 0% | 14 |
| 172-2 | 64% | 37 | 91% | 14 | 85% | 13 | 0% | 10 |
| 1524-2 | 63% | 37 | 90% | 14 | 83% | 13 | 0% | 10 |

### Synthesis Example 7

Compound (2) was synthesized according to the following reaction.

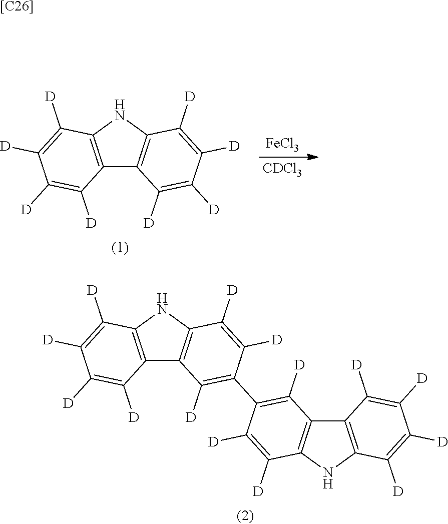

To compound (1) (10.0 g) were added 150 ml of deuterated chloroform (CDCl3) and 30.5 g of iron (III) chloride, and the mixture was stirred under a nitrogen atmosphere at room temperature for 12 hours. To the reaction liquid was added 300 g of methanol for dilution, and the mixture was subjected to separation and purification to give 2.9 g of white solid compound (2) as a deuterated product.

### Synthesis Example 8

Compound (3) was synthesized according to the following reaction. Compound (2) shows an example of a structural formula in the case where the rate of deuteration of the hydrogen on two carbazole rings is 100%, and the same applies to compound (3).

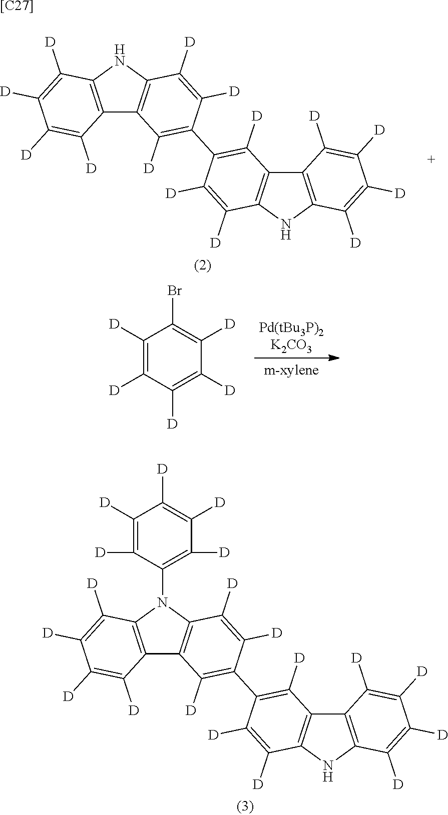

To compound (2) (3.5 g) were added 1.9 g of bromobenzene-d5, 300 ml of m-xylene, 0.3 g of bis(tri-tert-butylphosphine) palladium, and 7.0 g of potassium carbonate, and the mixture was stirred under a nitrogen atmosphere with heating and reflux for 5 hours. The reaction liquid was cooled, and then subjected to separation and purification to give 2.0 g of white solid compound (3) as a deuterated product.

### Synthesis Example 9

Compound 202-2 was synthesized according to the following reaction. Compound 202-2 shows an example of a structural formula in the case where the rate of deuteration of the hydrogen on two carbazole rings and the hydrogen in the biphenyl group on N of biscarbazole is 100%.

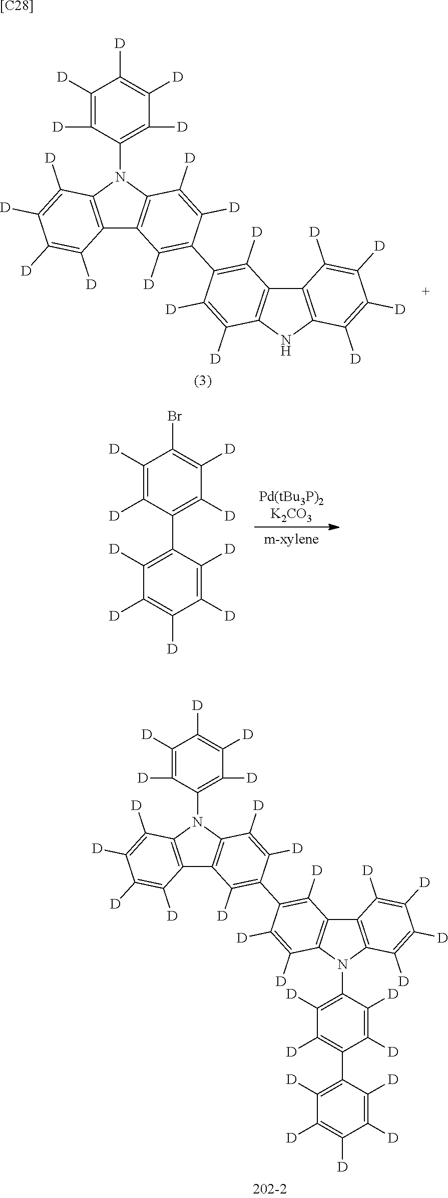

To compound (3) (3.0 g) were added 2.1 g of deuterated p-bromobiphenyl, 100 ml of m-xylene, 0.2 g of bis(tri-tert-butylphosphine) palladium, and 4.9 g of potassium carbonate, and the mixture was stirred under a nitrogen atmosphere with heating and reflux for 5 hours. The reaction liquid was cooled, and then subjected to separation and purification to give 1.4 g of white solid compound 202-2 as a deuterated product.

### Synthesis Example 10

Compound 202-1 was synthesized according to the following reaction.

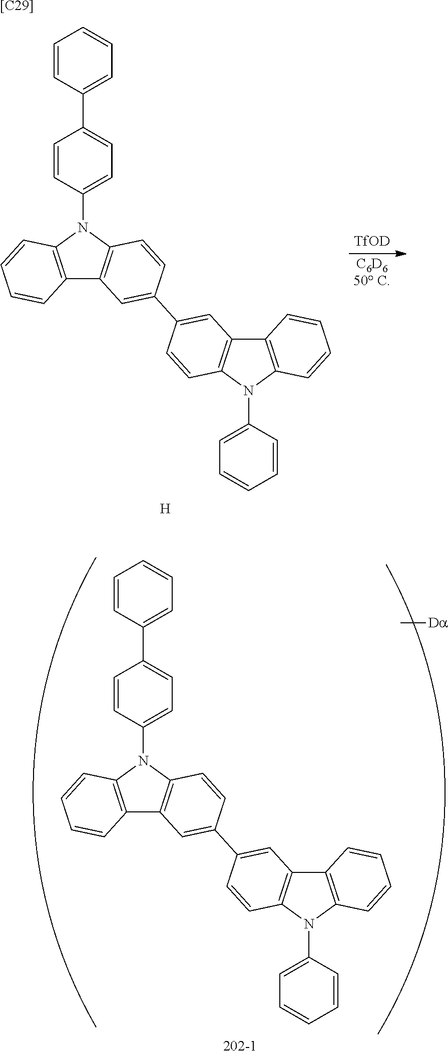

To 8.3 g of comparative compound H were added 160 ml of deuterated benzene (C6D6) and 10.0 g of deuterated trifluoromethanesulfonic acid (TEOD), and the mixture was heated and stirred under a nitrogen atmosphere at 50° C. for 6.5 hours. The reaction liquid was added to a solution of sodium carbonate (7.4 g) in deuterated water (200 ml), and the mixture was rapidly cooled, and subjected to separation and purification to give 2.5 g of white solid compound 202-1 as a deuterated product.

### Synthesis Example 11

Compound (5) was synthesized according to the following reaction.

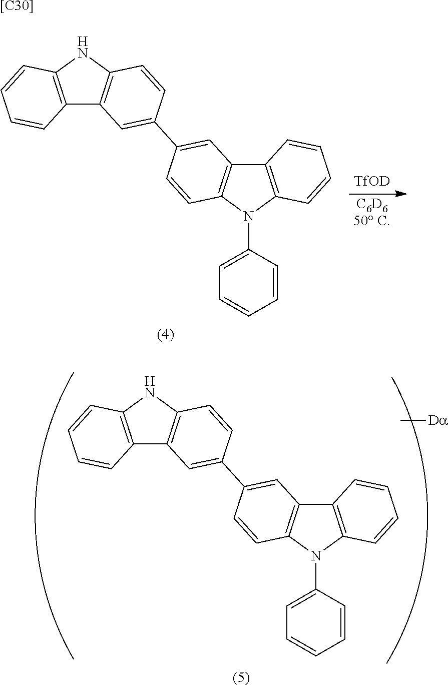

To 10.0 g of compound (4) were added 240 ml of deuterated benzene (C6D6) and 18.4 g of deuterated trifluoromethanesulfonic acid (TfOD), and the mixture was heated and stirred under a nitrogen atmosphere at 50° C. for 5.0 hours. The reaction liquid was added to a solution of sodium carbonate (14.3 g) in deuterated water (150 ml), and the mixture was rapidly cooled, and subjected to separation and purification to give 8.9 g of compound (5) as a deuterated product.

### Synthesis Example 12

Compound 202-3 was synthesized according to the following reaction.

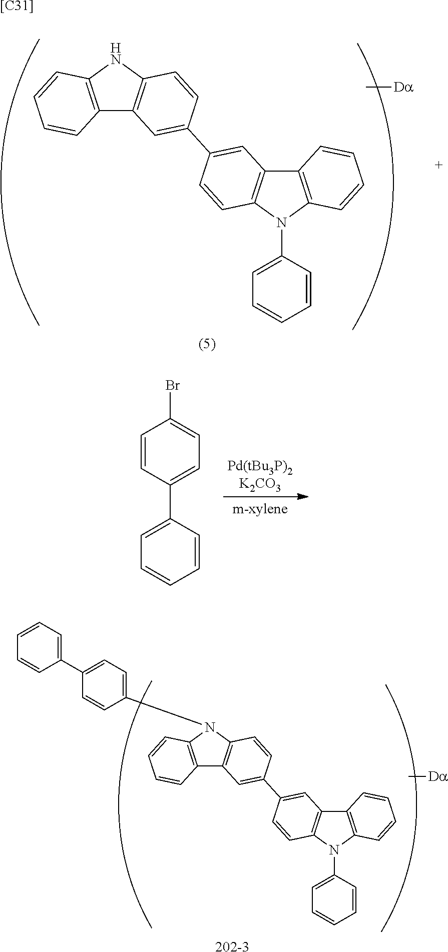

To compound (5) (5.0 g) were added 4.3 g of p-bromobiphenyl, 100 ml of m-xylene, 0.4 g of bis(tri-tert-butylphosphine) palladium, and 5.0 g of potassium carbonate, and the mixture was stirred under a nitrogen atmosphere with heating and reflux for 5 hours. The reaction mixture was cooled, and then subjected to separation and purification to give 2.7 g of white solid compound 202-3 as a deuterated product.

### Synthesis Example 13

Reaction was performed in the same manner as in Synthesis Examples 7 to 10 to synthesize compounds 205-1, 205-2, and 208-2 being deuterated products. In addition, the average rates of deuteration of the partial structure of the biscarbazole backbone and R² as the substituent thereof as well as the partial structure of Ar⁵ and Ar⁶ shown below, and the average rate of deuteration of the whole compound were calculated in the same manner as 104-2.

TABLE 2

| | | | Partial structure of | | | |
|---|---|---|---|---|---|---|
| | | | biscarbazole backbone | | | |
| | | | and R² as substituent | | Partial structure of | |
| | Whole | | thereof | | Ar⁵ + Ar⁶ | |
| | | before | | Number of | | before |
| | Average | Number of | Average | hydrogen | Average | Number of |
| | rate of | hydrogen | rate of | before | rate of | hydrogen |
| Compound | deuteration | deuteration | deuteration | deuteration | deuteration | deuteration |
| 202-1 | 81% | 28 | 96% | 14 | 66% | 14 |
| 202-2 | 92% | 28 | 96% | 14 | 89% | 14 |
| 202-3 | 65% | 28 | 87% | 14 | 43% | 14 |
| 205-1 | 76% | 32 | 96% | 14 | 60% | 18 |
| 205-2 | 90% | 32 | 96% | 14 | 85% | 18 |
| 208-2 | 93% | 32 | 96% | 14 | 90% | 18 |

The compounds used in Examples and Comparative Examples are shown below.

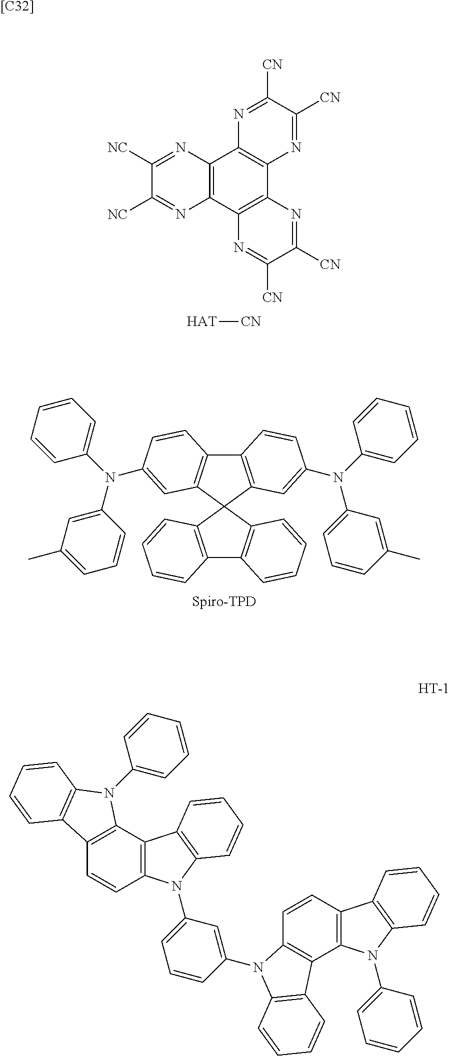

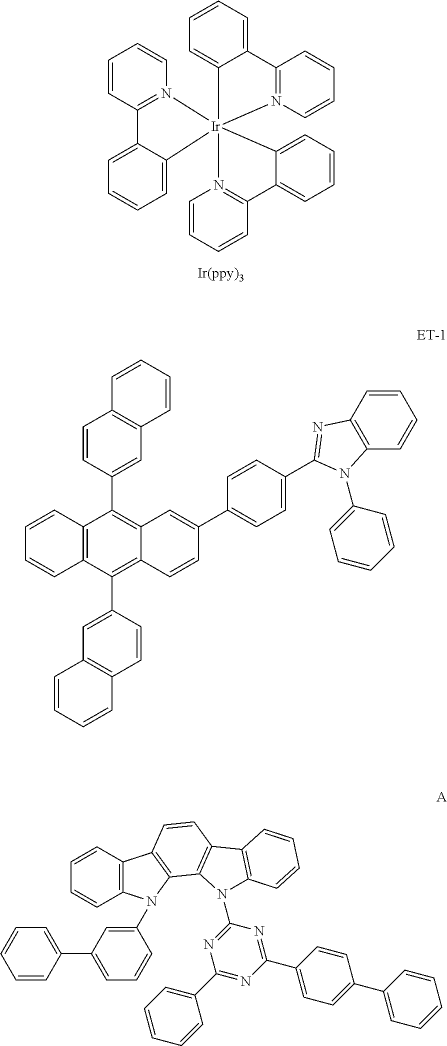

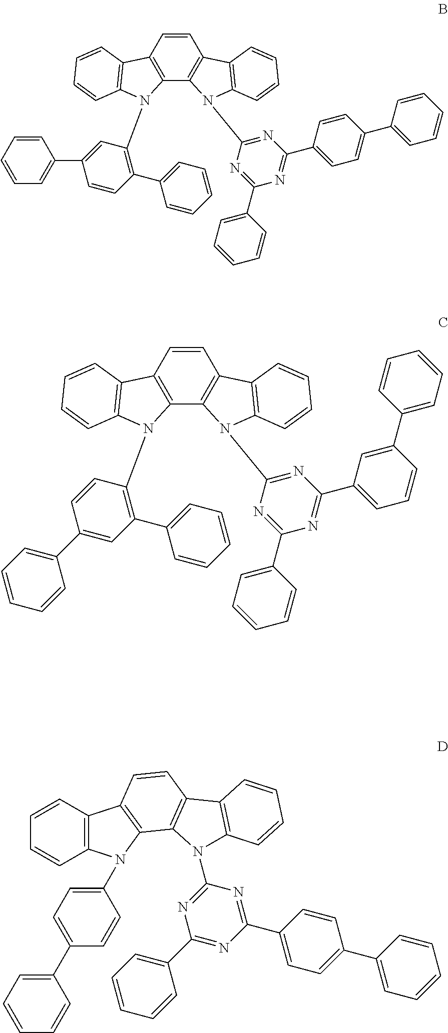 [SMILES: c1ccc(-c2ccc(-c3nc(-c4ccccc4)nc(-n4c5ccccc5c5ccc6c7ccccc7n(-c7cc(-c8ccccc8)ccc7-c7ccccc7)c6c54)n3)cc2)cc1 ; c1ccc(-c2cccc(-c3nc(-c4ccccc4)nc(-n4c5ccccc5c5ccc6c7ccccc7n(-c7ccc(-c8ccccc8)cc7-c7ccccc7)c6c54)n3)c2)cc1 ; c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1]

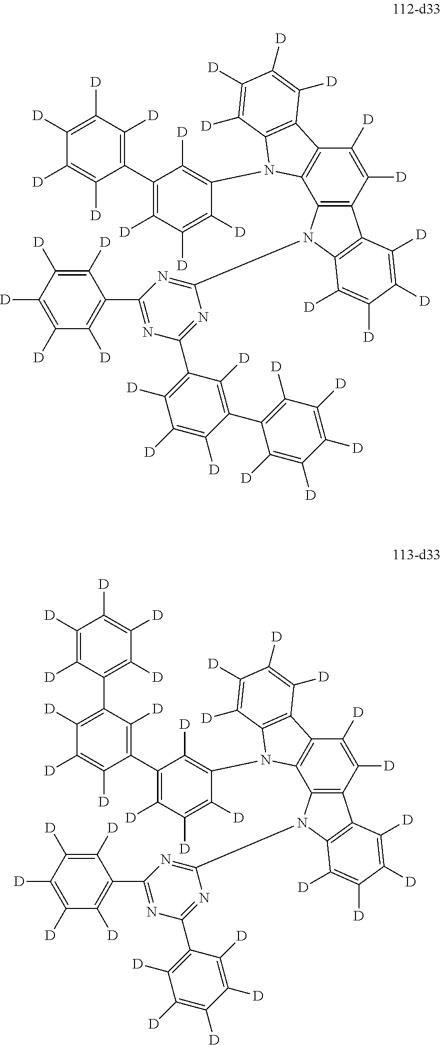

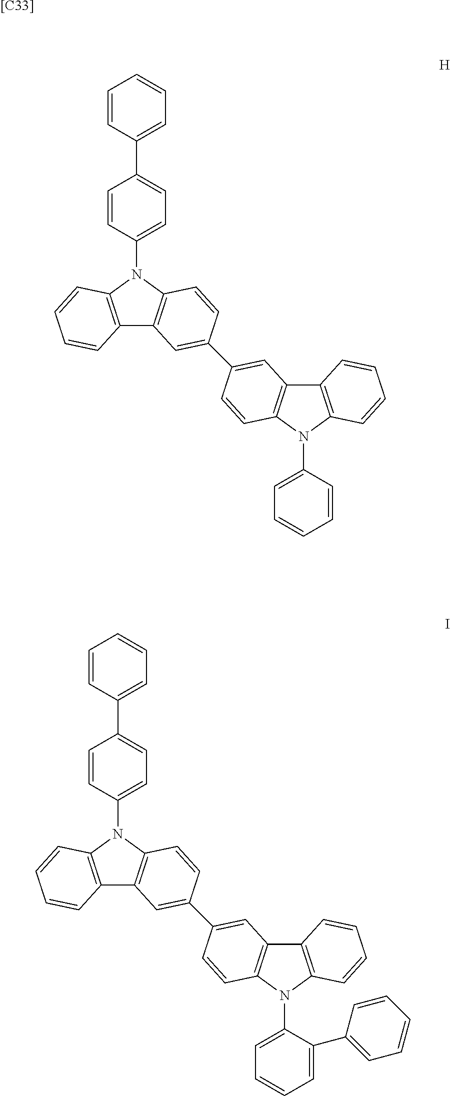

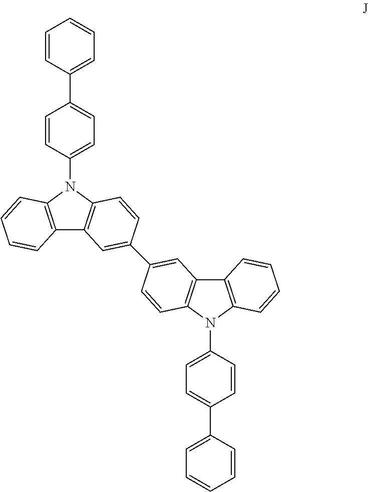 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

### Example 1

On a glass substrate on which an anode made of ITO with a film thickness of 110 nm was formed, respective thin films were laminated by a vacuum evaporation method at a degree of vacuum of 4.0×10⁻⁵ Pa. First, HAT-CN was formed with a thickness of 25 nm as a hole injection layer on ITO, and next, Spiro-TPD was formed with a thickness of 30 nm as a hole transport layer. Next, HT-1 was formed with a thickness of 10 nm as an electron blocking layer. Then, compound 108-1 as a first host, compound 202-1 as a second host, and Ir(ppy)₃ as a light-emitting dopant were co-vapor-deposited from different vapor deposition sources, respectively, to form a light-emitting layer with a thickness of 40 nm. In this case, co-vapor deposition was performed under vapor deposition conditions such that the concentration of Ir(ppy)₃ was 10 wt %, and the weight ratio between the first host and the second host was 30:70. Next, ET-1 was formed with a thickness of 20 nm as an electron transport layer. Further, LiF was formed with a thickness of 1 nm as an electron injection layer on the electron transport layer. Finally, Al was formed with a thickness of 70 nm as a cathode on the electron injection layer to produce an organic EL device.

### Examples 2 to 25, 31 to 47

Organic EL devices were produced in the same manner as in Example 1 except that compounds shown in Table 3 were used as the first host and the second host and the weight ratio was as shown in Table 3.

### Examples 26 to 30, 48 to 59

Organic EL devices were produced in the same manner as in Example 1 except that a premixture obtained by weighing a first host and a second host shown in Table 3 at a weight ratio shown in Table 3 and mixing them while grinding in a mortar was vapor-deposited from one vapor deposition source.

### Comparative Examples 1 to 9

Organic EL devices were produced in the same manner as in Example 1 except that compounds shown in Table 3 were used as the first host and the second host and the weight ratio was as shown in Table 3.

### Comparative Examples 10 to 13

Organic EL devices were produced in the same manner as in Example 1 except that a premixture obtained by weighing a first host and a second host shown in Table 3 at a weight ratio shown in Table 3 and mixing them while grinding in a mortar was vapor-deposited from one vapor deposition source.

Evaluation results of the produced organic EL devices are shown in Table 3. In the table, the luminance, voltage, and power efficiency are values at a driving current of 10 mA/cm², and they exhibit initial characteristics. LT97 is a time period needed for the luminance to be reduced to 97% of the initial luminance that is assumed to be 100% at a driving current of 20 mA/cm2, and it represents lifetime characteristics. The weight ratio corresponds to first host: second host.

TABLE 3-1

| | | | | | | Power | |
|---|---|---|---|---|---|---|---|
| | First | Second | Weight | Voltage | Luminance | efficiency | LT97 |
| | host | host | ratio | [V] | [cd/m²] | [lm/W] | [h] |
| Example 1 | 108-1 | 202-1 | 30:70 | 3.7 | 7500 | 63.3 | 470 |
| Example 2 | 108-1 | 202-2 | 30:70 | 3.7 | 7500 | 63.1 | 520 |
| Example 3 | 108-2 | 202-1 | 30:70 | 3.7 | 7500 | 63.1 | 540 |
| Example 4 | 108-2 | 202-2 | 30:70 | 3.7 | 7500 | 63.0 | 590 |
| Example 5 | 108-2 | 202-3 | 30:70 | 3.7 | 7500 | 63.5 | 510 |
| Example 6 | 101-2 | 202-2 | 30:70 | 3.8 | 7500 | 62.0 | 610 |
| Example 7 | 101-2 | 202-3 | 30:70 | 3.8 | 7500 | 61.6 | 520 |
| Example 8 | 107-2 | 202-2 | 30:70 | 3.9 | 7500 | 61.0 | 560 |
| Example 9 | 107-2 | 202-3 | 30:70 | 3.9 | 7500 | 60.9 | 480 |
| Example 10 | 104-1 | 202-2 | 30:70 | 3.9 | 7600 | 60.6 | 410 |
| Example 11 | 104-2 | 202-2 | 30:70 | 3.9 | 7600 | 60.6 | 470 |
| Example 12 | 102-2 | 202-2 | 30:70 | 3.8 | 7500 | 61.8 | 610 |
| Example 13 | 102-2 | 202-3 | 30:70 | 3.8 | 7500 | 61.6 | 520 |
| Example 14 | 101-2 | 208-2 | 30:70 | 3.8 | 7500 | 62.6 | 380 |
| Example 15 | 107-2 | 208-2 | 30:70 | 3.8 | 7500 | 61.6 | 350 |
| Example 16 | 104-2 | 208-2 | 30:70 | 3.9 | 7600 | 61.2 | 290 |
| Example 17 | 102-2 | 208-2 | 30:70 | 3.8 | 7500 | 62.4 | 380 |
| Example 18 | 108-1 | 205-1 | 30:70 | 3.6 | 7400 | 65.3 | 430 |
| Example 19 | 108-1 | 205-2 | 30:70 | 3.6 | 7400 | 65.1 | 520 |
| Example 20 | 108-2 | 205-1 | 30:70 | 3.6 | 7400 | 65.1 | 490 |
| Example 21 | 108-2 | 205-2 | 30:70 | 3.6 | 7400 | 64.9 | 590 |
| Example 22 | 101-2 | 205-2 | 30:70 | 3.6 | 7400 | 63.9 | 610 |
| Example 23 | 107-2 | 205-2 | 30:70 | 3.7 | 7400 | 62.9 | 560 |
| Example 24 | 104-2 | 205-2 | 30:70 | 3.8 | 7500 | 62.4 | 470 |
| Example 25 | 102-2 | 205-2 | 30:70 | 3.7 | 7400 | 63.7 | 610 |
| Example 26 | 101-2 | 202-2 | 30:70 | 3.8 | 7600 | 63.2 | 620 |
| Example 27 | 101-2 | 202-2 | 50:50 | 3.2 | 7600 | 74.1 | 400 |
| Example 28 | 104-2 | 202-2 | 30:70 | 3.9 | 7700 | 61.8 | 480 |
| Example 29 | 102-2 | 208-2 | 30:70 | 3.7 | 7600 | 63.7 | 380 |
| Example 30 | 101-3 | 202-2 | 30:70 | 3.8 | 7600 | 63.1 | 730 |
| Example 31 | 115-2 | 202-2 | 30:70 | 3.9 | 7800 | 63.7 | 700 |
| Example 32 | 116-2 | 202-2 | 30:70 | 3.9 | 7800 | 62.1 | 650 |
| Example 33 | 117-2 | 202-2 | 30:70 | 3.9 | 8000 | 64.5 | 530 |
| Example 34 | 1451-2 | 202-2 | 30:70 | 3.9 | 7400 | 60.6 | 610 |
| Example 35 | 119-2 | 202-2 | 30:70 | 3.9 | 7700 | 61.1 | 510 |
| Example 36 | 106-2 | 208-2 | 30:70 | 3.8 | 7800 | 63.7 | 370 |
| Example 37 | 106-3 | 208-2 | 30:70 | 3.8 | 8000 | 65.8 | 390 |
| Example 38 | 1642-2 | 202-2 | 30:70 | 4.0 | 7800 | 61.8 | 550 |
| Example 39 | 1642-3 | 202-2 | 30:70 | 4.0 | 8100 | 63.7 | 530 |
| Example 40 | 1665-2 | 202-2 | 30:70 | 4.0 | 7600 | 60.6 | 580 |
| Example 41 | 1665-3 | 202-2 | 30:70 | 4.0 | 7600 | 60.0 | 520 |
| Example 42 | 1639-2 | 205-2 | 30:70 | 3.7 | 7600 | 63.9 | 590 |
| Example 43 | 1673-2 | 202-2 | 30:70 | 4.0 | 8100 | 63.7 | 450 |
| Example 44 | 120-2 | 202-2 | 30:70 | 4.0 | 8300 | 65.4 | 510 |
| Example 45 | 149-2 | 208-2 | 30:70 | 3.8 | 7600 | 62.3 | 390 |

TABLE 3-2

| | | | | | | Power | |
|---|---|---|---|---|---|---|---|
| | First | Second | Weight | Voltage | Luminance | efficiency | LT97 |
| | host | host | ratio | [V] | [cd/m²] | [lm/W] | [h] |
| Example 46 | 172-2 | 202-2 | 30:70 | 5.0 | 7600 | 48.2 | 500 |
| Example 47 | 1524-2 | 202-2 | 30:70 | 4.0 | 8100 | 63.5 | 550 |
| Example 48 | 106-2 | 208-2 | 30:70 | 3.8 | 7800 | 63.9 | 380 |
| Example 49 | 106-3 | 208-2 | 30:70 | 3.8 | 8000 | 66.0 | 400 |
| Example 50 | 1642-2 | 202-2 | 30:70 | 4.0 | 7800 | 62.2 | 570 |
| Example 51 | 1642-3 | 202-2 | 30:70 | 4.0 | 8100 | 64.1 | 550 |
| Example 52 | 1665-2 | 202-2 | 30:70 | 4.0 | 7700 | 61.3 | 600 |
| Example 53 | 1665-3 | 202-2 | 30:70 | 4.0 | 7800 | 61.2 | 540 |
| Example 54 | 1639-2 | 205-2 | 30:70 | 3.7 | 7900 | 66.0 | 620 |
| Example 55 | 1673-2 | 202-2 | 30:70 | 4.0 | 8100 | 64.1 | 470 |
| Example 56 | 120-2 | 202-2 | 30:70 | 4.0 | 8300 | 65.6 | 530 |
| Example 57 | 149-2 | 208-2 | 30:70 | 3.8 | 7700 | 62.6 | 400 |
| Example 58 | 172-2 | 202-2 | 30:70 | 5.0 | 7700 | 48.7 | 510 |
| Example 59 | 1524-2 | 202-2 | 30:70 | 4.0 | 8200 | 64.1 | 560 |
| Comparative | A | H | 30:70 | 3.8 | 7500 | 61.5 | 300 |
| Example 1 | | | | | | | |
| Comparative | B | H | 30:70 | 3.9 | 7500 | 61.0 | 280 |
| Example 2 | | | | | | | |
| Comparative | C | H | 30:70 | 3.9 | 7600 | 60.6 | 230 |
| Example 3 | | | | | | | |
| Comparative | D | I | 30:70 | 3.8 | 7500 | 62.6 | 170 |
| Example 4 | | | | | | | |
| Comparative | C | 202-2 | 30:70 | 3.9 | 7600 | 60.6 | 300 |
| Example 5 | | | | | | | |
| Comparative | 112-d33 | H | 30:70 | 3.7 | 7900 | 67.0 | 280 |
| Example 6 | | | | | | | |
| Comparative | 112-d33 | J | 30:70 | 3.5 | 7700 | 69.3 | 200 |
| Example 7 | | | | | | | |
| Comparative | 113-d33 | H | 30:70 | 3.7 | 8000 | 67.9 | 250 |
| Example 8 | | | | | | | |
| Comparative | 113-d33 | J | 30:70 | 3.6 | 7900 | 70.0 | 230 |
| Example 9 | | | | | | | |
| Comparative | 104-2 | H | 30:70 | 3.9 | 7700 | 61.8 | 300 |
| Example 10 | | | | | | | |
| Comparative | 104-2 | H | 50:50 | 3.3 | 7700 | 72.4 | 200 |
| Example 11 | | | | | | | |
| Comparative | 102-2 | I | 30:70 | 3.7 | 7600 | 63.7 | 260 |
| Example 12 | | | | | | | |
| Comparative | 102-2 | I | 50:50 | 3.2 | 7600 | 74.6 | 180 |
| Example 13 | | | | | | | |

From the results in Table 3-1 and Table 3-2, it is understood that Examples 1 to 59 exhibited extended lifetime characteristics as compared with Comparative Examples.

Table 4 shows the temperature at 50% weight loss (T50) of compounds used in Examples and Comparative Examples.

TABLE 4

| Compound | T50[° C.] |
|---|---|
| 101-2 | 279 |
| 101-3 | 281 |
| 104-2 | 280 |
| 102-2 | 288 |
| 106-2 | 290 |
| 106-3 | 290 |
| 1642-2 | 274 |
| 1642-3 | 276 |
| 1665-2 | 277 |
| 1665-3 | 277 |
| 1639-2 | 315 |
| 1673-2 | 279 |
| 120-2 | 274 |
| 149-2 | 293 |
| 172-2 | 279 |
| 1524-2 | 278 |
| 202-2 | 283 |
| 208-2 | 292 |
| 205-2 | 317 |
| H | 283 |
| I | 292 |

### INDUSTRIAL APPLICABILITY

According to the present invention, a first host that has indolocarbazole, a nitrogen-containing six-membered ring, and a phenyl group or a biphenyl group and is further substituted with deuterium, and a biscarbazole compound substituted with deuterium as a second host can be mixed and used to thereby obtain an organic EL device having a low voltage, high efficiency and extended lifetime. In addition, the first host and the second host are mixed to give a premixture, and then a host material containing the premixture is used to thereby obtain an organic EL device having high luminance, high efficiency, and extended lifetime.

### REFERENCE SIGNS LIST

1 substrate, 2 anode, 3 hole injection layer, 4 hole transport layer, 5 light-emitting layer, 6 electron transport layer, 7 cathode

1. An organic electroluminescent device comprising one or more light emitting layers between an anode and a cathode opposed to each other, wherein at least one of the light emitting layers contains a first host selected from a compound represented by the following general formula (1), a second host selected from a compound represented by the following general formula (2), and a light emitting dopant material, 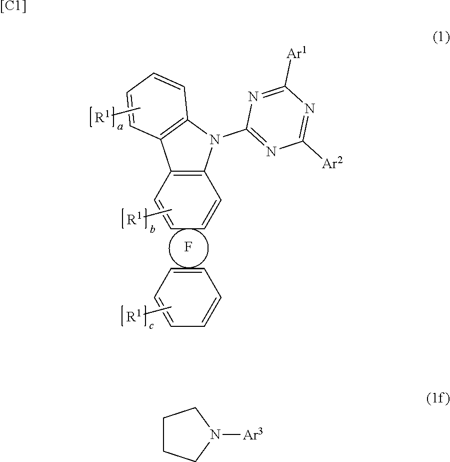
wherein ring F represents a heterocyclic ring represented by a formula (1f) fused with two adjacent benzene rings at any positions; Ar¹ and Ar² each independently represent a deuterium-containing substituted or unsubstituted phenyl group or a deuterium-containing substituted or unsubstituted biphenyl group; Ar³ represents a deuterium-containing substituted or unsubstituted aromatic hydrocarbon group having 6 to 30 carbon atoms, a deuterium-containing substituted or unsubstituted aromatic heterocyclic group having 3 to 17 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; each R¹ independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; a to c represent the number of substitutions, a and c represent an integer of 0 to 4, and b represents an integer of 0 to 2; provided that at least one R¹ represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and an average rate of deuteration of the total hydrogen contained in an indolocarbazole backbone and R¹ as a substituent thereof is 50% or more; some or all of hydrogen contained in Ar³ are replaced by deuterium, and an average rate of deuteration of the total hydrogen contained in Ar³ is 50% or more, 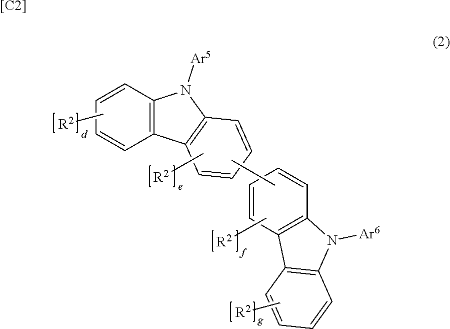
wherein Ar⁵ and Ar⁶ each independently represent a deuterium-containing substituted or unsubstituted aromatic hydrocarbon group having 6 to 30 carbon atoms or a deuterium-containing substituted or unsubstituted linked aromatic group in which two to five of these aromatic groups are linked to each other, and the aromatic hydrocarbon groups when being linked are the same as or different from each other; each R² independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; d to g represent the number of substitutions, d and g represent an integer of 0 to 4, and e and f represent an integer of 0 to 3; provided that at least one R² represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and an average rate of deuteration of the total hydrogen contained in a biscarbazole backbone and R² as a substituent thereof is 50% or more, and some or all of hydrogen contained in Ar⁵ and Ar⁶ are replaced by deuterium, and an average rate of deuteration of the total hydrogen contained in Ar⁵ and Ar⁶ is 30% or more.

2. The organic electroluminescent device according to claim 1, wherein, in the general formula (1), Ar³ represents a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted quaterphenyl group, a deuterium-containing substituted or unsubstituted dibenzofuranyl group, or a deuterium-containing substituted or unsubstituted dibenzothiophenyl group.

3. The organic electroluminescent device according to claim 1, wherein, in the general formula (1), Ar³ represents a deuterium-containing substituted or unsubstituted phenyl group, a deuterium-containing substituted or unsubstituted biphenyl group, a deuterium-containing substituted or unsubstituted terphenyl group, or a deuterium-containing substituted or unsubstituted quaterphenyl group.

4. The organic electroluminescent device according to claim 1, wherein, in the general formula (1), the average rate of deuteration of the total hydrogen contained in Ar³ is 70% or more.

5. The organic electroluminescent device according to claim 1, wherein, in the general formula (1), R¹ represents deuterium.

6. The organic electroluminescent device according to claim 1 wherein, in the general formula (2), Ar⁵ and Ar⁶ represent a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted dibenzofuranyl group, or a deuterium-containing substituted or unsubstituted dibenzothiophenyl group.

7. The organic electroluminescent device according to claim 1, wherein, in the general formula (2), Ar⁵ and Ar⁶ represent a deuterium-containing substituted or unsubstituted phenyl group or a deuterium-containing substituted or unsubstituted biphenyl group.

8. The organic electroluminescent device according to claim 1, wherein, in the general formula (2), the average rate of deuteration of the total hydrogen on Ar⁵ and Ar⁶ is 50% or more.

9. The organic electroluminescent device according to claim 1, wherein, in the general formula (2), R² represents deuterium.

10. The organic electroluminescent device according to claim 1, wherein a proportion of the first host to the first host and the second host in total is 10 wt % or more and less than 80 wt %.

11. The organic electroluminescent device according to claim 1, wherein the light emitting dopant material is an organic metal complex containing at least one metal selected from the group consisting of ruthenium, rhodium, palladium, silver, rhenium, osmium, iridium, platinum and gold.

12. The organic electroluminescent device according to claim 1, wherein the light emitting dopant material is a thermally activated delayed fluorescence-emitting dopant material.

13. A premixture comprising a first host and a second host to be used for forming, in an organic electroluminescent device comprising a light-emitting layer containing hosts and a light-emitting dopant material between an anode and a cathode opposed to each other, the light-emitting layer, wherein the first host is selected from a compound represented by the following general formula (1) and the second host is selected from a compound represented by the following general formula (2): 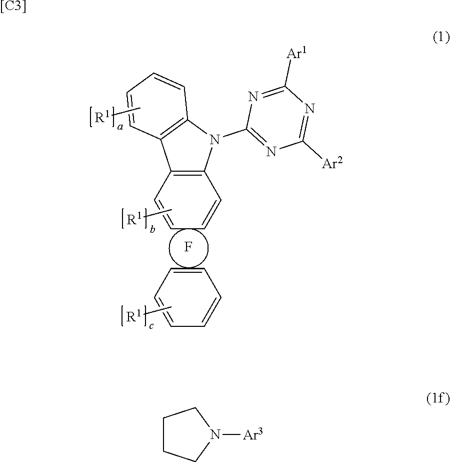
wherein ring F represents a heterocyclic ring represented by a formula (1f) fused with two adjacent benzene rings at any positions; Ar¹ and Ar² each independently represent a deuterium-containing substituted or unsubstituted phenyl group or a deuterium-containing substituted or unsubstituted biphenyl group; Ar³ represents a deuterium-containing substituted or unsubstituted aromatic hydrocarbon group having 6 to 30 carbon atoms, a deuterium-containing substituted or unsubstituted aromatic heterocyclic group having 3 to 17 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; each R¹ independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; a to c represent the number of substitutions, a and c represent an integer of 0 to 4, and b represents an integer of 0 to 2; provided that at least one R¹ represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and an average rate of deuteration of the total hydrogen contained in an indolocarbazole backbone and R¹ as a substituent thereof is 50% or more; some or all of hydrogen contained in Ar³ in the general formula (1) are replaced by deuterium, and an average rate of deuteration of the total hydrogen contained in Ar³ is 50% or more, 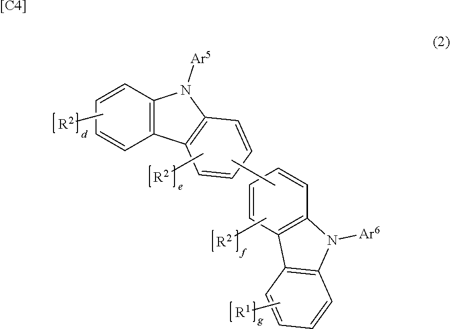
wherein Ar⁵ and Ar⁶ each independently represent a deuterium-containing substituted or unsubstituted aromatic hydrocarbon group having 6 to 30 carbon atoms or a deuterium-containing substituted or unsubstituted linked aromatic group in which two to five of these aromatic groups are linked to each other, and the aromatic hydrocarbon groups when being linked are the same as or different from each other; each R² independently represents deuterium, a deuterium-containing substituted or unsubstituted aromatic hydrocarbon group having 6 to 10 carbon atoms, a deuterium-containing substituted or unsubstituted aromatic heterocyclic group having 3 to 12 carbon atoms, or a deuterium-containing substituted or unsubstituted linked aromatic group in which two to five of these aromatic groups are linked to each other, and the aromatic hydrocarbon groups or the aromatic heterocyclic groups when being linked are the same as or different from each other; d to g represent the number of substitutions, d and g represent an integer of 0 to 4, and e and f represent an integer of 0 to 3; provided that at least one R² represents deuterium, a substituted or unsubstituted aromatic hydrocarbon group having 6 to 10 carbon atoms and partially or entirely substituted with deuterium, a substituted or unsubstituted aromatic heterocyclic group having 3 to 12 carbon atoms and partially or entirely substituted with deuterium, or a substituted or unsubstituted linked aromatic group partially or entirely substituted with deuterium in which two to five of these aromatic groups are linked to each other, and an average rate of deuteration of the total hydrogen contained in a biscarbazole backbone and R² as a substituent thereof is 50% or more; and some or all of hydrogen contained in Ar⁵ and Ar⁶ in the general formula (2) are replaced by deuterium, and an average rate of deuteration of the total hydrogen contained in Ar⁵ and Ar⁶ is 30% or more.

14. The premixture according to claim 13, wherein, in the general formula (1), Ar³ represents a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted quaterphenyl group, a deuterium-containing substituted or unsubstituted dibenzofuranyl group, or a deuterium-containing substituted or unsubstituted dibenzothiophenyl group.

15. The premixture according to claim 13, wherein, in the general formula (1), Ar³ represents a deuterium-containing substituted or unsubstituted phenyl group, a deuterium-containing substituted or unsubstituted biphenyl group, a deuterium-containing substituted or unsubstituted terphenyl group, or a deuterium-containing substituted or unsubstituted quaterphenyl group.

16. The premixture according to claim 13, wherein, in the general formula (1), the average rate of deuteration of the total hydrogen contained in Ar³ is 70% or more.

17. The premixture according to claim 13, wherein, in the general formula (1), R¹ represents deuterium.

18. The premixture according to claim 13, wherein, in the general formula (2), Ar⁵ and Ar⁶ represent a deuterium-containing substituted or unsubstituted phenyl group, a deuterium-containing substituted or unsubstituted biphenyl group, a deuterium-containing substituted or unsubstituted terphenyl group, a deuterium-containing substituted or unsubstituted dibenzofuranyl group, or a deuterium-containing substituted or unsubstituted dibenzothiophenyl group.

19. The premixture according to claim 13, wherein, in the general formula (2), Ar⁵ and Ar⁶ represent a deuterium-containing substituted or unsubstituted phenyl group or a deuterium-containing substituted or unsubstituted biphenyl group.

20. The premixture according to claim 13, wherein, in the general formula (2), the average rate of deuteration of the total hydrogen on Ar⁵ and Ar⁶ is 50% or more.

21. The premixture according to claim 13, wherein, in the general formula (2), R² represents deuterium.

22. The premixture according to claim 13, wherein a proportion of the compound represented by the general formula (1) to the compound represented by the general formula (1) and the compound represented by the general formula (2) in total is 10 wt % or more and less than 80 wt %.

23. The premixture according to claim 13, wherein a difference in temperature at 50% weight loss of the compound represented by the general formula (1) and the compound represented by the general formula (2) is within 20° C.

24. A method for producing the organic electroluminescent device according to claim 1, comprising a step of mixing a first host represented by the general formula (1) and a second host represented by the general formula (2) to give a premixture and then vapor-depositing a host material containing the premixture to form a light emitting layer.
